(19) United States
(12) Patent Application Publication
(10) Pub. No.: US 2025/0194412 A1
(43) Pub. Date: Jun. 12, 2025

(54) COMPOSITION, MIXTURE, LIGHT-EMITTING DEVICE AND DISPLAY PANEL

(71) Applicant: Shenzhen China Star Optoelectronics Semiconductor Display Technology Co., Ltd., Shenzhen (CN)

(72) Inventors: Ruifeng HE, Shenzhen (CN); Canjie WU, Shenzhen (CN); Kewei HE, Shenzhen (CN); Jingyao SONG, Shenzhen (CN)

(73) Assignee: Shenzhen China Star Optoelectronics Semiconductor Display Technology Co., Ltd., Shenzhen (CN)

(21) Appl. No.: 18/398,215

(22) Filed: Dec. 28, 2023

(30) Foreign Application Priority Data
Dec. 12, 2023 (CN) 202311702973.5

(51) Int. Cl. H10K 85/60; C09K 11/02; C09K 11/06; H10K 50/11

(52) U.S. Cl. CPC H10K 85/626; C09K 11/02; C09K 11/06; H10K 85/633; H10K 85/6572; H10K 85/6574; H10K 85/6576; H10K 85/658; C09K 2211/1007; C09K 2211/1011; C09K 2211/1014; C09K 2211/1018; H10K 50/11; H10K 85/622

(57) ABSTRACT

Embodiments of the present disclosure relates to a composition, a mixture, a light-emitting device and a display panel. The composition includes at least one first compound and at least one second compound. The first compound has a formula represented by formula (1):

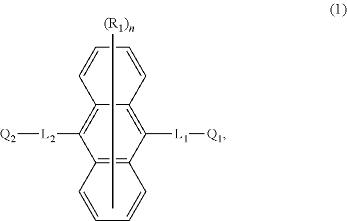

the second compound has a formula represented by formula (2):

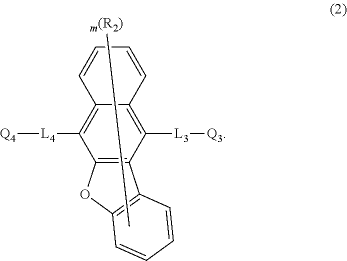

By using the composition formed by a first compound having a structure represented by formula (1) and a second compound having a structure represented by formula (2) of the present disclosure, the charge balance and energy transmission in the light-emitting devices are improved, and the luminous efficiency and luminous lifetime of the light-emitting device are also improved.

### CROSS-REFERENCE TO RELATED APPLICATION

The present disclosure claims priority to and the benefit of Chinese Patent Application No. 202311702973.5, filed on Dec. 12, 2023, the disclosure of which is incorporated herein by reference in its entirety.

### TECHNICAL FIELD

The present disclosure relates to the field of display, and in particularly, to a composition, a mixture, a light-emitting device and a display panel.

### BACKGROUND

Currently, an organic electroluminescent device generally has a positive electrode, a negative electrode, and an organic layer disposed therebetween. Organic substances in the organic layer are used to convert electric energy into light energy, thereby realizing organic electroluminescence. In order to improve the luminous efficiency and service life of an organic electroluminescent device, the organic layer is usually a multilayer, and the organic substance in each layer is different. Exemplarily, the organic layer mainly includes a hole injection layer, a hole transport layer, a light-emitting layer, an electron transport layer, an electron injection layer and the like. In a case that a voltage is applied between the positive electrode and the negative electrode of the organic electroluminescent device, the positive electrode injects holes into the organic layer, and the negative electrode injects electrons into the organic layer. The injected holes and electrons meet to form excitons, and light is emitted when the exciton transitions back to the ground state, thus realizing the luminescence of the organic electroluminescent device. Organic electroluminescent devices have the characteristics of self-luminescence, high brightness, high efficiency, low voltage driving, wide viewing angle, high contrast and high response. Therefore, organic electroluminescent devices have a wide application prospect.

Accordingly, the development of organic light-emitting diode (OLED) material has received wide attention due to a variety of advantages such as diversity in synthesis, simple composition and simple process. Meanwhile, in order to improve the luminous efficiency of organic electroluminescent devices, people have tried various material systems of energy transmission and conversion mechanisms. However, the luminous efficiency, stability and lifetime of the light-emitting layer materials applied to OLED devices (especially the light-emitting layer materials of blue-emitting OLED devices) are still low, resulting in limited improvement of the performance of OLED devices.

Therefore, there is an urgent need for a composition, a mixture, a light-emitting device, and a display panel to solve the above technical problems.

### SUMMARY

The present disclosure provides a composition, a mixture, a light-emitting device, and a display panel, which can alleviate the technical problem that the performance of OLED devices is difficult to improve due to low luminous efficiency, stability and lifetime of the light-emitting layer materials currently used in OLED devices.

The present disclosure provides a composition including at least one first compound and at least one second compound;
the first compound has a structure represented by formula (1):

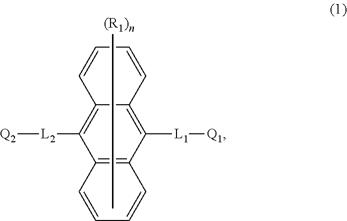

the second compound as a structure represented by formula (2):

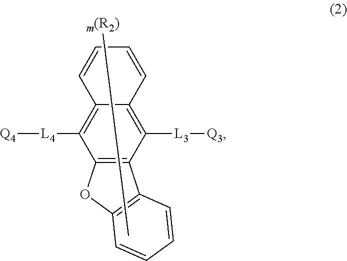

wherein L₁, L₂, L₃ and L₄ are each independently selected from a single bond, a substituted or unsubstituted aromatic group having 6 to 30 ring atoms, a substituted or unsubstituted heteroaromatic group having 5 to 30 ring atoms;
Q₁, Q₂, Q₃ and Q₄ are each independently selected from a substituted or unsubstituted alkyl group having 1 to 20 carbon atoms, a substituted or unsubstituted aromatic group having 6 to 60 ring atoms, a substituted or unsubstituted heteroaromatic group having 5 to 60 ring atoms, or a combination thereof,
R₁ and R₂ are each independently selected from hydrogen, deuterium, a substituted or unsubstituted alkyl group having 1 to 10 carbon atoms, a substituted or unsubstituted aromatic group having 6 to 30 ring atoms, a substituted or unsubstituted heteroaromatic group having 5 to 30 ring atoms; and
n and m are each independently selected from any one integer from 0 to 8.

Optionally, Q1, Q2, Q3 and Q4 are each independently selected from a substituted or unsubstituted alkyl group having 1 to 10 carbon atoms, a substituted or unsubstituted aromatic group having 6 to 30 ring atoms, a substituted or unsubstituted heteroaromatic group having 5 to 30 ring atoms, or a combination thereof.

Optionally, Q1 and Q2 are each independently selected from a structure represented by any one of formulae (A-1) to (A-4):

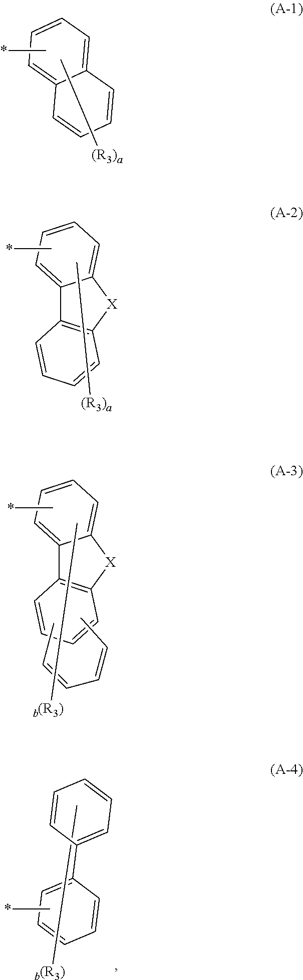

wherein X is selected from CR₄R₅, NR₆, O or S;
R₃, R₄, R₅ and R₆ are each independently selected from hydrogen, deuterium, a substituted or unsubstituted alkyl group having 1 to 10 carbon atoms, a substituted or unsubstituted aromatic group having 6 to 30 ring atoms, and a substituted or unsubstituted heteroaromatic group having 5 to 30 ring atoms, two adjacent R₃ form a ring or not, and R₄, R₅ form a ring or not;
a is selected from any one integer from 0 to 7;
b is selected from any one integer from 0 to 9; and
* indicates a linkage site.

Optionally, Q1 and Q2 are each independently selected from a structure represented by any one of formulae (B-1) to (B-2), (C-1) to (C-4) and (D-1) to (D-12):

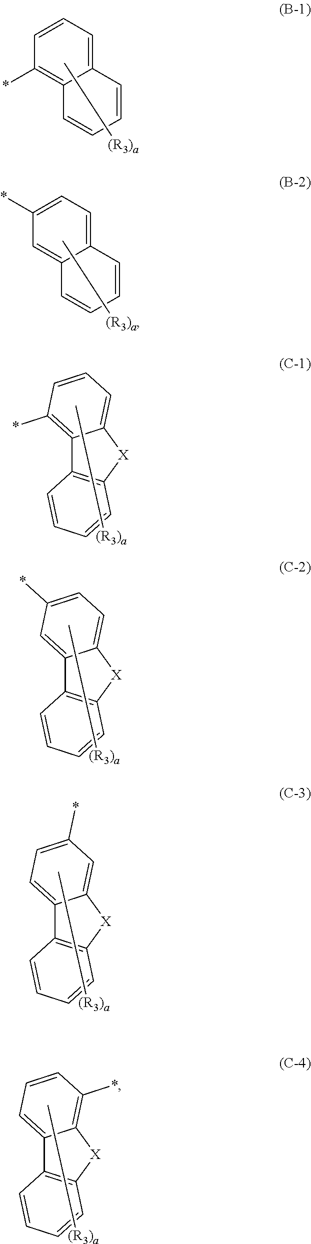

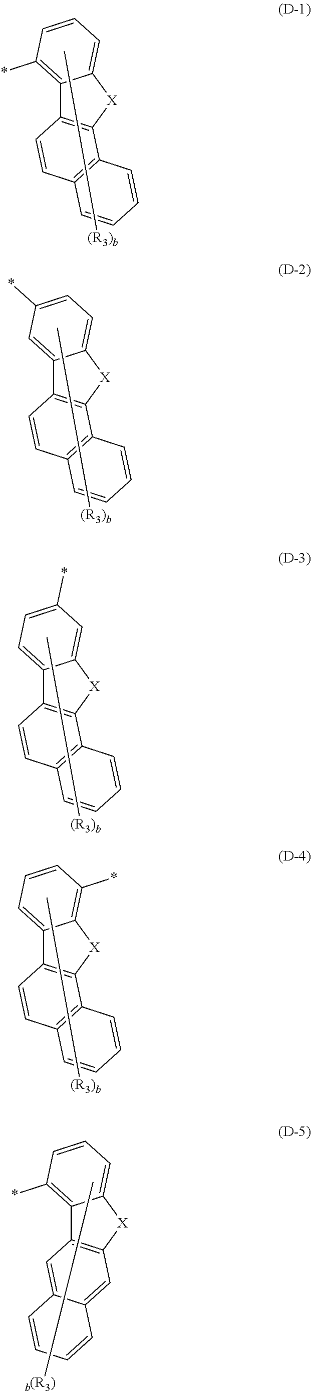

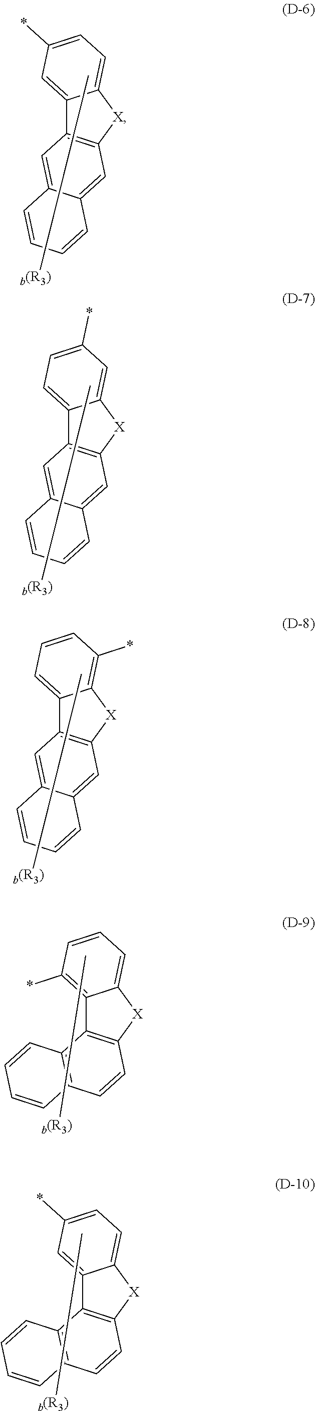

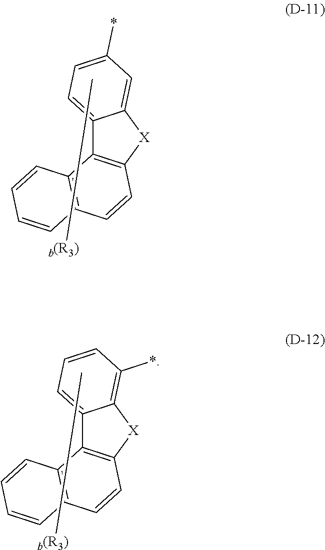

Optionally, Q3 and Q4 are each independently selected from a structure represented by any one of formulae (E-1) to (E-3):

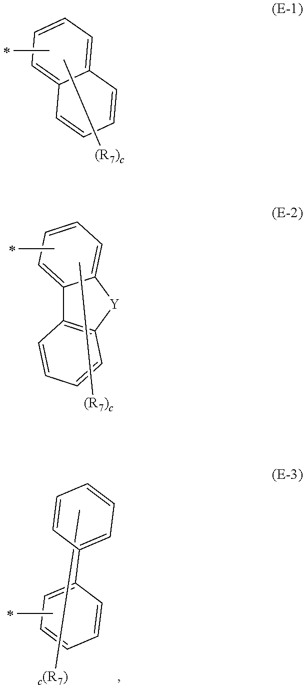

wherein Y is selected from CR₈R₉, NR₁₀, O or S;
R₇, R₈, R₉ and R₁₀ are each independently selected from hydrogen, deuterium, a substituted or unsubstituted alkyl group having 1 to 10 carbon atoms, a substituted or unsubstituted aromatic group having 6 to 30 ring atoms, and a substituted or unsubstituted heteroaromatic group having 5 to 30 ring atoms, two adjacent R₇ form a ring or not; and
c is selected from any integer from 0 to 9.

Optionally, Q3 and Q4 are each independently selected from a structure represented by any one of formulae (F-1) to (F-2) and (G-1) to (G-4):

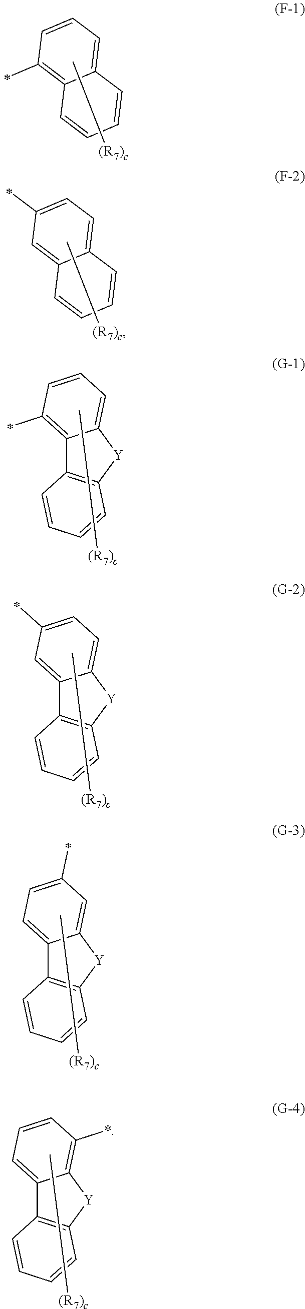

Optionally, the first compound has a structure represented by any one of formulae (1-1) to (1-3):

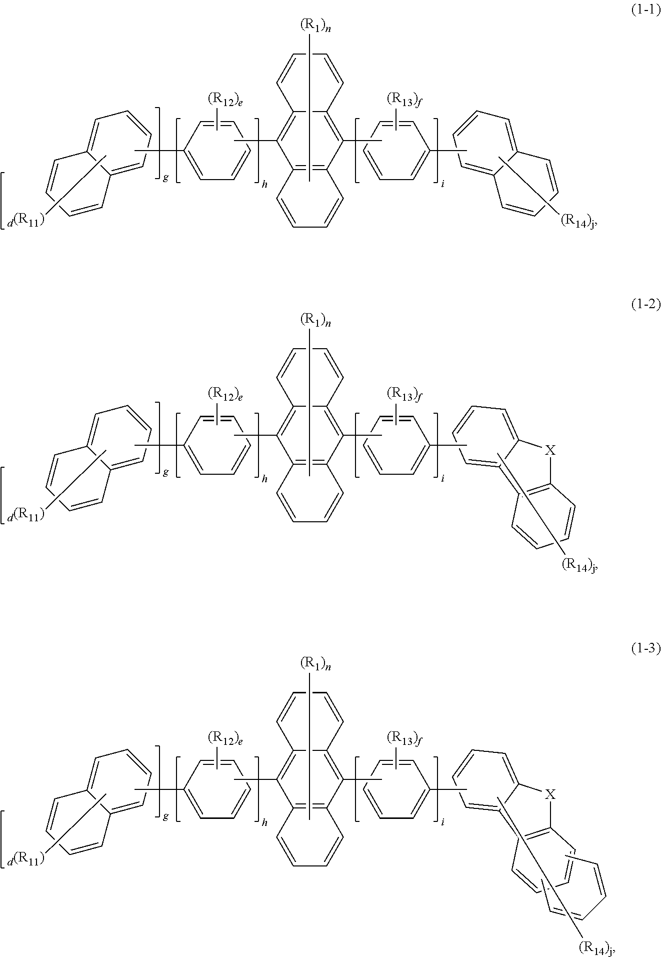

the second compound has a structure represented by any one of formulae (2-1) to (2-3):

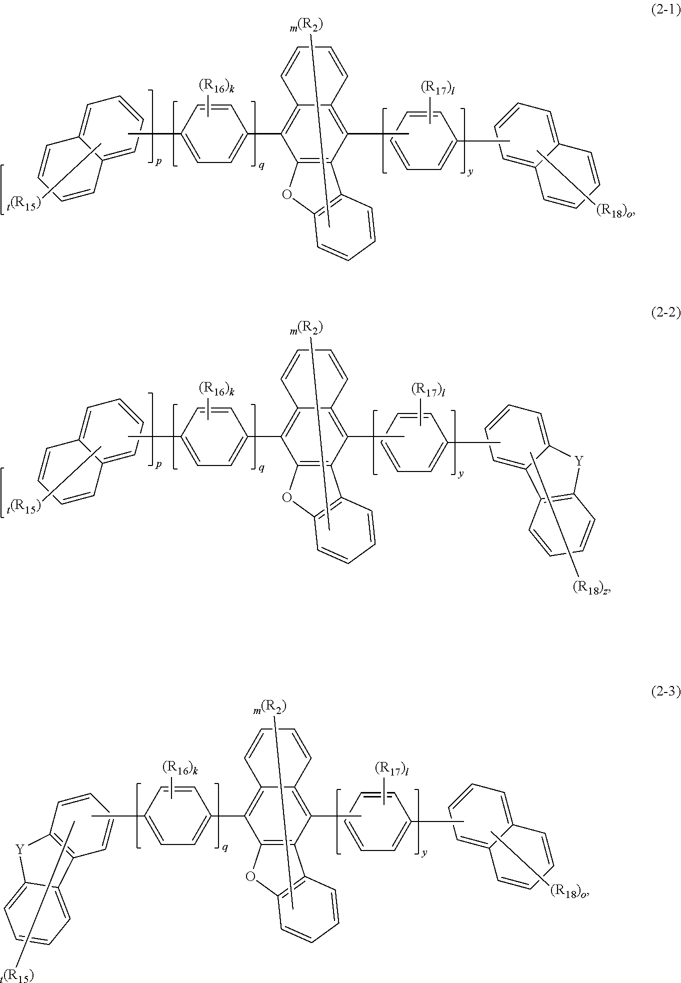

wherein R₁₁, R₁₂, R₁₃, R₁₄, R₁₅, R₁₆, R₁₇ and R₁₈ are each independently selected from hydrogen, deuterium, a substituted or unsubstituted alkyl group having 1 to 10 carbon atoms, a substituted or unsubstituted aromatic group having 6 to 30 ring atoms and a substituted or unsubstituted heteroaromatic group having 5 to 30 ring atoms, two adjacent R₁ form a ring or not, two adjacent R₁₂ form a ring or not, two adjacent R₁₃ form a ring or not, two adjacent R₁₄ form a ring or not, two adjacent R₁₅ form a ring or not, two adjacent R₁₆ form a ring or not, two adjacent R₁₇ form a ring or not, and two adjacent R₁₈ form a ring or not;
d, j, t, o and z are each independently selected from any one integer from 0 to 7;
e, f, k and 1 are each independently selected from any one integer from 0 to 4;
g and p are each independently selected from 0 or 1;
h, i, q and y are each independently selected from any integer from 0 to 3, a sum of g and h is greater than or equal to 1, and a sum of p and q is greater than or equal to 1.

Optionally, L1, L2, L3 and L4 are each independently selected from a single bond or phenyl.

Optionally, the first compound is selected from:

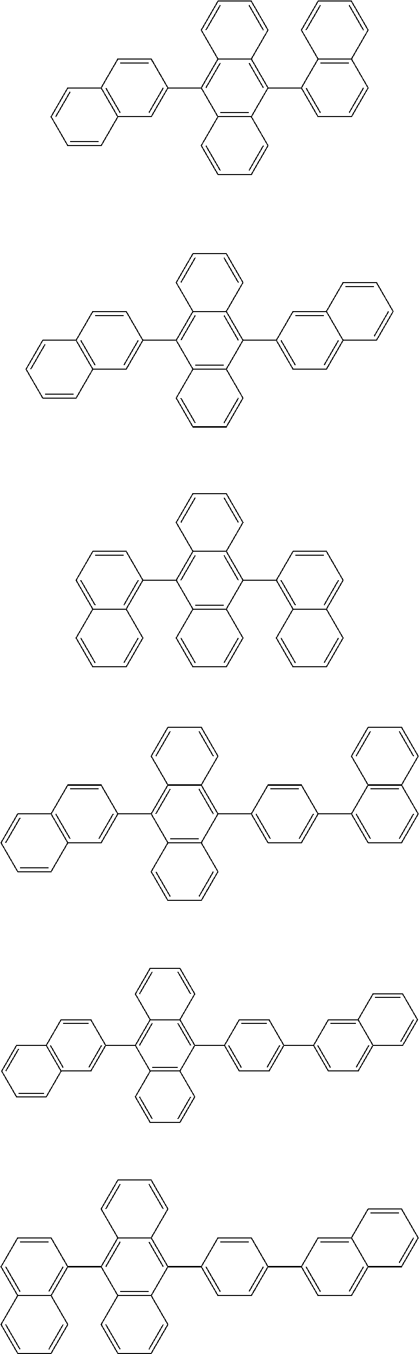

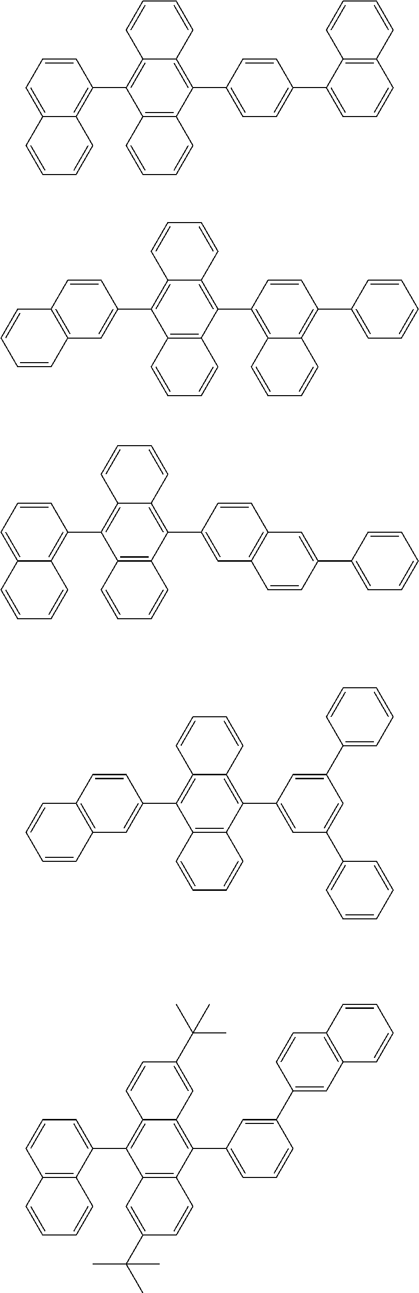

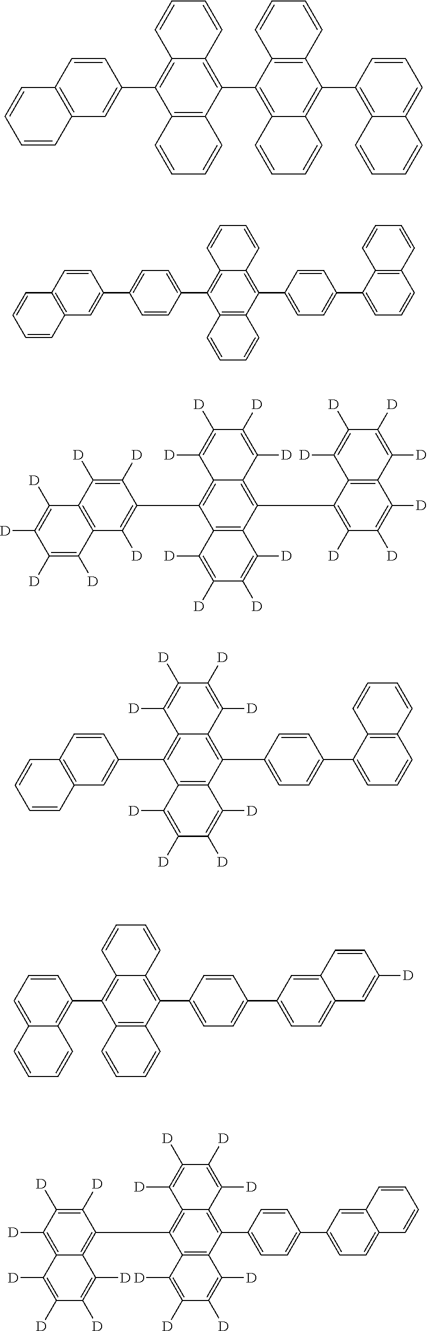

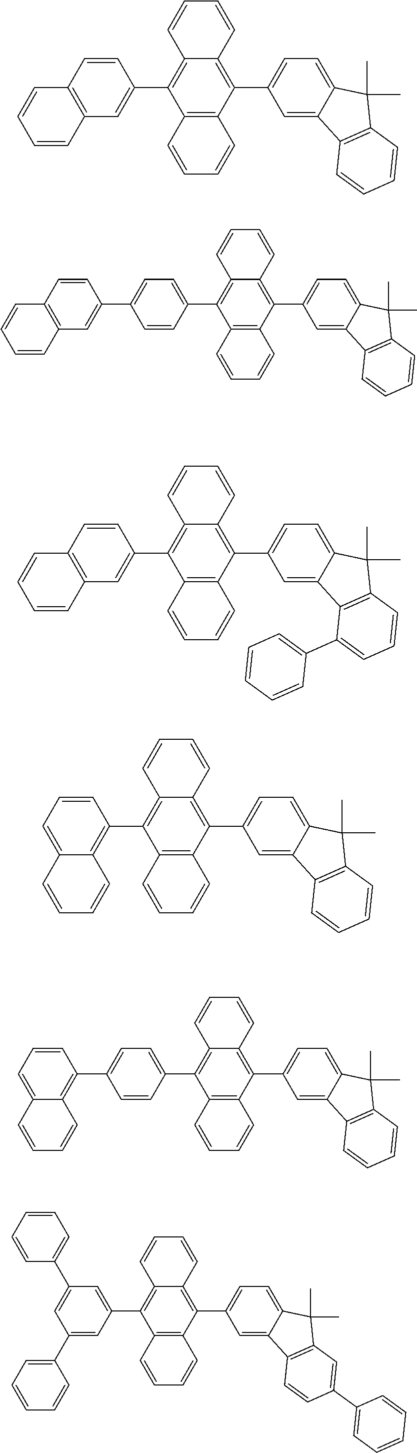

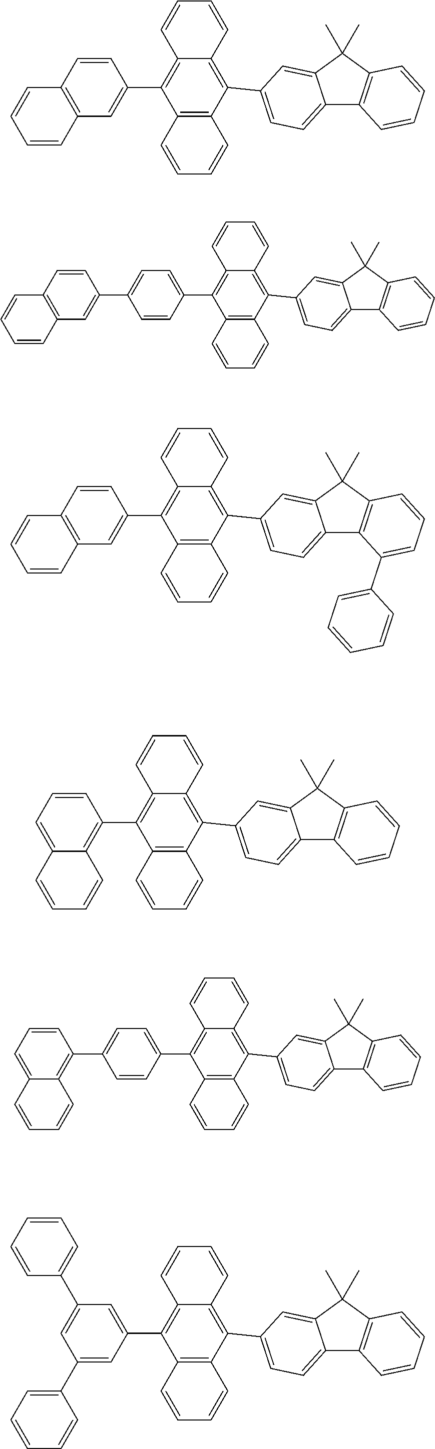

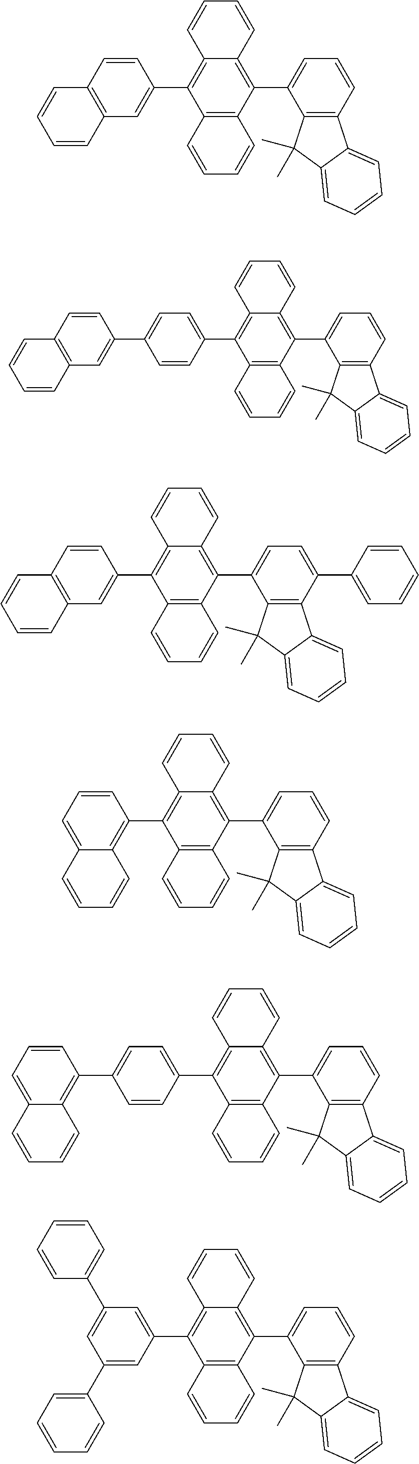

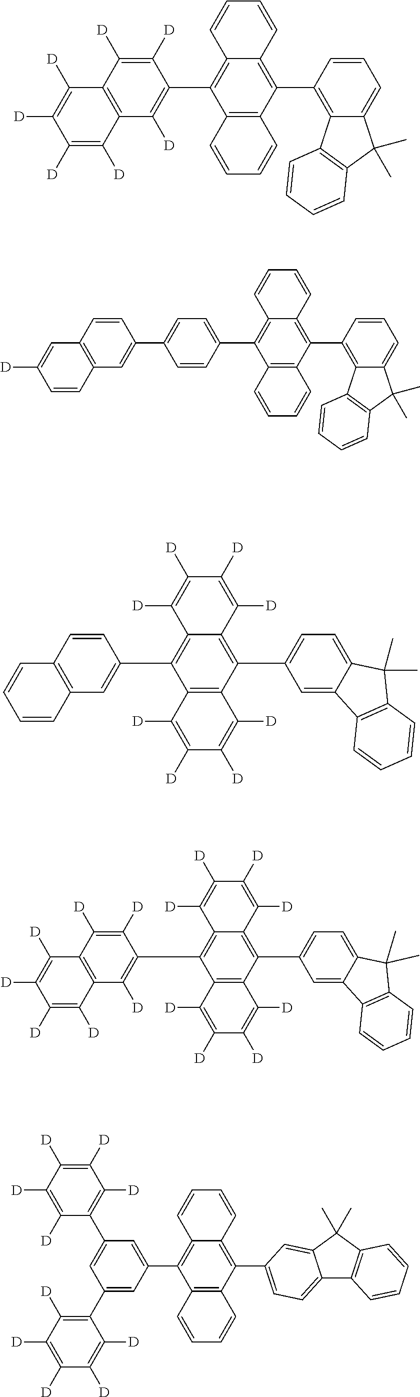

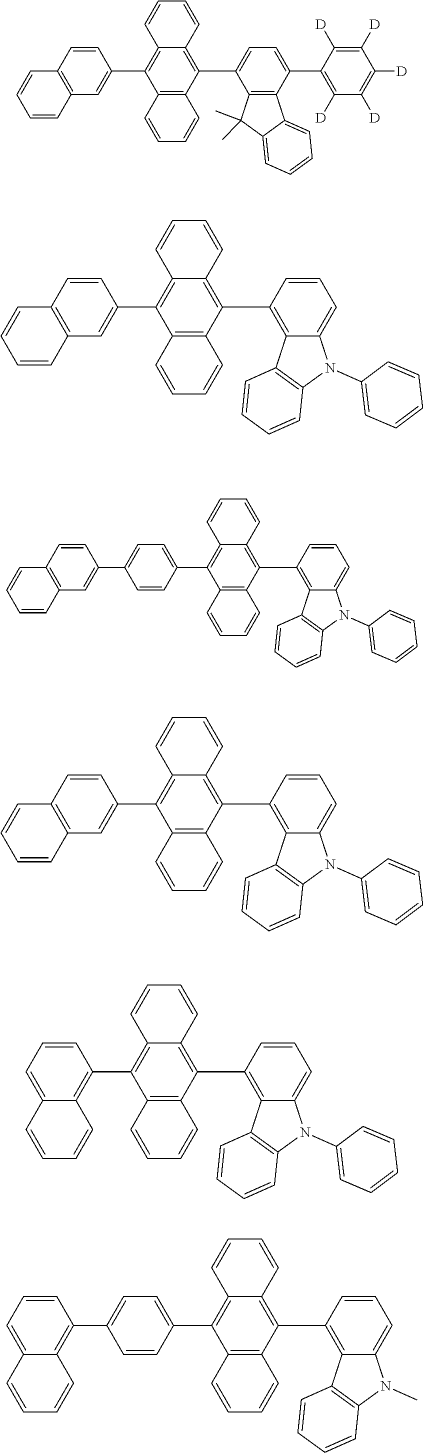

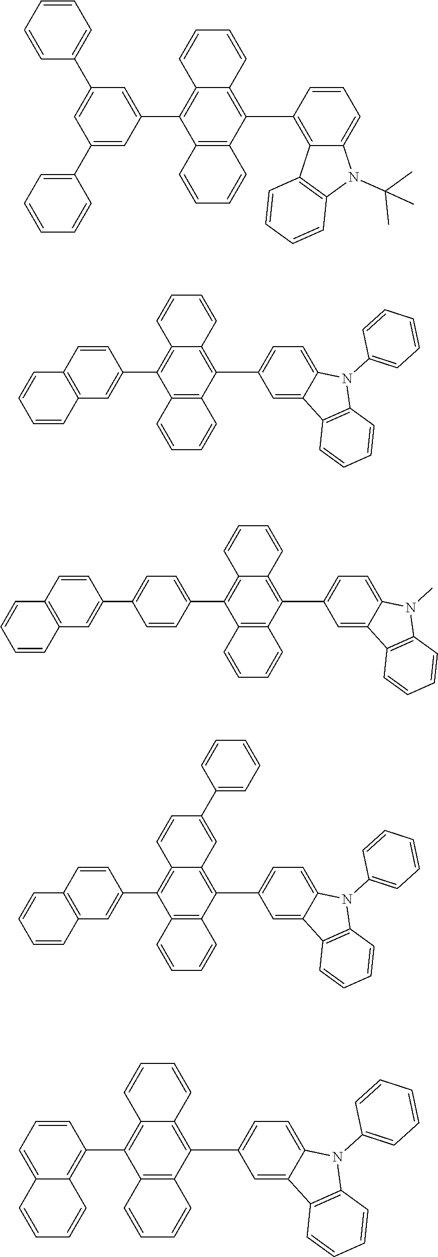 [SMILES: CC(C)(C)n1c2ccccc2c2c(-c3c4ccccc4c(-c4cc(-c5ccccc5)cc(-c5ccccc5)c4)c4ccccc34)cccc21 ; c1ccc(-n2c3ccccc3c3cc(-c4c5ccccc5c(-c5ccc6ccccc6c5)c5ccccc45)ccc32)cc1 ; Cn1c2ccccc2c2cc(-c3c4ccccc4c(-c4ccc(-c5ccc6ccccc6c5)cc4)c4ccccc34)ccc21 ; c1ccc(-c2ccc3c(-c4ccc5ccccc5c4)c4ccccc4c(-c4ccc5c(c4)c4ccccc4n5-c4ccccc4)c3c2)cc1 ; c1ccc(-n2c3ccccc3c3cc(-c4c5ccccc5c(-c5cccc6ccccc56)c5ccccc45)ccc32)cc1]

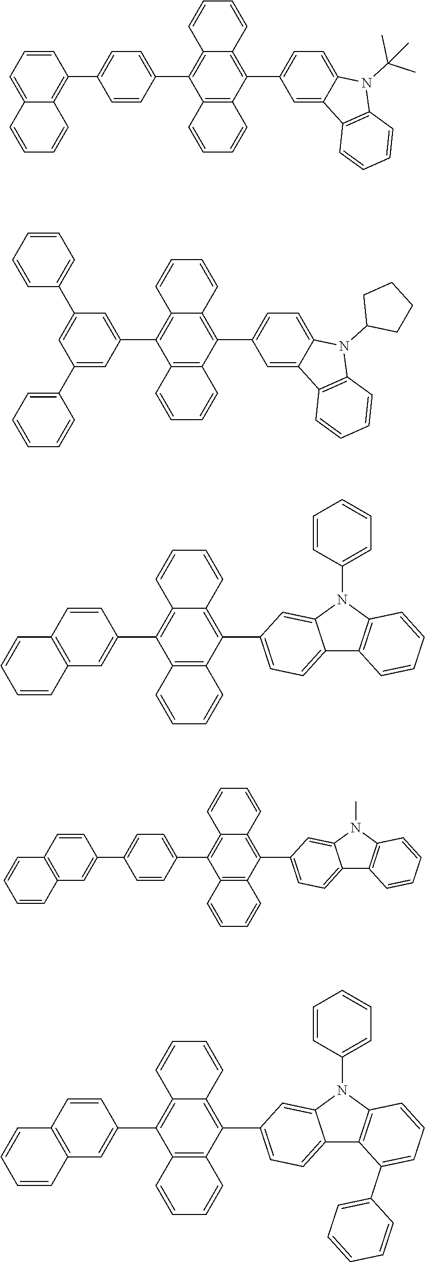 [SMILES: CC(C)(C)n1c2ccccc2c2cc(-c3c4ccccc4c(-c4ccc(-c5cccc6ccccc56)cc4)c4ccccc34)ccc21 ; c1ccc(-c2cc(-c3ccccc3)cc(-c3c4ccccc4c(-c4ccc5c(c4)c4ccccc4n5C4CCCC4)c4ccccc34)c2)cc1 ; c1ccc(-n2c3ccccc3c3ccc(-c4c5ccccc5c(-c5ccc6ccccc6c5)c5ccccc45)cc32)cc1 ; Cn1c2ccccc2c2ccc(-c3c4ccccc4c(-c4ccc(-c5ccc6ccccc6c5)cc4)c4ccccc34)cc21 ; c1ccc(-c2cccc3c2c2ccc(-c4c5ccccc5c(-c5ccc6ccccc6c5)c5ccccc45)cc2n3-c2ccccc2)cc1]

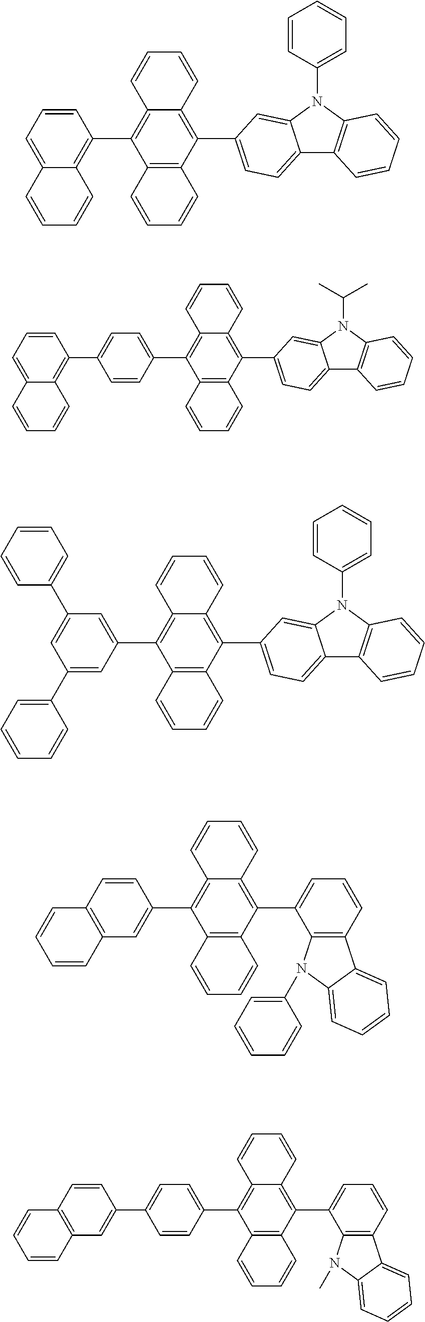 [SMILES: c1ccc(-n2c3ccccc3c3ccc(-c4c5ccccc5c(-c5cccc6ccccc56)c5ccccc45)cc32)cc1 ; CC(C)n1c2ccccc2c2ccc(-c3c4ccccc4c(-c4ccc(-c5cccc6ccccc56)cc4)c4ccccc34)cc21 ; c1ccc(-c2cc(-c3ccccc3)cc(-c3c4ccccc4c(-c4ccc5c6ccccc6n(-c6ccccc6)c5c4)c4ccccc34)c2)cc1 ; c1ccc(-n2c3ccccc3c3cccc(-c4c5ccccc5c(-c5ccc6ccccc6c5)c5ccccc45)c32)cc1 ; Cn1c2ccccc2c2cccc(-c3c4ccccc4c(-c4ccc(-c5ccc6ccccc6c5)cc4)c4ccccc34)c21]

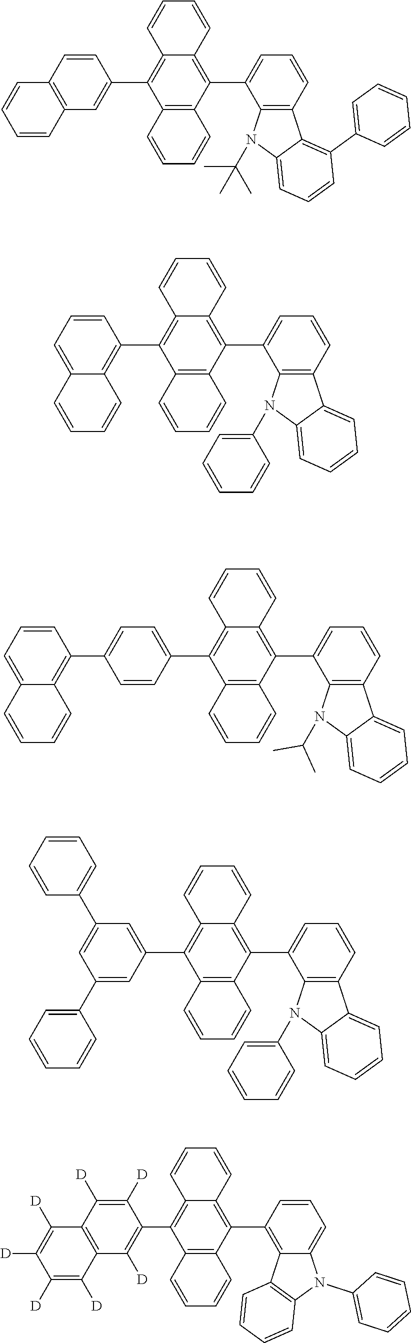 [SMILES: CC(C)(C)n1c2cccc(-c3ccccc3)c2c2cccc(-c3c4ccccc4c(-c4ccc5ccccc5c4)c4ccccc34)c21 ; c1ccc(-n2c3ccccc3c3cccc(-c4c5ccccc5c(-c5cccc6ccccc56)c5ccccc45)c32)cc1 ; CC(C)n1c2ccccc2c2cccc(-c3c4ccccc4c(-c4ccc(-c5cccc6ccccc56)cc4)c4ccccc34)c21 ; c1ccc(-c2cc(-c3ccccc3)cc(-c3c4ccccc4c(-c4cccc5c6ccccc6n(-c6ccccc6)c45)c4ccccc34)c2)cc1 ; [2H]c1c([2H])c([2H])c2c([2H])c(-c3c4ccccc4c(-c4cccc5c4c4ccccc4n5-c4ccccc4)c4ccccc34)c([2H])c([2H])c2c1[2H]]

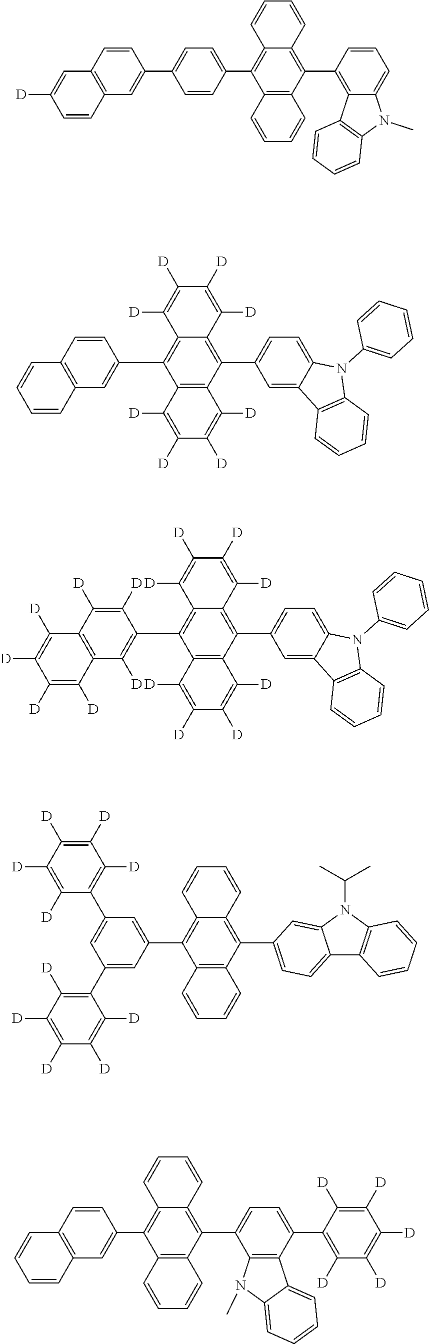

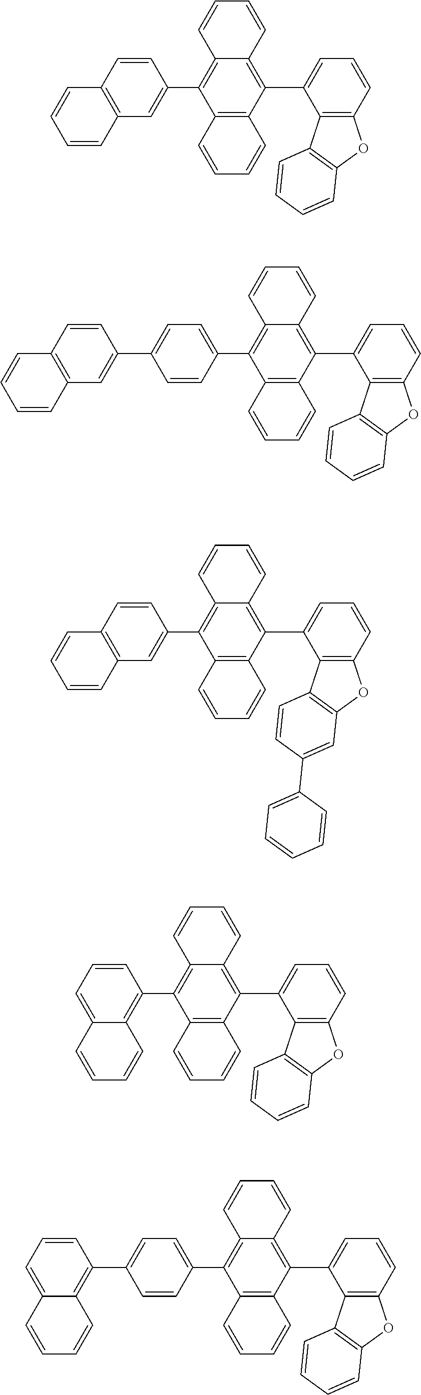 [SMILES: c1ccc2cc(-c3c4ccccc4c(-c4cccc5oc6ccccc6c45)c4ccccc34)ccc2c1 ; c1ccc2cc(-c3ccc(-c4c5ccccc5c(-c5cccc6oc7ccccc7c56)c5ccccc45)cc3)ccc2c1 ; c1ccc(-c2ccc3c(c2)oc2cccc(-c4c5ccccc5c(-c5ccc6ccccc6c5)c5ccccc45)c23)cc1 ; c1ccc2c(-c3c4ccccc4c(-c4cccc5oc6ccccc6c45)c4ccccc34)cccc2c1 ; c1ccc2c(-c3ccc(-c4c5ccccc5c(-c5cccc6oc7ccccc7c56)c5ccccc45)cc3)cccc2c1]

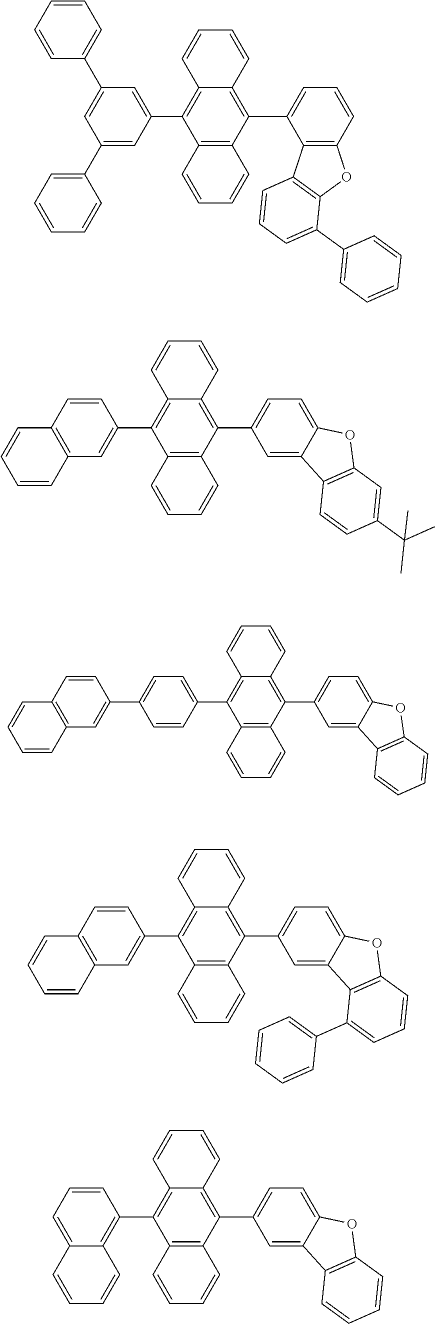 [SMILES: c1ccc(-c2cc(-c3ccccc3)cc(-c3c4ccccc4c(-c4cccc5oc6c(-c7ccccc7)cccc6c45)c4ccccc34)c2)cc1 ; CC(C)(C)c1ccc2c(c1)oc1ccc(-c3c4ccccc4c(-c4ccc5ccccc5c4)c4ccccc34)cc12 ; c1ccc2cc(-c3ccc(-c4c5ccccc5c(-c5ccc6oc7ccccc7c6c5)c5ccccc45)cc3)ccc2c1 ; c1ccc(-c2cccc3oc4ccc(-c5c6ccccc6c(-c6ccc7ccccc7c6)c6ccccc56)cc4c23)cc1 ; c1ccc2c(-c3c4ccccc4c(-c4ccc5oc6ccccc6c5c4)c4ccccc34)cccc2c1]

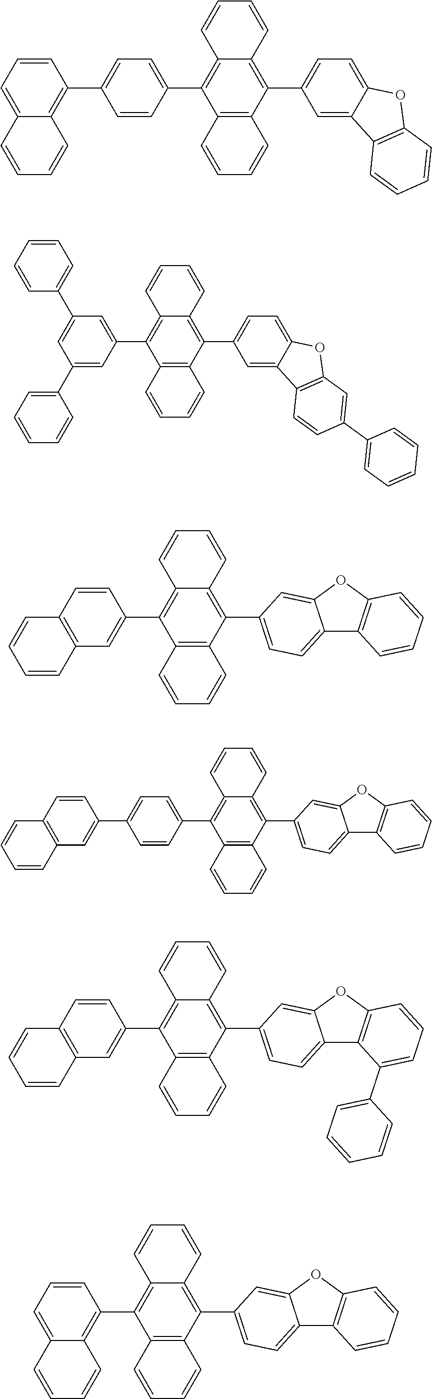 [SMILES: c1ccc2c(-c3ccc(-c4c5ccccc5c(-c5ccc6oc7ccccc7c6c5)c5ccccc45)cc3)cccc2c1 ; c1ccc(-c2cc(-c3ccccc3)cc(-c3c4ccccc4c(-c4ccc5oc6cc(-c7ccccc7)ccc6c5c4)c4ccccc34)c2)cc1 ; c1ccc2cc(-c3c4ccccc4c(-c4ccc5c(c4)oc4ccccc45)c4ccccc34)ccc2c1 ; c1ccc2cc(-c3ccc(-c4c5ccccc5c(-c5ccc6c(c5)oc5ccccc56)c5ccccc45)cc3)ccc2c1 ; c1ccc(-c2cccc3oc4cc(-c5c6ccccc6c(-c6ccc7ccccc7c6)c6ccccc56)ccc4c23)cc1 ; c1ccc2c(-c3c4ccccc4c(-c4ccc5c(c4)oc4ccccc45)c4ccccc34)cccc2c1]

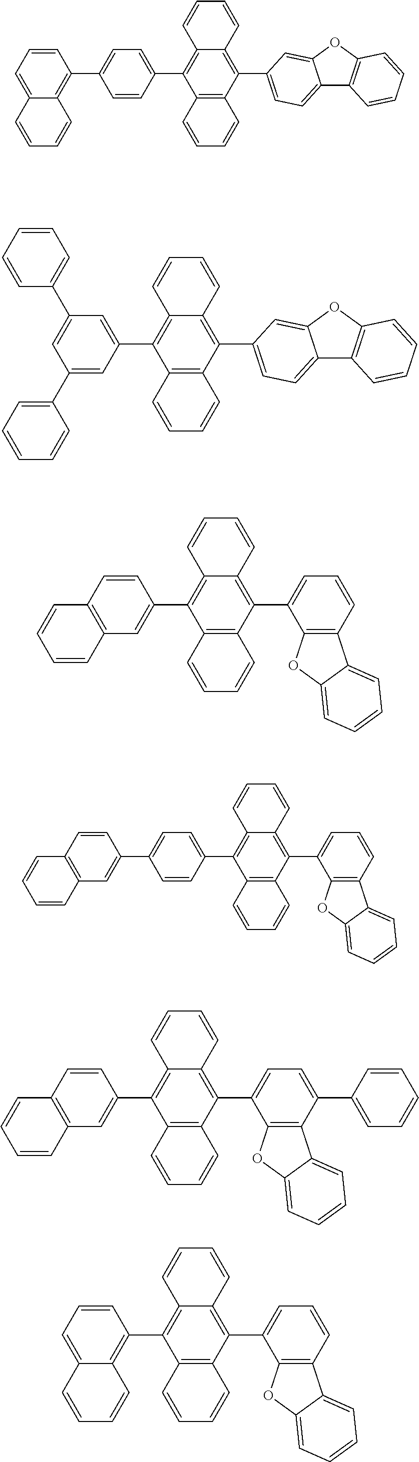 [SMILES: c1ccc2c(-c3ccc(-c4c5ccccc5c(-c5ccc6c(c5)oc5ccccc56)c5ccccc45)cc3)cccc2c1 ; c1ccc(-c2cc(-c3ccccc3)cc(-c3c4ccccc4c(-c4ccc5c(c4)oc4ccccc45)c4ccccc34)c2)cc1 ; c1ccc2cc(-c3c4ccccc4c(-c4cccc5c4oc4ccccc45)c4ccccc34)ccc2c1 ; c1ccc2cc(-c3ccc(-c4c5ccccc5c(-c5cccc6c5oc5ccccc56)c5ccccc45)cc3)ccc2c1 ; c1ccc(-c2ccc(-c3c4ccccc4c(-c4ccc5ccccc5c4)c4ccccc34)c3oc4ccccc4c23)cc1 ; c1ccc2c(-c3c4ccccc4c(-c4cccc5c4oc4ccccc45)c4ccccc34)cccc2c1]

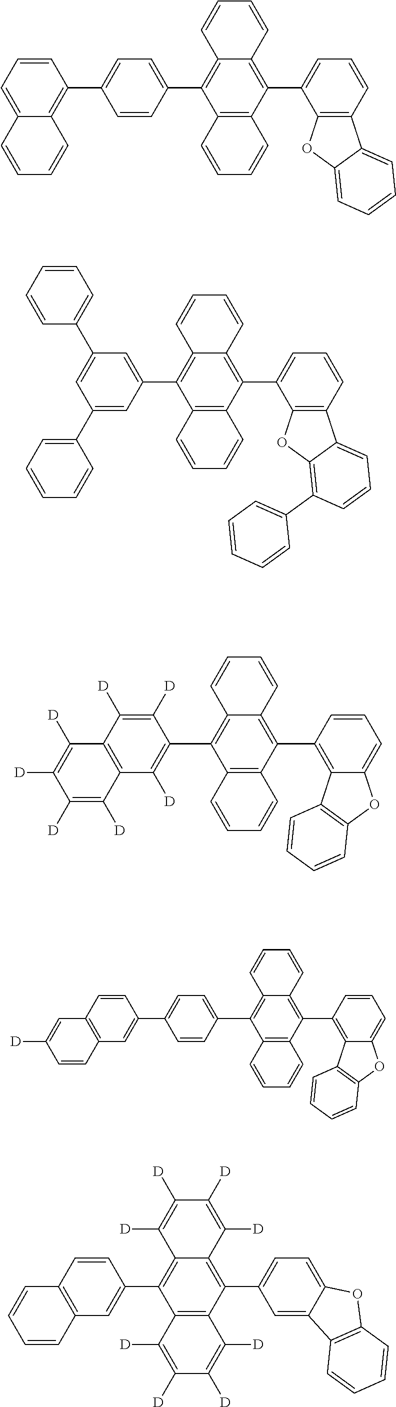 [SMILES: c1ccc2c(-c3ccc(-c4c5ccccc5c(-c5cccc6c5oc5ccccc56)c5ccccc45)cc3)cccc2c1 ; c1ccc(-c2cc(-c3ccccc3)cc(-c3c4ccccc4c(-c4cccc5c4oc4c(-c6ccccc6)cccc45)c4ccccc34)c2)cc1 ; [2H]c1c([2H])c([2H])c2c([2H])c(-c3c4ccccc4c(-c4cccc5oc6ccccc6c45)c4ccccc34)c([2H])c([2H])c2c1[2H] ; [2H]c1ccc2cc(-c3ccc(-c4c5ccccc5c(-c5cccc6oc7ccccc7c56)c5ccccc45)cc3)ccc2c1 ; [2H]c1c([2H])c([2H])c2c(-c3ccc4oc5ccccc5c4c3)c3c([2H])c([2H])c([2H])c([2H])c3c(-c3ccc4ccccc4c3)c2c1[2H]]

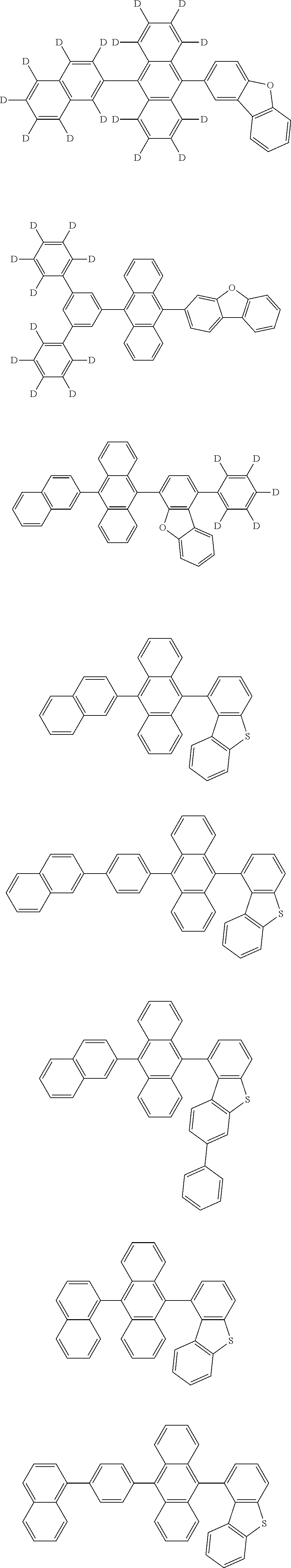

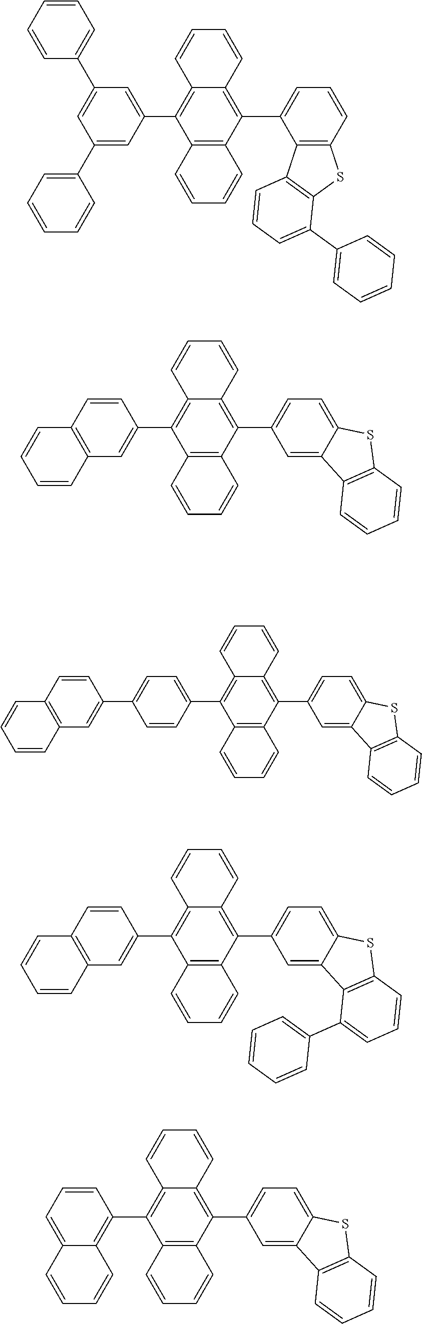 [SMILES: c1ccc(-c2cc(-c3ccccc3)cc(-c3c4ccccc4c(-c4cccc5sc6c(-c7ccccc7)cccc6c45)c4ccccc34)c2)cc1 ; c1ccc2cc(-c3c4ccccc4c(-c4ccc5sc6ccccc6c5c4)c4ccccc34)ccc2c1 ; c1ccc2cc(-c3ccc(-c4c5ccccc5c(-c5ccc6sc7ccccc7c6c5)c5ccccc45)cc3)ccc2c1 ; c1ccc(-c2cccc3sc4ccc(-c5c6ccccc6c(-c6ccc7ccccc7c6)c6ccccc56)cc4c23)cc1 ; c1ccc2c(-c3c4ccccc4c(-c4ccc5sc6ccccc6c5c4)c4ccccc34)cccc2c1]

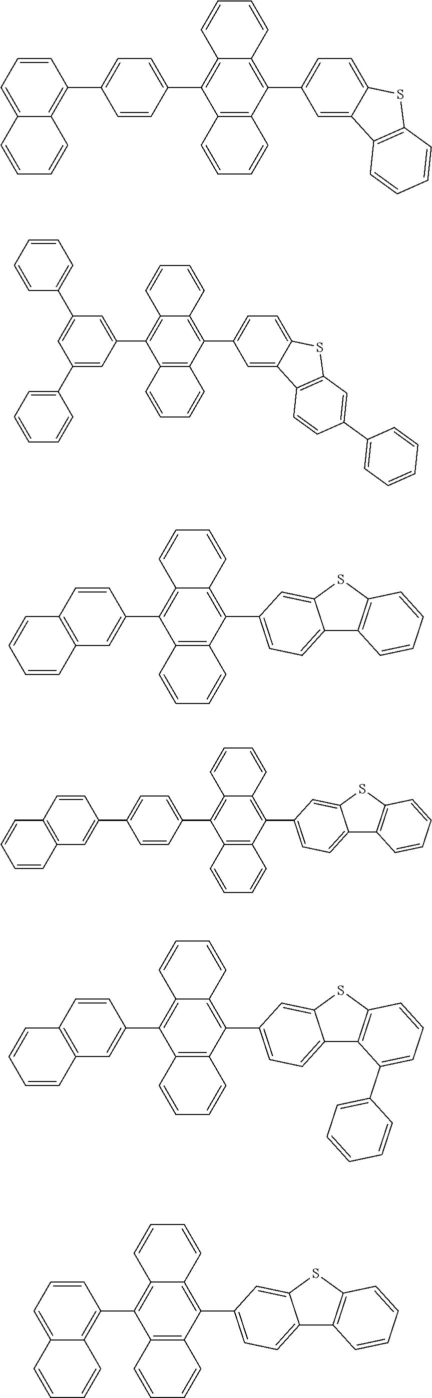 [SMILES: c1ccc2c(-c3ccc(-c4c5ccccc5c(-c5ccc6sc7ccccc7c6c5)c5ccccc45)cc3)cccc2c1 ; c1ccc(-c2cc(-c3ccccc3)cc(-c3c4ccccc4c(-c4ccc5sc6cc(-c7ccccc7)ccc6c5c4)c4ccccc34)c2)cc1 ; c1ccc2cc(-c3c4ccccc4c(-c4ccc5c(c4)sc4ccccc45)c4ccccc34)ccc2c1 ; c1ccc2cc(-c3ccc(-c4c5ccccc5c(-c5ccc6c(c5)sc5ccccc56)c5ccccc45)cc3)ccc2c1 ; c1ccc(-c2cccc3sc4cc(-c5c6ccccc6c(-c6ccc7ccccc7c6)c6ccccc56)ccc4c23)cc1 ; c1ccc2c(-c3c4ccccc4c(-c4ccc5c(c4)sc4ccccc45)c4ccccc34)cccc2c1]

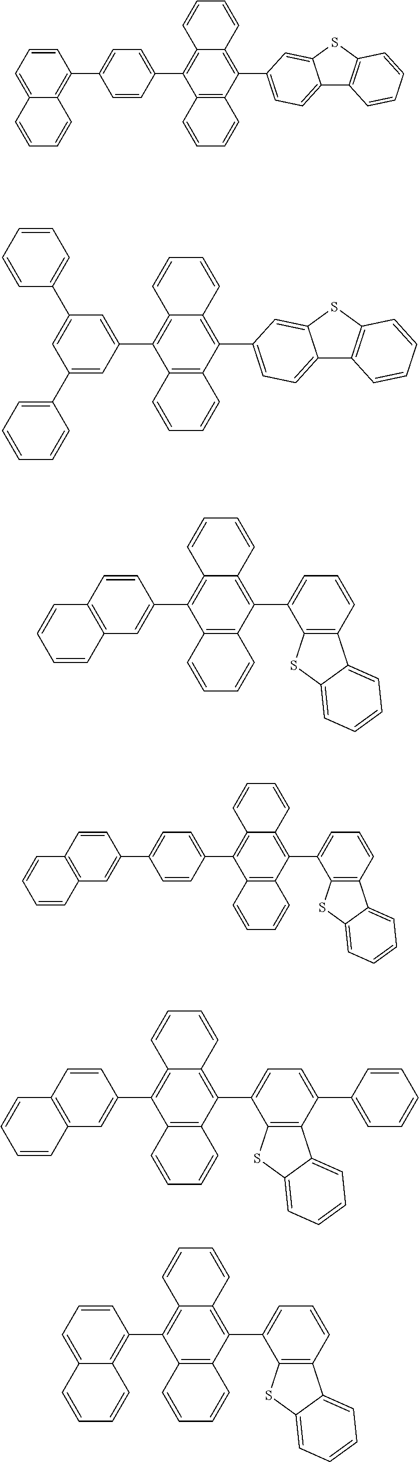 [SMILES: c1ccc2c(-c3ccc(-c4c5ccccc5c(-c5ccc6c(c5)sc5ccccc56)c5ccccc45)cc3)cccc2c1 ; c1ccc(-c2cc(-c3ccccc3)cc(-c3c4ccccc4c(-c4ccc5c(c4)sc4ccccc45)c4ccccc34)c2)cc1 ; c1ccc2cc(-c3c4ccccc4c(-c4cccc5c4sc4ccccc45)c4ccccc34)ccc2c1 ; c1ccc2cc(-c3ccc(-c4c5ccccc5c(-c5cccc6c5sc5ccccc56)c5ccccc45)cc3)ccc2c1 ; c1ccc(-c2ccc(-c3c4ccccc4c(-c4ccc5ccccc5c4)c4ccccc34)c3sc4ccccc4c23)cc1 ; c1ccc2c(-c3c4ccccc4c(-c4cccc5c4sc4ccccc45)c4ccccc34)cccc2c1]

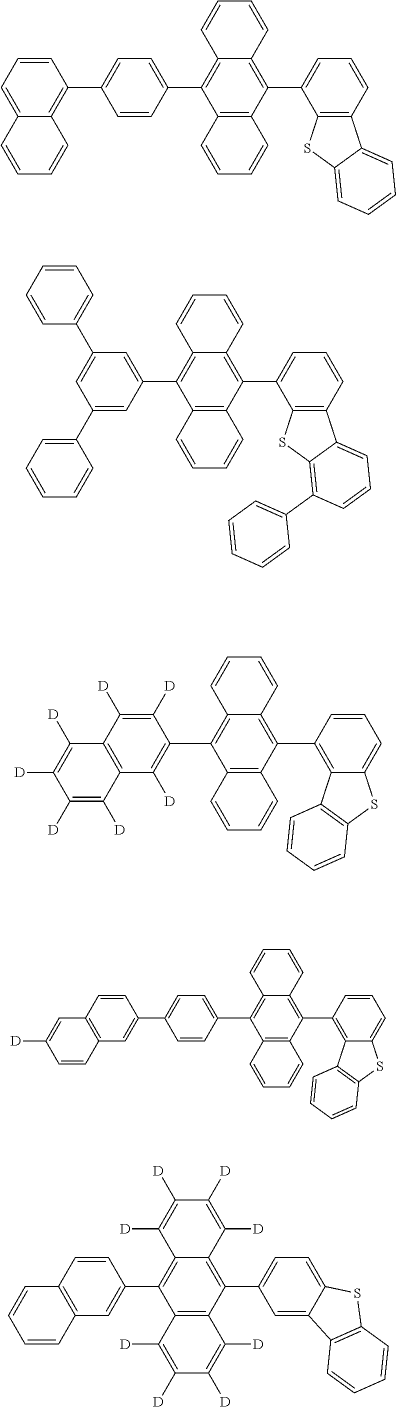 [SMILES: c1ccc2c(-c3ccc(-c4c5ccccc5c(-c5cccc6c5sc5ccccc56)c5ccccc45)cc3)cccc2c1 ; c1ccc(-c2cc(-c3ccccc3)cc(-c3c4ccccc4c(-c4cccc5c4sc4c(-c6ccccc6)cccc45)c4ccccc34)c2)cc1 ; [2H]c1c([2H])c([2H])c2c([2H])c(-c3c4ccccc4c(-c4cccc5sc6ccccc6c45)c4ccccc34)c([2H])c([2H])c2c1[2H] ; [2H]c1ccc2cc(-c3ccc(-c4c5ccccc5c(-c5cccc6sc7ccccc7c56)c5ccccc45)cc3)ccc2c1 ; [2H]c1c([2H])c([2H])c2c(-c3ccc4sc5ccccc5c4c3)c3c([2H])c([2H])c([2H])c([2H])c3c(-c3ccc4ccccc4c3)c2c1[2H]]

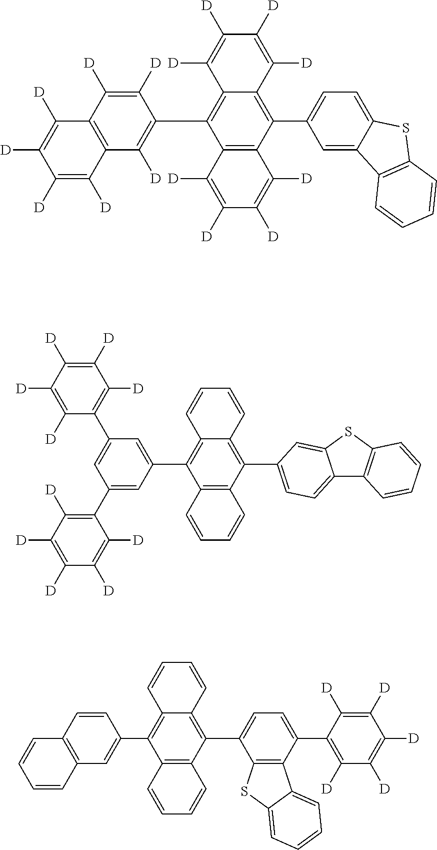 [SMILES: [2H]c1c([2H])c([2H])c2c([2H])c(-c3c4c([2H])c([2H])c([2H])c([2H])c4c(-c4ccc5sc6ccccc6c5c4)c4c([2H])c([2H])c([2H])c([2H])c34)c([2H])c([2H])c2c1[2H] ; [2H]c1c([2H])c([2H])c(-c2cc(-c3c([2H])c([2H])c([2H])c([2H])c3[2H])cc(-c3c4ccccc4c(-c4ccc5c(c4)sc4ccccc45)c4ccccc34)c2)c([2H])c1[2H] ; [2H]c1c([2H])c([2H])c(-c2ccc(-c3c4ccccc4c(-c4ccc5ccccc5c4)c4ccccc34)c3sc4ccccc4c23)c([2H])c1[2H]]

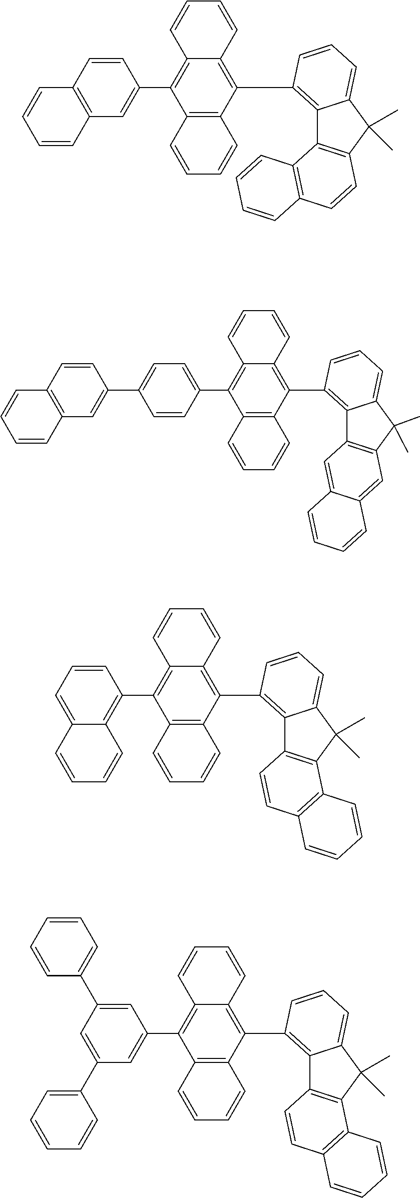

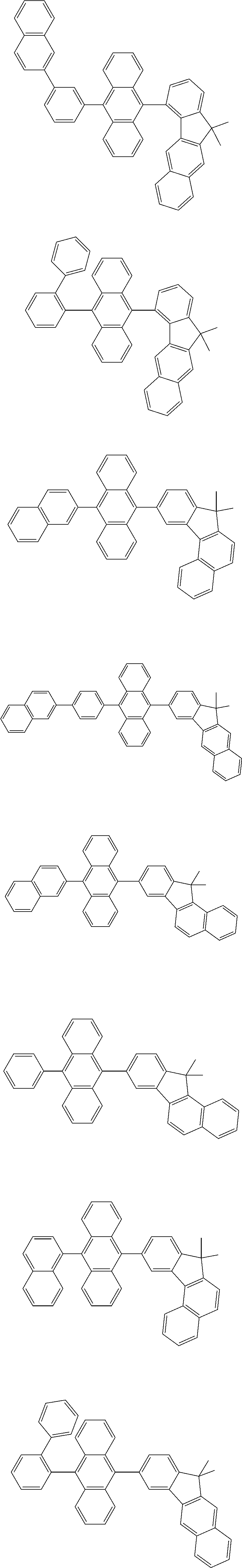

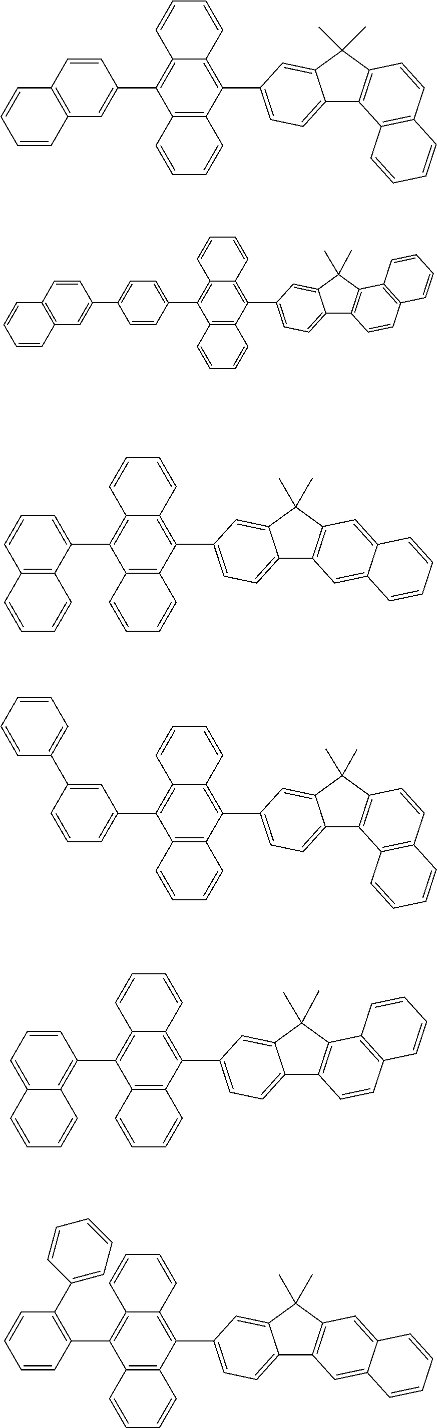

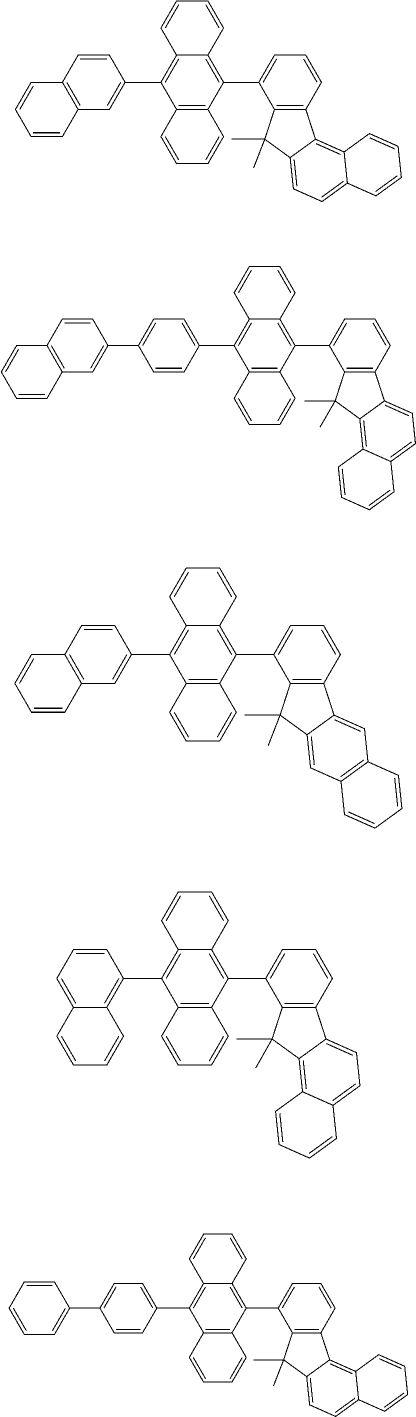

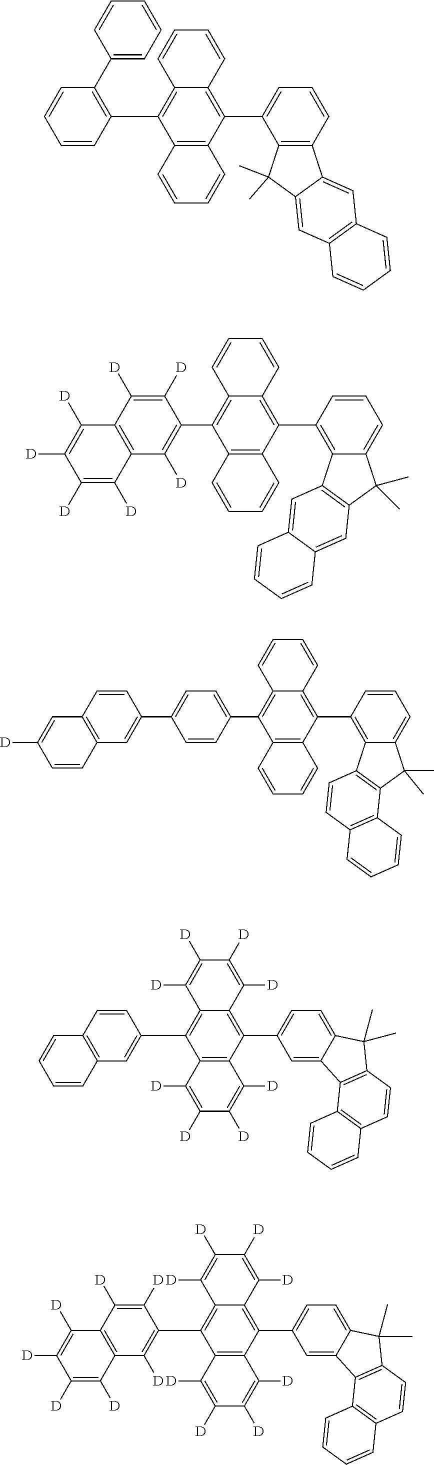

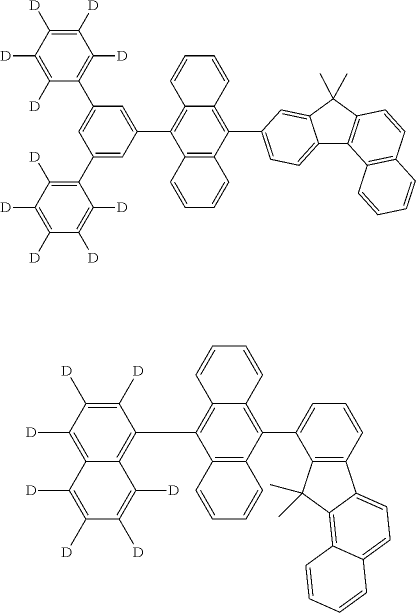 [SMILES: [2H]c1c([2H])c([2H])c(-c2cc(-c3c([2H])c([2H])c([2H])c([2H])c3[2H])cc(-c3c4ccccc4c(-c4ccc5c(c4)C(C)(C)c4ccc6ccccc6c4-5)c4ccccc34)c2)c([2H])c1[2H] ; [2H]c1c([2H])c([2H])c2c(-c3c4ccccc4c(-c4cccc5c4C(C)(C)c4c-5ccc5ccccc45)c4ccccc34)c([2H])c([2H])c([2H])c2c1[2H]]

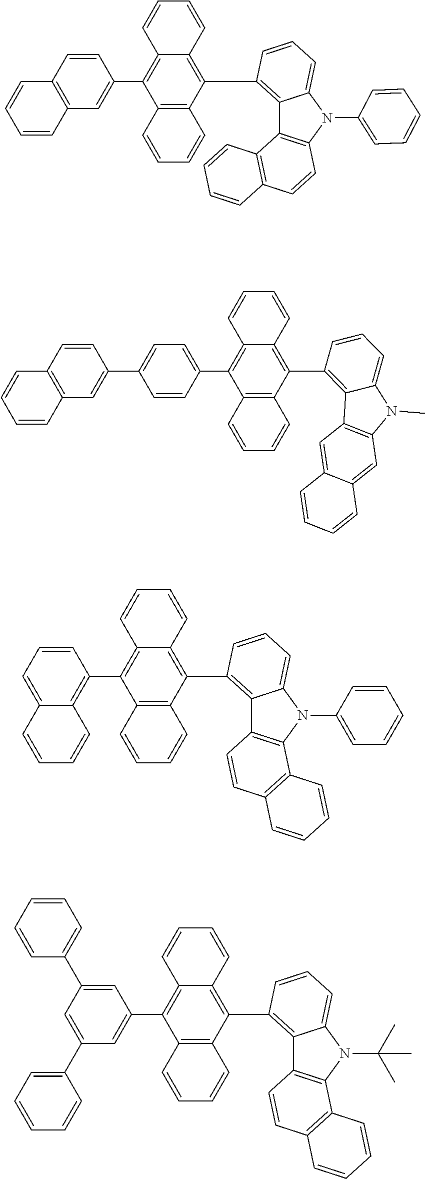 [SMILES: c1ccc(-n2c3cccc(-c4c5ccccc5c(-c5ccc6ccccc6c5)c5ccccc45)c3c3c4ccccc4ccc32)cc1 ; Cn1c2cc3ccccc3cc2c2c(-c3c4ccccc4c(-c4ccc(-c5ccc6ccccc6c5)cc4)c4ccccc34)cccc21 ; c1ccc(-n2c3cccc(-c4c5ccccc5c(-c5cccc6ccccc56)c5ccccc45)c3c3ccc4ccccc4c32)cc1 ; CC(C)(C)n1c2cccc(-c3c4ccccc4c(-c4cc(-c5ccccc5)cc(-c5ccccc5)c4)c4ccccc34)c2c2ccc3ccccc3c21]

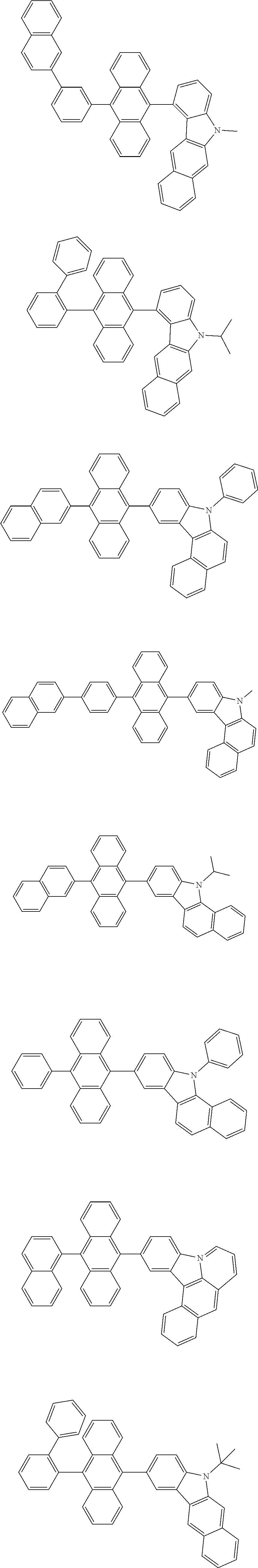

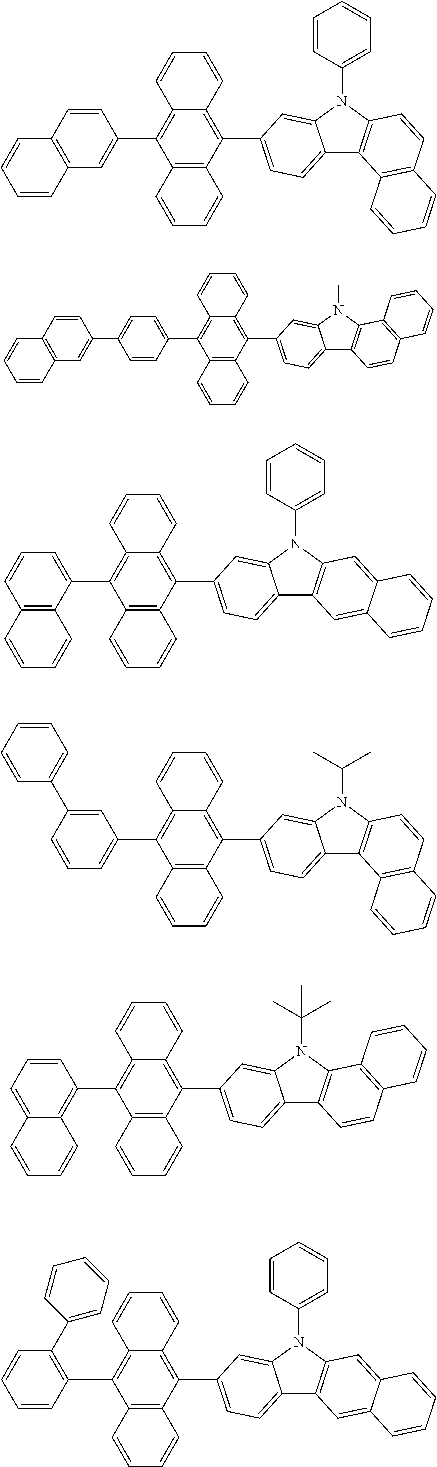 [SMILES: c1ccc(-n2c3cc(-c4c5ccccc5c(-c5ccc6ccccc6c5)c5ccccc45)ccc3c3c4ccccc4ccc32)cc1 ; Cn1c2cc(-c3c4ccccc4c(-c4ccc(-c5ccc6ccccc6c5)cc4)c4ccccc34)ccc2c2ccc3ccccc3c21 ; c1ccc(-n2c3cc(-c4c5ccccc5c(-c5cccc6ccccc56)c5ccccc45)ccc3c3cc4ccccc4cc32)cc1 ; CC(C)n1c2cc(-c3c4ccccc4c(-c4cccc(-c5ccccc5)c4)c4ccccc34)ccc2c2c3ccccc3ccc21 ; CC(C)(C)n1c2cc(-c3c4ccccc4c(-c4cccc5ccccc45)c4ccccc34)ccc2c2ccc3ccccc3c21 ; c1ccc(-c2ccccc2-c2c3ccccc3c(-c3ccc4c5cc6ccccc6cc5n(-c5ccccc5)c4c3)c3ccccc23)cc1]

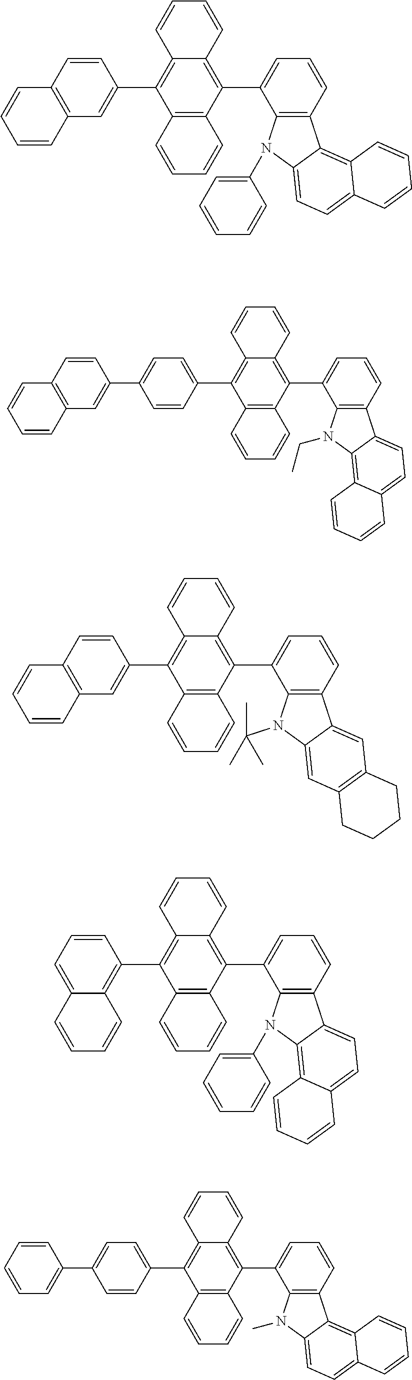 [SMILES: c1ccc(-n2c3ccc4ccccc4c3c3cccc(-c4c5ccccc5c(-c5ccc6ccccc6c5)c5ccccc45)c32)cc1 ; CCn1c2c(-c3c4ccccc4c(-c4ccc(-c5ccc6ccccc6c5)cc4)c4ccccc34)cccc2c2ccc3ccccc3c21 ; CC(C)(C)n1c2cc3c(cc2c2cccc(-c4c5ccccc5c(-c5ccc6ccccc6c5)c5ccccc45)c21)CCCC3 ; c1ccc(-n2c3c(-c4c5ccccc5c(-c5cccc6ccccc56)c5ccccc45)cccc3c3ccc4ccccc4c32)cc1 ; Cn1c2ccc3ccccc3c2c2cccc(-c3c4ccccc4c(-c4ccc(-c5ccccc5)cc4)c4ccccc34)c21]

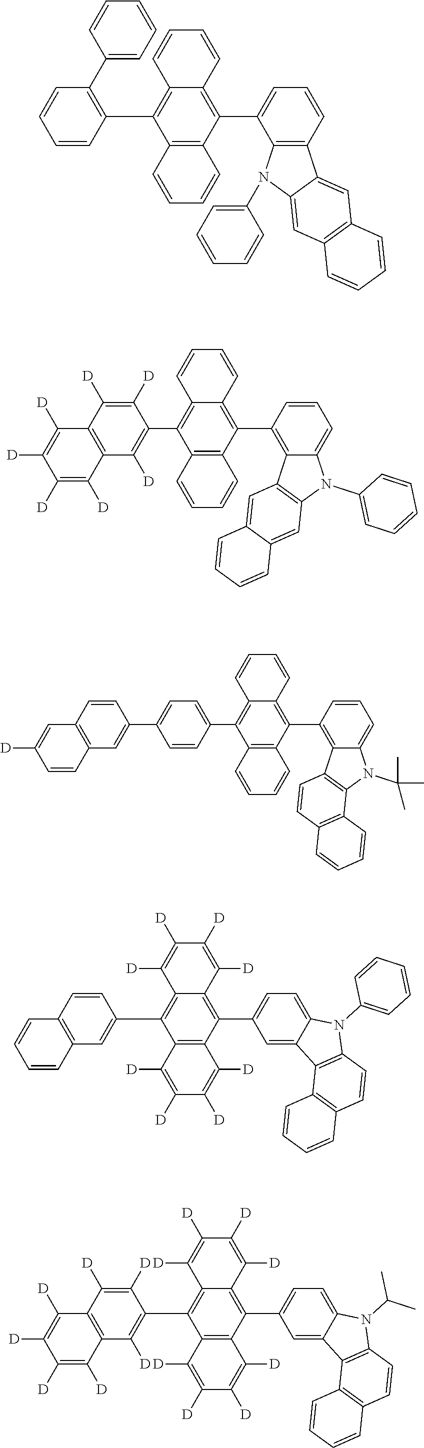

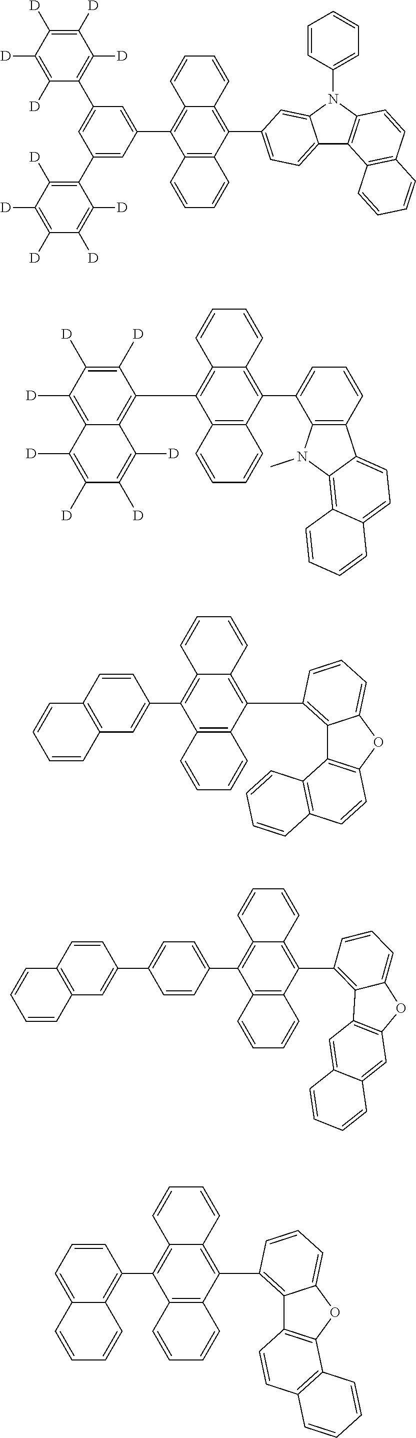 [SMILES: [2H]c1c([2H])c([2H])c(-c2cc(-c3c([2H])c([2H])c([2H])c([2H])c3[2H])cc(-c3c4ccccc4c(-c4ccc5c6c7ccccc7ccc6n(-c6ccccc6)c5c4)c4ccccc34)c2)c([2H])c1[2H] ; [2H]c1c([2H])c([2H])c2c(-c3c4ccccc4c(-c4cccc5c6ccc7ccccc7c6n(C)c45)c4ccccc34)c([2H])c([2H])c([2H])c2c1[2H] ; c1ccc2cc(-c3c4ccccc4c(-c4cccc5oc6ccc7ccccc7c6c45)c4ccccc34)ccc2c1 ; c1ccc2cc(-c3ccc(-c4c5ccccc5c(-c5cccc6oc7cc8ccccc8cc7c56)c5ccccc45)cc3)ccc2c1 ; c1ccc2c(-c3c4ccccc4c(-c4cccc5oc6c7ccccc7ccc6c45)c4ccccc34)cccc2c1]

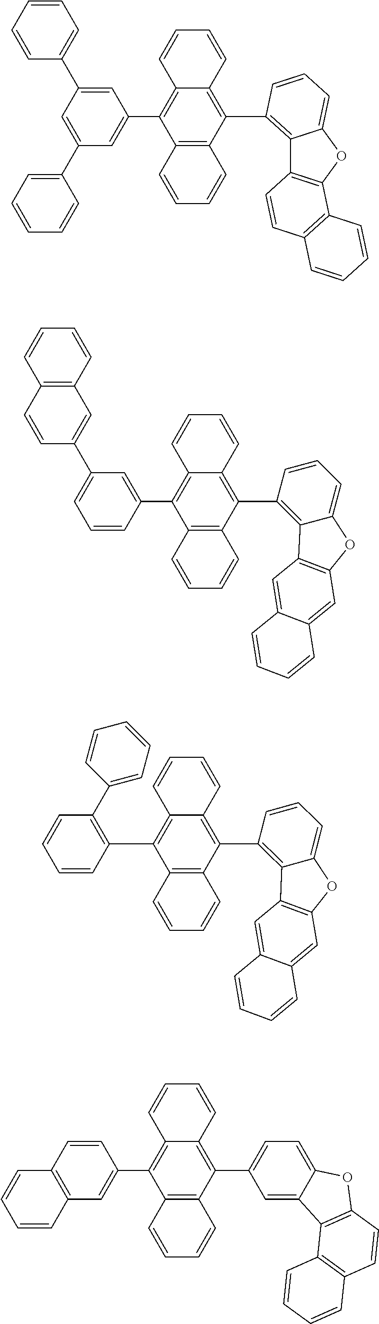 [SMILES: c1ccc(-c2cc(-c3ccccc3)cc(-c3c4ccccc4c(-c4cccc5oc6c7ccccc7ccc6c45)c4ccccc34)c2)cc1 ; c1cc(-c2ccc3ccccc3c2)cc(-c2c3ccccc3c(-c3cccc4oc5cc6ccccc6cc5c34)c3ccccc23)c1 ; c1ccc(-c2ccccc2-c2c3ccccc3c(-c3cccc4oc5cc6ccccc6cc5c34)c3ccccc23)cc1 ; c1ccc2cc(-c3c4ccccc4c(-c4ccc5oc6ccc7ccccc7c6c5c4)c4ccccc34)ccc2c1]

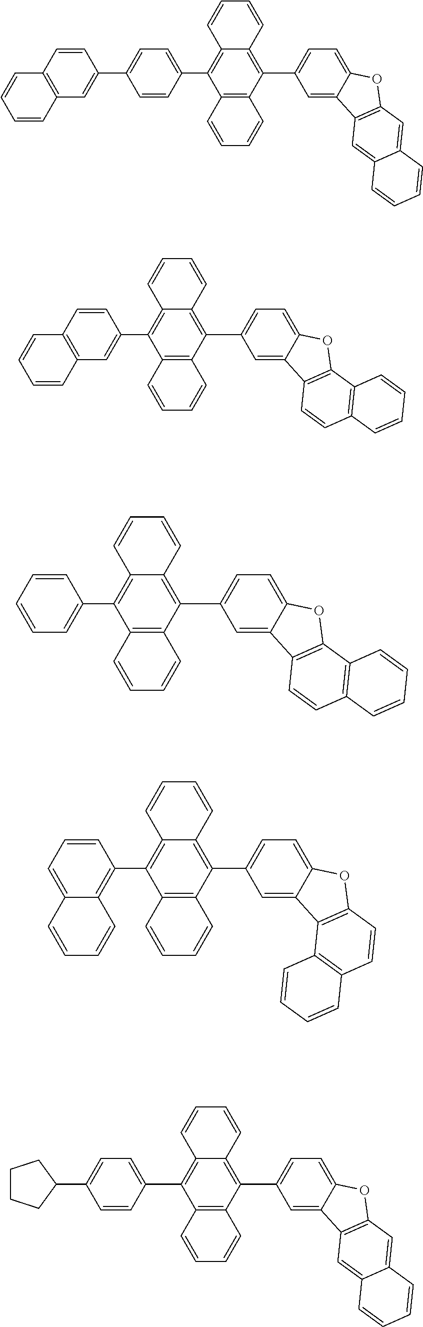 [SMILES: c1ccc2cc(-c3ccc(-c4c5ccccc5c(-c5ccc6oc7cc8ccccc8cc7c6c5)c5ccccc45)cc3)ccc2c1 ; c1ccc2cc(-c3c4ccccc4c(-c4ccc5oc6c7ccccc7ccc6c5c4)c4ccccc34)ccc2c1 ; c1ccc(-c2c3ccccc3c(-c3ccc4oc5c6ccccc6ccc5c4c3)c3ccccc23)cc1 ; c1ccc2c(-c3c4ccccc4c(-c4ccc5oc6ccc7ccccc7c6c5c4)c4ccccc34)cccc2c1 ; c1ccc2cc3c(cc2c1)oc1ccc(-c2c4ccccc4c(-c4ccc(C5CCCC5)cc4)c4ccccc24)cc13]

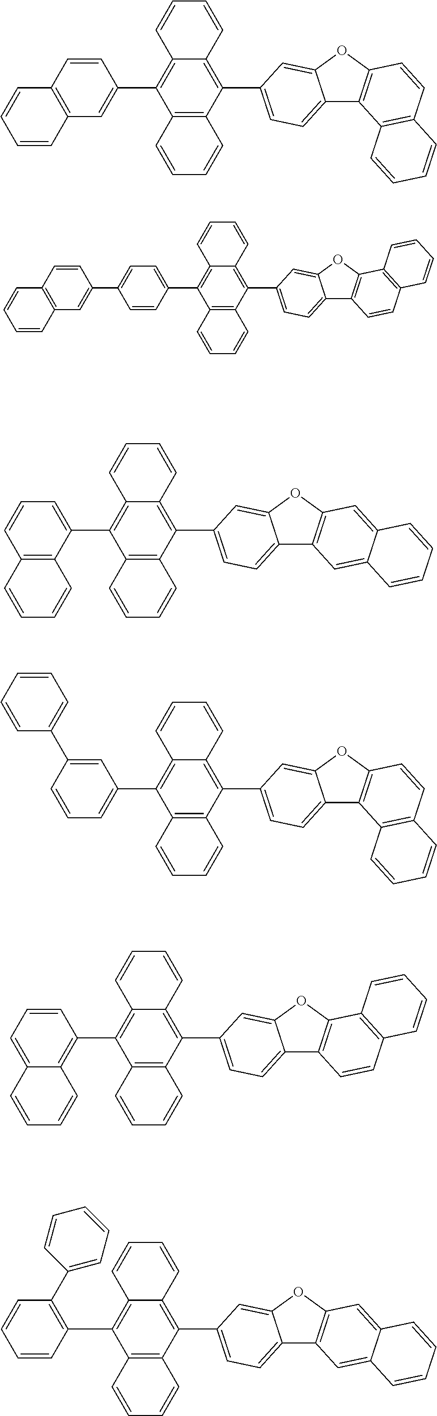 [SMILES: c1ccc2cc(-c3c4ccccc4c(-c4ccc5c(c4)oc4ccc6ccccc6c45)c4ccccc34)ccc2c1 ; c1ccc2cc(-c3ccc(-c4c5ccccc5c(-c5ccc6c(c5)oc5c7ccccc7ccc65)c5ccccc45)cc3)ccc2c1 ; c1ccc2cc3c(cc2c1)oc1cc(-c2c4ccccc4c(-c4cccc5ccccc45)c4ccccc24)ccc13 ; c1ccc(-c2cccc(-c3c4ccccc4c(-c4ccc5c(c4)oc4ccc6ccccc6c45)c4ccccc34)c2)cc1 ; c1ccc2c(-c3c4ccccc4c(-c4ccc5c(c4)oc4c6ccccc6ccc54)c4ccccc34)cccc2c1 ; c1ccc(-c2ccccc2-c2c3ccccc3c(-c3ccc4c(c3)oc3cc5ccccc5cc34)c3ccccc23)cc1]

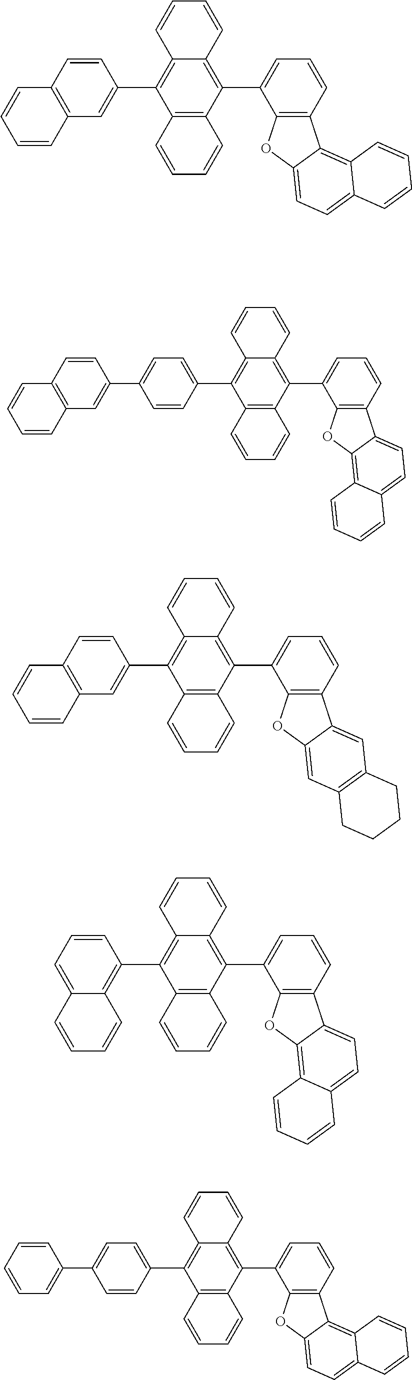 [SMILES: c1ccc2cc(-c3c4ccccc4c(-c4cccc5c4oc4ccc6ccccc6c45)c4ccccc34)ccc2c1 ; c1ccc2cc(-c3ccc(-c4c5ccccc5c(-c5cccc6c5oc5c7ccccc7ccc65)c5ccccc45)cc3)ccc2c1 ; c1ccc2cc(-c3c4ccccc4c(-c4cccc5c4oc4cc6c(cc45)CCCC6)c4ccccc34)ccc2c1 ; c1ccc2c(-c3c4ccccc4c(-c4cccc5c4oc4c6ccccc6ccc54)c4ccccc34)cccc2c1 ; c1ccc(-c2ccc(-c3c4ccccc4c(-c4cccc5c4oc4ccc6ccccc6c45)c4ccccc34)cc2)cc1]

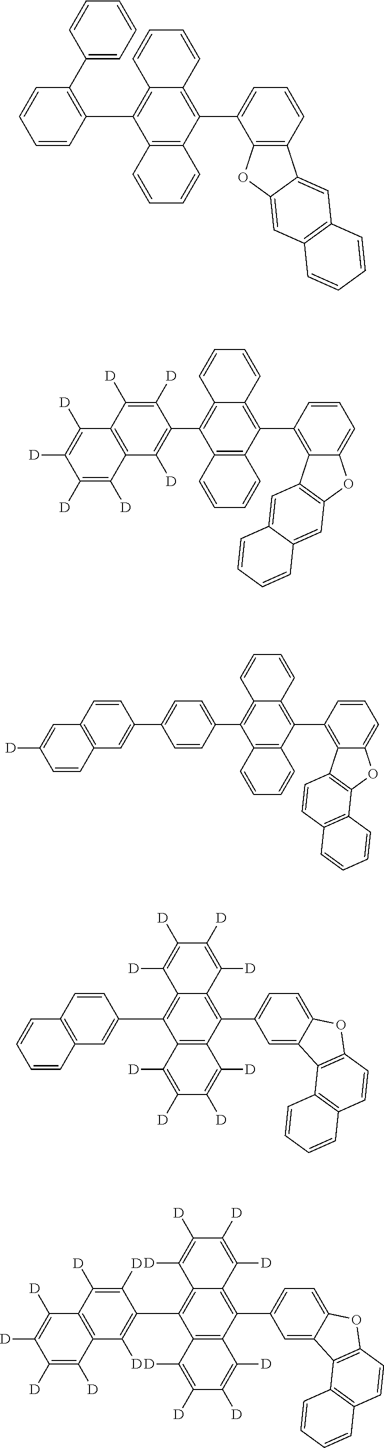

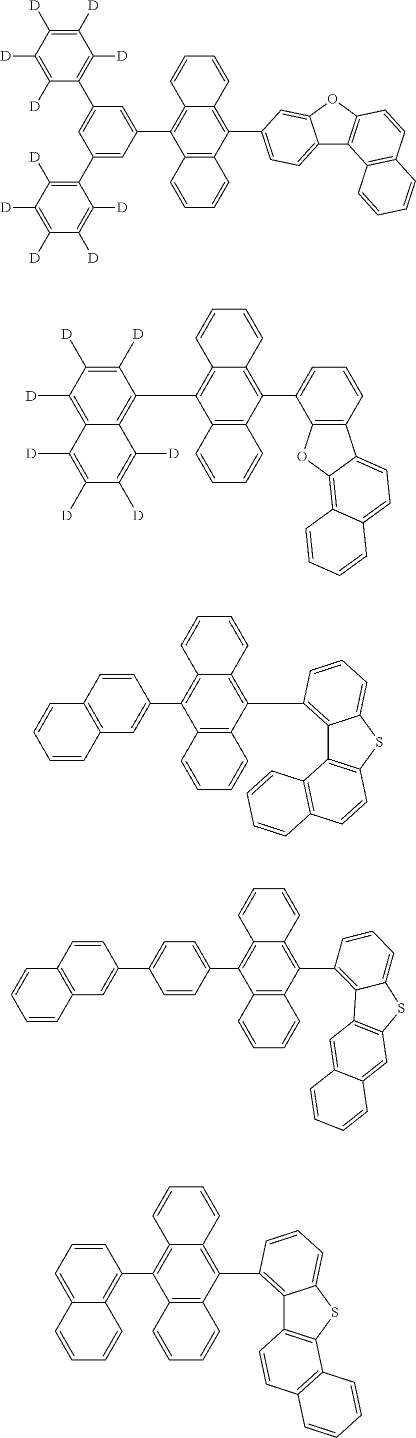 [SMILES: [2H]c1c([2H])c([2H])c(-c2cc(-c3c([2H])c([2H])c([2H])c([2H])c3[2H])cc(-c3c4ccccc4c(-c4ccc5c(c4)oc4ccc6ccccc6c45)c4ccccc34)c2)c([2H])c1[2H] ; [2H]c1c([2H])c([2H])c2c(-c3c4ccccc4c(-c4cccc5c4oc4c6ccccc6ccc54)c4ccccc34)c([2H])c([2H])c([2H])c2c1[2H] ; c1ccc2cc(-c3c4ccccc4c(-c4cccc5sc6ccc7ccccc7c6c45)c4ccccc34)ccc2c1 ; c1ccc2cc(-c3ccc(-c4c5ccccc5c(-c5cccc6sc7cc8ccccc8cc7c56)c5ccccc45)cc3)ccc2c1 ; c1ccc2c(-c3c4ccccc4c(-c4cccc5sc6c7ccccc7ccc6c45)c4ccccc34)cccc2c1]

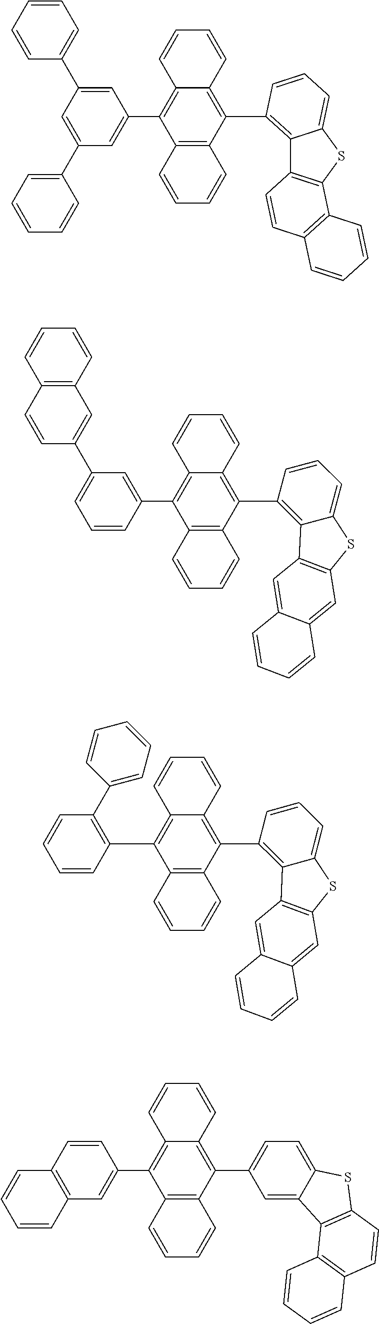 [SMILES: c1ccc(-c2cc(-c3ccccc3)cc(-c3c4ccccc4c(-c4cccc5sc6c7ccccc7ccc6c45)c4ccccc34)c2)cc1 ; c1cc(-c2ccc3ccccc3c2)cc(-c2c3ccccc3c(-c3cccc4sc5cc6ccccc6cc5c34)c3ccccc23)c1 ; c1ccc(-c2ccccc2-c2c3ccccc3c(-c3cccc4sc5cc6ccccc6cc5c34)c3ccccc23)cc1 ; c1ccc2cc(-c3c4ccccc4c(-c4ccc5sc6ccc7ccccc7c6c5c4)c4ccccc34)ccc2c1]

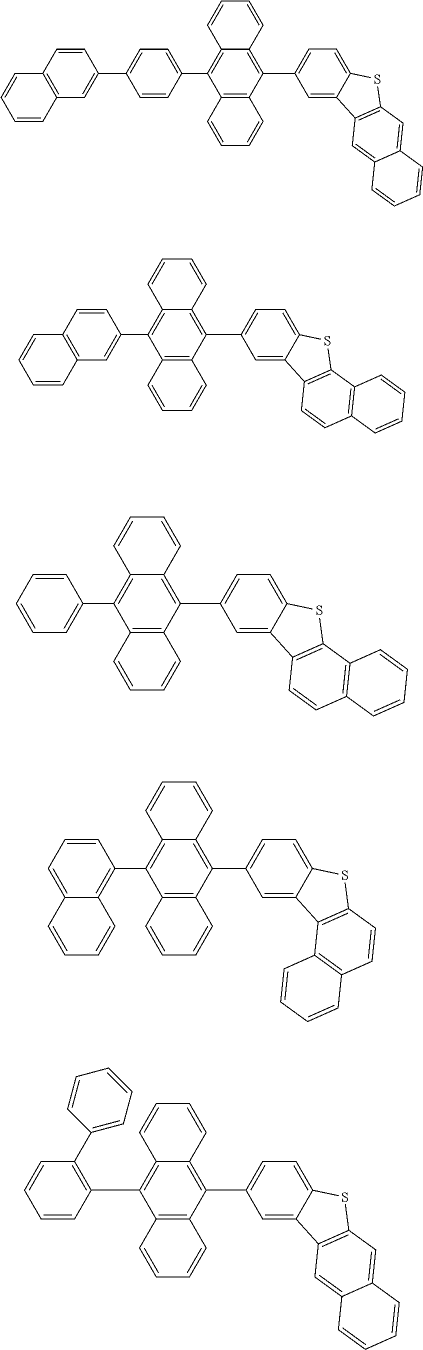 [SMILES: c1ccc2cc(-c3ccc(-c4c5ccccc5c(-c5ccc6sc7cc8ccccc8cc7c6c5)c5ccccc45)cc3)ccc2c1 ; c1ccc2cc(-c3c4ccccc4c(-c4ccc5sc6c7ccccc7ccc6c5c4)c4ccccc34)ccc2c1 ; c1ccc(-c2c3ccccc3c(-c3ccc4sc5c6ccccc6ccc5c4c3)c3ccccc23)cc1 ; c1ccc2c(-c3c4ccccc4c(-c4ccc5sc6ccc7ccccc7c6c5c4)c4ccccc34)cccc2c1 ; c1ccc(-c2ccccc2-c2c3ccccc3c(-c3ccc4sc5cc6ccccc6cc5c4c3)c3ccccc23)cc1]

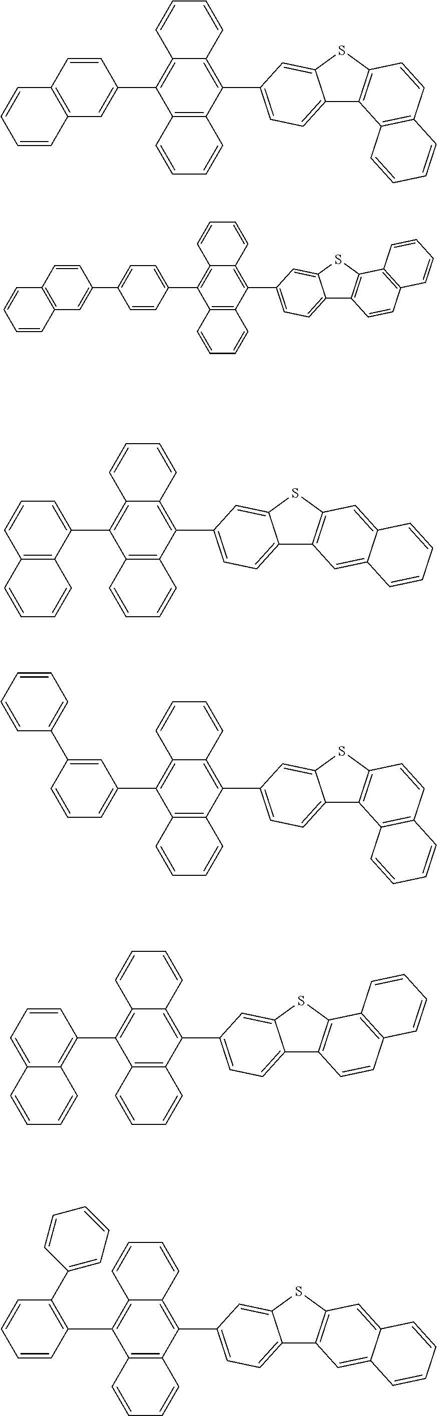 [SMILES: c1ccc2cc(-c3c4ccccc4c(-c4ccc5c(c4)sc4ccc6ccccc6c45)c4ccccc34)ccc2c1 ; c1ccc2cc(-c3ccc(-c4c5ccccc5c(-c5ccc6c(c5)sc5c7ccccc7ccc65)c5ccccc45)cc3)ccc2c1 ; c1ccc2cc3c(cc2c1)sc1cc(-c2c4ccccc4c(-c4cccc5ccccc45)c4ccccc24)ccc13 ; c1ccc(-c2cccc(-c3c4ccccc4c(-c4ccc5c(c4)sc4ccc6ccccc6c45)c4ccccc34)c2)cc1 ; c1ccc2c(-c3c4ccccc4c(-c4ccc5c(c4)sc4c6ccccc6ccc54)c4ccccc34)cccc2c1 ; c1ccc(-c2ccccc2-c2c3ccccc3c(-c3ccc4c(c3)sc3cc5ccccc5cc34)c3ccccc23)cc1]

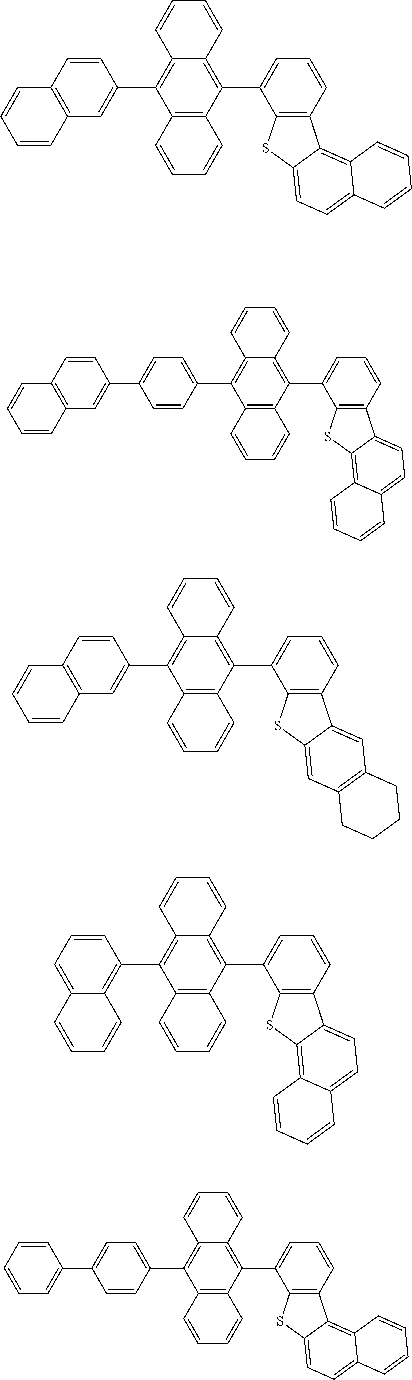 [SMILES: c1ccc2cc(-c3c4ccccc4c(-c4cccc5c4sc4ccc6ccccc6c45)c4ccccc34)ccc2c1 ; c1ccc2cc(-c3ccc(-c4c5ccccc5c(-c5cccc6c5sc5c7ccccc7ccc65)c5ccccc45)cc3)ccc2c1 ; c1ccc2cc(-c3c4ccccc4c(-c4cccc5c4sc4cc6c(cc45)CCCC6)c4ccccc34)ccc2c1 ; c1ccc2c(-c3c4ccccc4c(-c4cccc5c4sc4c6ccccc6ccc54)c4ccccc34)cccc2c1 ; c1ccc(-c2ccc(-c3c4ccccc4c(-c4cccc5c4sc4ccc6ccccc6c45)c4ccccc34)cc2)cc1]

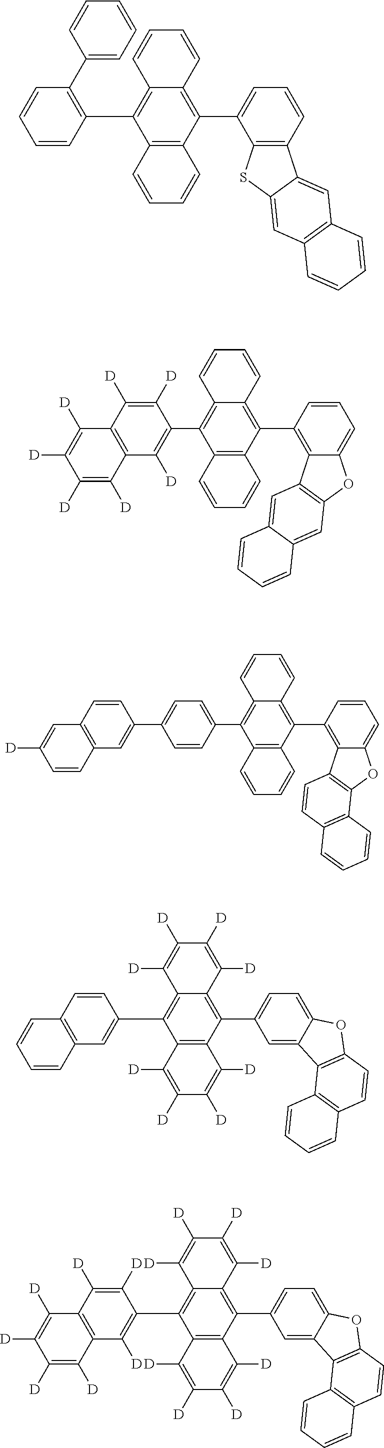

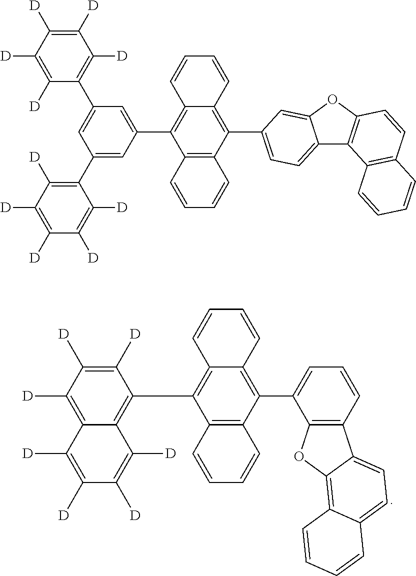 [SMILES: [2H]c1c([2H])c([2H])c(-c2cc(-c3c([2H])c([2H])c([2H])c([2H])c3[2H])cc(-c3c4ccccc4c(-c4ccc5c(c4)oc4ccc6ccccc6c45)c4ccccc34)c2)c([2H])c1[2H] ; [2H]c1c([2H])c([2H])c2c(-c3c4ccccc4c(-c4cccc5c4oc4c6ccccc6ccc54)c4ccccc34)c([2H])c([2H])c([2H])c2c1[2H]]

Optionally, the second compound is selected from:

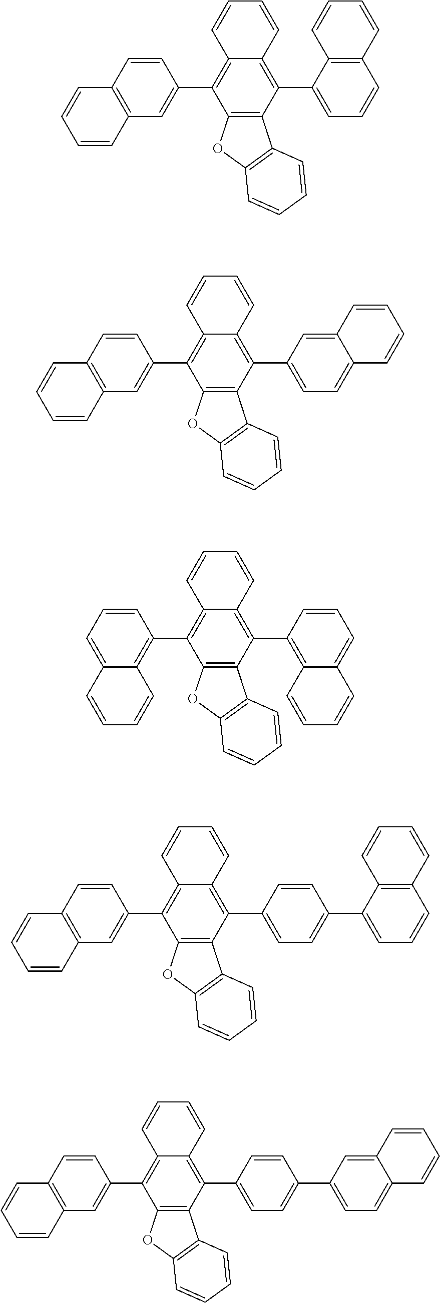 [SMILES: c1ccc2cc(-c3c4ccccc4c(-c4cccc5ccccc45)c4c3oc3ccccc34)ccc2c1 ; c1ccc2cc(-c3c4ccccc4c(-c4ccc5ccccc5c4)c4c3oc3ccccc34)ccc2c1 ; c1ccc2c(-c3c4ccccc4c(-c4cccc5ccccc45)c4c3oc3ccccc34)cccc2c1 ; c1ccc2cc(-c3c4ccccc4c(-c4ccc(-c5cccc6ccccc56)cc4)c4c3oc3ccccc34)ccc2c1 ; c1ccc2cc(-c3ccc(-c4c5ccccc5c(-c5ccc6ccccc6c5)c5oc6ccccc6c45)cc3)ccc2c1]

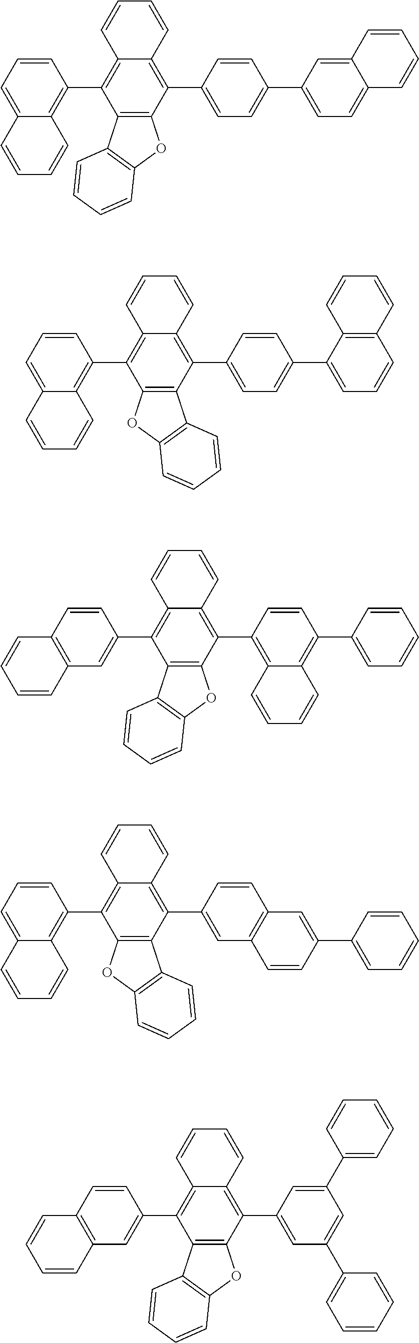 [SMILES: c1ccc2cc(-c3ccc(-c4c5ccccc5c(-c5cccc6ccccc56)c5c4oc4ccccc45)cc3)ccc2c1 ; c1ccc2c(-c3ccc(-c4c5ccccc5c(-c5cccc6ccccc56)c5oc6ccccc6c45)cc3)cccc2c1 ; c1ccc(-c2ccc(-c3c4ccccc4c(-c4ccc5ccccc5c4)c4c3oc3ccccc34)c3ccccc23)cc1 ; c1ccc(-c2ccc3cc(-c4c5ccccc5c(-c5cccc6ccccc56)c5oc6ccccc6c45)ccc3c2)cc1 ; c1ccc(-c2cc(-c3ccccc3)cc(-c3c4ccccc4c(-c4ccc5ccccc5c4)c4c3oc3ccccc34)c2)cc1]

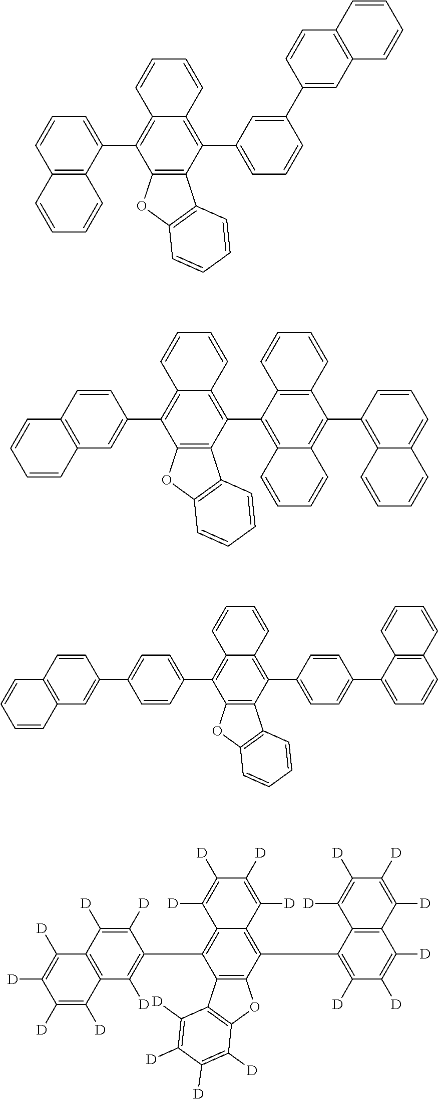 [SMILES: c1cc(-c2ccc3ccccc3c2)cc(-c2c3ccccc3c(-c3cccc4ccccc34)c3oc4ccccc4c23)c1 ; c1ccc2cc(-c3c4ccccc4c(-c4c5ccccc5c(-c5cccc6ccccc56)c5ccccc45)c4c3oc3ccccc34)ccc2c1 ; c1ccc2cc(-c3ccc(-c4c5ccccc5c(-c5ccc(-c6cccc7ccccc67)cc5)c5c4oc4ccccc45)cc3)ccc2c1 ; [2H]c1c([2H])c([2H])c2c(oc3c(-c4c([2H])c([2H])c([2H])c5c([2H])c([2H])c([2H])c([2H])c45)c4c([2H])c([2H])c([2H])c([2H])c4c(-c4c([2H])c([2H])c5c([2H])c([2H])c([2H])c([2H])c5c4[2H])c32)c1[2H]]

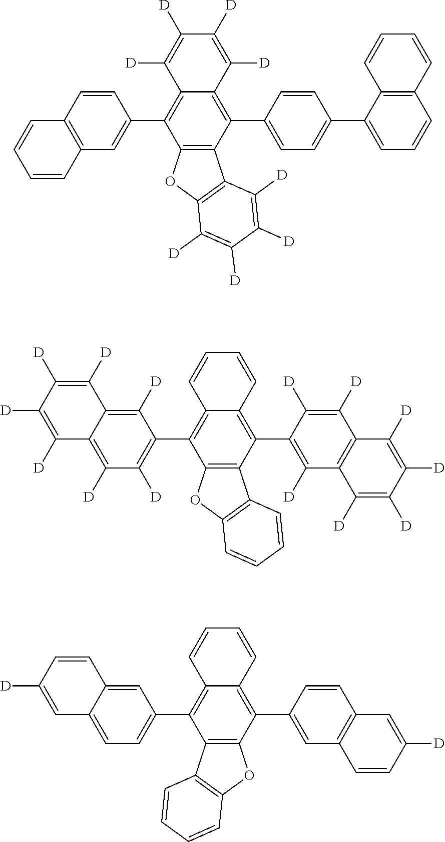 [SMILES: [2H]c1c([2H])c([2H])c2c(oc3c(-c4ccc5ccccc5c4)c4c([2H])c([2H])c([2H])c([2H])c4c(-c4ccc(-c5cccc6ccccc56)cc4)c32)c1[2H] ; [2H]c1c([2H])c([2H])c2c([2H])c(-c3c4ccccc4c(-c4c([2H])c([2H])c5c([2H])c([2H])c([2H])c([2H])c5c4[2H])c4c3oc3ccccc34)c([2H])c([2H])c2c1[2H] ; [2H]c1ccc2cc(-c3c4ccccc4c(-c4ccc5cc([2H])ccc5c4)c4c3oc3ccccc34)ccc2c1]

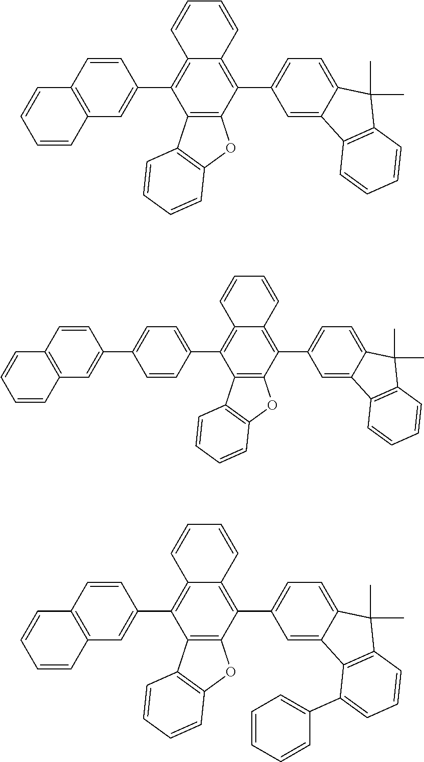 [SMILES: CC1(C)c2ccccc2-c2cc(-c3c4ccccc4c(-c4ccc5ccccc5c4)c4c3oc3ccccc34)ccc21 ; CC1(C)c2ccccc2-c2cc(-c3c4ccccc4c(-c4ccc(-c5ccc6ccccc6c5)cc4)c4c3oc3ccccc34)ccc21 ; CC1(C)c2ccc(-c3c4ccccc4c(-c4ccc5ccccc5c4)c4c3oc3ccccc34)cc2-c2c(-c3ccccc3)cccc21]

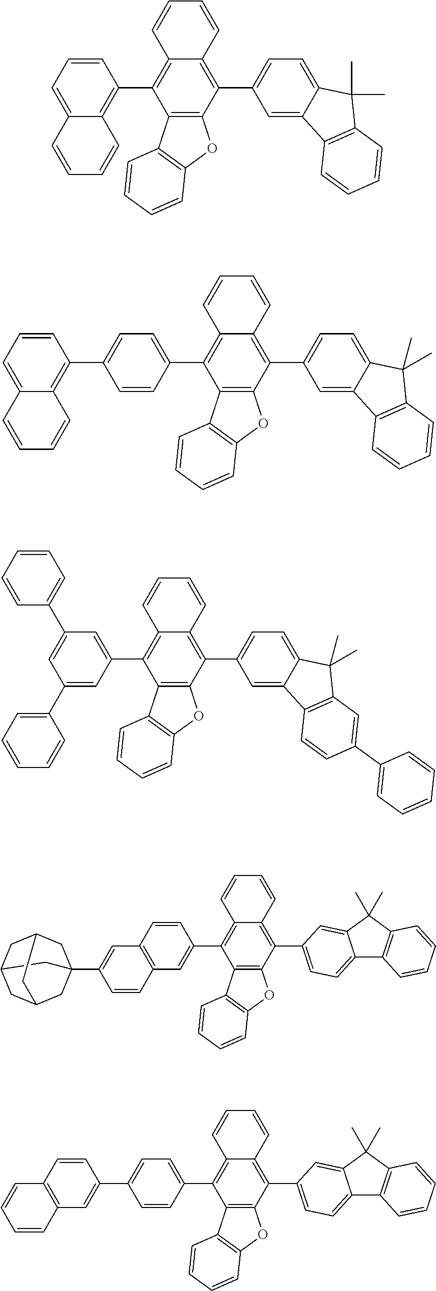 [SMILES: CC1(C)c2ccccc2-c2cc(-c3c4ccccc4c(-c4cccc5ccccc45)c4c3oc3ccccc34)ccc21 ; CC1(C)c2ccccc2-c2cc(-c3c4ccccc4c(-c4ccc(-c5cccc6ccccc56)cc4)c4c3oc3ccccc34)ccc21 ; CC1(C)c2ccc(-c3c4ccccc4c(-c4cc(-c5ccccc5)cc(-c5ccccc5)c4)c4c3oc3ccccc34)cc2-c2ccc(-c3ccccc3)cc21 ; CC1(C)c2ccccc2-c2ccc(-c3c4ccccc4c(-c4ccc5cc(C67CC8CC(CC(C8)C6)C7)ccc5c4)c4c3oc3ccccc34)cc21 ; CC1(C)c2ccccc2-c2ccc(-c3c4ccccc4c(-c4ccc(-c5ccc6ccccc6c5)cc4)c4c3oc3ccccc34)cc21]

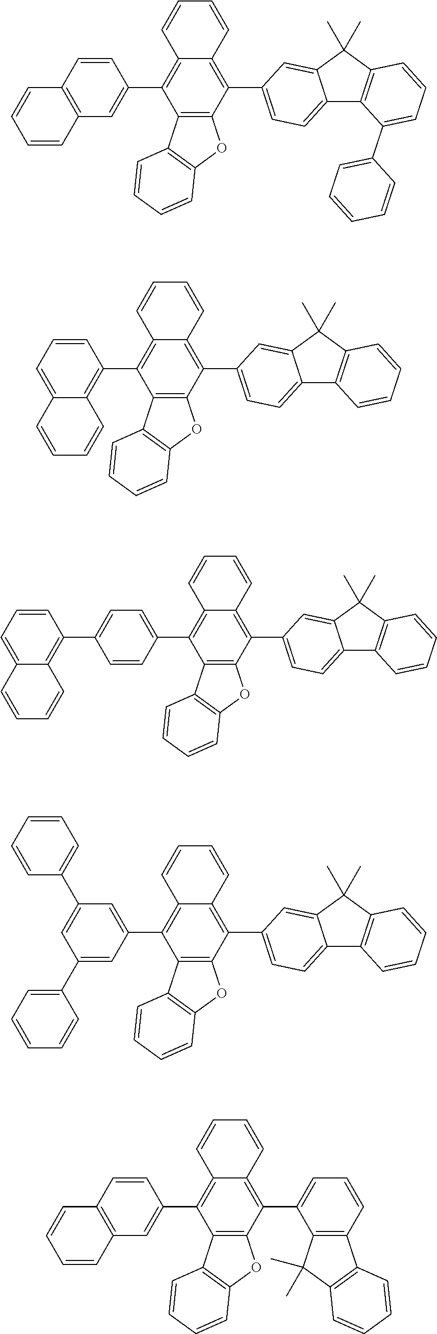 [SMILES: CC1(C)c2cc(-c3c4ccccc4c(-c4ccc5ccccc5c4)c4c3oc3ccccc34)ccc2-c2c(-c3ccccc3)cccc21 ; CC1(C)c2ccccc2-c2ccc(-c3c4ccccc4c(-c4cccc5ccccc45)c4c3oc3ccccc34)cc21 ; CC1(C)c2ccccc2-c2ccc(-c3c4ccccc4c(-c4ccc(-c5cccc6ccccc56)cc4)c4c3oc3ccccc34)cc21 ; CC1(C)c2ccccc2-c2ccc(-c3c4ccccc4c(-c4cc(-c5ccccc5)cc(-c5ccccc5)c4)c4c3oc3ccccc34)cc21 ; CC1(C)c2ccccc2-c2cccc(-c3c4ccccc4c(-c4ccc5ccccc5c4)c4c3oc3ccccc34)c21]

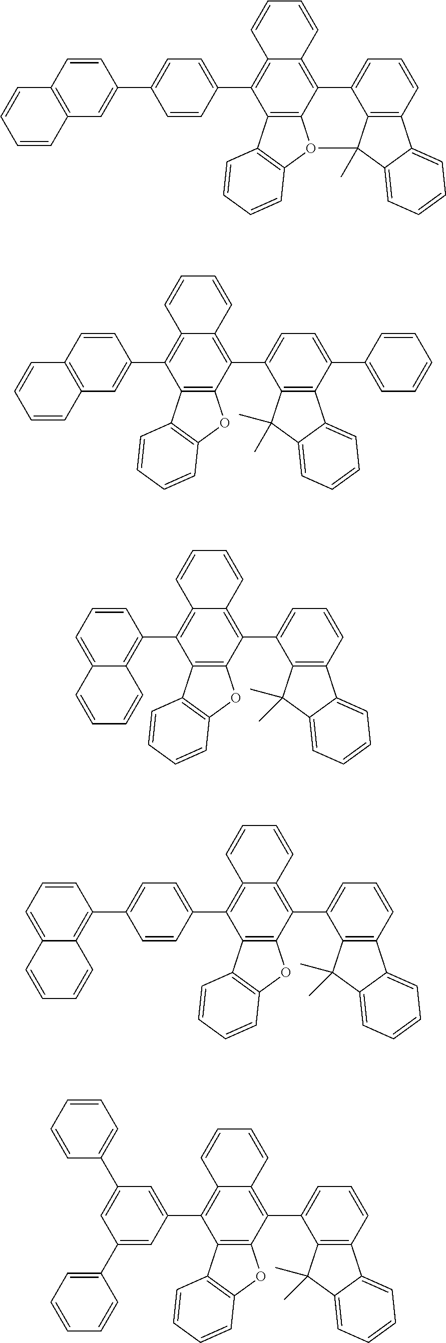

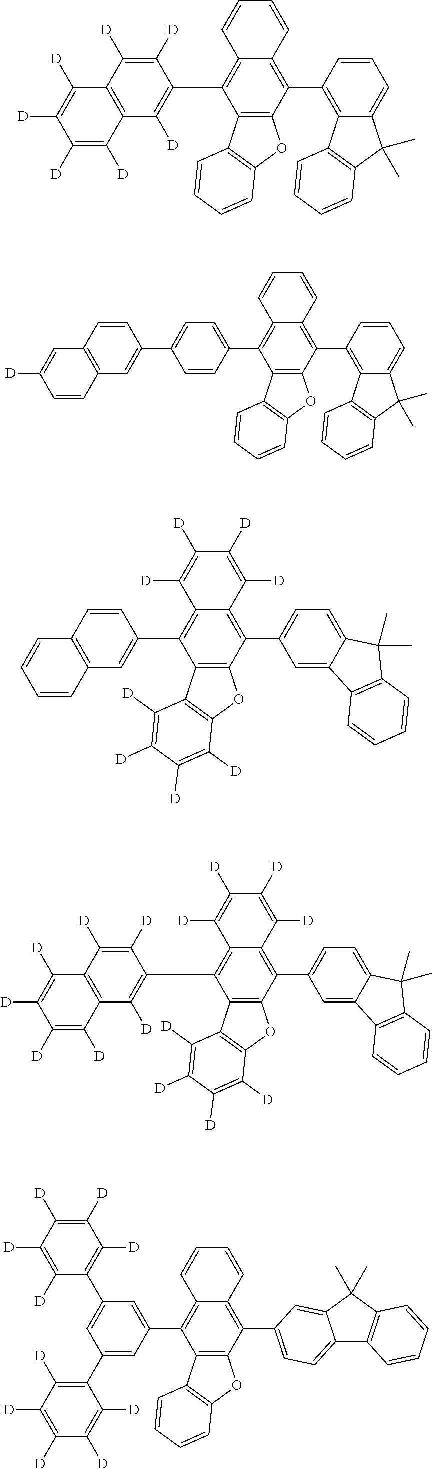

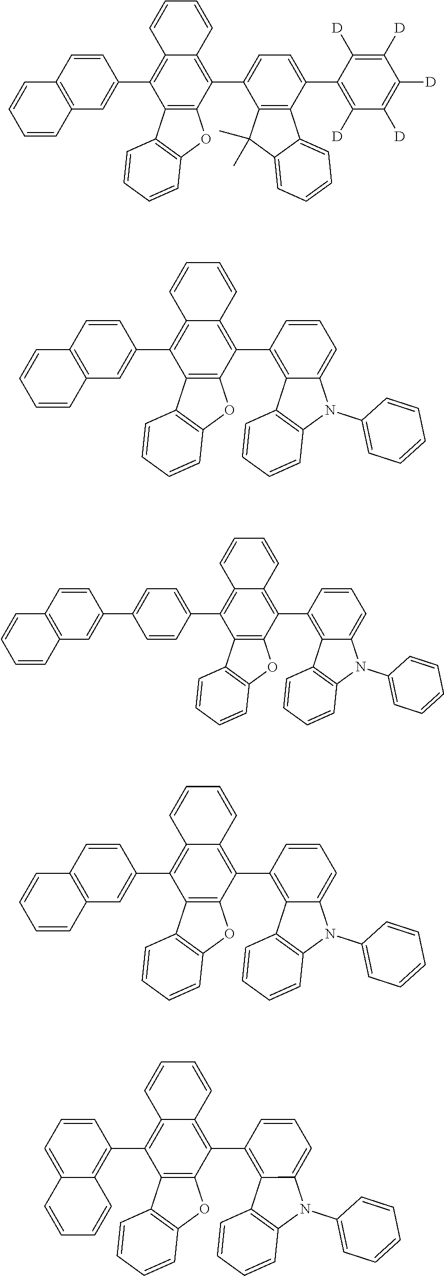 [SMILES: [2H]c1c([2H])c([2H])c(-c2ccc(-c3c4ccccc4c(-c4ccc5ccccc5c4)c4c3oc3ccccc34)c3c2-c2ccccc2C3(C)C)c([2H])c1[2H] ; c1ccc(-n2c3ccccc3c3c(-c4c5ccccc5c(-c5ccc6ccccc6c5)c5c4oc4ccccc45)cccc32)cc1 ; c1ccc(-n2c3ccccc3c3c(-c4c5ccccc5c(-c5ccc(-c6ccc7ccccc7c6)cc5)c5c4oc4ccccc45)cccc32)cc1 ; c1ccc(-n2c3ccccc3c3c(-c4c5ccccc5c(-c5ccc6ccccc6c5)c5c4oc4ccccc45)cccc32)cc1 ; c1ccc(-n2c3ccccc3c3c(-c4c5ccccc5c(-c5cccc6ccccc56)c5c4oc4ccccc45)cccc32)cc1]

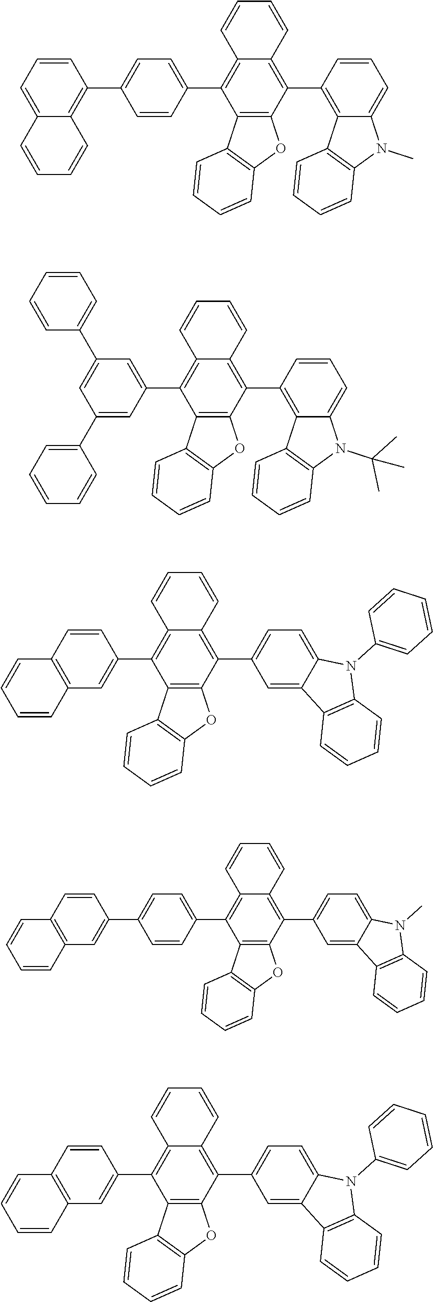 [SMILES: Cn1c2ccccc2c2c(-c3c4ccccc4c(-c4ccc(-c5cccc6ccccc56)cc4)c4c3oc3ccccc34)cccc21 ; CC(C)(C)n1c2ccccc2c2c(-c3c4ccccc4c(-c4cc(-c5ccccc5)cc(-c5ccccc5)c4)c4c3oc3ccccc34)cccc21 ; c1ccc(-n2c3ccccc3c3cc(-c4c5ccccc5c(-c5ccc6ccccc6c5)c5c4oc4ccccc45)ccc32)cc1 ; Cn1c2ccccc2c2cc(-c3c4ccccc4c(-c4ccc(-c5ccc6ccccc6c5)cc4)c4c3oc3ccccc34)ccc21 ; c1ccc(-n2c3ccccc3c3cc(-c4c5ccccc5c(-c5ccc6ccccc6c5)c5c4oc4ccccc45)ccc32)cc1]

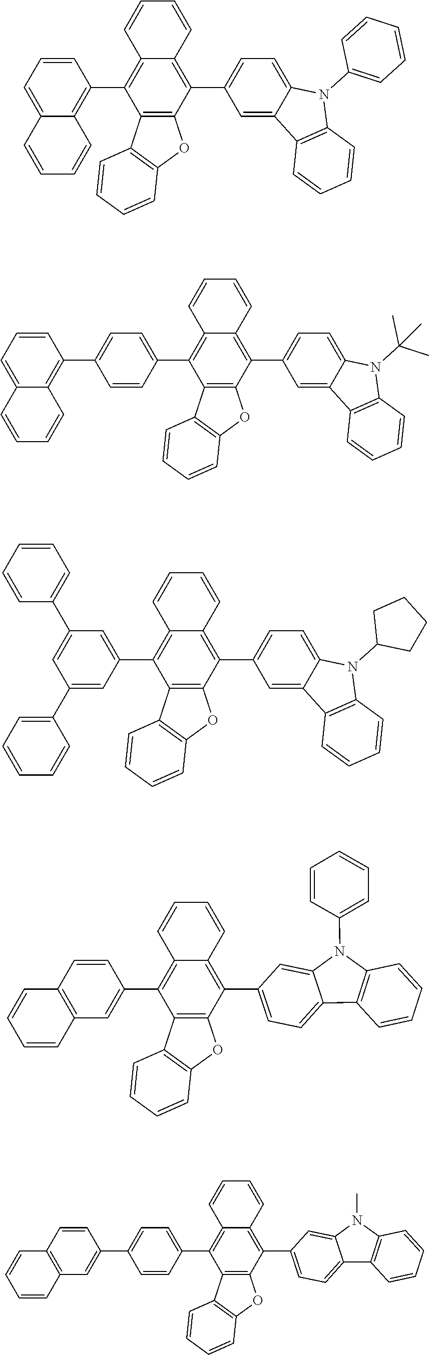 [SMILES: c1ccc(-n2c3ccccc3c3cc(-c4c5ccccc5c(-c5cccc6ccccc56)c5c4oc4ccccc45)ccc32)cc1 ; CC(C)(C)n1c2ccccc2c2cc(-c3c4ccccc4c(-c4ccc(-c5cccc6ccccc56)cc4)c4c3oc3ccccc34)ccc21 ; c1ccc(-c2cc(-c3ccccc3)cc(-c3c4ccccc4c(-c4ccc5c(c4)c4ccccc4n5C4CCCC4)c4oc5ccccc5c34)c2)cc1 ; c1ccc(-n2c3ccccc3c3ccc(-c4c5ccccc5c(-c5ccc6ccccc6c5)c5c4oc4ccccc45)cc32)cc1 ; Cn1c2ccccc2c2ccc(-c3c4ccccc4c(-c4ccc(-c5ccc6ccccc6c5)cc4)c4c3oc3ccccc34)cc21]

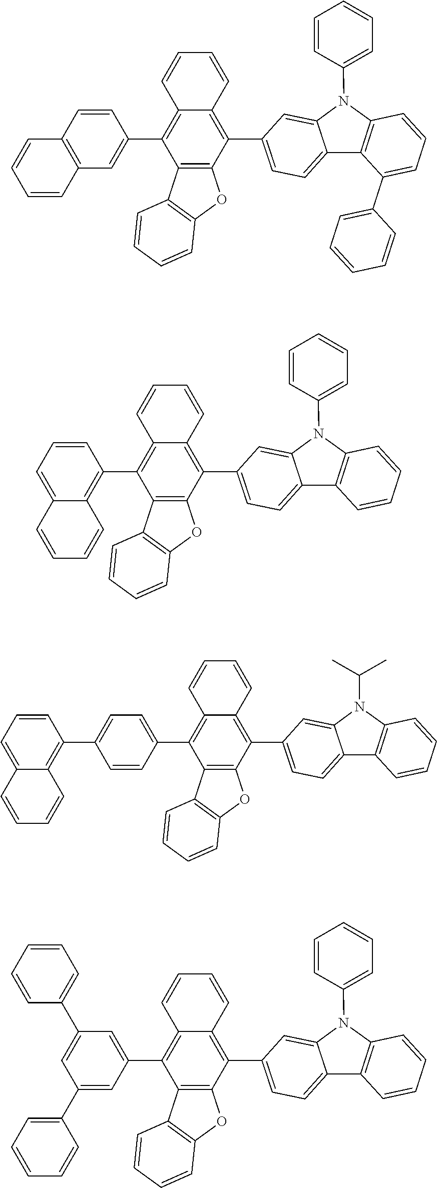 [SMILES: c1ccc(-c2cccc3c2c2ccc(-c4c5ccccc5c(-c5ccc6ccccc6c5)c5c4oc4ccccc45)cc2n3-c2ccccc2)cc1 ; c1ccc(-n2c3ccccc3c3ccc(-c4c5ccccc5c(-c5cccc6ccccc56)c5c4oc4ccccc45)cc32)cc1 ; CC(C)n1c2ccccc2c2ccc(-c3c4ccccc4c(-c4ccc(-c5cccc6ccccc56)cc4)c4c3oc3ccccc34)cc21 ; c1ccc(-c2cc(-c3ccccc3)cc(-c3c4ccccc4c(-c4ccc5c6ccccc6n(-c6ccccc6)c5c4)c4oc5ccccc5c34)c2)cc1]

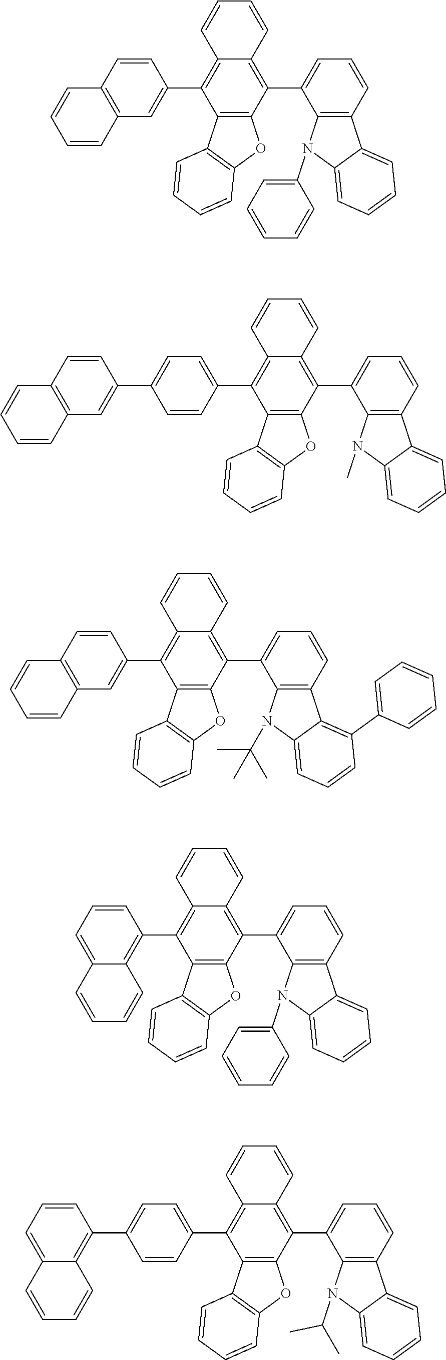 [SMILES: c1ccc(-n2c3ccccc3c3cccc(-c4c5ccccc5c(-c5ccc6ccccc6c5)c5c4oc4ccccc45)c32)cc1 ; Cn1c2ccccc2c2cccc(-c3c4ccccc4c(-c4ccc(-c5ccc6ccccc6c5)cc4)c4c3oc3ccccc34)c21 ; CC(C)(C)n1c2cccc(-c3ccccc3)c2c2cccc(-c3c4ccccc4c(-c4ccc5ccccc5c4)c4c3oc3ccccc34)c21 ; c1ccc(-n2c3ccccc3c3cccc(-c4c5ccccc5c(-c5cccc6ccccc56)c5c4oc4ccccc45)c32)cc1 ; CC(C)n1c2ccccc2c2cccc(-c3c4ccccc4c(-c4ccc(-c5cccc6ccccc56)cc4)c4c3oc3ccccc34)c21]

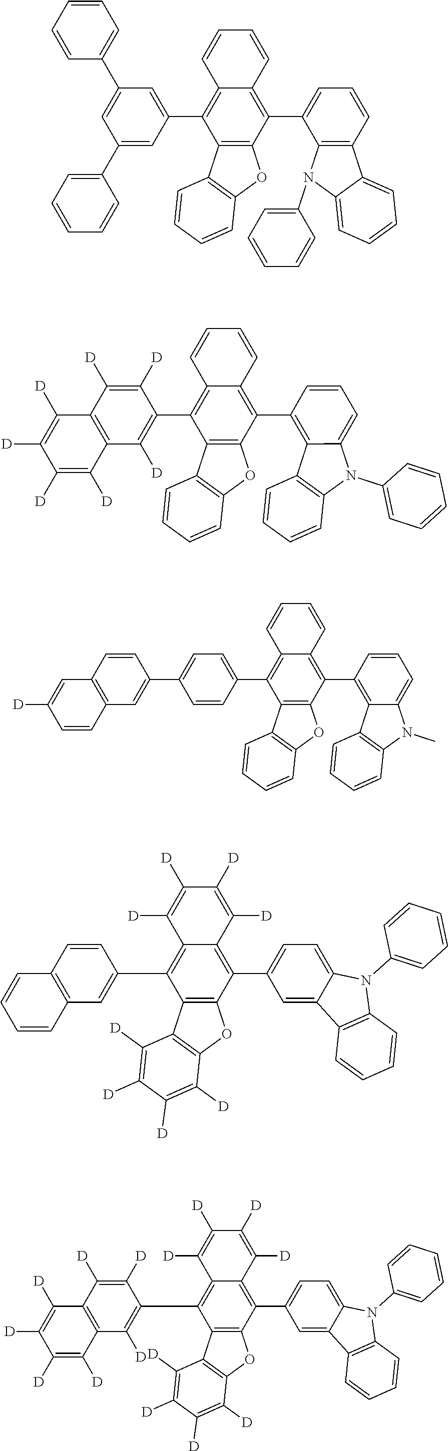

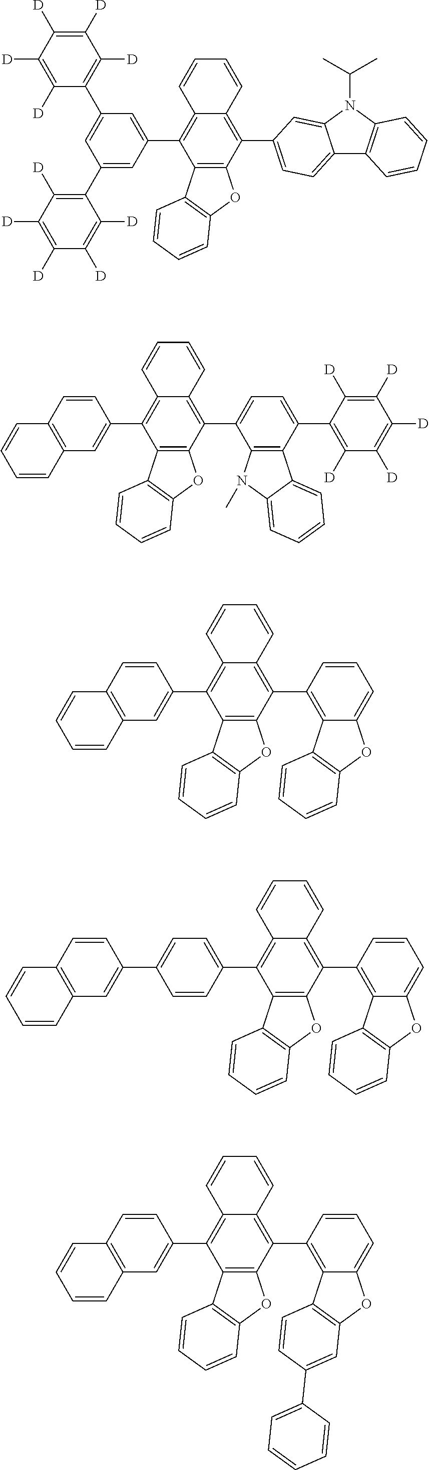 [SMILES: [2H]c1c([2H])c([2H])c(-c2cc(-c3c([2H])c([2H])c([2H])c([2H])c3[2H])cc(-c3c4ccccc4c(-c4ccc5c6ccccc6n(C(C)C)c5c4)c4oc5ccccc5c34)c2)c([2H])c1[2H] ; [2H]c1c([2H])c([2H])c(-c2ccc(-c3c4ccccc4c(-c4ccc5ccccc5c4)c4c3oc3ccccc34)c3c2c2ccccc2n3C)c([2H])c1[2H] ; c1ccc2cc(-c3c4ccccc4c(-c4cccc5oc6ccccc6c45)c4oc5ccccc5c34)ccc2c1 ; c1ccc2cc(-c3ccc(-c4c5ccccc5c(-c5cccc6oc7ccccc7c56)c5oc6ccccc6c45)cc3)ccc2c1 ; c1ccc(-c2ccc3c(c2)oc2cccc(-c4c5ccccc5c(-c5ccc6ccccc6c5)c5c4oc4ccccc45)c23)cc1]

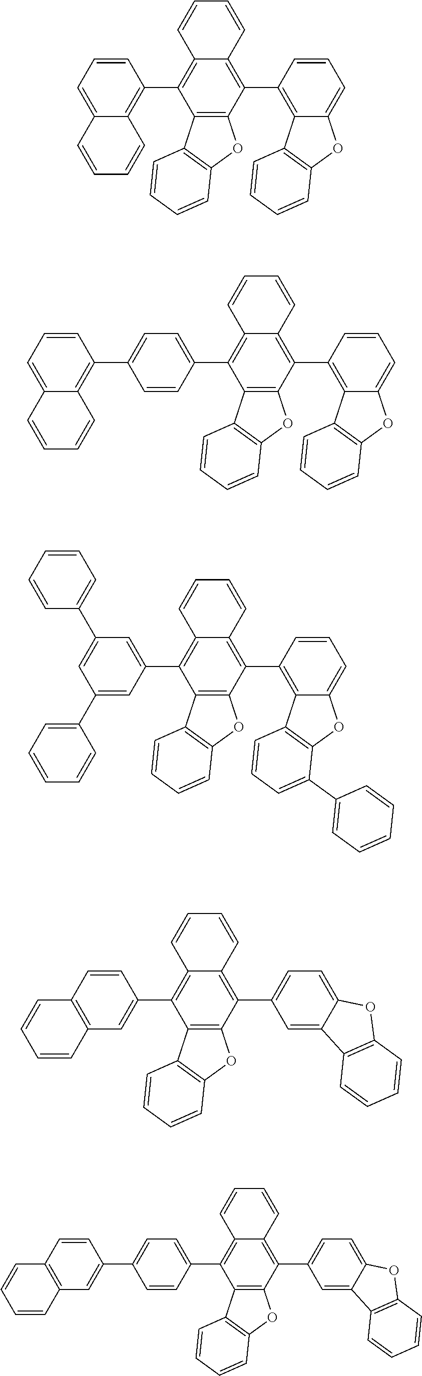 [SMILES: c1ccc2c(-c3c4ccccc4c(-c4cccc5oc6ccccc6c45)c4oc5ccccc5c34)cccc2c1 ; c1ccc2c(-c3ccc(-c4c5ccccc5c(-c5cccc6oc7ccccc7c56)c5oc6ccccc6c45)cc3)cccc2c1 ; c1ccc(-c2cc(-c3ccccc3)cc(-c3c4ccccc4c(-c4cccc5oc6c(-c7ccccc7)cccc6c45)c4oc5ccccc5c34)c2)cc1 ; c1ccc2cc(-c3c4ccccc4c(-c4ccc5oc6ccccc6c5c4)c4oc5ccccc5c34)ccc2c1 ; c1ccc2cc(-c3ccc(-c4c5ccccc5c(-c5ccc6oc7ccccc7c6c5)c5oc6ccccc6c45)cc3)ccc2c1]

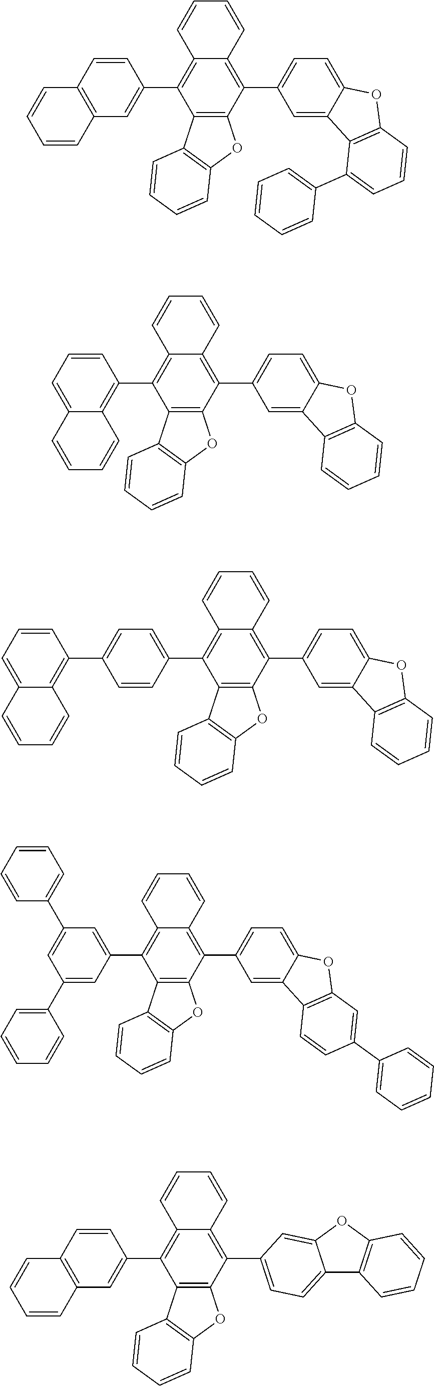 [SMILES: c1ccc(-c2cccc3oc4ccc(-c5c6ccccc6c(-c6ccc7ccccc7c6)c6c5oc5ccccc56)cc4c23)cc1 ; c1ccc2c(-c3c4ccccc4c(-c4ccc5oc6ccccc6c5c4)c4oc5ccccc5c34)cccc2c1 ; c1ccc2c(-c3ccc(-c4c5ccccc5c(-c5ccc6oc7ccccc7c6c5)c5oc6ccccc6c45)cc3)cccc2c1 ; c1ccc(-c2cc(-c3ccccc3)cc(-c3c4ccccc4c(-c4ccc5oc6cc(-c7ccccc7)ccc6c5c4)c4oc5ccccc5c34)c2)cc1 ; c1ccc2cc(-c3c4ccccc4c(-c4ccc5c(c4)oc4ccccc45)c4oc5ccccc5c34)ccc2c1]

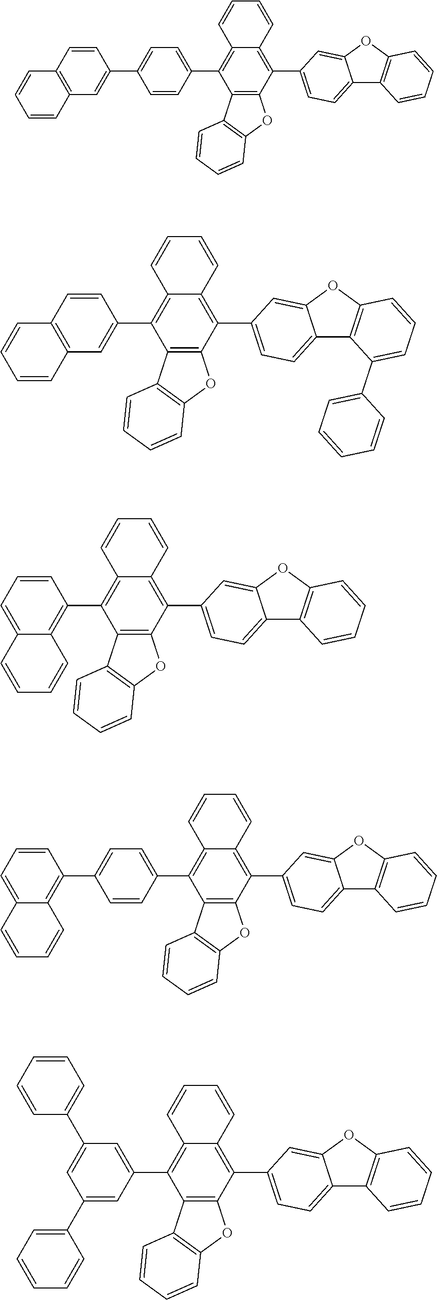 [SMILES: c1ccc2cc(-c3ccc(-c4c5ccccc5c(-c5ccc6c(c5)oc5ccccc56)c5oc6ccccc6c45)cc3)ccc2c1 ; c1ccc(-c2cccc3oc4cc(-c5c6ccccc6c(-c6ccc7ccccc7c6)c6c5oc5ccccc56)ccc4c23)cc1 ; c1ccc2c(-c3c4ccccc4c(-c4ccc5c(c4)oc4ccccc45)c4oc5ccccc5c34)cccc2c1 ; c1ccc2c(-c3ccc(-c4c5ccccc5c(-c5ccc6c(c5)oc5ccccc56)c5oc6ccccc6c45)cc3)cccc2c1 ; c1ccc(-c2cc(-c3ccccc3)cc(-c3c4ccccc4c(-c4ccc5c(c4)oc4ccccc45)c4oc5ccccc5c34)c2)cc1]

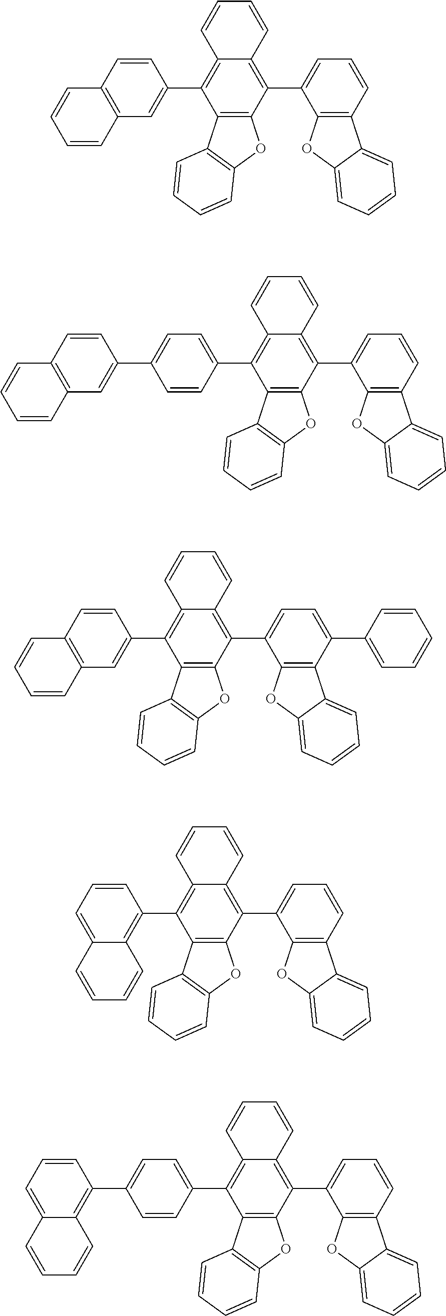 [SMILES: c1ccc2cc(-c3c4ccccc4c(-c4cccc5c4oc4ccccc45)c4oc5ccccc5c34)ccc2c1 ; c1ccc2cc(-c3ccc(-c4c5ccccc5c(-c5cccc6c5oc5ccccc56)c5oc6ccccc6c45)cc3)ccc2c1 ; c1ccc(-c2ccc(-c3c4ccccc4c(-c4ccc5ccccc5c4)c4c3oc3ccccc34)c3oc4ccccc4c23)cc1 ; c1ccc2c(-c3c4ccccc4c(-c4cccc5c4oc4ccccc45)c4oc5ccccc5c34)cccc2c1 ; c1ccc2c(-c3ccc(-c4c5ccccc5c(-c5cccc6c5oc5ccccc56)c5oc6ccccc6c45)cc3)cccc2c1]

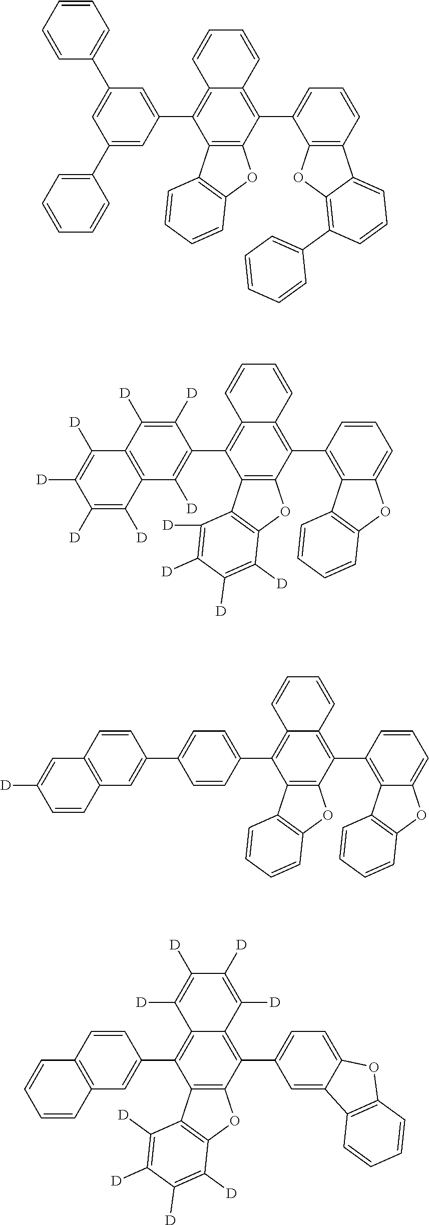 [SMILES: c1ccc(-c2cc(-c3ccccc3)cc(-c3c4ccccc4c(-c4cccc5c4oc4c(-c6ccccc6)cccc45)c4oc5ccccc5c34)c2)cc1 ; [2H]c1c([2H])c([2H])c2c(oc3c(-c4cccc5oc6ccccc6c45)c4ccccc4c(-c4c([2H])c([2H])c5c([2H])c([2H])c([2H])c([2H])c5c4[2H])c32)c1[2H] ; [2H]c1ccc2cc(-c3ccc(-c4c5ccccc5c(-c5cccc6oc7ccccc7c56)c5oc6ccccc6c45)cc3)ccc2c1 ; [2H]c1c([2H])c([2H])c2c(oc3c(-c4ccc5oc6ccccc6c5c4)c4c([2H])c([2H])c([2H])c([2H])c4c(-c4ccc5ccccc5c4)c32)c1[2H]]

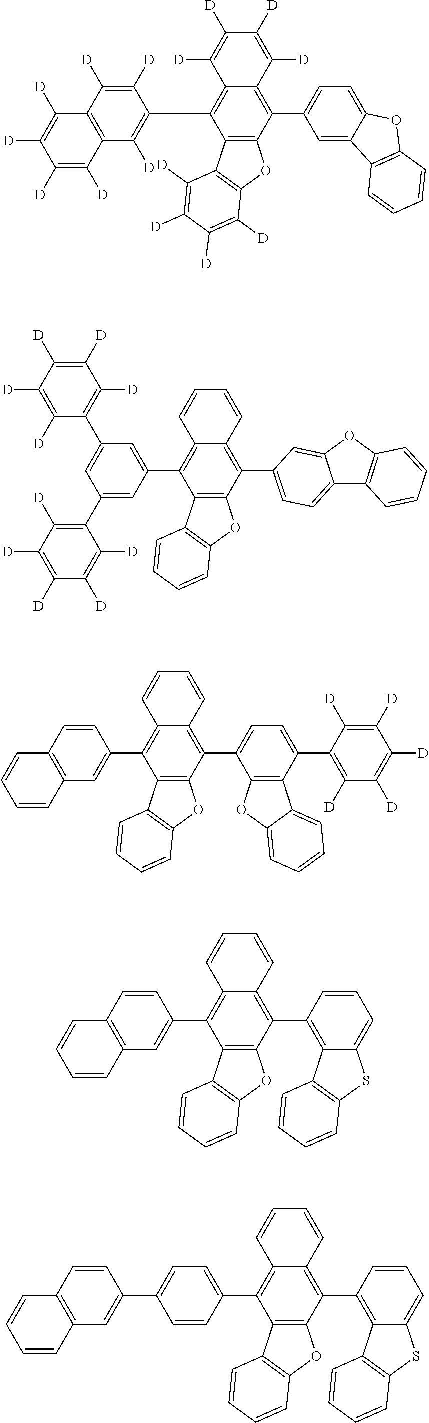

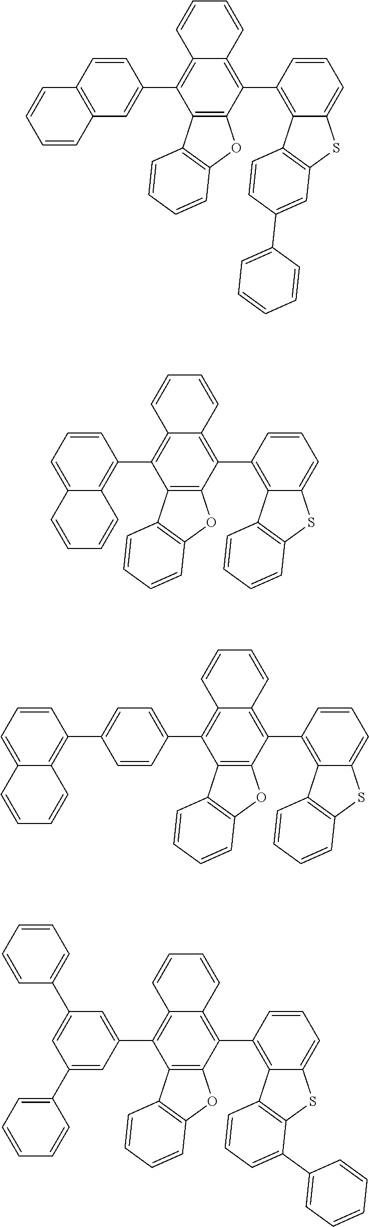 [SMILES: c1ccc(-c2ccc3c(c2)sc2cccc(-c4c5ccccc5c(-c5ccc6ccccc6c5)c5c4oc4ccccc45)c23)cc1 ; c1ccc2c(-c3c4ccccc4c(-c4cccc5sc6ccccc6c45)c4oc5ccccc5c34)cccc2c1 ; c1ccc2c(-c3ccc(-c4c5ccccc5c(-c5cccc6sc7ccccc7c56)c5oc6ccccc6c45)cc3)cccc2c1 ; c1ccc(-c2cc(-c3ccccc3)cc(-c3c4ccccc4c(-c4cccc5sc6c(-c7ccccc7)cccc6c45)c4oc5ccccc5c34)c2)cc1]

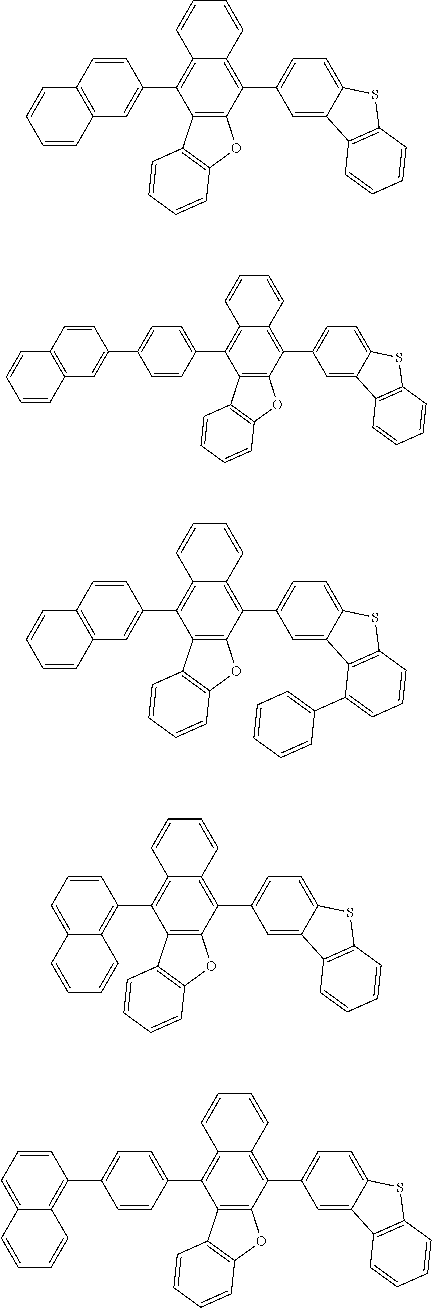 [SMILES: c1ccc2cc(-c3c4ccccc4c(-c4ccc5sc6ccccc6c5c4)c4oc5ccccc5c34)ccc2c1 ; c1ccc2cc(-c3ccc(-c4c5ccccc5c(-c5ccc6sc7ccccc7c6c5)c5oc6ccccc6c45)cc3)ccc2c1 ; c1ccc(-c2cccc3sc4ccc(-c5c6ccccc6c(-c6ccc7ccccc7c6)c6c5oc5ccccc56)cc4c23)cc1 ; c1ccc2c(-c3c4ccccc4c(-c4ccc5sc6ccccc6c5c4)c4oc5ccccc5c34)cccc2c1 ; c1ccc2c(-c3ccc(-c4c5ccccc5c(-c5ccc6sc7ccccc7c6c5)c5oc6ccccc6c45)cc3)cccc2c1]

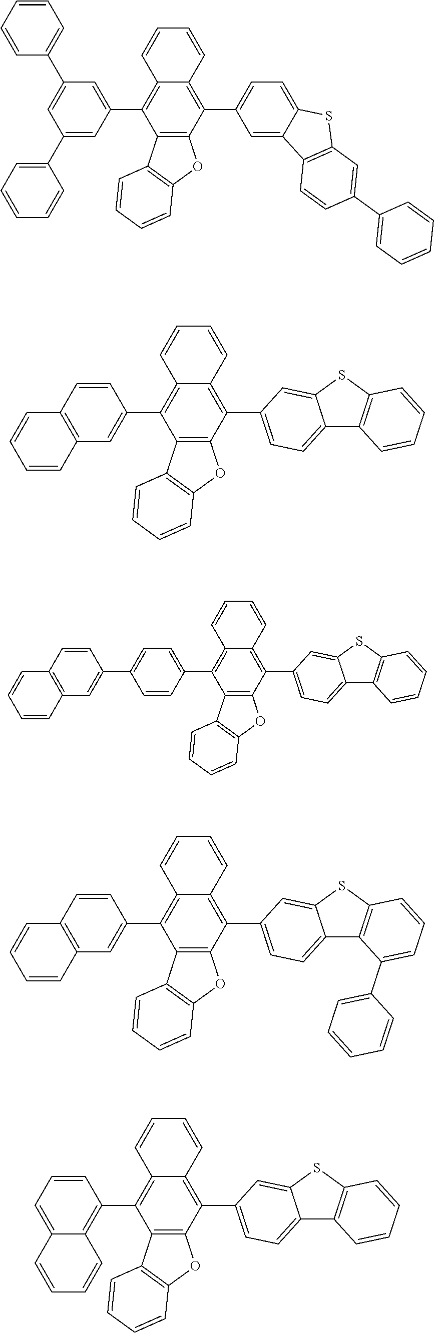 [SMILES: c1ccc(-c2cc(-c3ccccc3)cc(-c3c4ccccc4c(-c4ccc5sc6cc(-c7ccccc7)ccc6c5c4)c4oc5ccccc5c34)c2)cc1 ; c1ccc2cc(-c3c4ccccc4c(-c4ccc5c(c4)sc4ccccc45)c4oc5ccccc5c34)ccc2c1 ; c1ccc2cc(-c3ccc(-c4c5ccccc5c(-c5ccc6c(c5)sc5ccccc56)c5oc6ccccc6c45)cc3)ccc2c1 ; c1ccc(-c2cccc3sc4cc(-c5c6ccccc6c(-c6ccc7ccccc7c6)c6c5oc5ccccc56)ccc4c23)cc1 ; c1ccc2c(-c3c4ccccc4c(-c4ccc5c(c4)sc4ccccc45)c4oc5ccccc5c34)cccc2c1]

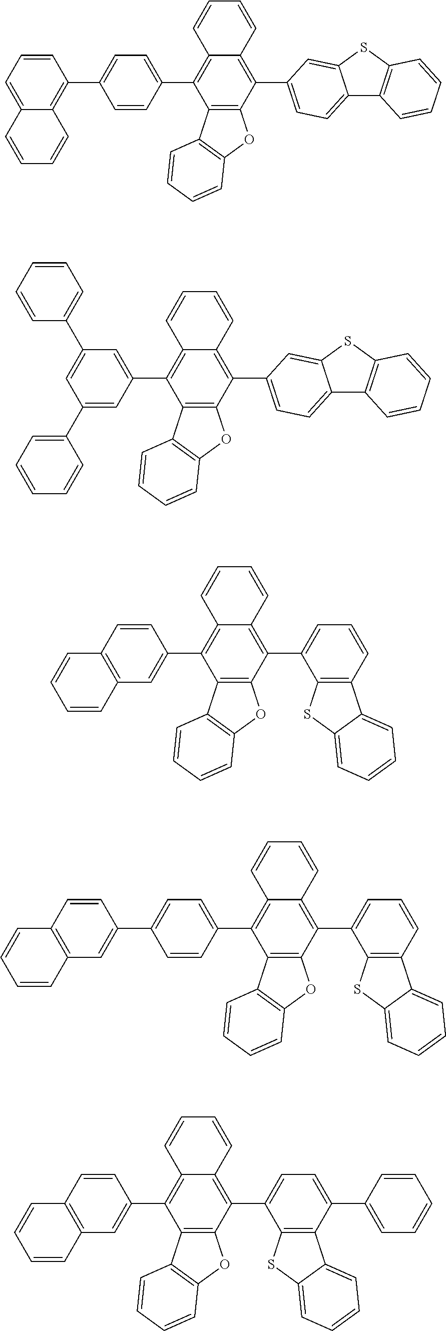 [SMILES: c1ccc2c(-c3ccc(-c4c5ccccc5c(-c5ccc6c(c5)sc5ccccc56)c5oc6ccccc6c45)cc3)cccc2c1 ; c1ccc(-c2cc(-c3ccccc3)cc(-c3c4ccccc4c(-c4ccc5c(c4)sc4ccccc45)c4oc5ccccc5c34)c2)cc1 ; c1ccc2cc(-c3c4ccccc4c(-c4cccc5c4sc4ccccc45)c4oc5ccccc5c34)ccc2c1 ; c1ccc2cc(-c3ccc(-c4c5ccccc5c(-c5cccc6c5sc5ccccc56)c5oc6ccccc6c45)cc3)ccc2c1 ; c1ccc(-c2ccc(-c3c4ccccc4c(-c4ccc5ccccc5c4)c4c3oc3ccccc34)c3sc4ccccc4c23)cc1]

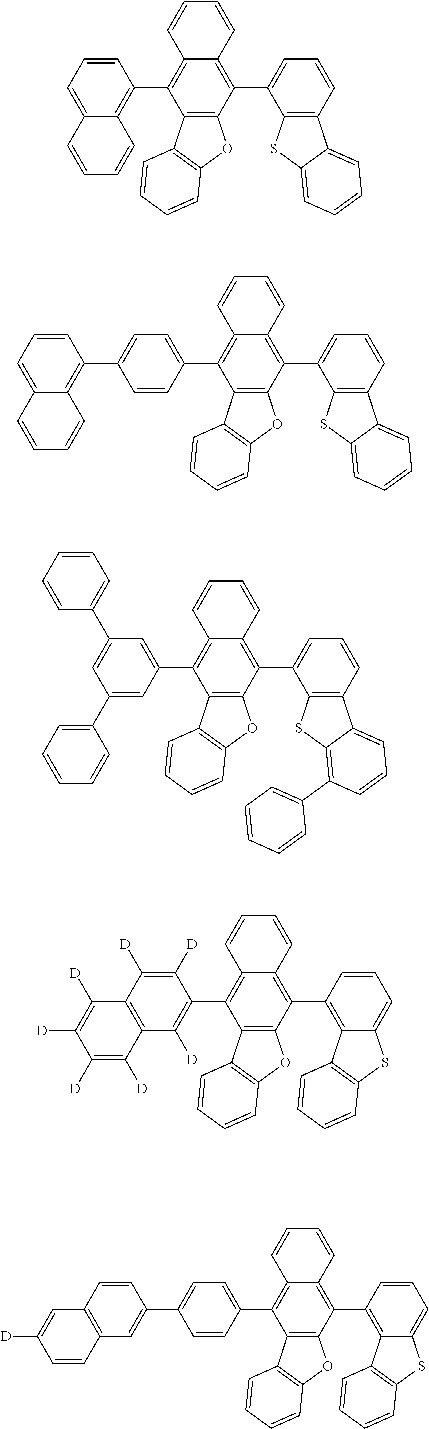 [SMILES: c1ccc2c(-c3c4ccccc4c(-c4cccc5c4sc4ccccc45)c4oc5ccccc5c34)cccc2c1 ; c1ccc2c(-c3ccc(-c4c5ccccc5c(-c5cccc6c5sc5ccccc56)c5oc6ccccc6c45)cc3)cccc2c1 ; c1ccc(-c2cc(-c3ccccc3)cc(-c3c4ccccc4c(-c4cccc5c4sc4c(-c6ccccc6)cccc45)c4oc5ccccc5c34)c2)cc1 ; [2H]c1c([2H])c([2H])c2c([2H])c(-c3c4ccccc4c(-c4cccc5sc6ccccc6c45)c4oc5ccccc5c34)c([2H])c([2H])c2c1[2H] ; [2H]c1ccc2cc(-c3ccc(-c4c5ccccc5c(-c5cccc6sc7ccccc7c56)c5oc6ccccc6c45)cc3)ccc2c1]

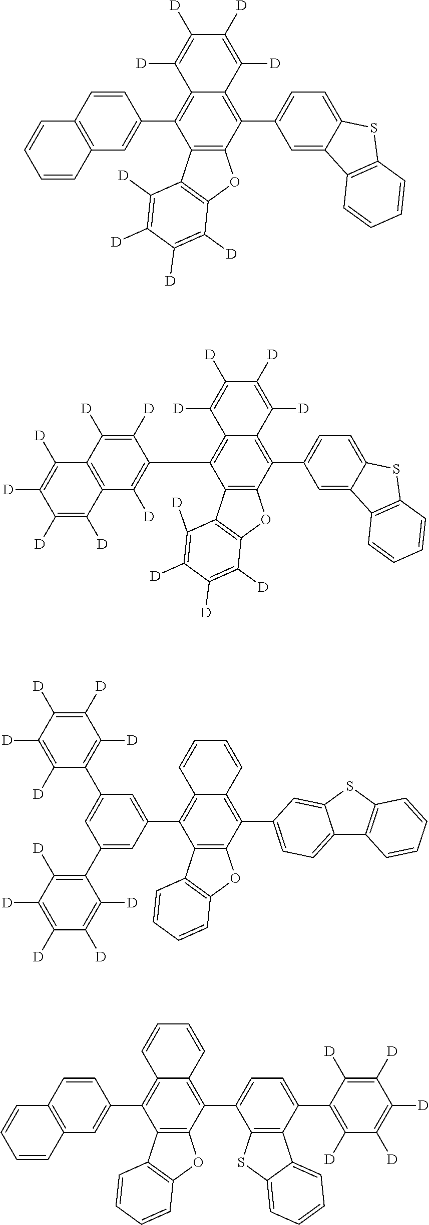

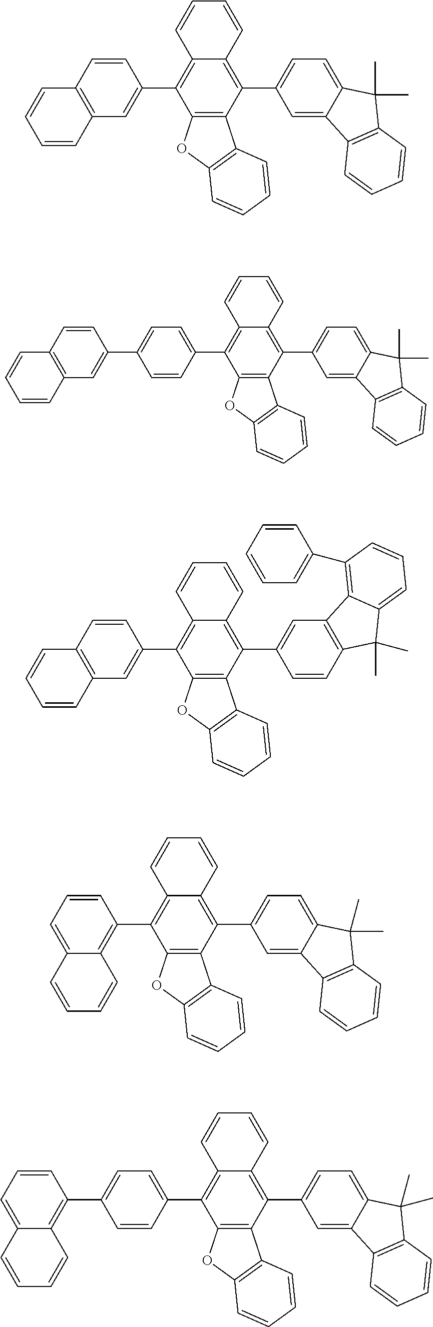 [SMILES: CC1(C)c2ccccc2-c2cc(-c3c4ccccc4c(-c4ccc5ccccc5c4)c4oc5ccccc5c34)ccc21 ; CC1(C)c2ccccc2-c2cc(-c3c4ccccc4c(-c4ccc(-c5ccc6ccccc6c5)cc4)c4oc5ccccc5c34)ccc21 ; CC1(C)c2ccc(-c3c4ccccc4c(-c4ccc5ccccc5c4)c4oc5ccccc5c34)cc2-c2c(-c3ccccc3)cccc21 ; CC1(C)c2ccccc2-c2cc(-c3c4ccccc4c(-c4cccc5ccccc45)c4oc5ccccc5c34)ccc21 ; CC1(C)c2ccccc2-c2cc(-c3c4ccccc4c(-c4ccc(-c5cccc6ccccc56)cc4)c4oc5ccccc5c34)ccc21]

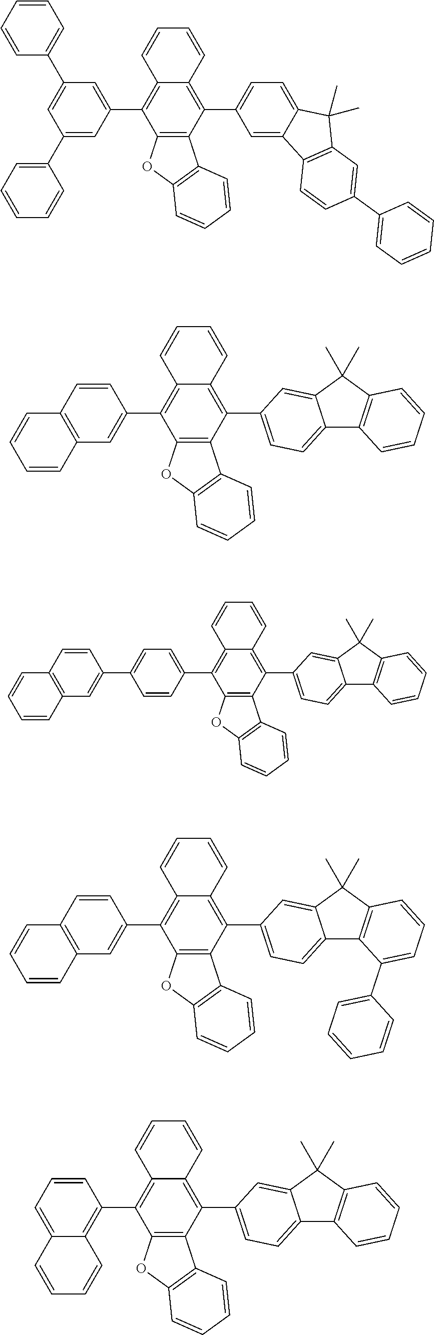 [SMILES: CC1(C)c2ccc(-c3c4ccccc4c(-c4cc(-c5ccccc5)cc(-c5ccccc5)c4)c4oc5ccccc5c34)cc2-c2ccc(-c3ccccc3)cc21 ; CC1(C)c2ccccc2-c2ccc(-c3c4ccccc4c(-c4ccc5ccccc5c4)c4oc5ccccc5c34)cc21 ; CC1(C)c2ccccc2-c2ccc(-c3c4ccccc4c(-c4ccc(-c5ccc6ccccc6c5)cc4)c4oc5ccccc5c34)cc21 ; CC1(C)c2cc(-c3c4ccccc4c(-c4ccc5ccccc5c4)c4oc5ccccc5c34)ccc2-c2c(-c3ccccc3)cccc21 ; CC1(C)c2ccccc2-c2ccc(-c3c4ccccc4c(-c4cccc5ccccc45)c4oc5ccccc5c34)cc21]

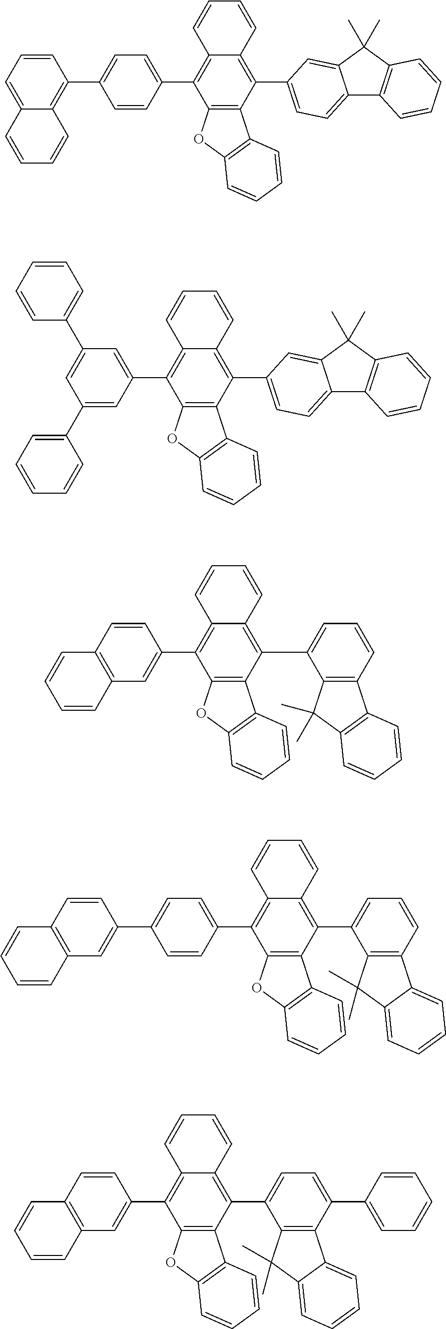 [SMILES: CC1(C)c2ccccc2-c2ccc(-c3c4ccccc4c(-c4ccc(-c5cccc6ccccc56)cc4)c4oc5ccccc5c34)cc21 ; CC1(C)c2ccccc2-c2ccc(-c3c4ccccc4c(-c4cc(-c5ccccc5)cc(-c5ccccc5)c4)c4oc5ccccc5c34)cc21 ; CC1(C)c2ccccc2-c2cccc(-c3c4ccccc4c(-c4ccc5ccccc5c4)c4oc5ccccc5c34)c21 ; CC1(C)c2ccccc2-c2cccc(-c3c4ccccc4c(-c4ccc(-c5ccc6ccccc6c5)cc4)c4oc5ccccc5c34)c21 ; CC1(C)c2ccccc2-c2c(-c3ccccc3)ccc(-c3c4ccccc4c(-c4ccc5ccccc5c4)c4oc5ccccc5c34)c21]

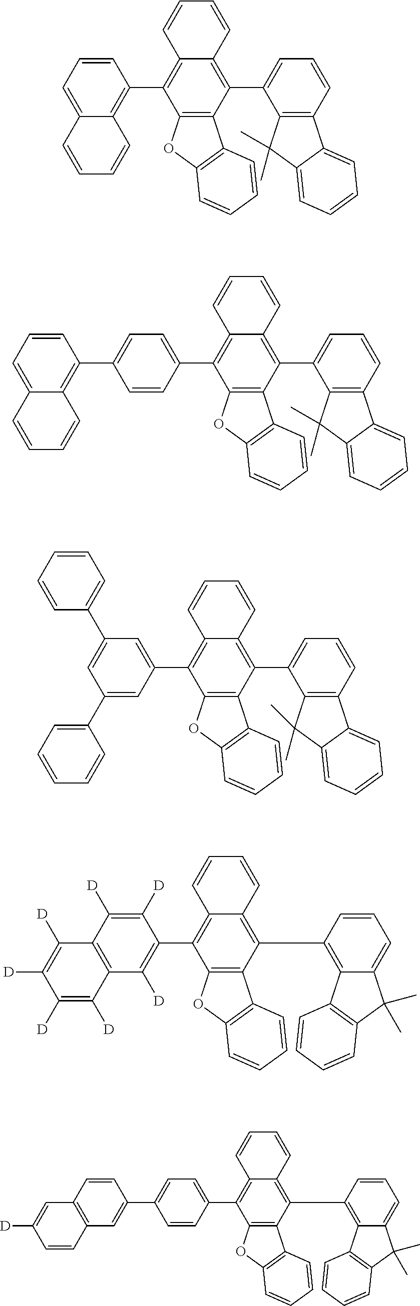 [SMILES: CC1(C)c2ccccc2-c2cccc(-c3c4ccccc4c(-c4cccc5ccccc45)c4oc5ccccc5c34)c21 ; CC1(C)c2ccccc2-c2cccc(-c3c4ccccc4c(-c4ccc(-c5cccc6ccccc56)cc4)c4oc5ccccc5c34)c21 ; CC1(C)c2ccccc2-c2cccc(-c3c4ccccc4c(-c4cc(-c5ccccc5)cc(-c5ccccc5)c4)c4oc5ccccc5c34)c21 ; [2H]c1c([2H])c([2H])c2c([2H])c(-c3c4ccccc4c(-c4cccc5c4-c4ccccc4C5(C)C)c4c3oc3ccccc34)c([2H])c([2H])c2c1[2H] ; [2H]c1ccc2cc(-c3ccc(-c4c5ccccc5c(-c5cccc6c5-c5ccccc5C6(C)C)c5c4oc4ccccc45)cc3)ccc2c1]

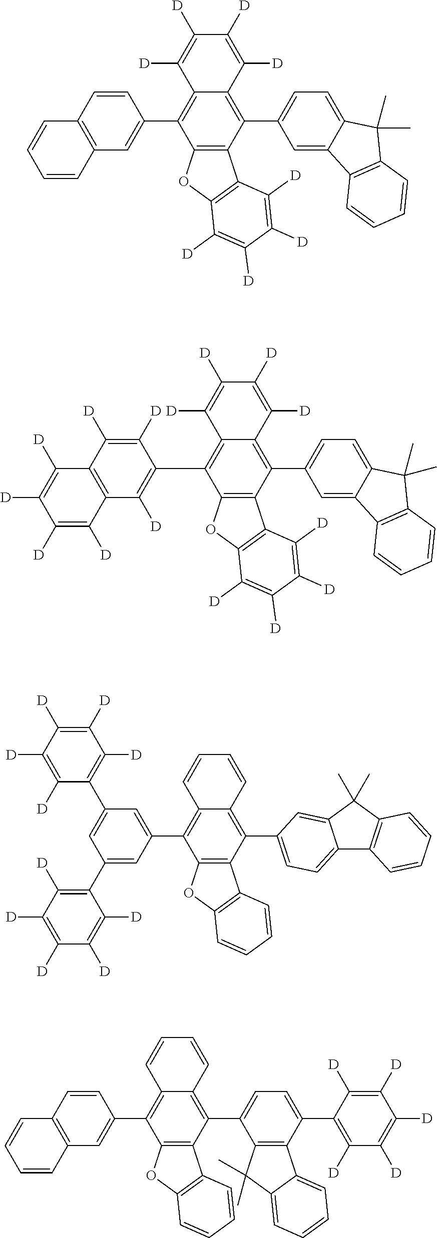

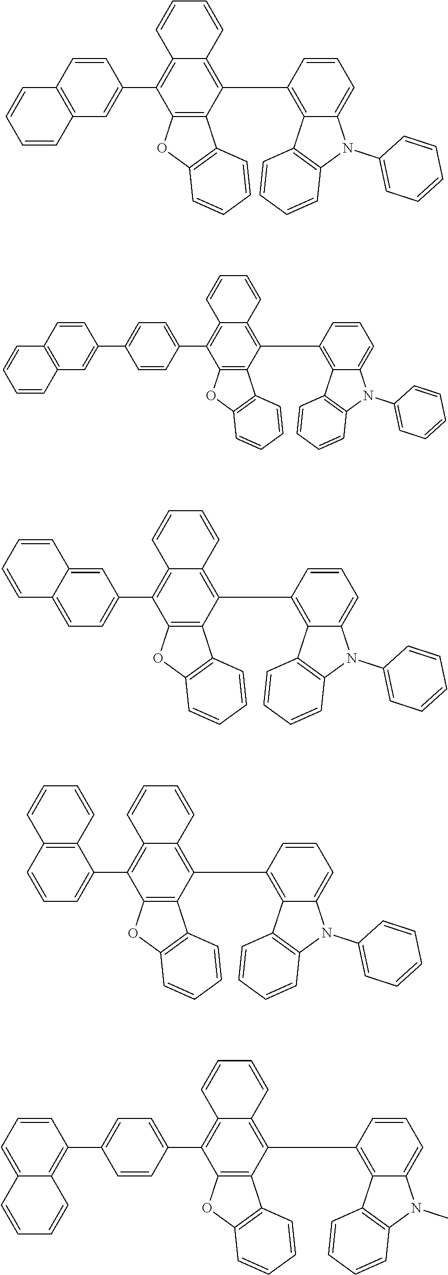 [SMILES: c1ccc(-n2c3ccccc3c3c(-c4c5ccccc5c(-c5ccc6ccccc6c5)c5oc6ccccc6c45)cccc32)cc1 ; c1ccc(-n2c3ccccc3c3c(-c4c5ccccc5c(-c5ccc(-c6ccc7ccccc7c6)cc5)c5oc6ccccc6c45)cccc32)cc1 ; c1ccc(-n2c3ccccc3c3c(-c4c5ccccc5c(-c5ccc6ccccc6c5)c5oc6ccccc6c45)cccc32)cc1 ; c1ccc(-n2c3ccccc3c3c(-c4c5ccccc5c(-c5cccc6ccccc56)c5oc6ccccc6c45)cccc32)cc1 ; Cn1c2ccccc2c2c(-c3c4ccccc4c(-c4ccc(-c5cccc6ccccc56)cc4)c4oc5ccccc5c34)cccc21]

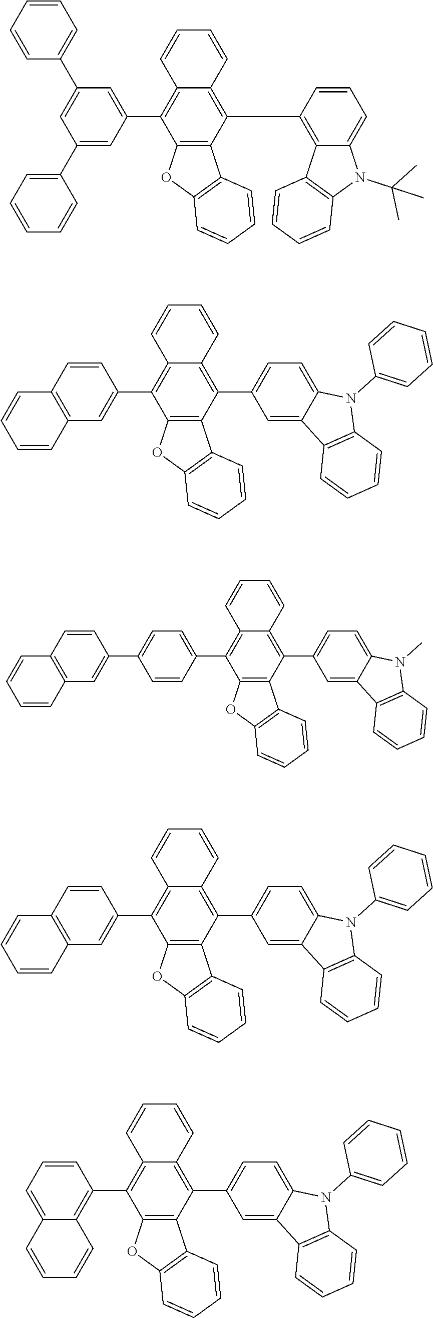 [SMILES: CC(C)(C)n1c2ccccc2c2c(-c3c4ccccc4c(-c4cc(-c5ccccc5)cc(-c5ccccc5)c4)c4oc5ccccc5c34)cccc21 ; c1ccc(-n2c3ccccc3c3cc(-c4c5ccccc5c(-c5ccc6ccccc6c5)c5oc6ccccc6c45)ccc32)cc1 ; Cn1c2ccccc2c2cc(-c3c4ccccc4c(-c4ccc(-c5ccc6ccccc6c5)cc4)c4oc5ccccc5c34)ccc21 ; c1ccc(-n2c3ccccc3c3cc(-c4c5ccccc5c(-c5ccc6ccccc6c5)c5oc6ccccc6c45)ccc32)cc1 ; c1ccc(-n2c3ccccc3c3cc(-c4c5ccccc5c(-c5cccc6ccccc56)c5oc6ccccc6c45)ccc32)cc1]

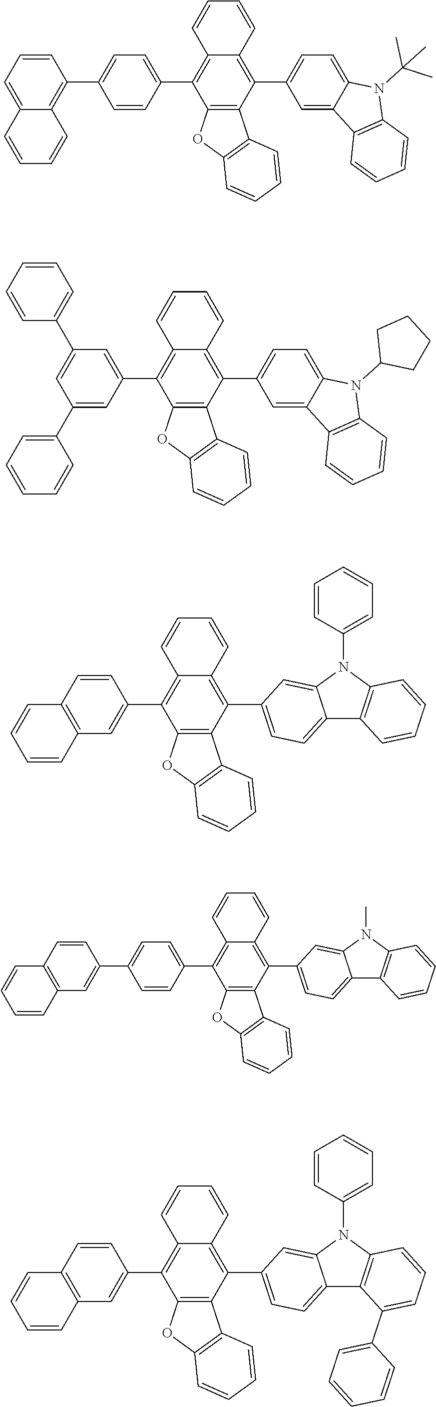 [SMILES: CC(C)(C)n1c2ccccc2c2cc(-c3c4ccccc4c(-c4ccc(-c5cccc6ccccc56)cc4)c4oc5ccccc5c34)ccc21 ; c1ccc(-c2cc(-c3ccccc3)cc(-c3c4ccccc4c(-c4ccc5c(c4)c4ccccc4n5C4CCCC4)c4c3oc3ccccc34)c2)cc1 ; c1ccc(-n2c3ccccc3c3ccc(-c4c5ccccc5c(-c5ccc6ccccc6c5)c5oc6ccccc6c45)cc32)cc1 ; Cn1c2ccccc2c2ccc(-c3c4ccccc4c(-c4ccc(-c5ccc6ccccc6c5)cc4)c4oc5ccccc5c34)cc21 ; c1ccc(-c2cccc3c2c2ccc(-c4c5ccccc5c(-c5ccc6ccccc6c5)c5oc6ccccc6c45)cc2n3-c2ccccc2)cc1]

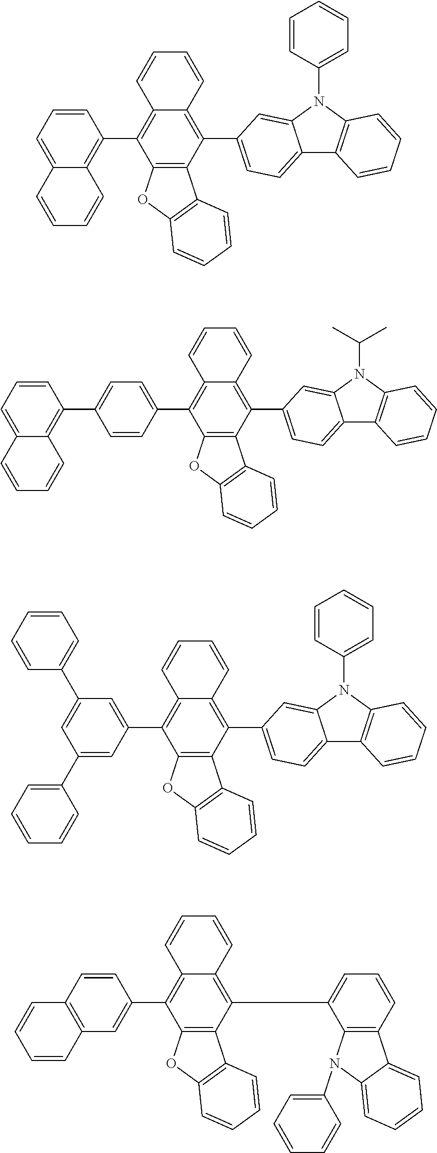 [SMILES: c1ccc(-n2c3ccccc3c3ccc(-c4c5ccccc5c(-c5cccc6ccccc56)c5oc6ccccc6c45)cc32)cc1 ; CC(C)n1c2ccccc2c2ccc(-c3c4ccccc4c(-c4ccc(-c5cccc6ccccc56)cc4)c4oc5ccccc5c34)cc21 ; c1ccc(-c2cc(-c3ccccc3)cc(-c3c4ccccc4c(-c4ccc5c6ccccc6n(-c6ccccc6)c5c4)c4c3oc3ccccc34)c2)cc1 ; c1ccc(-n2c3ccccc3c3cccc(-c4c5ccccc5c(-c5ccc6ccccc6c5)c5oc6ccccc6c45)c32)cc1]

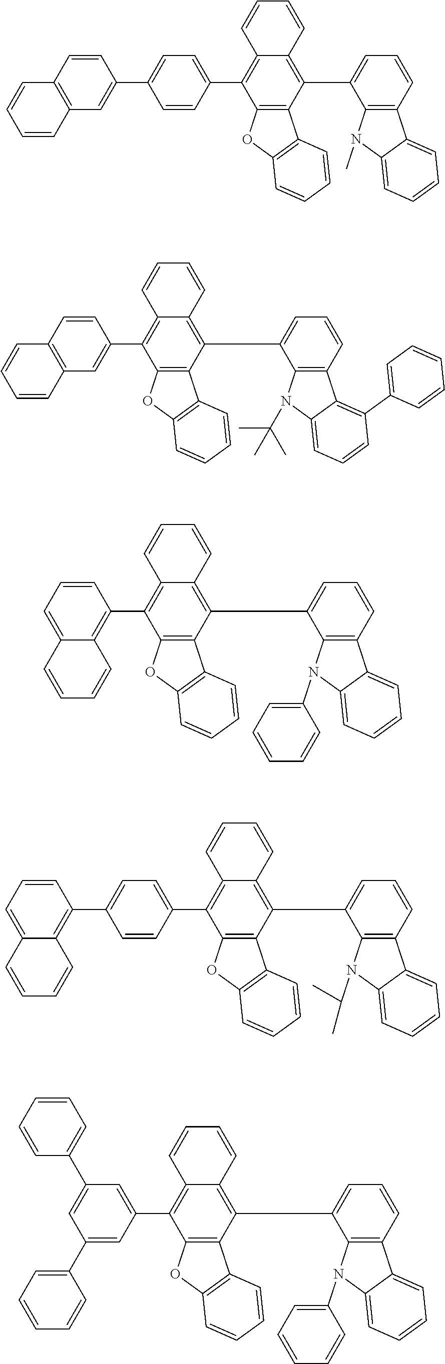 [SMILES: Cn1c2ccccc2c2cccc(-c3c4ccccc4c(-c4ccc(-c5ccc6ccccc6c5)cc4)c4oc5ccccc5c34)c21 ; CC(C)(C)n1c2cccc(-c3ccccc3)c2c2cccc(-c3c4ccccc4c(-c4ccc5ccccc5c4)c4oc5ccccc5c34)c21 ; c1ccc(-n2c3ccccc3c3cccc(-c4c5ccccc5c(-c5cccc6ccccc56)c5oc6ccccc6c45)c32)cc1 ; CC(C)n1c2ccccc2c2cccc(-c3c4ccccc4c(-c4ccc(-c5cccc6ccccc56)cc4)c4oc5ccccc5c34)c21 ; c1ccc(-c2cc(-c3ccccc3)cc(-c3c4ccccc4c(-c4cccc5c6ccccc6n(-c6ccccc6)c45)c4c3oc3ccccc34)c2)cc1]

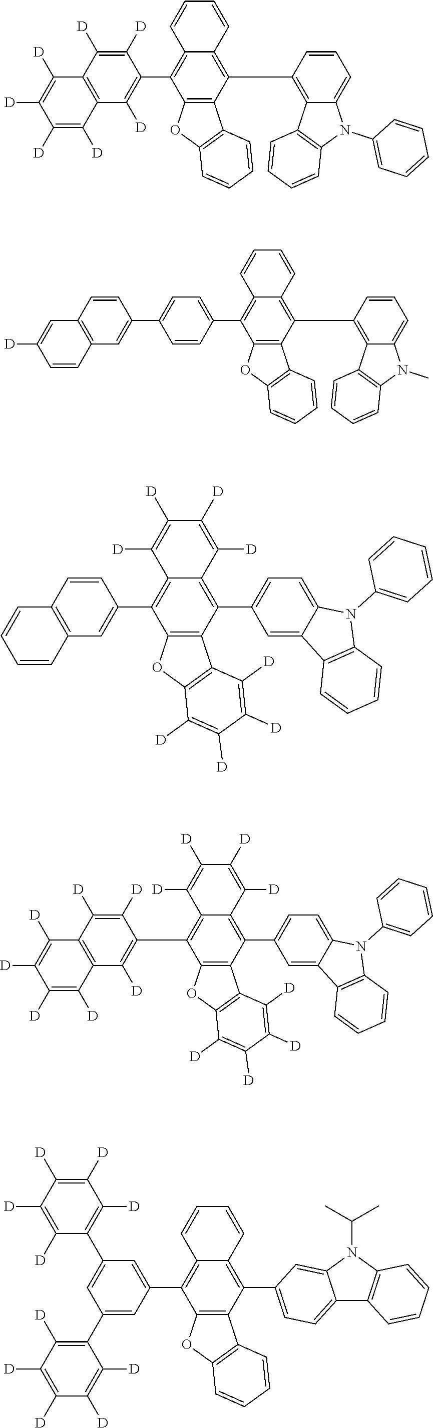

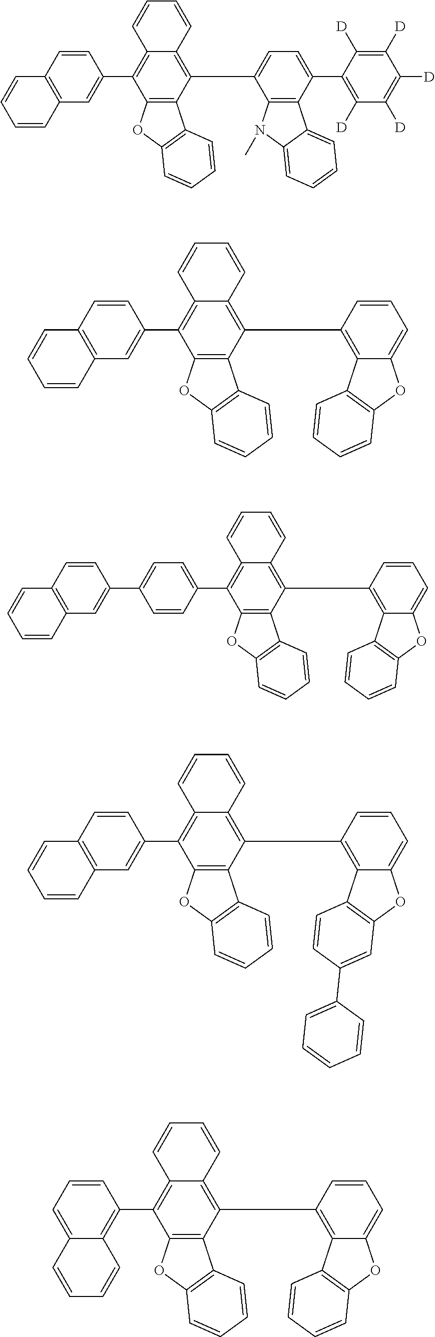 [SMILES: [2H]c1c([2H])c([2H])c(-c2ccc(-c3c4ccccc4c(-c4ccc5ccccc5c4)c4oc5ccccc5c34)c3c2c2ccccc2n3C)c([2H])c1[2H] ; c1ccc2cc(-c3c4ccccc4c(-c4cccc5oc6ccccc6c45)c4c3oc3ccccc34)ccc2c1 ; c1ccc2cc(-c3ccc(-c4c5ccccc5c(-c5cccc6oc7ccccc7c56)c5c4oc4ccccc45)cc3)ccc2c1 ; c1ccc(-c2ccc3c(c2)oc2cccc(-c4c5ccccc5c(-c5ccc6ccccc6c5)c5oc6ccccc6c45)c23)cc1 ; c1ccc2c(-c3c4ccccc4c(-c4cccc5oc6ccccc6c45)c4c3oc3ccccc34)cccc2c1]

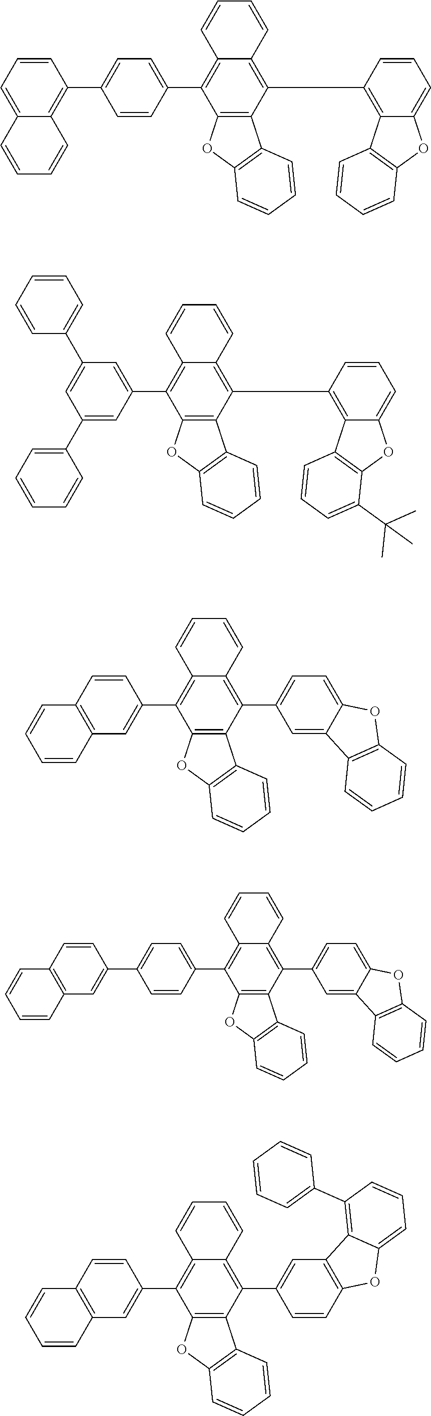 [SMILES: c1ccc2c(-c3ccc(-c4c5ccccc5c(-c5cccc6oc7ccccc7c56)c5c4oc4ccccc45)cc3)cccc2c1 ; CC(C)(C)c1cccc2c1oc1cccc(-c3c4ccccc4c(-c4cc(-c5ccccc5)cc(-c5ccccc5)c4)c4oc5ccccc5c34)c12 ; c1ccc2cc(-c3c4ccccc4c(-c4ccc5oc6ccccc6c5c4)c4c3oc3ccccc34)ccc2c1 ; c1ccc2cc(-c3ccc(-c4c5ccccc5c(-c5ccc6oc7ccccc7c6c5)c5c4oc4ccccc45)cc3)ccc2c1 ; c1ccc(-c2cccc3oc4ccc(-c5c6ccccc6c(-c6ccc7ccccc7c6)c6oc7ccccc7c56)cc4c23)cc1]

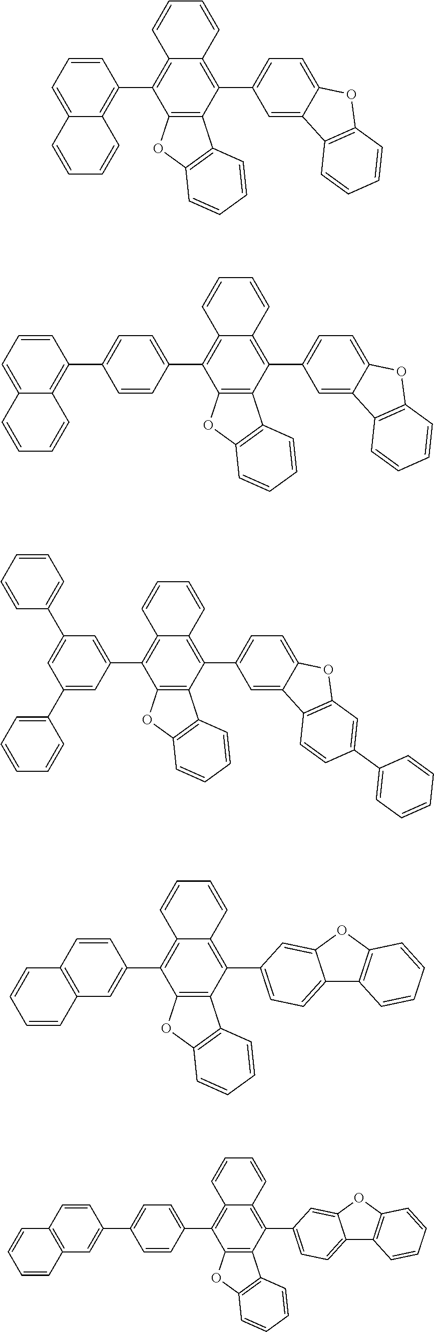 [SMILES: c1ccc2c(-c3c4ccccc4c(-c4ccc5oc6ccccc6c5c4)c4c3oc3ccccc34)cccc2c1 ; c1ccc2c(-c3ccc(-c4c5ccccc5c(-c5ccc6oc7ccccc7c6c5)c5c4oc4ccccc45)cc3)cccc2c1 ; c1ccc(-c2cc(-c3ccccc3)cc(-c3c4ccccc4c(-c4ccc5oc6cc(-c7ccccc7)ccc6c5c4)c4c3oc3ccccc34)c2)cc1 ; c1ccc2cc(-c3c4ccccc4c(-c4ccc5c(c4)oc4ccccc45)c4c3oc3ccccc34)ccc2c1 ; c1ccc2cc(-c3ccc(-c4c5ccccc5c(-c5ccc6c(c5)oc5ccccc56)c5c4oc4ccccc45)cc3)ccc2c1]

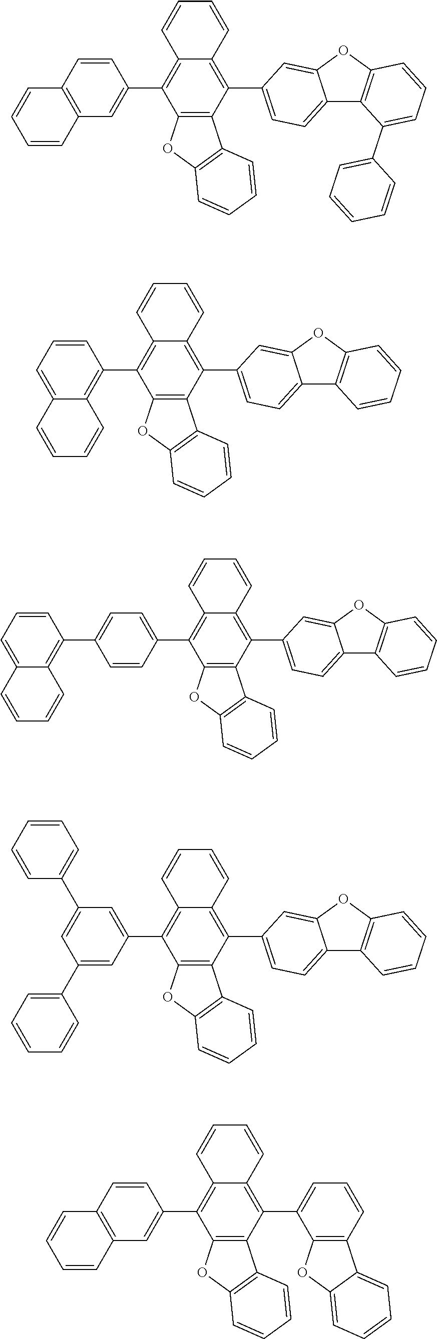 [SMILES: c1ccc(-c2cccc3oc4cc(-c5c6ccccc6c(-c6ccc7ccccc7c6)c6oc7ccccc7c56)ccc4c23)cc1 ; c1ccc2c(-c3c4ccccc4c(-c4ccc5c(c4)oc4ccccc45)c4c3oc3ccccc34)cccc2c1 ; c1ccc2c(-c3ccc(-c4c5ccccc5c(-c5ccc6c(c5)oc5ccccc56)c5c4oc4ccccc45)cc3)cccc2c1 ; c1ccc(-c2cc(-c3ccccc3)cc(-c3c4ccccc4c(-c4ccc5c(c4)oc4ccccc45)c4c3oc3ccccc34)c2)cc1 ; c1ccc2cc(-c3c4ccccc4c(-c4cccc5c4oc4ccccc45)c4c3oc3ccccc34)ccc2c1]

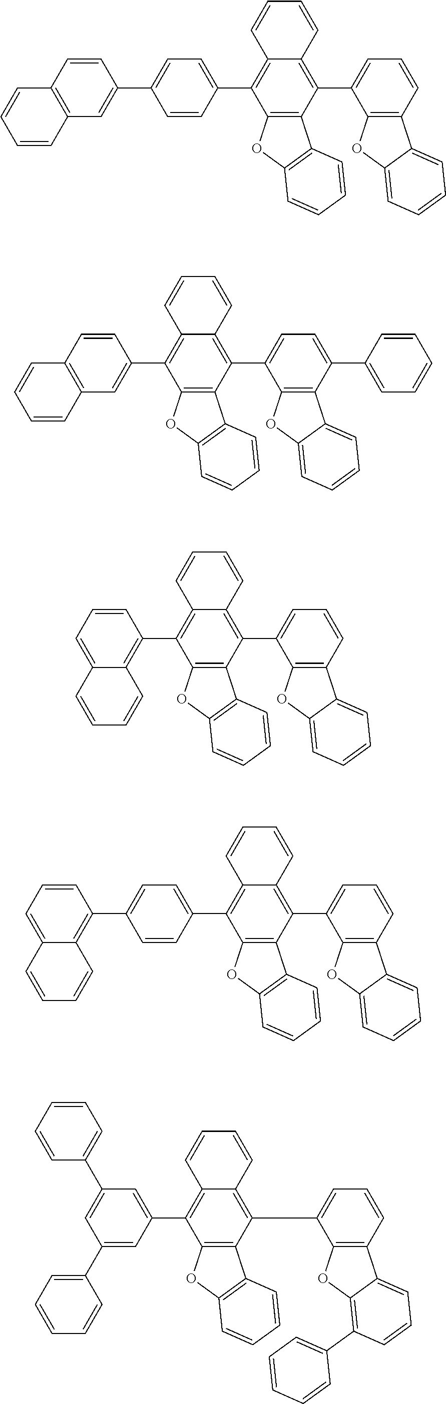 [SMILES: c1ccc2cc(-c3ccc(-c4c5ccccc5c(-c5cccc6c5oc5ccccc56)c5c4oc4ccccc45)cc3)ccc2c1 ; c1ccc(-c2ccc(-c3c4ccccc4c(-c4ccc5ccccc5c4)c4oc5ccccc5c34)c3oc4ccccc4c23)cc1 ; c1ccc2c(-c3c4ccccc4c(-c4cccc5c4oc4ccccc45)c4c3oc3ccccc34)cccc2c1 ; c1ccc2c(-c3ccc(-c4c5ccccc5c(-c5cccc6c5oc5ccccc56)c5c4oc4ccccc45)cc3)cccc2c1 ; c1ccc(-c2cc(-c3ccccc3)cc(-c3c4ccccc4c(-c4cccc5c4oc4c(-c6ccccc6)cccc45)c4c3oc3ccccc34)c2)cc1]

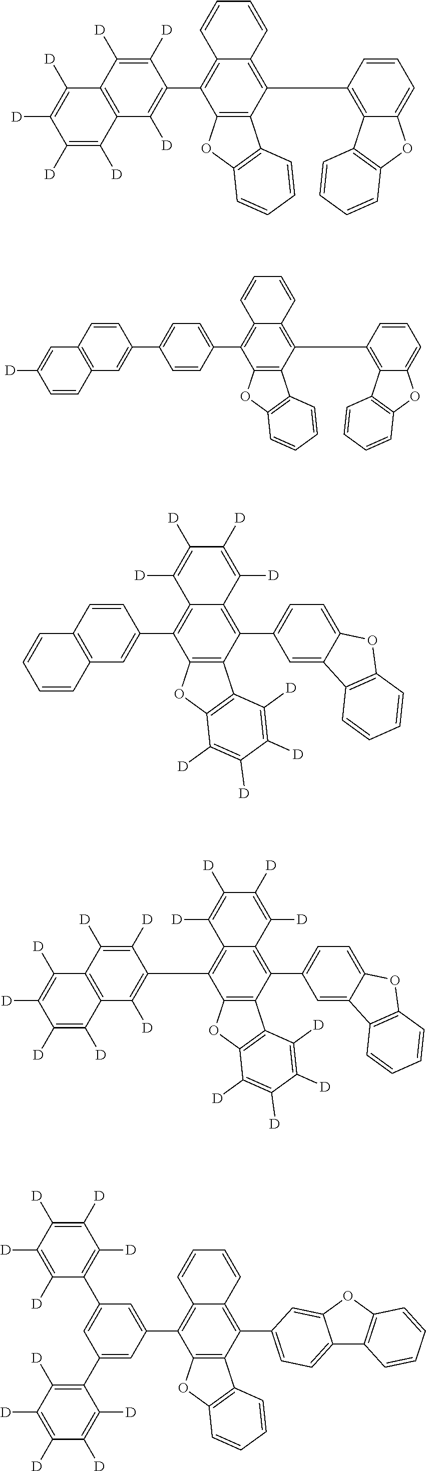

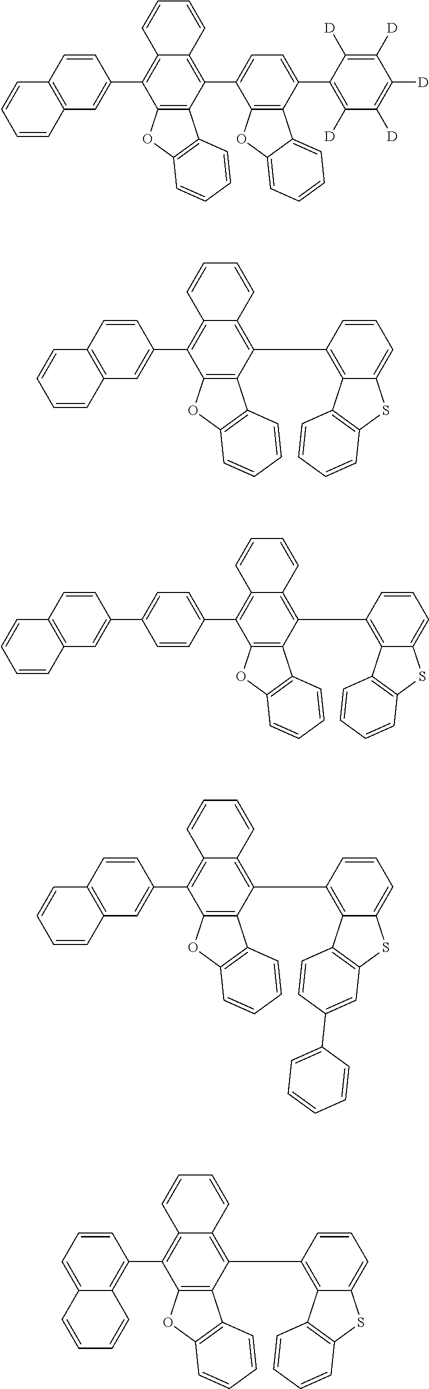 [SMILES: [2H]c1c([2H])c([2H])c(-c2ccc(-c3c4ccccc4c(-c4ccc5ccccc5c4)c4oc5ccccc5c34)c3oc4ccccc4c23)c([2H])c1[2H] ; c1ccc2cc(-c3c4ccccc4c(-c4cccc5sc6ccccc6c45)c4c3oc3ccccc34)ccc2c1 ; c1ccc2cc(-c3ccc(-c4c5ccccc5c(-c5cccc6sc7ccccc7c56)c5c4oc4ccccc45)cc3)ccc2c1 ; c1ccc(-c2ccc3c(c2)sc2cccc(-c4c5ccccc5c(-c5ccc6ccccc6c5)c5oc6ccccc6c45)c23)cc1 ; c1ccc2c(-c3c4ccccc4c(-c4cccc5sc6ccccc6c45)c4c3oc3ccccc34)cccc2c1]

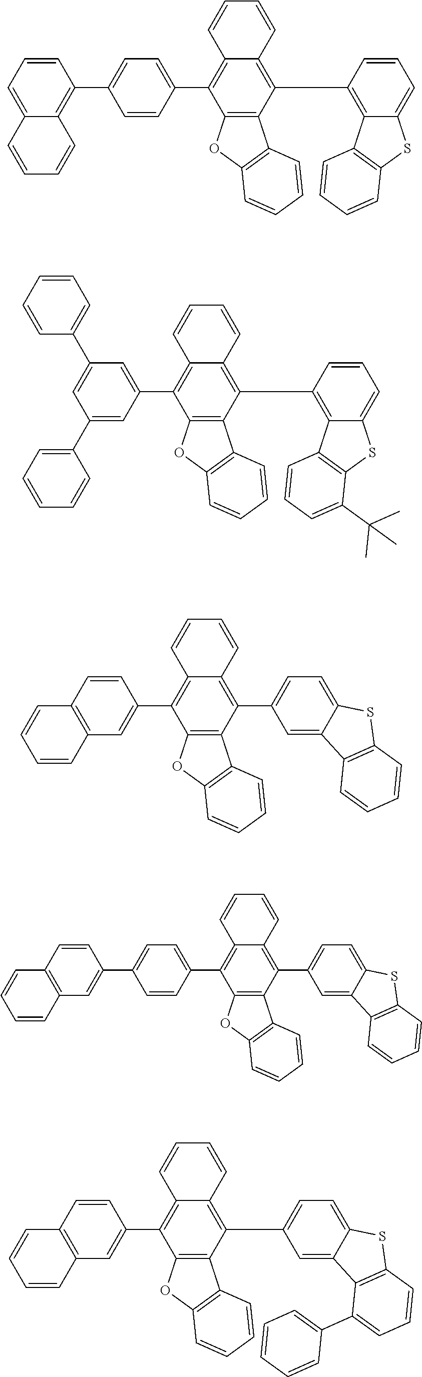 [SMILES: c1ccc2c(-c3ccc(-c4c5ccccc5c(-c5cccc6sc7ccccc7c56)c5c4oc4ccccc45)cc3)cccc2c1 ; CC(C)(C)c1cccc2c1sc1cccc(-c3c4ccccc4c(-c4cc(-c5ccccc5)cc(-c5ccccc5)c4)c4oc5ccccc5c34)c12 ; c1ccc2cc(-c3c4ccccc4c(-c4ccc5sc6ccccc6c5c4)c4c3oc3ccccc34)ccc2c1 ; c1ccc2cc(-c3ccc(-c4c5ccccc5c(-c5ccc6sc7ccccc7c6c5)c5c4oc4ccccc45)cc3)ccc2c1 ; c1ccc(-c2cccc3sc4ccc(-c5c6ccccc6c(-c6ccc7ccccc7c6)c6oc7ccccc7c56)cc4c23)cc1]

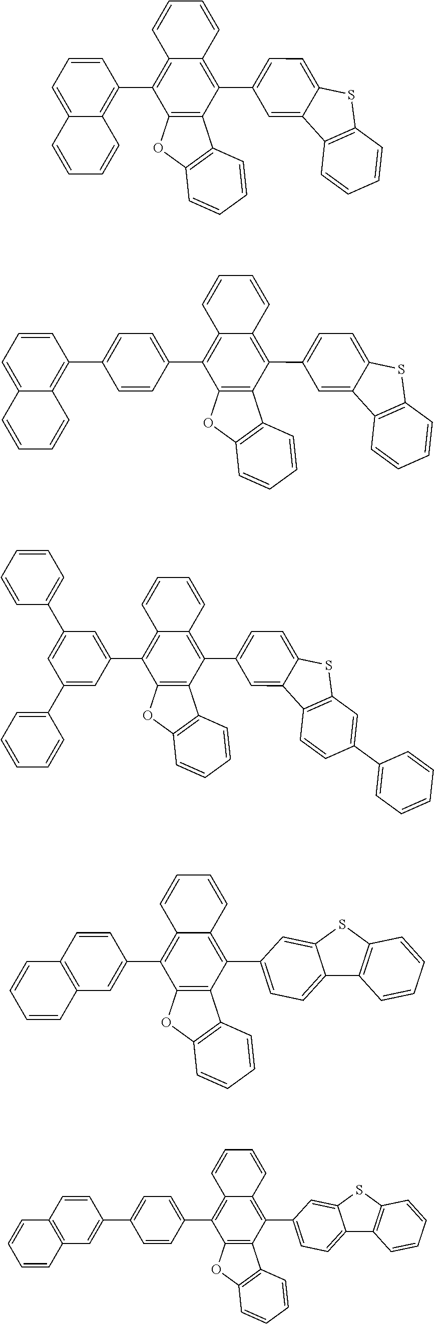 [SMILES: c1ccc2c(-c3c4ccccc4c(-c4ccc5sc6ccccc6c5c4)c4c3oc3ccccc34)cccc2c1 ; c1ccc2c(-c3ccc(-c4c5ccccc5c(-c5ccc6sc7ccccc7c6c5)c5c4oc4ccccc45)cc3)cccc2c1 ; c1ccc(-c2cc(-c3ccccc3)cc(-c3c4ccccc4c(-c4ccc5sc6cc(-c7ccccc7)ccc6c5c4)c4c3oc3ccccc34)c2)cc1 ; c1ccc2cc(-c3c4ccccc4c(-c4ccc5c(c4)sc4ccccc45)c4c3oc3ccccc34)ccc2c1 ; c1ccc2cc(-c3ccc(-c4c5ccccc5c(-c5ccc6c(c5)sc5ccccc56)c5c4oc4ccccc45)cc3)ccc2c1]

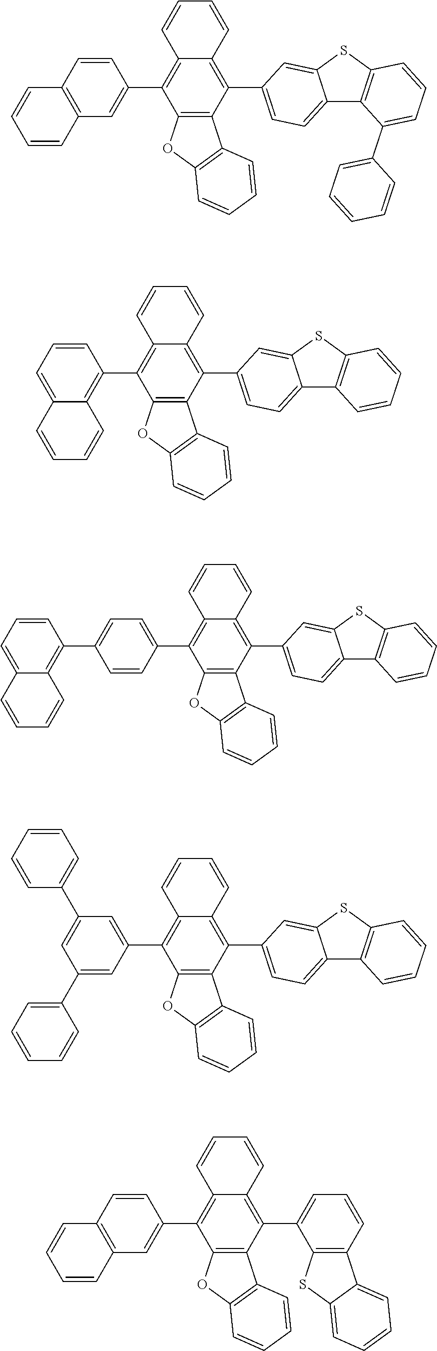 [SMILES: c1ccc(-c2cccc3sc4cc(-c5c6ccccc6c(-c6ccc7ccccc7c6)c6oc7ccccc7c56)ccc4c23)cc1 ; c1ccc2c(-c3c4ccccc4c(-c4ccc5c(c4)sc4ccccc45)c4c3oc3ccccc34)cccc2c1 ; c1ccc2c(-c3ccc(-c4c5ccccc5c(-c5ccc6c(c5)sc5ccccc56)c5c4oc4ccccc45)cc3)cccc2c1 ; c1ccc(-c2cc(-c3ccccc3)cc(-c3c4ccccc4c(-c4ccc5c(c4)sc4ccccc45)c4c3oc3ccccc34)c2)cc1 ; c1ccc2cc(-c3c4ccccc4c(-c4cccc5c4sc4ccccc45)c4c3oc3ccccc34)ccc2c1]

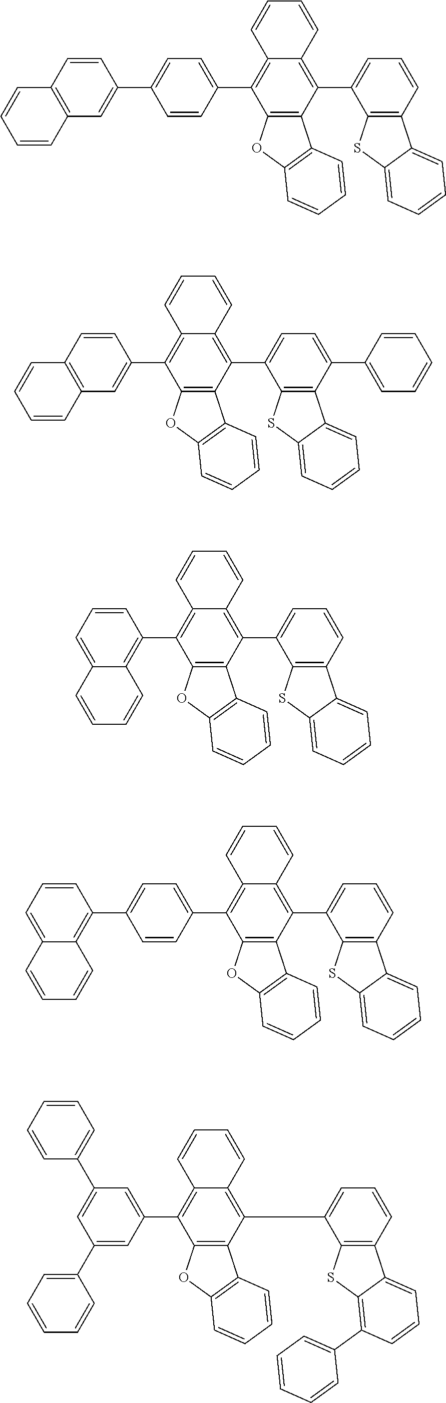 [SMILES: c1ccc2cc(-c3ccc(-c4c5ccccc5c(-c5cccc6c5sc5ccccc56)c5c4oc4ccccc45)cc3)ccc2c1 ; c1ccc(-c2ccc(-c3c4ccccc4c(-c4ccc5ccccc5c4)c4oc5ccccc5c34)c3sc4ccccc4c23)cc1 ; c1ccc2c(-c3c4ccccc4c(-c4cccc5c4sc4ccccc45)c4c3oc3ccccc34)cccc2c1 ; c1ccc2c(-c3ccc(-c4c5ccccc5c(-c5cccc6c5sc5ccccc56)c5c4oc4ccccc45)cc3)cccc2c1 ; c1ccc(-c2cc(-c3ccccc3)cc(-c3c4ccccc4c(-c4cccc5c4sc4c(-c6ccccc6)cccc45)c4c3oc3ccccc34)c2)cc1]

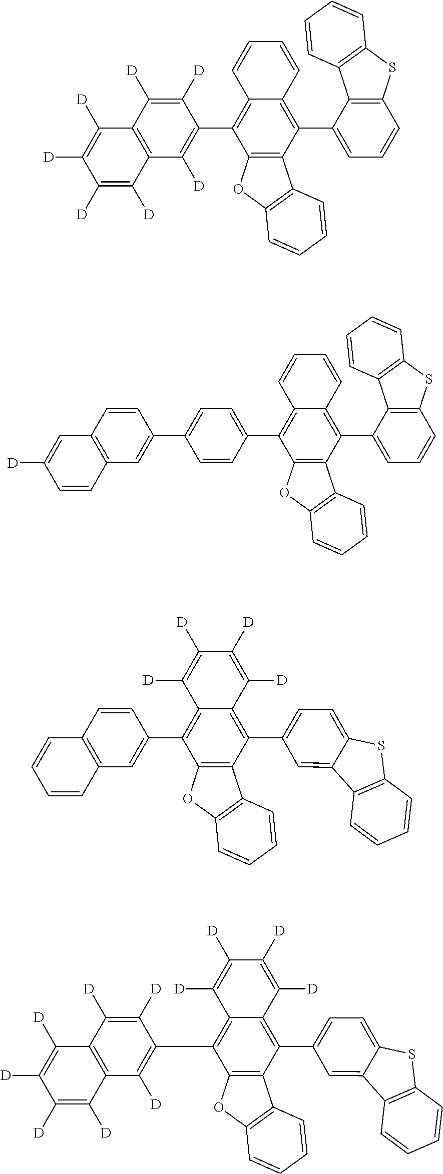 [SMILES: [2H]c1c([2H])c([2H])c2c([2H])c(-c3c4ccccc4c(-c4cccc5sc6ccccc6c45)c4c3oc3ccccc34)c([2H])c([2H])c2c1[2H] ; [2H]c1ccc2cc(-c3ccc(-c4c5ccccc5c(-c5cccc6sc7ccccc7c56)c5c4oc4ccccc45)cc3)ccc2c1 ; [2H]c1c([2H])c([2H])c2c(-c3ccc4sc5ccccc5c4c3)c3c(oc4ccccc43)c(-c3ccc4ccccc4c3)c2c1[2H] ; [2H]c1c([2H])c([2H])c2c([2H])c(-c3c4oc5ccccc5c4c(-c4ccc5sc6ccccc6c5c4)c4c([2H])c([2H])c([2H])c([2H])c34)c([2H])c([2H])c2c1[2H]]

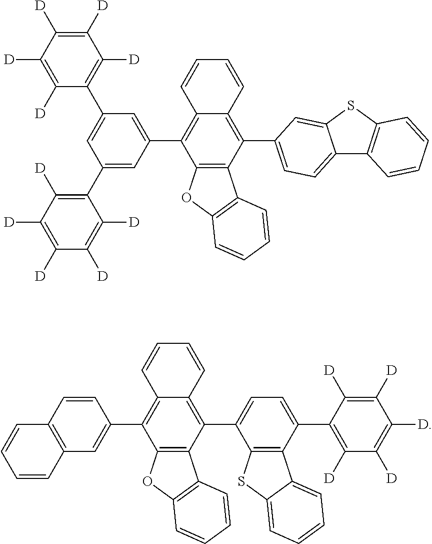

The present disclosure also provides a mixture including at least one composition as described above and an organic functional material. The organic functional material is selected from at least one of a hole transport material, a hole injection material, a hole blocking material, an electron injection material, an electron transport material, a host material or a guest material.

Optionally, the organic functional material comprises at least one third compound, and the third compound is selected from a structure represented by any one of formulae (3-1) to (3-2):

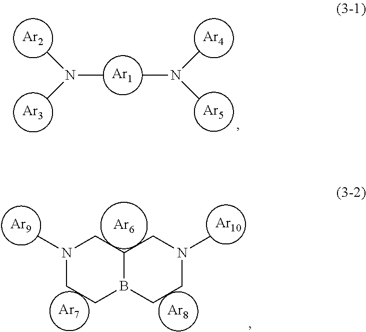

wherein each of Ar₁ to Ar₁₀ is independently selected from a substituted or unsubstituted aromatic group having 6-40 ring atoms, a substituted or unsubstituted heteroaromatic group having 5-40 ring atoms, two adjacent one of Ar₁ to Ar₅ form a ring or not, and two adjacent one of Ar₆ to Ar₁₀ form a ring or not.

Optionally, Ar1 is independently selected from a structure represented by any one of formulae (H-1) to (H-3):

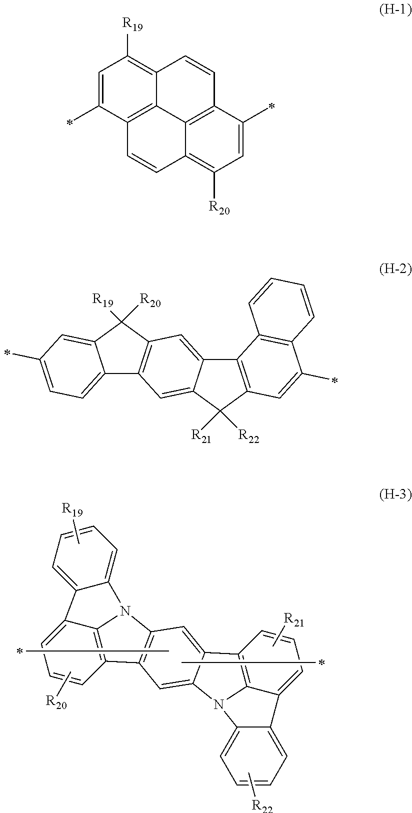

wherein R₁₉, R₂₀, R₂₁ and R₂₂ are each independently selected from —H, -D, a substituted of unsubstituted linear alkyl group having 1 to 20 carbon atoms, a substituted or unsubstituted alkoxy group having 1 to 20 carbon atoms, a substituted or unsubstituted thioalkoxy group having 1 to 20 carbon atoms, a substituted or unsubstituted branched or cyclic alkyl group having 3 to 20 carbon atoms, a substituted or unsubstituted alkoxy group having 3 to 20 carbon atoms, a substituted or unsubstituted thioalkoxy group having 3 to 20 carbon atoms, a silyl group, a substituted or unsubstituted keto group having 1 to 20 carbon atoms, a substituted or unsubstituted alkoxycarbonyl group having 2 to 20 carbon atoms, a substituted or unsubstituted aryloxycarbonyl group having 7 to 20 carbon atoms, a cyano group, a carbamoyl group, a haloformyl group, a formyl group, an isocyano group, an isocyanate group, a thiocyanate group, an isothiocyanate group, a hydroxyl group, a nitro group, an amino group, —CF₃, —Cl, —Br, —F, —I, a substituted or unsubstituted alkenyl having 2 to 20 carbon atoms, a substituted or unsubstituted aromatic group having 6 to 30 ring atoms, a substituted or unsubstituted heteroaromatic groups having 5 to 30 ring atoms, a substituted or unsubstituted aryloxy group having 6 to 30 ring atoms, a substituted or unsubstituted heteroaryloxy group having 5 to 30 ring atoms, or a combinations thereof.

Optionally, each of Ar2 to Ar10 is independently selected from:

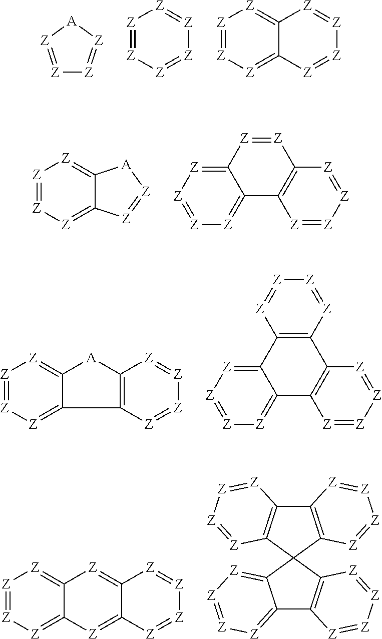

wherein Z is independently selected from CR₂₃ or N;
A is independently selected from NR₂₄, PR₂₄, CR₂₄R₂₅, SiR₂₄R₂₅, O, S, S(═O)₂ or S(═O);
R₂₃, R₂₄ and R₂₅ are each independently selected from —H, -D, a substituted or unsubstituted linear alkyl group having 1 to 20 carbon atoms, a substituted or unsubstituted alkoxy group having 1 to 20 carbon atoms, a substituted or unsubstituted thioalkoxy group having 1 to 20 carbon atoms, a substituted or unsubstituted branched or cyclic alkyl group having 3 to 20 carbon atoms, a substituted or unsubstituted alkoxy group having 3 to 20 carbon atoms, a substituted or unsubstituted thioalkoxy group having 3 to 20 carbon atoms, a silyl group, a substituted or unsubstituted keto group having 1 to 20 carbon atoms, a substituted or unsubstituted alkoxycarbonyl group having 2 to 20 carbon atoms, a substituted or unsubstituted aryloxycarbonyl group having 7 to 20 carbon atoms, a cyano group, a carbamoyl group, a haloformyl group, a formyl group, an isocyano group, an isocyanate group, a thiocyanate group, an isothiocyanate group, a hydroxyl group, a nitro group, an amino group, —CF₃, —Cl, —Br, —F, —I, a substituted or unsubstituted alkenyl having 2 to 20 carbon atoms, a substituted or unsubstituted aromatic group having 6 to 30 ring atoms, a substituted or unsubstituted heteroaromatic groups having 5 to 30 ring atoms, a substituted or unsubstituted aryloxy group having 6 to 30 ring atoms, a substituted or unsubstituted heteroaryloxy group having 5 to 30 ring atoms, or a combinations thereof.

Optionally, the third compound is selected from:

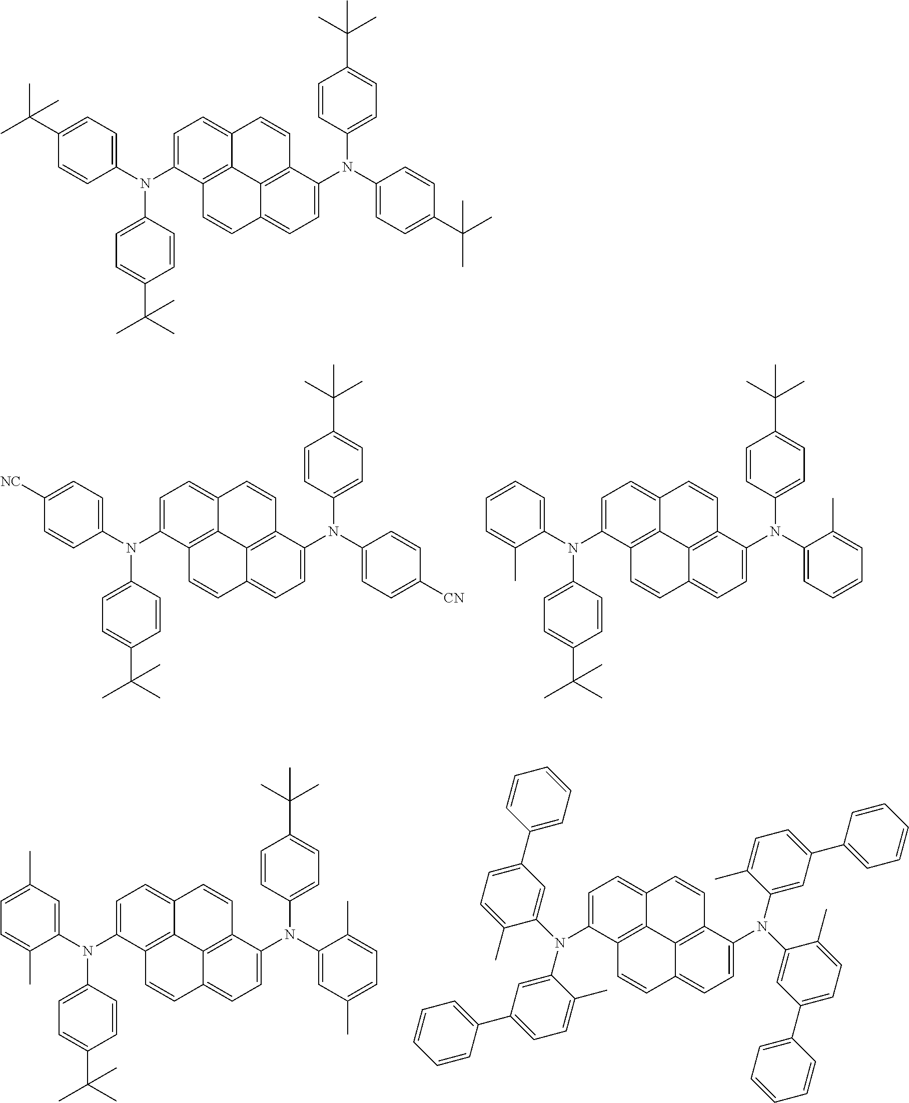

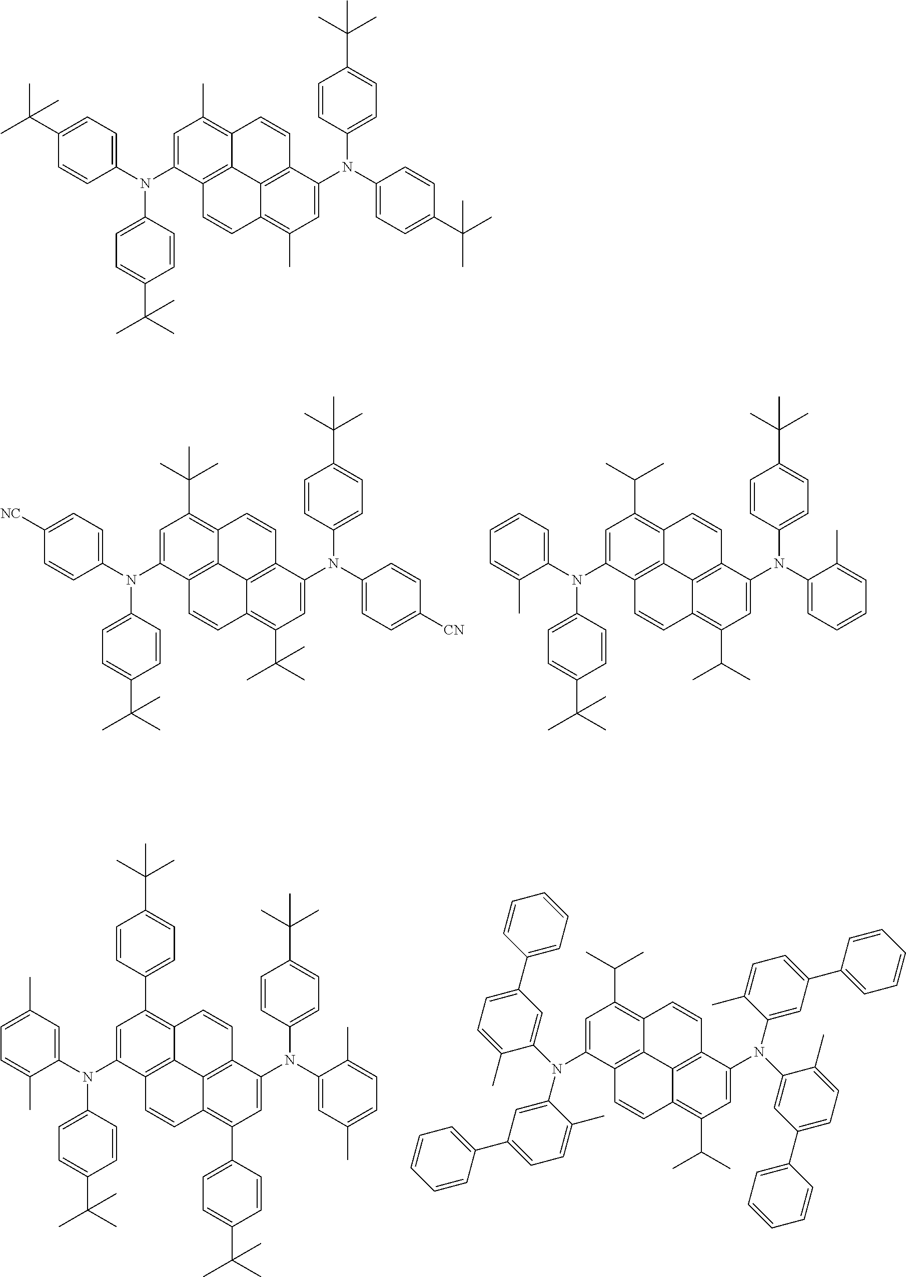

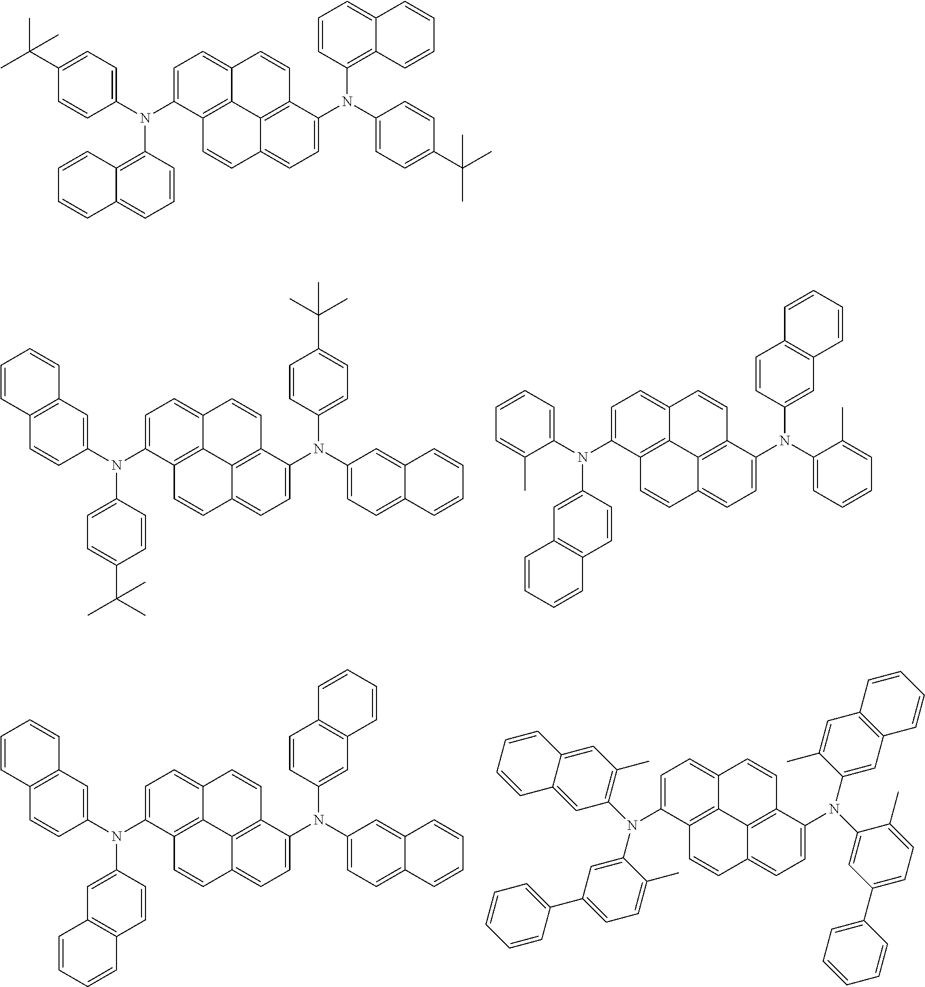

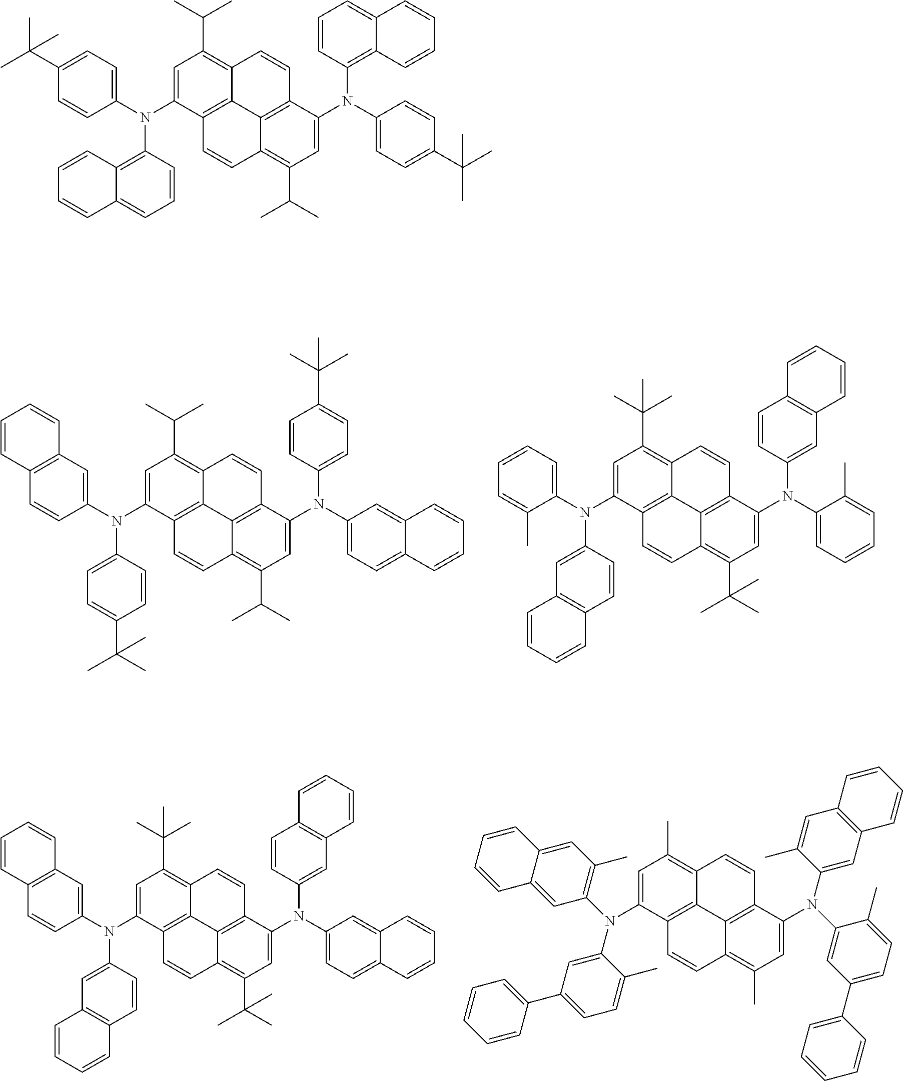

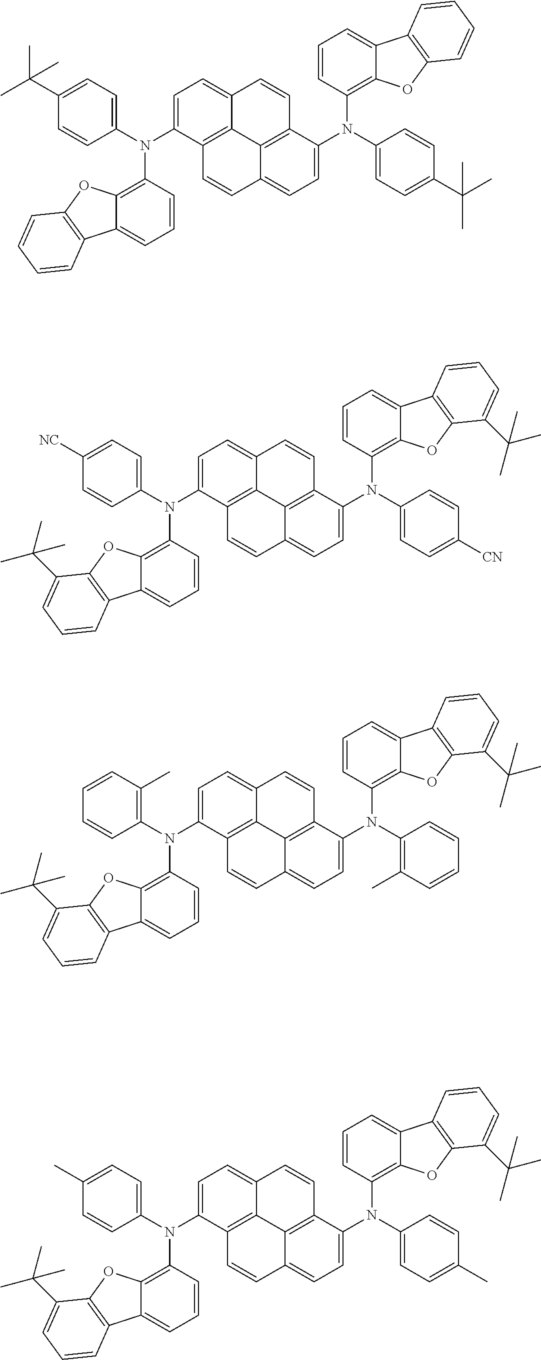

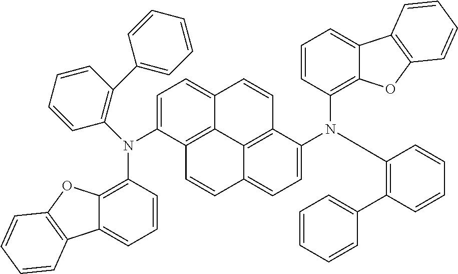 [SMILES: c1ccc(-c2ccccc2N(c2ccc3ccc4c(N(c5ccccc5-c5ccccc5)c5cccc6c5oc5ccccc56)ccc5ccc2c3c54)c2cccc3c2oc2ccccc23)cc1]

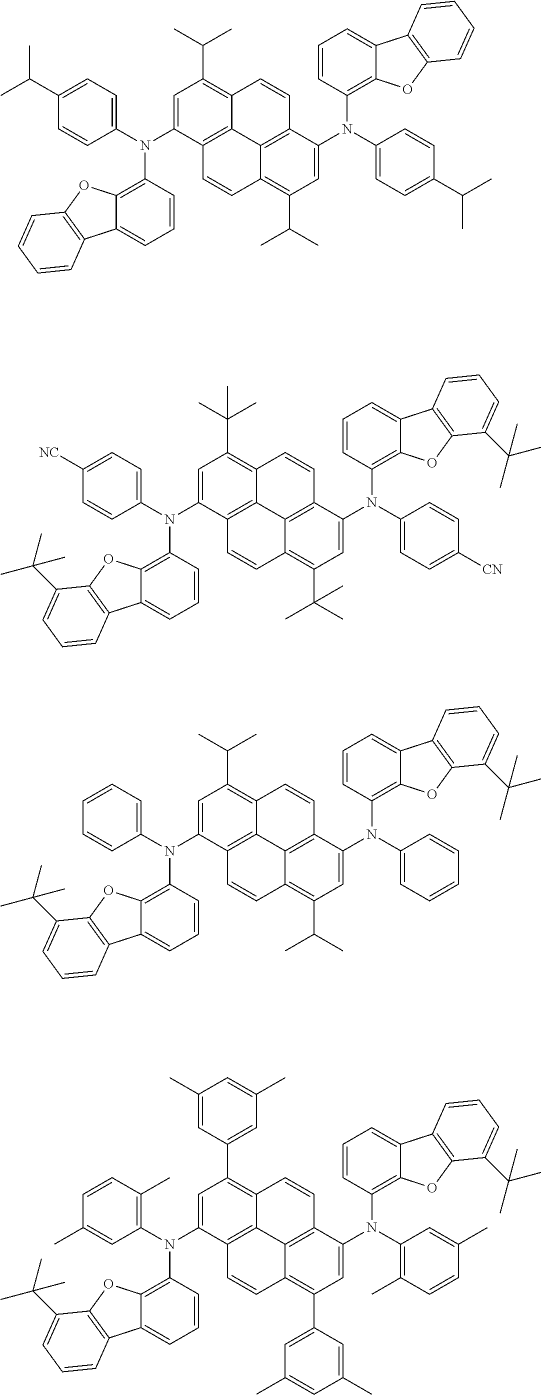

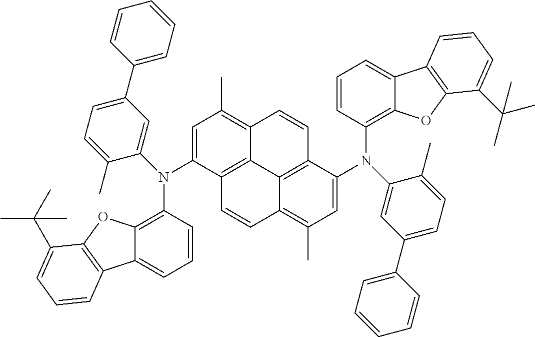 [SMILES: Cc1ccc(-c2ccccc2)cc1N(c1cc(C)c2ccc3c(N(c4cc(-c5ccccc5)ccc4C)c4cccc5c4oc4c(C(C)(C)C)cccc45)cc(C)c4ccc1c2c43)c1cccc2c1oc1c(C(C)(C)C)cccc12]

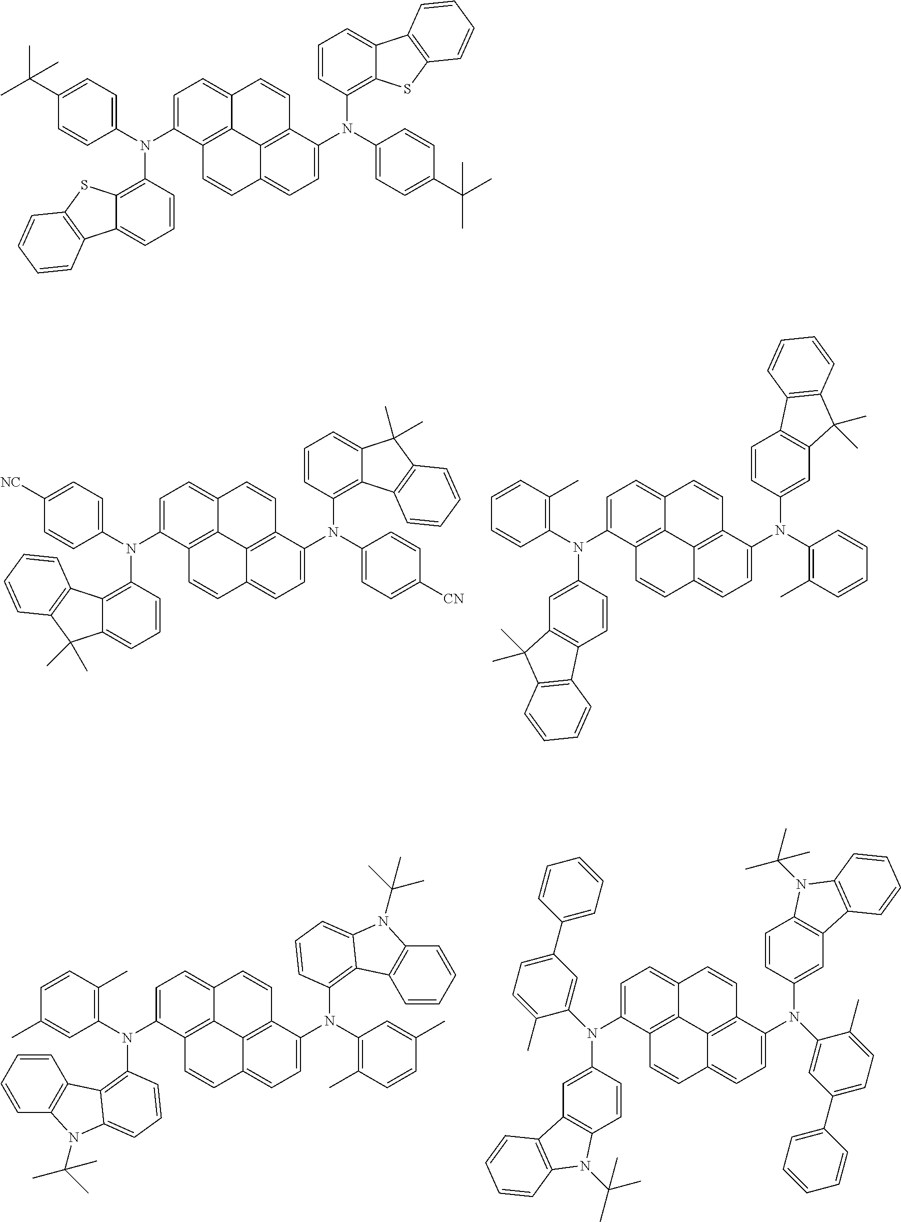

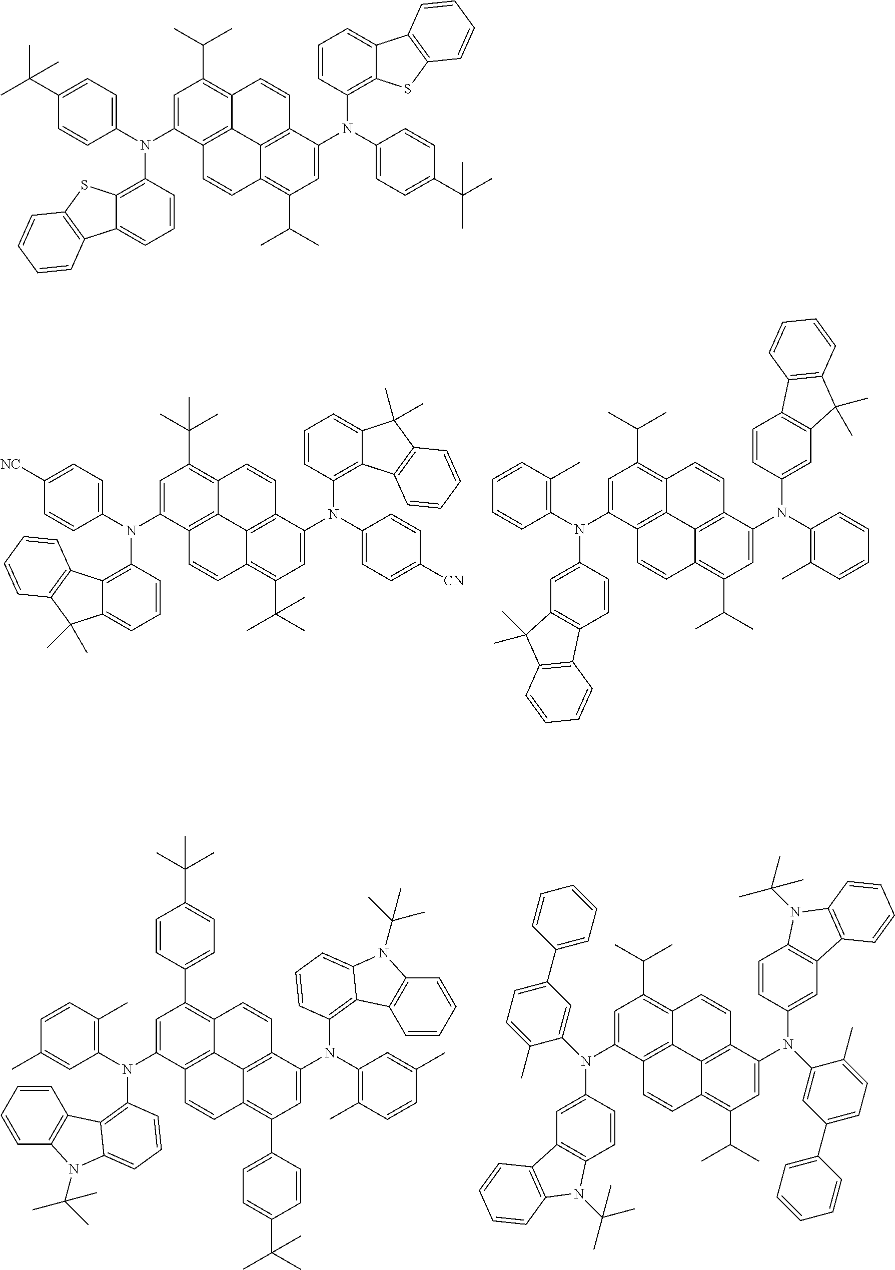

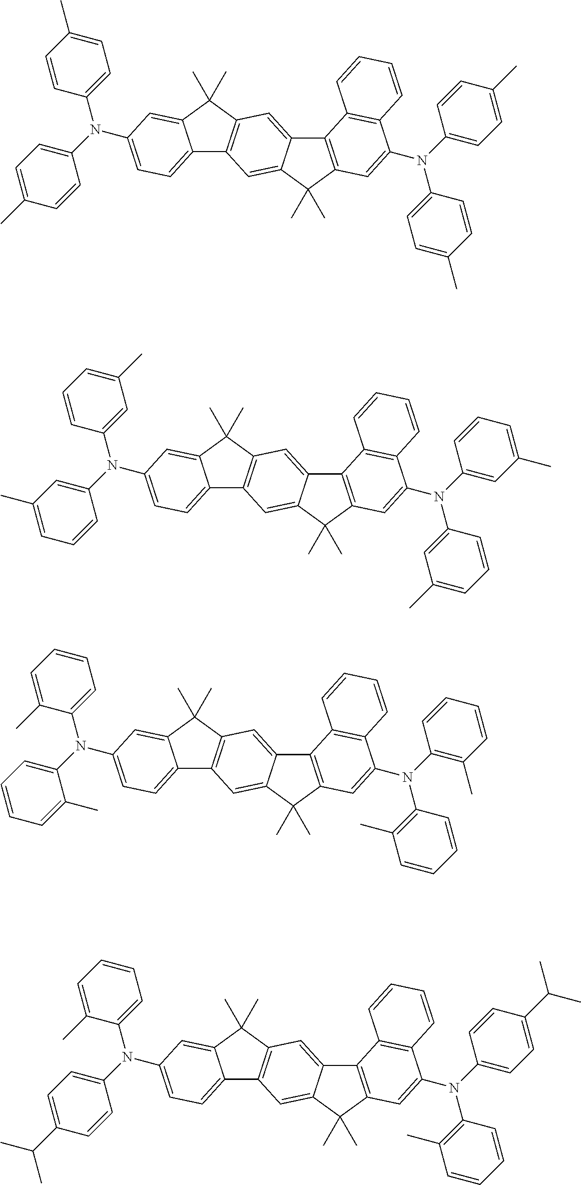

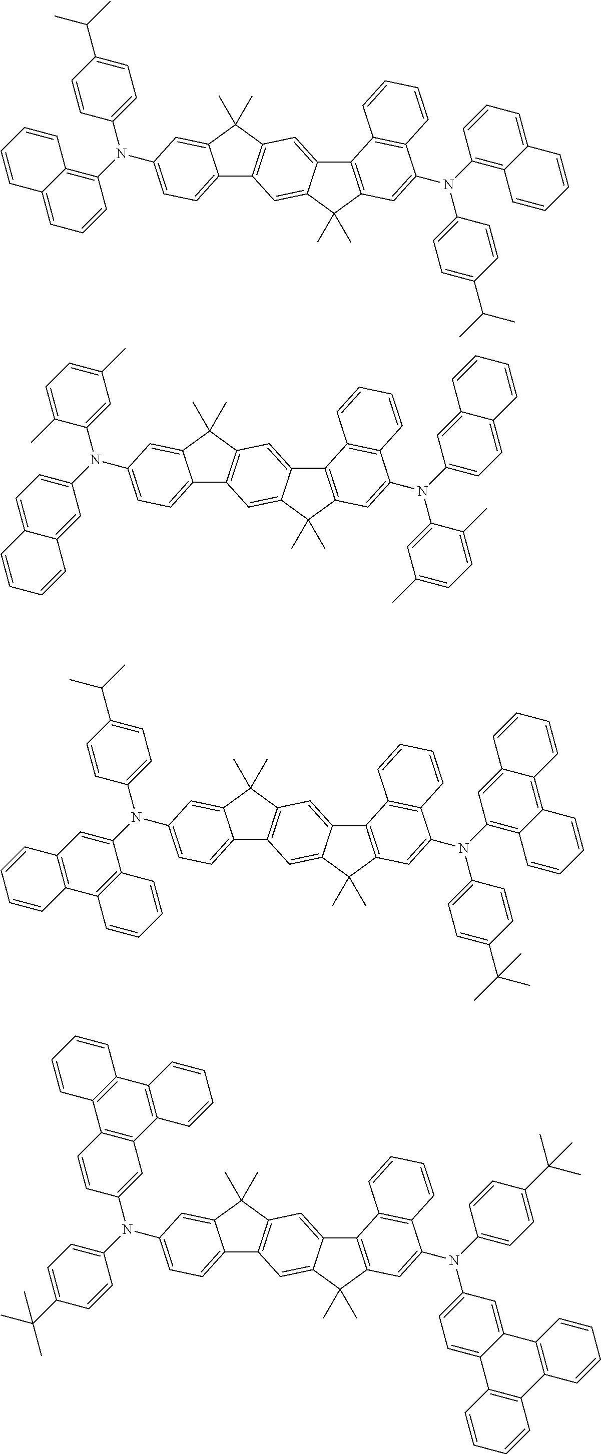

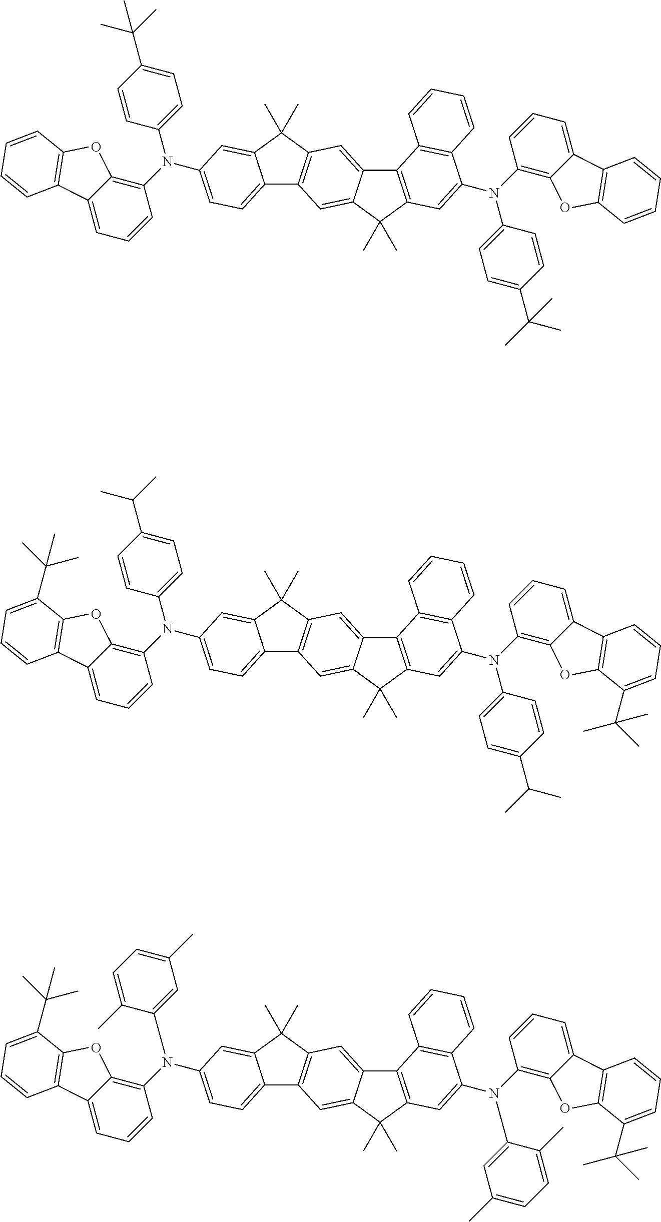 [SMILES: CC(C)(C)c1ccc(N(c2ccc3c(c2)C(C)(C)c2cc4c(cc2-3)C(C)(C)c2cc(N(c3ccc(C(C)(C)C)cc3)c3cccc5c3oc3ccccc35)c3ccccc3c2-4)c2cccc3c2oc2ccccc23)cc1 ; CC(C)c1ccc(N(c2ccc3c(c2)C(C)(C)c2cc4c(cc2-3)C(C)(C)c2cc(N(c3ccc(C(C)C)cc3)c3cccc5c3oc3c(C(C)(C)C)cccc35)c3ccccc3c2-4)c2cccc3c2oc2c(C(C)(C)C)cccc23)cc1 ; Cc1ccc(C)c(N(c2ccc3c(c2)C(C)(C)c2cc4c(cc2-3)C(C)(C)c2cc(N(c3cc(C)ccc3C)c3cccc5c3oc3c(C(C)(C)C)cccc35)c3ccccc3c2-4)c2cccc3c2oc2c(C(C)(C)C)cccc23)c1]

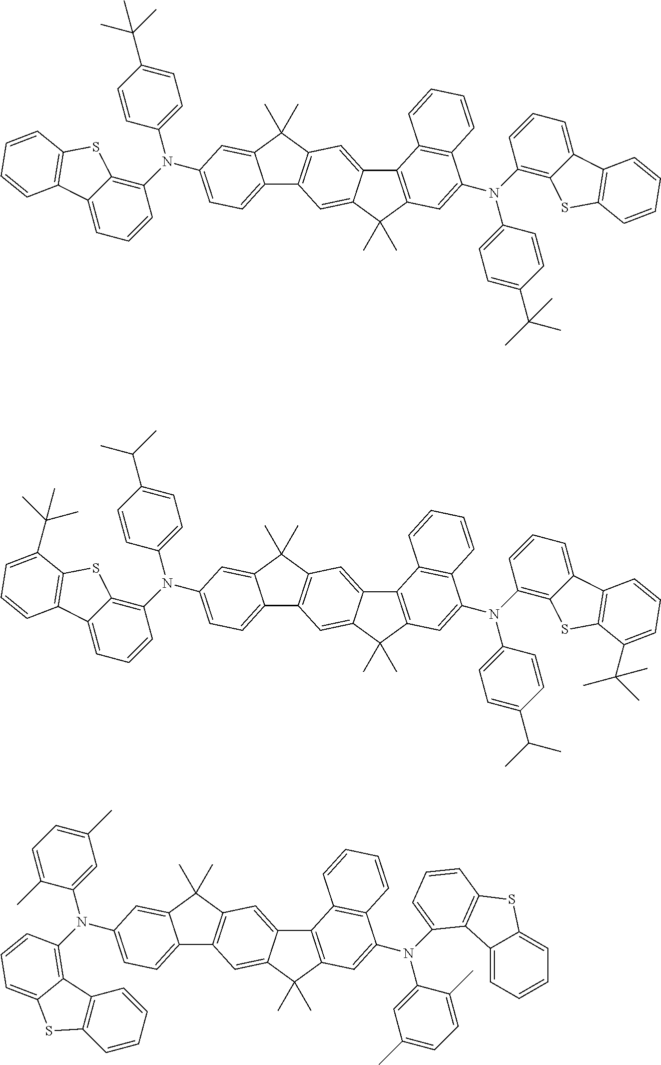 [SMILES: CC(C)(C)c1ccc(N(c2ccc3c(c2)C(C)(C)c2cc4c(cc2-3)C(C)(C)c2cc(N(c3ccc(C(C)(C)C)cc3)c3cccc5c3sc3ccccc35)c3ccccc3c2-4)c2cccc3c2sc2ccccc23)cc1 ; CC(C)c1ccc(N(c2ccc3c(c2)C(C)(C)c2cc4c(cc2-3)C(C)(C)c2cc(N(c3ccc(C(C)C)cc3)c3cccc5c3sc3c(C(C)(C)C)cccc35)c3ccccc3c2-4)c2cccc3c2sc2c(C(C)(C)C)cccc23)cc1 ; Cc1ccc(C)c(N(c2ccc3c(c2)C(C)(C)c2cc4c(cc2-3)C(C)(C)c2cc(N(c3cc(C)ccc3C)c3cccc5sc6ccccc6c35)c3ccccc3c2-4)c2cccc3sc4ccccc4c23)c1]

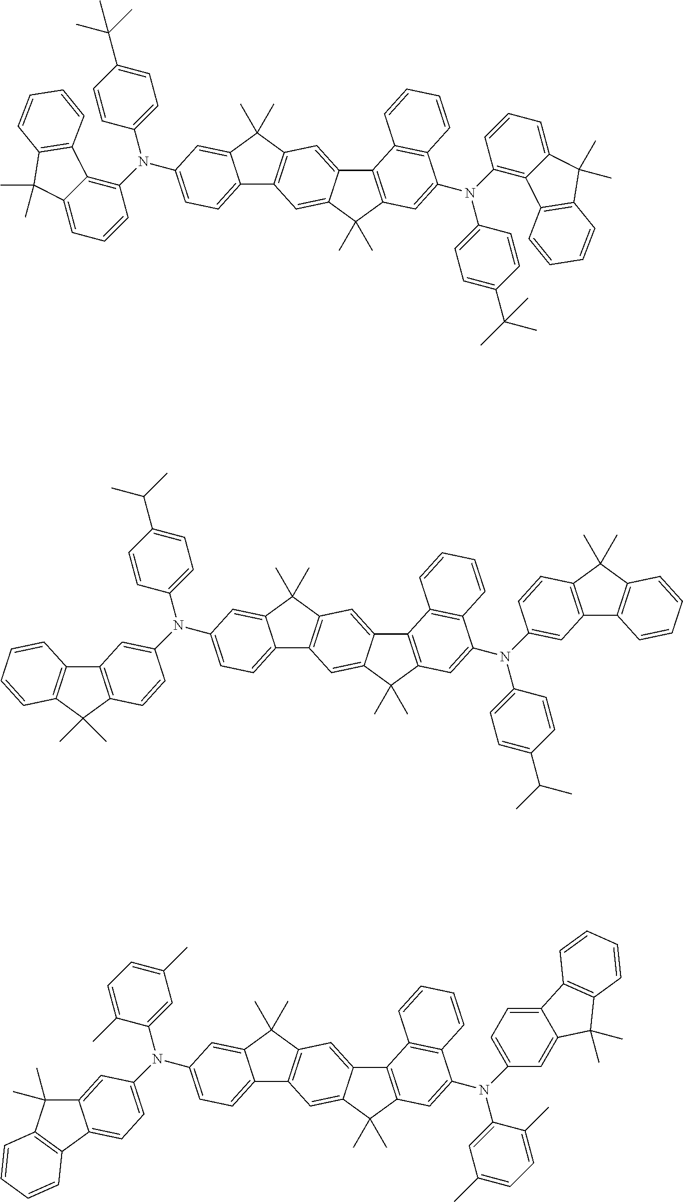

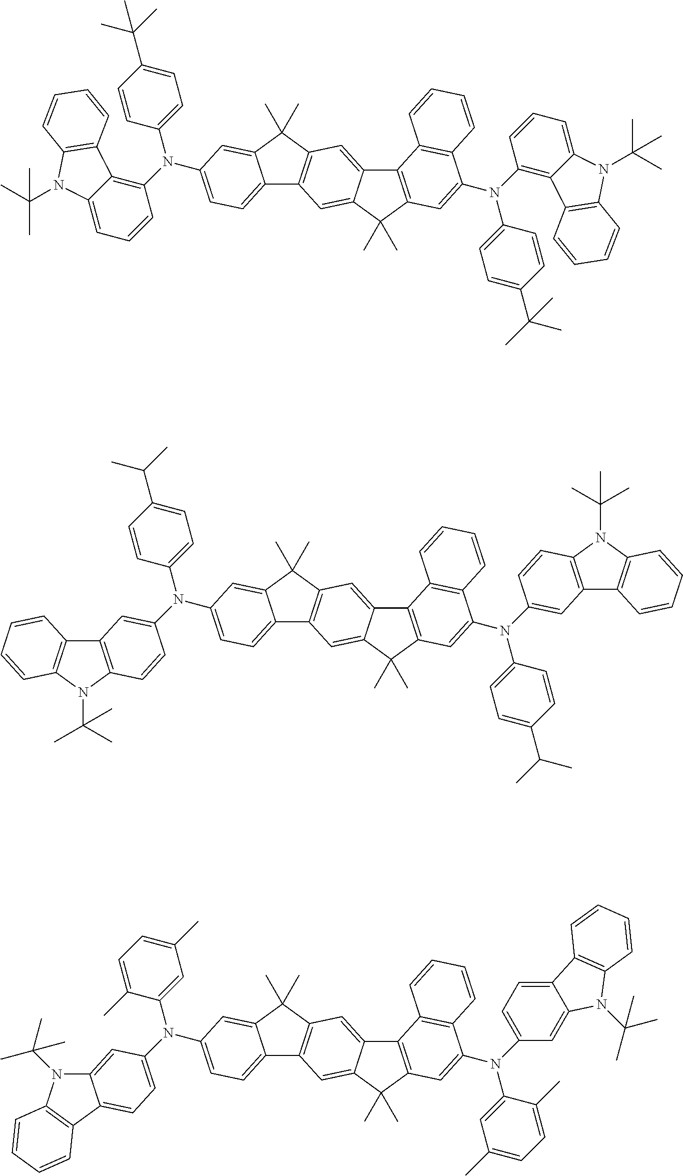

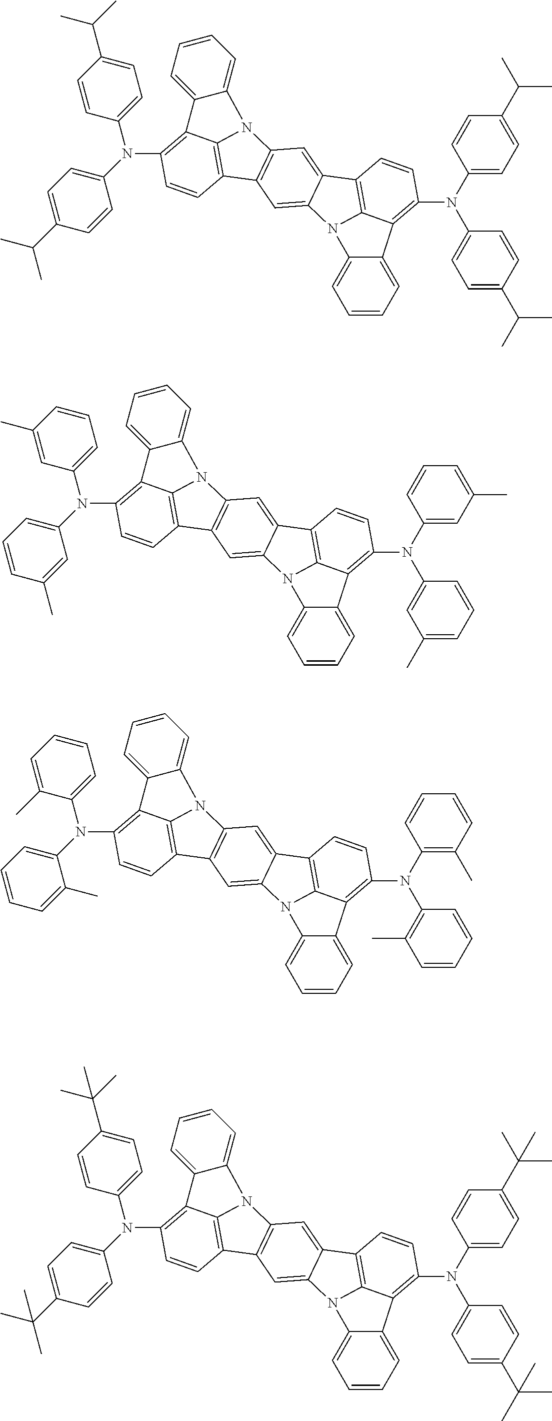

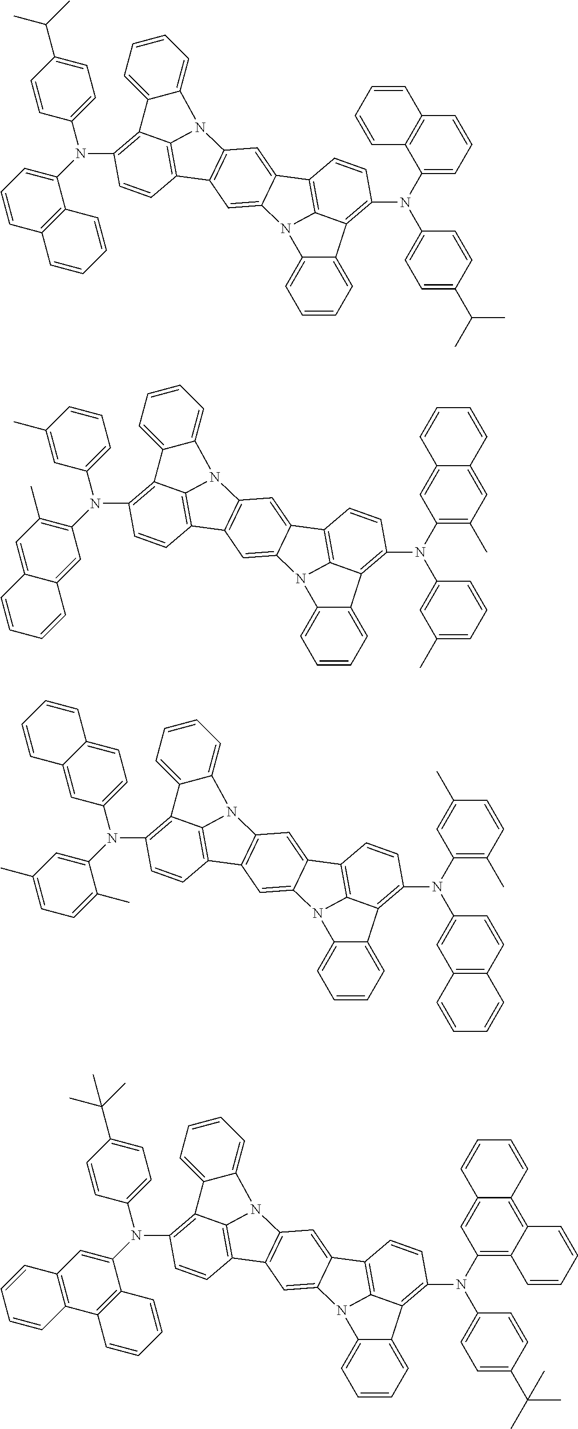

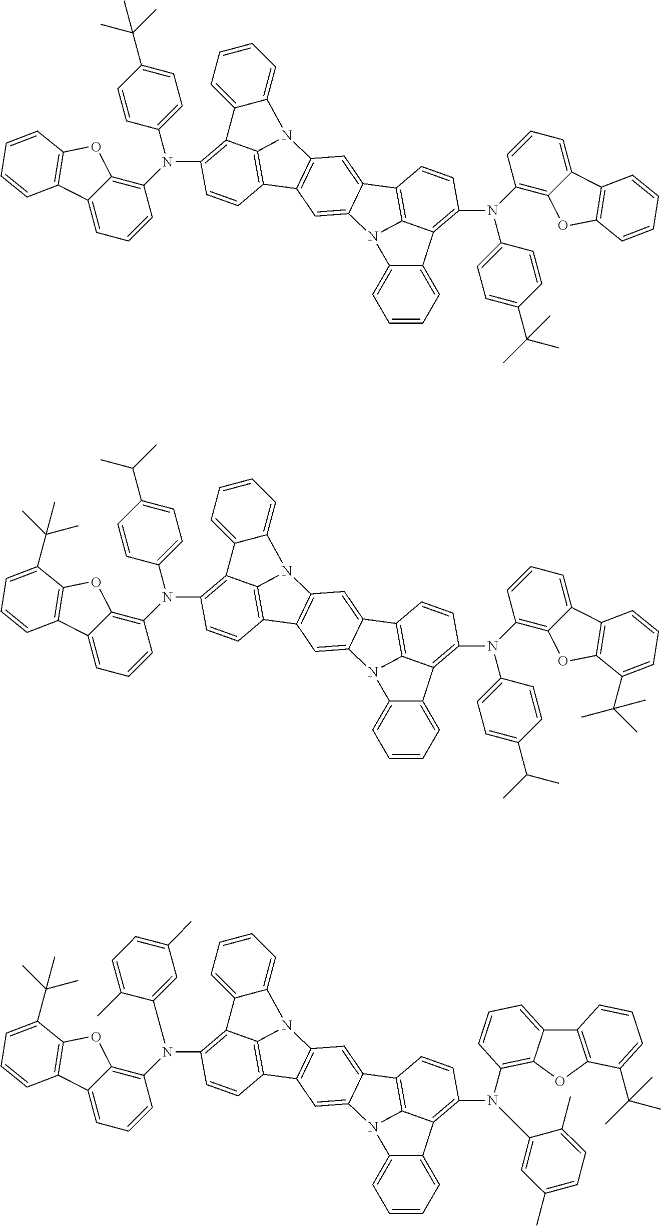 [SMILES: CC(C)(C)c1ccc(N(c2cccc3c2oc2ccccc23)c2ccc3c4cc5c(cc4n4c6ccccc6c2c34)c2ccc(N(c3ccc(C(C)(C)C)cc3)c3cccc4c3oc3ccccc34)c3c4ccccc4n5c23)cc1 ; CC(C)c1ccc(N(c2cccc3c2oc2c(C(C)(C)C)cccc23)c2ccc3c4cc5c(cc4n4c6ccccc6c2c34)c2ccc(N(c3ccc(C(C)C)cc3)c3cccc4c3oc3c(C(C)(C)C)cccc34)c3c4ccccc4n5c23)cc1 ; Cc1ccc(C)c(N(c2cccc3c2oc2c(C(C)(C)C)cccc23)c2ccc3c4cc5c(cc4n4c6ccccc6c2c34)c2ccc(N(c3cc(C)ccc3C)c3cccc4c3oc3c(C(C)(C)C)cccc34)c3c4ccccc4n5c23)c1]

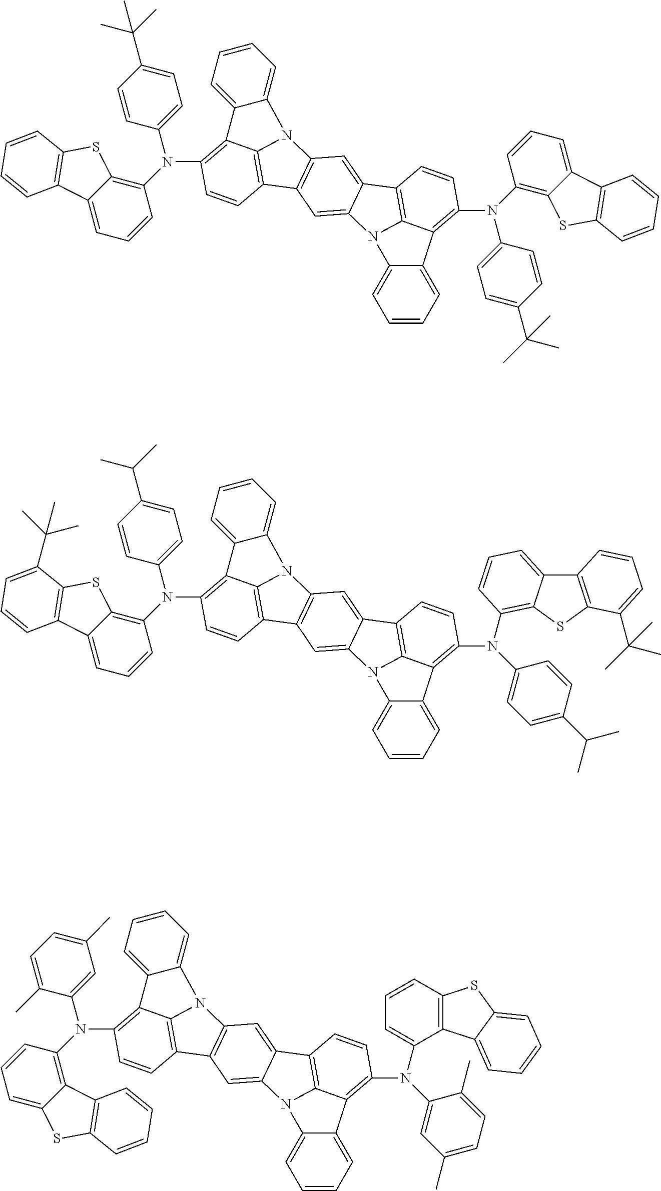 [SMILES: CC(C)(C)c1ccc(N(c2cccc3c2sc2ccccc23)c2ccc3c4cc5c(cc4n4c6ccccc6c2c34)c2ccc(N(c3ccc(C(C)(C)C)cc3)c3cccc4c3sc3ccccc34)c3c4ccccc4n5c23)cc1 ; CC(C)c1ccc(N(c2cccc3c2sc2c(C(C)(C)C)cccc23)c2ccc3c4cc5c(cc4n4c6ccccc6c2c34)c2ccc(N(c3ccc(C(C)C)cc3)c3cccc4c3sc3c(C(C)(C)C)cccc34)c3c4ccccc4n5c23)cc1 ; Cc1ccc(C)c(N(c2cccc3sc4ccccc4c23)c2ccc3c4cc5c(cc4n4c6ccccc6c2c34)c2ccc(N(c3cc(C)ccc3C)c3cccc4sc6ccccc6c34)c3c4ccccc4n5c23)c1]

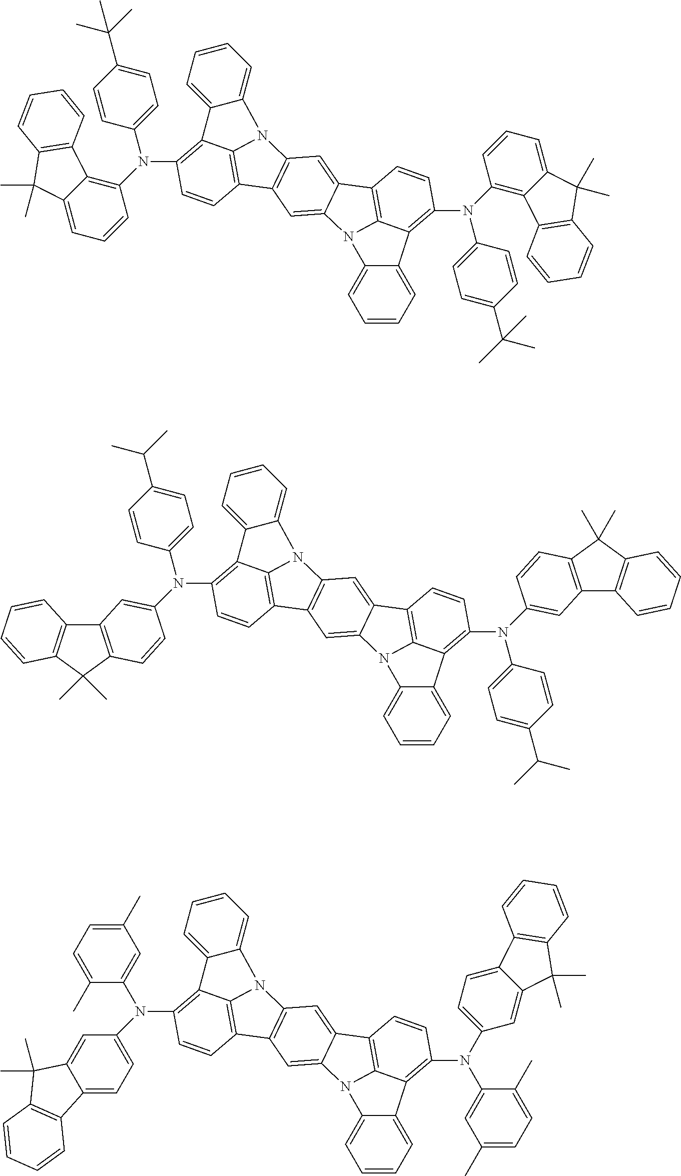

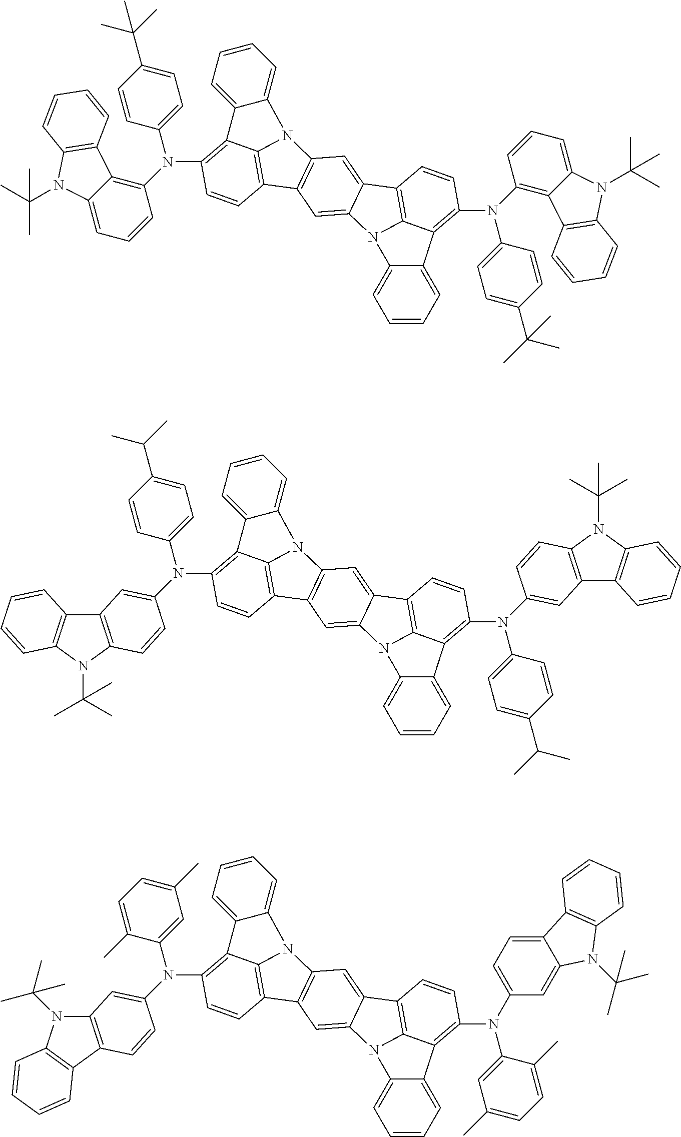

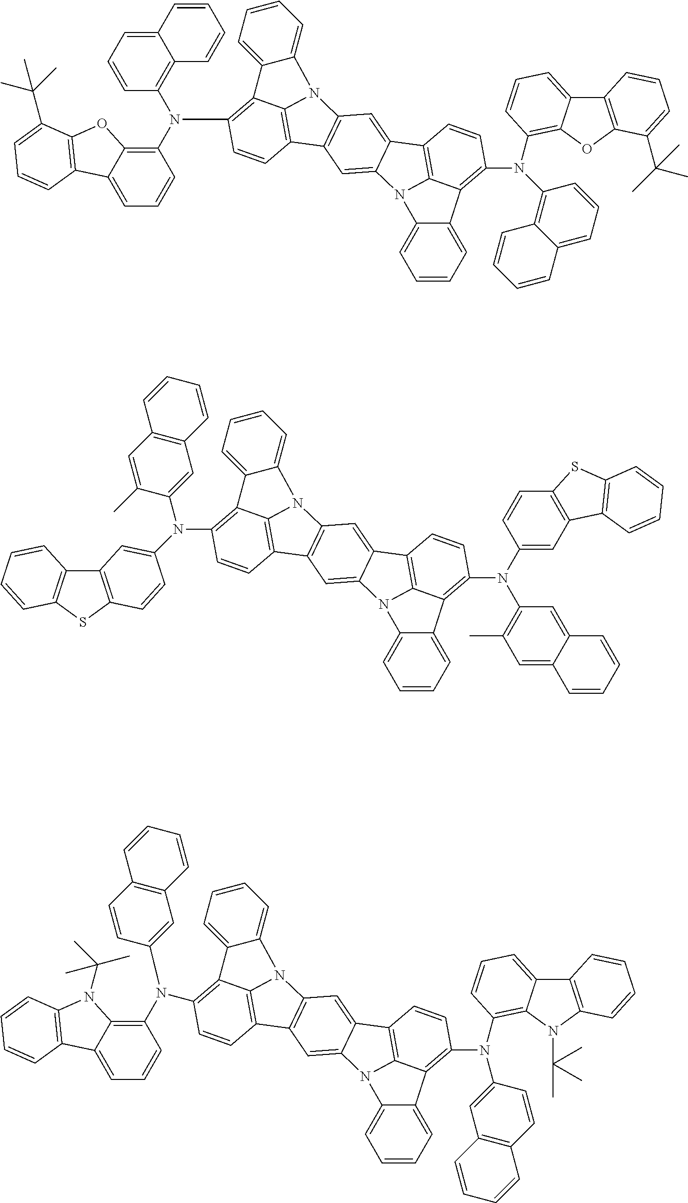 [SMILES: CC(C)(C)c1cccc2c1oc1c(N(c3cccc4ccccc34)c3ccc4c5cc6c(cc5n5c7ccccc7c3c45)c3ccc(N(c4cccc5ccccc45)c4cccc5c4oc4c(C(C)(C)C)cccc45)c4c5ccccc5n6c34)cccc12 ; Cc1cc2ccccc2cc1N(c1ccc2sc3ccccc3c2c1)c1ccc2c3cc4c(cc3n3c5ccccc5c1c23)c1ccc(N(c2ccc3sc5ccccc5c3c2)c2cc3ccccc3cc2C)c2c3ccccc3n4c12 ; CC(C)(C)n1c2ccccc2c2cccc(N(c3ccc4ccccc4c3)c3ccc4c5cc6c(cc5n5c7ccccc7c3c45)c3ccc(N(c4ccc5ccccc5c4)c4cccc5c7ccccc7n(C(C)(C)C)c45)c4c5ccccc5n6c34)c21]

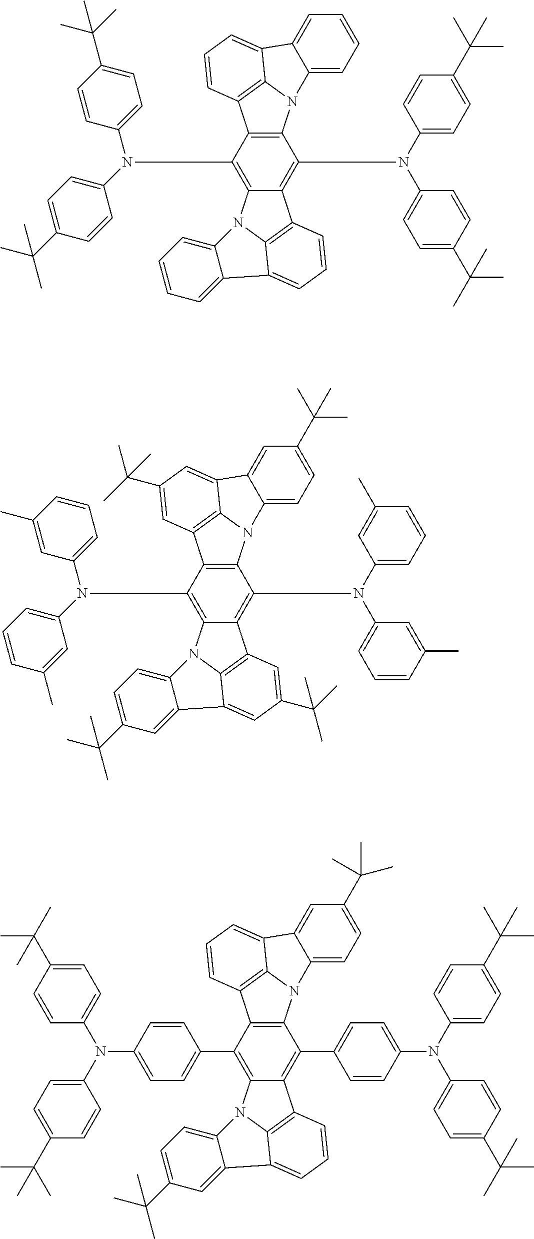

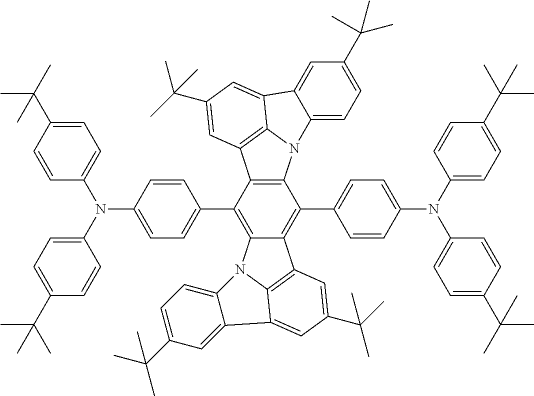 [SMILES: CC(C)(C)c1ccc(N(c2ccc(-c3c4c5cc(C(C)(C)C)cc6c7cc(C(C)(C)C)ccc7n(c4c(-c4ccc(N(c7ccc(C(C)(C)C)cc7)c7ccc(C(C)(C)C)cc7)cc4)c4c7cc(C(C)(C)C)cc8c9cc(C(C)(C)C)ccc9n(c34)c87)c65)cc2)c2ccc(C(C)(C)C)cc2)cc1]

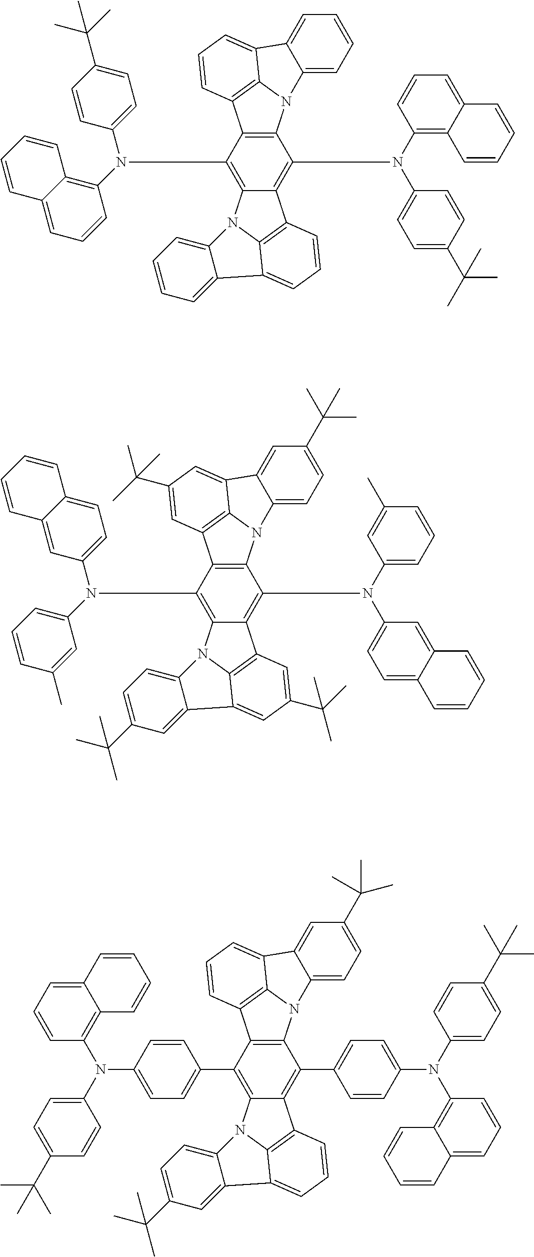 [SMILES: CC(C)(C)c1ccc(N(c2cccc3ccccc23)c2c3c4cccc5c6ccccc6n(c3c(N(c3ccc(C(C)(C)C)cc3)c3cccc6ccccc36)c3c6cccc7c8ccccc8n(c23)c76)c54)cc1 ; Cc1cccc(N(c2ccc3ccccc3c2)c2c3c4cc(C(C)(C)C)cc5c6cc(C(C)(C)C)ccc6n(c3c(N(c3cccc(C)c3)c3ccc6ccccc6c3)c3c6cc(C(C)(C)C)cc7c8cc(C(C)(C)C)ccc8n(c23)c76)c54)c1 ; CC(C)(C)c1ccc(N(c2ccc(-c3c4c5cccc6c7cc(C(C)(C)C)ccc7n(c4c(-c4ccc(N(c7ccc(C(C)(C)C)cc7)c7cccc8ccccc78)cc4)c4c7cccc8c9cc(C(C)(C)C)ccc9n(c34)c87)c65)cc2)c2cccc3ccccc23)cc1]

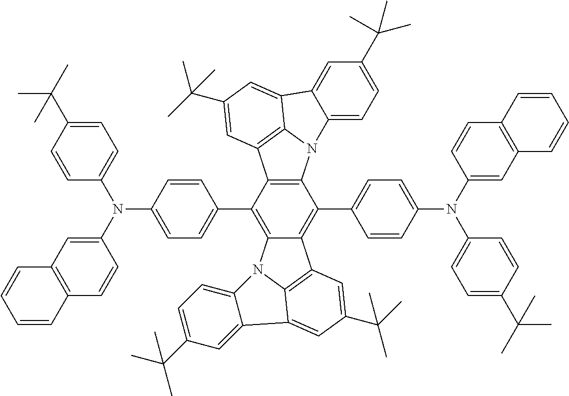 [SMILES: CC(C)(C)c1ccc(N(c2ccc(-c3c4c5cc(C(C)(C)C)cc6c7cc(C(C)(C)C)ccc7n(c4c(-c4ccc(N(c7ccc(C(C)(C)C)cc7)c7ccc8ccccc8c7)cc4)c4c7cc(C(C)(C)C)cc8c9cc(C(C)(C)C)ccc9n(c34)c87)c65)cc2)c2ccc3ccccc3c2)cc1]

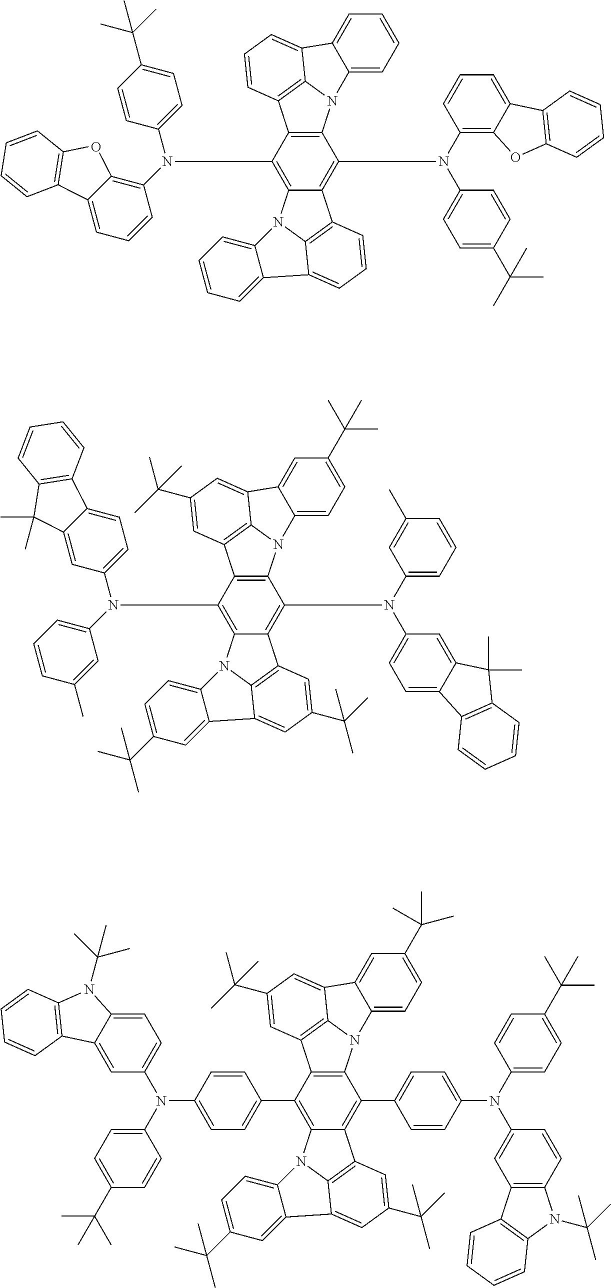

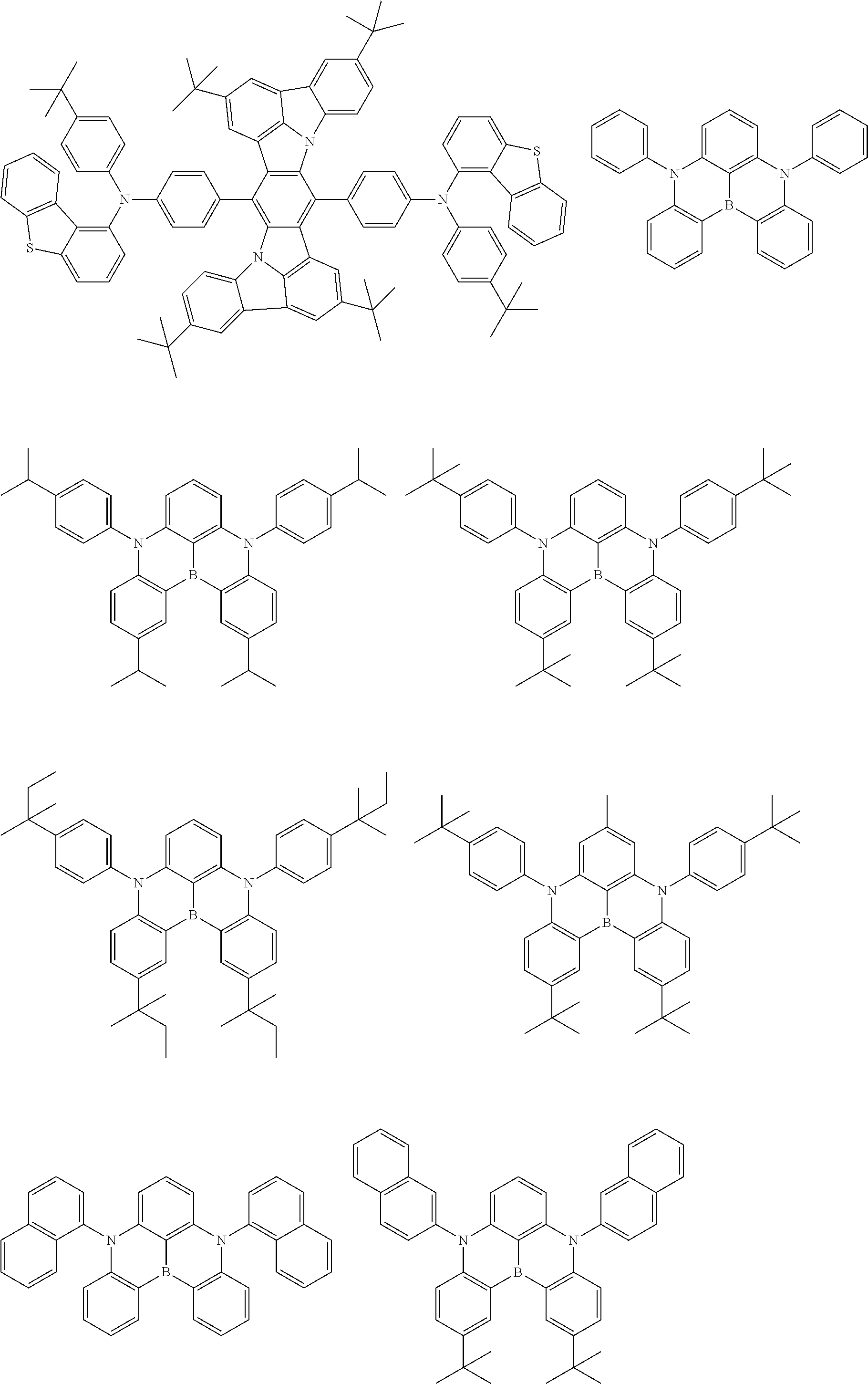

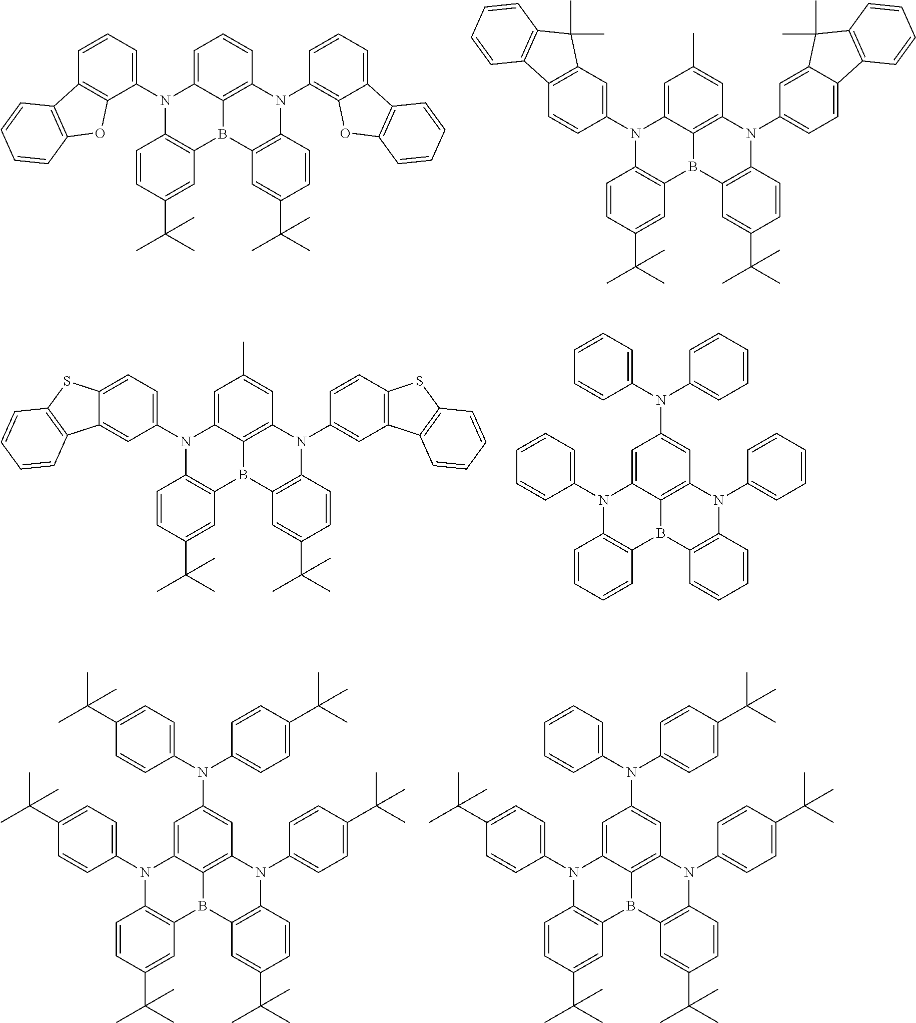

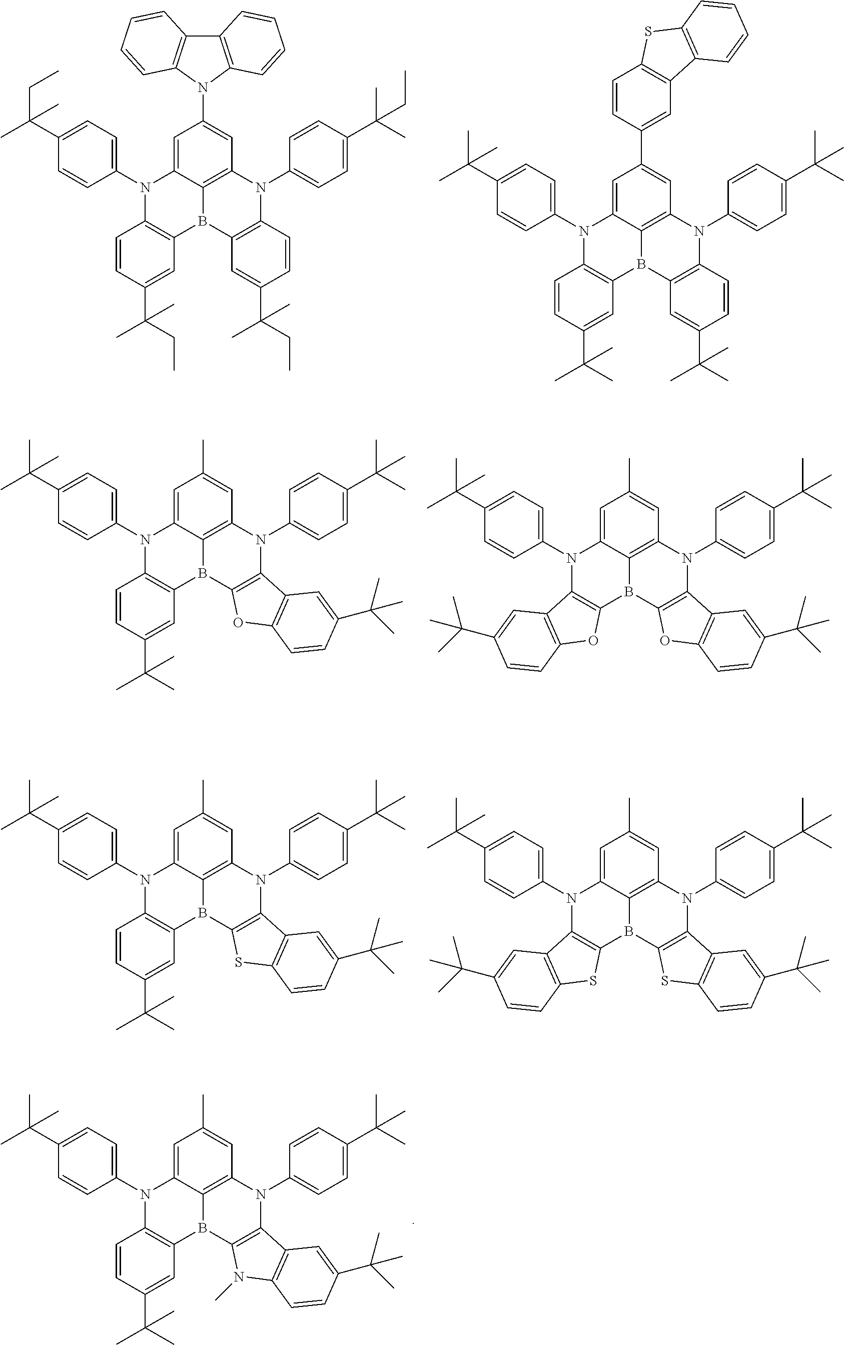

The present disclosure further provides a light-emitting device including: P
a pair of electrodes comprising a first electrode and a second electrode;
an organic functional layer disposed between the first electrode and the second electrode;
wherein a material of the organic functional layer includes a composition as described above or a mixture as described above.

The present disclosure further provides a display panel including a light-emitting device as described above.

By using a composition formed by a first compound having a structure represented by formula (1) and a second compound having a structure represented by formula (2) of the present disclosure, the charge balance and energy transmission in the light-emitting devices are improved, and the luminous efficiency and luminous lifetime of the light-emitting device are also improved.

### BRIEF DESCRIPTION OF THE DRAWINGS

In order to more clearly describe the technical solutions in embodiments of the present disclosure, the drawings used for describing the embodiments will be briefly introduced below. Apparently, the drawings described below are only directed to some embodiments of the present disclosure, and for a person with ordinary skills in the art, without expenditure of creative labor, other drawings can be derived on the basis of these drawings.

FIG. 1 is a schematic structural diagram of a light-emitting device according to an embodiment of the present disclosure.

### DETAILED DESCRIPTION

Hereinafter, technical solutions in embodiments of the present disclosure will be clearly and completely described with reference to the accompanying drawings in embodiments of the present disclosure. Apparently, the described embodiments comprise but are not limited to the embodiments of the present disclosure. Other embodiments that can be obtained by a person with ordinary skill in the art on the basis of the embodiments in the present disclosure without creative labor belong to the protection scope of the present disclosure. In addition, it should be understood that the specific embodiments described herein are intended only to illustrate and explain the present disclosure and are not intended to limit the present disclosure. In the present disclosure, in the absence of contrary description, directional words such as “up” and “down” generally refer to the up and down in the actual use or working state of a device, and specifically the drawing direction in the accompanying drawings. While “inside” and “outside” are for profile of the device. In the present disclosure, “optionally”, “optional” and “alternatively” means dispensable, i.e., selected from any one of the two parallel solutions of “with” and “without”. If there are multiple “optional” in a technical solution, unless otherwise specified and there is no contradiction or mutual restriction, each “optional” solution is independent. In the present disclosure, the technical features described in open-type include a closed-type technical solution composed of the listed features and an open-type technical solution including the listed features.

In the present disclosure, aromatic group, aryl group and aromatic ring system have the same meaning and are interchangeable. “Aryl group or aromatic group or aromatic ring system” refers to an aromatic hydrocarbon group derived from an aromatic ring compound by removing one hydrogen atom, which can be a monocyclic aromatic group, a condensed aromatic group or a polycyclic aromatic group. For polycyclic ring species, at least one is an aromatic ring system. For example, “a substituted or unsubstituted aryl having 6 to 40 ring atoms” refers to an aryl group having 6 to 40 ring atoms, preferably a substituted or unsubstituted aryl group having 6 to 30 ring atoms, more preferably a substituted or unsubstituted aryl group having 6 to 18 ring atoms, particularly preferably a substituted or unsubstituted aryl having 6 to 14 ring atoms, and the above aryl groups are optionally further substituted. Suitable examples include, but are not limited to, phenyl, biphenyl, terphenyl, naphthyl, anthracenyl, phenanthrenyl, fluoranthenyl, triphenylene, pyrenyl, perylene, tetraphenyl, fluorenyl, perylene, acenaphthylene, and derivatives thereof. It can be understood that a plurality of aryl groups may also be interrupted by short non-aromatic units (e.g. <10% of non-H atoms, such as C, N or O atoms), such as acenaphthylene, fluorene, or 9,9-diarylfluorene, triarylamine, diaryl ether systems should also be included in the definition of aryl groups.

In the present disclosure, heteroaromatic group, heteroaryl group and heteroaromatic ring system have the same meaning and are interchangeable. “Heteroaryl group or heteroaromatic group or heteroaromatic ring system” means that at least one carbon atom of the aryl group is replaced by a non-carbon atom, and the non-carbon atom can be an N atom, an O atom, an S atom, or the like. For example, “a substituted or unsubstituted heteroaryl having 5 to 40 ring atoms” refers to a heteroaryl group having 5 to 40 ring atoms, preferably a substituted or unsubstituted heteroaryl group having 6 to 30 ring atoms, more preferably a substituted or unsubstituted heteroaryl group having 6 to 18 ring atoms, particularly preferably a substituted or unsubstituted heteroaryl group having 6 to 14 ring atoms, and the heteroaryl group is optionally further substituted. Suitable examples include, but are not limited to: thienyl, furyl, pyrrolyl, diazolyl, triazolyl, imidazolyl, pyridyl, bipyridyl, pyrimidinyl, triazinyl, acridinyl, pyridazinyl, pyrazinyl, quinolinyl, isoquinolinyl, quinazolinyl, quinoxalinyl, phthalazinyl, pyridopyrimidinyl, pyridopyrazinyl, benzothienyl, benzofuranyl, indolyl, pyrroloimidazolyl, pyrrolopyrrolyl, thienopyrrolyl, thienothienyl, furopyrrolyl, furfuranyl, thienofuranyl, benzisoxazolyl, benzisothiazolyl, benzimidazolyl, o-naphthyridinyl, phenanthridinyl, permidyl, quinazolinonyl, dibenzothienyl, dibenzofuranyl, carbazolyl and derivatives thereof.

In the present disclosure, “substituted” means that one or more hydrogen atoms in a substituent are replaced by one or more substituents. When the same substituent occurs multiple times, it may be independently selected from different groups, for example, when the formula contains a plurality of R, then R may be independently selected from different groups. In the embodiments of the present disclosure, “substituted or unsubstituted” means that the defined group may be substituted or may not be substituted. When a defined group is substituted, it is understood that the defined group may be substituted by one or more substituents R, and the substituent R is selected from, but not limited to, deuterium atom, cyano group, isocyano group, nitro group or halogen, an alkyl group having 1 to 20 carbon atoms, a heterocyclyl group having 3 to 20 ring atoms, an aromatic group having 6 to 20 ring atoms, a heteroaromatic group having 5 to 20 ring atoms, —NR′R″, silyl group, carbonyl group, alkoxycarbonyl group, an aryloxycarbonyl group, a carbamoyl group, a haloformyl group, a formyl group, an isocyano group, an isocyanate group, a thiocyanate group, an isothiocyanate group, a hydroxyl group, and trifluoromethyl group, and the above groups may be further substituted by substituents acceptable in the art. R′ and R″ in —NR′R″ are independently selected from, but not limited to, H, deuterium atom, cyano group, isocyano group, nitro group or halogen, an alkyl group having 1 to 10 carbon atoms, a heterocyclyl group having 3 to 20 ring atoms, an aromatic group having 6 to 20 ring atoms, and a heteroaromatic group having 5 to 20 ring atoms. Preferably, R is selected from, but not limited to, deuterium atom, cyano group, isocyano group, nitro group or halogen, an alkyl group having 1 to 10 carbon atoms, a heterocyclyl group having 3 to 10 ring atoms, an aromatic group having 6 to 20 ring atoms, a heteroaromatic group having 5 to 20 ring atoms, silyl group, carbonyl group, alkoxycarbonyl group, an aryloxycarbonyl group, a carbamoyl group, a haloformyl group, a formyl group, an isocyano group, an isocyanate group, a thiocyanate group, an isothiocyanate group, a hydroxyl group, and trifluoromethyl group, and the above groups may be further substituted by substituents acceptable in the art.

In the present disclosure, “amino group” refers to a derivative of amine, which has the structural characteristics of the formula —NR′R″, wherein R′ and R″ have the same meanings as above.

In the present disclosure, “the number of ring atoms” means the number of atoms constituting the ring itself of a structural compound (e.g., a monocyclic compound, a fused ring compound, a cross-linked compound, a carbocyclic compound, a heterocyclic compound) obtained by synthesizing the ring by atomic bonds. In a case that the ring is replaced by a substituent, the atoms contained in the substituent are not included in the ring-forming atoms. The “number of ring atoms” mentioned below has the same meaning unless otherwise specified, for example, the number of ring atoms of benzene ring is 6, the number of ring atoms of naphthalene ring is 10, and the number of ring atoms of thienyl group is 5.

In the present disclosure, “*” connected to a single bond indicates a linkage site or a fusion site.

In the present disclosure, in a case that the linkage site is not specified in a group, it means that any linkage site in a group can be used as a linkage site.

In the present disclosure, in a case that the fusion site is not specified in a group, it means that any fusion site in a group can be used as a fusion site, preferably two or more sites in the adjacent position of the group are fusion sites.

In the present disclosure, when the same group contains a plurality of substituents with the same symbol, each of the substituents may be the same as or different from each other, for example

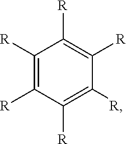

six R's on the phenyl ring may be the same as or different from each other.

In the present disclosure, a single bond connected to a substituent extends through the corresponding ring, meaning that the substituent may be connected to any position of the ring, for example, R in

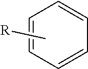

may be connected to any substitutable position of the phenyl ring;

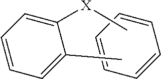

means that

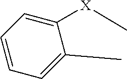

may form a fused ring with an optional position on.

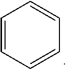

The cyclic alkyl group or cycloalkyl group described in the present disclosure has the same meaning and are interchangeable.

In the present disclosure, “adjacent groups” means that there are no substitutable sites between two substituents.

In the present disclosure, “two adjacent ones of R1, R3 and R5 form a ring with each other” means that a ring system formed by connecting two adjacent ones of R1, R3 and R5 to each other, and the ring system may be selected from an aliphatic hydrocarbon ring, an aliphatic heterocyclic ring, an aromatic hydrocarbon ring or an aromatic heterocyclic ring.

Currently, the performance of the OLED devices is difficult to improve due to low luminous efficiency, stability and lifetime of the light-emitting layer materials currently used in OLED devices.

Sone embodiments of the present disclosure provide a composition comprising at least one first compound and at least one second compound;
the first compound has a structure represented by formula (1):

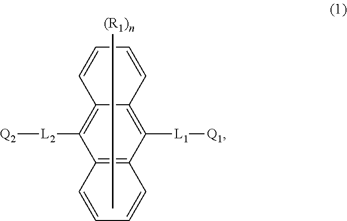

the second compound has a structure represented by formula (2):

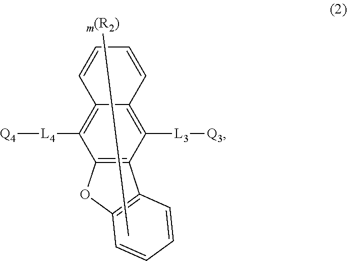

wherein L₁, L₂, L₃ and L₄ are each independently selected from a single bond, a substituted or unsubstituted aromatic group having 6 to 30 ring atoms, a substituted or unsubstituted heteroaromatic group having 5 to 30 ring atoms;
Q₁, Q₂, Q₃ and Q₄ are each independently selected from a substituted or unsubstituted alkyl group having 1 to 20 carbon atoms, a substituted or unsubstituted aromatic group having 6 to 60 ring atoms, a substituted or unsubstituted heteroaromatic group having 5 to 60 ring atoms, or a combination thereof;
R₁ and R₂ are each independently selected from hydrogen, deuterium, a substituted or unsubstituted alkyl group having 1 to 10 carbon atoms, a substituted or unsubstituted aromatic group having 6 to 30 ring atoms, a substituted or unsubstituted heteroaromatic group having 5 to 30 ring atoms; and
n and m are each independently selected from any one integer from 0 to 8.

By using a composition formed by a first compound having a structure represented by formula (1) and a second compound having a structure represented by formula (2) of the present disclosure, the charge balance and energy transmission in the light-emitting devices are improved, and the luminous efficiency and luminous lifetime of the light-emitting device are also improved.

In some embodiments, L1, L2, L3 and L4 are each independently selected from a single bond, a substituted or unsubstituted aromatic group having 6 to 30 ring atoms, a substituted or unsubstituted heteroaromatic group having 5 to 30 ring atoms.

In some embodiments, L1, L2, L3 and L4 are each independently selected from a single bond, a substituted or unsubstituted aromatic group having 6 to 20 ring atoms, a substituted or unsubstituted heteroaromatic group having 5 to 20 ring atoms.

In some embodiments, L₁, L₂, L₃, L₄ are each independently selected from a single bond, phenyl, naphthyl, carbazolyl, dibenzofuranyl, dibenzothienyl, 9,9-dimethylfluorenyl. In a case that any of L₁, L₂, L₃, L₄ is selected from phenyl, any of L₁, L₂, L₃, L₄ is selected from any of the following structures:

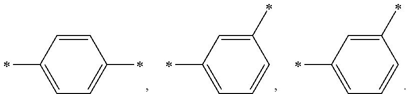

In a case that any one of L₁, L₂, L₃, L₄ is selected from naphthyl, any one of L₁, L₂, L₃, L₄ is selected from the following structure:

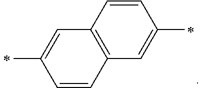

In a case that any one of L₁, L₂, L₃, L₄ is selected from carbazolyl, dibenzofuranyl, dibenzothienyl, or 9,9-dimethylfluorenyl, any one of L₁, L₂, L₃, L₄ is selected from any one of the following structures:

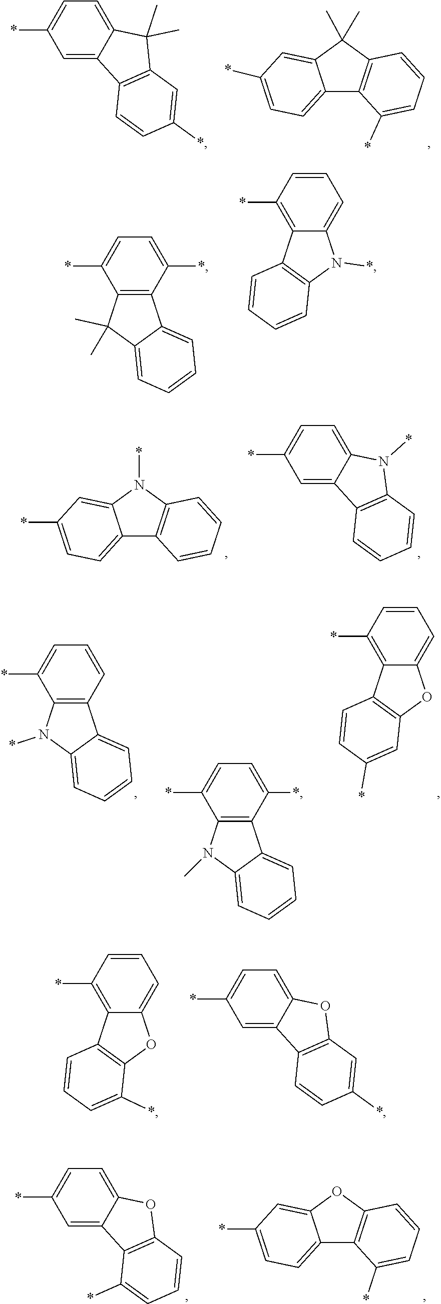

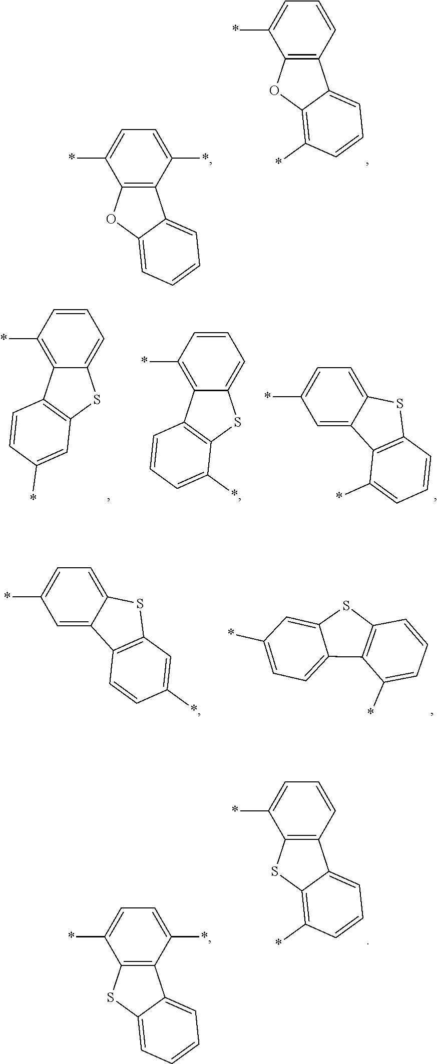

In some embodiments, R₁ and R₂ are each independently selected from hydrogen, deuterium, a substituted or unsubstituted alkyl group having 1 to 10 carbon atoms, a substituted or unsubstituted aromatic group having 6 to 30 ring atoms, a substituted or unsubstituted heteroaromatic group having 5 to 30 ring atoms.

In some embodiments, R₁ and R₂ are each independently selected from hydrogen, deuterium, an unsubstituted alkyl group having 1 to 5 carbon atoms, an unsubstituted aromatic group having 6 to 10 ring atoms.

In some embodiments, each occurrence of R1, R2 is independently selected from hydrogen, deuterium, tert-butyl, or phenyl.

In some embodiments, n is selected from any one integer from 0 to 8, for example, it may be 0, 1, 2, 3, 4, 5, 6, 7 or 8; m is selected from any one integer from 0 to 8, for example, it may be 0, 1, 2, 3, 4, 5, 6, 7 or 8.

In some embodiments, Q1, Q2, Q3 and Q4 are each independently selected from a substituted or unsubstituted alkyl group having 1 to 20 carbon atoms, a substituted or unsubstituted aromatic group having 6 to 60 ring atoms, or a substituted or unsubstituted heteroaromatic group having 5 to 60 ring atoms, or a combination thereof.

In some embodiments, Q1, Q2, Q3 and Q4 are each independently selected from a substituted or unsubstituted alkyl group having 1 to 10 carbon atoms, a substituted or unsubstituted aromatic group having 6 to 30 ring atoms, or a substituted or unsubstituted heteroaromatic group having 5 to 30 ring atoms, or a combination thereof.

In some embodiments, in a case that at least one of Q1, Q2, Q3, Q4 is selected from a substituted or unsubstituted alkyl group having 1 to 10 carbon atoms, at least one of Q1, Q2, Q3, Q4 is selected from methyl, isopropyl, tert-butyl, cyclopentyl, adamantyl, and the like.

In some embodiments, in a case that Q1, Q2, Q3, Q4 are each independently selected from a substituted or unsubstituted aromatic group having 6 to 30 ring atoms, or a substituted or unsubstituted heteroaromatic group having 5 to 30 ring atoms, Q1, Q2 are each independently selected from structures represented by any one of formulae (A-4-1) to (A-4):

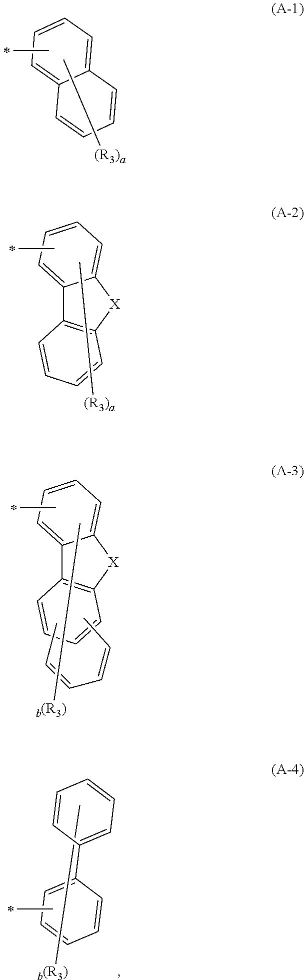

wherein is selected from CR₄R₅, NR₆, O or S;
R₃, R₄, R₅ and R₆ are each independently selected from hydrogen, deuterium, a substituted or unsubstituted alkyl group having 1 to 10 carbon atoms, a substituted or unsubstituted aromatic group having 6 to 30 ring atoms, or a substituted or unsubstituted heteroaromatic group having 5 to 30 ring atoms, two adjacent R₃ form a ring or not, and R₄, R₅ form a ring or not;
a is selected from any one integer from 0 to 7, and a may be selected from 0, 1, 2, 3, 4, 5, 6 or 7;
b is selected from any one integer from 0 to 9, and b may be selected from 0, 1, 2, 3, 4, 5, 6, 7, 8 or 9; and
* indicates a linkage site.

In some embodiments, Q1 and Q2 are each independently selected from a structure represented by any one of formulae (B-1) to (B-2), (C-1) to (C-4) and (D-1) to (D-12):

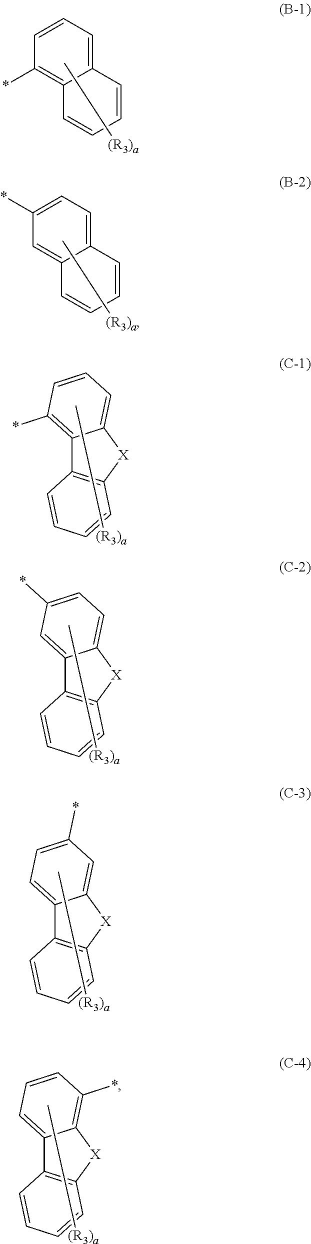

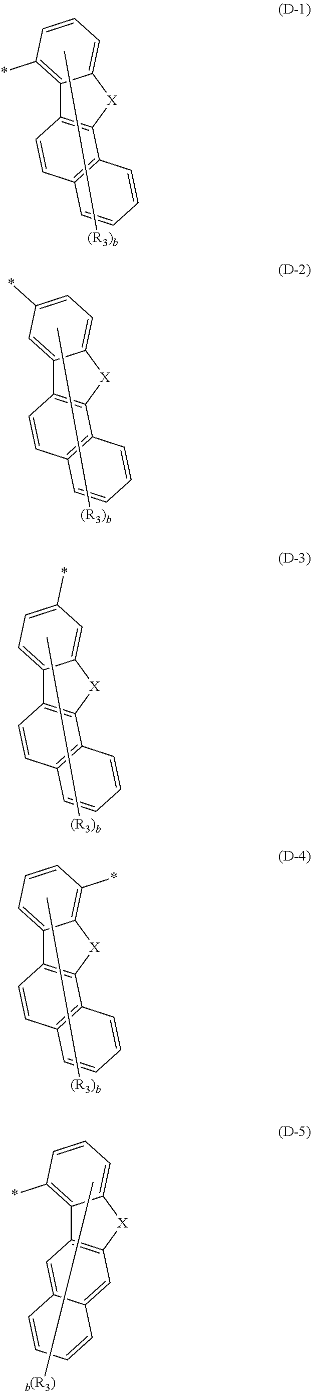

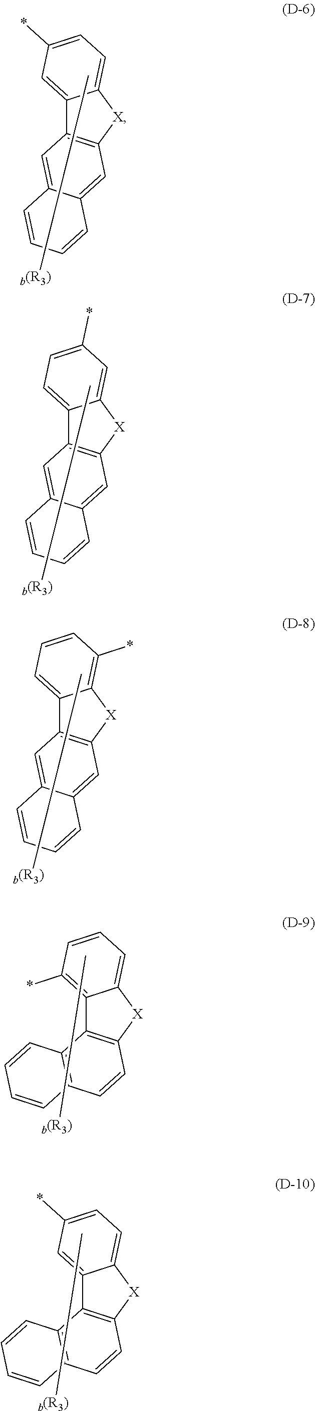

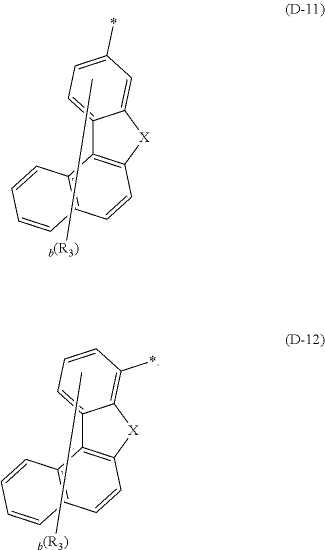

In some embodiments, R3, R4, R5 and R6 are each independently selected from hydrogen, deuterium, a substituted or unsubstituted alkyl group having 1 to 10 carbon atoms, a substituted or unsubstituted aromatic group having 6 to 10 ring atoms, or a substituted or unsubstituted heteroaromatic group having 5 to 10 ring atoms.

In some embodiments, R3, R4, R5, R6 are each independently selected from hydrogen, deuterium, methyl, ethyl, isopropyl, tert-butyl, phenyl, cyclopentyl, adamantyl, and the like.

In some embodiments, Q1, Q2 are each independently selected from the following structures:

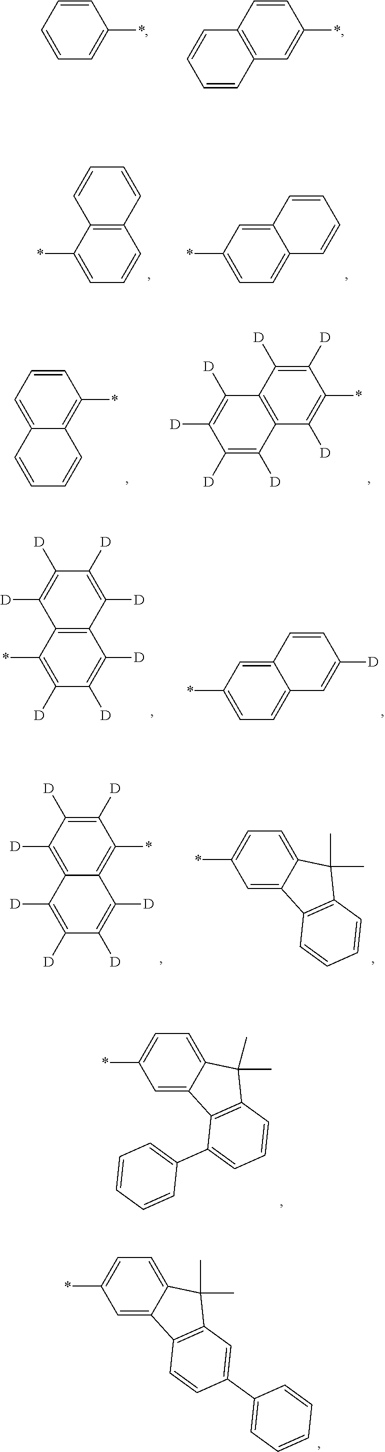

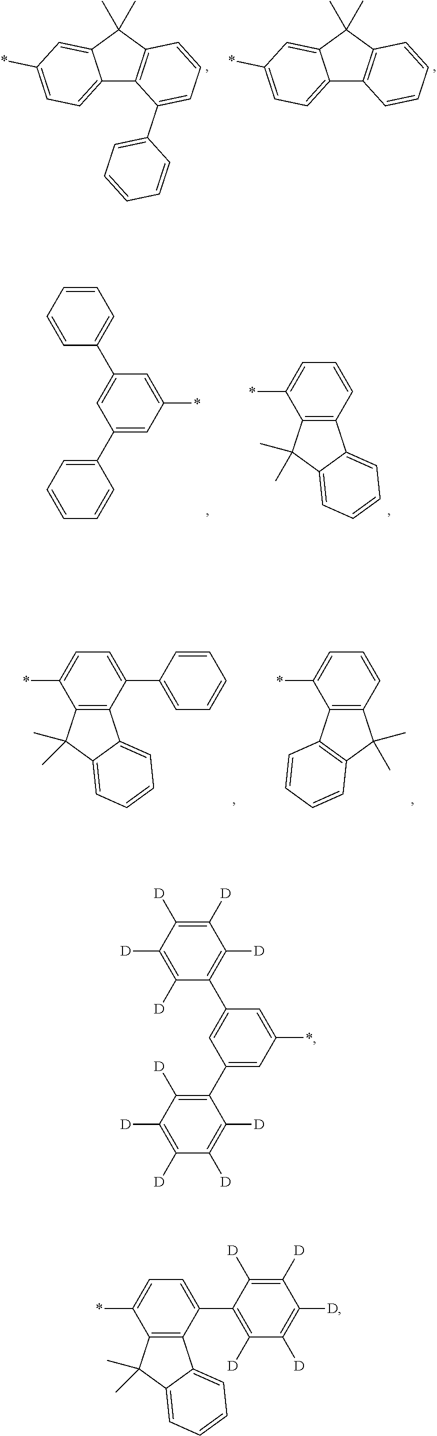

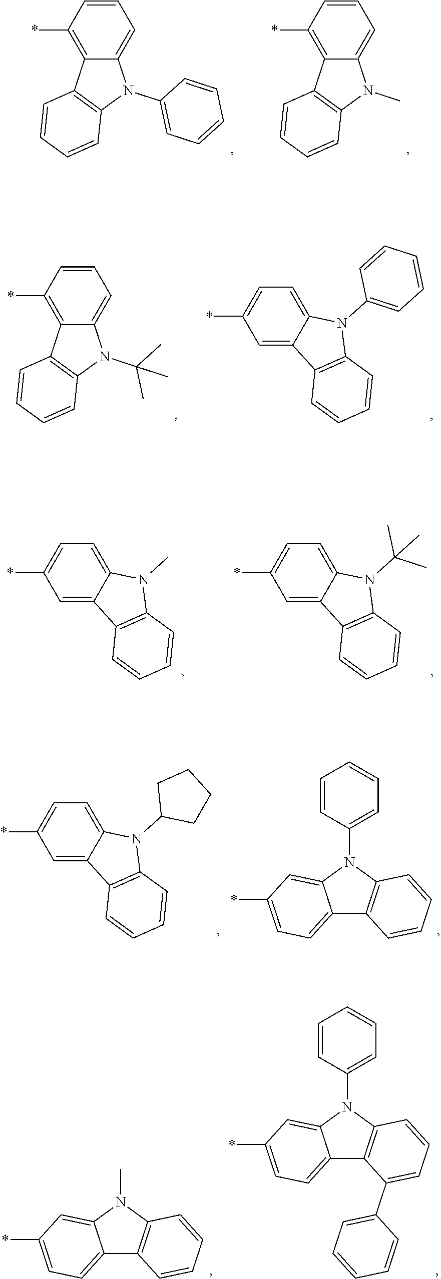

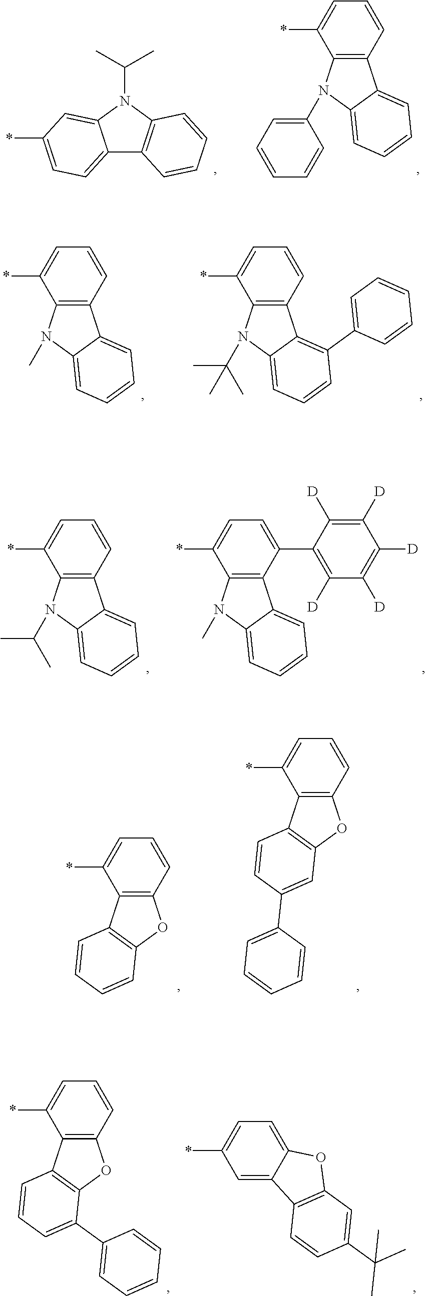

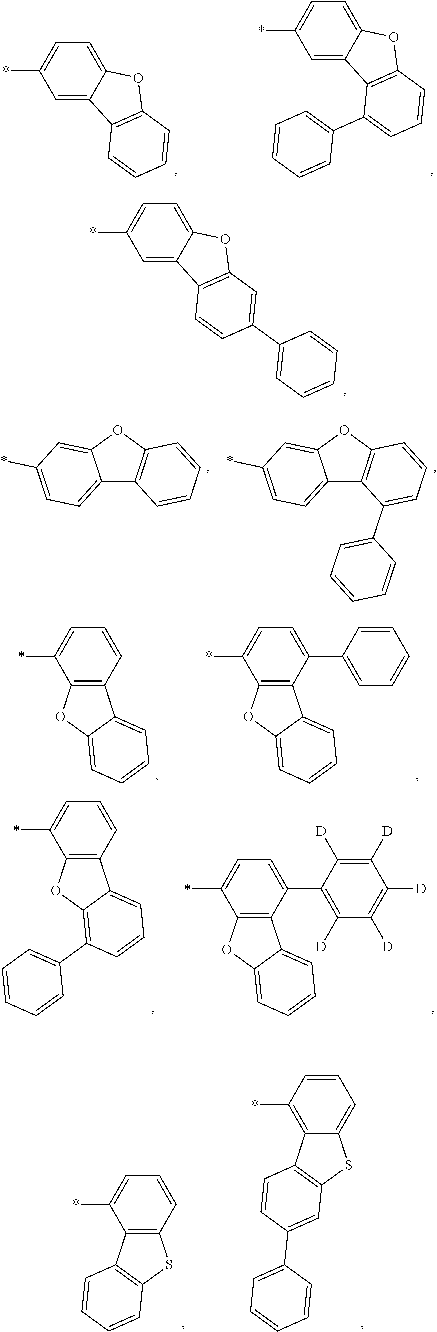

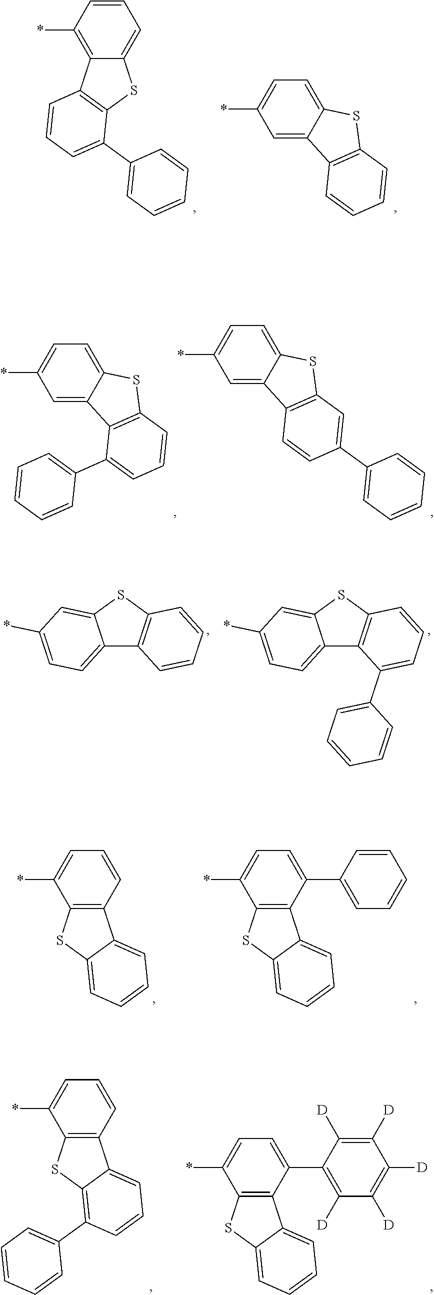

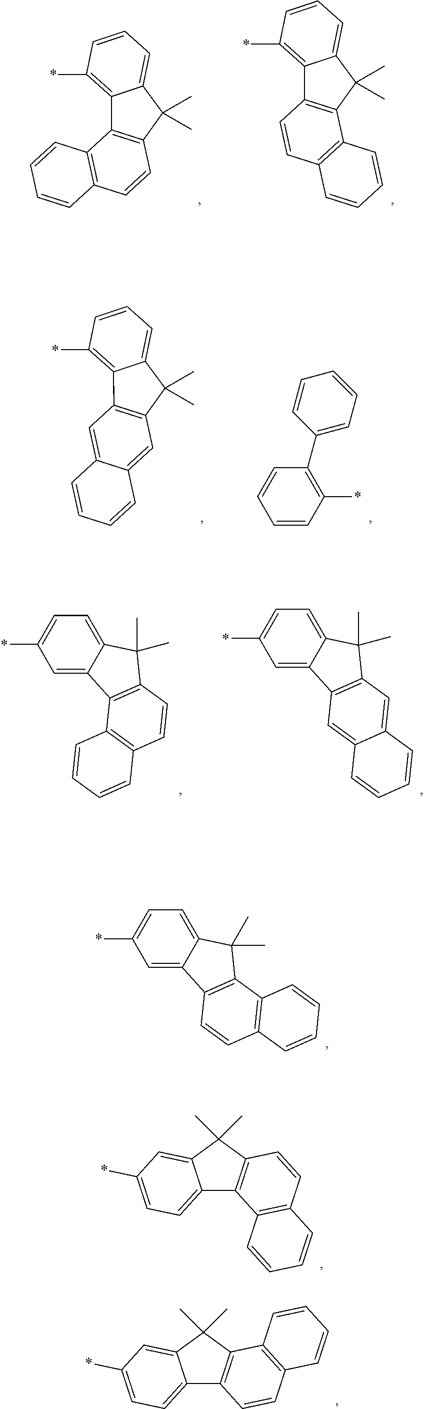

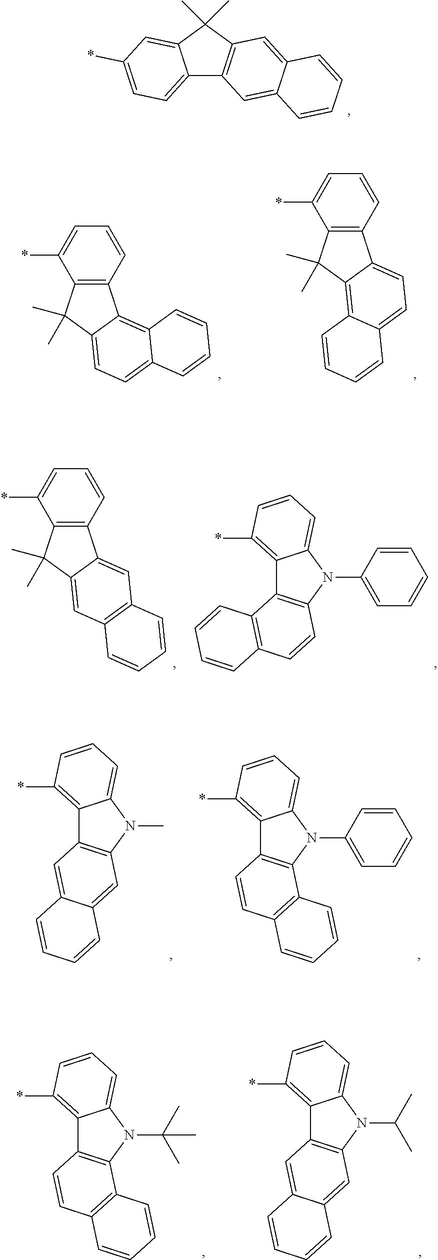

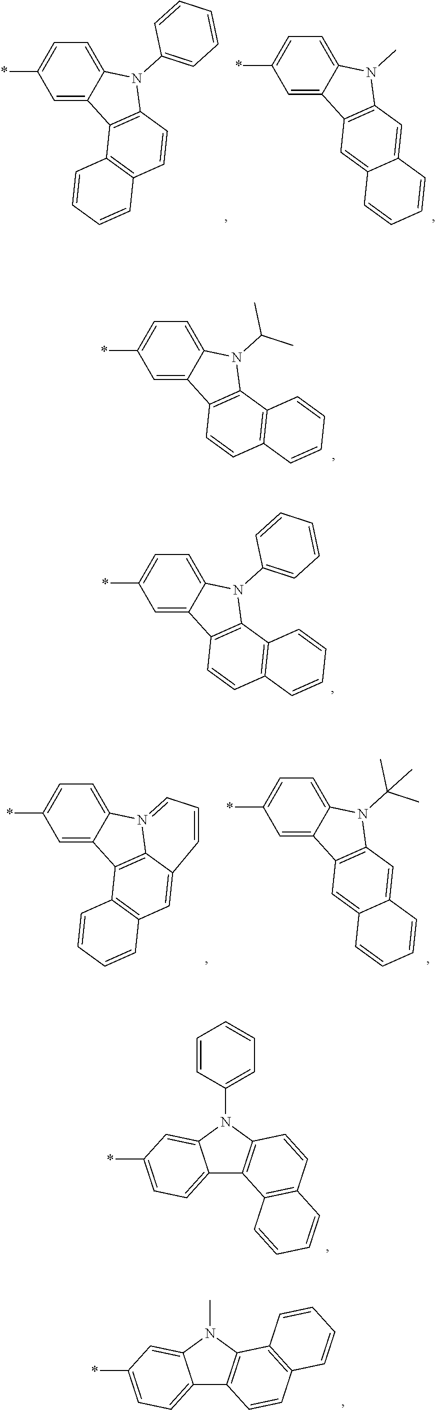

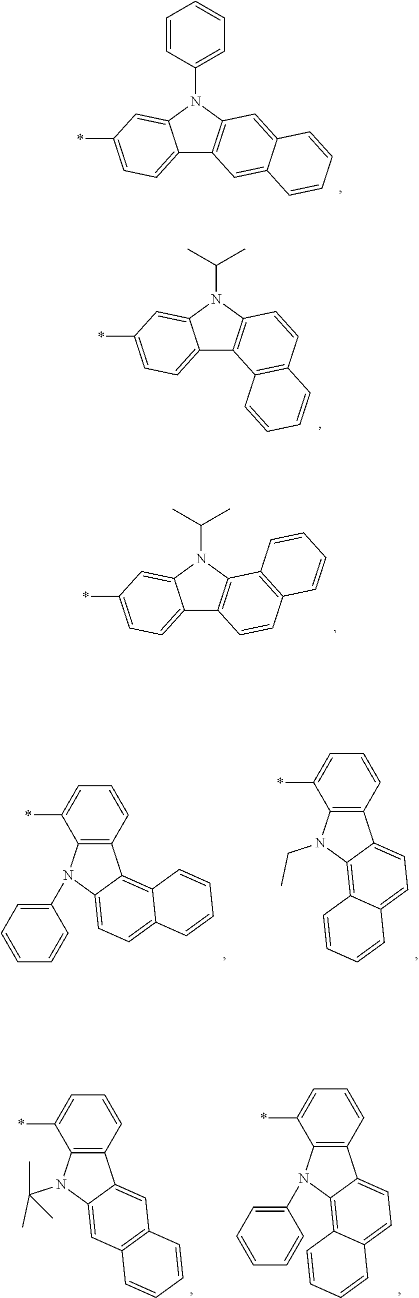

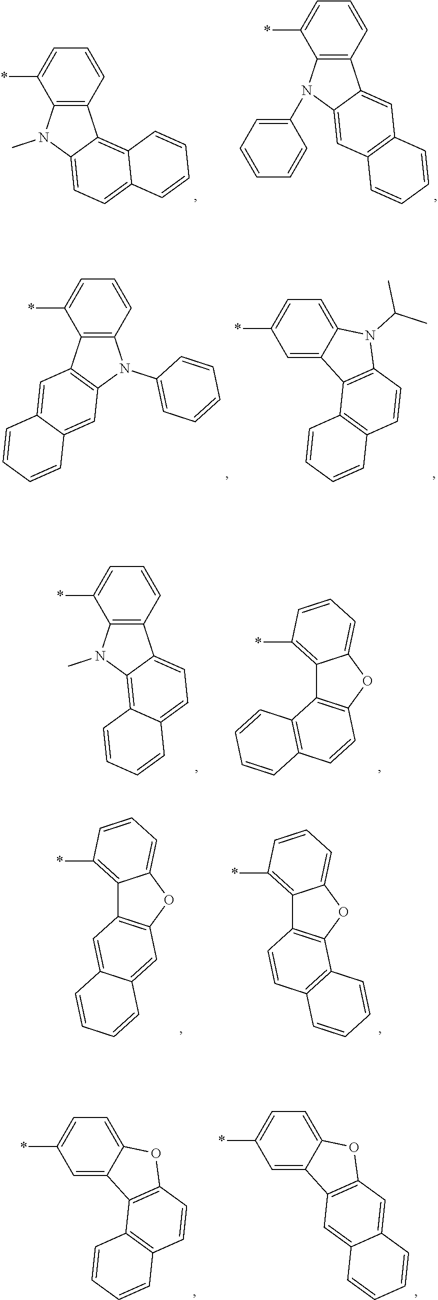

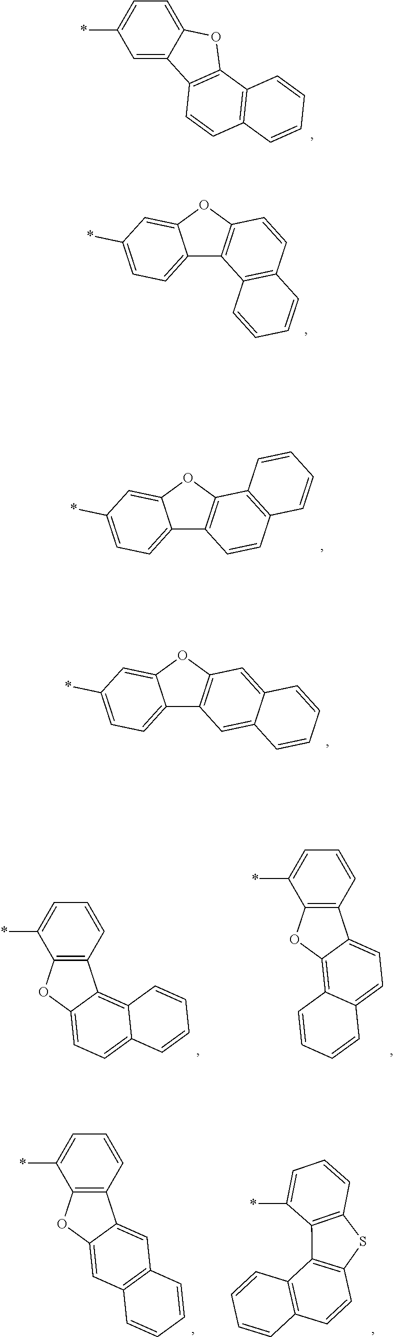

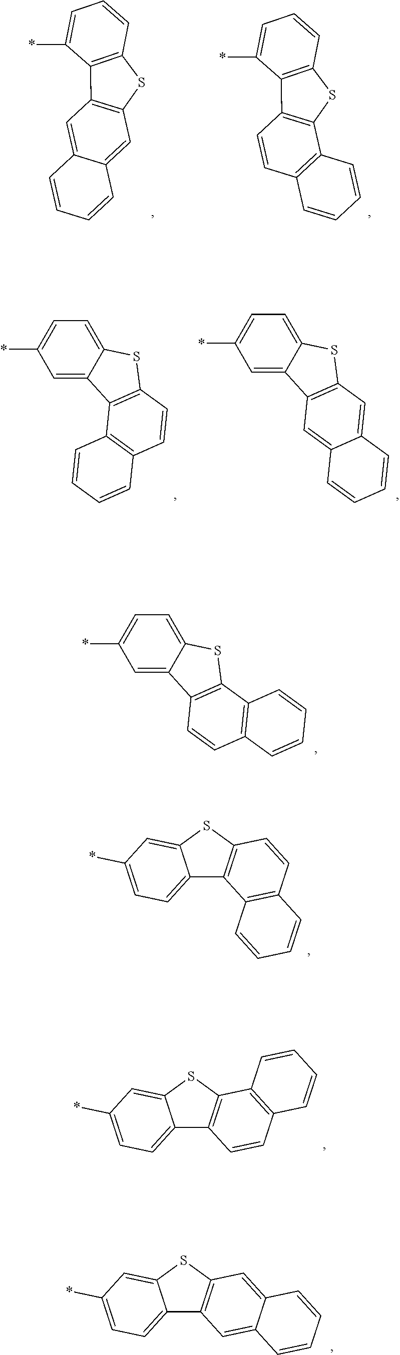

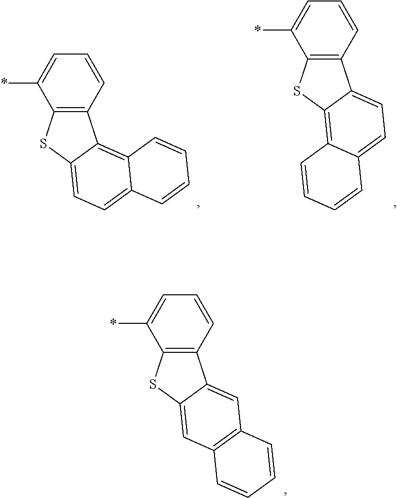 [SMILES: *c1cccc2c1sc1ccc3ccccc3c12 ; *c1cccc2c1sc1c3ccccc3ccc21 ; *c1cccc2c1sc1cc3ccccc3cc12]

In some embodiments, the first compound has a structure represented by any one of formulae (1-1) to (1-3):

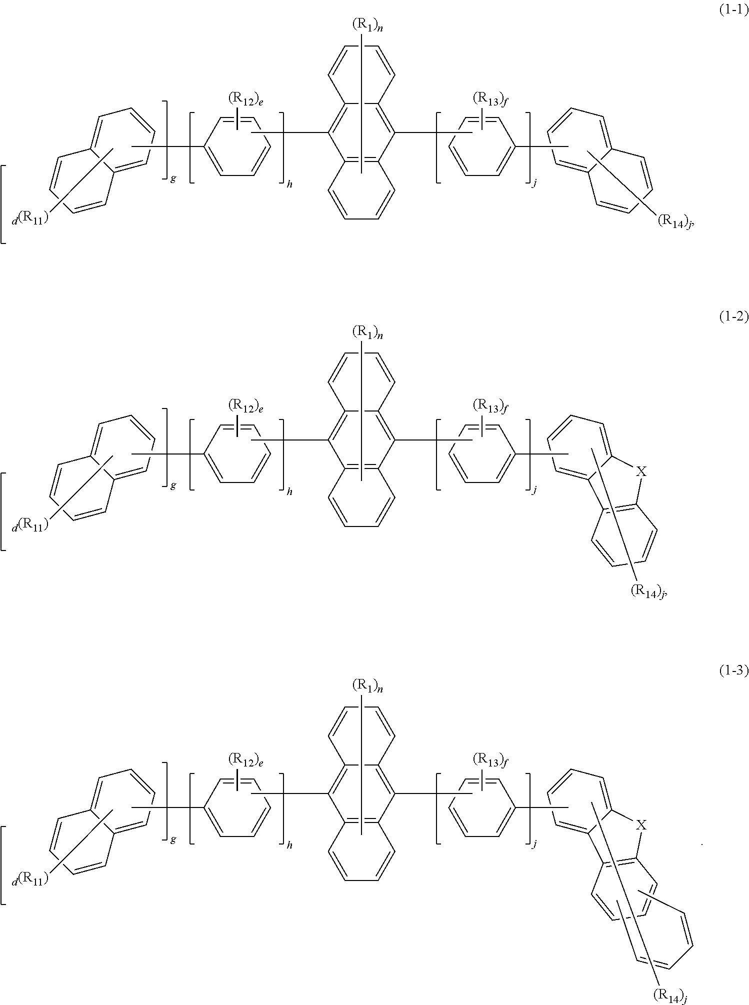

wherein R₁₁, R₁₂, R₁₃ and R₁₄ are each independently selected from hydrogen, deuterium, a substituted or unsubstituted alkyl group having 1 to 10 carbon atoms, a substituted or unsubstituted aromatic group having 6 to 30 ring atoms or a substituted or unsubstituted heteroaromatic group having 5 to 30 ring atoms, two adjacent R₁₁ form a ring or not, two adjacent R₁₂ form a ring or not, and two adjacent R₁₃ form a ring or not, two adjacent R₁₄ form a ring or not.

In some embodiments, R11, R12, R13, R14 are each independently selected from hydrogen, deuterium, methyl, propyl, tert-butyl, cyclopentyl, adamantyl, phenyl, and the like.

In some embodiments, d and j are each independently selected from any one integer from 0 to 7, for example, it may be 0, 1, 2, 3, 4, 5, 6 or 7;
e, f are each independently selected from any one integer from 0 to 4, for example, it may be 0, 1, 2, 3 or 4;
g may be selected from 0 or 1;
h, i are each independently selected from any one integer from 0 to 3, for example, it may be 0, 1, 2 or 3; and
a sum of g and h is greater than or equal to 1.

In some embodiments, the first compound is selected from:

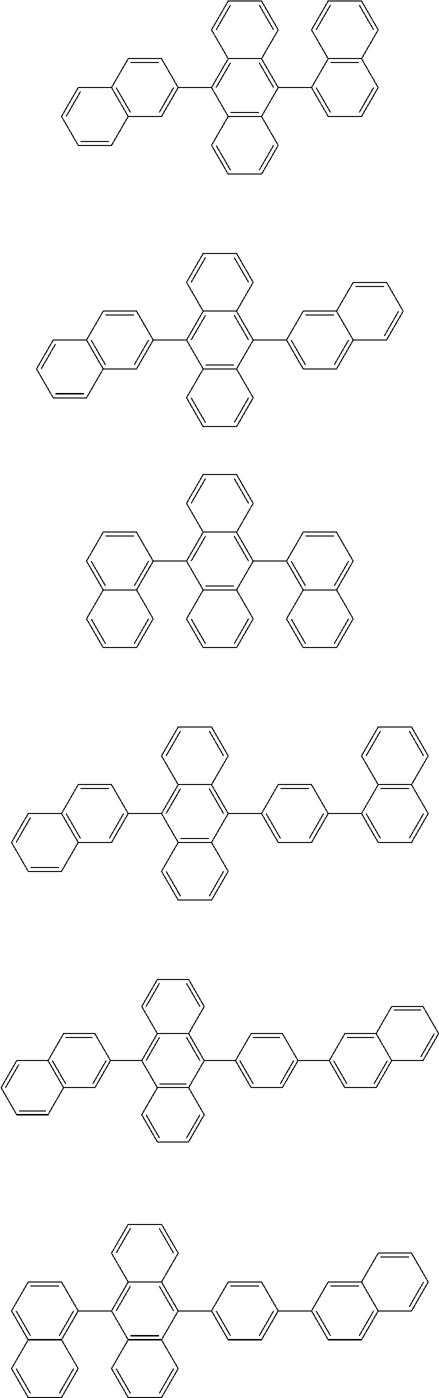

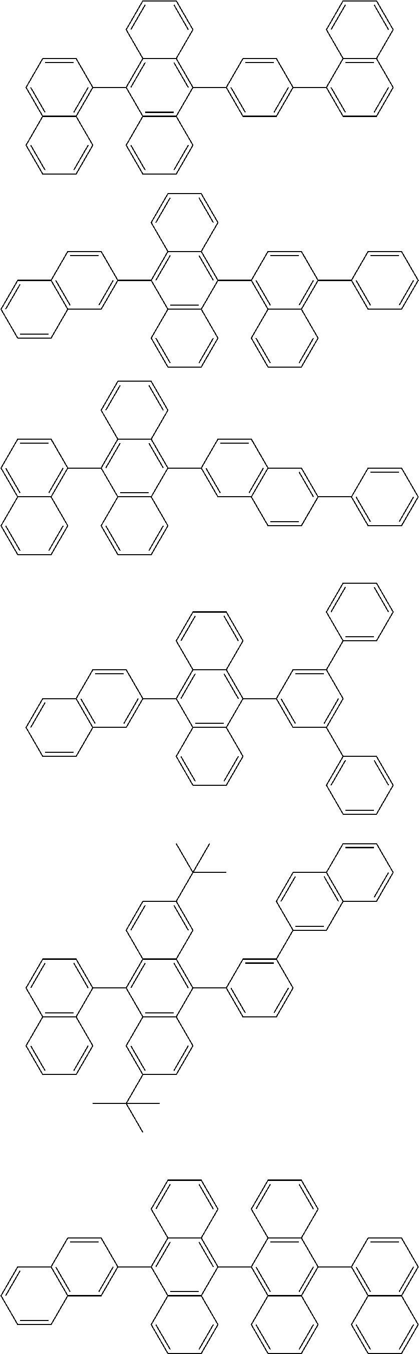

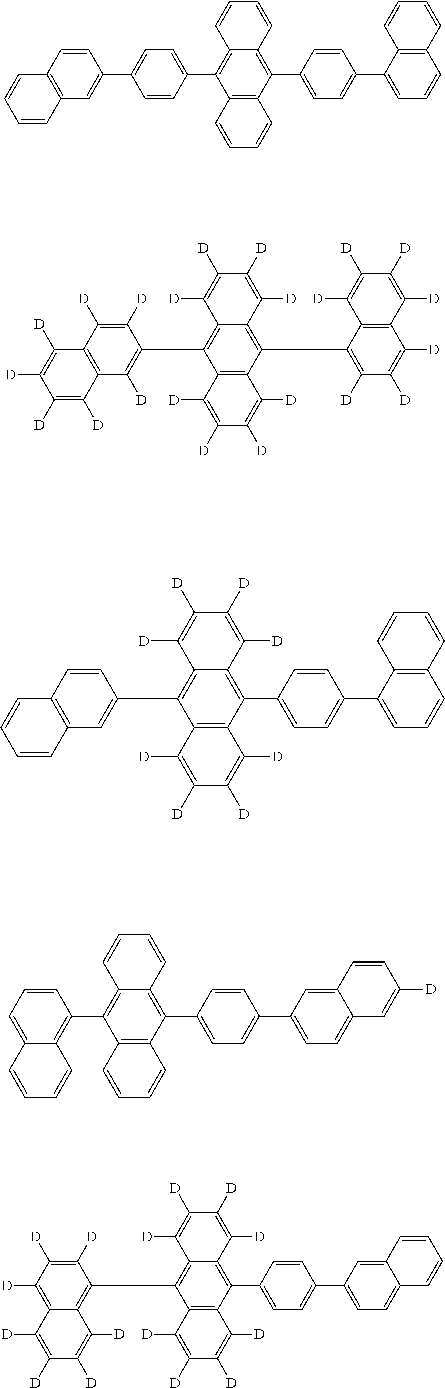

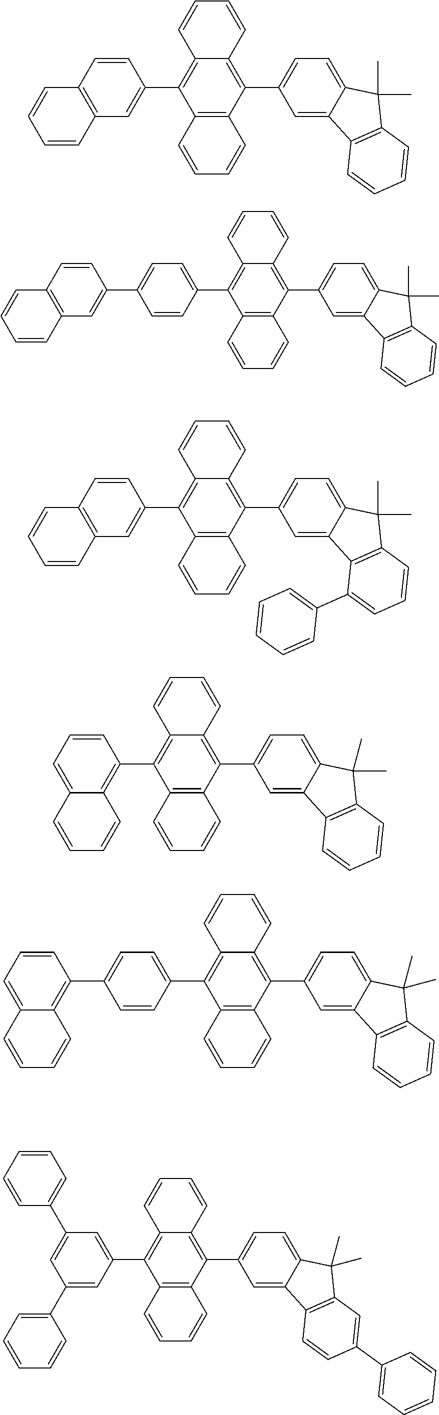

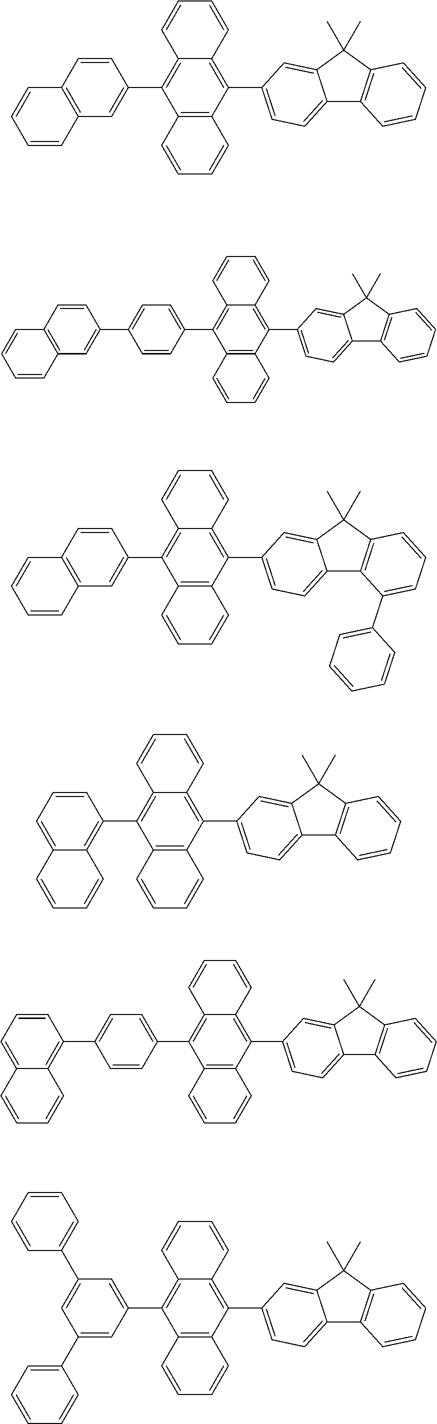

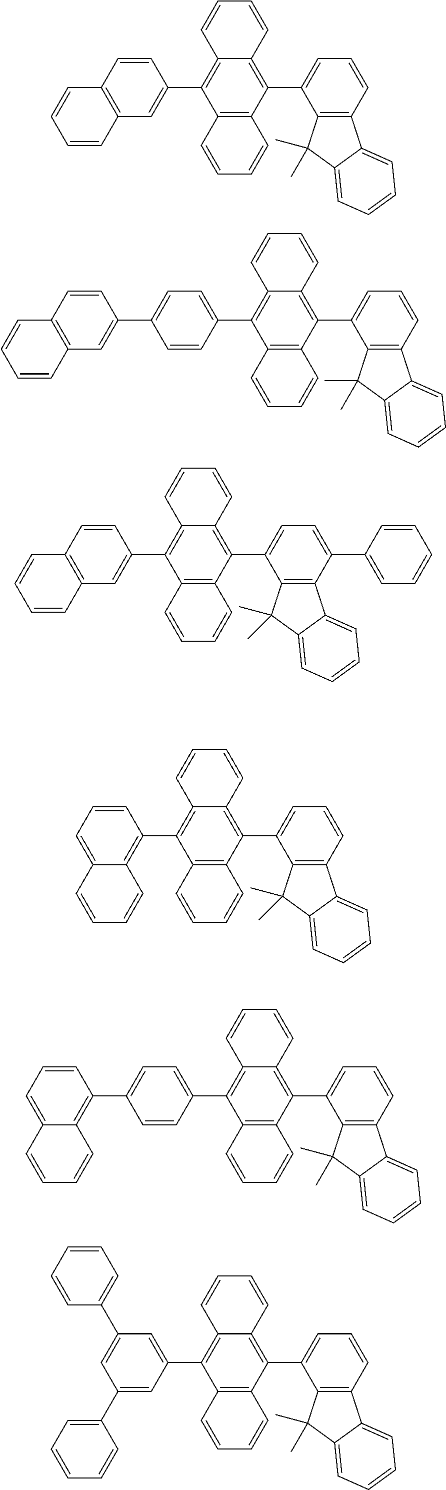

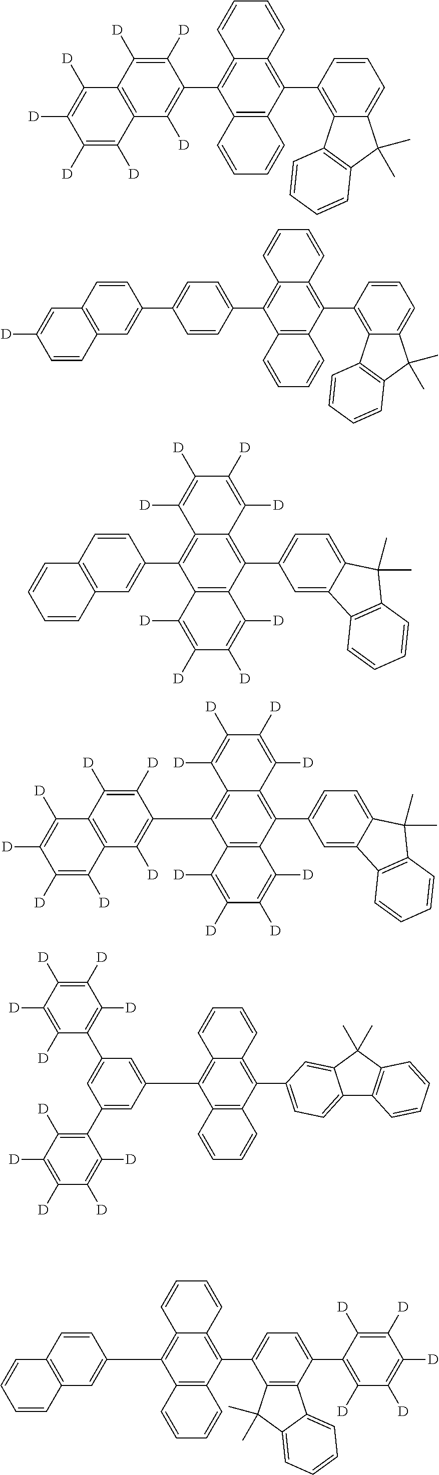

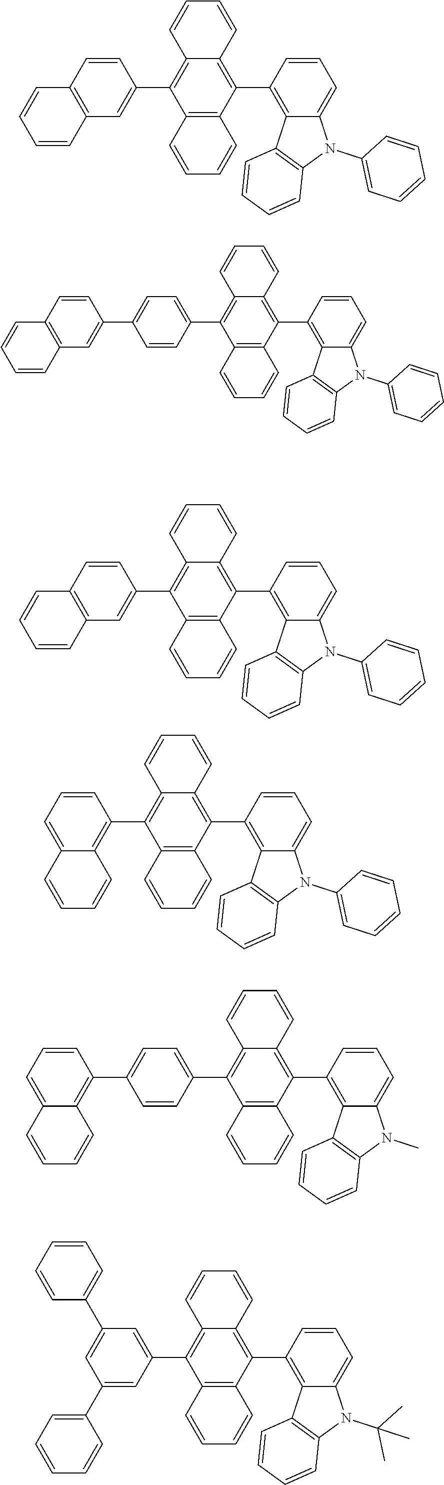

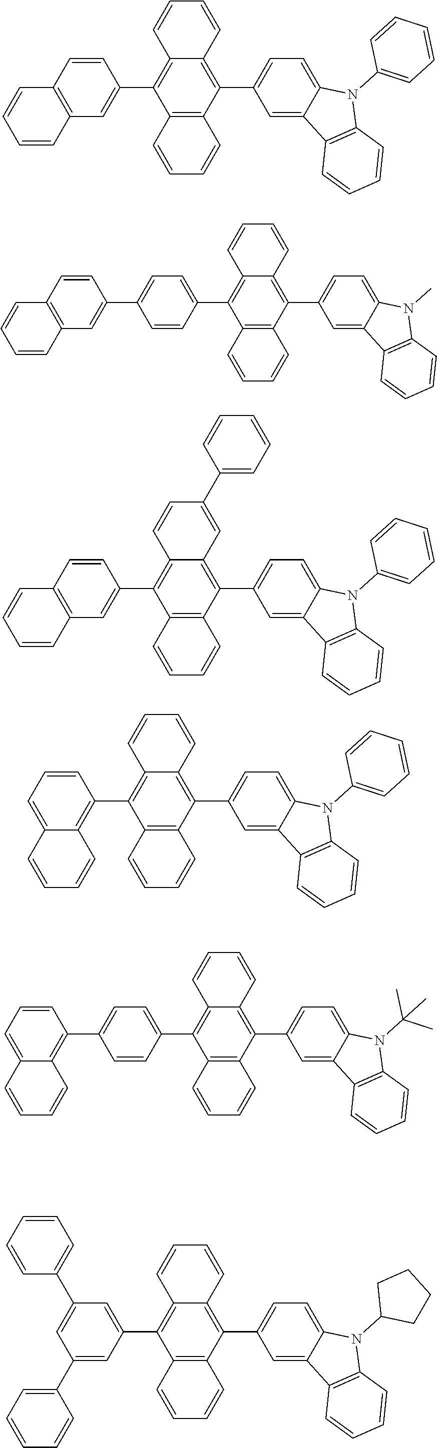

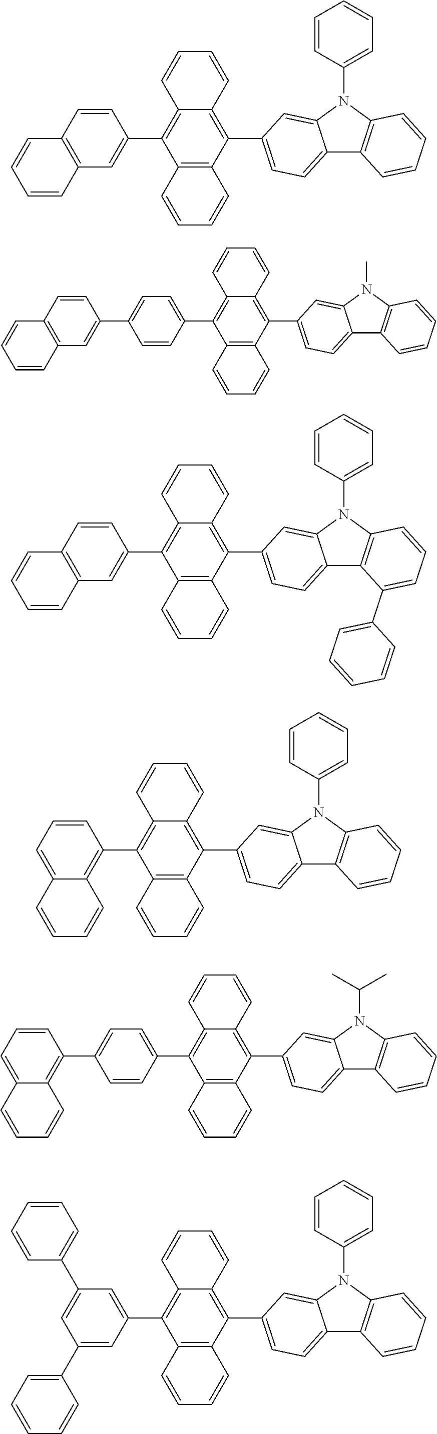

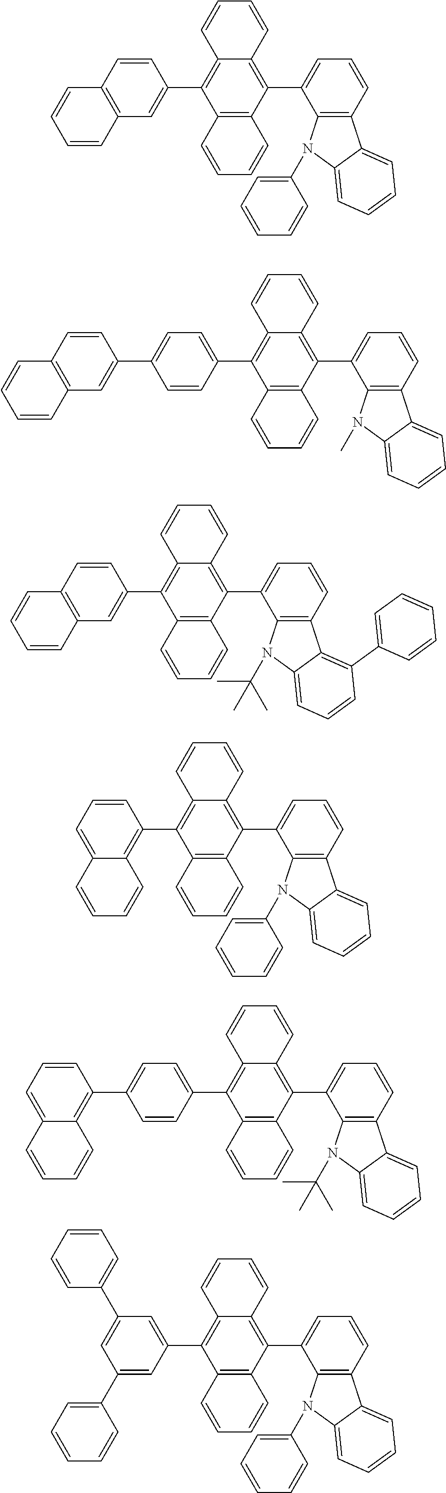

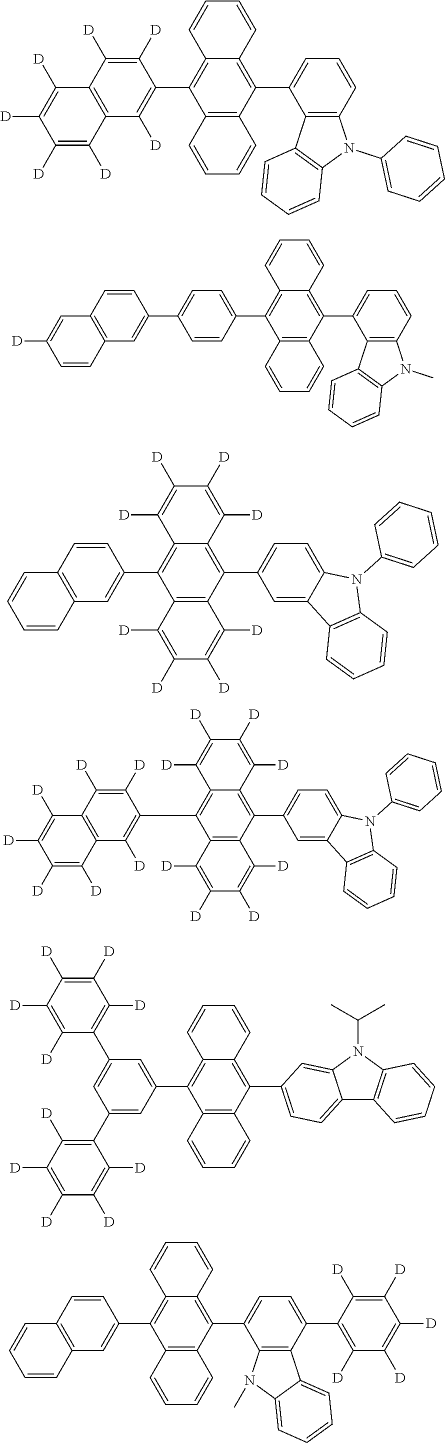

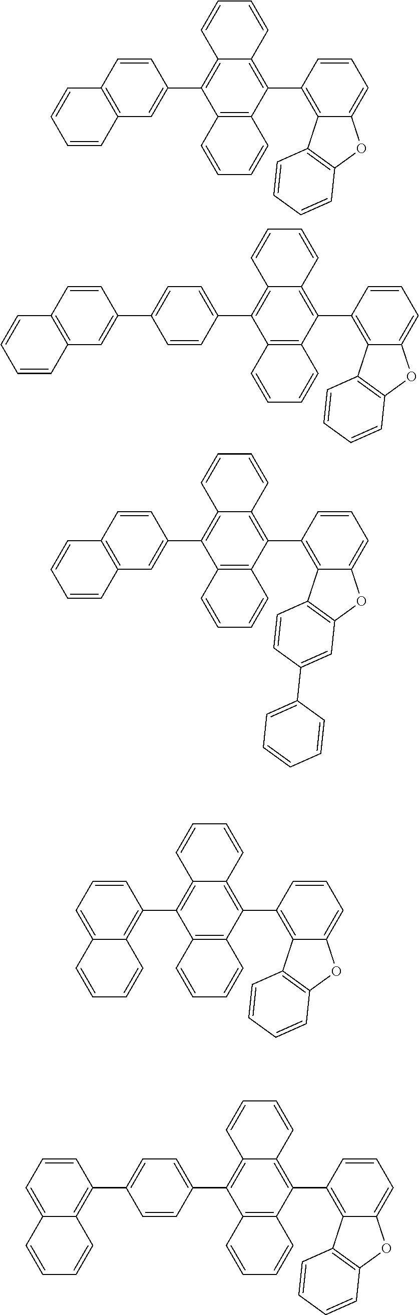

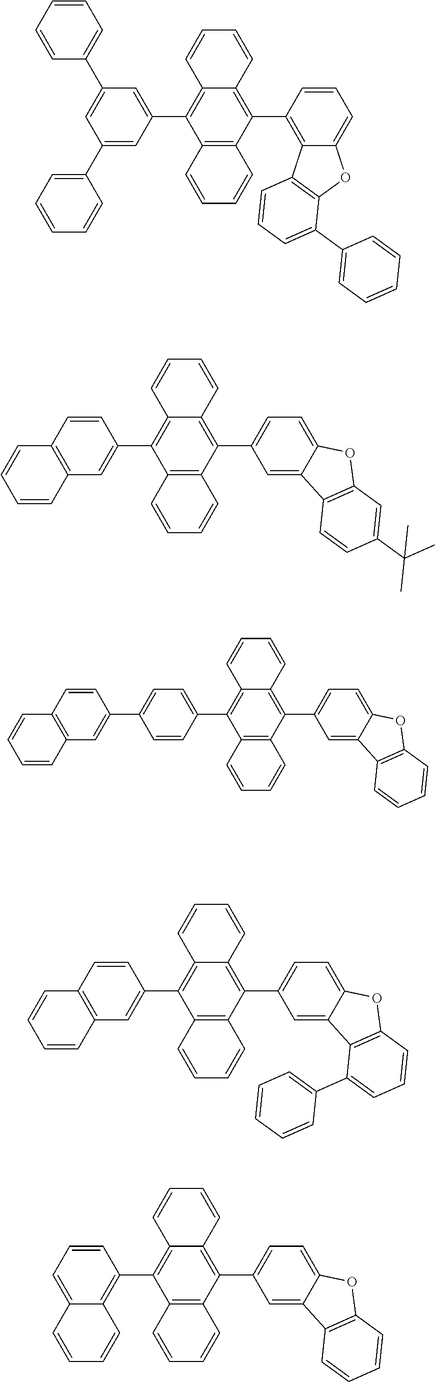 [SMILES: c1ccc(-c2cc(-c3ccccc3)cc(-c3c4ccccc4c(-c4cccc5oc6c(-c7ccccc7)cccc6c45)c4ccccc34)c2)cc1 ; CC(C)(C)c1ccc2c(c1)oc1ccc(-c3c4ccccc4c(-c4ccc5ccccc5c4)c4ccccc34)cc12 ; c1ccc2cc(-c3ccc(-c4c5ccccc5c(-c5ccc6oc7ccccc7c6c5)c5ccccc45)cc3)ccc2c1 ; c1ccc(-c2cccc3oc4ccc(-c5c6ccccc6c(-c6ccc7ccccc7c6)c6ccccc56)cc4c23)cc1 ; c1ccc2c(-c3c4ccccc4c(-c4ccc5oc6ccccc6c5c4)c4ccccc34)cccc2c1]

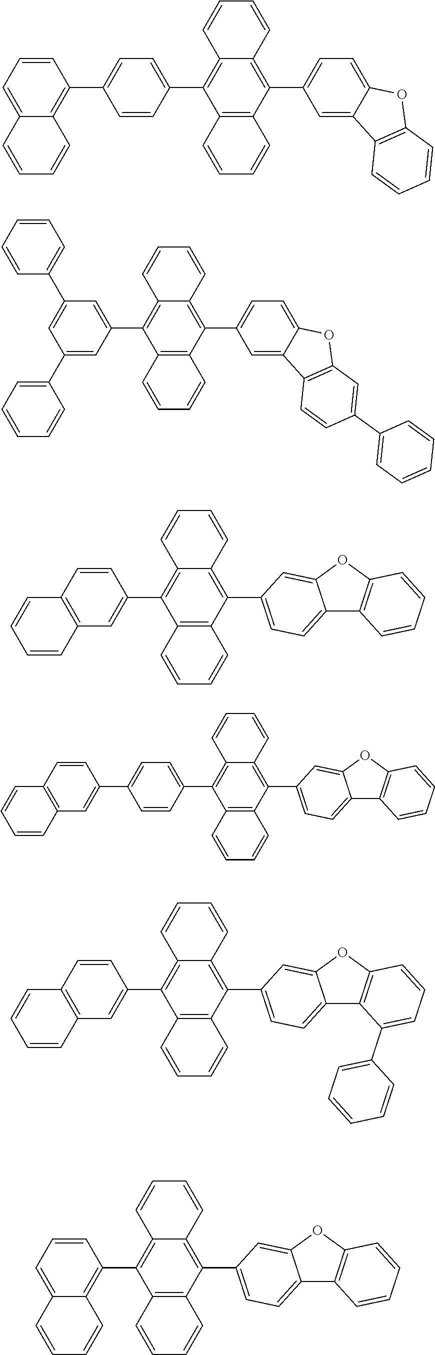

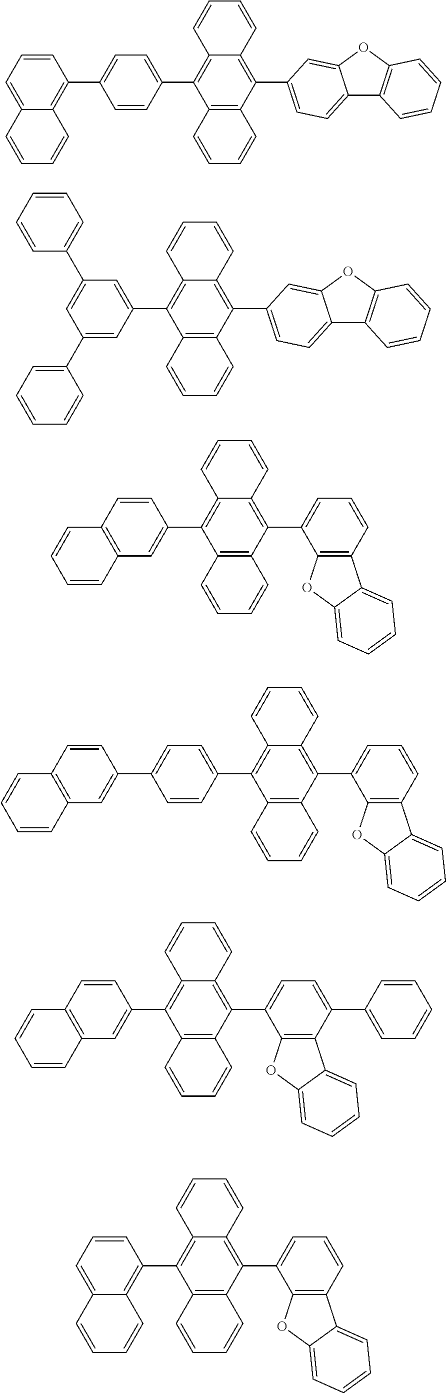

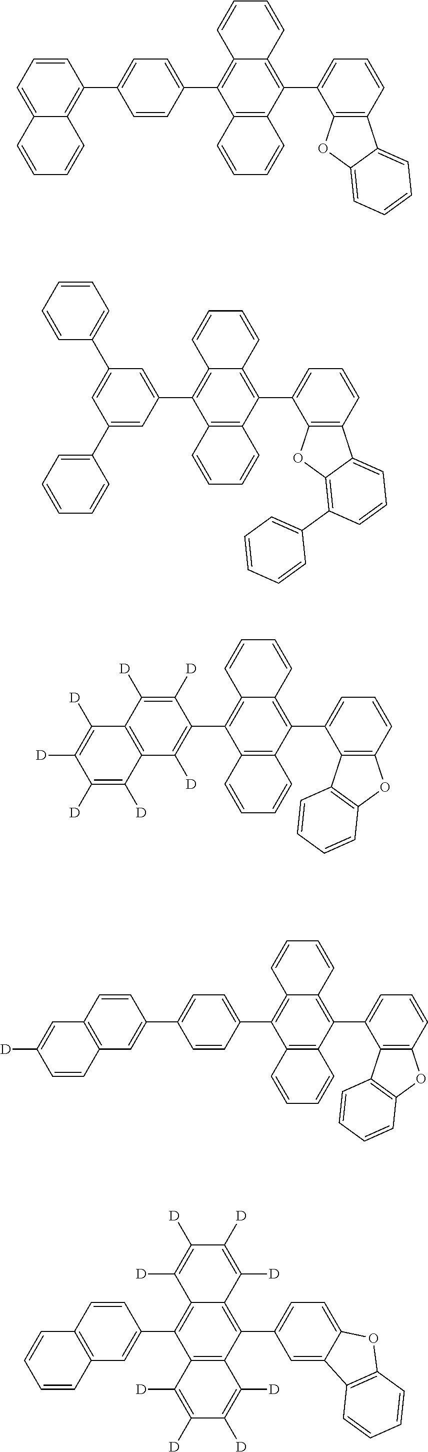 [SMILES: c1ccc2c(-c3ccc(-c4c5ccccc5c(-c5cccc6c5oc5ccccc56)c5ccccc45)cc3)cccc2c1 ; c1ccc(-c2cc(-c3ccccc3)cc(-c3c4ccccc4c(-c4cccc5c4oc4c(-c6ccccc6)cccc45)c4ccccc34)c2)cc1 ; [2H]c1c([2H])c([2H])c2c([2H])c(-c3c4ccccc4c(-c4cccc5oc6ccccc6c45)c4ccccc34)c([2H])c([2H])c2c1[2H] ; [2H]c1ccc2cc(-c3ccc(-c4c5ccccc5c(-c5cccc6oc7ccccc7c56)c5ccccc45)cc3)ccc2c1 ; [2H]c1c([2H])c([2H])c2c(-c3ccc4oc5ccccc5c4c3)c3c([2H])c([2H])c([2H])c([2H])c3c(-c3ccc4ccccc4c3)c2c1[2H]]

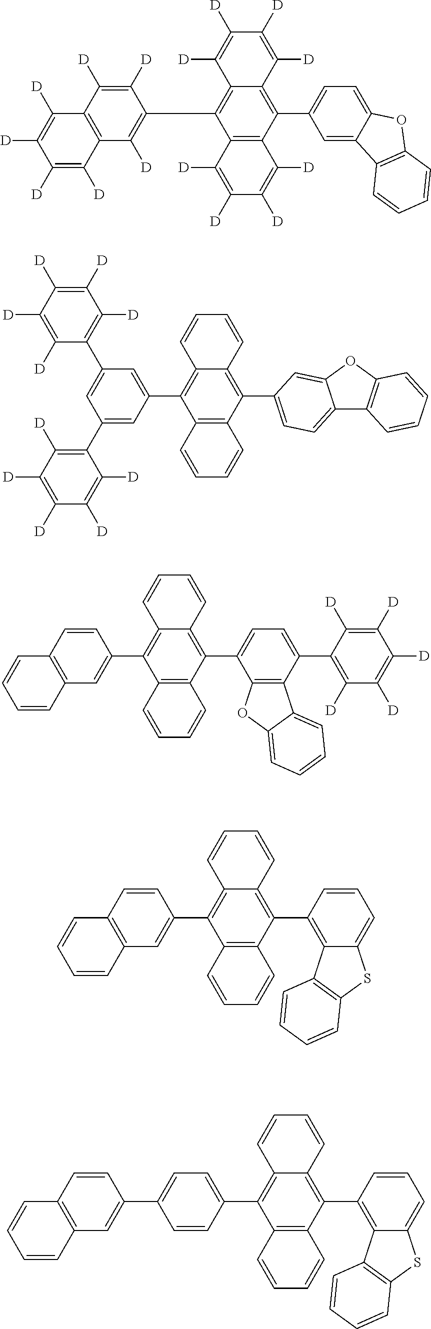

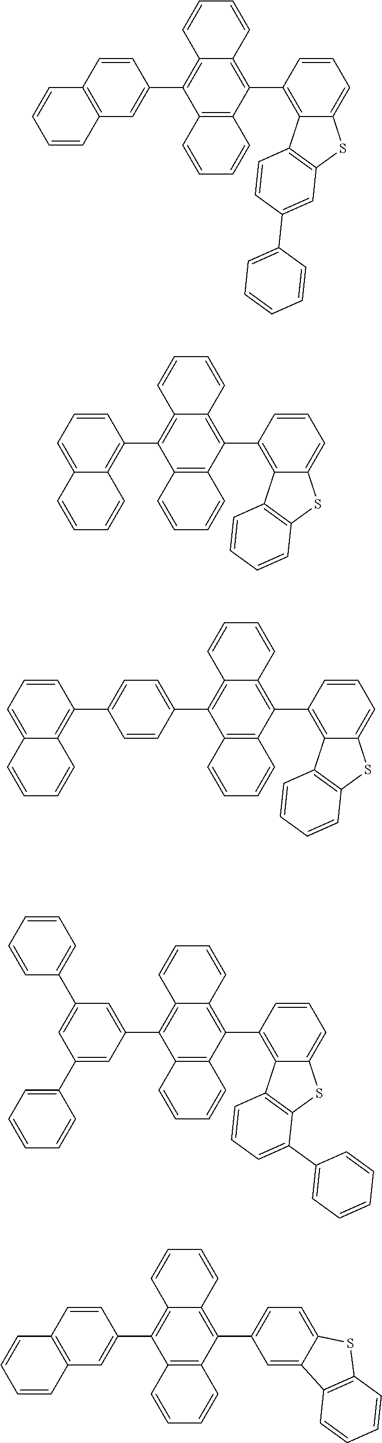 [SMILES: c1ccc(-c2ccc3c(c2)sc2cccc(-c4c5ccccc5c(-c5ccc6ccccc6c5)c5ccccc45)c23)cc1 ; c1ccc2c(-c3c4ccccc4c(-c4cccc5sc6ccccc6c45)c4ccccc34)cccc2c1 ; c1ccc2c(-c3ccc(-c4c5ccccc5c(-c5cccc6sc7ccccc7c56)c5ccccc45)cc3)cccc2c1 ; c1ccc(-c2cc(-c3ccccc3)cc(-c3c4ccccc4c(-c4cccc5sc6c(-c7ccccc7)cccc6c45)c4ccccc34)c2)cc1 ; c1ccc2cc(-c3c4ccccc4c(-c4ccc5sc6ccccc6c5c4)c4ccccc34)ccc2c1]

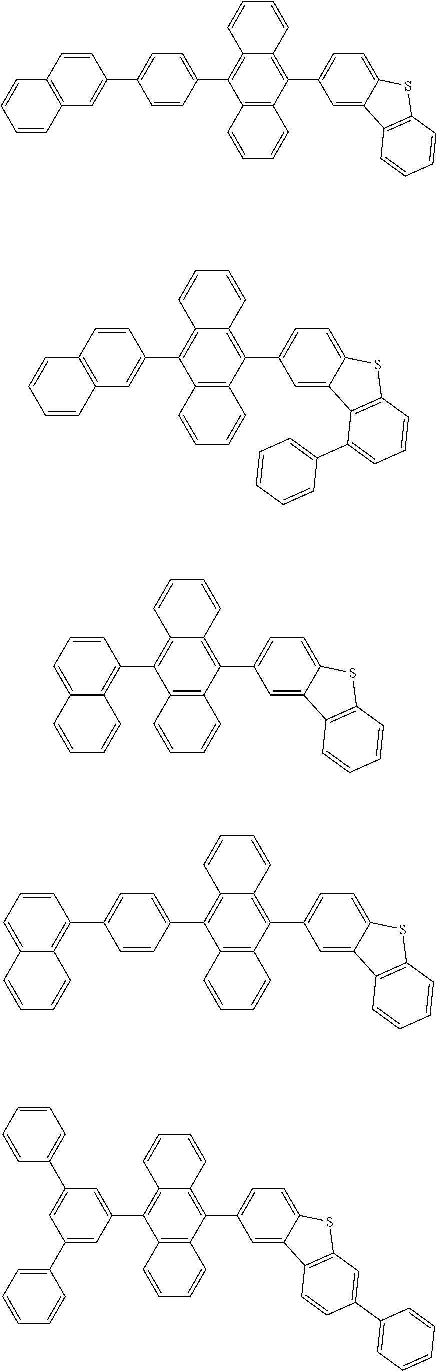 [SMILES: c1ccc2cc(-c3ccc(-c4c5ccccc5c(-c5ccc6sc7ccccc7c6c5)c5ccccc45)cc3)ccc2c1 ; c1ccc(-c2cccc3sc4ccc(-c5c6ccccc6c(-c6ccc7ccccc7c6)c6ccccc56)cc4c23)cc1 ; c1ccc2c(-c3c4ccccc4c(-c4ccc5sc6ccccc6c5c4)c4ccccc34)cccc2c1 ; c1ccc2c(-c3ccc(-c4c5ccccc5c(-c5ccc6sc7ccccc7c6c5)c5ccccc45)cc3)cccc2c1 ; c1ccc(-c2cc(-c3ccccc3)cc(-c3c4ccccc4c(-c4ccc5sc6cc(-c7ccccc7)ccc6c5c4)c4ccccc34)c2)cc1]

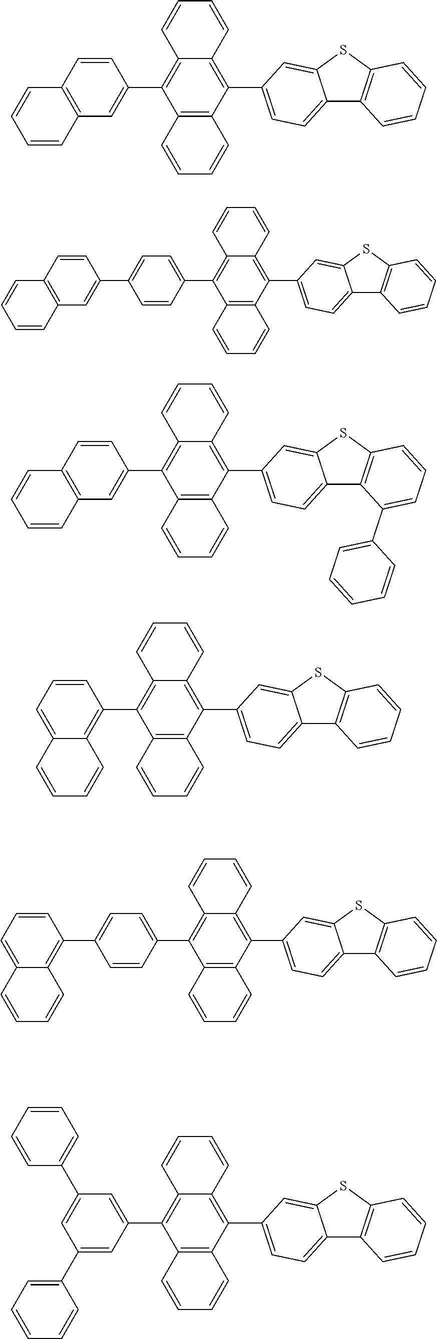

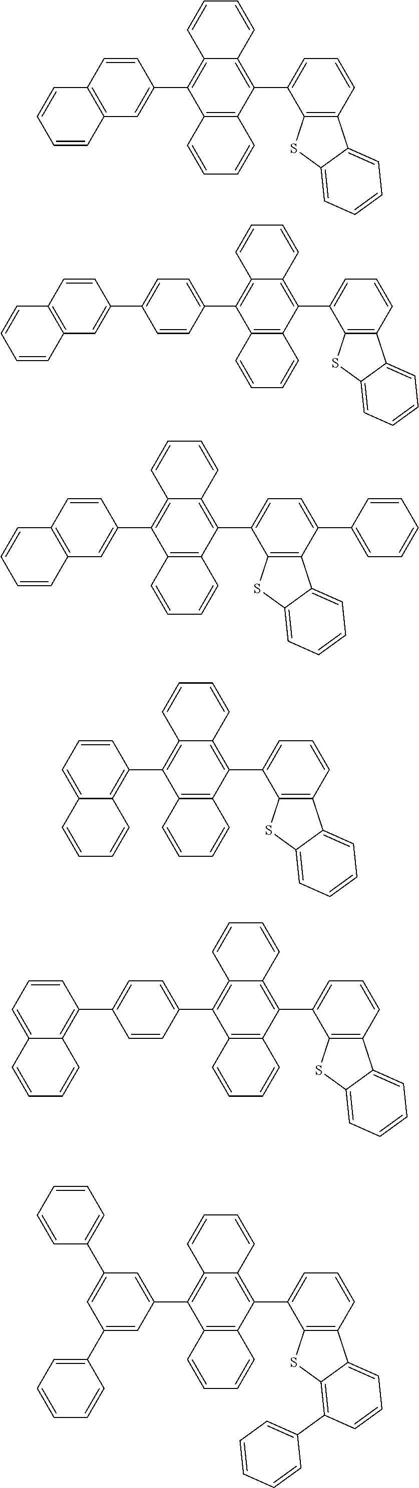 [SMILES: c1ccc2cc(-c3c4ccccc4c(-c4cccc5c4sc4ccccc45)c4ccccc34)ccc2c1 ; c1ccc2cc(-c3ccc(-c4c5ccccc5c(-c5cccc6c5sc5ccccc56)c5ccccc45)cc3)ccc2c1 ; c1ccc(-c2ccc(-c3c4ccccc4c(-c4ccc5ccccc5c4)c4ccccc34)c3sc4ccccc4c23)cc1 ; c1ccc2c(-c3c4ccccc4c(-c4cccc5c4sc4ccccc45)c4ccccc34)cccc2c1 ; c1ccc2c(-c3ccc(-c4c5ccccc5c(-c5cccc6c5sc5ccccc56)c5ccccc45)cc3)cccc2c1 ; c1ccc(-c2cc(-c3ccccc3)cc(-c3c4ccccc4c(-c4cccc5c4sc4c(-c6ccccc6)cccc45)c4ccccc34)c2)cc1]

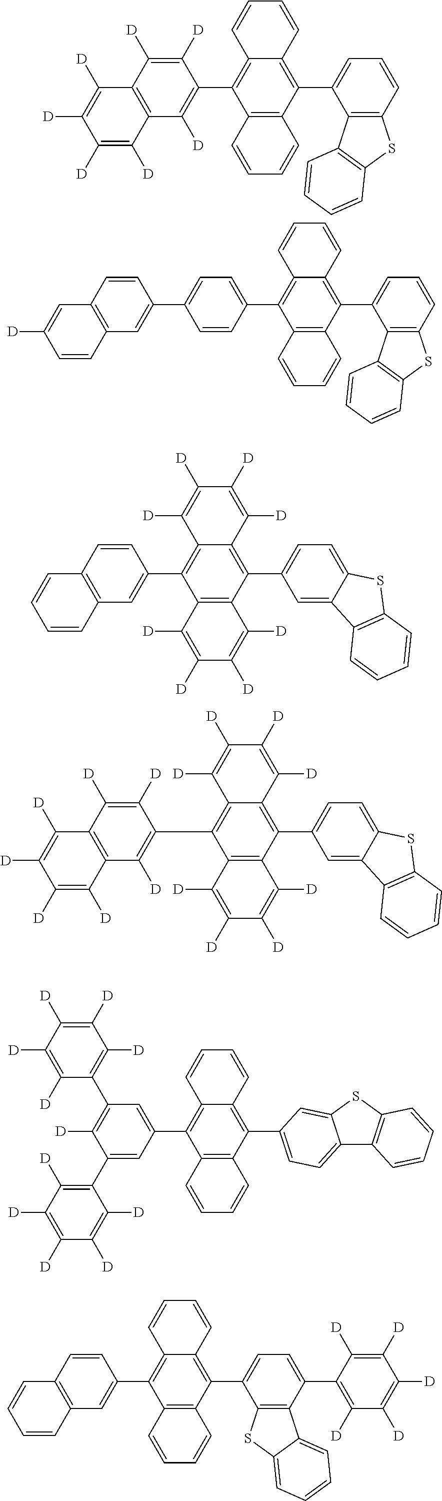

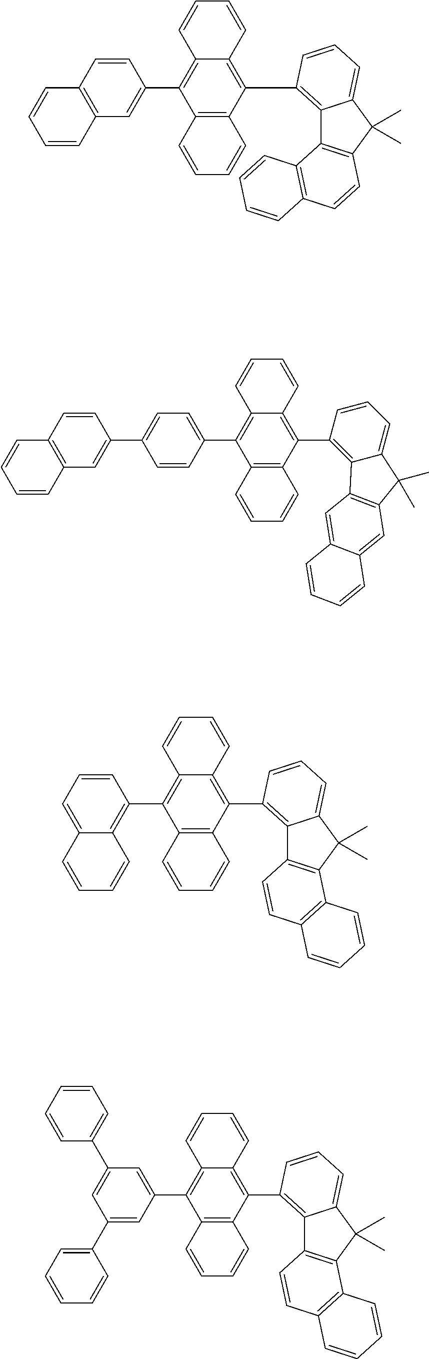

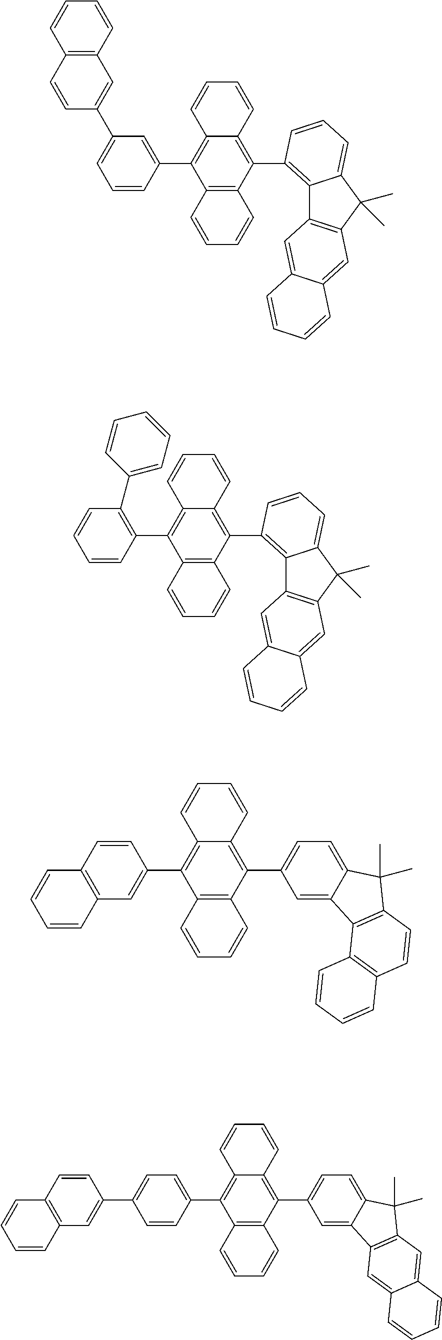

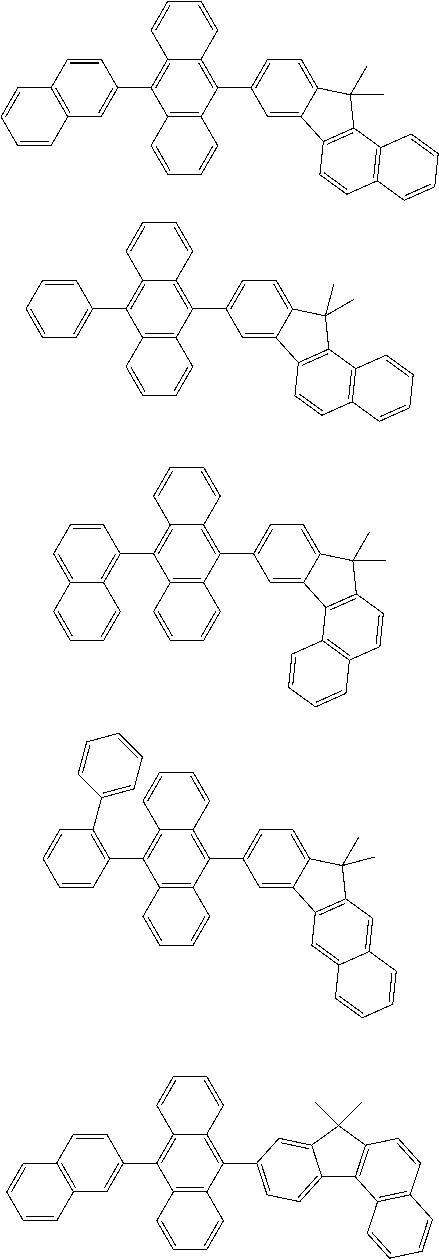

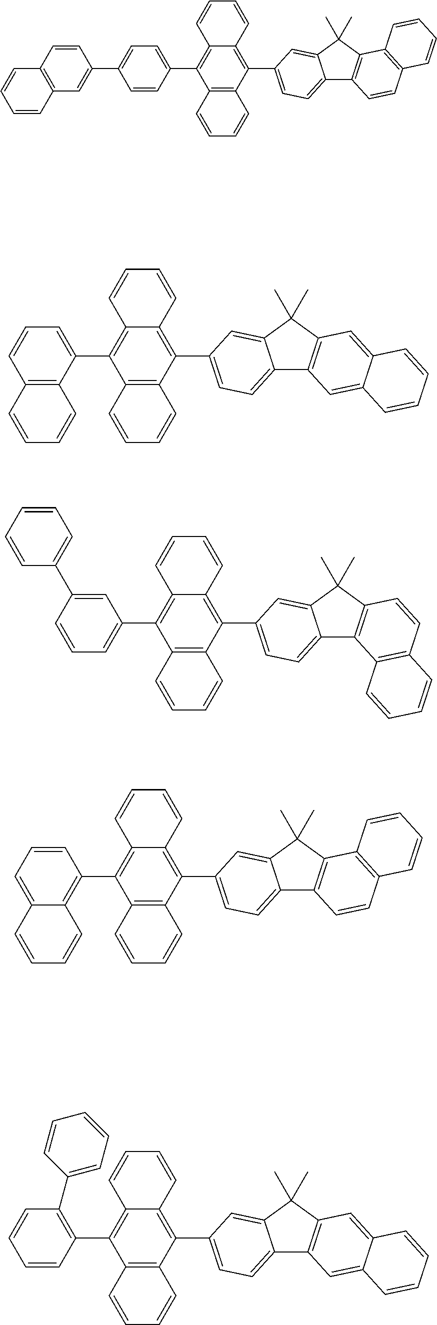

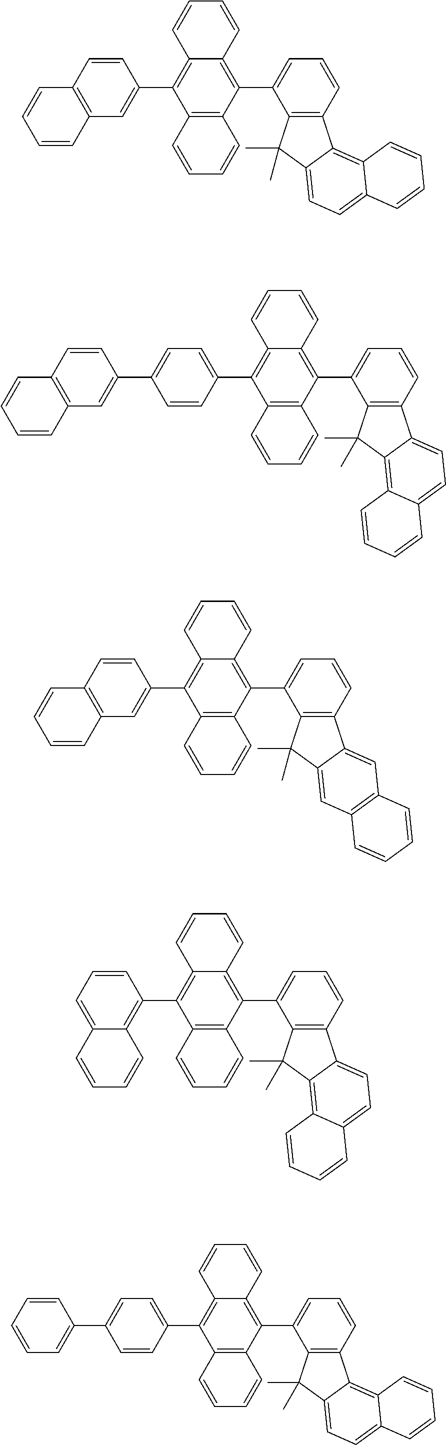

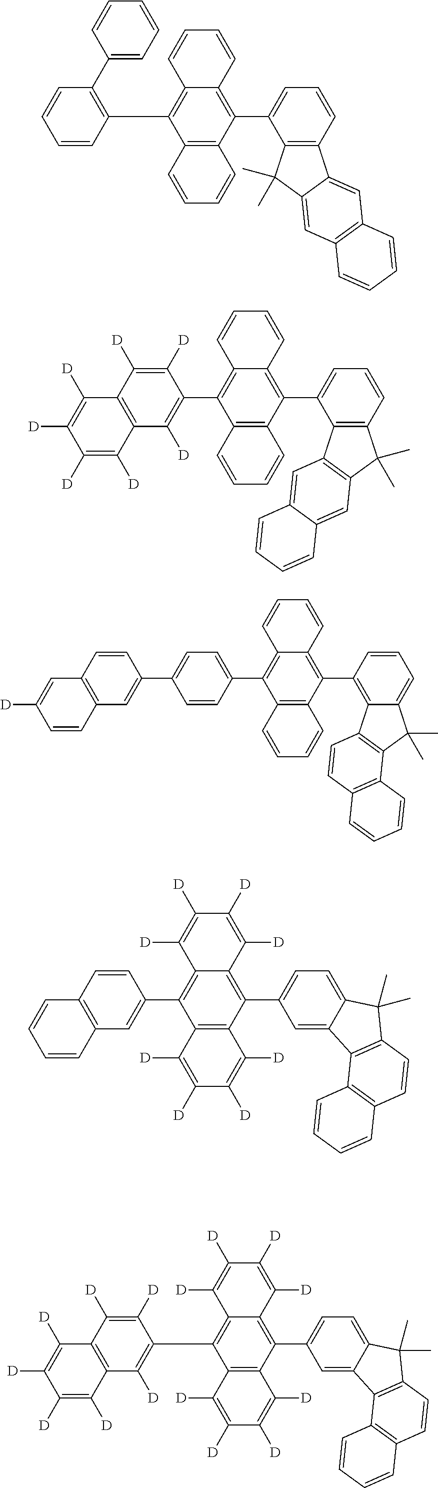

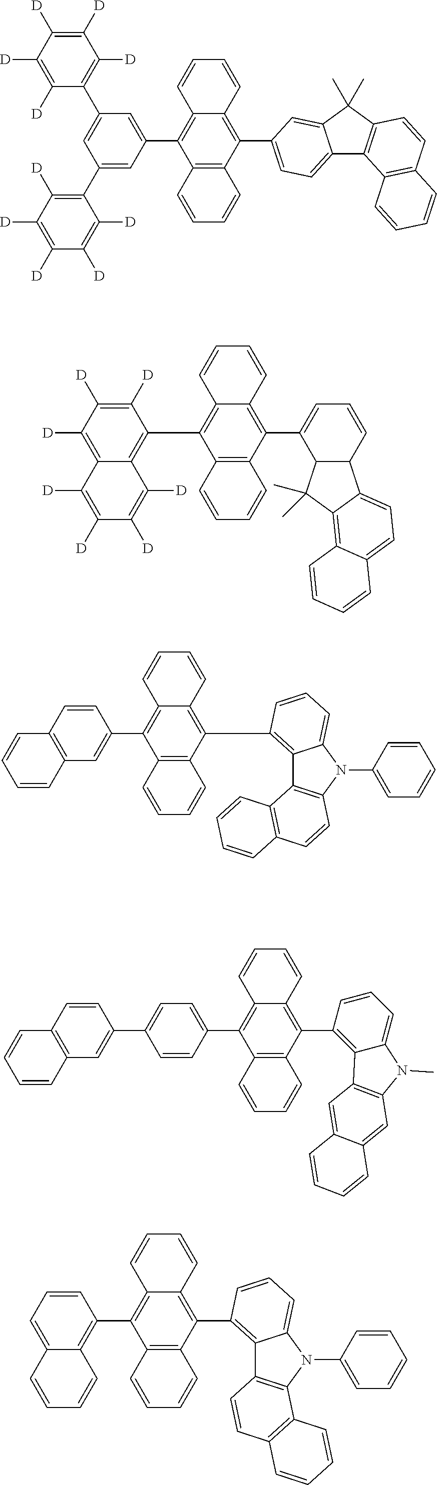 [SMILES: [2H]c1c([2H])c([2H])c(-c2cc(-c3c([2H])c([2H])c([2H])c([2H])c3[2H])cc(-c3c4ccccc4c(-c4ccc5c(c4)C(C)(C)c4ccc6ccccc6c4-5)c4ccccc34)c2)c([2H])c1[2H] ; [2H]c1c([2H])c([2H])c2c(-c3c4ccccc4c(C4=CC=CC5c6ccc7ccccc7c6C(C)(C)C45)c4ccccc34)c([2H])c([2H])c([2H])c2c1[2H] ; c1ccc(-n2c3cccc(-c4c5ccccc5c(-c5ccc6ccccc6c5)c5ccccc45)c3c3c4ccccc4ccc32)cc1 ; Cn1c2cc3ccccc3cc2c2c(-c3c4ccccc4c(-c4ccc(-c5ccc6ccccc6c5)cc4)c4ccccc34)cccc21 ; c1ccc(-n2c3cccc(-c4c5ccccc5c(-c5cccc6ccccc56)c5ccccc45)c3c3ccc4ccccc4c32)cc1]

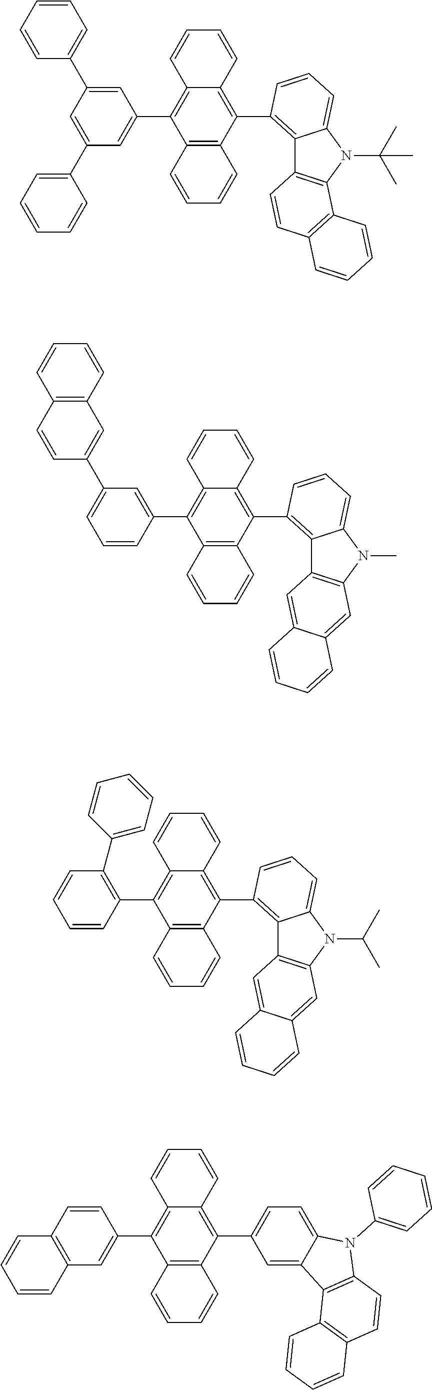

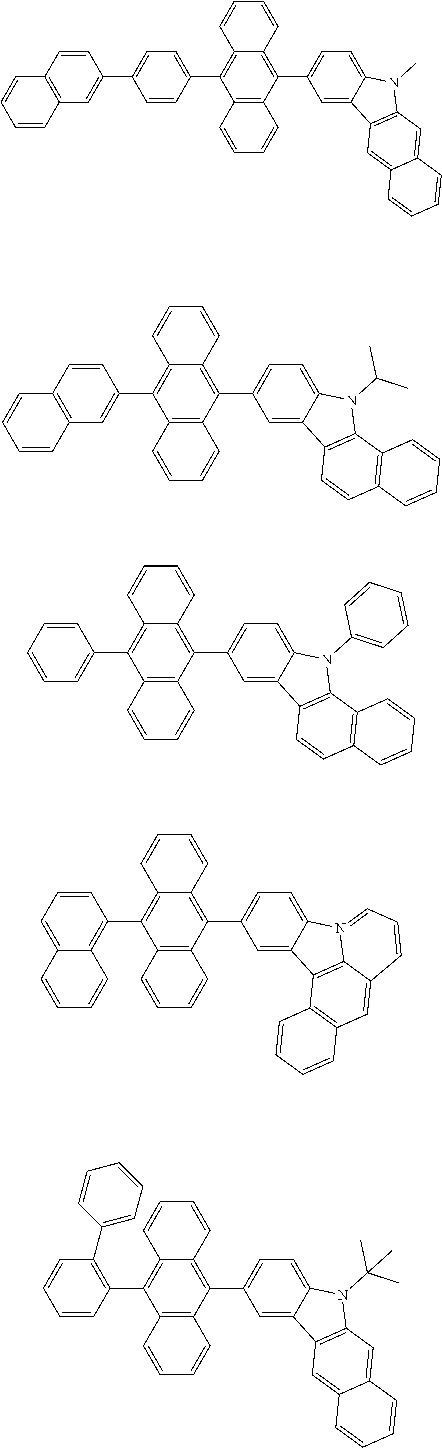

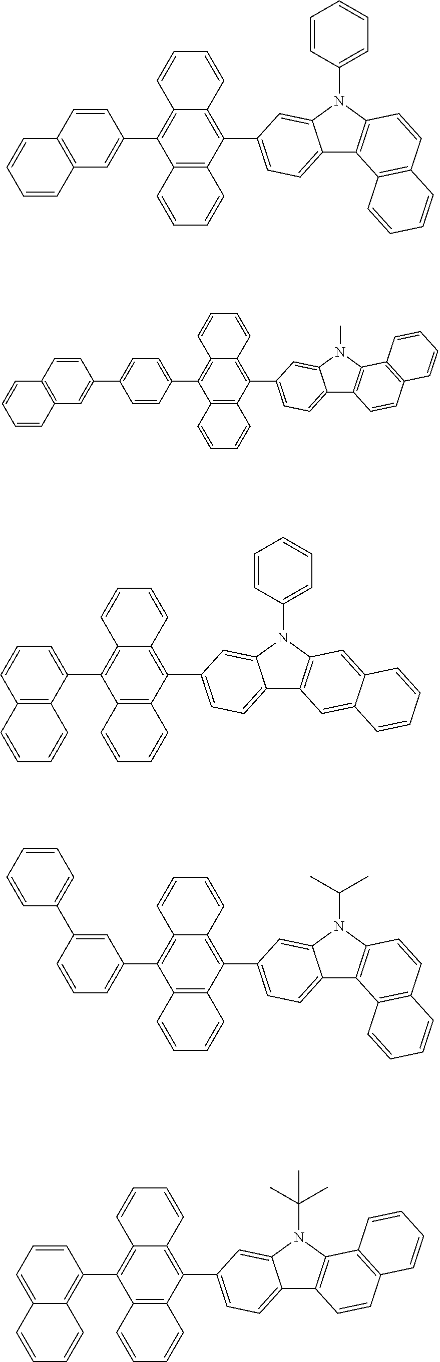

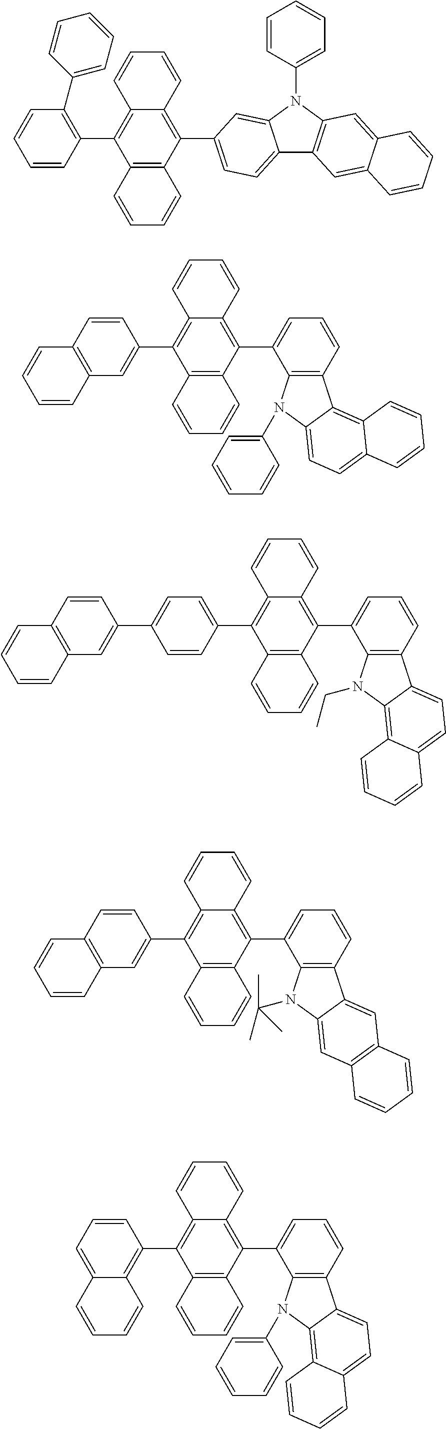

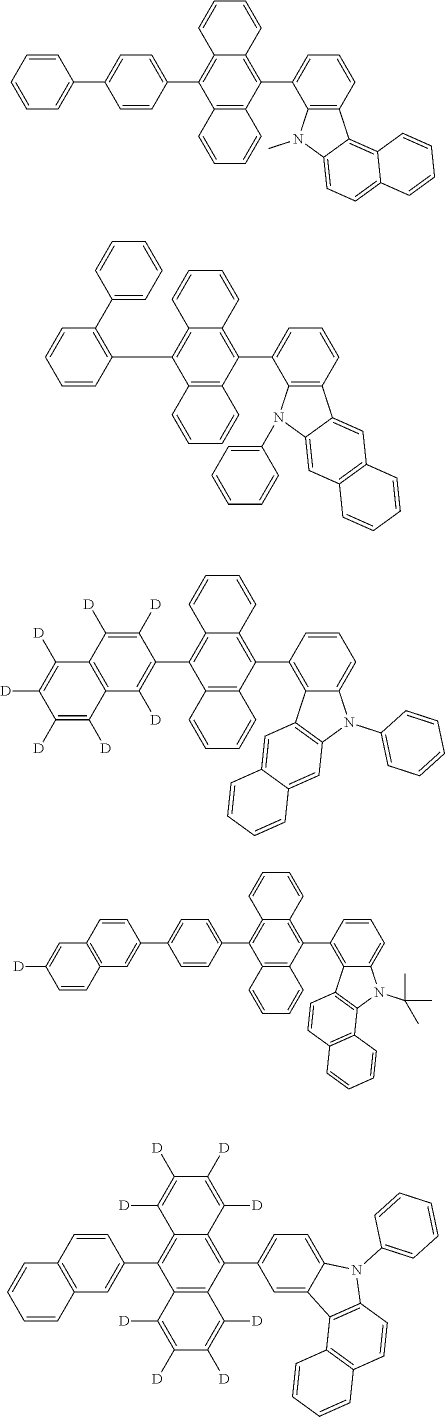

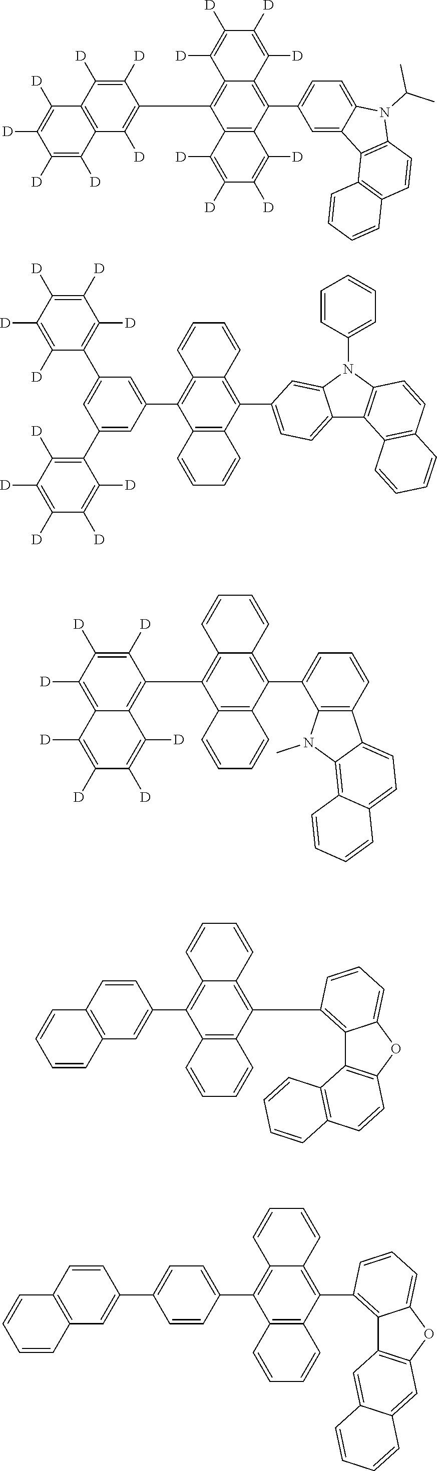

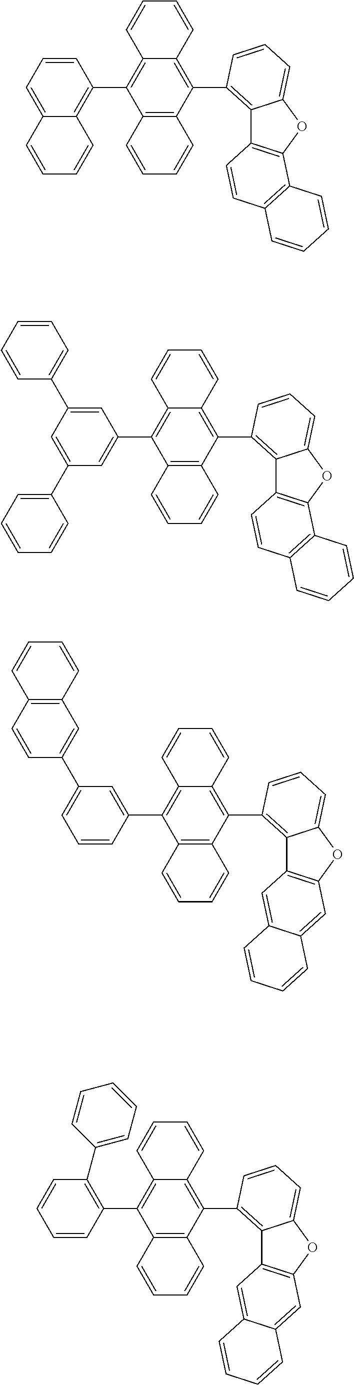 [SMILES: c1ccc2c(-c3c4ccccc4c(-c4cccc5oc6c7ccccc7ccc6c45)c4ccccc34)cccc2c1 ; c1ccc(-c2cc(-c3ccccc3)cc(-c3c4ccccc4c(-c4cccc5oc6c7ccccc7ccc6c45)c4ccccc34)c2)cc1 ; c1cc(-c2ccc3ccccc3c2)cc(-c2c3ccccc3c(-c3cccc4oc5cc6ccccc6cc5c34)c3ccccc23)c1 ; c1ccc(-c2ccccc2-c2c3ccccc3c(-c3cccc4oc5cc6ccccc6cc5c34)c3ccccc23)cc1]

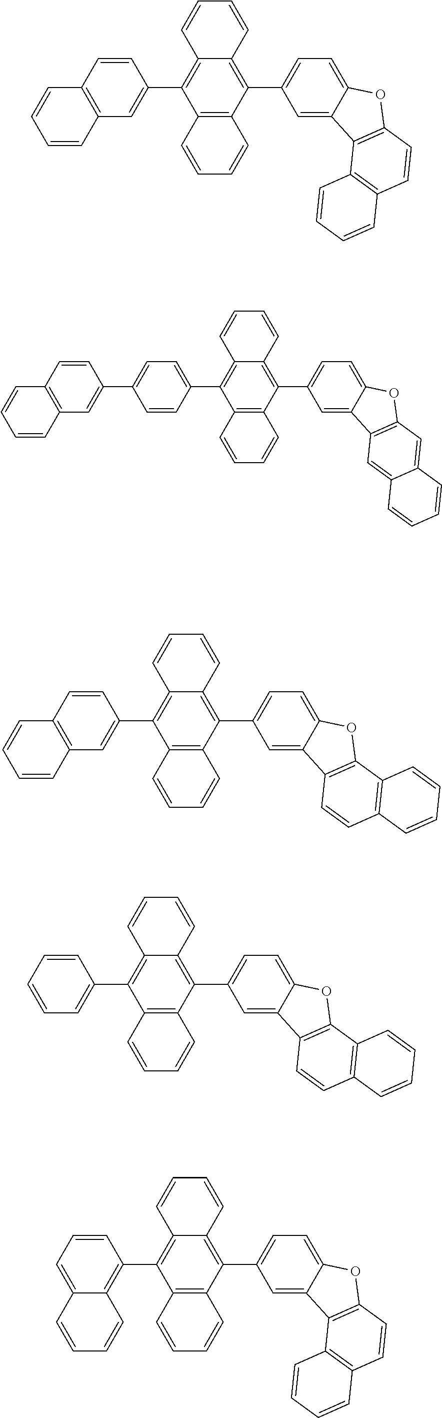 [SMILES: c1ccc2cc(-c3c4ccccc4c(-c4ccc5oc6ccc7ccccc7c6c5c4)c4ccccc34)ccc2c1 ; c1ccc2cc(-c3ccc(-c4c5ccccc5c(-c5ccc6oc7cc8ccccc8cc7c6c5)c5ccccc45)cc3)ccc2c1 ; c1ccc2cc(-c3c4ccccc4c(-c4ccc5oc6c7ccccc7ccc6c5c4)c4ccccc34)ccc2c1 ; c1ccc(-c2c3ccccc3c(-c3ccc4oc5c6ccccc6ccc5c4c3)c3ccccc23)cc1 ; c1ccc2c(-c3c4ccccc4c(-c4ccc5oc6ccc7ccccc7c6c5c4)c4ccccc34)cccc2c1]

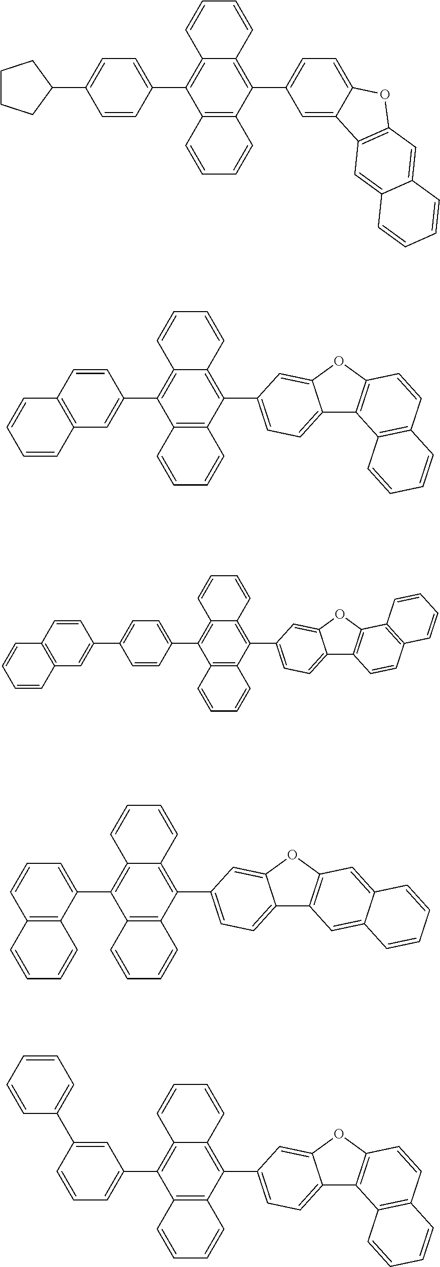 [SMILES: c1ccc2cc3c(cc2c1)oc1ccc(-c2c4ccccc4c(-c4ccc(C5CCCC5)cc4)c4ccccc24)cc13 ; c1ccc2cc(-c3c4ccccc4c(-c4ccc5c(c4)oc4ccc6ccccc6c45)c4ccccc34)ccc2c1 ; c1ccc2cc(-c3ccc(-c4c5ccccc5c(-c5ccc6c(c5)oc5c7ccccc7ccc65)c5ccccc45)cc3)ccc2c1 ; c1ccc2cc3c(cc2c1)oc1cc(-c2c4ccccc4c(-c4cccc5ccccc45)c4ccccc24)ccc13 ; c1ccc(-c2cccc(-c3c4ccccc4c(-c4ccc5c(c4)oc4ccc6ccccc6c45)c4ccccc34)c2)cc1]

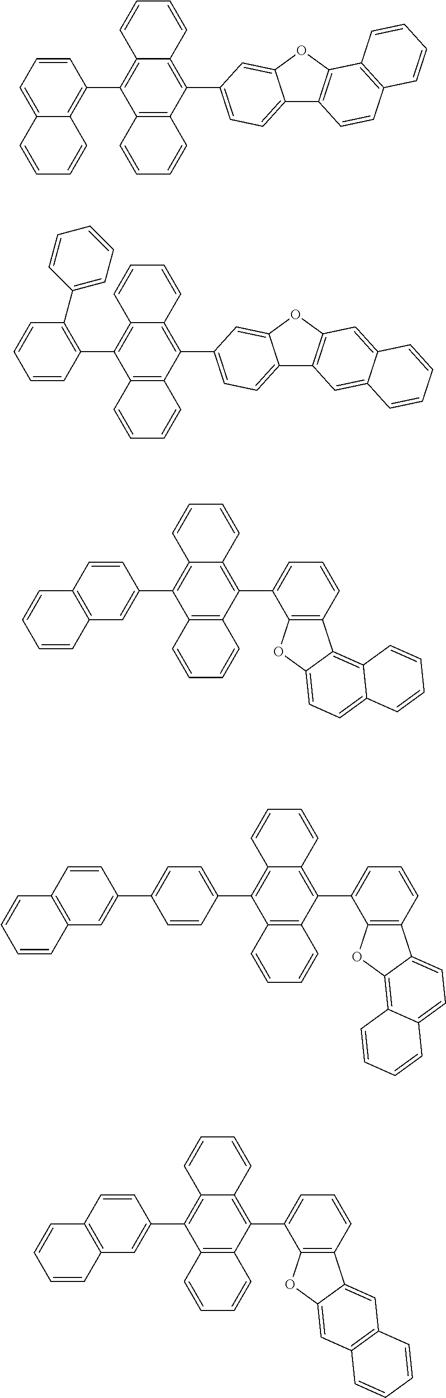 [SMILES: c1ccc2c(-c3c4ccccc4c(-c4ccc5c(c4)oc4c6ccccc6ccc54)c4ccccc34)cccc2c1 ; c1ccc(-c2ccccc2-c2c3ccccc3c(-c3ccc4c(c3)oc3cc5ccccc5cc34)c3ccccc23)cc1 ; c1ccc2cc(-c3c4ccccc4c(-c4cccc5c4oc4ccc6ccccc6c45)c4ccccc34)ccc2c1 ; c1ccc2cc(-c3ccc(-c4c5ccccc5c(-c5cccc6c5oc5c7ccccc7ccc65)c5ccccc45)cc3)ccc2c1 ; c1ccc2cc(-c3c4ccccc4c(-c4cccc5c4oc4cc6ccccc6cc45)c4ccccc34)ccc2c1]

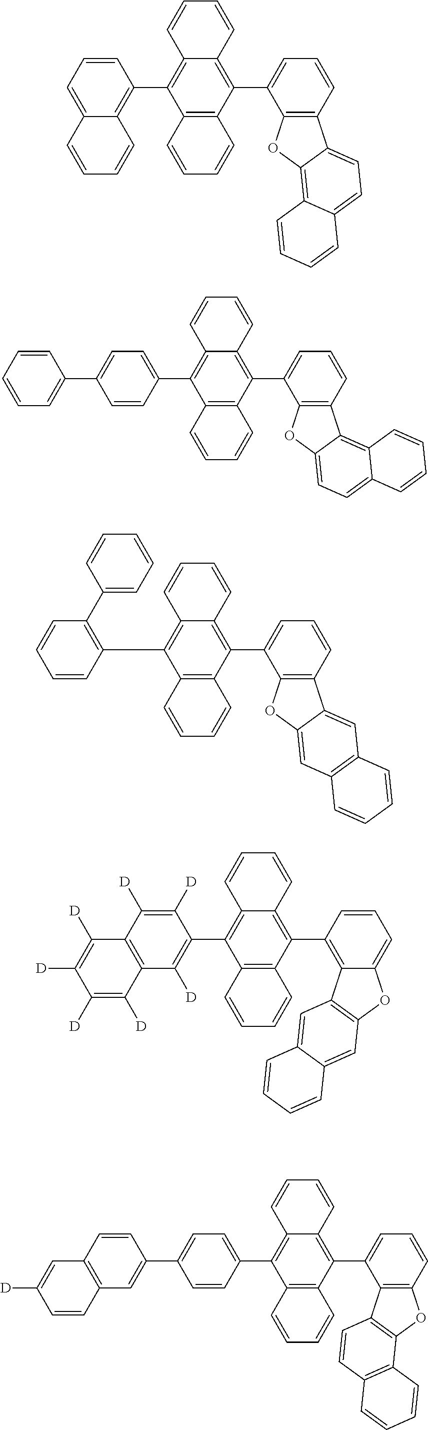 [SMILES: c1ccc2c(-c3c4ccccc4c(-c4cccc5c4oc4c6ccccc6ccc54)c4ccccc34)cccc2c1 ; c1ccc(-c2ccc(-c3c4ccccc4c(-c4cccc5c4oc4ccc6ccccc6c45)c4ccccc34)cc2)cc1 ; c1ccc(-c2ccccc2-c2c3ccccc3c(-c3cccc4c3oc3cc5ccccc5cc34)c3ccccc23)cc1 ; [2H]c1c([2H])c([2H])c2c([2H])c(-c3c4ccccc4c(-c4cccc5oc6cc7ccccc7cc6c45)c4ccccc34)c([2H])c([2H])c2c1[2H] ; [2H]c1ccc2cc(-c3ccc(-c4c5ccccc5c(-c5cccc6oc7c8ccccc8ccc7c56)c5ccccc45)cc3)ccc2c1]

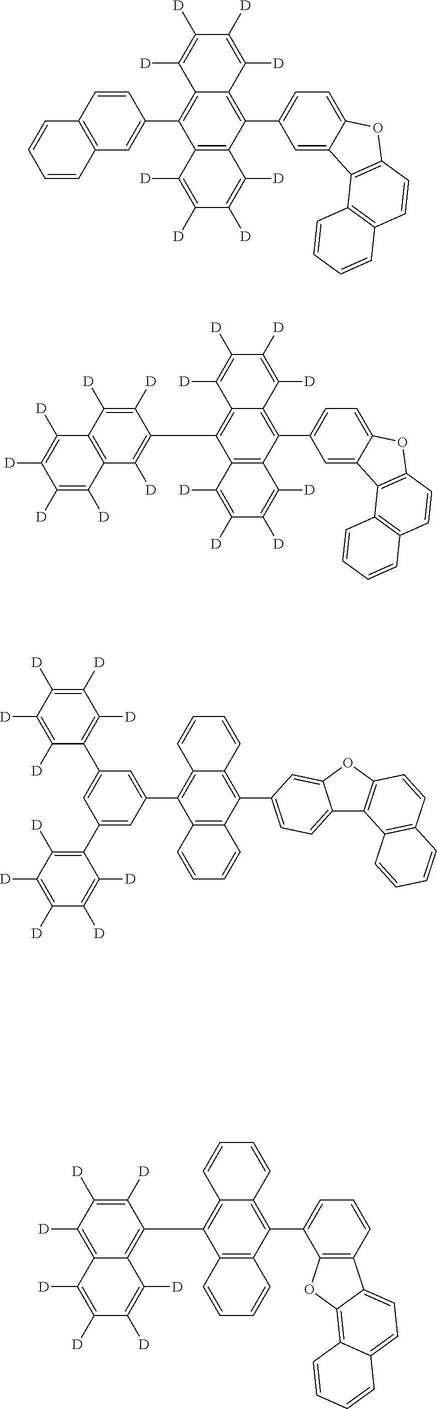

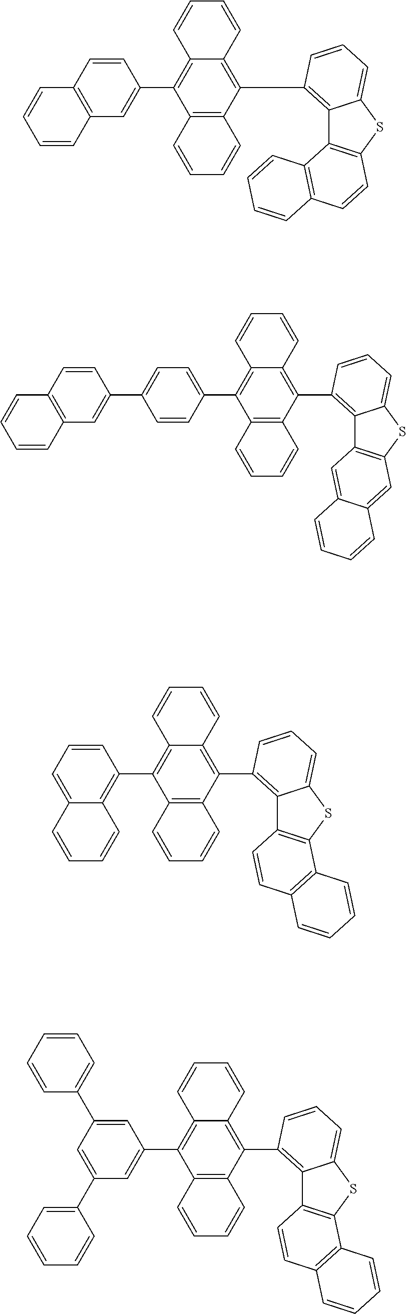 [SMILES: c1ccc2cc(-c3c4ccccc4c(-c4cccc5sc6ccc7ccccc7c6c45)c4ccccc34)ccc2c1 ; c1ccc2cc(-c3ccc(-c4c5ccccc5c(-c5cccc6sc7cc8ccccc8cc7c56)c5ccccc45)cc3)ccc2c1 ; c1ccc2c(-c3c4ccccc4c(-c4cccc5sc6c7ccccc7ccc6c45)c4ccccc34)cccc2c1 ; c1ccc(-c2cc(-c3ccccc3)cc(-c3c4ccccc4c(-c4cccc5sc6c7ccccc7ccc6c45)c4ccccc34)c2)cc1]

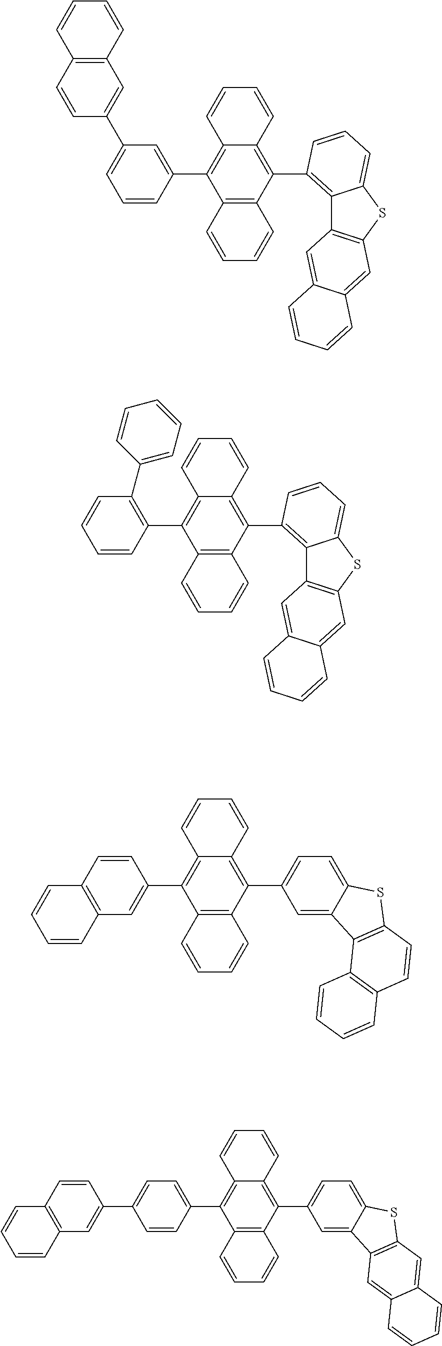 [SMILES: c1cc(-c2ccc3ccccc3c2)cc(-c2c3ccccc3c(-c3cccc4sc5cc6ccccc6cc5c34)c3ccccc23)c1 ; c1ccc(-c2ccccc2-c2c3ccccc3c(-c3cccc4sc5cc6ccccc6cc5c34)c3ccccc23)cc1 ; c1ccc2cc(-c3c4ccccc4c(-c4ccc5sc6ccc7ccccc7c6c5c4)c4ccccc34)ccc2c1 ; c1ccc2cc(-c3ccc(-c4c5ccccc5c(-c5ccc6sc7cc8ccccc8cc7c6c5)c5ccccc45)cc3)ccc2c1]

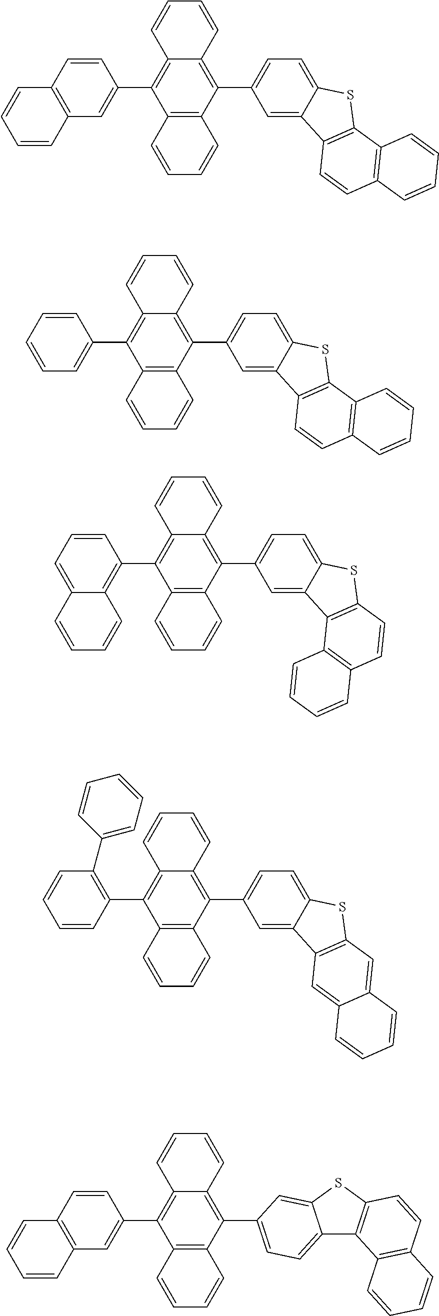 [SMILES: c1ccc2cc(-c3c4ccccc4c(-c4ccc5sc6c7ccccc7ccc6c5c4)c4ccccc34)ccc2c1 ; c1ccc(-c2c3ccccc3c(-c3ccc4sc5c6ccccc6ccc5c4c3)c3ccccc23)cc1 ; c1ccc2c(-c3c4ccccc4c(-c4ccc5sc6ccc7ccccc7c6c5c4)c4ccccc34)cccc2c1 ; c1ccc(-c2ccccc2-c2c3ccccc3c(-c3ccc4sc5cc6ccccc6cc5c4c3)c3ccccc23)cc1 ; c1ccc2cc(-c3c4ccccc4c(-c4ccc5c(c4)sc4ccc6ccccc6c45)c4ccccc34)ccc2c1]

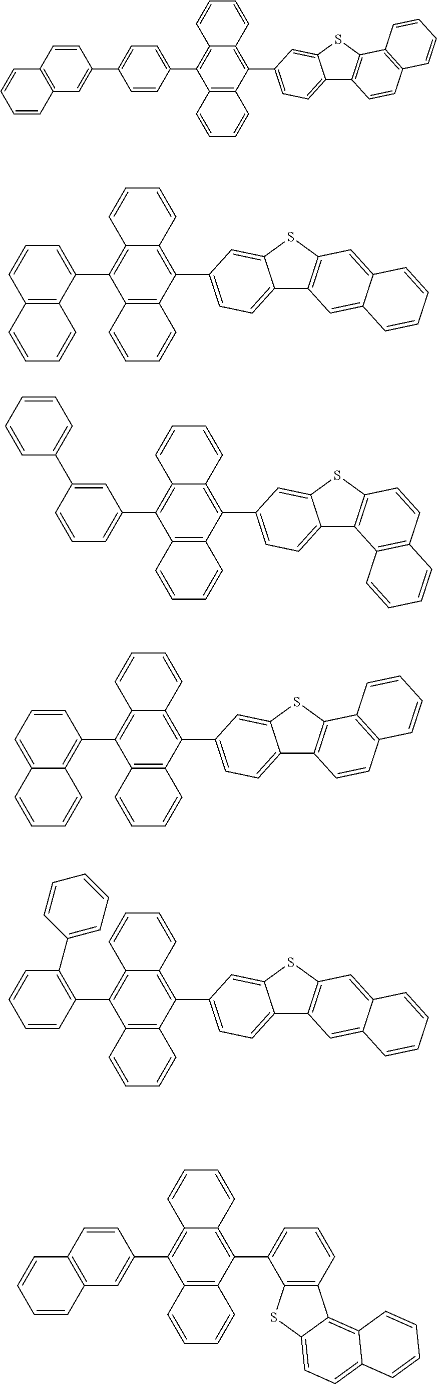

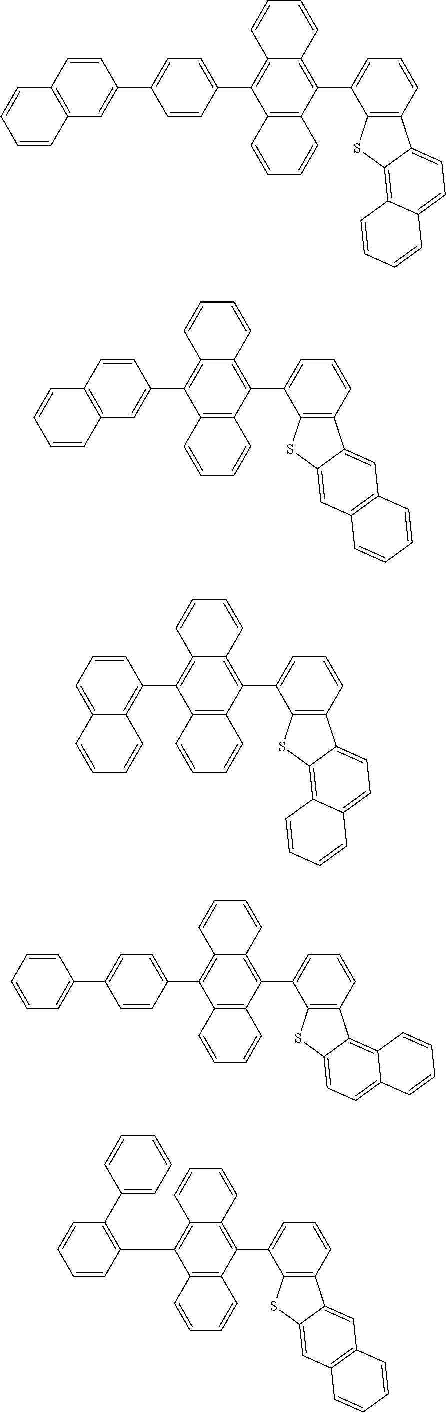 [SMILES: c1ccc2cc(-c3ccc(-c4c5ccccc5c(-c5cccc6c5sc5c7ccccc7ccc65)c5ccccc45)cc3)ccc2c1 ; c1ccc2cc(-c3c4ccccc4c(-c4cccc5c4sc4cc6ccccc6cc45)c4ccccc34)ccc2c1 ; c1ccc2c(-c3c4ccccc4c(-c4cccc5c4sc4c6ccccc6ccc54)c4ccccc34)cccc2c1 ; c1ccc(-c2ccc(-c3c4ccccc4c(-c4cccc5c4sc4ccc6ccccc6c45)c4ccccc34)cc2)cc1 ; c1ccc(-c2ccccc2-c2c3ccccc3c(-c3cccc4c3sc3cc5ccccc5cc34)c3ccccc23)cc1]

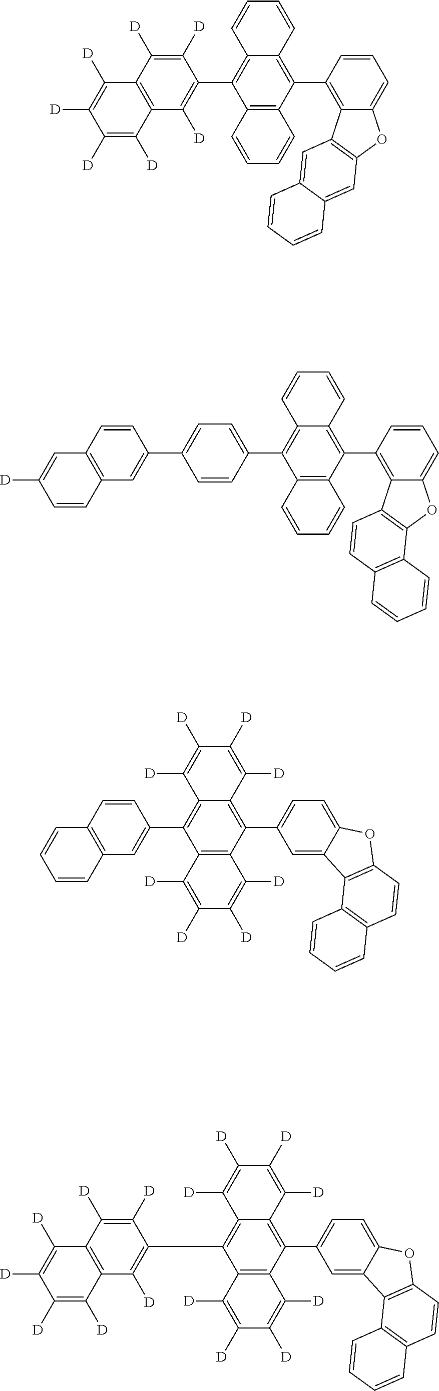 [SMILES: [2H]c1c([2H])c([2H])c2c([2H])c(-c3c4ccccc4c(-c4cccc5oc6cc7ccccc7cc6c45)c4ccccc34)c([2H])c([2H])c2c1[2H] ; [2H]c1ccc2cc(-c3ccc(-c4c5ccccc5c(-c5cccc6oc7c8ccccc8ccc7c56)c5ccccc45)cc3)ccc2c1 ; [2H]c1c([2H])c([2H])c2c(-c3ccc4oc5ccc6ccccc6c5c4c3)c3c([2H])c([2H])c([2H])c([2H])c3c(-c3ccc4ccccc4c3)c2c1[2H] ; [2H]c1c([2H])c([2H])c2c([2H])c(-c3c4c([2H])c([2H])c([2H])c([2H])c4c(-c4ccc5oc6ccc7ccccc7c6c5c4)c4c([2H])c([2H])c([2H])c([2H])c34)c([2H])c([2H])c2c1[2H]]

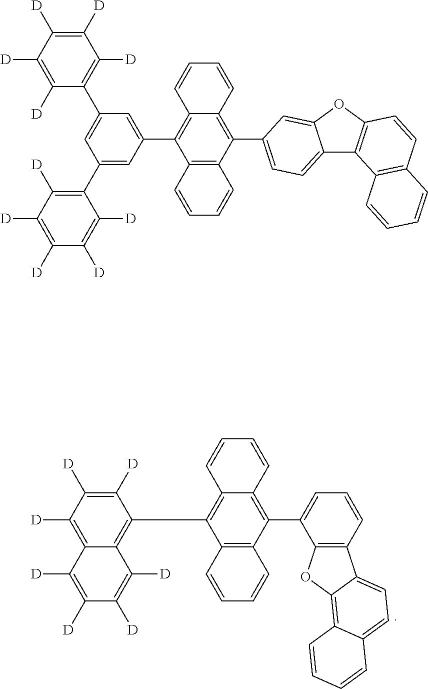 [SMILES: [2H]c1c([2H])c([2H])c(-c2cc(-c3c([2H])c([2H])c([2H])c([2H])c3[2H])cc(-c3c4ccccc4c(-c4ccc5c(c4)oc4ccc6ccccc6c45)c4ccccc34)c2)c([2H])c1[2H] ; [2H]c1c([2H])c([2H])c2c(-c3c4ccccc4c(-c4cccc5c4oc4c6ccccc6ccc54)c4ccccc34)c([2H])c([2H])c([2H])c2c1[2H]]

In some embodiments, Q3 and Q4 are each independently selected from the structures represented by any one of formulae (E-1) to (E-3):

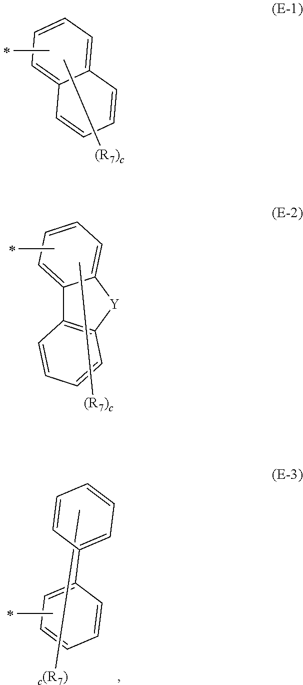

wherein Y is selected from CR₈R₉, NR₁₀, O or S;
R₇, R₈, R₉, R₁₀ are each independently selected from hydrogen, deuterium, a substituted or unsubstituted alkyl group having 1 to 10 carbon atoms, a substituted or unsubstituted aromatic group having 6 to 30 ring atoms or a substituted or unsubstituted heteroaromatic group having 5 to 30 ring atoms, and two adjacent R₁₁ form a ring or not; and
c is selected from any one integer from 0 to 9, for example, it may be 0, 1, 2, 3, 4, 5, 6, 7, 8 or 9.

In some embodiments, R7, R8, R9, R10 are each independently selected from hydrogen, deuterium, methyl, ethyl, isopropyl, tert-butyl, phenyl, cyclopentyl, adamantyl, and the like.

In some embodiments, Q3, Q4 are each independently selected from structures represented by any one of formulae (F-1) to (F-2), (G-1) to (G-4):

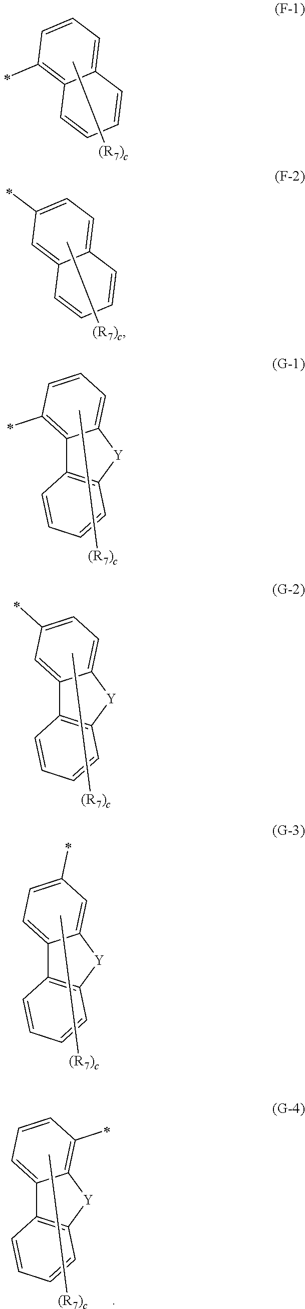

In some embodiments, Q3, Q4 are each independently selected from the following structures:

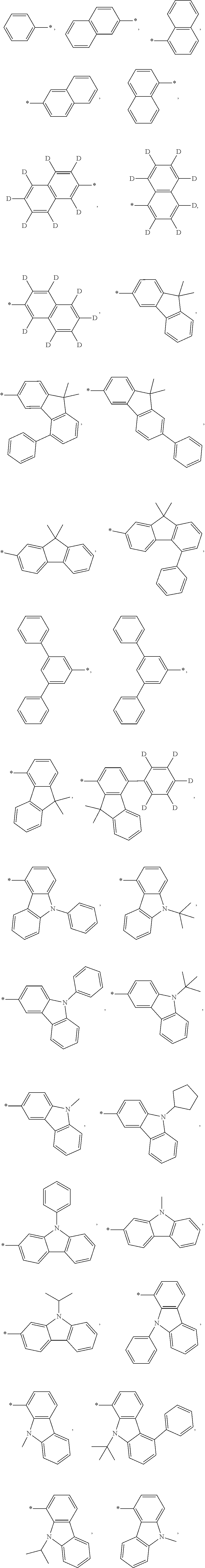

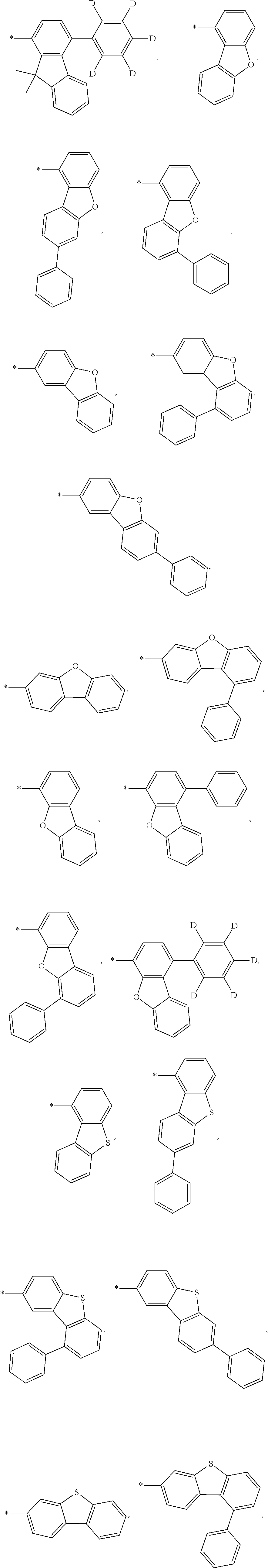

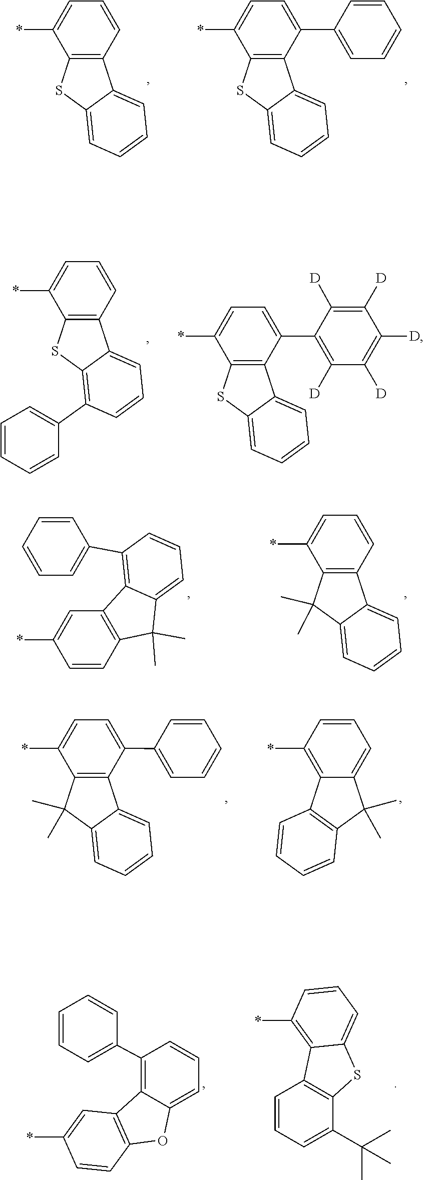

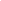

In some embodiments, the second compound has a structure represented by any one of formulae (2-1) to (2-3):

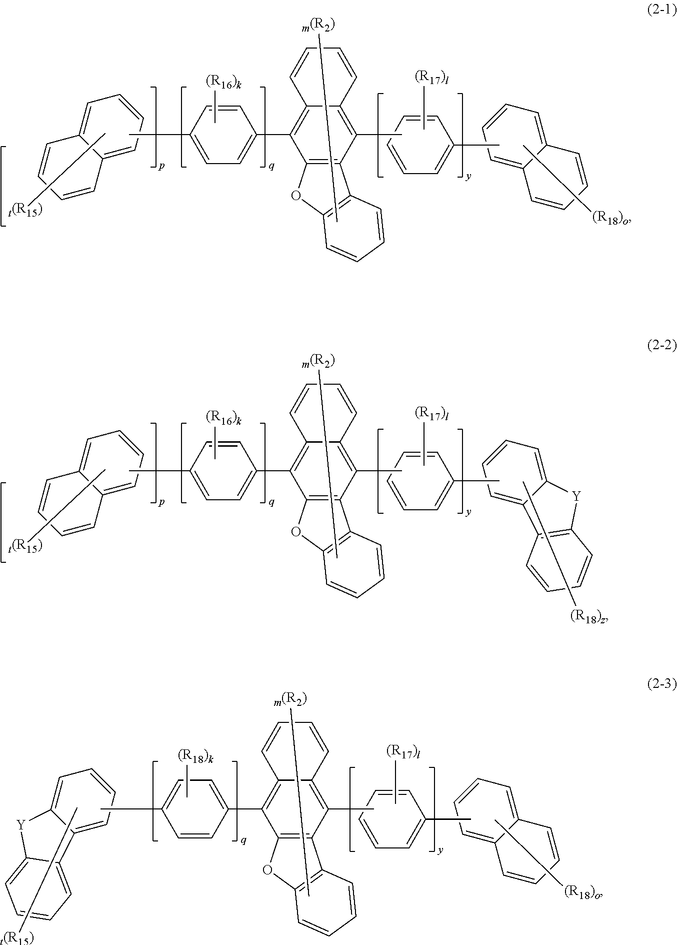

wherein R₁₅, R₁₆, R₁₇, R₁₈ are each independently selected from hydrogen, deuterium, a substituted or unsubstituted alkyl group having 1 to 10 carbon atoms, a substituted or unsubstituted aromatic group having 6 to 30 ring atoms or a substituted or unsubstituted heteroaromatic group having 5 to 30 ring atoms, two adjacent R₁₅ form a ring or not, two adjacent R₁₆ form a ring or not, two adjacent R₁₇ form a ring or not, and two adjacent R₁₈ form a ring or not.

In some embodiments, R15, R16, R17 and R18 are each independently selected from hydrogen, deuterium, methyl, propyl, tert-butyl, cyclopentyl, adamantyl, phenyl, and the like.

In some embodiments, t, o and z are each independently selected from any one integer from 0 to 7, for example, it may be 0, 1, 2, 3, 4, 5, 6 or 7;
k and 1 are each independently selected from any one integer from 0 to 4, for example, it may be 0, 1, 2, 3 or 4;
p may be selected from 0 or 1;
q and y are each independently selected from any one integer from 0 to 3, for example, it may be 0, 1, 2 or 3; and
a sum of p and q is greater than or equal to 1.

In some embodiments, in the structure of formula (2-3), R15 and R18 may be selected from the same group, and R16 and R17 may be selected from the same group. K and 1 may be the same, and q and y may be the same.

In some embodiments, the second compound is selected from:

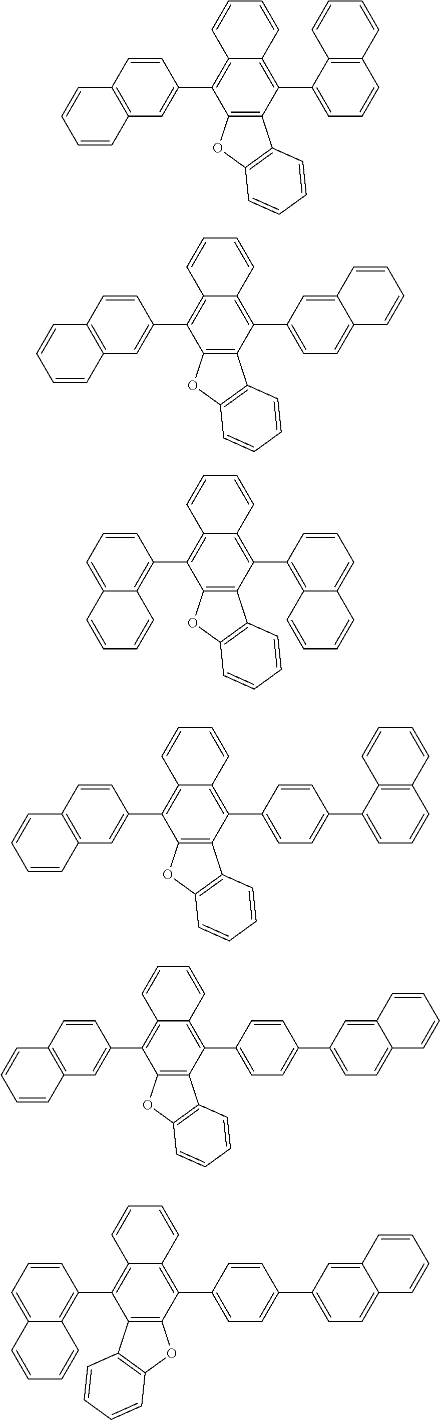

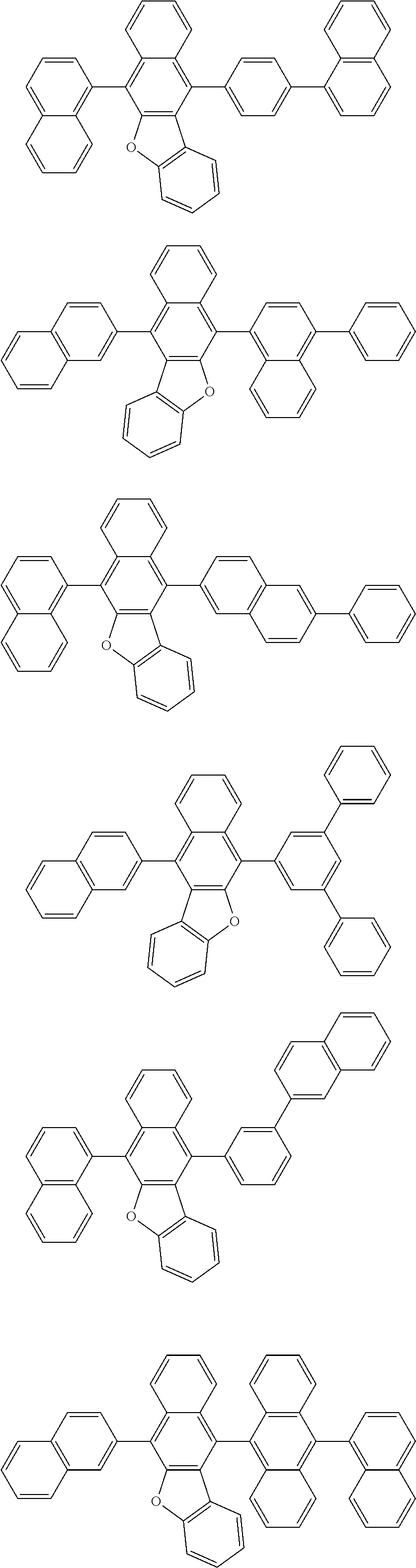

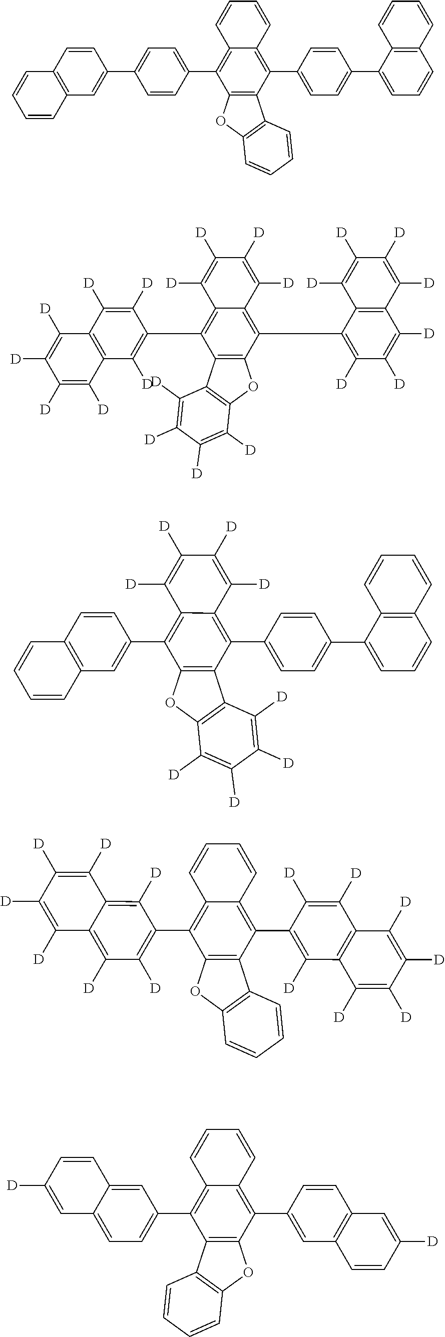

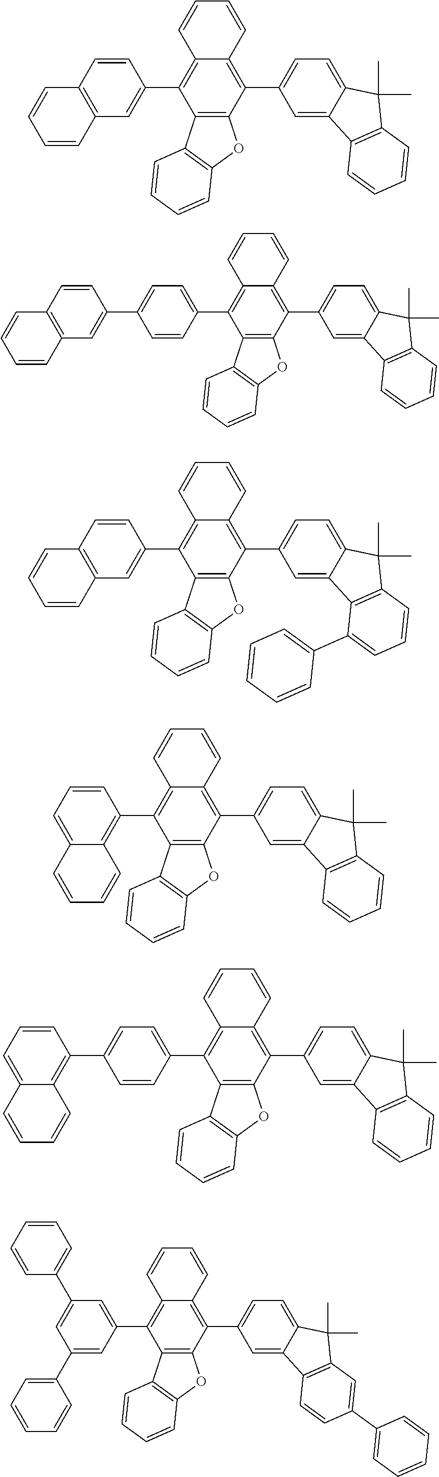

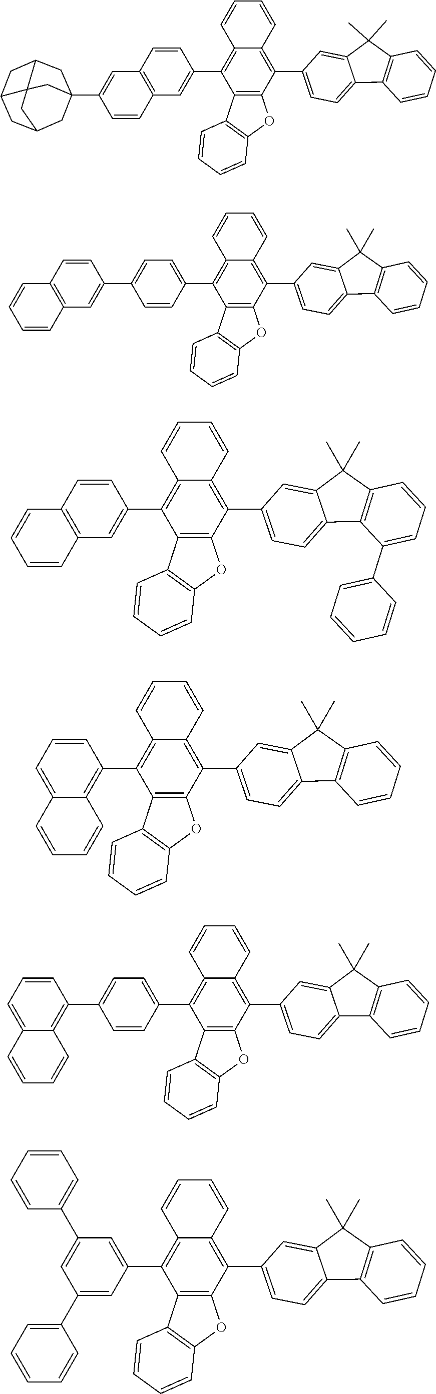

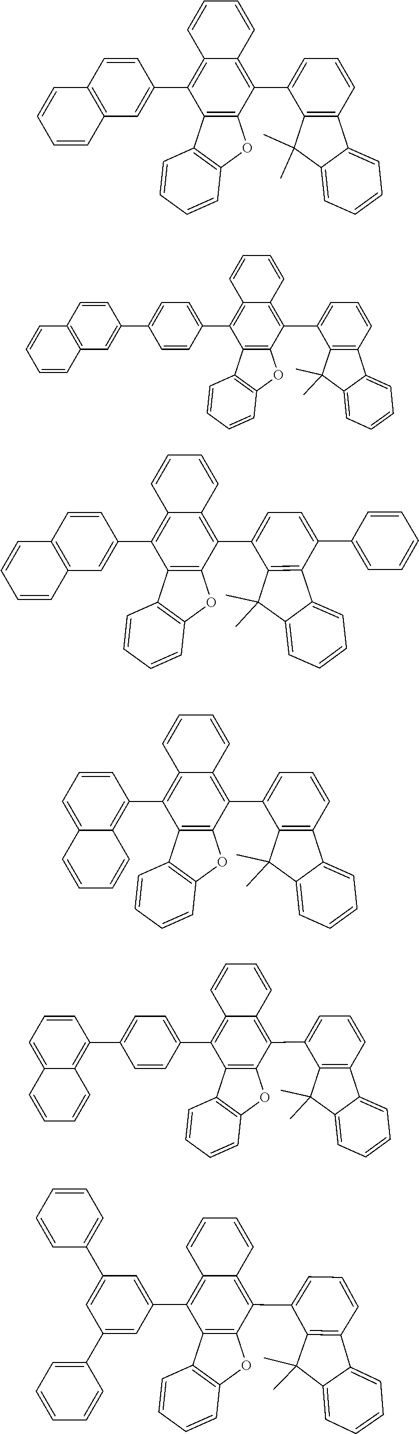

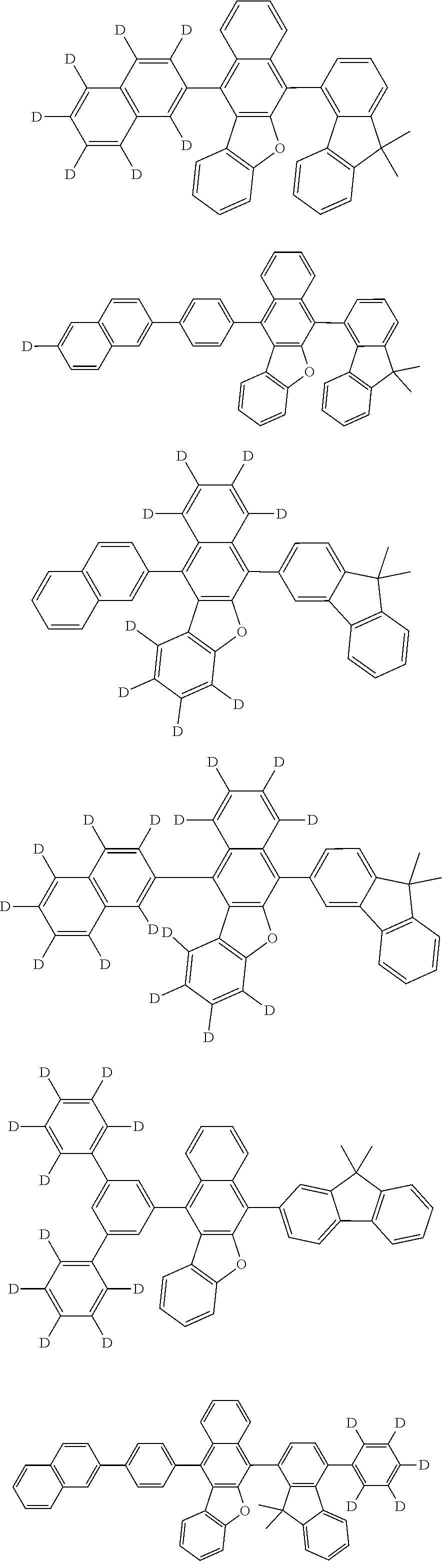

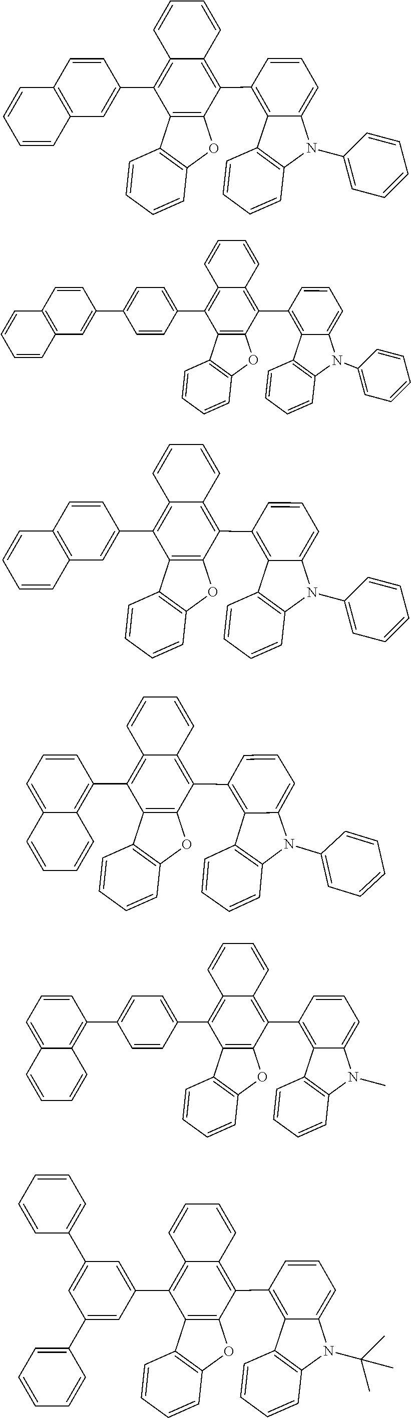

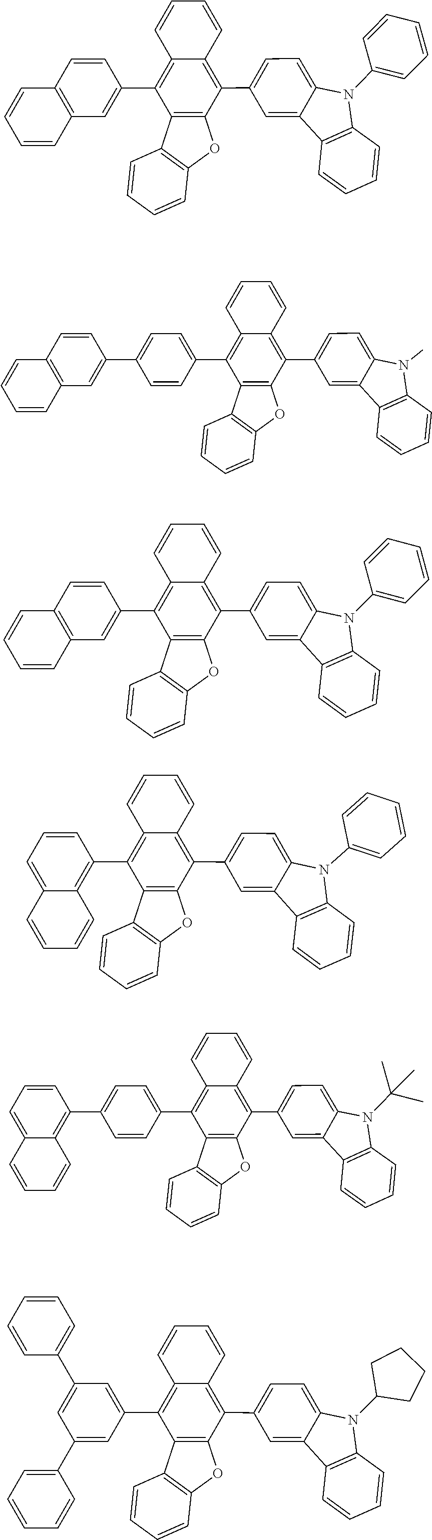

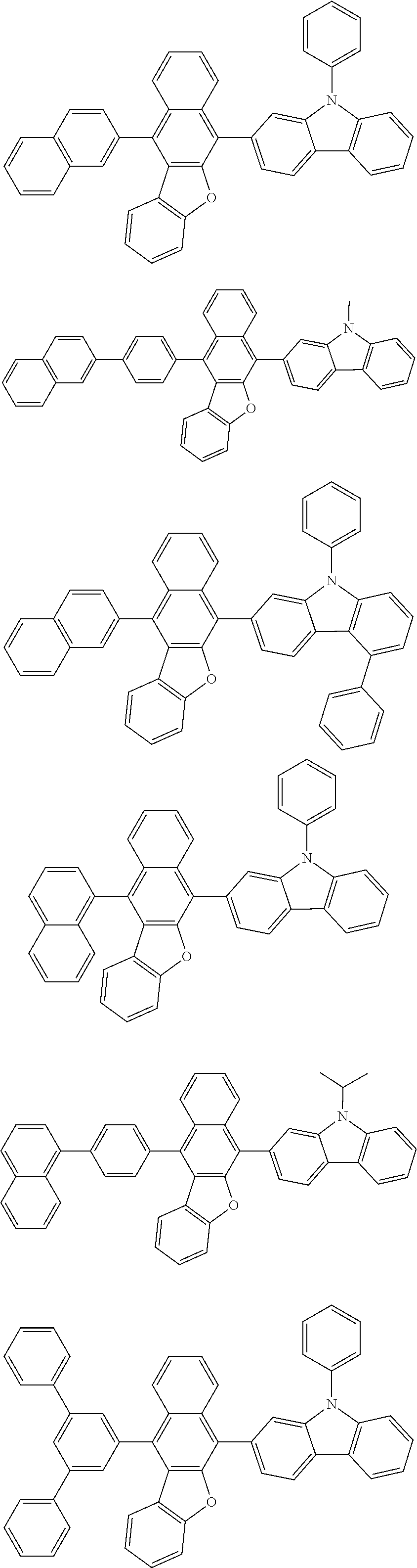

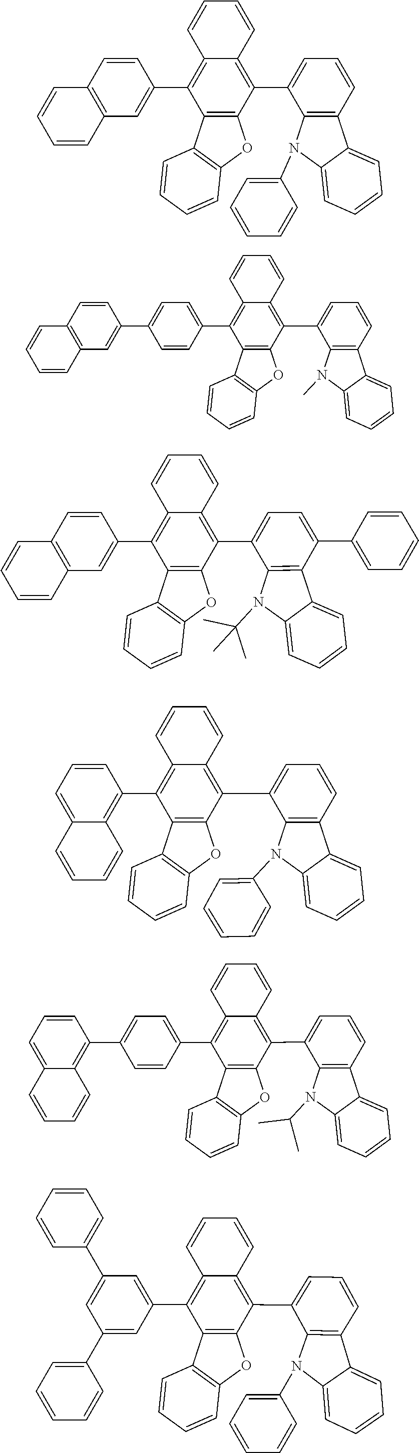

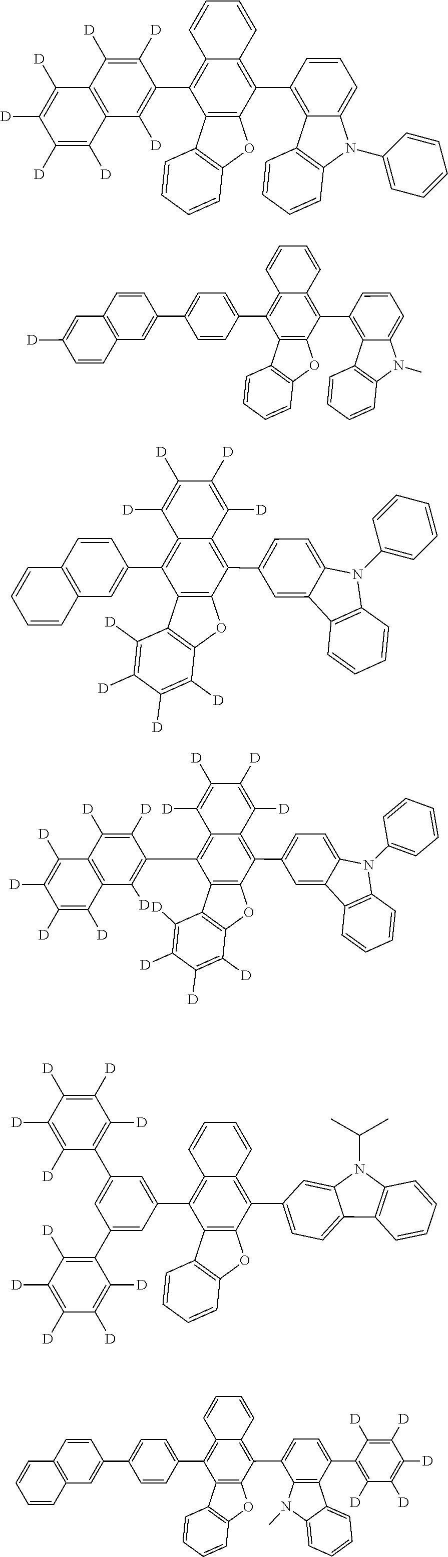

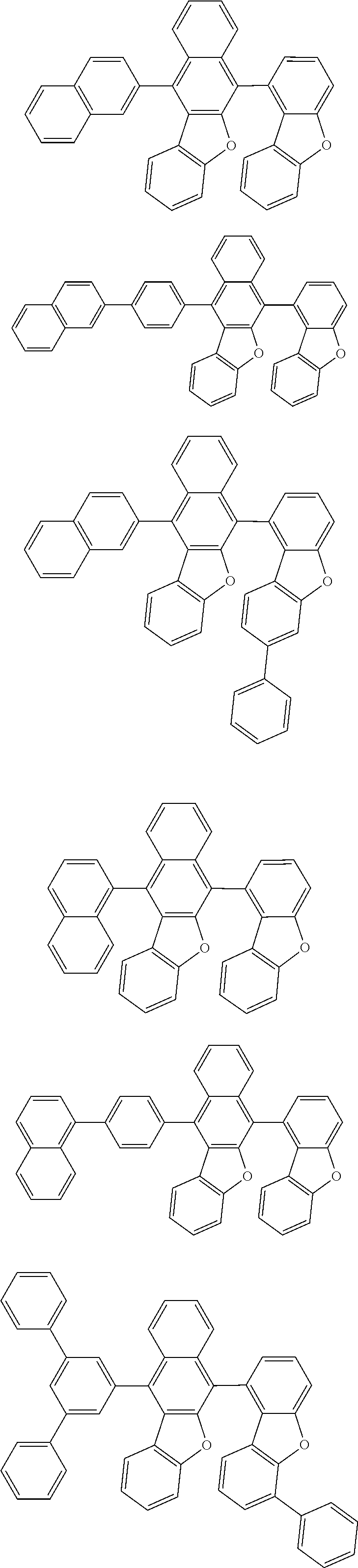

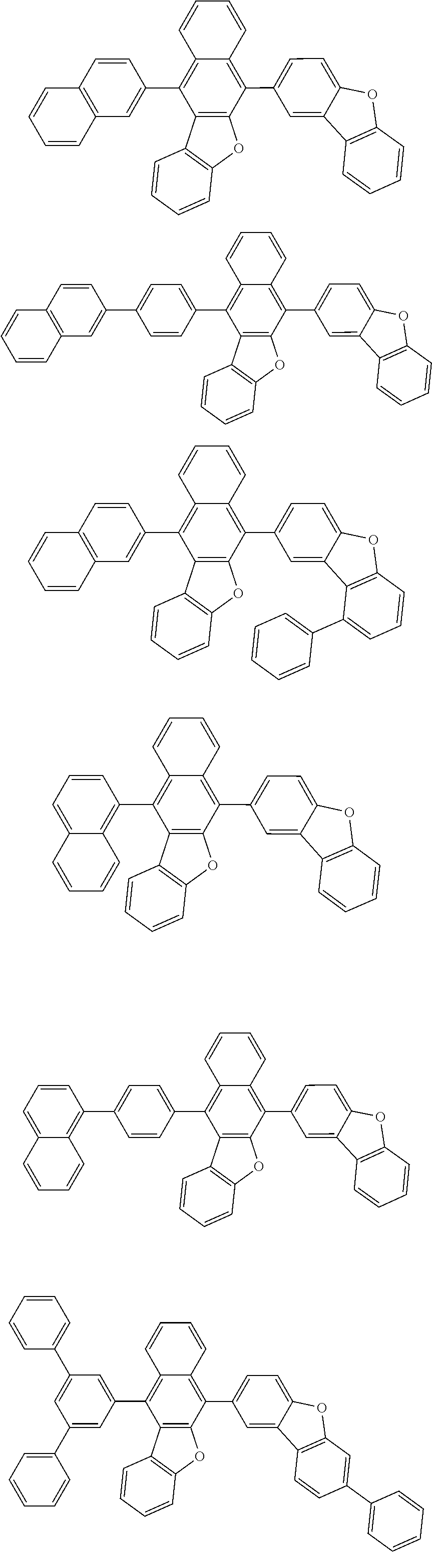

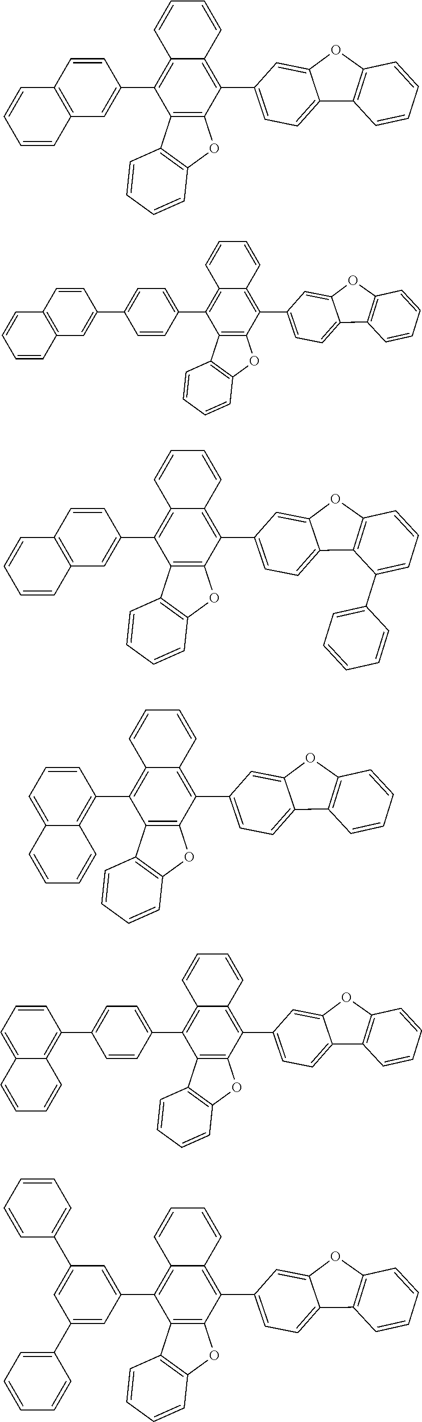

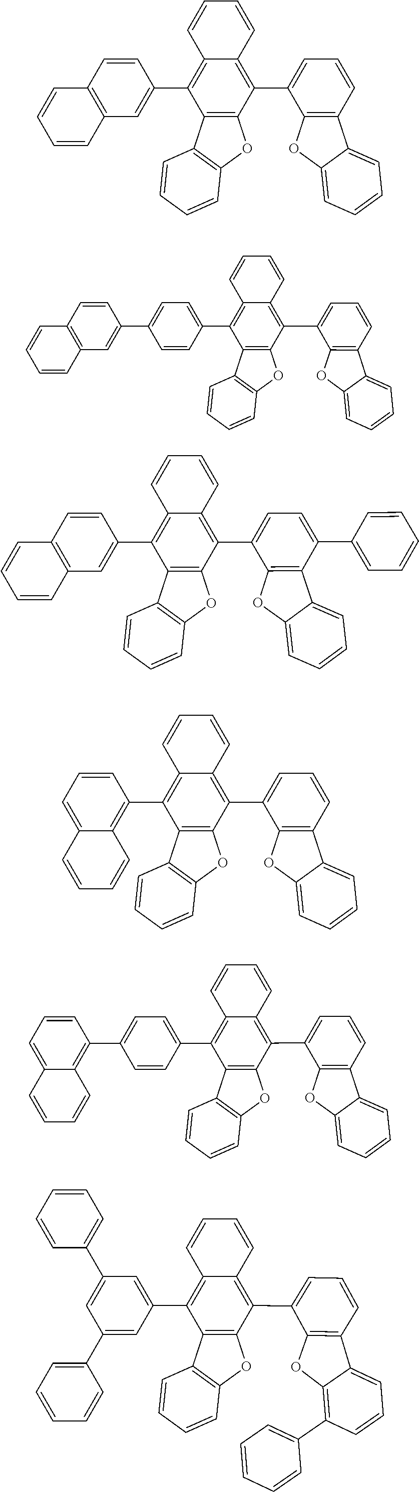

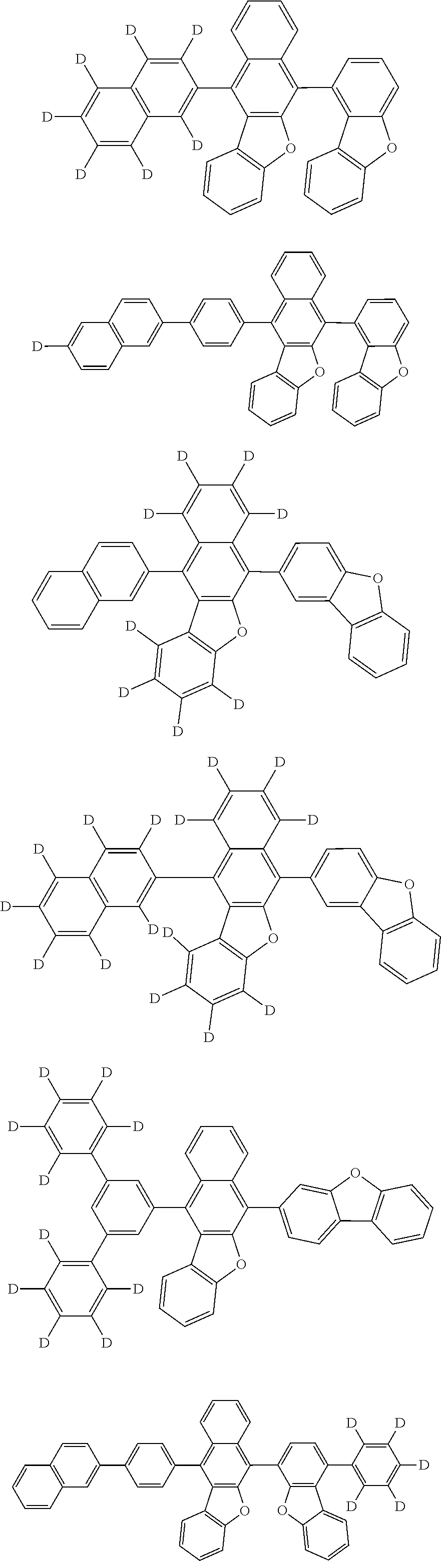

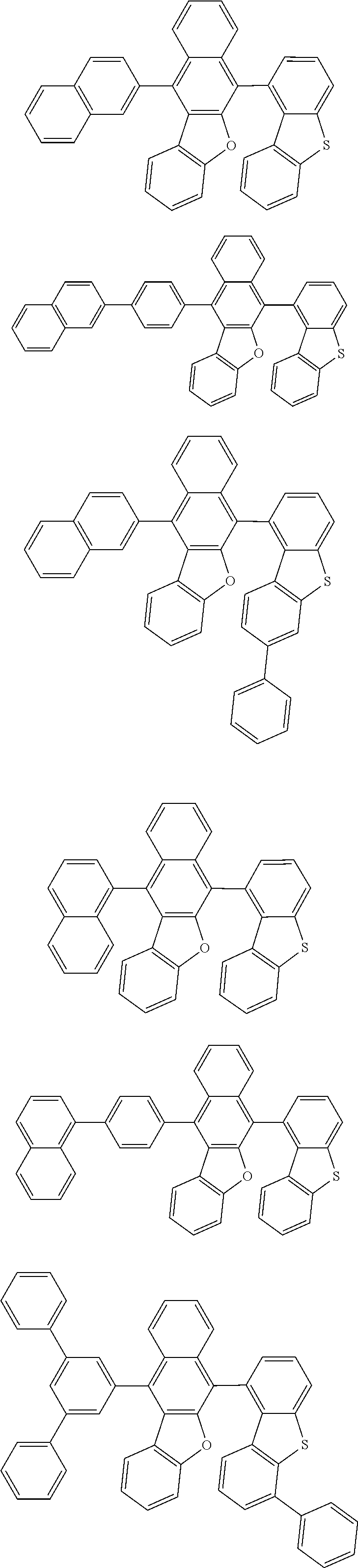

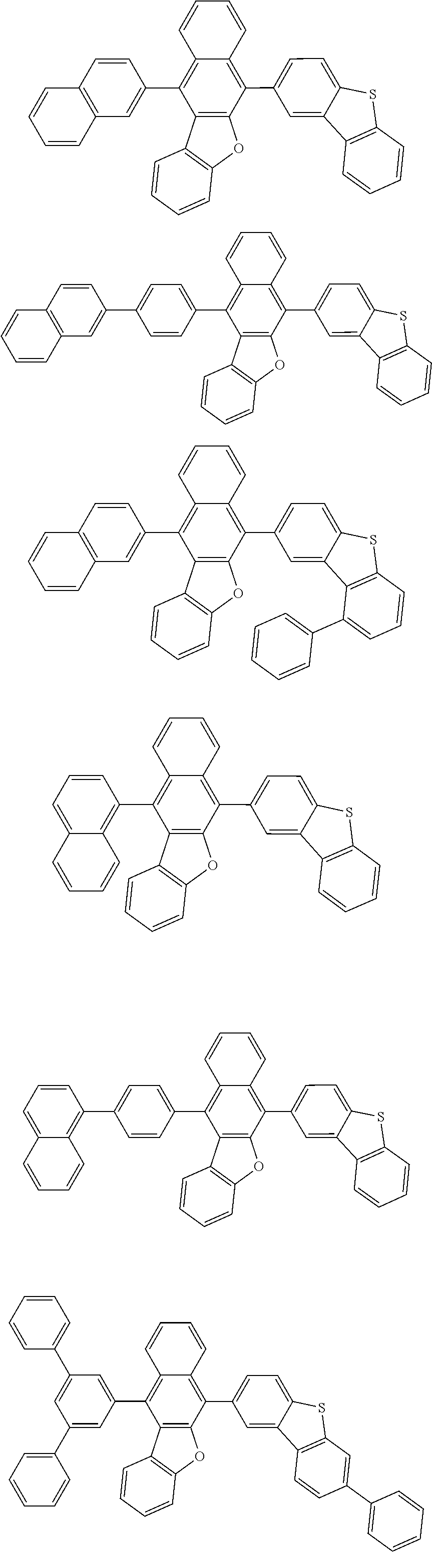

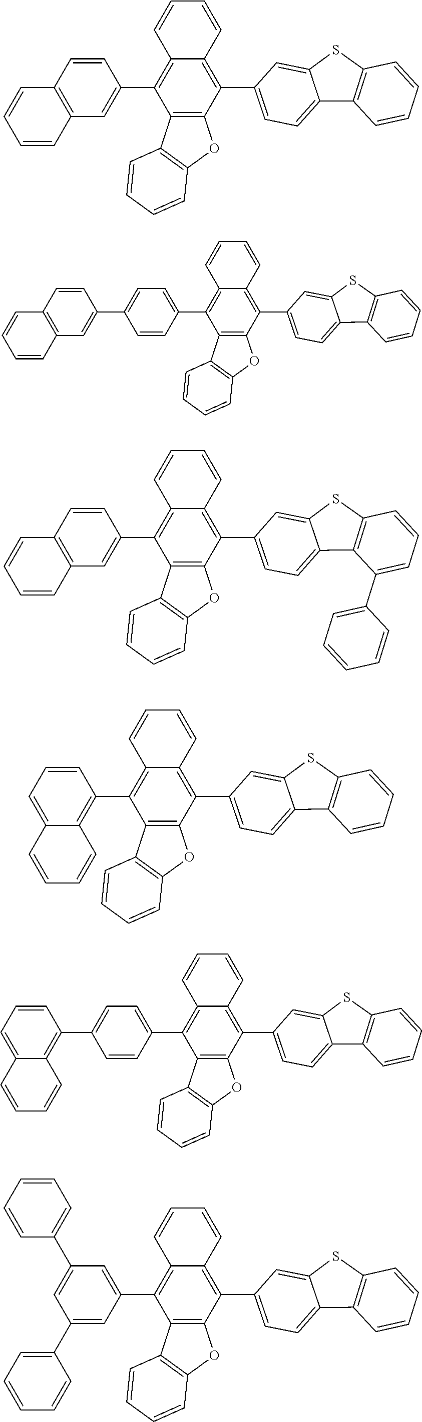

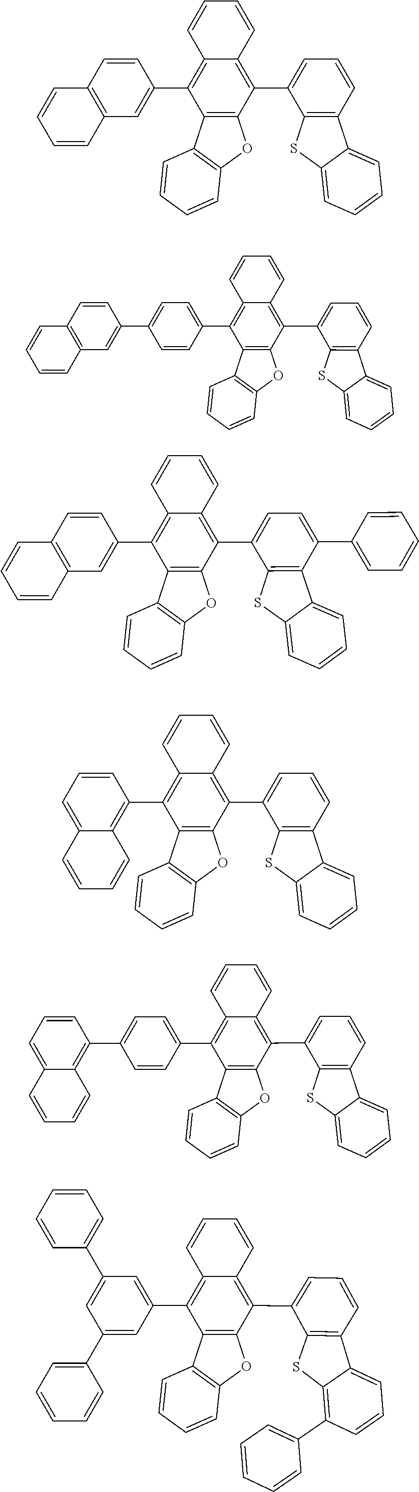

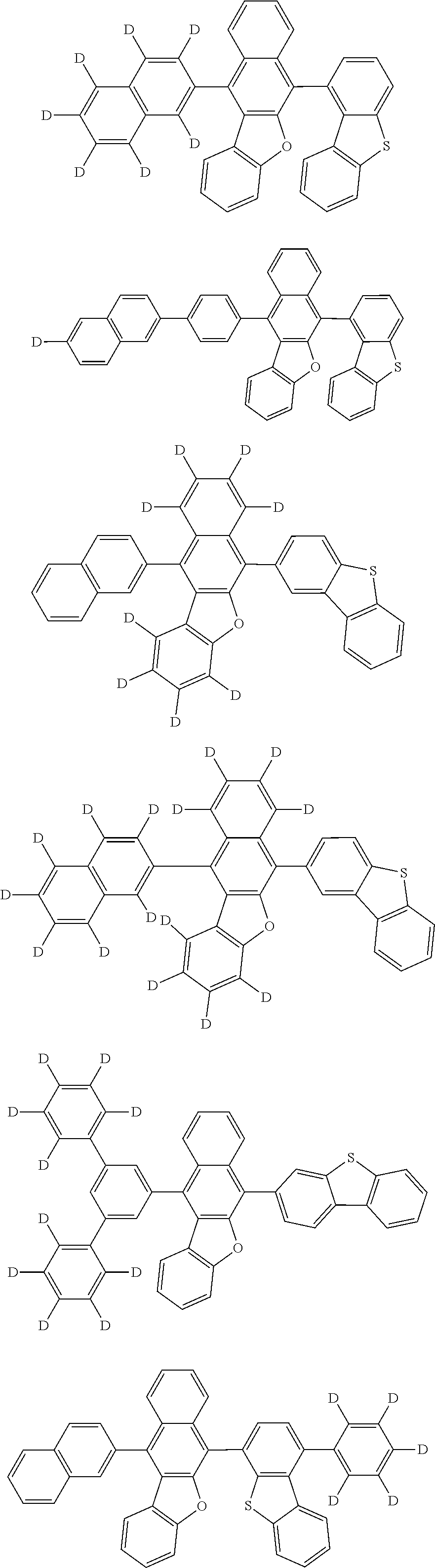

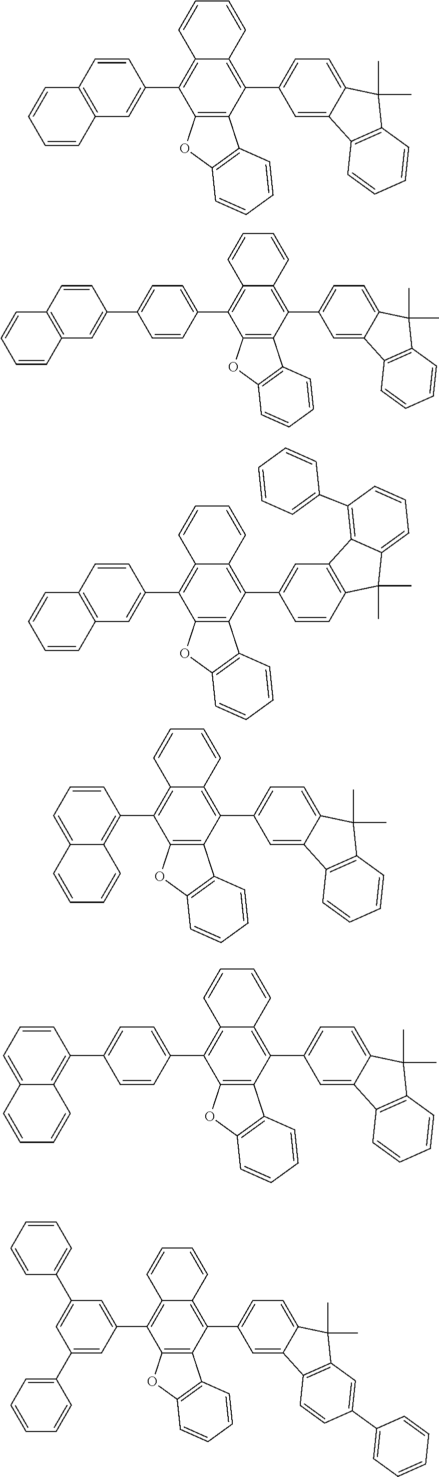

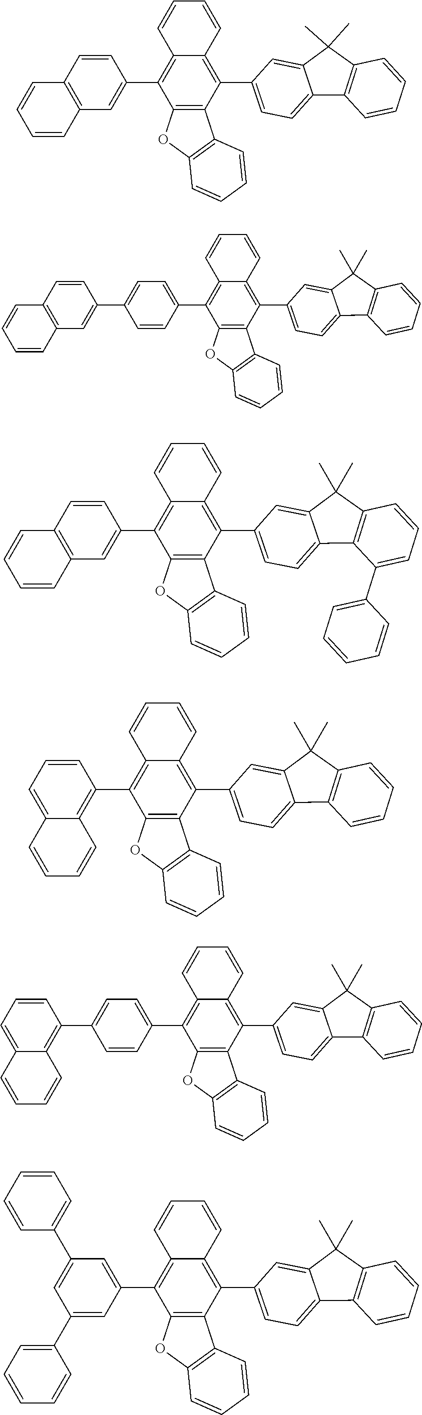

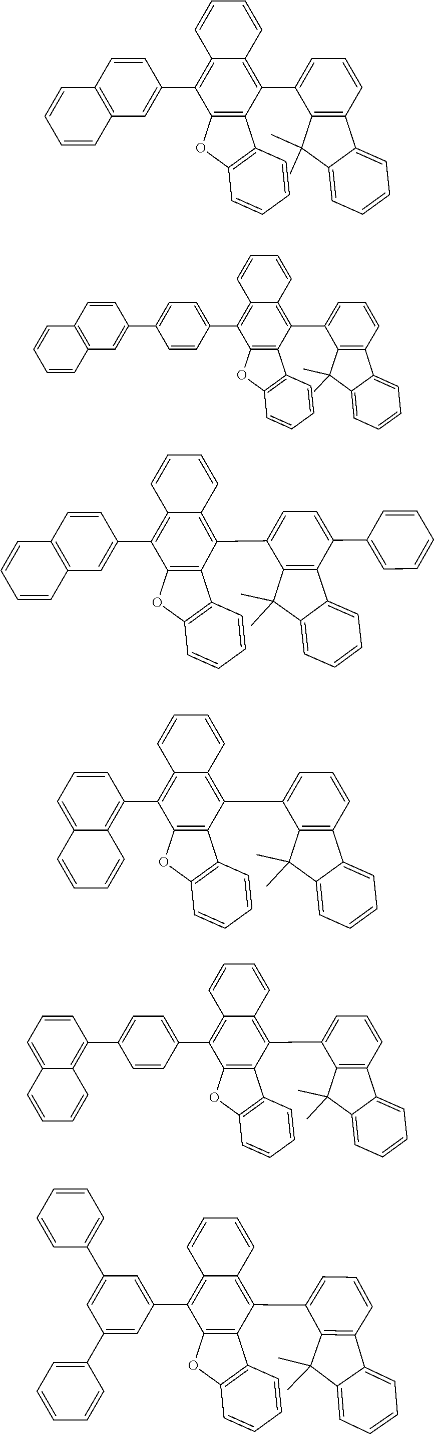

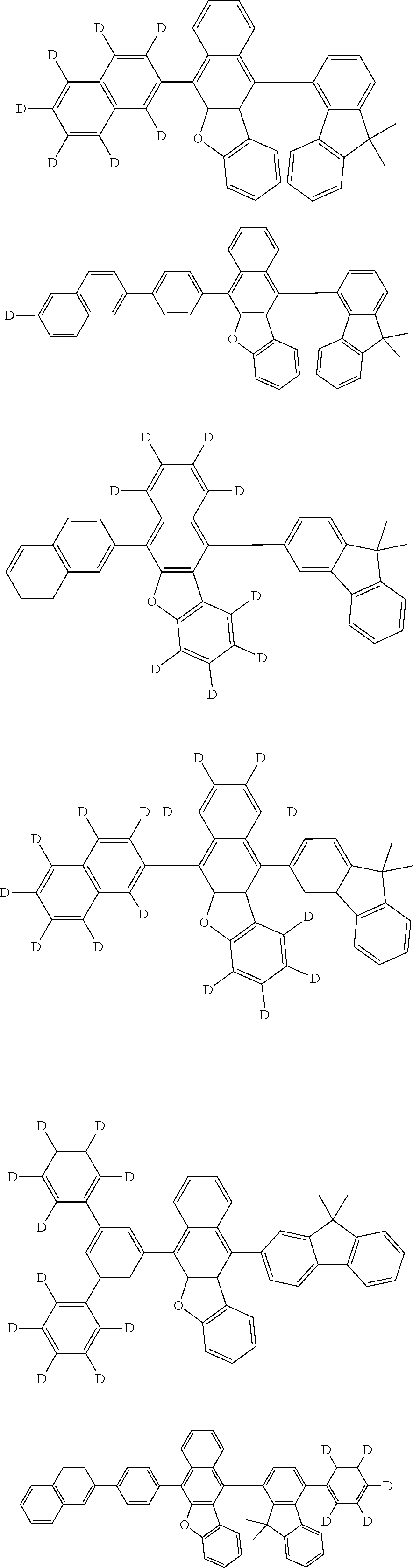

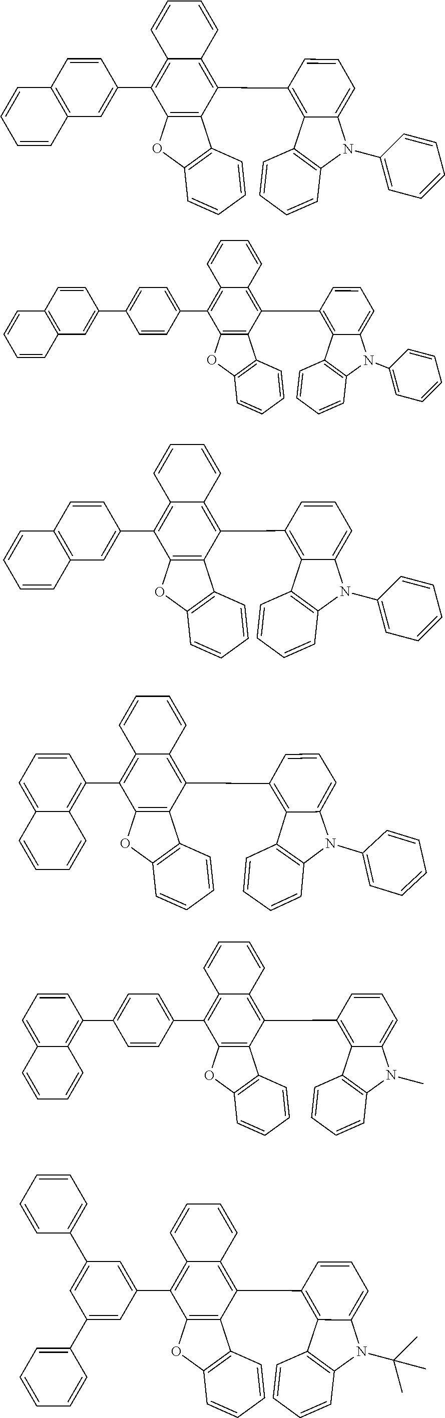

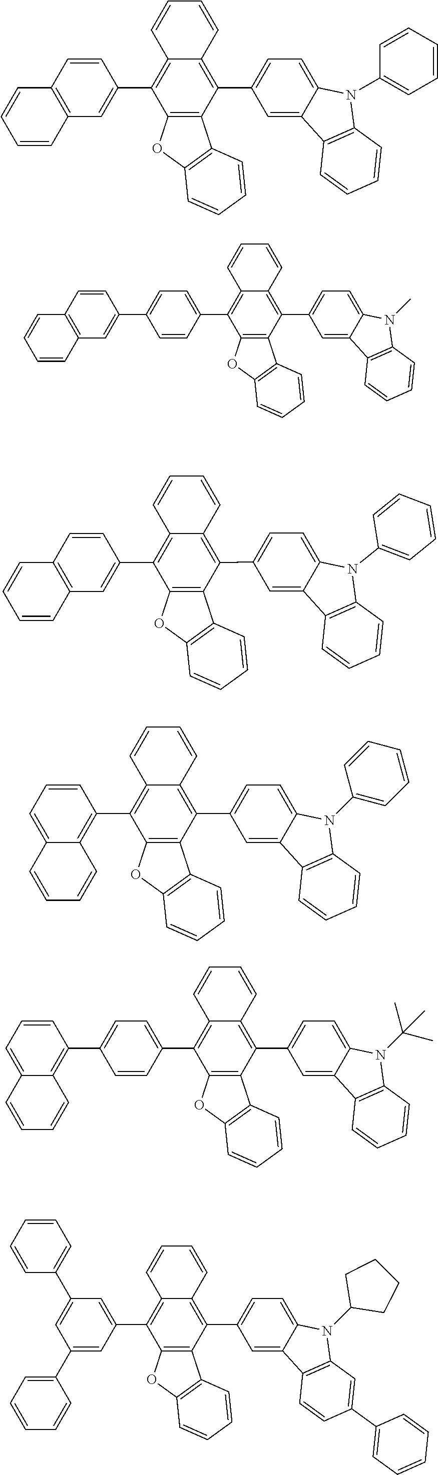

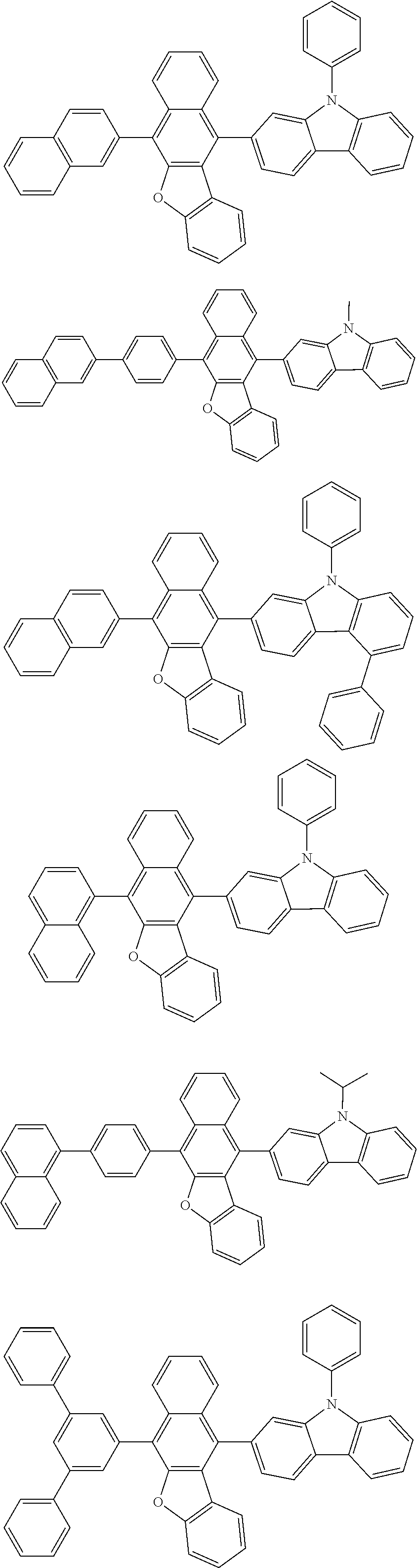

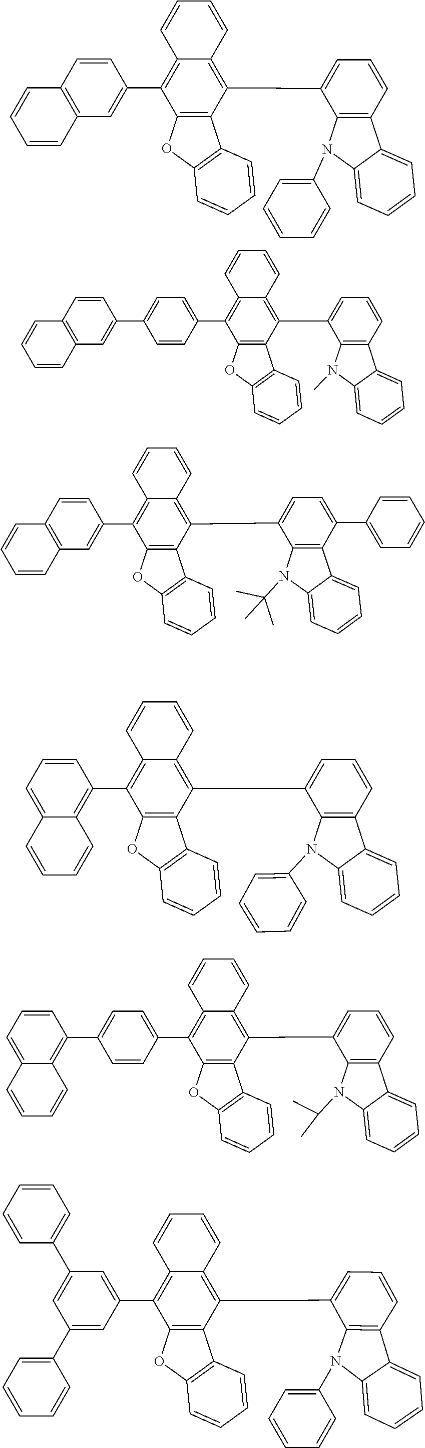

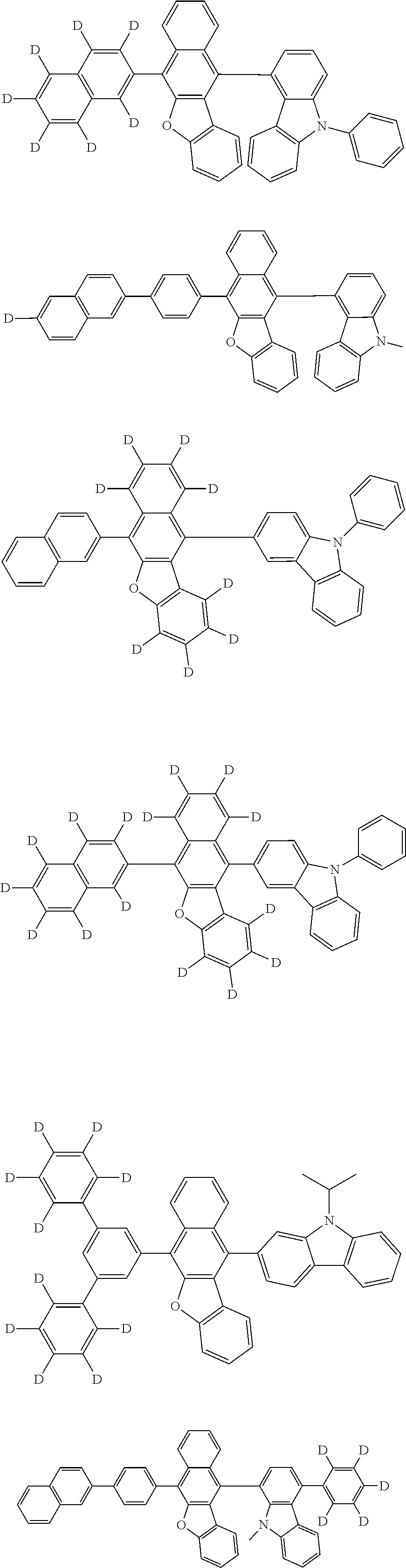

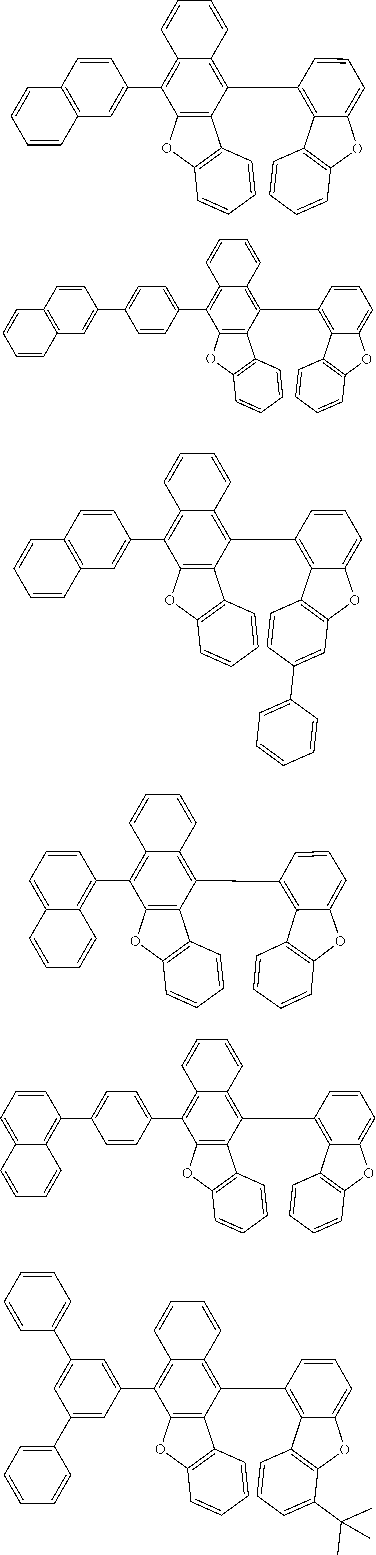

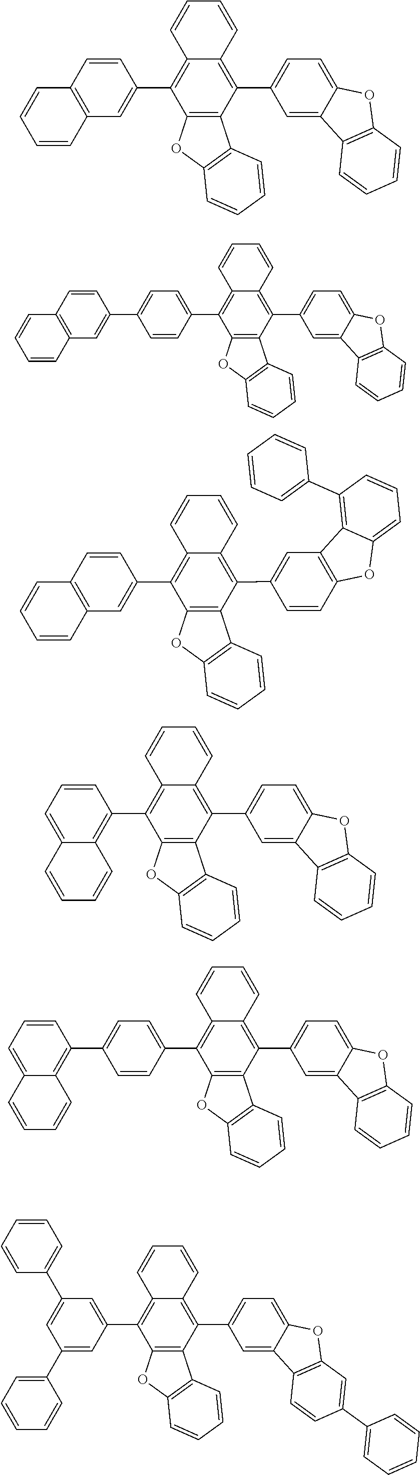

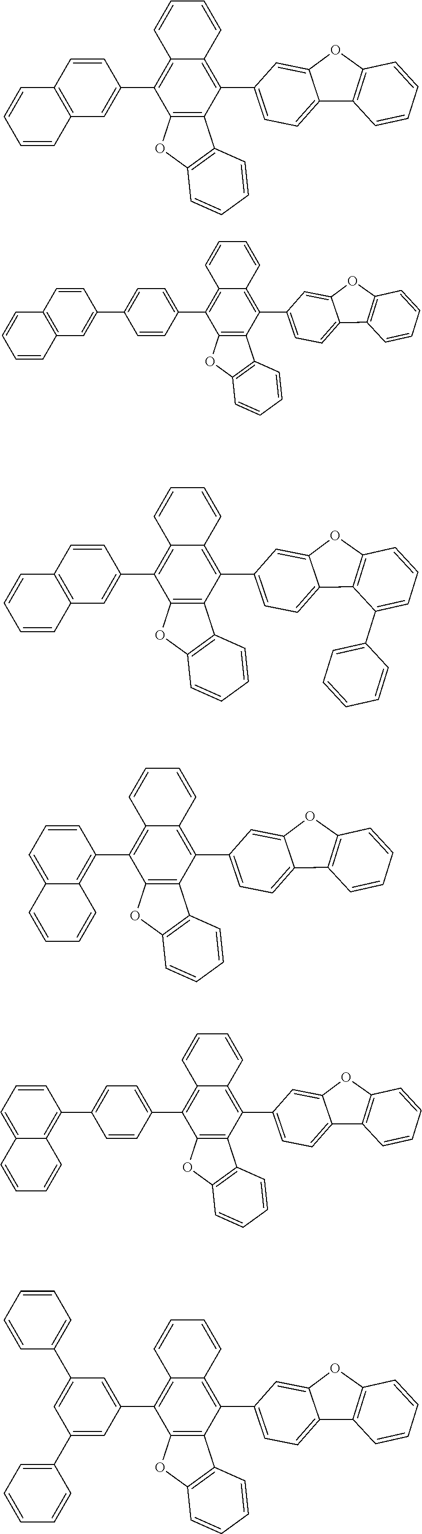

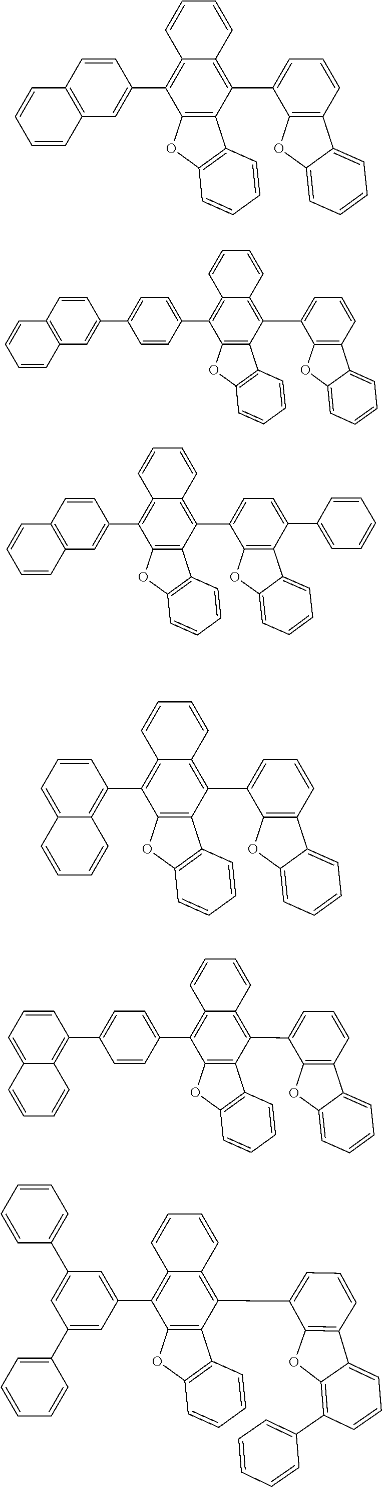

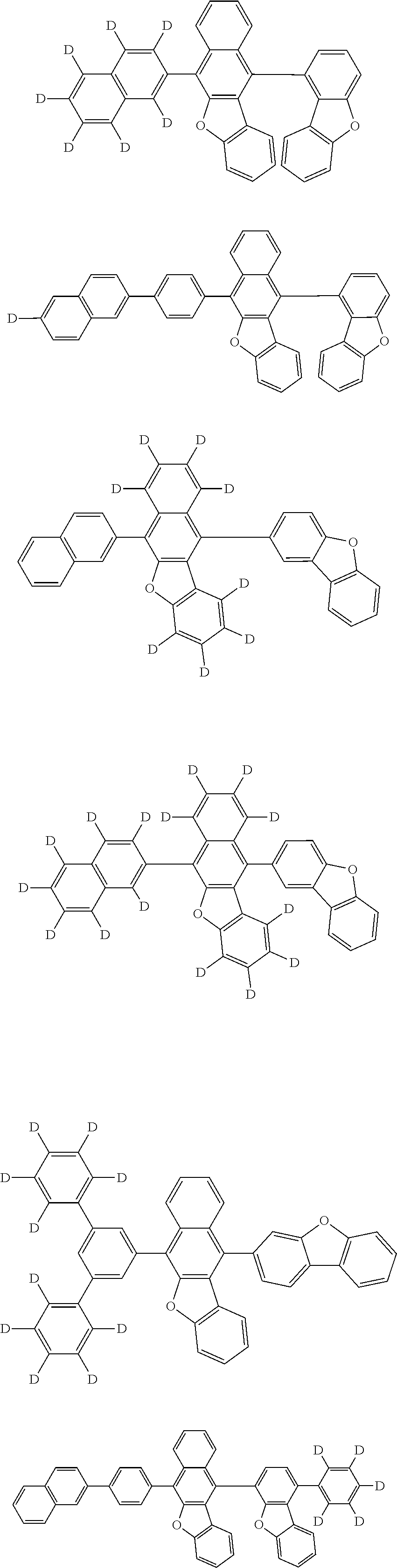

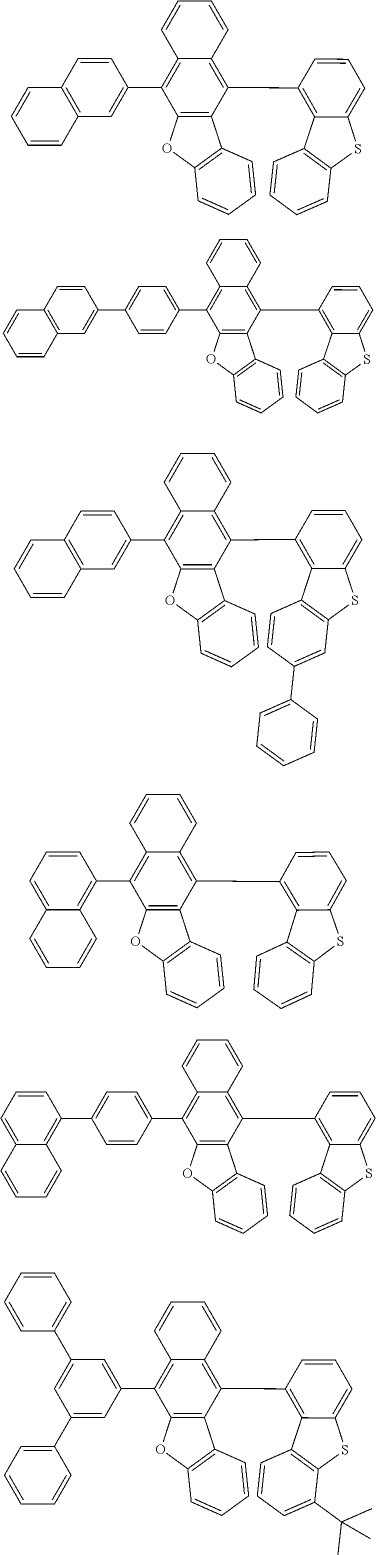

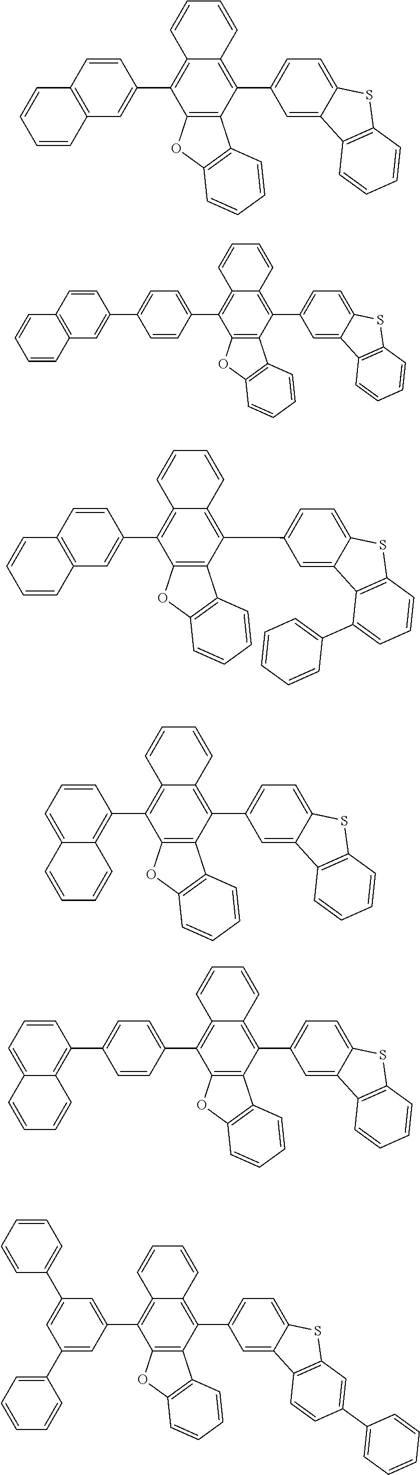

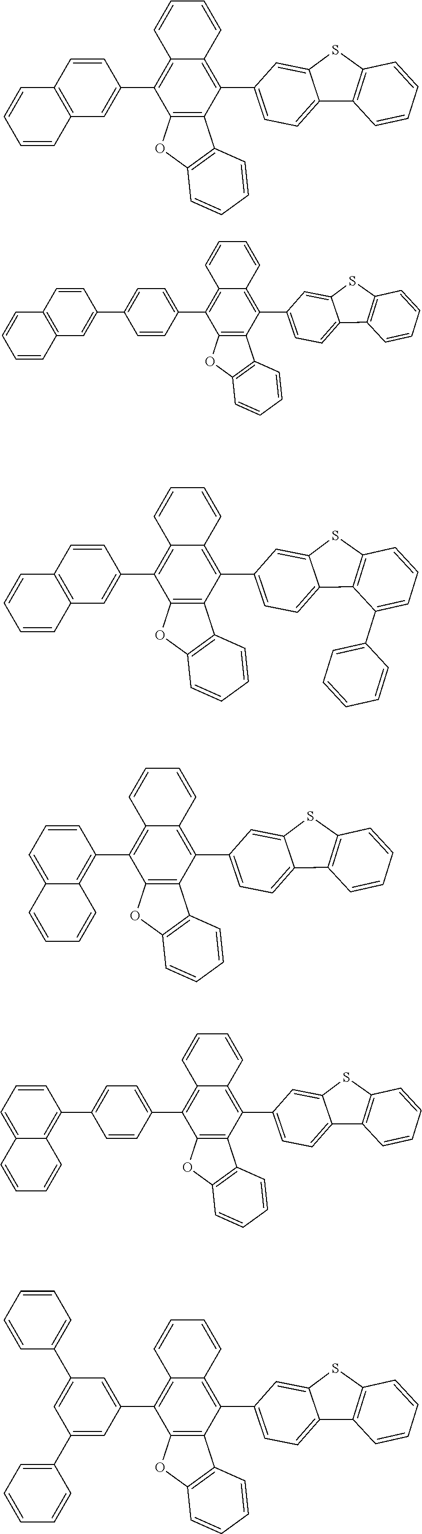

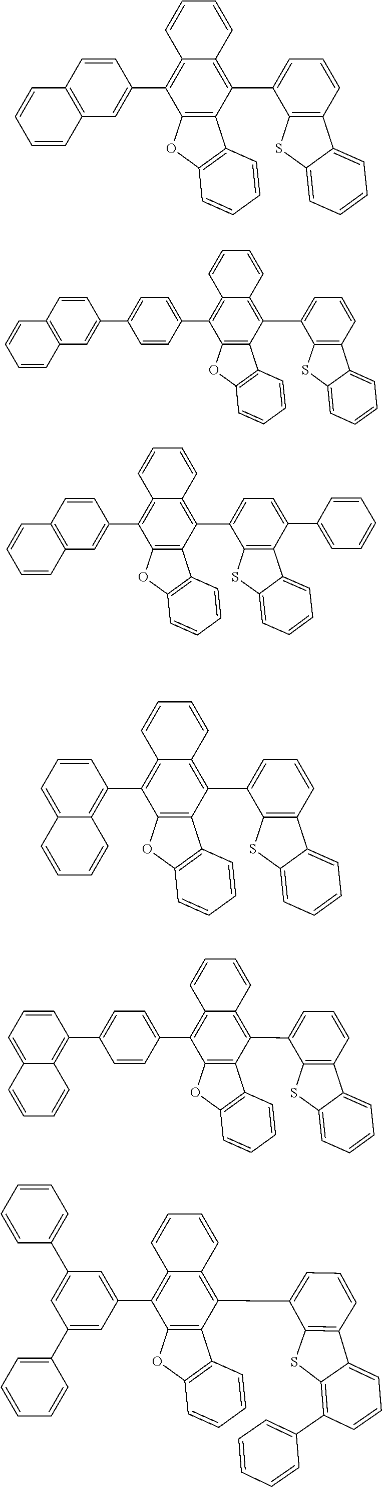

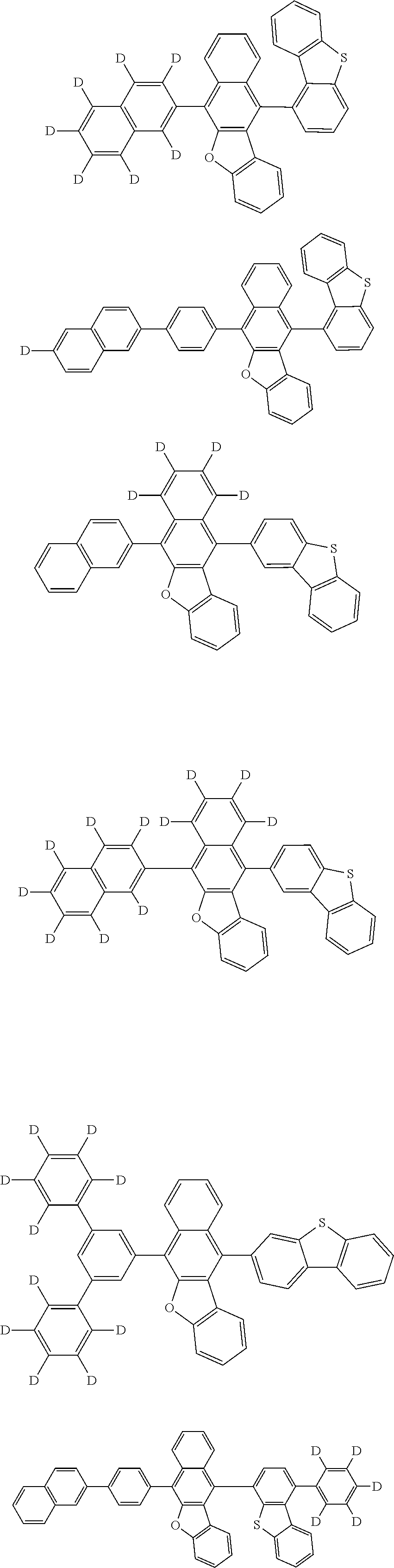

In some embodiments, the mass ratio of the first compound to the second compound is greater than or equal to 1:9, and the mass ratio of the first compound to the second compound is less than or equal to 9:1, for example, 2:8, 3:7, 4:6, 5:5, 6:4, 7:3, 8:2, 9:1, and the like.

According to embodiments of the present disclosure, by using a composition formed by a first compound having a structure represented by formula (1) and a second compound having a structure represented by formula (2), the charge balance and energy transmission in the light-emitting devices are improved, and the luminous efficiency and luminous lifetime of the light-emitting device are also improved.

The present disclosure further provides a mixture comprising at least one organic compound as described above and an organic functional material. The organic functional material being selected from at least one of a hole transport material, a hole injection material, a hole blocking material, an electron injection material, an electron transport material, a host material or a guest material.

In some embodiments, the organic functional material includes at least one third compound selected from structures represented by any one of formulae (3-1) to (3-2):

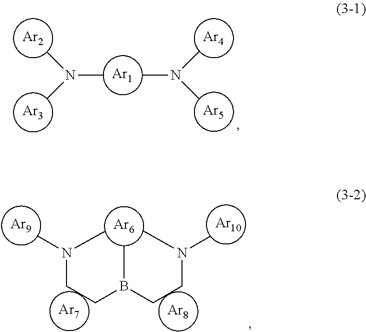

wherein each of Ar₁ to Ar₁₀ is independently selected from a substituted or unsubstituted aromatic group having 6 to 40 ring atoms, or a substituted or unsubstituted heteroaromatic group having 5 to 40 ring atoms, two adjacent ones of Ar₁ to Ar₅ form a ring or not, and two adjacent ones of Ar₆ to Ar₁₀ form a ring or not.

In some embodiments, Ar1 is independently selected from a structure represented by any one of formulae (H-1) to (H-3):

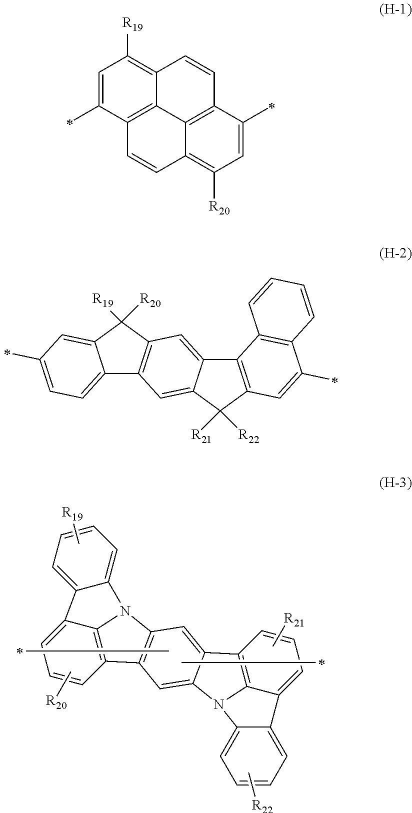

wherein R₁₉, R₂₀, R₂₁ and R₂₂ are each independently selected from —H, -D, a substituted or unsubstituted linear alkyl group having 1 to 20 carbon atoms, a substituted or unsubstituted alkoxy group having 1 to 20 carbon atoms, a substituted or unsubstituted thioalkoxy group having 1 to 20 carbon atoms, a substituted or unsubstituted branched or cyclic alkyl group having 3 to 20 carbon atoms, a substituted or unsubstituted alkoxy group having 3 to 20 carbon atoms, a substituted or unsubstituted thioalkoxy group having 3 to 20 carbon atoms, a silyl group, a substituted or unsubstituted keto group having 1 to 20 carbon atoms, a substituted or unsubstituted alkoxycarbonyl group having 2 to 20 carbon atoms, a substituted or unsubstituted aryloxycarbonyl group having 7 to 20 carbon atoms, a cyano group, a carbamoyl group, a haloformyl group, a formyl group, an isocyano group, an isocyanate group, a thiocyanate group, an isothiocyanate group, a hydroxyl group, a nitro group, an amino group, —CF₃, —Cl, —Br, —F, —I, a substituted or unsubstituted alkenyl having 2 to 20 carbon atoms, a substituted or unsubstituted aromatic group having 6 to 30 ring atoms, a substituted or unsubstituted heteroaromatic groups having 5 to 30 ring atoms, a substituted or unsubstituted aryloxy group having 6 to 30 ring atoms, a substituted or unsubstituted heteroaryloxy group having 5 to 30 ring atoms, or a combinations thereof.

In some embodiments, R19, R20, R21, R22 are each independently selected from —H, -D, a linear alkyl group having 1 to 10 carbon atoms, a branched or cyclic alkyl group having 3 to 10 carbon atoms, or a substituted or unsubstituted phenyl, wherein the substituted phenyl may be substituted by -D, a linear alkyl group having 1 to 10 carbon atoms, or a branched or cyclic alkyl group having 3 to 10 carbon atoms.

In some embodiments, R19, R20, R21, R22 are each independently selected from —H, -D, an unsubstituted linear alkyl group having 1 to 5 carbon atoms, an unsubstituted branched or cyclic alkyl group having 3 to 5 carbon atoms, or a substituted or unsubstituted phenyl, wherein the unsubstituted phenyl may be substituted by -D, a linear alkyl group having 1 to 5 carbon atoms, or a branched or cyclic alkyl having 3 to 5 carbon atoms.

In some embodiments, R19, R20, R21, R22 are each independently selected from —H, -D, methyl, propyl, tert-butyl, phenyl,

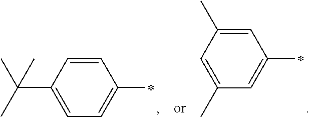

In some embodiments, each of Ar₂ to Ar₁₀ is independently selected from the following structures:

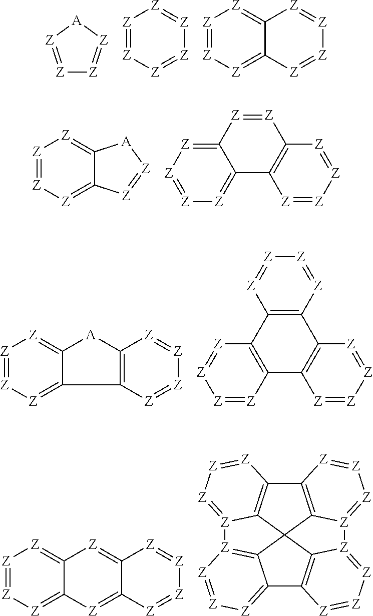

wherein Z is independently selected from CR₂₃ or N; in a case that Z is a linkage site, Z is C; and in a case that A is linkage site, A is N.
A is independently selected from NR₂₄, PR₂₄, CR₂₄R₂₅, SiR₂₄R₂₅, O, S, S(═O)₂ or S(═O);
R₂₃, R₂₄ and R₂₅ are each independently selected from —H, -D, a substituted or unsubstituted linear alkyl group having 1 to 20 carbon atoms, a substituted or unsubstituted alkoxy group having 1 to 20 carbon atoms, a substituted or unsubstituted thioalkoxy group having 1 to 20 carbon atoms, a substituted or unsubstituted branched or cyclic alkyl group having 3 to 20 carbon atoms, a substituted or unsubstituted alkoxy group having 3 to 20 carbon atoms, a substituted or unsubstituted thioalkoxy group having 3 to 20 carbon atoms, a silyl group, a substituted or unsubstituted keto group having 1 to 20 carbon atoms, a substituted or unsubstituted alkoxycarbonyl group having 2 to 20 carbon atoms, a substituted or unsubstituted aryloxycarbonyl group having 7 to 20 carbon atoms, a cyano group, a carbamoyl group, a haloformyl group, a formyl group, an isocyano group, an isocyanate group, a thiocyanate group, an isothiocyanate group, a hydroxyl group, a nitro group, an amino group, —CF₃, —Cl, —Br, —F, —I, a substituted or unsubstituted alkenyl having 2 to 20 carbon atoms, a substituted or unsubstituted aromatic group having 6 to 30 ring atoms, a substituted or unsubstituted heteroaromatic groups having 5 to 30 ring atoms, a substituted or unsubstituted aryloxy group having 6 to 30 ring atoms, a substituted or unsubstituted heteroaryloxy group having 5 to 30 ring atoms, or a combinations thereof.

In some embodiments, R23, R24, R25 are each independently selected from —H, -D, cyano group, an unsubstituted linear alkyl group having 1 to 5 carbon atoms, an unsubstituted branched or cyclic alkyl group having 3 to 5 carbon atoms, or a substituted or unsubstituted phenyl, wherein the substituted phenyl may be substituted by -D, a linear alkyl group having 1 to 5 carbon atoms, or a branched or cyclic alkyl group having 3 to 5 carbon atoms.

In some embodiments, R23, R24, R25 are each independently selected from —H, -D, cyano group, methyl, propyl, tert-butyl, phenyl, or a combination thereof.

In some embodiments, the third compound is selected from:

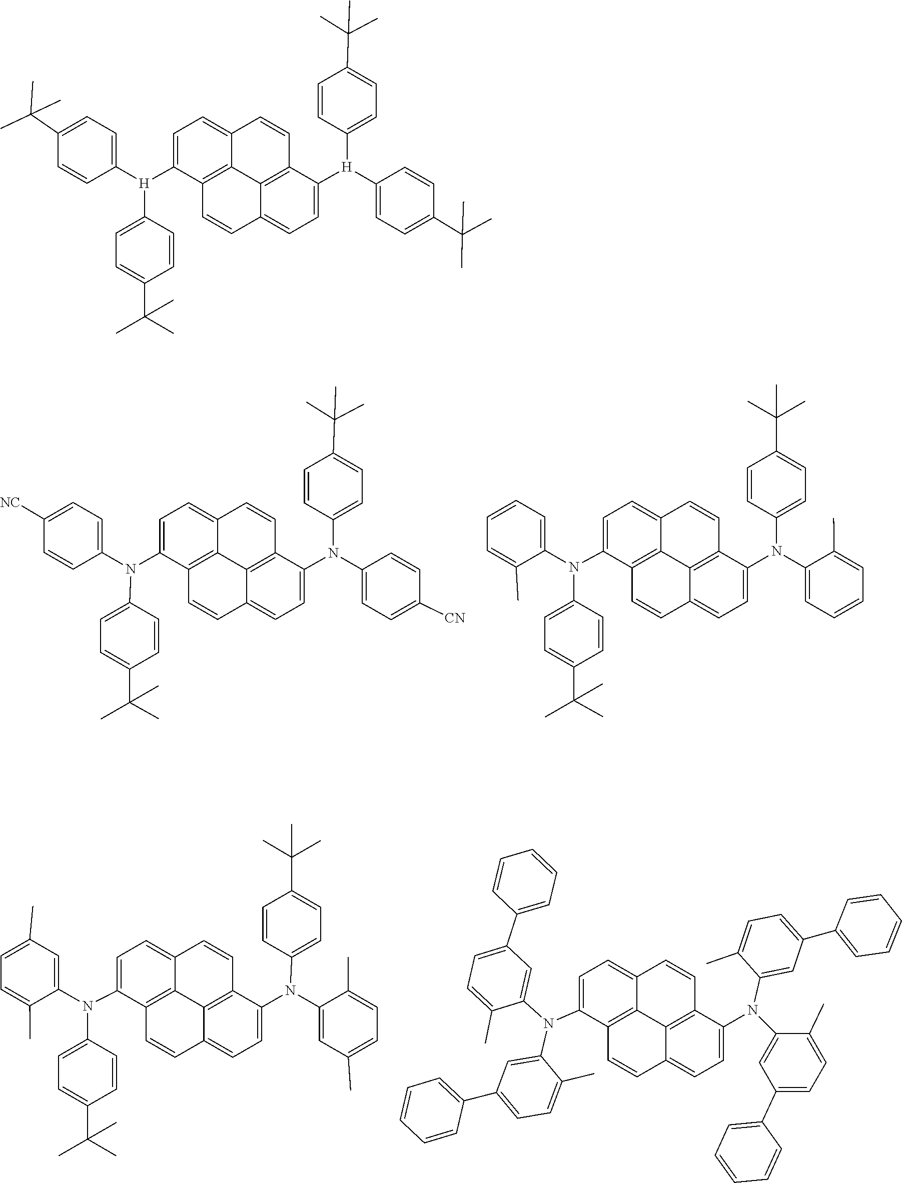

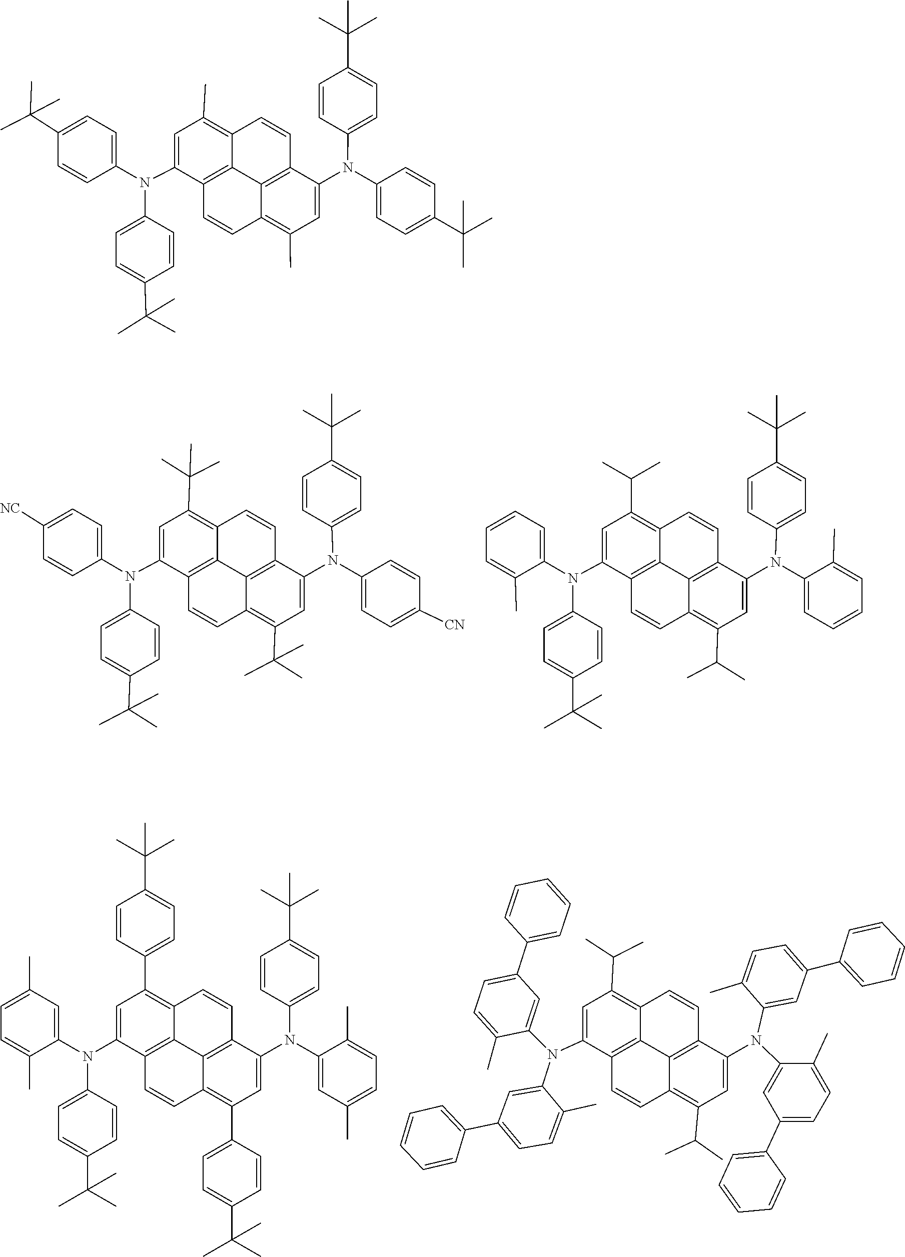

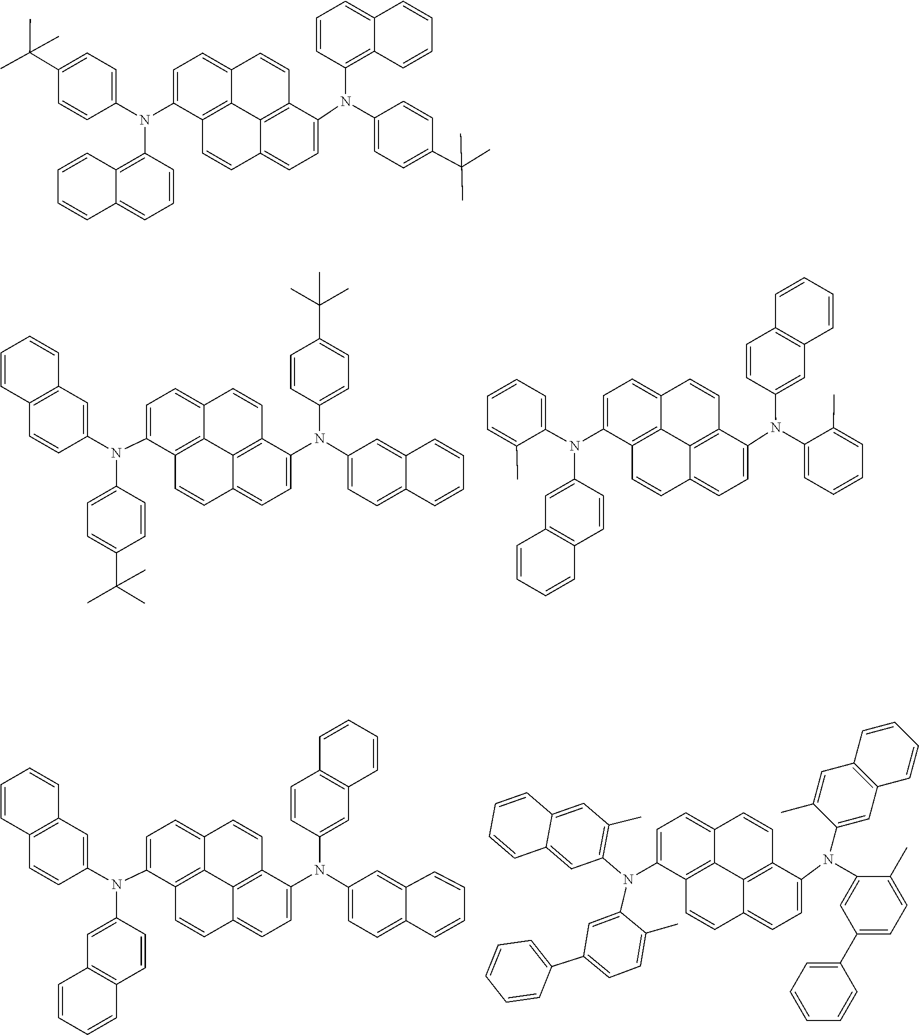

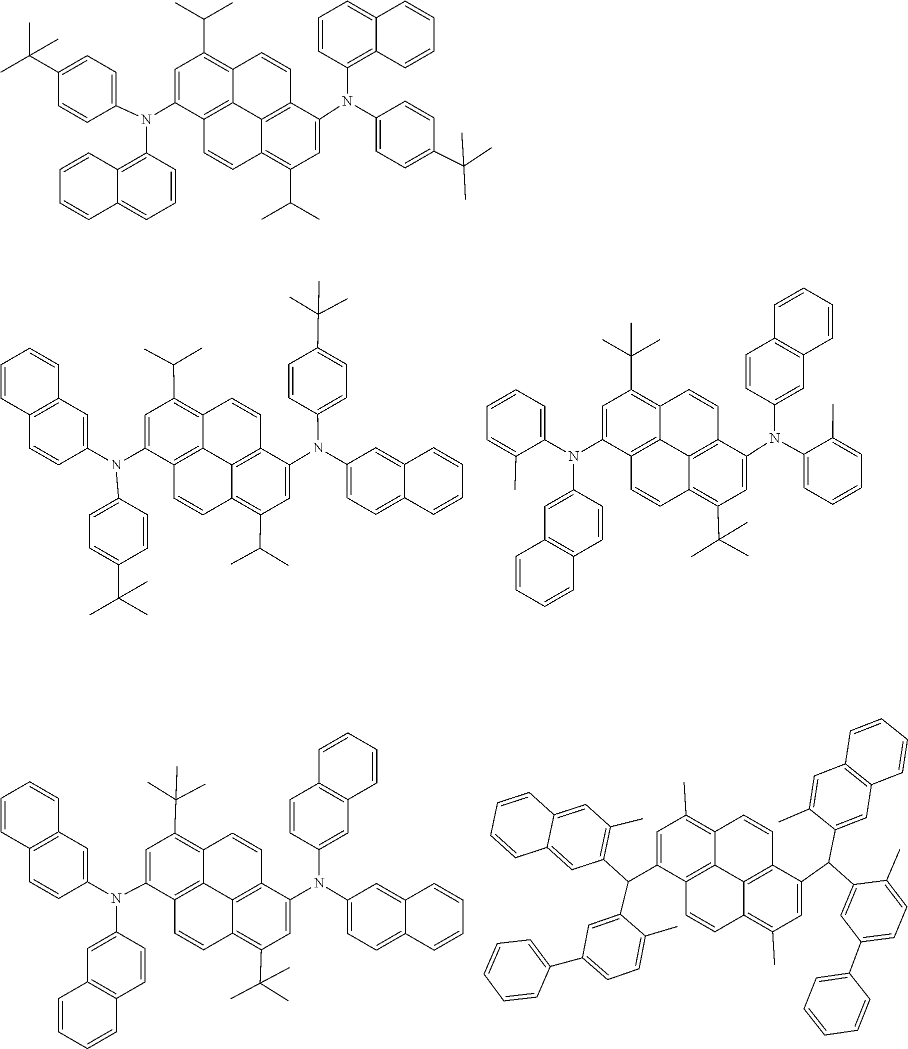

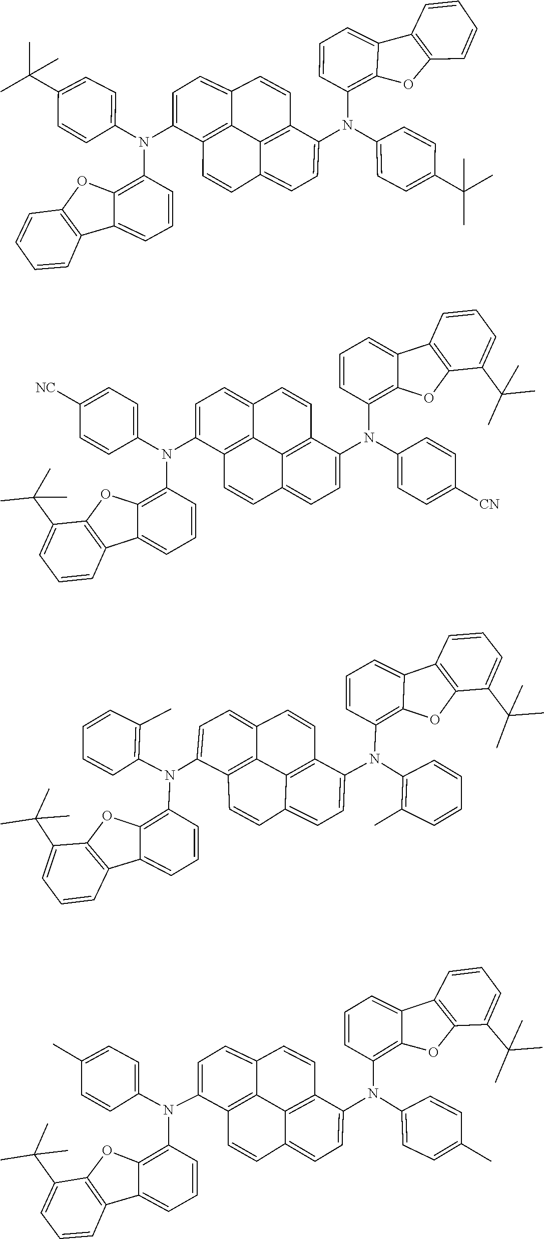

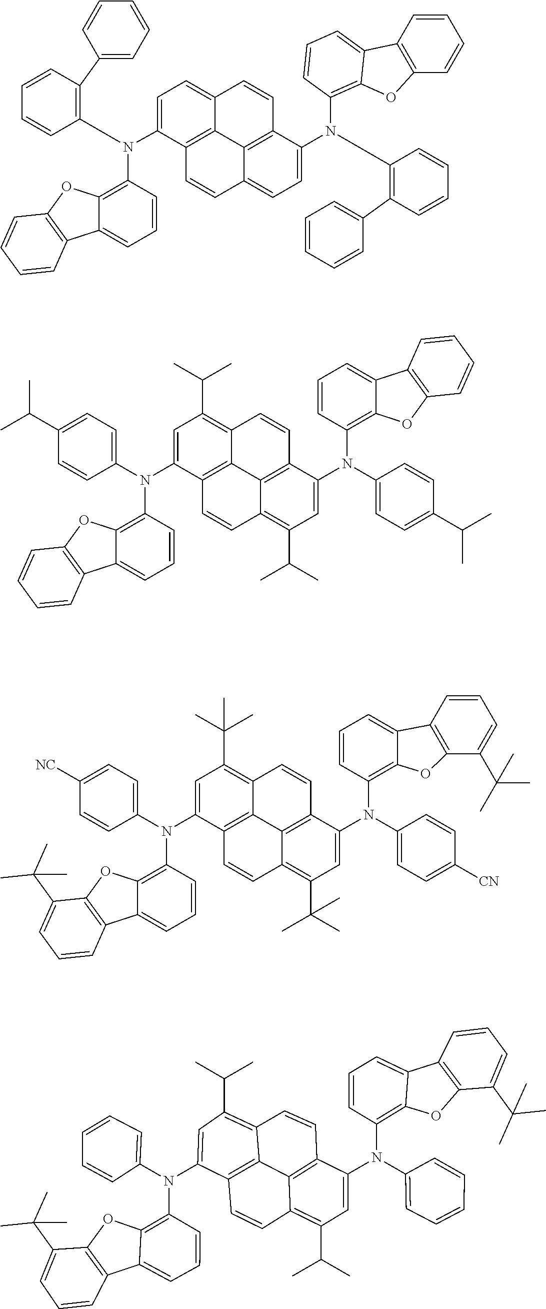

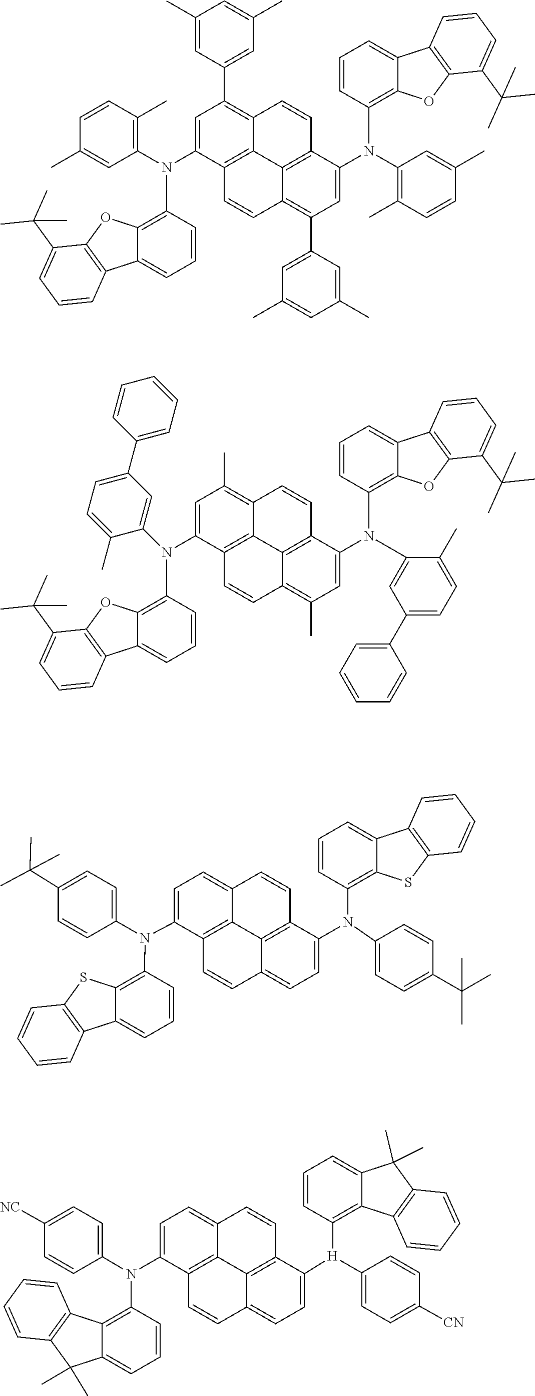

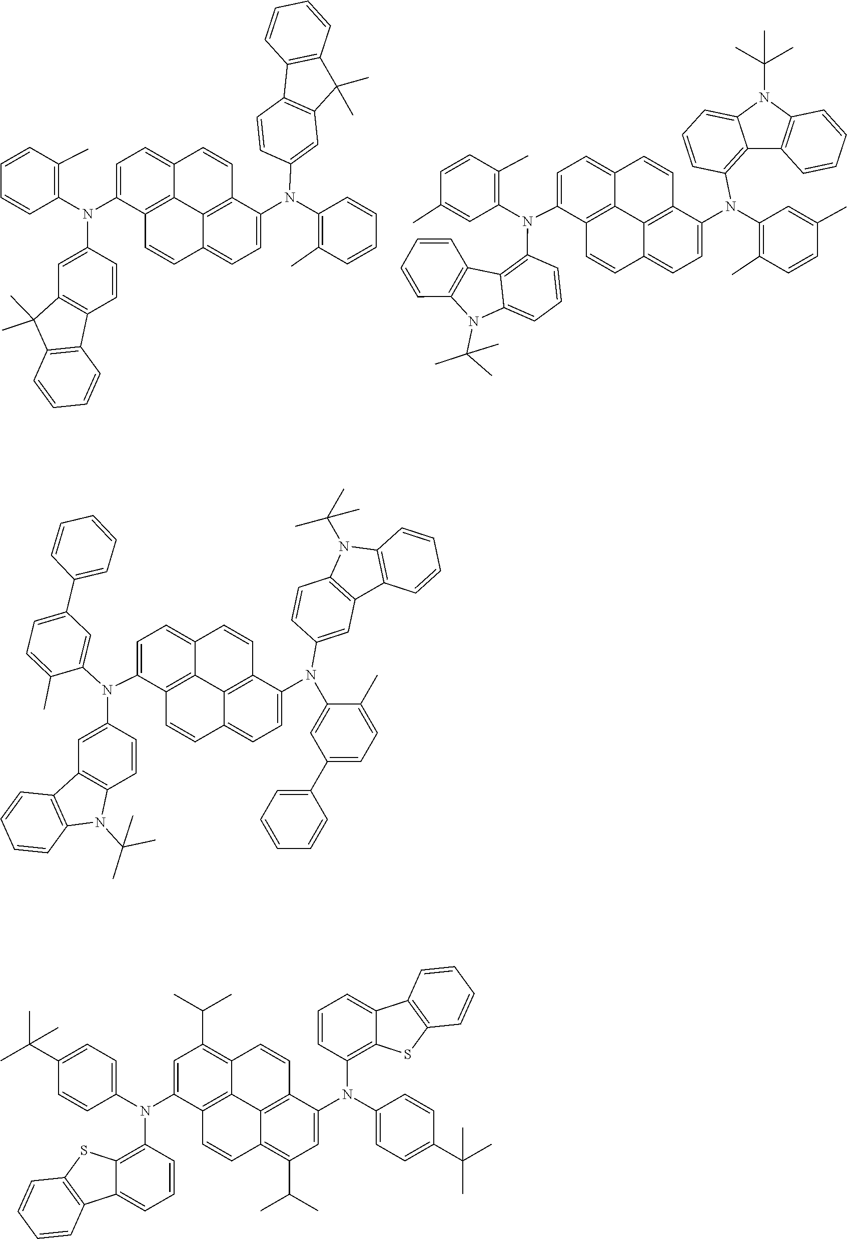

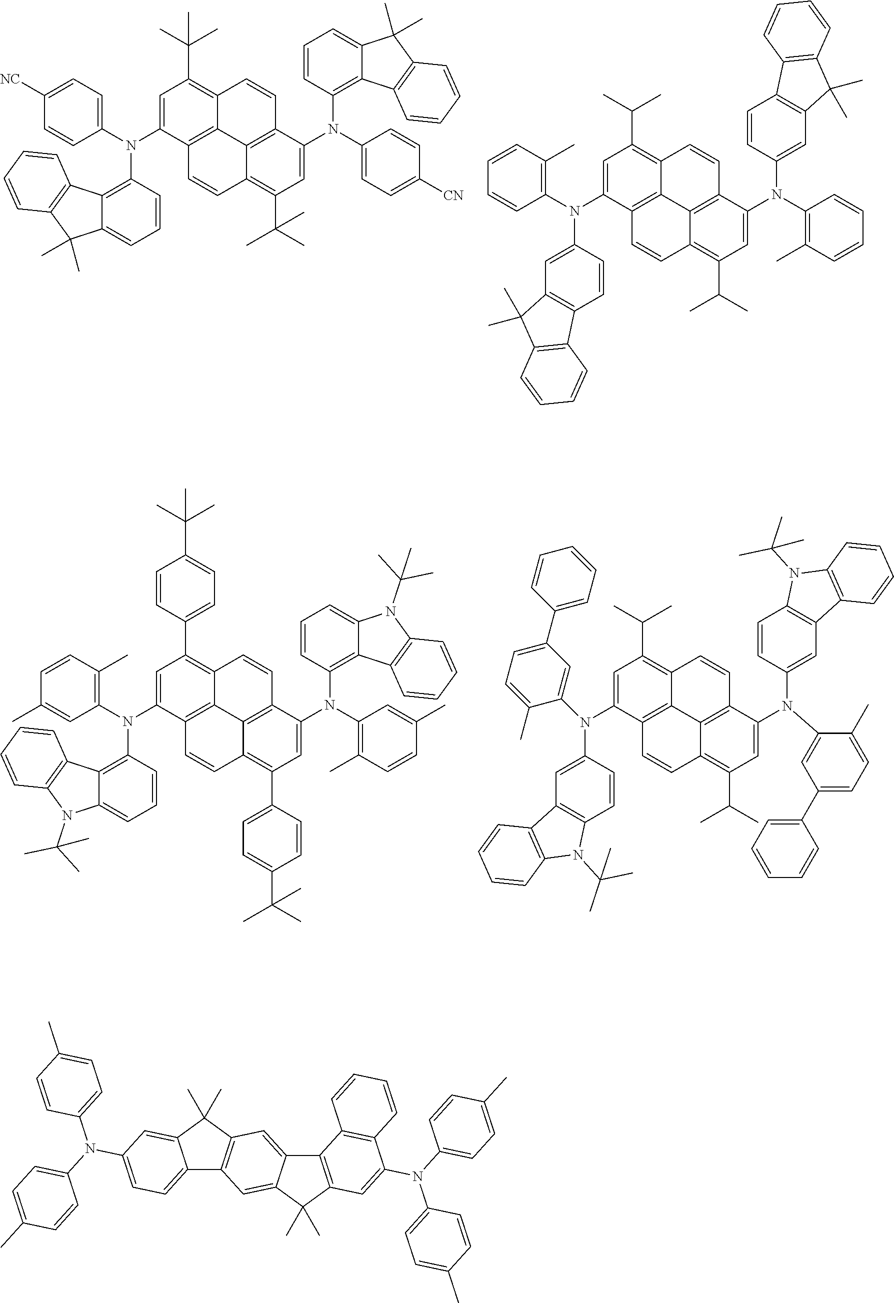

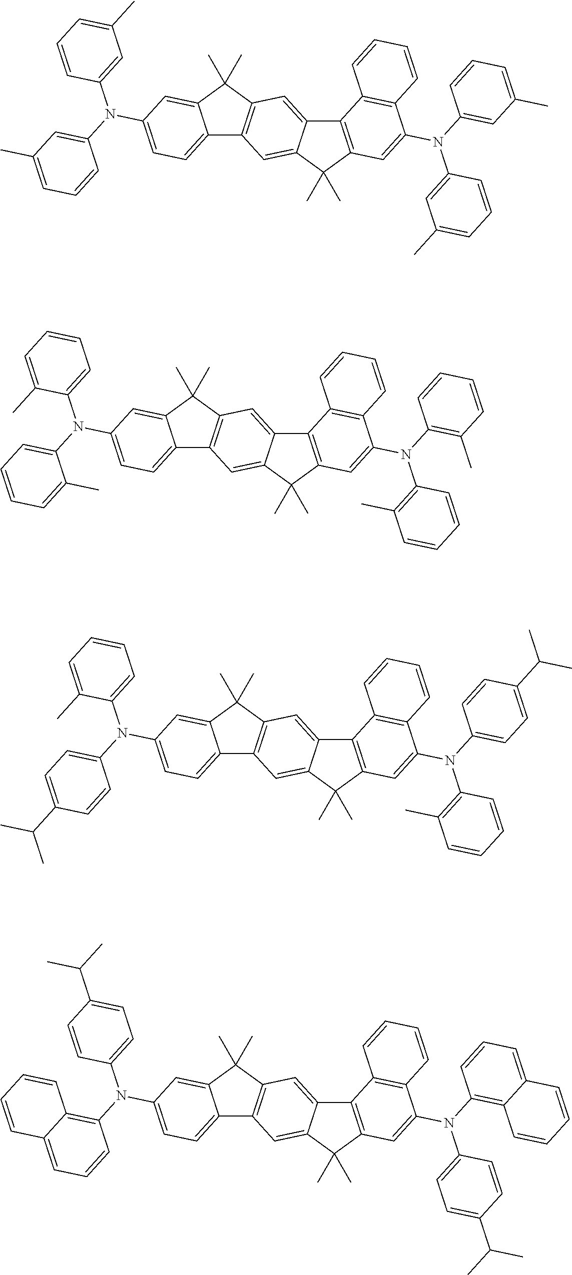

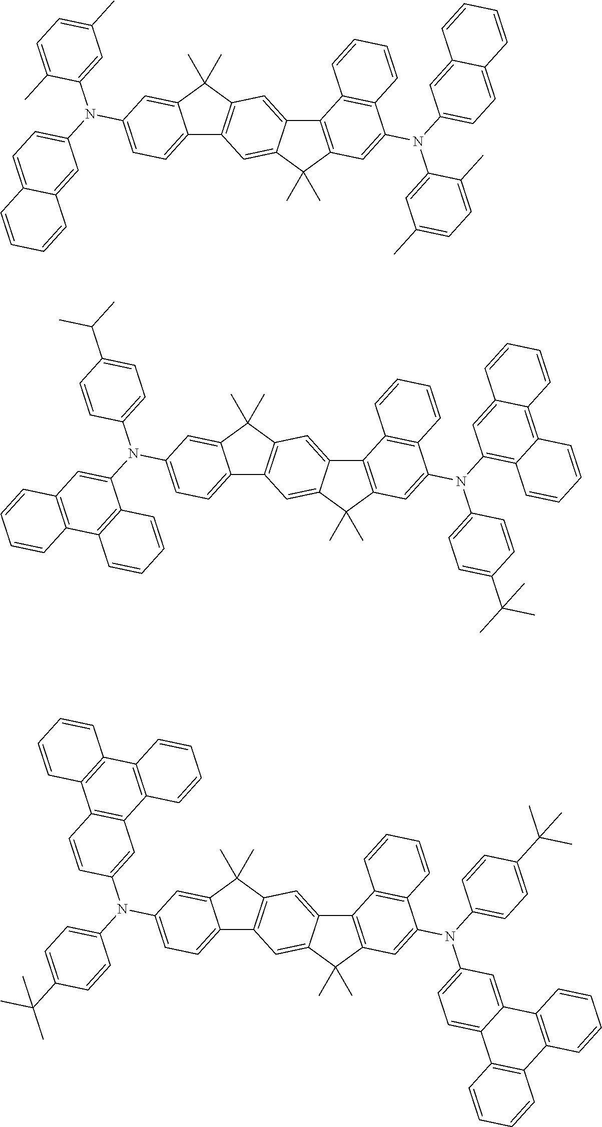 [SMILES: Cc1ccc(C)c(N(c2ccc3c(c2)C(C)(C)c2cc4c(cc2-3)C(C)(C)c2cc(N(c3ccc5ccccc5c3)c3cc(C)ccc3C)c3ccccc3c2-4)c2ccc3ccccc3c2)c1 ; CC(C)c1ccc(N(c2ccc3c(c2)C(C)(C)c2cc4c(cc2-3)C(C)(C)c2cc(N(c3ccc(C(C)(C)C)cc3)c3cc5ccccc5c5ccccc35)c3ccccc3c2-4)c2cc3ccccc3c3ccccc23)cc1 ; CC(C)(C)c1ccc(N(c2ccc3c(c2)C(C)(C)c2cc4c(cc2-3)C(C)(C)c2cc(N(c3ccc(C(C)(C)C)cc3)c3ccc5c6ccccc6c6ccccc6c5c3)c3ccccc3c2-4)c2ccc3c4ccccc4c4ccccc4c3c2)cc1]

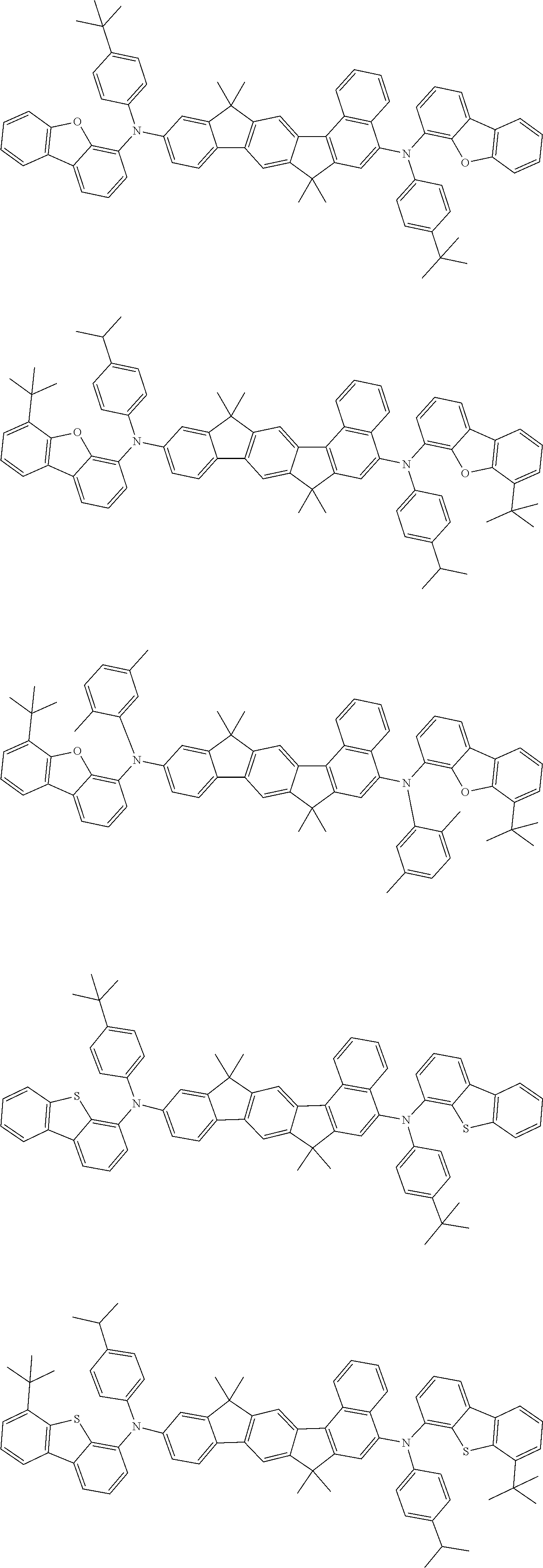

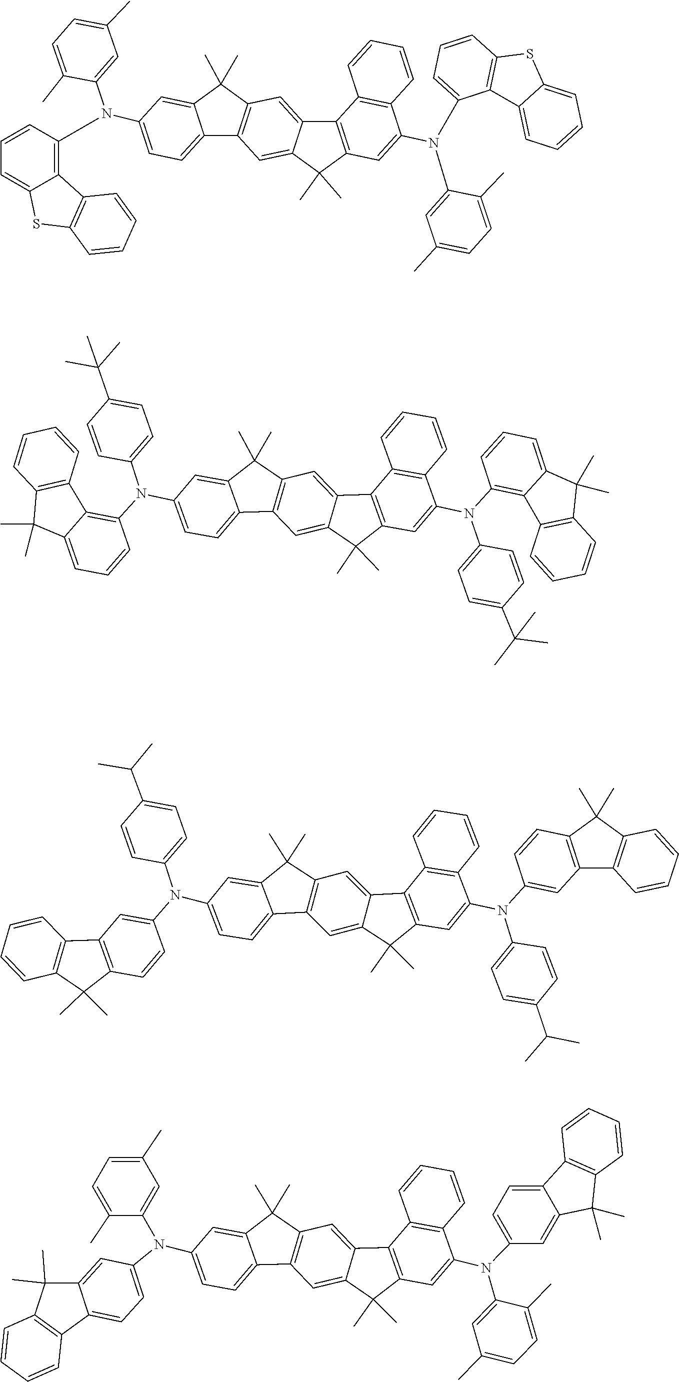

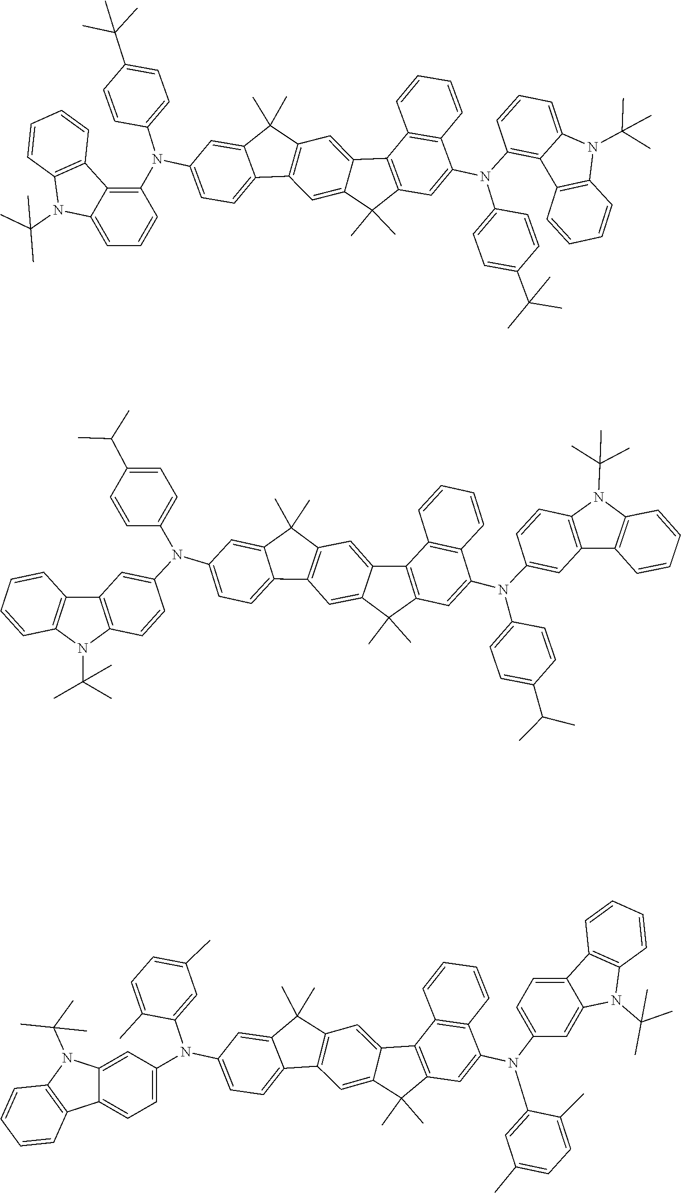 [SMILES: CC(C)(C)c1ccc(N(c2ccc3c(c2)C(C)(C)c2cc4c(cc2-3)C(C)(C)c2cc(N(c3ccc(C(C)(C)C)cc3)c3cccc5c3c3ccccc3n5C(C)(C)C)c3ccccc3c2-4)c2cccc3c2c2ccccc2n3C(C)(C)C)cc1 ; CC(C)c1ccc(N(c2ccc3c(c2)C(C)(C)c2cc4c(cc2-3)C(C)(C)c2cc(N(c3ccc(C(C)C)cc3)c3ccc5c(c3)c3ccccc3n5C(C)(C)C)c3ccccc3c2-4)c2ccc3c(c2)c2ccccc2n3C(C)(C)C)cc1 ; Cc1ccc(C)c(N(c2ccc3c(c2)C(C)(C)c2cc4c(cc2-3)C(C)(C)c2cc(N(c3ccc5c6ccccc6n(C(C)(C)C)c5c3)c3cc(C)ccc3C)c3ccccc3c2-4)c2ccc3c4ccccc4n(C(C)(C)C)c3c2)c1]

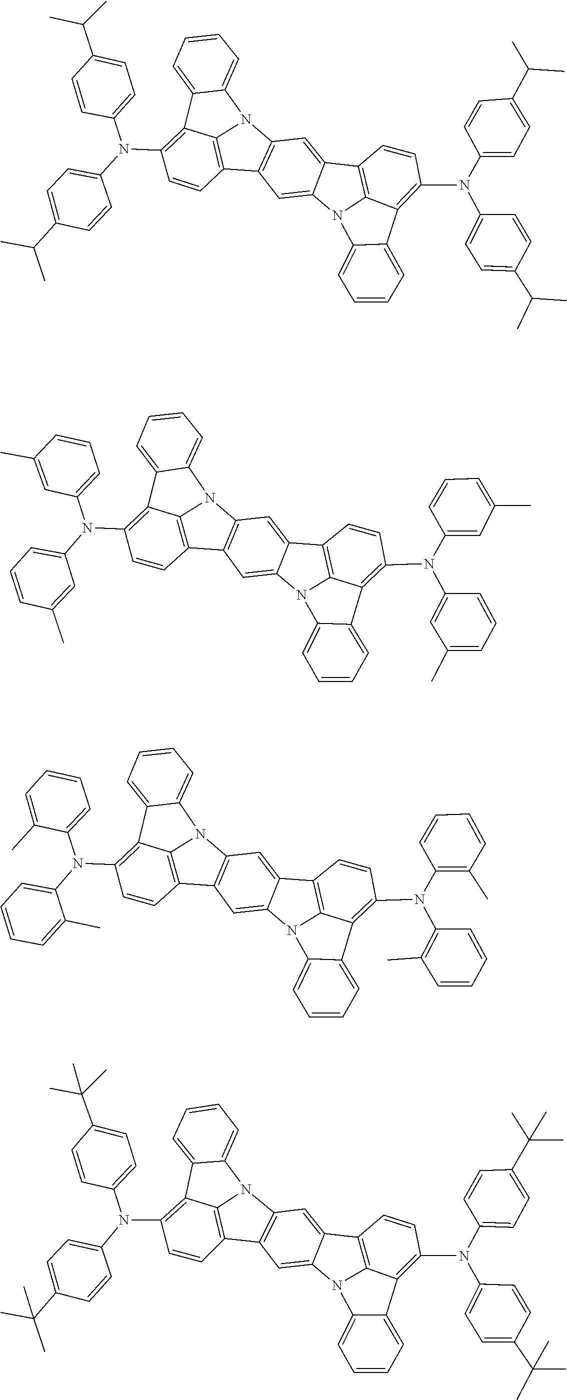

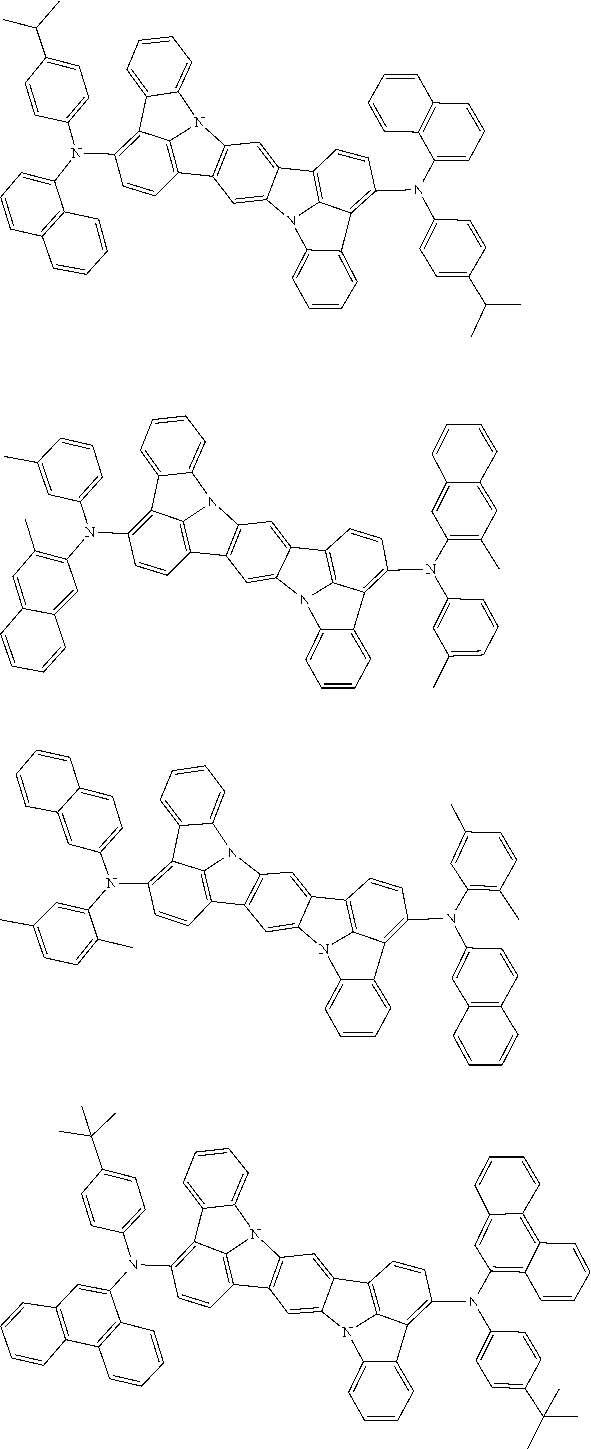

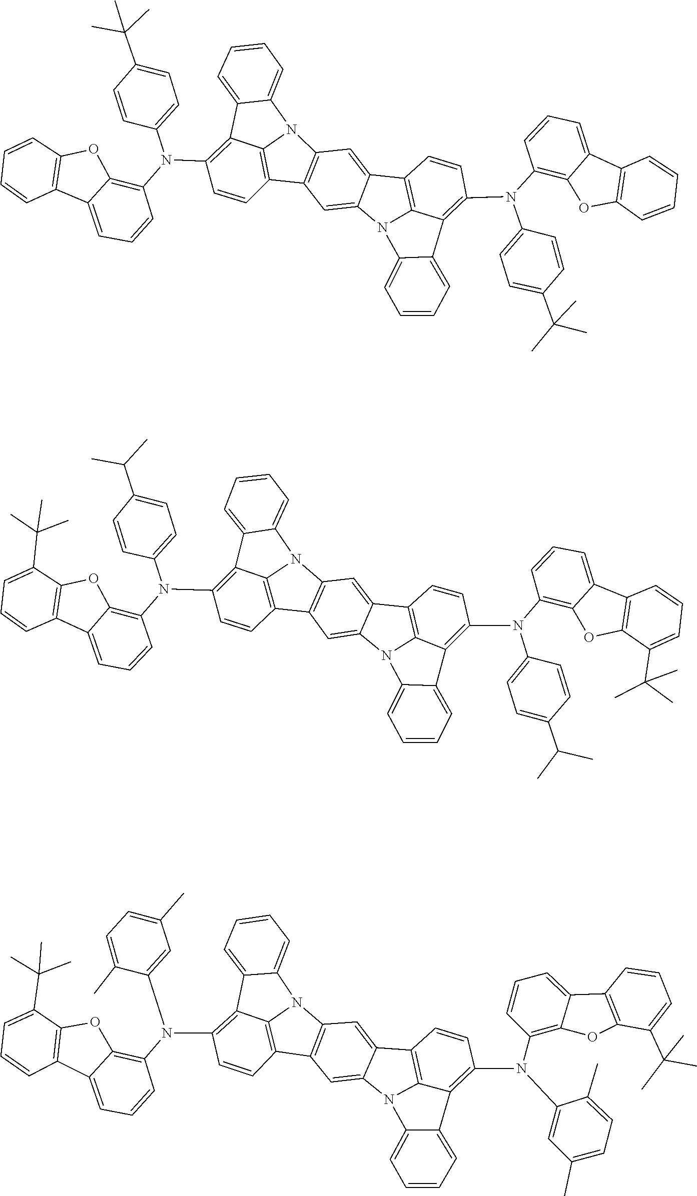 [SMILES: CC(C)(C)c1ccc(N(c2cccc3c2oc2ccccc23)c2ccc3c4cc5c(cc4n4c6ccccc6c2c34)c2ccc(N(c3ccc(C(C)(C)C)cc3)c3cccc4c3oc3ccccc34)c3c4ccccc4n5c23)cc1 ; CC(C)c1ccc(N(c2cccc3c2oc2c(C(C)(C)C)cccc23)c2ccc3c4cc5c(cc4n4c6ccccc6c2c34)c2ccc(N(c3ccc(C(C)C)cc3)c3cccc4c3oc3c(C(C)(C)C)cccc34)c3c4ccccc4n5c23)cc1 ; Cc1ccc(C)c(N(c2cccc3c2oc2c(C(C)(C)C)cccc23)c2ccc3c4cc5c(cc4n4c6ccccc6c2c34)c2ccc(N(c3cc(C)ccc3C)c3cccc4c3oc3c(C(C)(C)C)cccc34)c3c4ccccc4n5c23)c1]

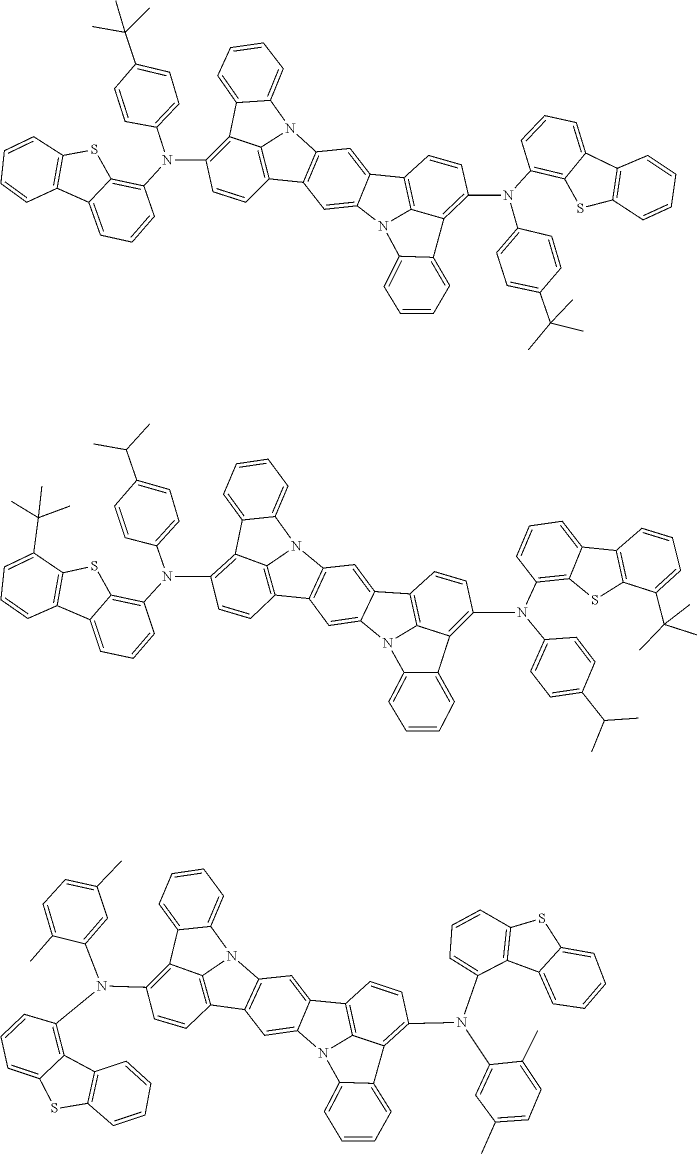 [SMILES: CC(C)(C)c1ccc(N(c2cccc3c2sc2ccccc23)c2ccc3c4cc5c(cc4n4c6ccccc6c2c34)c2ccc(N(c3ccc(C(C)(C)C)cc3)c3cccc4c3sc3ccccc34)c3c4ccccc4n5c23)cc1 ; CC(C)c1ccc(N(c2cccc3c2sc2c(C(C)(C)C)cccc23)c2ccc3c4cc5c(cc4n4c6ccccc6c2c34)c2ccc(N(c3ccc(C(C)C)cc3)c3cccc4c3sc3c(C(C)(C)C)cccc34)c3c4ccccc4n5c23)cc1 ; Cc1ccc(C)c(N(c2cccc3sc4ccccc4c23)c2ccc3c4cc5c(cc4n4c6ccccc6c2c34)c2ccc(N(c3cc(C)ccc3C)c3cccc4sc6ccccc6c34)c3c4ccccc4n5c23)c1]

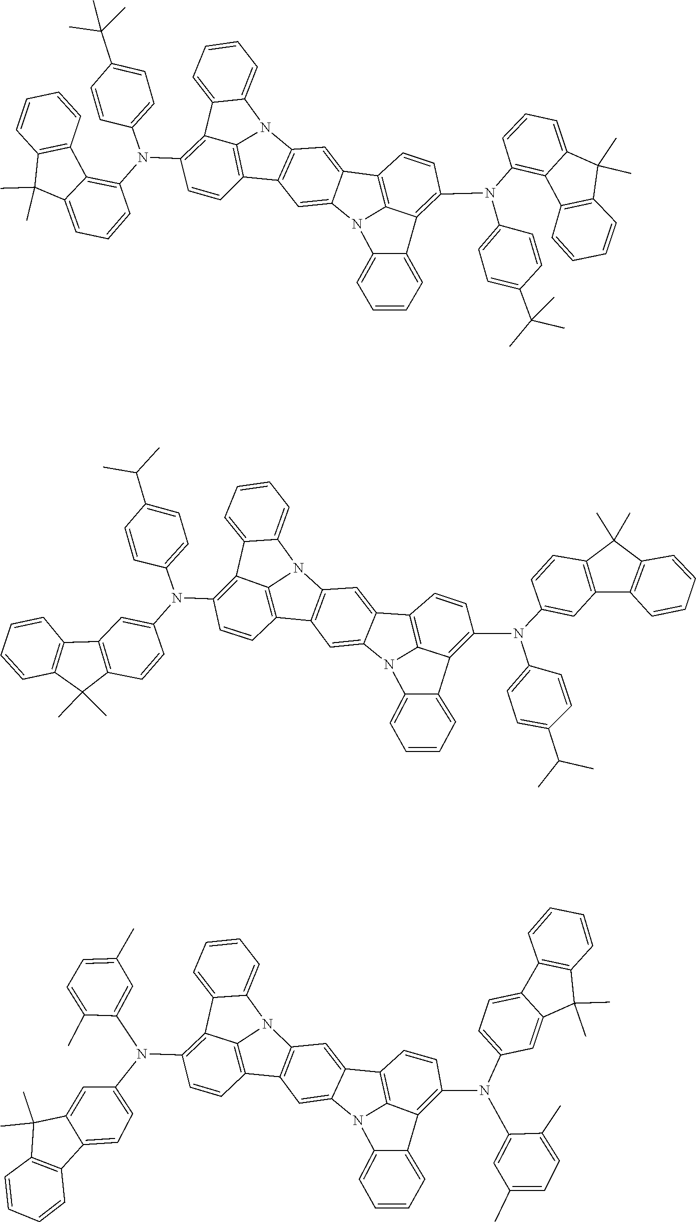

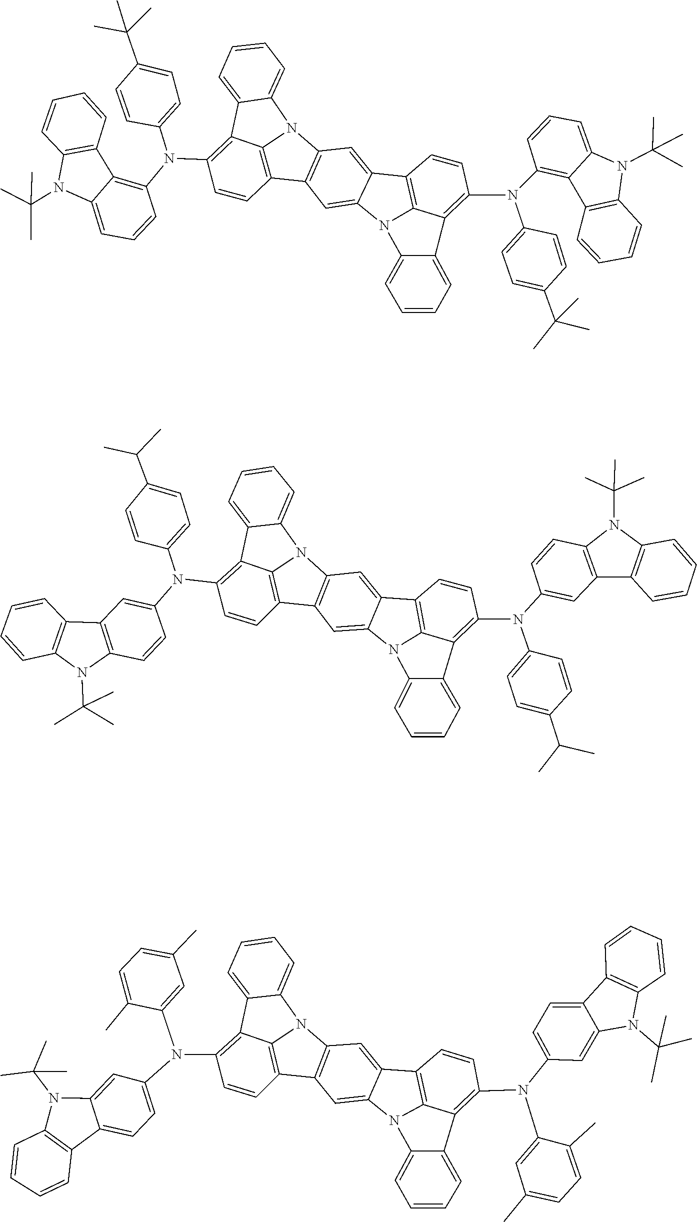

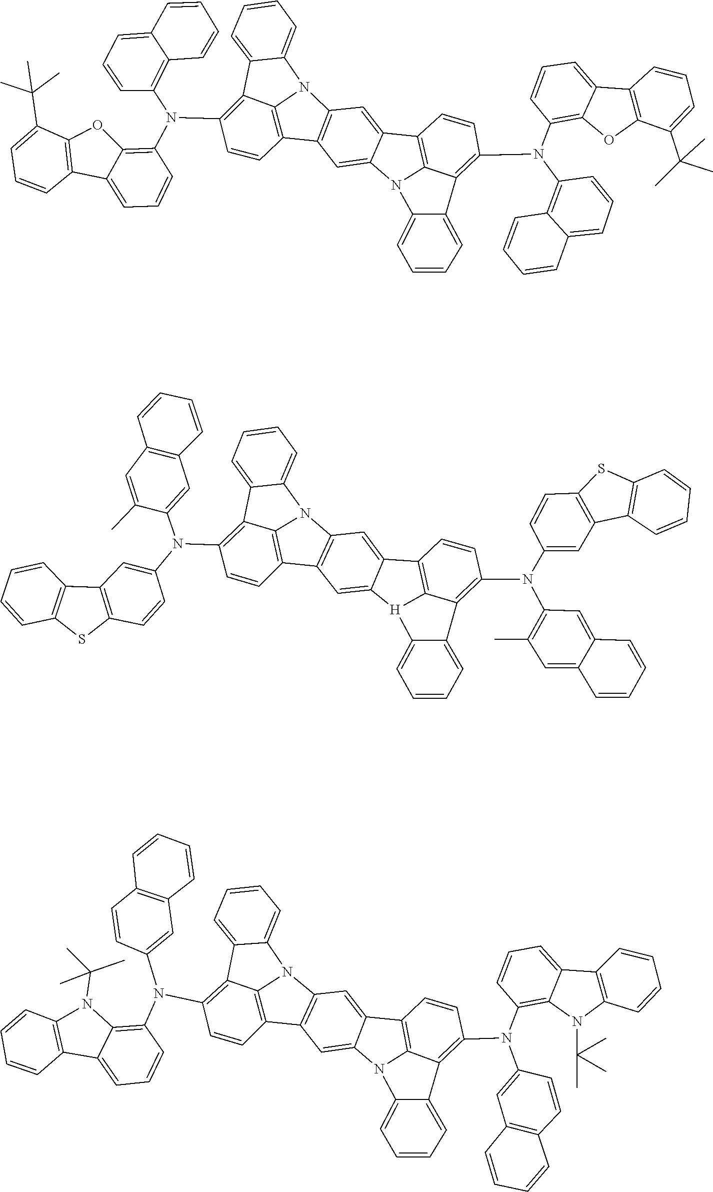

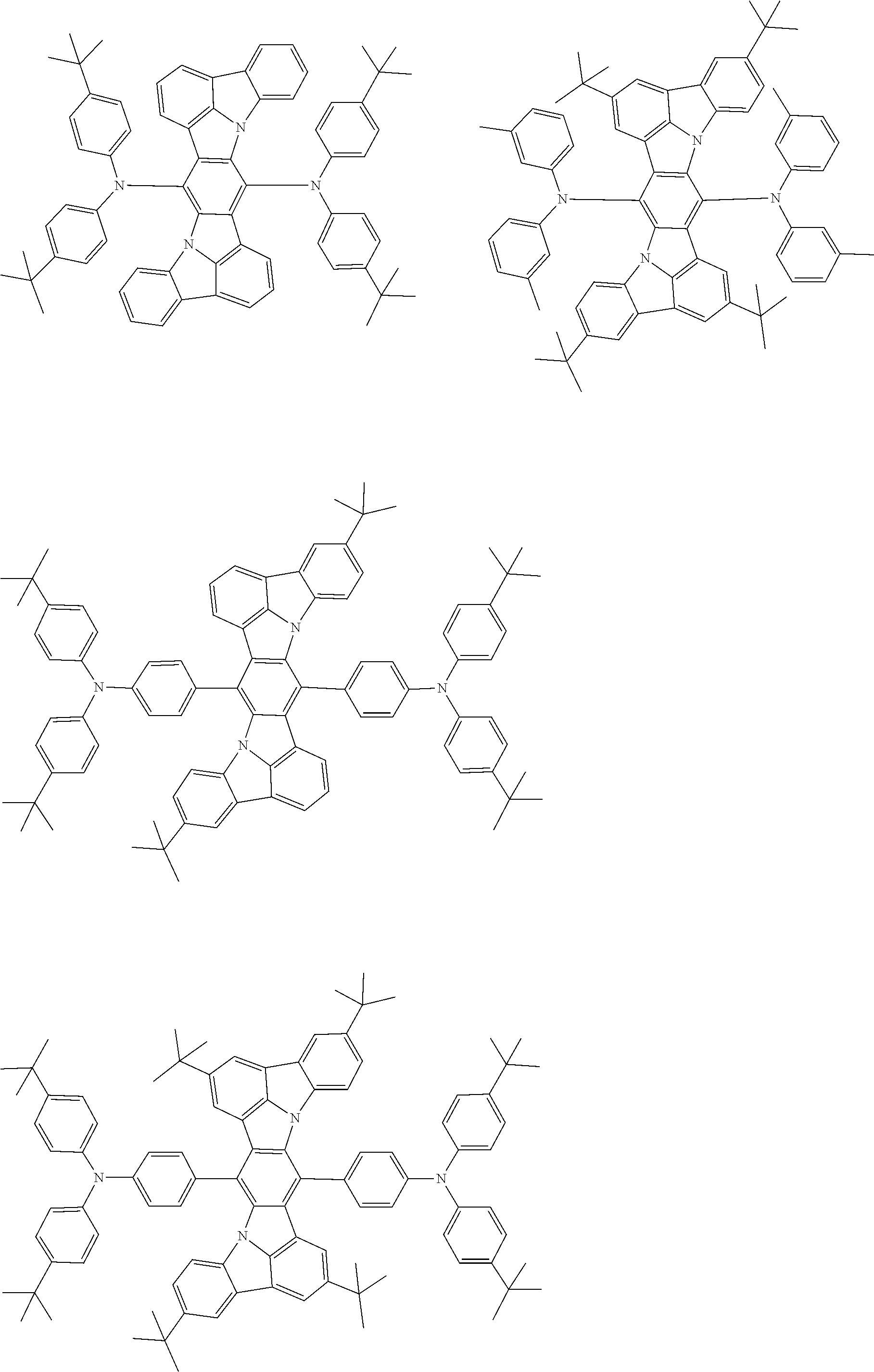

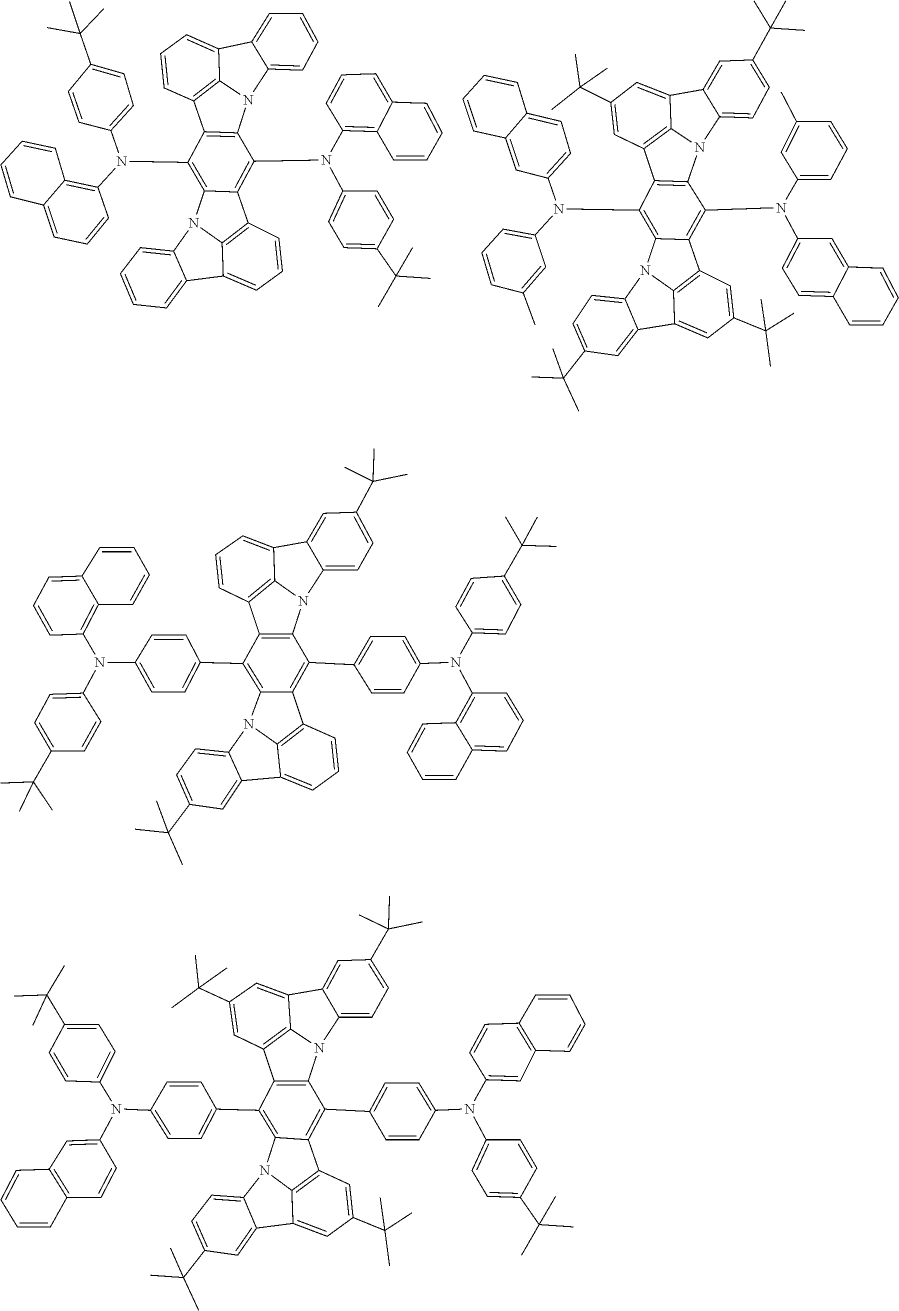

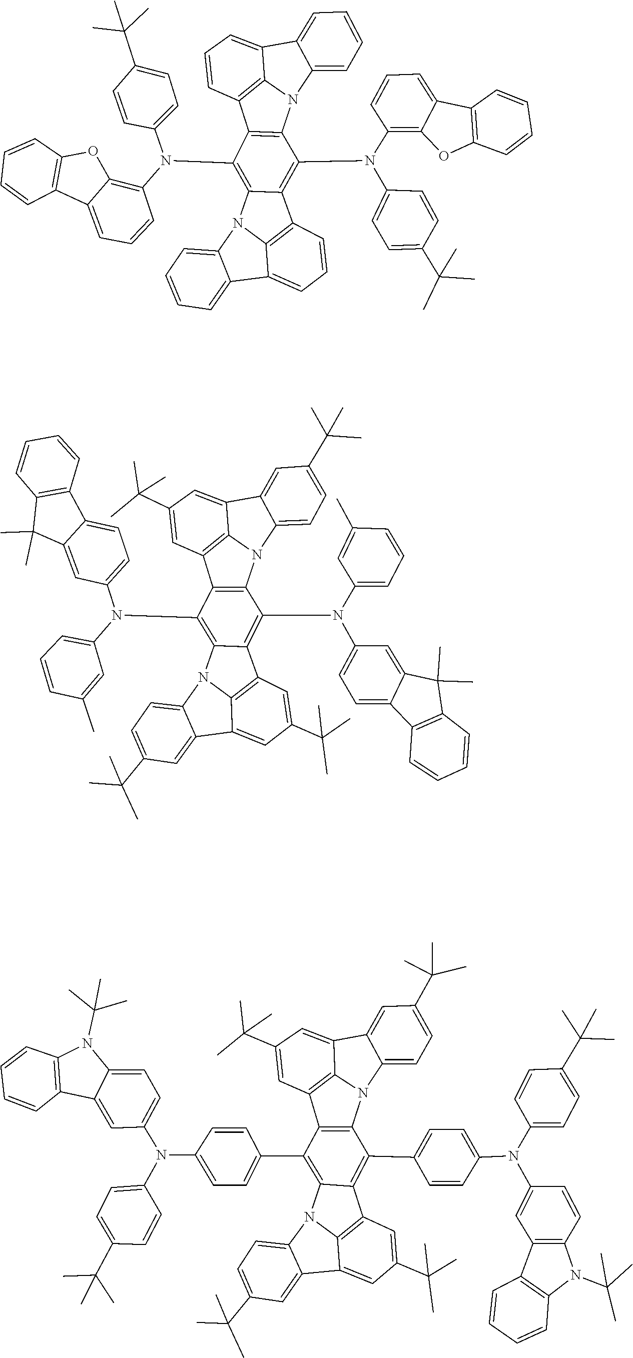

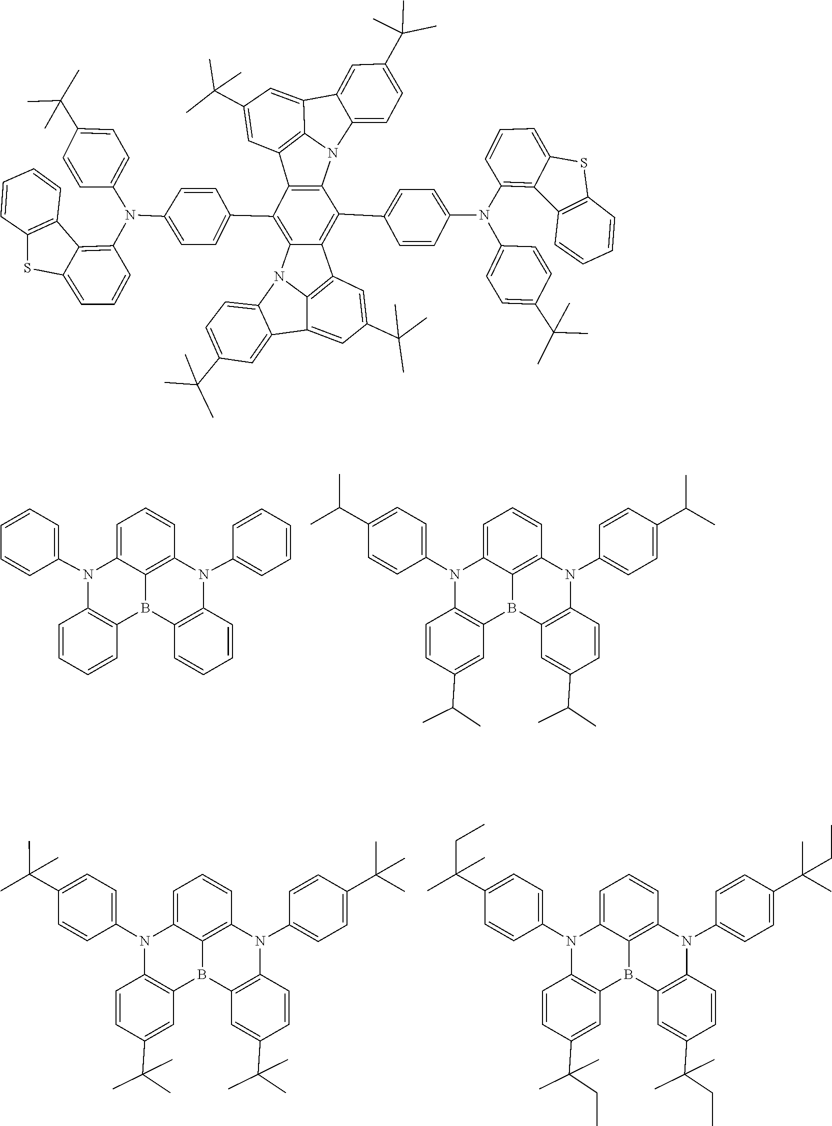

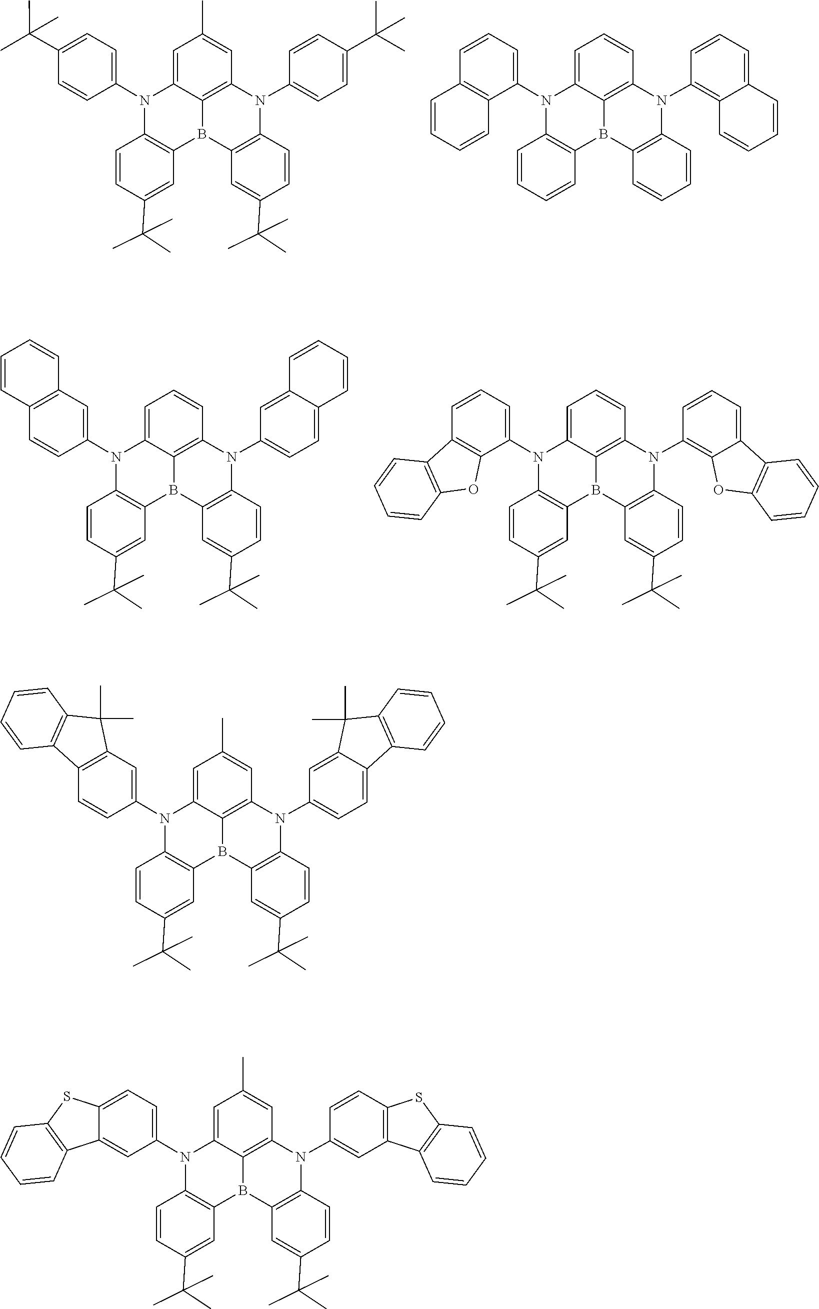

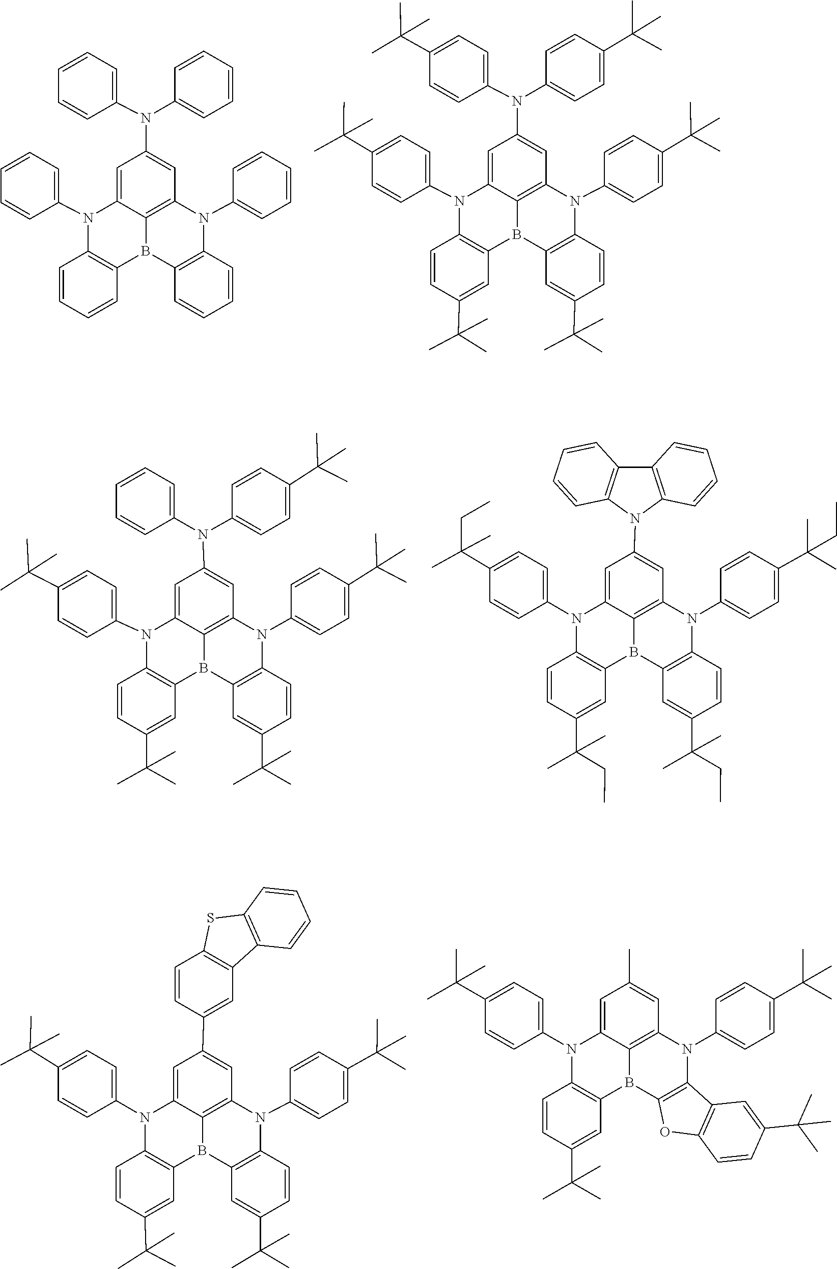

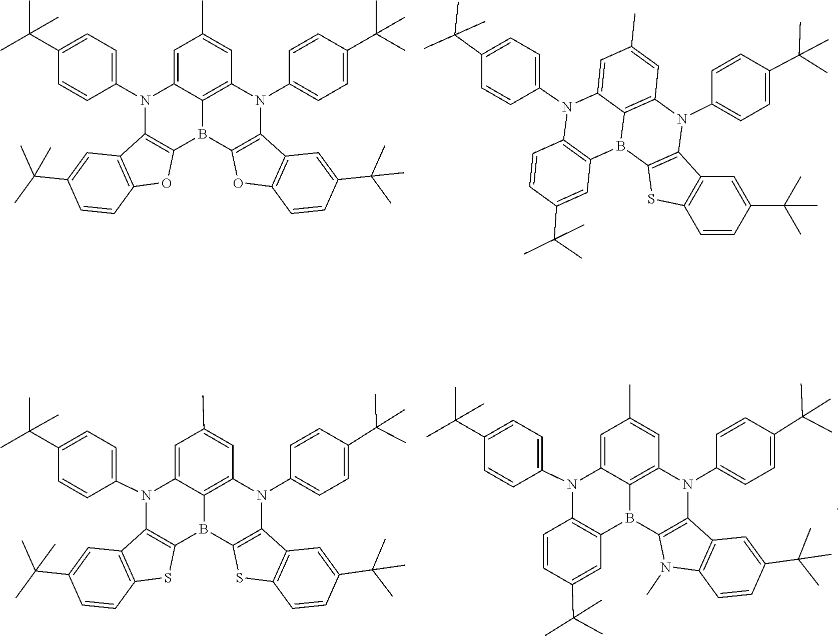

In some embodiments, in the mixture, the mass ratio of the composition to the third compound is greater than or equal to 70:30, and the mass ratio of the composition to the third compound is less than or equal to 99:1, such as 90:10, 85:15, 80:20, 75:25, and the like. Further, the mass ratio of the composition to the third compound is greater than or equal to 90:10, and the mass ratio of the composition to the third compound is less than or equal to 99:1, such as 98:2, 97:35, 96:4, 95:5, 94:6, 93:7, 92:9, 91:9, and the like.

In some embodiments, the mixture is used to form a light-emitting layer of a light-emitting device, the composition is a host material of the light-emitting layer, the third compound is a guest material of the light-emitting layer, and the third compound is dispersed in the composition to inhibit crystallization of the light-emitting layer and concentration quenching of the third compound due to high concentration, thereby improving luminous efficiency of the light-emitting device.

The present disclosure further provides an organic dispersion system including the composition or mixture as described above, and at least one dispersant. The dispersant is used to disperse the composition or the mixture.

In some embodiments, the organic dispersion system may be an organic solution or an organic suspension.

In some embodiments, the mass fraction of the composition or the mixture within the organic dispersion system may range from 0.01% to 10%, preferably from 0.1% to 15%, more preferably from 0.2% to 5%, and most preferably from 0.25% to 3%.

In some embodiments, the composition or the mixture may form a film layer through a printing or coating process of the organic dispersant. Printing or coating processes include inkjet printing, nozzle printing, letterpress printing, screen printing, dip coating, spin coating, doctor blade coating, roller printing, twist roller printing, flexographic lithographic printing, flexographic printing, rotary printing, spraying, brushing or pad printing, slot-type extrusion coating, and the like. Preferably, it is gravure printing, jet printing and inkjet printing.

In some embodiments, the hansen solubility parameters of the dispersant are as follows: δd (dispersion force) of the dispersant ranges from 17.0 MPa^{1/2} to 23.2 MPa^{1/2}, preferably from 18.5 MPa^{1/2} to 21.0 MPa^{1/2}; Δp (polarity force) ranges from 0.2 MPa^{1/2} to 12.5 MPa/2, preferably from 2.0 MPa^{1/2} to 6.0 MPa^{1/2}; and Δh (hydrogen bonding force) ranges from 0.9 MPa^{1/2} to 14.2 MPa^{1/2}, preferably from 2.0 MPa^{1/2} to 6.0 MPa^{1/2}.

In some embodiments, the boiling point of the dispersant is greater than or equal to 150° C.; preferably greater than or equal to 180° C.; more preferably greater than or equal to 200° C.; more preferably greater than or equal to 250° C.; and further preferably greater than or equal to 275° C. and most preferably greater than or equal to 300° C. The boiling point of the dispersant is at least greater than or equal to 150° C., which is conducive to preventing clogging of the nozzles of the inkjet head during inkjet printing, and the higher the boiling point, the more conducive to preventing clogging.

In some embodiments, the dispersant can include at least one dispersant that can be evaporated from a solvent system to form a film including functional materials. The dispersant may include at least one first dispersant, which may be aromatic or heteroaromatic. Exemplarily, the first dispersant may be selected from p-diisopropylbenzene, pentylbenzene, tetrahydronaphthalene, cyclohexylbenzene, chloronaphthalene, 1, 4-dimethylnaphthalene, 3-isopropylbiphenyl, p-methylcumene, dipentylbenzene, tripentylbenzene, amyl-toluene, o-diethylbenzene, m-diethylbenzene, p-diethylbenzene, 1,2,3,4-tetramethylbenzene, 1,2,3,5-tetramethylbenzene, 1,2,4,5-tetramethylbenzene, butylbenzene, dodecylbenzene, dihexylbenzene, dibutylbenzene, p-diisopropylbenzene, cyclohexylbenzene, benzylbutylbenzene, dimethylnaphthalene, 3-isopropylbiphenyl, p-methylcumene, 1-methylnaphthalene, 1,2,4-trichlorobenzene, 4,4-difluorodiphenylmethane, 1,2-dimethoxy-4-(1-propenyl)benzene, diphenylmethane, 2-phenylpyridine, 3-phenylpyridine, N-methyldiphenylamine, 4-isopropylbiphenyl, α,α-dichlorodiphenylmethane, 4-(3-phenylpropyl)pyridine, benzyl benzoate, 1,1-bis(3,4-dimethylphenyl)ethane, 2-isopropylnaphthalene, quinoline, isoquinoline, methyl 2-furanoate, ethyl 2-furanoate, and the like.

The first dispersant may be selected from aromatic ketone solvents. Exemplarily, the first dispersant may be selected from 1-tetralone, 2-tetralone, 2-(phenylepoxy) tetralone, 6-(methoxy) tetralone, acetophenone, propiophenone, benzophenone, and derivatives thereof, such as 4-methylacetophenone, 3-methylacetophenone, 2-methylacetophenone, 4-methylacetophenone, 3-methylacetophenone, 2-methylacetophenone, and the like.

The first dispersant may be selected from aromatic ether solvents. Exemplarily, the first dispersant may be selected from 3-phenoxytoluene, butoxybenzene, p-anisaldehyde dimethyl acetal, tetrahydro-2-phenoxy-2H-pyran, 1,2-dimethoxy-4-(1-propenyl)benzene, 1,4-benzodioxane, 1,3-dipropylbenzene, 2,5-dimethoxytoluene, 4-ethylbenzoethyl ether, 1,3-dipropoxybenzene, 1,2,4-trimethoxybenzene, 4-(1-propenyl)-1,2-dimethoxybenzene, 1,3-dimethoxybenzene, glycidyl phenyl ether, dibenzyl ether, 4-tert-butyl anisole, trans-p-propenyl anisole, 1,2-dimethoxybenzene, 1-methoxynaphthalene, diphenyl ether, 2-phenoxymethyl ether, 2-phenoxytetrahydrofuran, ethyl-2-naphthyl ether, and the like.

The first dispersant may be selected from aliphatic ketones. Exemplarily, the first dispersant may be selected from aliphatic ketones, such as 2-nonanone, 3-nonanone, 5-nonanone, 2-decanone, 2,5-hexanedione, 2,6,8-trimethyl-4-nonanone, fenchone, phorone, isophorone, di-n-amyl ketone, and the like; or aliphatic ethers, such as amyl ether, hexyl ether, dioctyl ether, ethylene glycol dibutyl ether, diethylene glycol diethyl ether, diethylene glycol butyl methyl ether, diethylene glycol dibutyl ether, triethylene glycol dimethyl ether, triethylene glycol ethyl methyl ether, triethylene glycol butyl methyl ether, tripropylene glycol dimethyl ether, tetraethylene glycol dimethyl ether, and the like.

The first dispersant may be selected from organic ester solvents. Exemplarily, the first solvent may be selected from alkyl octanoate, alkyl sebacate, alkyl stearate, alkyl benzoate, alkyl phenylacetate, alkyl cinnamate, alkyl oxalate, alkyl maleate, alkyl lactone, alkyl oleate, and the like. Octyl octanoate, diethyl sebacate, diallyl phthalate, isononyl isononanoate, and the like are particularly preferred.

The dispersant may further include a second dispersant, and the second dispersant may be selected from one or more of methanol, ethanol, 2-methoxyethanol, dichloromethane, trichloromethane, chlorobenzene, o-dichlorobenzene, tetrahydrofuran, anisole, morpholine, toluene, o-xylene, m-xylene, p-xylene, 1, 4-dioxane, acetone, methyl ethyl ketone, 1,2-dichloroethane, 3-phenoxytoluene, 1,1,1-trichloroethane, 1,1,2,2-tetrachloroethane, ethyl acetate, butyl acetate, dimethylformamide, dimethylacetamide, dimethylsulfoxide, tetrahydronaphthalene, decalin, indene, and the like.

In addition to the dispersoid and dispersant, the composition may further include one or more components such as surface active compounds, lubricants, wetting agents, dispersing agents, hydrophobic agents, adhesives, and the like, for adjusting viscosity, film-forming performance, for adjusting viscosity, film-forming performance, improving adhesion, and the like.

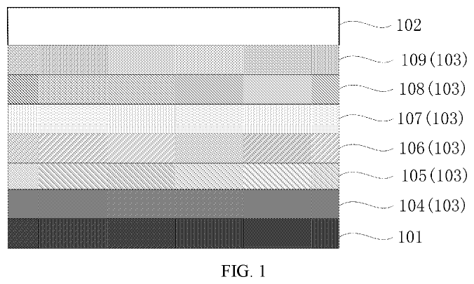

Referring to FIG. 1, the present disclosure further provides a light-emitting device. The light-emitting device includes a pair of electrodes including a first electrode 101 and a second electrode 102; and an organic functional layer 103 disposed between the first electrode 101 and the second electrode 102. The material of the organic functional layer 103 includes one or more organic compounds as described above. The first electrode 101 may be an anode and the second electrode 102 may be a cathode.

In some embodiments, the light-emitting device may be used in organic light-emitting diodes, organic photovoltaic cells, organic light-emitting cells, organic field-effect transistors, organic light-emitting field-effect transistors, organic lasers, organic spin-electron devices, organic sensors, organic plasmon-emitting diodes, and the like, preferably organic light-emitting diodes, organic light-emitting cells, organic light-emitting field-effect transistors.

In some embodiments, the light-emitting devices may be applied to a variety of electronic devices, such as display panels, lighting devices, light sources, and the like.

In some embodiments, the organic functional layer 103 may be a single layer. In this case, the organic functional layer 103 is a mixture layer. The mixture in the mixture layer includes a first compound and a second compound. The first compound is selected from one or more of the organic compounds described above. The second compound is selected from one or more of a hole injection material, a hole transport material, an electron transport material, a hole blocking material, a light-emitting guest material, a light-emitting host material, and an organic dye.

In a case that the second compound is selected from one or more of a hole injection material, a hole transport material, an electron transport material, a hole blocking material, a light-emitting host material, and an organic dye, the mass ratio of the first compound to the second compound is 1:99 to 30:70, preferably 1:99 to 10:90.

In a case that the second compound is a light-emitting guest material, the mass ratio of the first compound to the second compound is 99:1 to 70:30, preferably 99:1 to 90:10.

In some embodiments, the organic functional layer 103 may include multiple layers. In a case that the organic functional layer 103 include multiple layers, the organic functional layer 103 includes at least a light-emitting layer 107; preferably, the organic functional layer 103 includes a hole injection layer 104, a hole transport layer 105, a light emitting layer 107, an electron blocking layer 106, an electron injection layer 109, an electron transport layer 108, or a hole blocking layer.

In some embodiments, the anode is an electrode that injects holes, and the anode may inject holes into the organic functional layer 103, for example, the anode injects holes into the hole injection layer, the hole transport layer, or the light-emitting layer. The anode may include at least one of a conductive metal, a conductive metal oxide, or a conductive polymer. Preferably, the absolute value of the difference between the work function of the anode and HOMO (highest occupied molecular orbital) level or the valence band energy level of luminescent materials in the light-emitting layer or the p-type semiconductor materials in the hole injection layer or the hole transport layer or the electron blocking layer is less than 0.5 eV, preferably less than 0.3 eV, more preferably less than 0.2 eV. The materials of the anode include, but are not limited to, at least one of Al, Cu, Au, Ag, Mg, Fe, Co, Ni, Mn, Pd, Pt, ITO (indium tin oxide), aluminum-doped zinc oxide (AZO), and the like, or other suitable and known materials for anode that can be readily selected by those skilled in the art. The materials of anode may be deposited using any suitable technique, such as a suitable physical vapor deposition method, including radio frequency magnetron sputtering, vacuum thermal evaporation, e-beam, and the like. In some embodiments, the anode can be patterned, for example, patterned ITO conductive substrates are commercially available and can be used to prepare devices according to the present disclosure.

In some embodiments, the cathode is an electrode that injects electrons, and the cathode may inject electrons into the organic functional layer, for example, the cathode injects electrons into the electron injection layer, the electron transport layer, or the light-emitting layer. The cathode may include at least one of a conductive metal or a conductive metal oxide. Preferably, the absolute value of the difference between the work function of the cathode and LUMO (lowest unoccupied molecular orbital) level or the valence band energy level of luminescent materials in the light-emitting layer or the n-type semiconductor materials in the electron injection layer or the electron transport layer or the hole blocking layer is less than 0.5 eV, preferably less than 0.3 eV, more preferably less than 0.2 eV. All materials that can be used as cathodes for organic electronic devices may be used as materials of cathode of devices in the present disclosure. The materials of cathode include but not limited to at least one of Al, Au, Ag, Ca, Ba, Mg, LiF/Al, MgAg alloy, BaF2/Al, Cu, Fe, Co, Ni, Mn, Pd, Pt, ITO, and the like. The materials of cathode may be deposited using any suitable technique, such as a suitable physical vapor deposition method, including radio frequency magnetron sputtering, vacuum thermal evaporation, e-beam, and the like.

In some embodiments, the hole injection layer 104 is used to facilitate the injection of holes from the anode to the light-emitting layer 107. The hole injection layer 104 includes hole injection materials, which are material that can receive holes injected from a positive electrode at a low voltage. Preferably, the HOMO of the hole injection materials is between the work function of the materials of the anode and HOMO of the functional materials of the hole injection layer on the side away from the anode (e.g.: hole transport materials of the hole transport layer). The hole injection materials include, but are not limited to, at least one of metalloporphyrins, oligomeric thiophenes, arylamine-based organic materials, hexanitrile hexaazabenzophenanthrene-based organic materials, quinacridone-based organic materials, perylene-based organic materials, anthraquinones, polyaniline-based and polythiophene-based conductive polymers, and the like.

In some embodiments, the hole transport layer 105 may be used to transport holes to the light-emitting layer 107. The hole transport layer 105 includes hole transport materials, which receive holes transported from the anode or the hole injection layer and transfers the holes to the light-emitting layer. The hole transport materials are materials known to have high hole mobility in the art. The hole transport materials may include, but are not limited to, at least one of arylamine-based organic materials, conductive polymers, block copolymers having both a conjugated moiety and a non-conjugated moiety, and the like.

In some embodiments, the electron transport layer 108 is used to transport electrons. The electron transport layer 108 includes electron transport materials, which receive electrons injected from a negative electrode and transfers the electrons to the light-emitting layer 107. The electron transport materials are materials known to have a high electron mobility in the art. The electron transport materials may include, but are not limited to, at least one of Al complexes of 8-hydroxyquinoline, complexes containing Alq3, organic radical compounds, hydroxyflavone-metal complexes, lithium 8-hydroxyquinoline (LiQ), and benzimidazole-based compounds.

In some embodiments, the electron injection layer 109 is used to inject electrons. The electron injection layer 109 includes electron injection materials. The electron injection materials preferably have the ability to transport electrons, have the effects of injecting electrons from the negative electrode, excellent effects of injecting electrons into the light-emitting layer 107 or the light-emitting materials, and the effects of preventing excitons generated by the light-emitting layer 107 from moving to the hole injection layer, and further have an excellent ability of forming a thin film. The electron injection materials include, but are not limited to, at least one of 8-hydroxyquinoline lithium (LiQ), fluorenone, anthraquinone dimethane, phenylbenzoquinone, thiopyran dioxide, oxazole, oxadiazole, triazole, imidazole, perylene tetracarboxylic acid, fluorenylidene methane, anthracenone and derivatives thereof, metal complex compounds, nitrogen-containing 5-membered ring derivatives, and the like.

In some embodiments, the hole blocking layer is used to block holes from reaching the negative electrode, and can generally be formed under the same conditions as the hole injection layer 104. The hole blocking layer includes hole blocking materials, which include, but are not limited to, at least one of oxadiazole derivatives or triazole derivatives, phenanthroline derivatives, BCP, aluminum complexes, and the like.

In some embodiments, the light-emitting layer 107 includes a host material and a guest material. The host material is a composition as described above. The guest material is one or more of the third compounds as described above.

The light-emitting wavelength of the light-emitting device may be between 300 nm and 1000 nm, preferably between 350 nm and 900 nm, more preferably between 400 nm and 800 nm. The light emitted by the light-emitting device may be red light, green light or blue light, and preferably blue light.

In some embodiments, the light-emitting element further includes a substrate on which the first electrode 101, the hole injection layer electrode 104, the hole transport layer electrode 105, the electron blocking layer electrode 106, the light-emitting layer electrode 107, the electron transport layer electrode 108, the electron injection layer electrode 109, and the second electrode 102 are sequentially stacked. The substrate may be a transparent substrate or an opaque substrate. In a case that the substrate is a transparent substrate, a transparent light-emitting device may be manufactured. The substrate may be a rigid substrate or a flexible substrate with elasticity. Materials of the substrate may include, but are not limited to, plastic, polymer, metal, semiconductor wafer, glass, and the like. Preferably, the substrate includes at least one smooth surface for forming the anode on the surface. More preferably, the surface has no surface defects. Preferably, the material of the substrate is a polymeric film or plastic, including but not limited to polyethylene terephthalate (PET material) and polyethylene glycol (2,6-naphthalene) (PEN material). The glass transition temperature of the substrate is greater than or equal to electrode 150° C., preferably greater than or equal to 200° C., more preferably greater than or equal to 250° C., and most preferably greater than or equal to 300° C.

Exemplary preparation method of the first compounds in the composition provided by the present disclosure is shown in exemplary Example 1 below.

### Example 1

The synthetic routes of the compounds represented by formulae (1-1) to (1-3) are as follows:

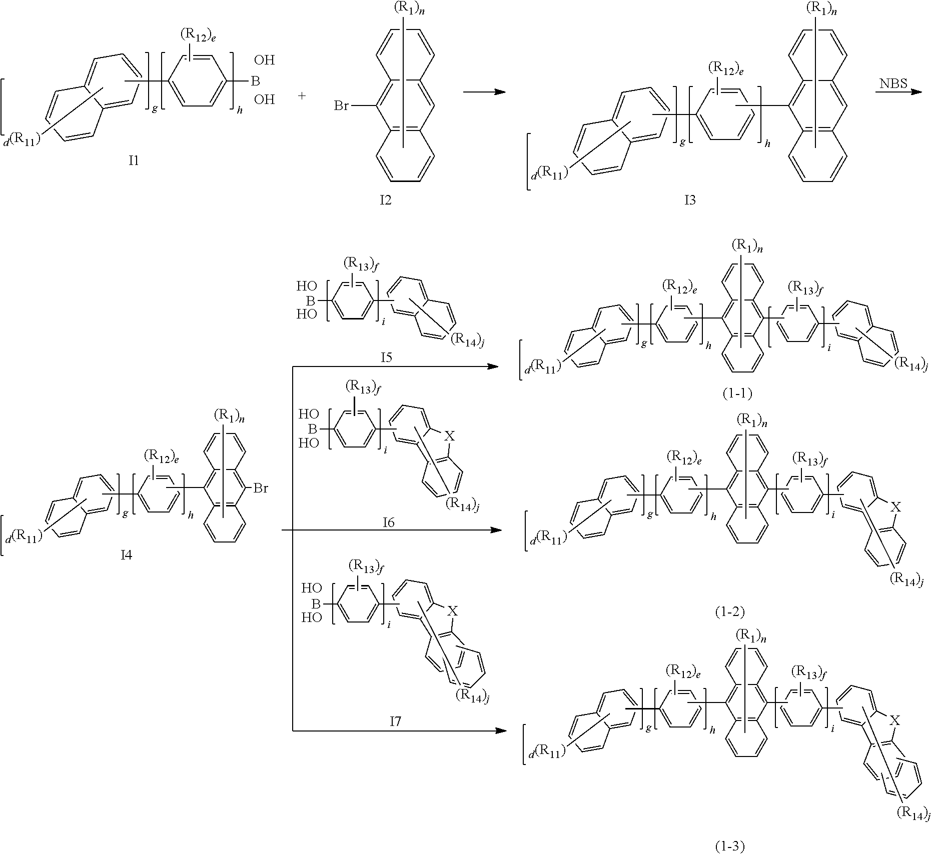

Synthesis of intermediate I3: one part of raw material I1, on part of raw material I2, 0.03 parts of tetrakis (triphenylphosphine) palladium, two parts of potassium carbonate, 0.3 part of water, and ten parts of toluene were added to a three-necked flask under nitrogen atmosphere, which were heated and stirred until the temperature was 110° C. The reaction was carried out for 12 hours to obtain a mixture. After the reaction was completed, the mixture was cooled to room temperature. The mixture was sucting filtered to collect the filtrate, followed by rotary evaporation to remove most of the solvent, after that dissolved with dichloromethane, washed with water for three times to collect the organic solution. The organic solution was then purified on a silica gel column through column chromatography.

Synthesis of intermediate I4: One part of intermediate I3 and ten parts of N,N-dimethylformamide (DMF) were added to a two-necked bottle, then a solution of one part of N-bromosuccinimide in DMF was slowly added dropwise. After the addition was completed, the reaction was further stirred for 6 hours, then quenched by adding water. The reaction mixture was sucting filtered to obtain a filter residue, which was washed with water for three times, and then recrystallized and purified with a mixed solution of dichloromethane/ethanol.

Synthesis of compounds of formula (1-1): one part of intermediate I4, one part of intermediate I5, 0.03 parts of tetrakis (triphenylphosphine) palladium, two parts of potassium carbonate, 0.3 parts of water, and ten parts of toluene were added to a three-necked flask under nitrogen atmosphere, which were heated and stirred until the temperature was 110° C. The reaction was carried out for 12 hours to obtain a mixture. After the reaction was completed, the mixture was cooled to room temperature. The mixture was sucting filtered to collect the filtrate, followed by rotary evaporation to remove most of the solvent, and then recrystallized and purified with toluene to obtain the compounds of formula (1-1).

Synthesis of compounds of formula (1-2): one part of intermediate I4, one part of intermediate I6, 0.03 parts of tetrakis (triphenylphosphine) palladium, two parts of potassium carbonate, 0.3 parts of water, and ten parts of toluene were added to a three-necked flask under nitrogen atmosphere, which were heated and stirred until the temperature was 110° C. The reaction was carried out for 12 hours to obtain a mixture. After the reaction was completed, the mixture was cooled to room temperature. The mixture was sucting filtered to collect the filtrate, followed by rotary evaporation to remove most of the solvent, and then recrystallized and purified with toluene to obtain the compounds of formula (1-2).

Synthesis of compounds of formula (1-3): one part of intermediate I4, one part of intermediate I7, 0.03 parts of tetrakis (triphenylphosphine) palladium, two parts of potassium carbonate, 0.3 parts of water, and ten parts of toluene were added to a three-necked flask under nitrogen atmosphere, which were heated and stirred until the temperature was 110° C. The reaction was carried out for 12 hours to obtain a mixture. After the reaction was completed, the mixture was cooled to room temperature. The mixture was sucting filtered to collect the filtrate, followed by rotary evaporation to remove most of the solvent, and then recrystallized and purified with toluene to obtain the compounds of formula (1-3).

The first compounds M1 to M16 obtained by the above method are shown in Table 1 below.

TABLE 1
Structures, starting materials and intermediate structures of the first compounds
M1 to M16

| | Raw materials I1 | Raw materials I2 | Intermediates I5/I6/I7 | First compounds |
|---|---|---|---|---|
| M1 | 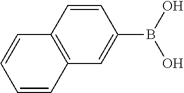 [SMILES: OB(O)c1ccc2ccccc2c1] | 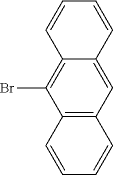 [SMILES: Brc1c2ccccc2cc2ccccc12] | 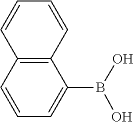 [SMILES: OB(O)c1cccc2ccccc12] | 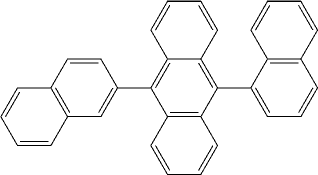 [SMILES: c1ccc2cc(-c3c4ccccc4c(-c4cccc5ccccc45)c4ccccc34)ccc2c1] |
| M2 | 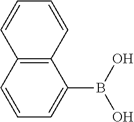 [SMILES: OB(O)c1cccc2ccccc12] | 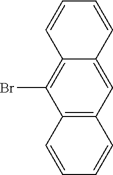 [SMILES: Brc1c2ccccc2cc2ccccc12] | 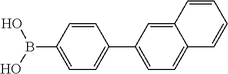 [SMILES: OB(O)c1ccc(-c2ccc3ccccc3c2)cc1] | 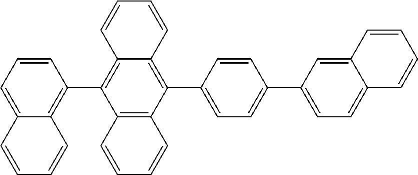 [SMILES: c1ccc2cc(-c3ccc(-c4c5ccccc5c(-c5cccc6ccccc56)c5ccccc45)cc3)ccc2c1] |
| M3 | 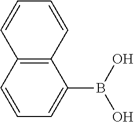 [SMILES: OB(O)c1cccc2ccccc12] | 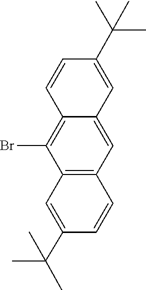 [SMILES: CC(C)(C)c1ccc2c(Br)c3cc(C(C)(C)C)ccc3cc2c1] | 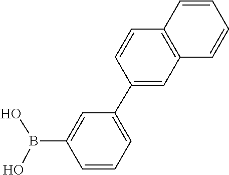 [SMILES: OB(O)c1cccc(-c2ccc3ccccc3c2)c1] | 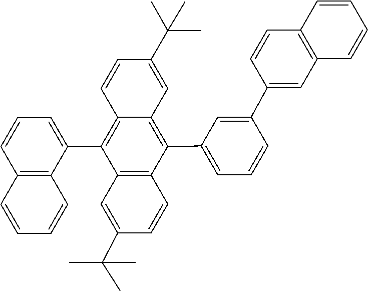 [SMILES: CC(C)(C)c1ccc2c(-c3cccc4ccccc34)c3cc(C(C)(C)C)ccc3c(-c3cccc(-c4ccc5ccccc5c4)c3)c2c1] |
| M4 | 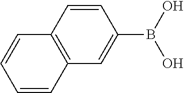 [SMILES: OB(O)c1ccc2ccccc2c1] | 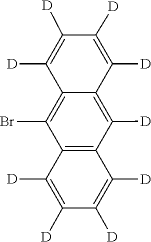 [SMILES: [2H]c1c([2H])c([2H])c2c(Br)c3c([2H])c([2H])c([2H])c([2H])c3c([2H])c2c1[2H]] | 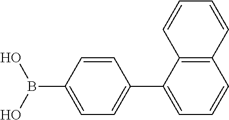 [SMILES: OB(O)c1ccc(-c2cccc3ccccc23)cc1] | 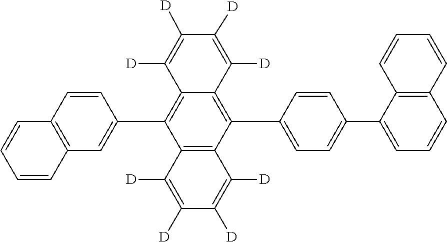 [SMILES: [2H]c1c([2H])c([2H])c2c(-c3ccc4ccccc4c3)c3c([2H])c([2H])c([2H])c([2H])c3c(-c3ccc(-c4cccc5ccccc45)cc3)c2c1[2H]] |
| M5 | 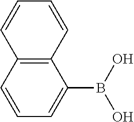 [SMILES: OB(O)c1cccc2ccccc12] | 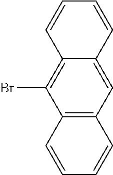 [SMILES: Brc1c2ccccc2cc2ccccc12] | 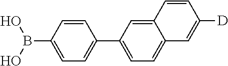 [SMILES: [2H]c1ccc2cc(-c3ccc(B(O)O)cc3)ccc2c1] | 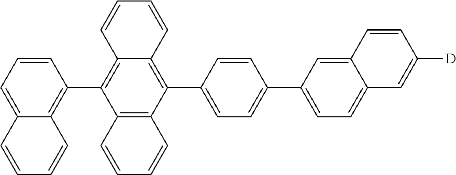 [SMILES: [2H]c1ccc2cc(-c3ccc(-c4c5ccccc5c(-c5cccc6ccccc56)c5ccccc45)cc3)ccc2c1] |
| M6 | 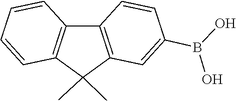 [SMILES: CC1(C)c2ccccc2-c2ccc(B(O)O)cc21] | 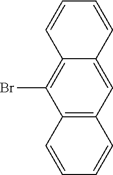 [SMILES: Brc1c2ccccc2cc2ccccc12] | 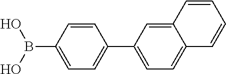 [SMILES: OB(O)c1ccc(-c2ccc3ccccc3c2)cc1] | 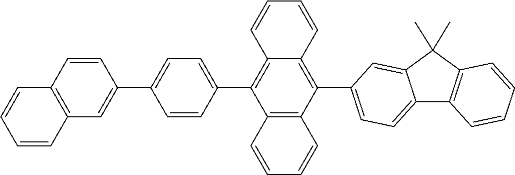 [SMILES: CC1(C)c2ccccc2-c2ccc(-c3c4ccccc4c(-c4ccc(-c5ccc6ccccc6c5)cc4)c4ccccc34)cc21] |
| M7 | 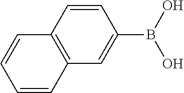 [SMILES: OB(O)c1ccc2ccccc2c1] | 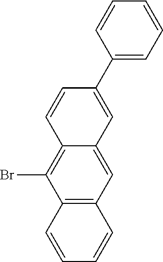 [SMILES: Brc1c2ccccc2cc2cc(-c3ccccc3)ccc12] | 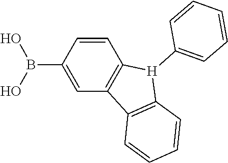 | 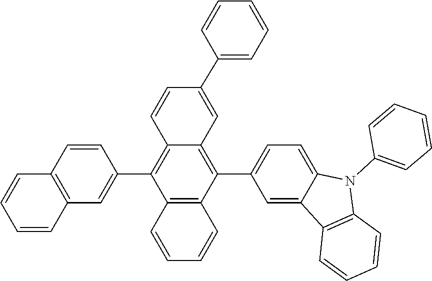 [SMILES: c1ccc(-c2ccc3c(-c4ccc5ccccc5c4)c4ccccc4c(-c4ccc5c(c4)c4ccccc4n5-c4ccccc4)c3c2)cc1] |
| M8 | 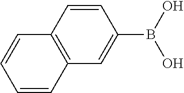 [SMILES: OB(O)c1ccc2ccccc2c1] | 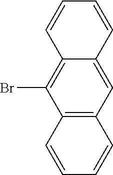 [SMILES: Brc1c2ccccc2cc2ccccc12] | 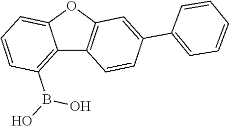 [SMILES: OB(O)c1cccc2oc3cc(-c4ccccc4)ccc3c12] | 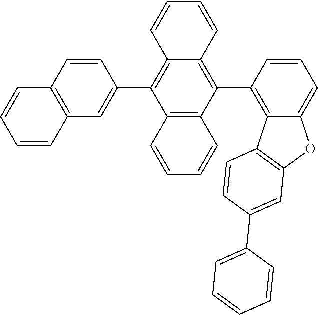 [SMILES: c1ccc(-c2ccc3c(c2)oc2cccc(-c4c5ccccc5c(-c5ccc6ccccc6c5)c5ccccc45)c23)cc1] |
| M9 | 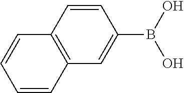 [SMILES: OB(O)c1ccc2ccccc2c1] | 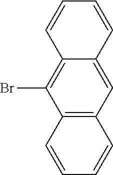 [SMILES: Brc1c2ccccc2cc2ccccc12] | 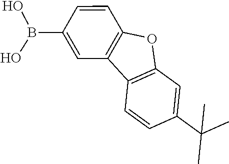 [SMILES: CC(C)(C)c1ccc2c(c1)oc1ccc(B(O)O)cc12] | 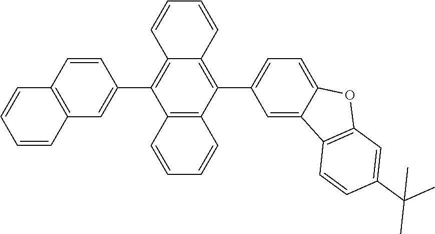 [SMILES: CC(C)(C)c1ccc2c(c1)oc1ccc(-c3c4ccccc4c(-c4ccc5ccccc5c4)c4ccccc34)cc12] |
| M10 | 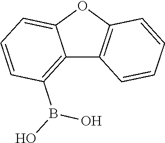 [SMILES: OB(O)c1cccc2oc3ccccc3c12] | 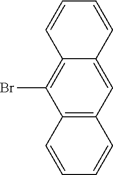 [SMILES: Brc1c2ccccc2cc2ccccc12] | 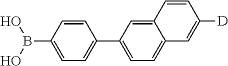 [SMILES: [2H]c1ccc2cc(-c3ccc(B(O)O)cc3)ccc2c1] | 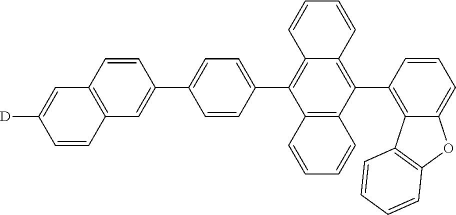 [SMILES: [2H]c1ccc2cc(-c3ccc(-c4c5ccccc5c(-c5cccc6oc7ccccc7c56)c5ccccc45)cc3)ccc2c1] |
| M11 | 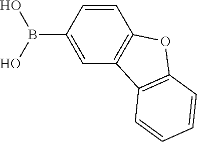 [SMILES: OB(O)c1ccc2oc3ccccc3c2c1] | 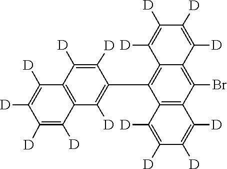 [SMILES: [2H]c1c([2H])c([2H])c2c([2H])c(-c3c4c([2H])c([2H])c([2H])c([2H])c4c(Br)c4c([2H])c([2H])c([2H])c([2H])c34)c([2H])c([2H])c2c1[2H]] | | 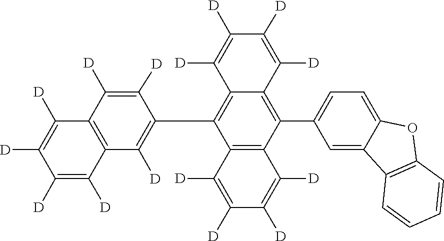 [SMILES: [2H]c1c([2H])c([2H])c2c([2H])c(-c3c4c([2H])c([2H])c([2H])c([2H])c4c(-c4ccc5oc6ccccc6c5c4)c4c([2H])c([2H])c([2H])c([2H])c34)c([2H])c([2H])c2c1[2H]] |
| M12 | 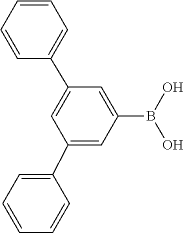 [SMILES: OB(O)c1cc(-c2ccccc2)cc(-c2ccccc2)c1] | 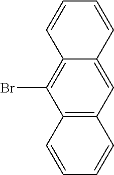 [SMILES: Brc1c2ccccc2cc2ccccc12] | 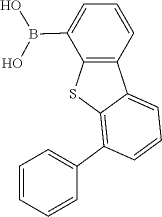 [SMILES: OB(O)c1cccc2c1sc1c(-c3ccccc3)cccc12] | 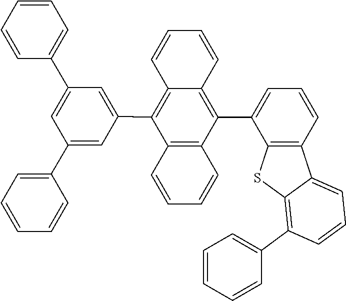 [SMILES: c1ccc(-c2cc(-c3ccccc3)cc(-c3c4ccccc4c(-c4cccc5c4sc4c(-c6ccccc6)cccc45)c4ccccc34)c2)cc1] |
| M13 | 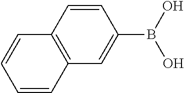 [SMILES: OB(O)c1ccc2ccccc2c1] | 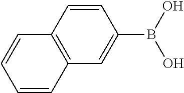 [SMILES: OB(O)c1ccc2ccccc2c1] | 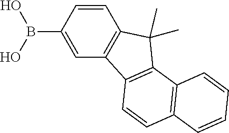 [SMILES: CC1(C)c2ccc(B(O)O)cc2-c2ccc3ccccc3c21] | 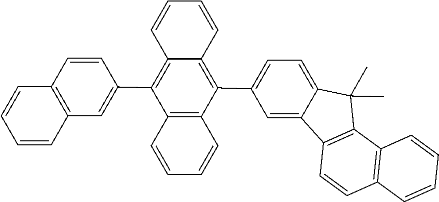 [SMILES: CC1(C)c2ccc(-c3c4ccccc4c(-c4ccc5ccccc5c4)c4ccccc34)cc2-c2ccc3ccccc3c21] |
| M14 | 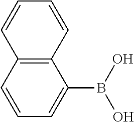 [SMILES: OB(O)c1cccc2ccccc12] | 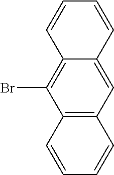 [SMILES: Brc1c2ccccc2cc2ccccc12] | 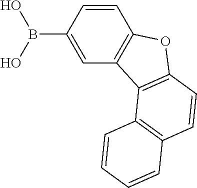 [SMILES: OB(O)c1ccc2oc3ccc4ccccc4c3c2c1] | 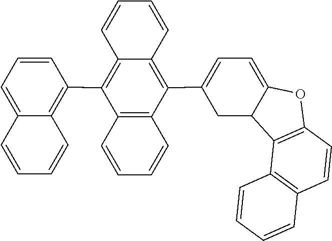 [SMILES: C1=C(c2c3ccccc3c(-c3cccc4ccccc34)c3ccccc23)CC2C(=C1)Oc1ccc3ccccc3c12] |
| M15 | 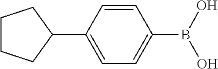 [SMILES: OB(O)c1ccc(C2CCCC2)cc1] | 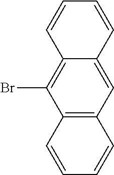 [SMILES: Brc1c2ccccc2cc2ccccc12] | 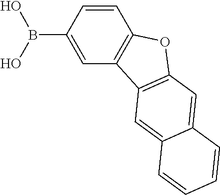 [SMILES: OB(O)c1ccc2oc3cc4ccccc4cc3c2c1] | 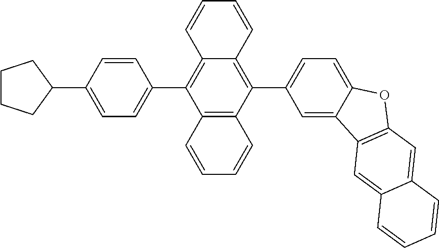 [SMILES: c1ccc2cc3c(cc2c1)oc1ccc(-c2c4ccccc4c(-c4ccc(C5CCCC5)cc4)c4ccccc24)cc13] |
| M16 | 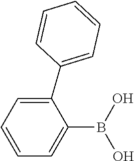 [SMILES: OB(O)c1ccccc1-c1ccccc1] | 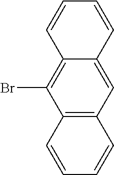 [SMILES: Brc1c2ccccc2cc2ccccc12] | 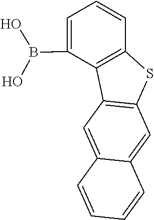 [SMILES: OB(O)c1cccc2sc3cc4ccccc4cc3c12] | 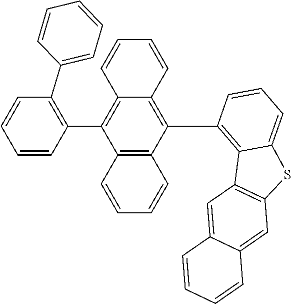 [SMILES: c1ccc(-c2ccccc2-c2c3ccccc3c(-c3cccc4sc5cc6ccccc6cc5c34)c3ccccc23)cc1] |

Exemplary preparation method of the second compounds in the composition provided by the present disclosure is shown in exemplary Example 1 below.

### Example 2

The synthetic routes of the compounds represented by formula (2-1) and formula (2-3) are as follows:

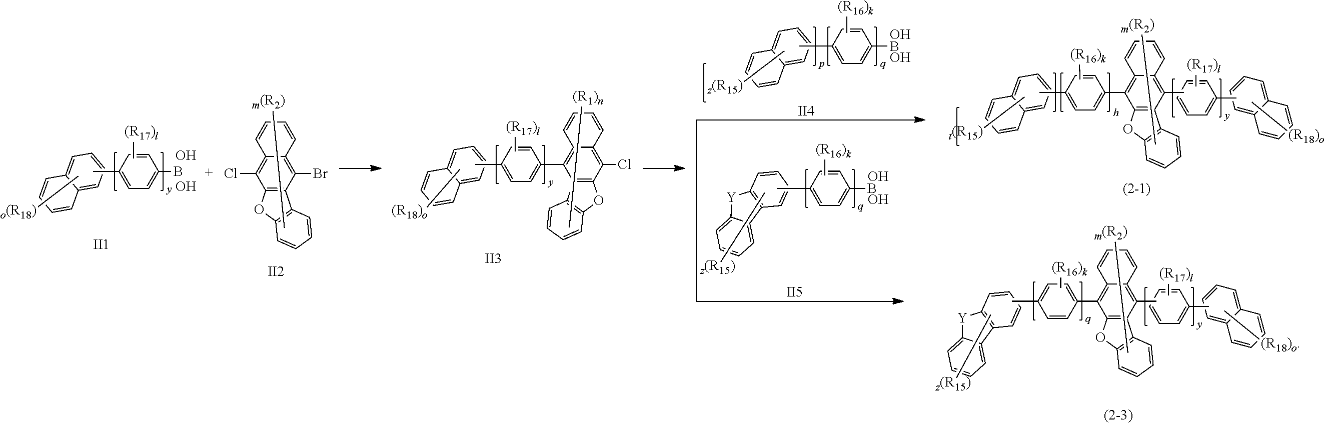

The synthetic route of the compound represented by formula (2-2) is as follows:

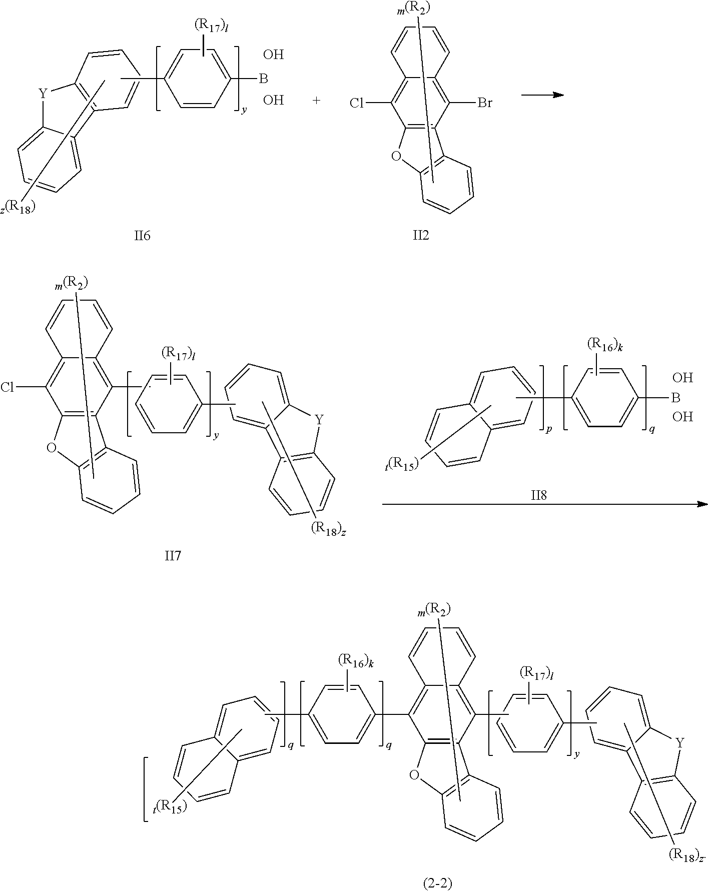

Synthetic steps of compounds represented by formula (2-1) and formula (2-3) are as follows:

Synthesis of intermediate II3: one part of raw material II1, one part of raw material II2, 0.03 parts of tetrakis (triphenylphosphine) palladium, two parts of potassium carbonate, 0.3 parts of water, and ten parts of toluene were added to a three-necked flask under nitrogen atmosphere, which were heated and stirred to until the temperature was 110° C. The reaction was carried out for 12 hours to obtain a mixture. After the reaction is completed, the mixture was cooled to room temperature. The mixture was sucting filtered to collect the filtrate, followed by rotary evaporation to remove most of the solvent, after that dissolved with dichloromethane, washed with water for three times to collect the organic solution. The organic solution was then purified on a silica gel column through column chromatography.

Synthesis of compounds of formula (2-1): one part of intermediate II3, one part of intermediate II4, 0.03 parts of bis(dibenzylideneacetone) palladium, 0.03 parts of isopropylbiphenyl, 0.03 parts of 2-dicyclohexylphosphine-2′,4′,6′-triisopropylbiphenyl, two parts of potassium carbonate, 0.3 parts of water, and ten parts of toluene were added to a three-necked flask under nitrogen atmosphere, which were heated and stirred until the temperature was 110° C. The reaction was carried out for 12 hours to obtain a mixture. After the reaction is completed, the mixture was cooled to room temperature. The mixture was sucting filtered to collect the filtrate, followed by rotary evaporation to remove most of the solvent, and then recrystallized and purified with toluene to obtain the compounds of formula (2-1).

Synthesis of compounds of formula (2-3): one part of intermediate II3, one part of intermediate II5, 0.03 parts of bis(dibenzylideneacetone)palladium, 0.03 part of isopropylbiphenyl, 0.03 parts of 2-dicyclohexylphosphine-2′,4′,6′-triisopropylbiphenyl, two parts of potassium carbonate, 0.3 parts of water, and ten parts of toluene were added to a three-necked flask under nitrogen atmosphere, which were heated and stirred until the temperature was 110° C. The reaction was carried out for 12 hours to obtain a mixture. After the reaction was completed, the mixture was cooled to room temperature. The mixture was sucting filtered to collect the filtrate, followed by rotary evaporation to remove most of the solvent, and then recrystallized and purified with toluene to obtain the compounds of formula (2-3).

Synthetic steps of compounds represented by formula (2-2) are as follows:

Synthesis of intermediate II7: one part of raw material II5, one part of raw material II2, 0.03 parts of tetrakis (triphenylphosphine) palladium, two parts of potassium carbonate, 0.3 part of water, and ten parts of toluene were added to a three-necked flask under nitrogen atmosphere, which were heated and stirred until the temperature was 110° C. The reaction was carried out for 12 hours to obtain a mixture. After the reaction was completed, the mixture was cooled to room temperature. The mixture was sucting filtered to collect the filtrate, followed by rotary evaporation to remove most of the solvent, after that dissolved with dichloromethane, washed with water for three times to collect the organic solution. The organic solution was then purified on a silica gel column through column chromatography.

Synthesis of compound of formula (2-2): one part of intermediate II7, one part of intermediate II8, 0.03 parts of bis(dibenzylideneacetone) palladium, 0.03 parts of isopropylbiphenyl, 0.03 parts of 2-dicyclohexylphosphine-2′,4′,6′-triisopropylbiphenyl, two parts of potassium carbonate, 0.3 parts of water, and ten parts of toluene were added to a three-necked flask under nitrogen atmosphere, which were heated and stirred until the temperature was 110° C. The reaction was carried out for 12 hours to obtain a mixture. After the reaction is completed, the mixture was cooled to room temperature. The mixture was sucting filtered to collect the filtrate, followed by rotary evaporation to remove most of the solvent, and then recrystallized and purified with toluene to obtain the compounds of formula (2-2).

The second compounds M17 to M30 obtained by the above method are shown in Table 2 below.

TABLE 2
Structures, starting materials and intermediate structures of second compounds
M17 to M30

| | | | Intermediates | |
|---|---|---|---|---|
| | Raw materials II1/II5 | Raw materials II2 | II4/II5/II8 | Second compounds |
| M17 | 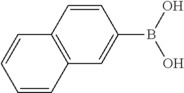 [SMILES: OB(O)c1ccc2ccccc2c1] | 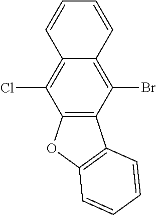 [SMILES: Clc1c2ccccc2c(Br)c2c1oc1ccccc12] | 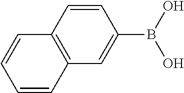 [SMILES: OB(O)c1ccc2ccccc2c1] | 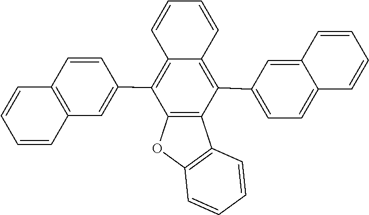 [SMILES: c1ccc2cc(-c3c4ccccc4c(-c4ccc5ccccc5c4)c4c3oc3ccccc34)ccc2c1] |
| M18 | 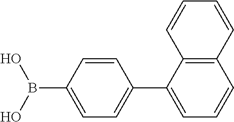 [SMILES: OB(O)c1ccc(-c2cccc3ccccc23)cc1] | 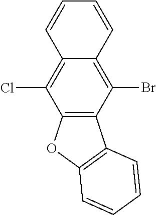 [SMILES: Clc1c2ccccc2c(Br)c2c1oc1ccccc12] | 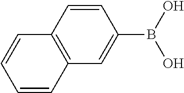 [SMILES: OB(O)c1ccc2ccccc2c1] | 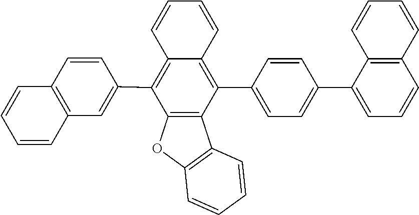 [SMILES: c1ccc2cc(-c3c4ccccc4c(-c4ccc(-c5cccc6ccccc56)cc4)c4c3oc3ccccc34)ccc2c1] |
| M19 | 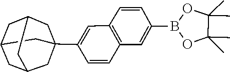 [SMILES: CC1(C)OB(c2ccc3cc(C45CC6CC(CC(C6)C4)C5)ccc3c2)OC1(C)C] | 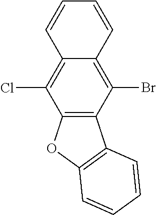 [SMILES: Clc1c2ccccc2c(Br)c2c1oc1ccccc12] | 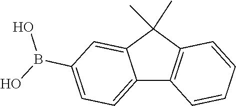 [SMILES: CC1(C)c2ccccc2-c2ccc(B(O)O)cc21] | 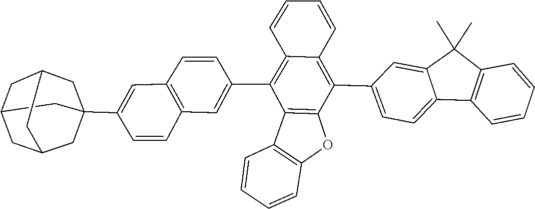 [SMILES: CC1(C)c2ccccc2-c2ccc(-c3c4ccccc4c(-c4ccc5cc(C67CC8CC(CC(C8)C6)C7)ccc5c4)c4c3oc3ccccc34)cc21] |
| M20 | 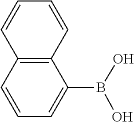 [SMILES: OB(O)c1cccc2ccccc12] | 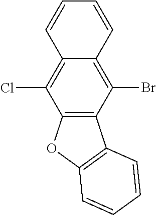 [SMILES: Clc1c2ccccc2c(Br)c2c1oc1ccccc12] | 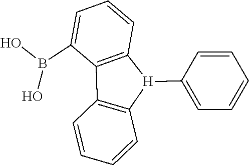 | 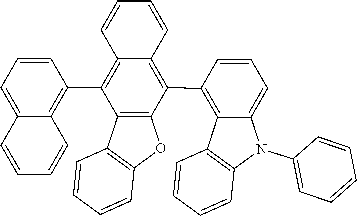 [SMILES: c1ccc(-n2c3ccccc3c3c(-c4c5ccccc5c(-c5cccc6ccccc56)c5c4oc4ccccc45)cccc32)cc1] |
| M21 | 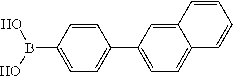 [SMILES: OB(O)c1ccc(-c2ccc3ccccc3c2)cc1] | 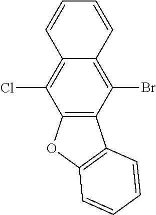 [SMILES: Clc1c2ccccc2c(Br)c2c1oc1ccccc12] | 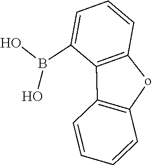 | 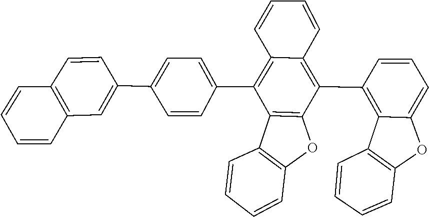 [SMILES: c1ccc2cc(-c3ccc(-c4c5ccccc5c(-c5cccc6oc7ccccc7c56)c5oc6ccccc6c45)cc3)ccc2c1] |
| M22 | 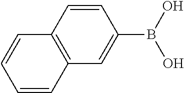 [SMILES: OB(O)c1ccc2ccccc2c1] | 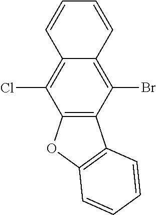 [SMILES: Clc1c2ccccc2c(Br)c2c1oc1ccccc12] | 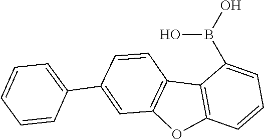 [SMILES: OB(O)c1cccc2oc3cc(-c4ccccc4)ccc3c12] | 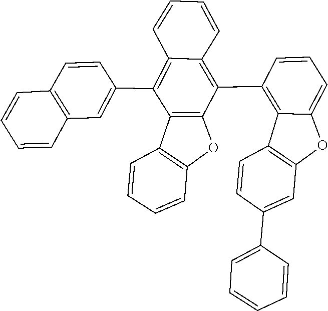 [SMILES: c1ccc(-c2ccc3c(c2)oc2cccc(-c4c5ccccc5c(-c5ccc6ccccc6c5)c5c4oc4ccccc45)c23)cc1] |
| M23 | 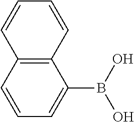 [SMILES: OB(O)c1cccc2ccccc12] | 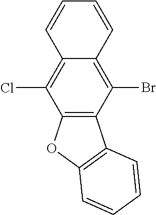 [SMILES: Clc1c2ccccc2c(Br)c2c1oc1ccccc12] | 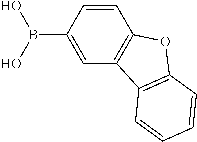 [SMILES: OB(O)c1ccc2oc3ccccc3c2c1] | 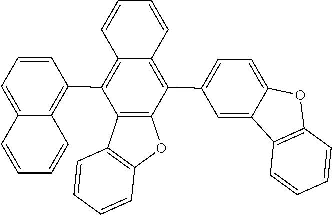 [SMILES: c1ccc2c(-c3c4ccccc4c(-c4ccc5oc6ccccc6c5c4)c4oc5ccccc5c34)cccc2c1] |
| M24 | 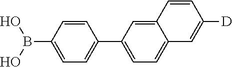 [SMILES: [2H]c1ccc2cc(-c3ccc(B(O)O)cc3)ccc2c1] | 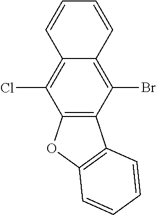 [SMILES: Clc1c2ccccc2c(Br)c2c1oc1ccccc12] | 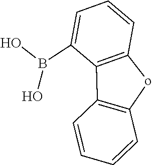 | 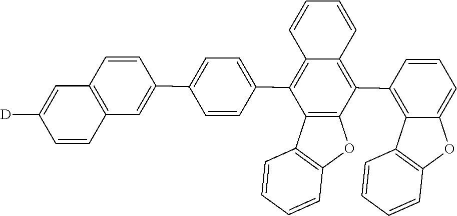 [SMILES: [2H]c1ccc2cc(-c3ccc(-c4c5ccccc5c(-c5cccc6oc7ccccc7c56)c5oc6ccccc6c45)cc3)ccc2c1] |
| M25 | 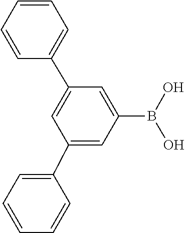 [SMILES: OB(O)c1cc(-c2ccccc2)cc(-c2ccccc2)c1] | 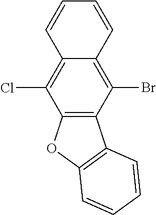 [SMILES: Clc1c2ccccc2c(Br)c2c1oc1ccccc12] | 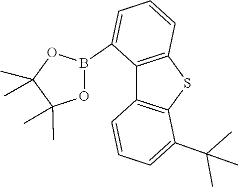 [SMILES: CC(C)(C)c1cccc2c1sc1cccc(B3OC(C)(C)C(C)(C)O3)c12] | 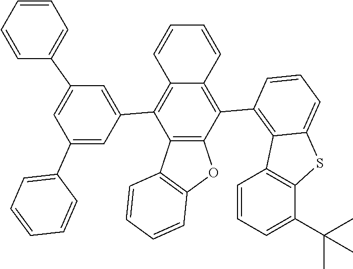 [SMILES: CC(C)(C)c1cccc2c1sc1cccc(-c3c4ccccc4c(-c4cc(-c5ccccc5)cc(-c5ccccc5)c4)c4c3oc3ccccc34)c12] |
| M26 | 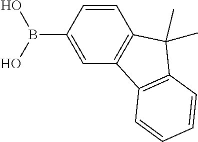 [SMILES: CC1(C)c2ccccc2-c2cc(B(O)O)ccc21] | 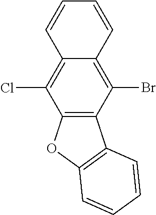 [SMILES: Clc1c2ccccc2c(Br)c2c1oc1ccccc12] | 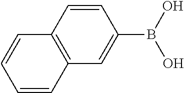 [SMILES: OB(O)c1ccc2ccccc2c1] | 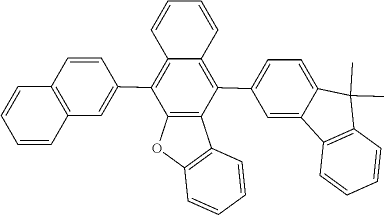 [SMILES: CC1(C)c2ccccc2-c2cc(-c3c4ccccc4c(-c4ccc5ccccc5c4)c4oc5ccccc5c34)ccc21] |
| M27 | 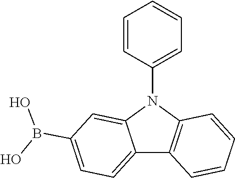 [SMILES: OB(O)c1ccc2c3ccccc3n(-c3ccccc3)c2c1] | 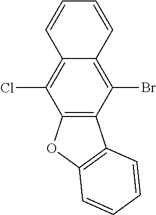 [SMILES: Clc1c2ccccc2c(Br)c2c1oc1ccccc12] | 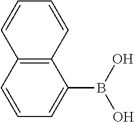 [SMILES: OB(O)c1cccc2ccccc12] | 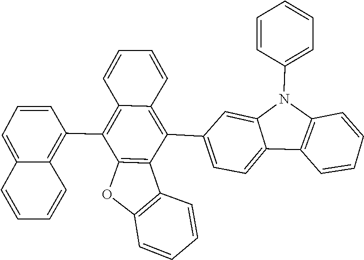 [SMILES: c1ccc(-n2c3ccccc3c3ccc(-c4c5ccccc5c(-c5cccc6ccccc56)c5oc6ccccc6c45)cc32)cc1] |
| M28 | 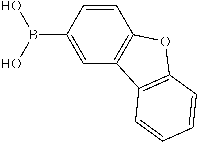 [SMILES: OB(O)c1ccc2oc3ccccc3c2c1] | 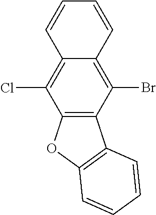 [SMILES: Clc1c2ccccc2c(Br)c2c1oc1ccccc12] | 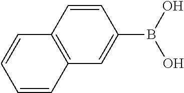 [SMILES: OB(O)c1ccc2ccccc2c1] | 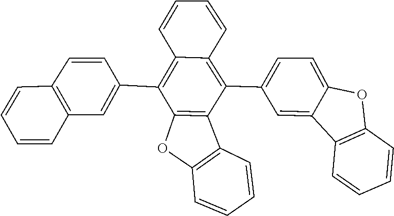 [SMILES: c1ccc2cc(-c3c4ccccc4c(-c4ccc5oc6ccccc6c5c4)c4c3oc3ccccc34)ccc2c1] |
| M29 | 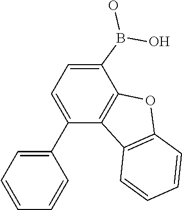 | 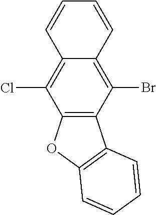 [SMILES: Clc1c2ccccc2c(Br)c2c1oc1ccccc12] | 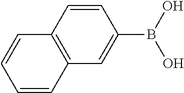 [SMILES: OB(O)c1ccc2ccccc2c1] | 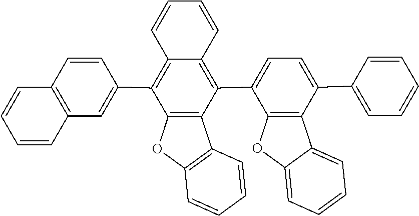 [SMILES: c1ccc(-c2ccc(-c3c4ccccc4c(-c4ccc5ccccc5c4)c4oc5ccccc5c34)c3oc4ccccc4c23)cc1] |
| M30 | 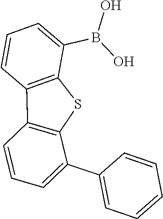 [SMILES: OB(O)c1cccc2c1sc1c(-c3ccccc3)cccc12] | 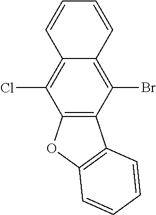 [SMILES: Clc1c2ccccc2c(Br)c2c1oc1ccccc12] | 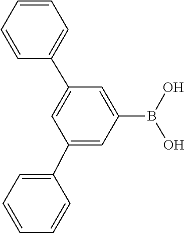 [SMILES: OB(O)c1cc(-c2ccccc2)cc(-c2ccccc2)c1] | 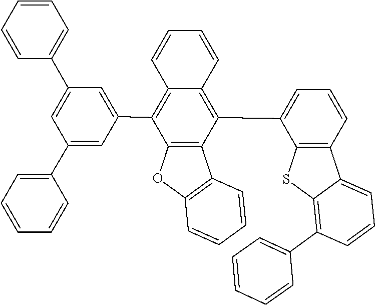 [SMILES: c1ccc(-c2cc(-c3ccccc3)cc(-c3c4ccccc4c(-c4cccc5c4sc4c(-c6ccccc6)cccc45)c4c3oc3ccccc34)c2)cc1] |

Exemplary manufacturing steps of the light-emitting devices provided by the present disclosure are shown in the following example 3.

### Example 3

In this example, manufacturing steps of a light-emitting device having an anode (ITO)/hole injection layer (80 nm)/hole transport layer (100 nm)/light-emitting layer (82% (mass ratio) of first host material: 15% (mass ratio) of second host material: 3% of third compound) (60 nm)/electron transport layer (25 nm)/cathode (LiQ (1 nm)/Al (150 nm) are as follows:
a. Cleaning of conductive glass substrate: subjecting a conductive glass substrate to ultrasonic treatment by using an aqueous solution of 5% Decon90 cleaning solution for 30 minutes, followed by ultrasonic cleaning with deionized water for several times, and then ultrasonic cleaning with isopropyl alcohol. After blow-drying with nitrogen, and treating the conductive glass substrate under oxygen plasma for 5 minutes to clean the ITO surface and improve a work function of the ITO electrode;
b. Preparation of a hole injection layer and a hole transport layer: PEDOT:PSS (Clevios™PEDOT:PSSA14083) is spin-coated on a glass substrate that has been treated with oxygen plasma to obtain a film of 80 nm. After the spin-coating is completed, annealing it in air at 150° C. for 20 minutes, followed by spin-coating on the PEDOT:PSS layer to obtain a poly-TFB film (CAS: 223569-31-1, commercially available from Lumtec.Corp; 5 mg/mL toluene solution) of 20 nm, followed by treating on a hot plate at 180° C. for 60 minutes;
c. Preparation of a light-emitting layer: dissolving a composition and a third compound in xylene to obtain a solution with a total concentration of 20 mg/mL, wherein the composition is a host material and consists of a first compound and a second compound, and the third compound is a guest material. Then spin-coating the solution in a nitrogen glove box to obtain a film of 60 nm, followed by annealing at 120° C. for 10 minutes;
d, Preparation of an electron transport layer, an electron injection layer, and a cathode: placing the spin-coated device into a vacuum evaporation chamber, and sequentially evaporating an ETL material of 25 nm, LiQ of 1 nm, and aluminum of 150 nm to obtain a light-emitting device; and
e. Encapsulation: the device is encapsulated in a nitrogen glove box with an ultraviolet curing resin and a glass cover plate.

In this example, the light-emitting device 1 to light-emitting device 15 are formed by using the first compound as the first host material, the second compound as the second host material, and BD1 as the guest material; comparative devices 1 and 2 are formed by using only the first compound or the second compound as the first host material; the light-emitting device 16 to light-emitting device 30 are formed by using the first compound as the first compound, the second compound as the second host material, and BD2 as the guest material; and comparative devices 3 and 4 are formed by using only the first compound or the second compound as the first host material.

The structural formula of BD1 is:

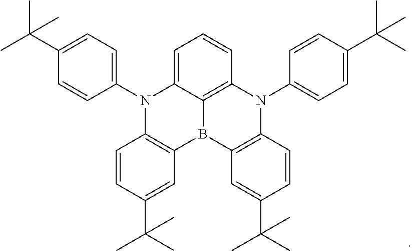 [SMILES: CC(C)(C)c1ccc(N2c3ccc(C(C)(C)C)cc3B3c4cc(C(C)(C)C)ccc4N(c4ccc(C(C)(C)C)cc4)c4cccc2c43)cc1]

The structural formula of BD2 is:

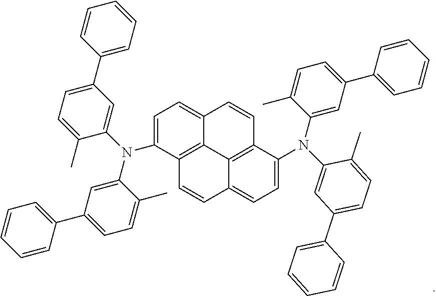 [SMILES: Cc1ccc(-c2ccccc2)cc1N(c1cc(-c2ccccc2)ccc1C)c1ccc2ccc3c(N(c4cc(-c5ccccc5)ccc4C)c4cc(-c5ccccc5)ccc4C)ccc4ccc1c2c43]

In the light-emitting device 1 to light-emitting device 30, and comparative device 1 to comparative device 4, the structural formula of the material of the electron transport layer is as follows:

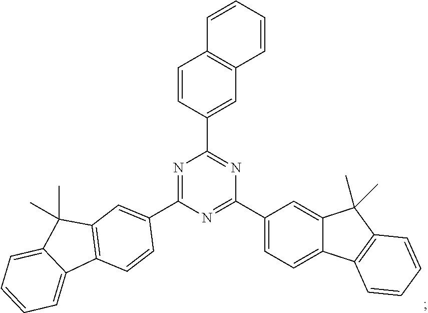 [SMILES: CC1(C)c2ccccc2-c2ccc(-c3nc(-c4ccc5c(c4)C(C)(C)c4ccccc4-5)nc(-c4ccc5ccccc5c4)n3)cc21]

and
the structural formula of LiQ is:

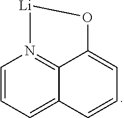

In this example, the external quantum efficiency (EQE) and the luminous lifetime (T90@1000 nits, which refers to the time for the device to be tested to decay from 1000 nits to 900 nits) tests are performed on the light-emitting device 1 to light-emitting device 20 and the comparative device 1 to comparative device 4. The results are shown in table 3 and table 4, respectively.

TABLE 3
Performance data of light-emitting device 1 to light-emitting
device 15 and comparative device 1 to comparative device 2

| | | | | T90@ |
|---|---|---|---|---|
| | First | Second | | 1000 |
| OLED devices | compounds | compounds | EQE | nits |
| Light-emitting element 1 | M1 | M17 | 1.62 | 1.67 |
| Light-emitting element 2 | M2 | M17 | 1.70 | 1.75 |
| Light-emitting element 3 | M2 | M18 | 1.67 | 1.72 |
| Light-emitting element 4 | M2 | M22 | 1.69 | 1.73 |
| Light-emitting element 5 | M3 | M25 | 1.61 | 1.65 |
| Light-emitting element 6 | M5 | M17 | 1.73 | 1.79 |
| Light-emitting element 7 | M5 | M22 | 1.72 | 1.77 |
| Light-emitting element 8 | M6 | M27 | 1.58 | 1.62 |
| Light-emitting element 9 | M8 | M29 | 1.59 | 1.64 |
| Light-emitting element 10 | M10 | M17 | 1.77 | 1.83 |
| Light-emitting element 11 | M10 | M21 | 1.76 | 1.82 |
| Light-emitting element 12 | M10 | M22 | 1.74 | 1.80 |
| Light-emitting element 13 | M11 | M18 | 1.66 | 1.70 |
| Light-emitting element 14 | M11 | M26 | 1.64 | 1.68 |
| Light-emitting element 15 | M15 | M30 | 1.56 | 1.60 |
| Comparative element 1 | M1 | | 1.1 | 1.2 |
| Comparative element 2 | | M17 | 1 | 1 |

TABLE 4
Performance data of light-emitting device 16 to light-emitting
device 30 and comparative device 3 to comparative device 4

| | First | Second | | |
|---|---|---|---|---|
| | com- | com- | | T90@1000 |
| OLED devices | pounds | pounds | EQE | nits |
| Light-emitting element 16 | M1 | M17 | 1.54 | 1.60 |
| Light-emitting element 17 | M2 | M17 | 1.62 | 1.68 |
| Light-emitting element 18 | M2 | M18 | 1.59 | 1.65 |
| Light-emitting element 19 | M2 | M22 | 1.62 | 1.65 |
| Light-emitting element 20 | M3 | M25 | 1.53 | 1.57 |
| Light-emitting element 21 | M5 | M17 | 1.65 | 1.72 |
| Light-emitting element 22 | M5 | M22 | 1.64 | 1.70 |
| Light-emitting element 23 | M6 | M27 | 1.50 | 1.55 |
| Light-emitting element 24 | M8 | M29 | 1.51 | 1.56 |
| Light-emitting element 25 | M10 | M17 | 1.69 | 1.76 |
| Light-emitting element 26 | M10 | M21 | 1.68 | 1.74 |
| Light-emitting element 27 | M10 | M22 | 1.66 | 1.72 |
| Light-emitting element 28 | M11 | M18 | 1.58 | 1.63 |
| Light-emitting element 29 | M11 | M26 | 1.56 | 1.61 |
| Light-emitting element 30 | M15 | M30 | 1.48 | 1.53 |
| Comparative element 3 | M1 | | 1.1 | 1.2 |
| Comparative element 4 | | M17 | 1 | 1 |

As can be seen from the data in table 3 and table 4 that the external quantum efficiencies of the light-emitting device 1 to light-emitting device 15 and the light-emitting device 16 to light-emitting device 30 are significantly improved and the luminous lifetimes thereof are also effectively prolonged in case that the external quantum efficiencies and the luminous lifetimes of comparative devices 2 and 4 are taken as reference value 1. It shows that the composition of the first compound and the second compound enhances the resonance effects and the space effects of the organic compounds, improves the charge balance and the energy transmission in the light-emitting devices, improves the luminous efficiency of the light-emitting devices, and prolongs the luminous lifetime of the light-emitting devices.

According to the light-emitting devices of the present disclosure, the charge balance and energy transmission in the light-emitting devices are improved, and the luminous efficiency and luminous lifetime of the light-emitting device are also improved by using a composition formed by a first compound having a structure represented by formula (1) and a second compound having a structure represented by formula (2).

Embodiments of the present disclosure further discloses a display panel including the light-emitting devices as described above.

The display panel further includes an array substrate disposed on one side of the light-emitting device, and an encapsulation layer disposed on one side of the light-emitting device away from the array substrate and covering the light-emitting device.

The display panel further includes a polarizer layer on one side of the encapsulation layer away from the light-emitting device and a cover plate layer on one side of the polarizer layer away from the light-emitting device. The polarizer layer may be replaced by a color film layer, and the color film layer may include a plurality of color resistors and a black matrix located on both sides of the color resistors.

According to the display panels of the present disclosure, the charge balance and energy transmission in the light-emitting devices are improved, and the luminous efficiency and luminous lifetime of the light-emitting device are also improved by using a composition formed by a first compound having a structure represented by formula (1) and a second compound having a structure represented by formula (2).

Embodiments of the present disclosure disclose a composition, a mixture, a light-emitting device and a display panel. The composition includes at least one first compound having a structure represented by formula (1):

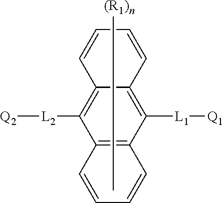

(1), and at least one second compound having a structure represented by formula (2):

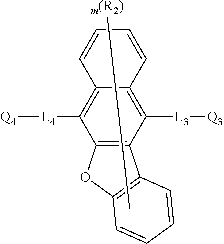

(2). By using a composition formed by a first compound having a structure represented by formula (1) and a second compound having a structure represented by formula (2) of the present disclosure, the charge balance and energy transmission in the light-emitting devices are improved, and the luminous efficiency and luminous lifetime of the light-emitting device are also improved.

In view of the foregoing, the composition, the mixture, the light-emitting device, and the display panel and display device provided in examples of the present disclosure have been described in detail above, and the principles and embodiments of the present disclosure are described by using specific examples herein. Descriptions of the above examples are merely intended to help understand the technical solutions and core ideas of the present disclosure. At the same time, for those skilled in the art, according to the idea of the present disclosure, there will be changes in the specific implementation and application scopes. To sum up, the contents of the specification should not be understood as limiting the present disclosure.

1. A composition comprising at least one first compound and at least one second compound;
the first compound has a structure represented by formula (1): 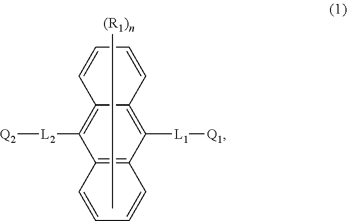
the second compound has a structure represented by formula (2): 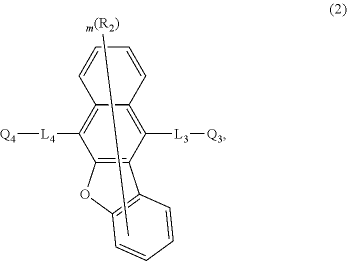
wherein L₁, L₂, L₃ and L₄ are each independently selected from a single bond, a substituted or unsubstituted aromatic group having 6 to 30 ring atoms, or a substituted or unsubstituted heteroaromatic group having 5 to 30 ring atoms;
Q₁, Q₂, Q₃ and Q₄ are each independently selected from a substituted or unsubstituted alkyl group having 1 to 20 carbon atoms, a substituted or unsubstituted aromatic group having 6 to 60 ring atoms, or a substituted or unsubstituted heteroaromatic group having 5 to 60 ring atoms, or a combination thereof,
R₁ and R₂ are each independently selected from hydrogen, deuterium, a substituted or unsubstituted alkyl group having 1 to 10 carbon atoms, a substituted or unsubstituted aromatic group having 6 to 30 ring atoms, or a substituted or unsubstituted heteroaromatic group having 5 to 30 ring atoms; and
n and m are each independently selected from any one integer from 0 to 8.

2. The composition according to claim 1, wherein Q₁, Q₂, Q₃ and Q₄ are each independently selected from a substituted or unsubstituted alkyl group having 1 to 10 carbon atoms, a substituted or unsubstituted aromatic group having 6 to 30 ring atoms, a substituted or unsubstituted heteroaromatic group having 5 to 30 ring atoms, or a combination thereof.

3. The composition according to claim 2, wherein Q₁ and Q₂ are each independently selected from a structure represented by any one of formulae (A-1) to (A-4): 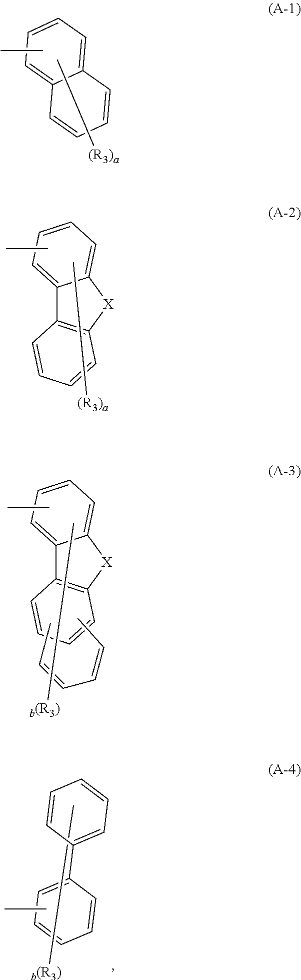
wherein X is selected from CR₄R₅, NR₆, O or S;
R₃, R₄, R₅ and R₆ are each independently selected from hydrogen, deuterium, a substituted or unsubstituted alkyl group having 1 to 10 carbon atoms, a substituted or unsubstituted aromatic group having 6 to 30 ring atoms, or a substituted or unsubstituted heteroaromatic group having 5 to 30 ring atoms, two adjacent R₃ form a ring or not, and R₄, R₅ form a ring or not;
a is selected from any one integer from 0 to 7;
b is selected from any one integer from 0 to 9; and
* indicates a linkage site.

4. The composition according to claim 3, wherein Q₁ and Q₂ are each independently selected from a structure represented by any one of formulae (B-1) to (B-2), (C-1) to (C-4) and (D-1) to (D-12):

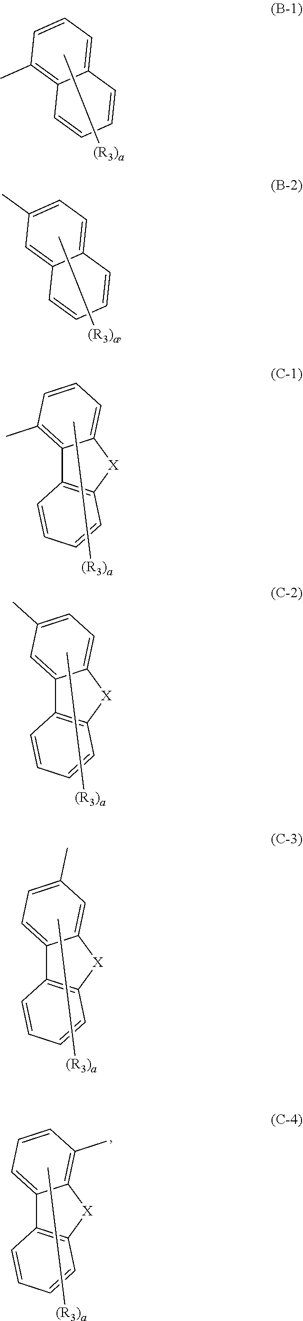

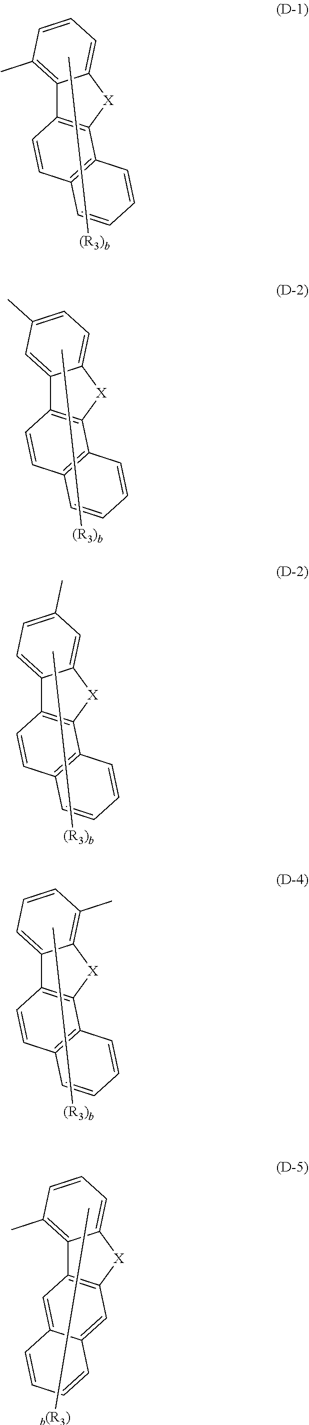

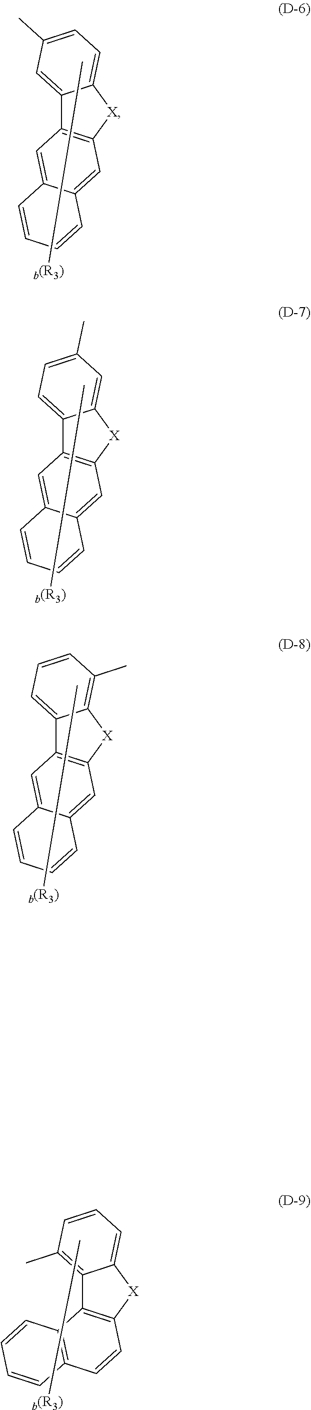

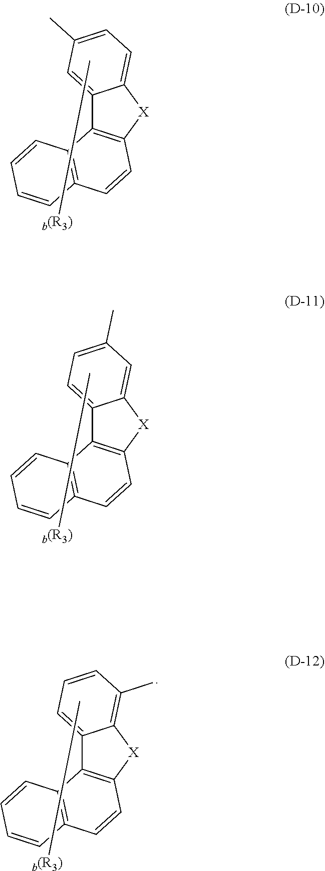

5. The composition according to claim 2, wherein Q₃ and Q₄ are each independently selected from a structure represented by any one of formulae (E-1) to (E-3): 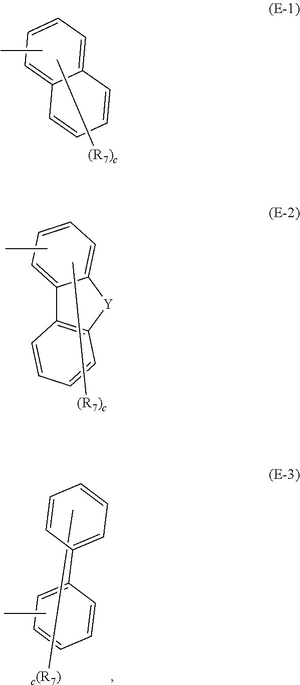
wherein Y is selected from CR₈R₉, NR₁₀, O or S;
R₇, R₈, R₉ and R₁₀ are each independently selected from hydrogen, deuterium, a substituted or unsubstituted alkyl group having 1 to 10 carbon atoms, a substituted or unsubstituted aromatic group having 6 to 30 ring atoms, or a substituted or unsubstituted heteroaromatic group having 5 to 30 ring atoms, and two adjacent R₇ form a ring or not; and
c is selected from any integer from 0 to 9.

6. The composition according to claim 5, wherein Q₃ and Q₄ are each independently selected from a structure represented by any one of formulae (F-1) to (F-2) and (G-1) to (G-4):

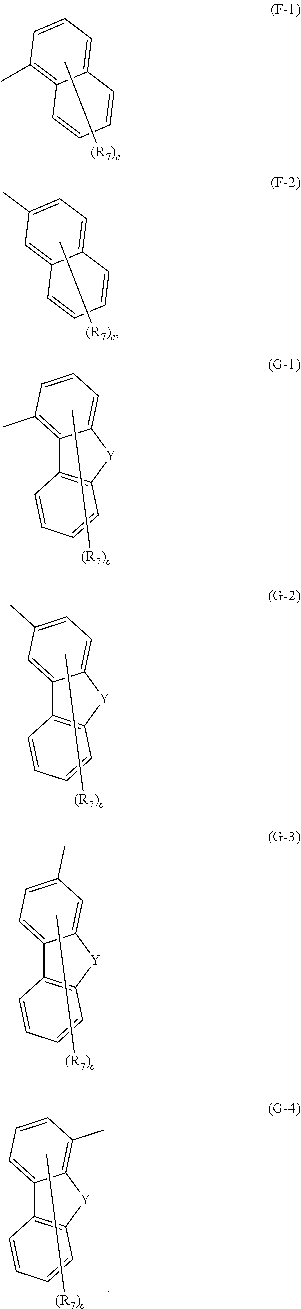

7. The composition according to claim 1, wherein the first compound has a structure represented by any one of formulae (1-1) to (1-3): 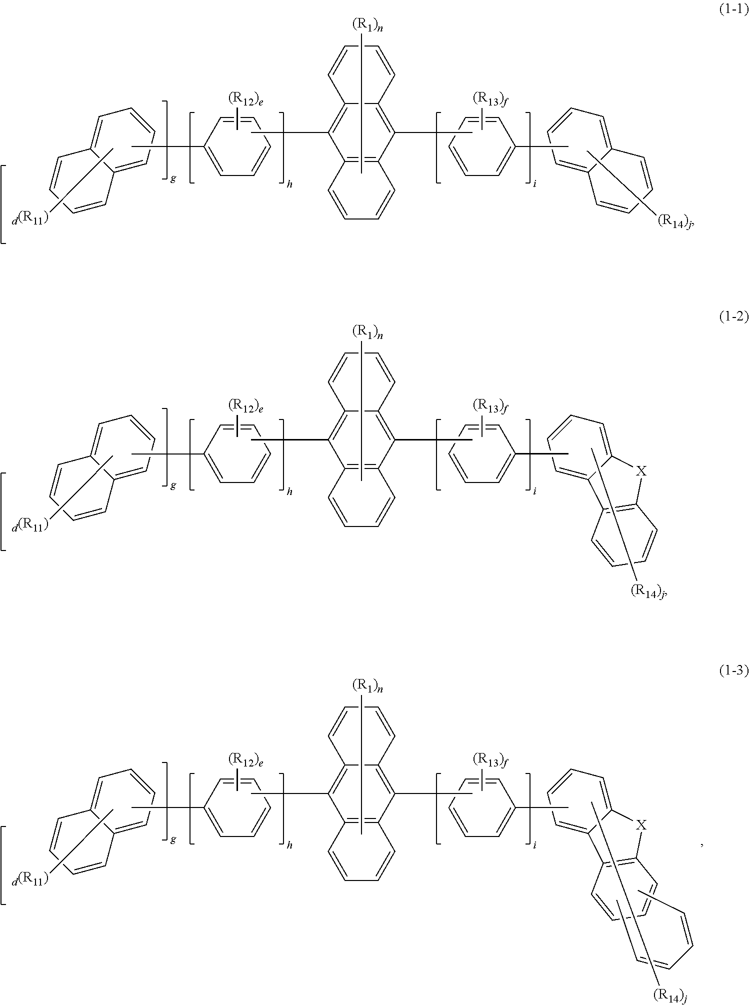
the second compound has a structure represented by any one of formulae (2-1) to (2-3): 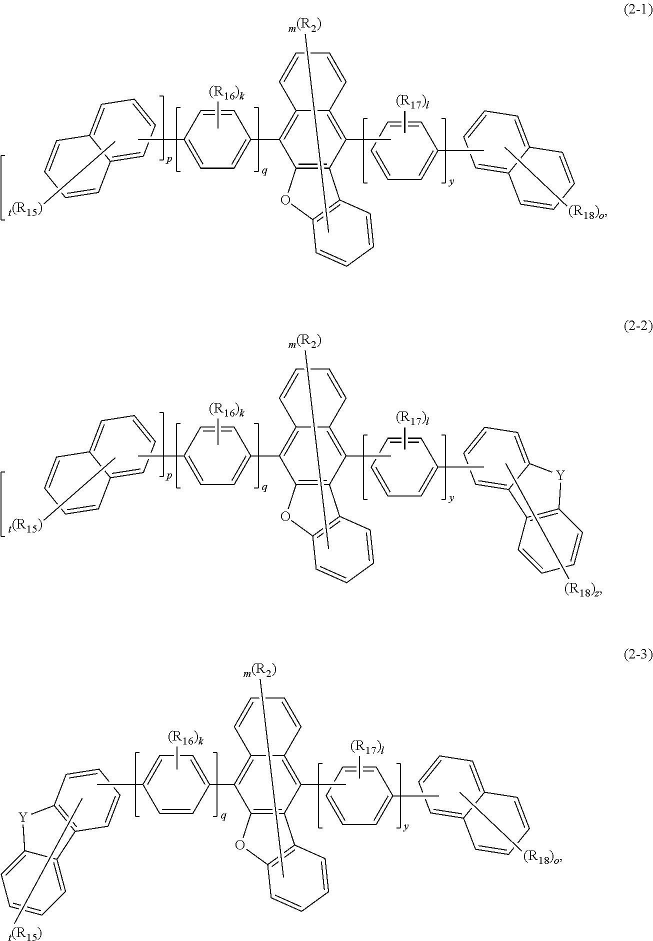
wherein R₁₁, R₁₂, R₁₃, R₁₄, R₁₅, R₁₆, R₁₇ and R₁₈ are each independently selected from hydrogen, deuterium, a substituted or unsubstituted alkyl group having 1 to 10 carbon atoms, a substituted or unsubstituted aromatic group having 6 to 30 ring atoms or a substituted or unsubstituted heteroaromatic group having 5 to 30 ring atoms, two adjacent R₁₁ form a ring or not, two adjacent R₁₂ form a ring or not, two adjacent R₁₃ form a ring or not, two adjacent R₁₄ form a ring or not, two adjacent R₁₅ form a ring or not, two adjacent R₁₆ form a ring or not, two adjacent R₁₇ form a ring or not, and two adjacent R₁₈ form a ring or not;
d, j, t, o and z are each independently selected from any one integer from 0 to 7;
e, f, k and 1 are each independently selected from any one integer from 0 to 4;
g and p are each independently selected from 0 or 1;
h, i, q and y are each independently selected from any integer from 0 to 3, a sum of g and h is greater than or equal to 1, and a sum of p and q is greater than or equal to 1.

8. The composition according to claim 2, wherein the first compound has a structure represented by any one of formulae (1-1) to (1-3): 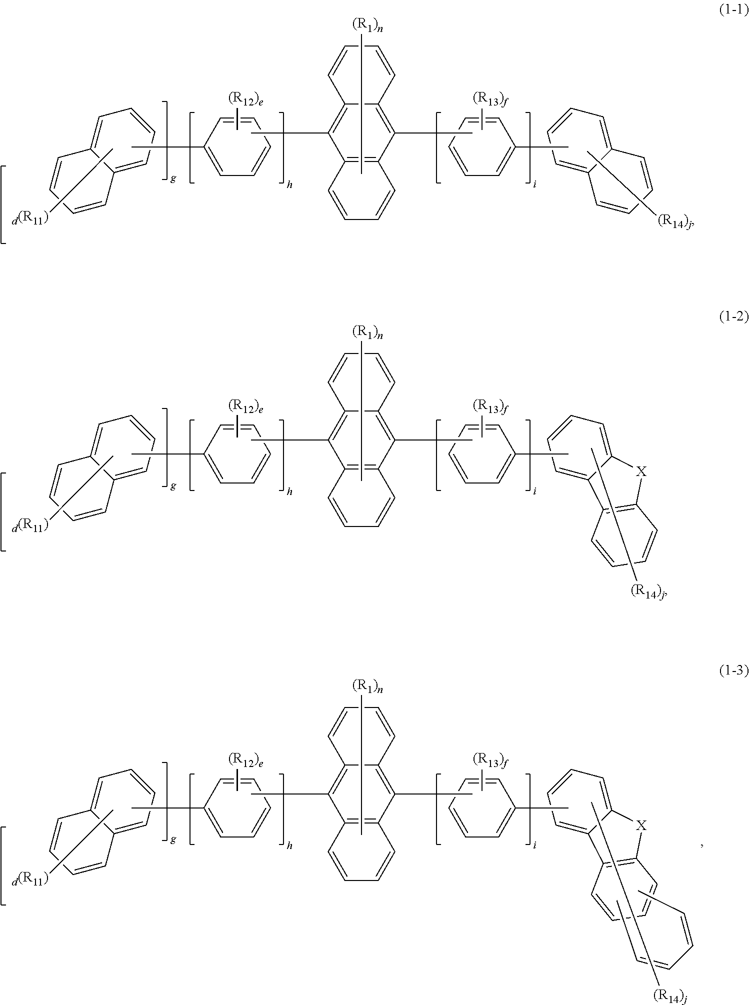
the second compound has a structure represented by any one of formulae (2-1) to (2-3): 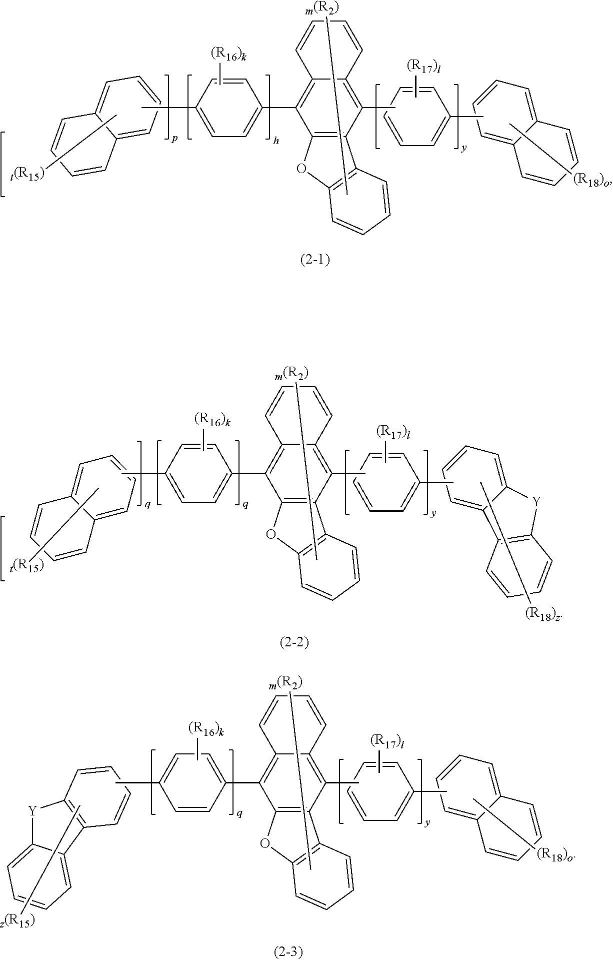
wherein R₁₁, R₁₂, R₁₃, R₁₄, R₁₅, R₁₆, R₁₇ and R₁₈ are each independently selected from hydrogen, deuterium, a substituted or unsubstituted alkyl group having 1 to 10 carbon atoms, a substituted or unsubstituted aromatic group having 6 to 30 ring atoms or a substituted or unsubstituted heteroaromatic group having 5 to 30 ring atoms, two adjacent R₁₁ form a ring or not, two adjacent R₁₂ form a ring or not, two adjacent R₁₃ form a ring or not, two adjacent R₁₄ form a ring or not, two adjacent R₁₅ form a ring or not, two adjacent R₁₆ form a ring or not, two adjacent R₁₇ form a ring or not, and two adjacent R₁₈ form a ring or not;
d, j, t, o and z are each independently selected from any one integer from 0 to 7;
e, f, k and 1 are each independently selected from any one integer from 0 to 4;
g and p are each independently selected from 0 or 1;
h, i, q and y are each independently selected from any integer from 0 to 3, a sum of g and h is greater than or equal to 1, and a sum of p and q is greater than or equal to 1.

9. The composition according to claim 3, wherein the first compound has a structure represented by any one of formulae (1-1) to (1-3): 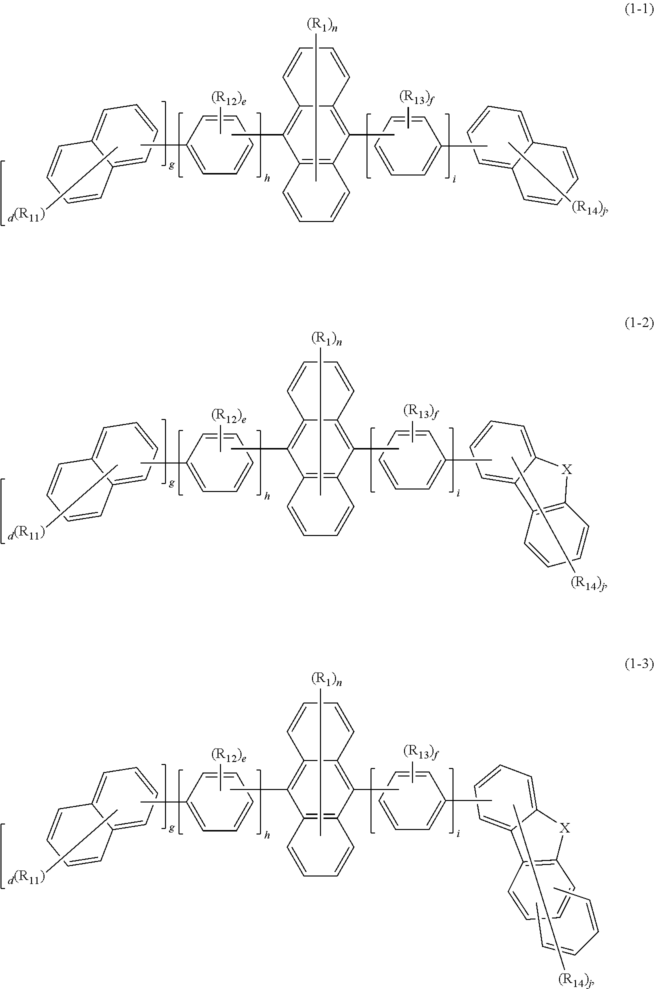
the second compound has a structure represented by any one of formulae (2-1) to (2-3): 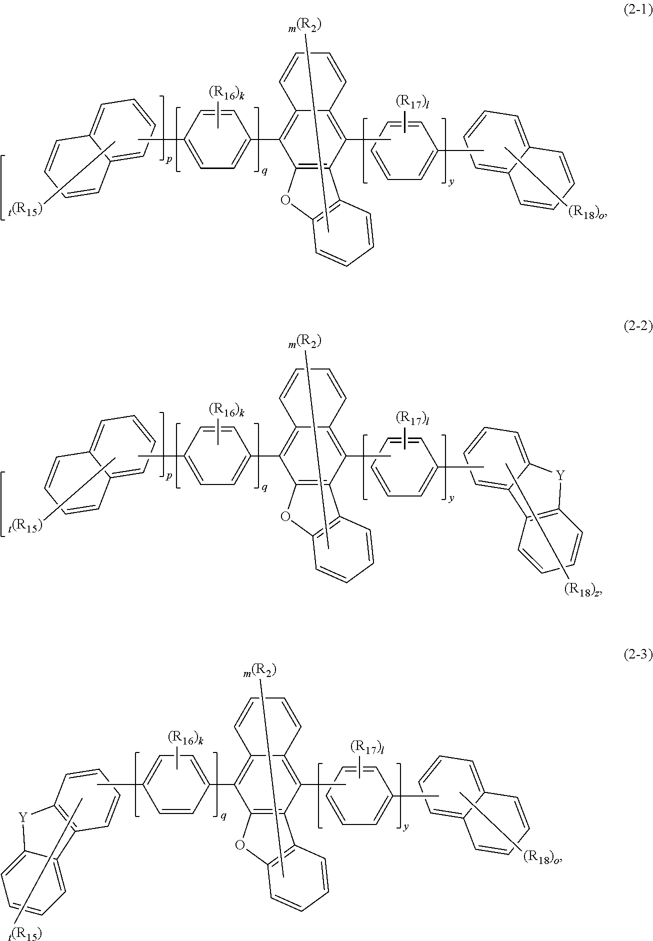
wherein R₁₁, R₁₂, R₁₃, R₁₄, R₁₅, R₁₆, R₁₇ and R₁₈ are each independently selected from hydrogen, deuterium, a substituted or unsubstituted alkyl group having 1 to 10 carbon atoms, a substituted or unsubstituted aromatic group having 6 to 30 ring atoms or a substituted or unsubstituted heteroaromatic group having 5 to 30 ring atoms, two adjacent R₁₁ form a ring or not, two adjacent R₁₂ form a ring or not, two adjacent R₁₃ form a ring or not, two adjacent R₁₄ form a ring or not, two adjacent R₁₅ form a ring or not, two adjacent R₁₆ form a ring or not, two adjacent R₁₇ form a ring or not, and two adjacent R₁₈ form a ring or not;
d, j, t, o and z are each independently selected from any one integer from 0 to 7;
e, f, k and 1 are each independently selected from any one integer from 0 to 4;
g and p are each independently selected from 0 or 1;
h, i, q and y are each independently selected from any integer from 0 to 3, a sum of g and h is greater than or equal to 1, and a sum of p and q is greater than or equal to 1.

10. The composition according to claim 4, wherein the first compound has a structure represented by any one of formulae (1-1) to (1-3): 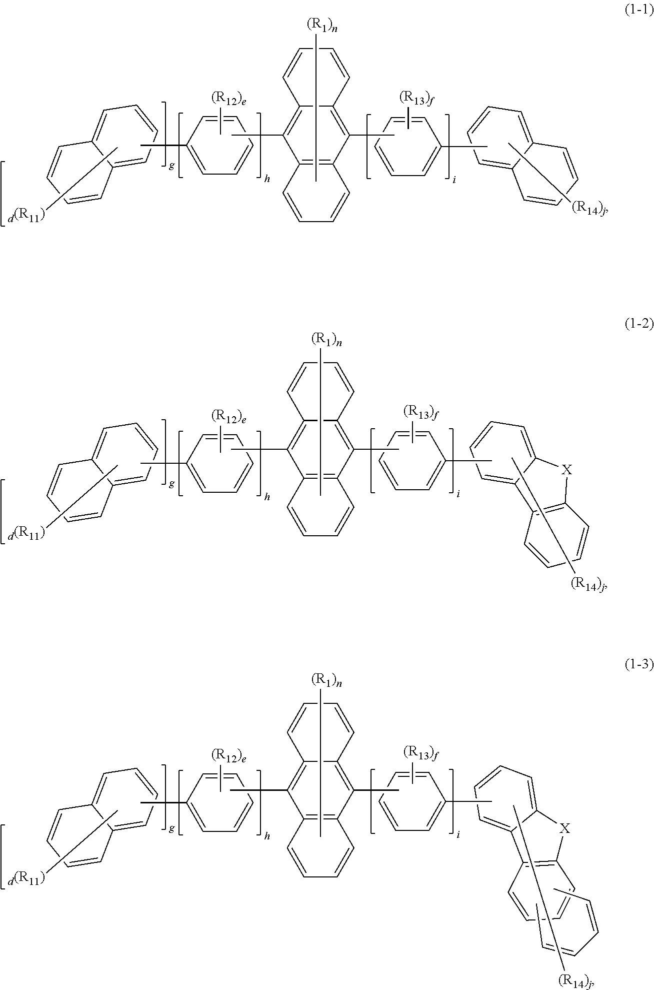
the second compound has a structure represented by any one of formulae (2-1) to (2-3): 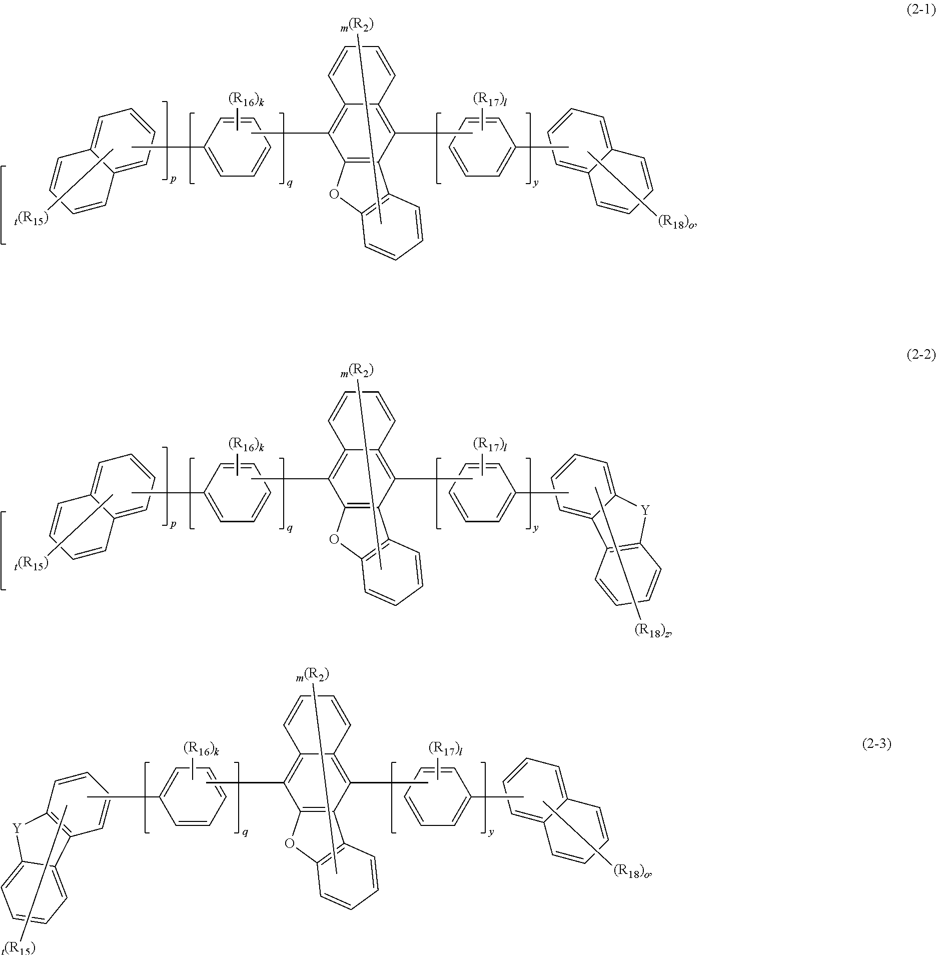
wherein R₁₁, R₁₂, R₁₃, R₁₄, R₁₅, R₁₆, R₁₇ and R₁₈ are each independently selected from hydrogen, deuterium, a substituted or unsubstituted alkyl group having 1 to 10 carbon atoms, a substituted or unsubstituted aromatic group having 6 to 30 ring atoms or a substituted or unsubstituted heteroaromatic group having 5 to 30 ring atoms, two adjacent R₁₁ form a ring or not, two adjacent R₁₂ form a ring or not, two adjacent R₁₃ form a ring or not, two adjacent R₁₄ form a ring or not, two adjacent R₁₅ form a ring or not, two adjacent R₁₆ form a ring or not, two adjacent R₁₇ form a ring or not, and two adjacent R₁₈ form a ring or not;
d, j, t, o and z are each independently selected from any one integer from 0 to 7;
e, f, k and 1 are each independently selected from any one integer from 0 to 4;
g and p are each independently selected from 0 or 1;
h, i, q and y are each independently selected from any integer from 0 to 3, a sum of g and h is greater than or equal to 1, and a sum of p and q is greater than or equal to 1.

11. The composition according to claim 1, wherein L₁, L₂, L₃ and L₄ are each independently selected from a single bond or phenyl.

12. The composition according to claim 1, wherein the first compound is selected from:

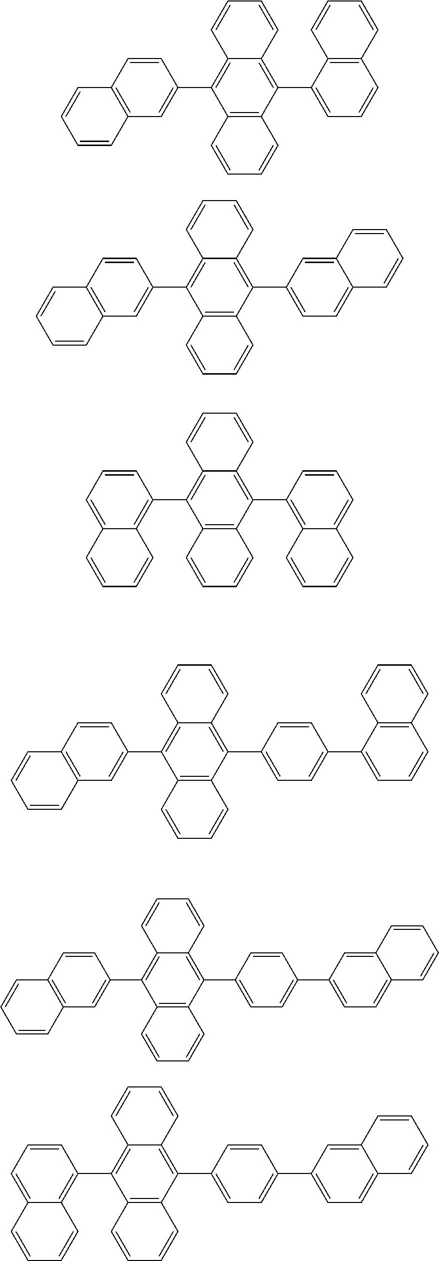

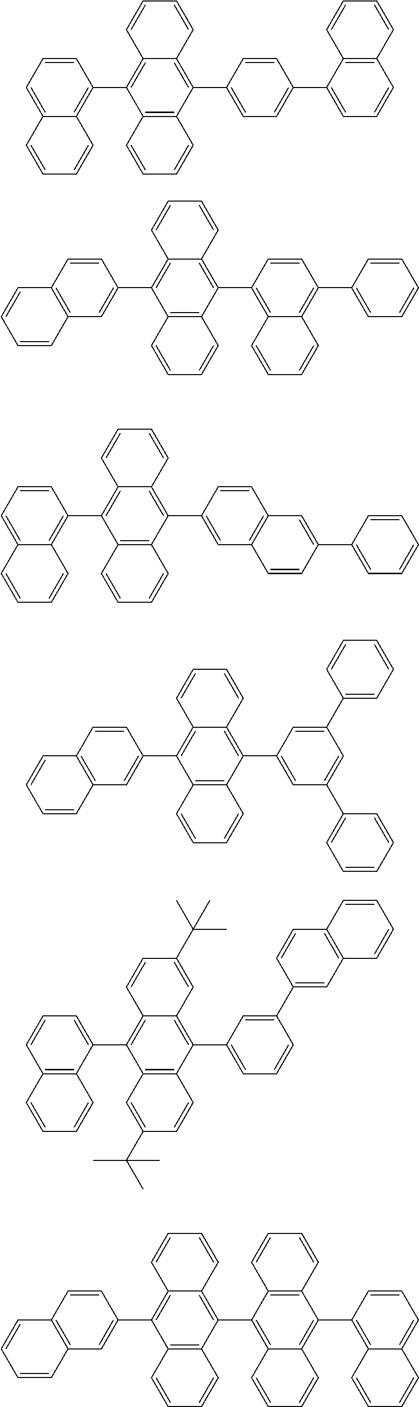

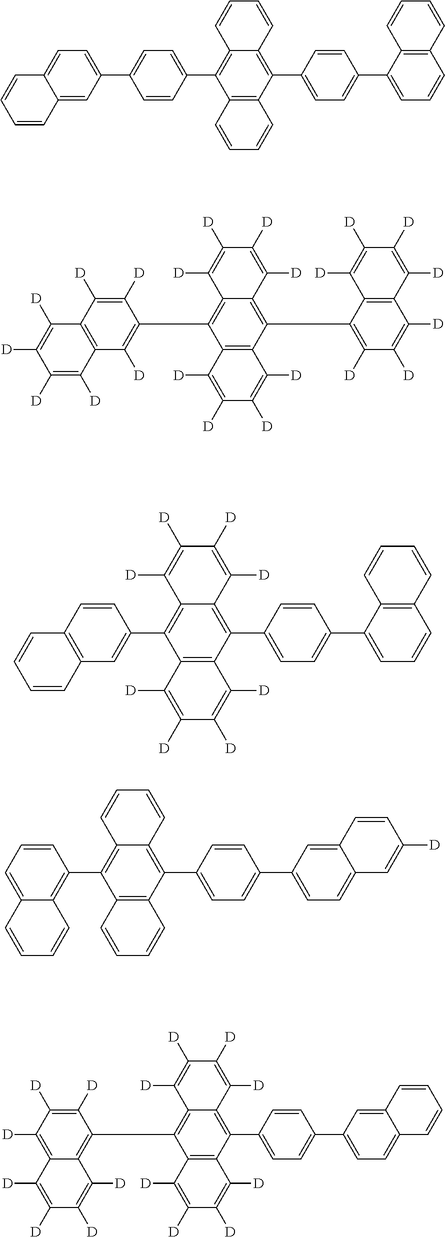

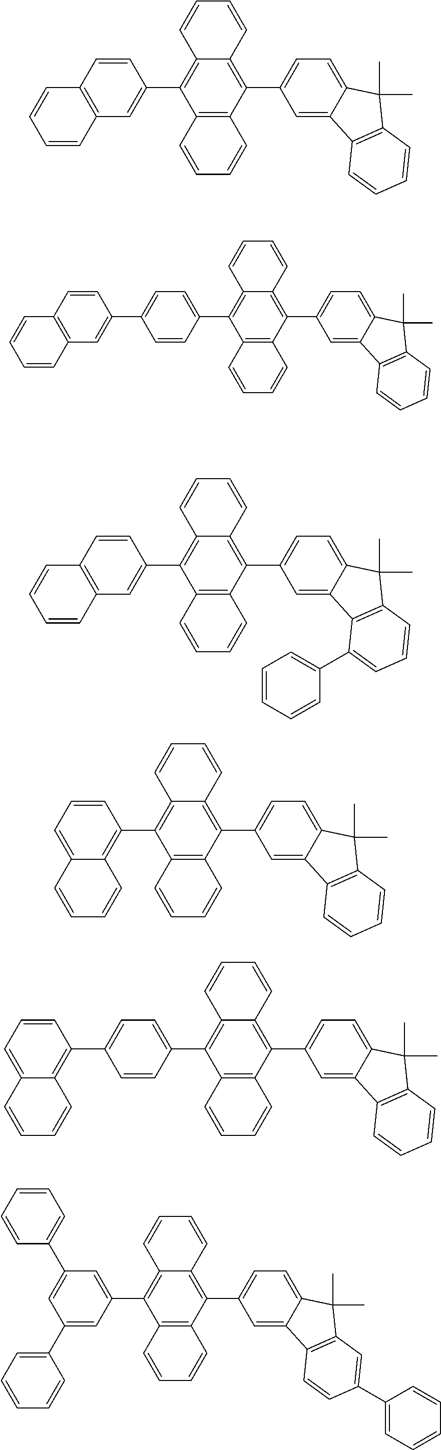

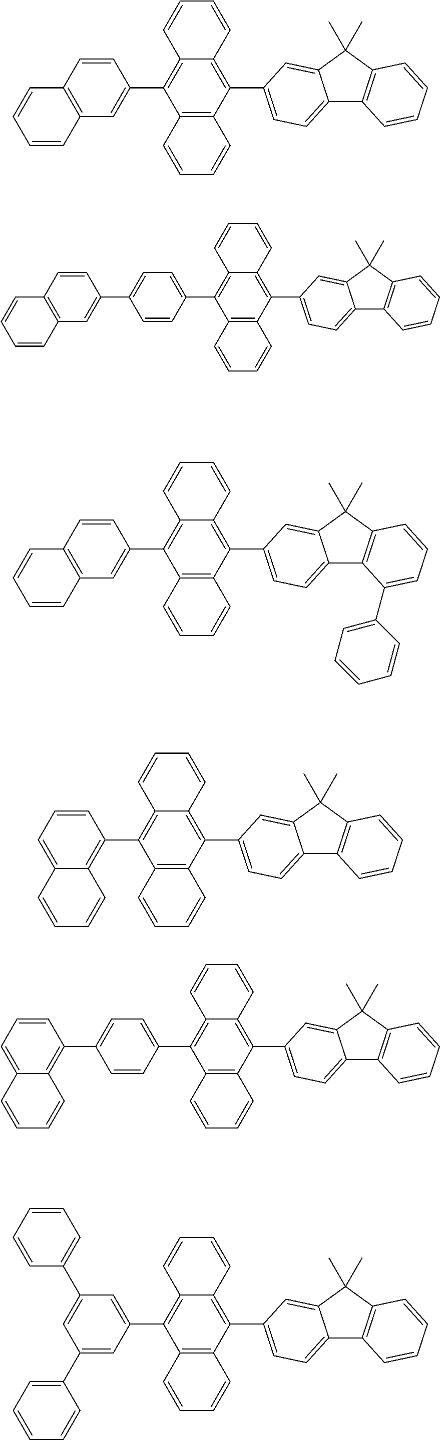

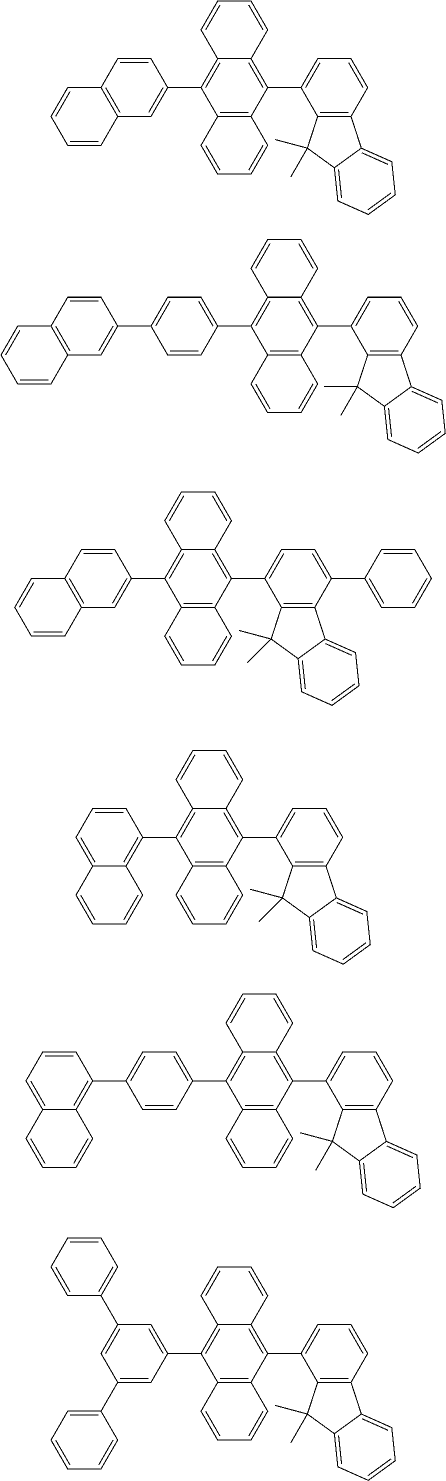

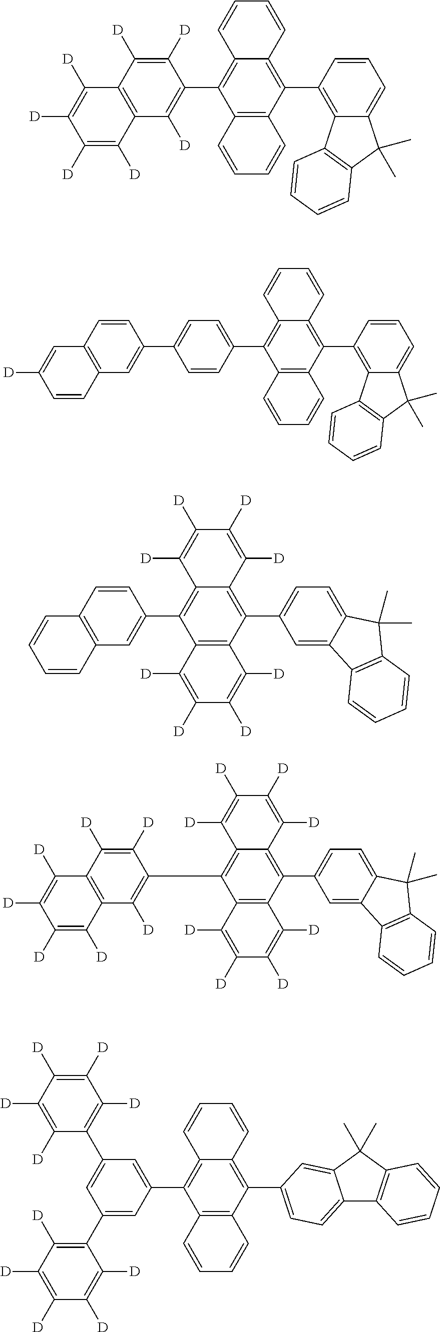

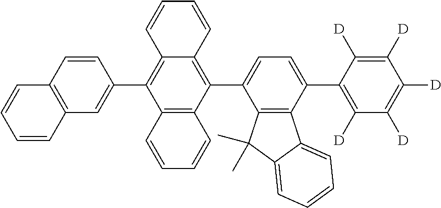 [SMILES: [2H]c1c([2H])c([2H])c(-c2ccc(-c3c4ccccc4c(-c4ccc5ccccc5c4)c4ccccc34)c3c2-c2ccccc2C3(C)C)c([2H])c1[2H]]

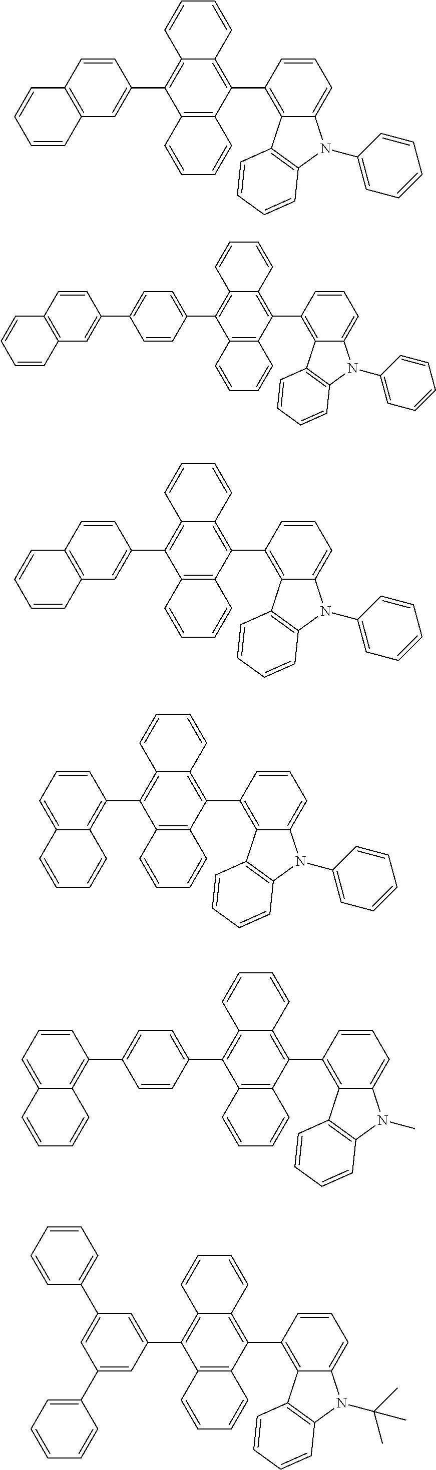

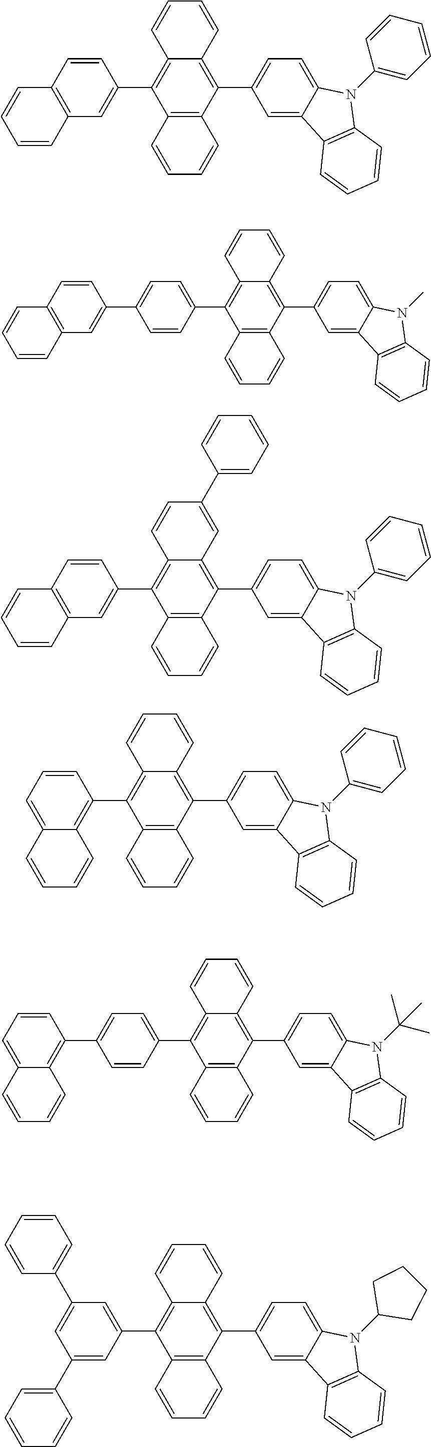

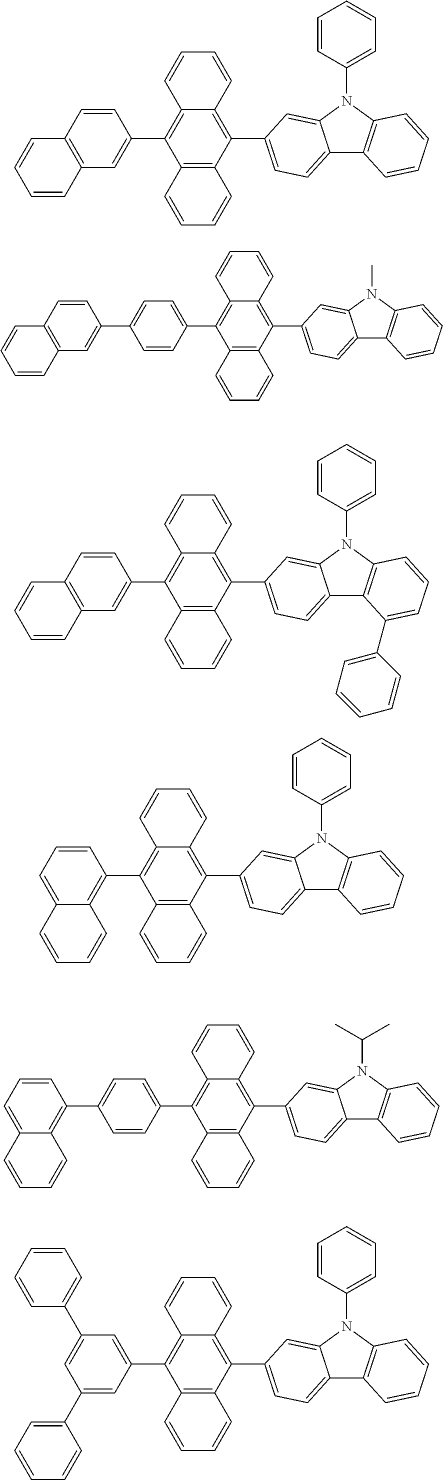

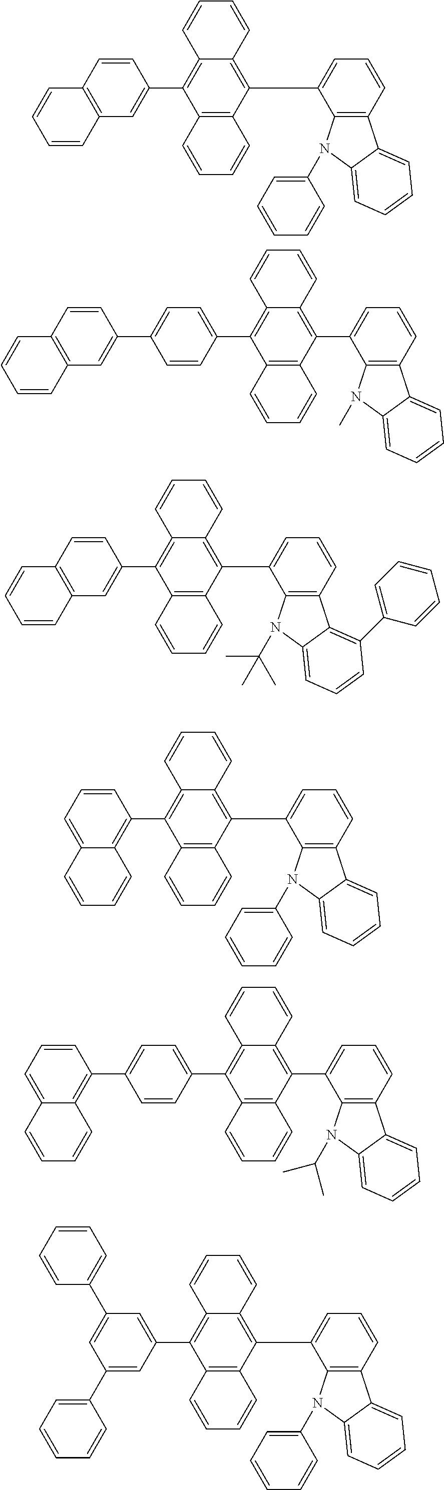

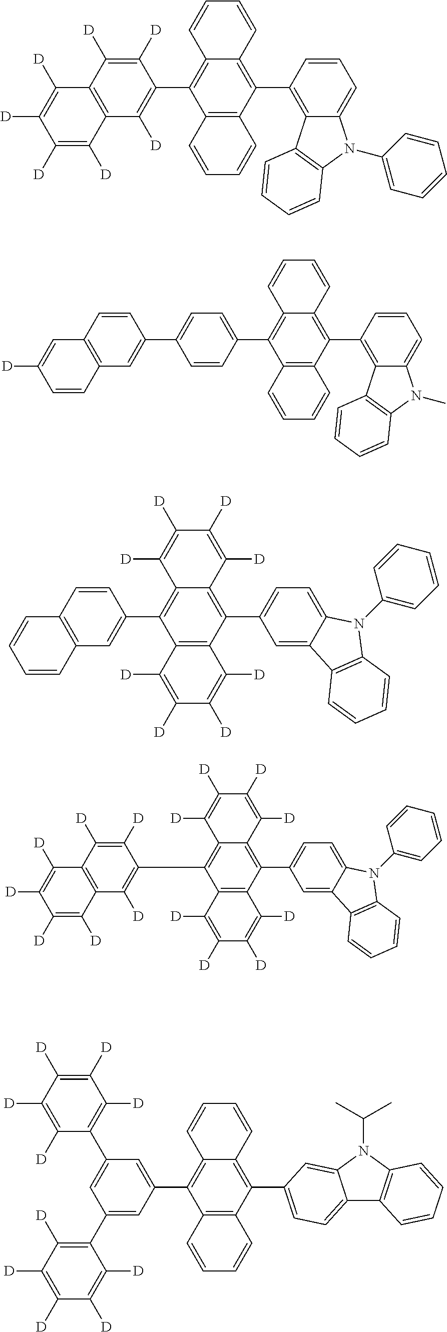

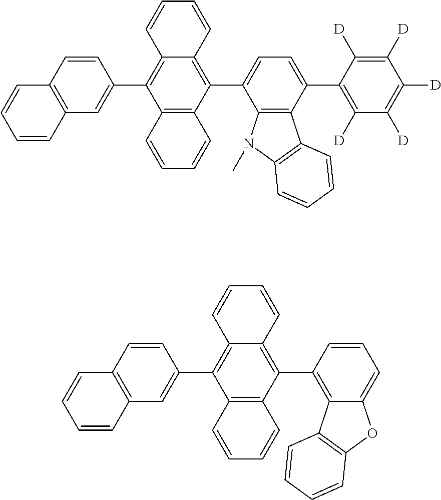 [SMILES: [2H]c1c([2H])c([2H])c(-c2ccc(-c3c4ccccc4c(-c4ccc5ccccc5c4)c4ccccc34)c3c2c2ccccc2n3C)c([2H])c1[2H] ; c1ccc2cc(-c3c4ccccc4c(-c4cccc5oc6ccccc6c45)c4ccccc34)ccc2c1]

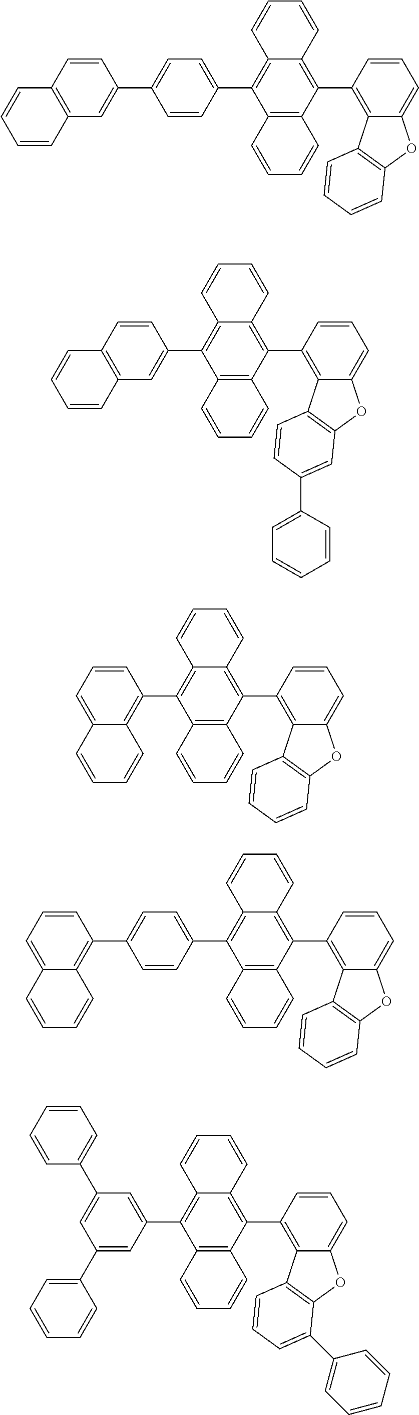

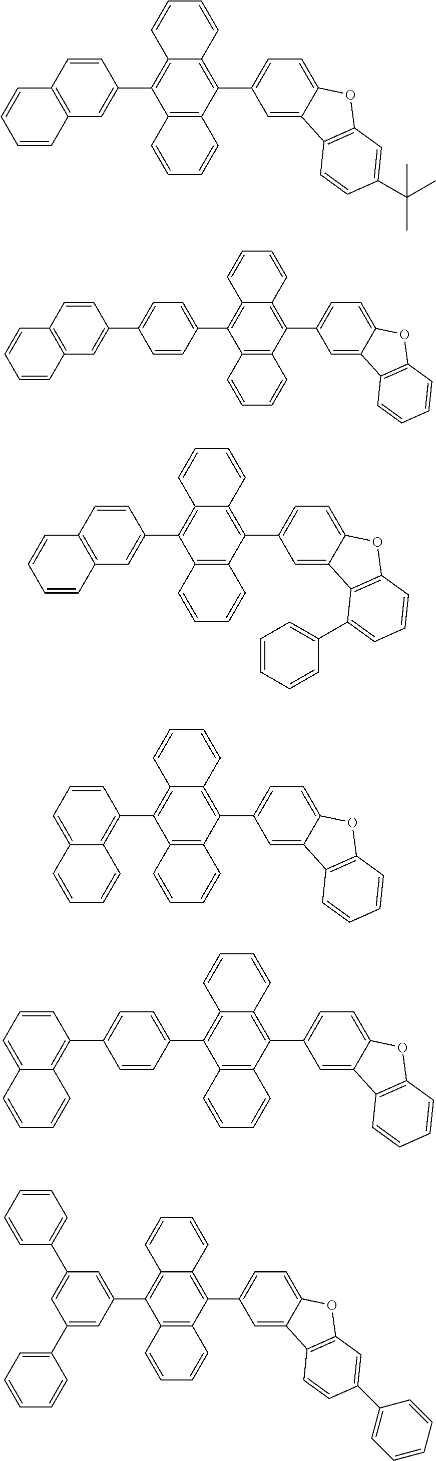

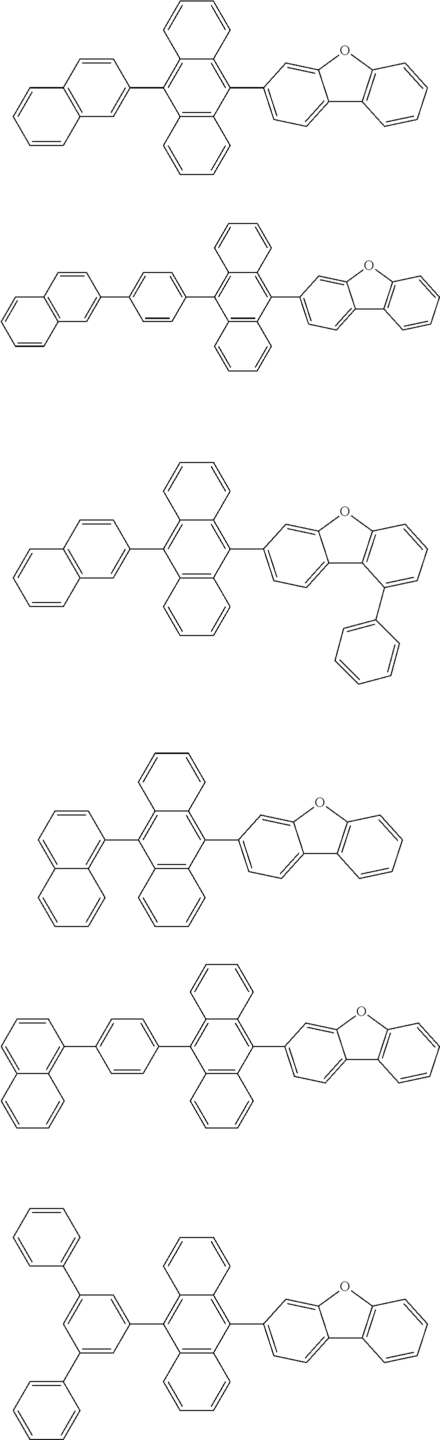

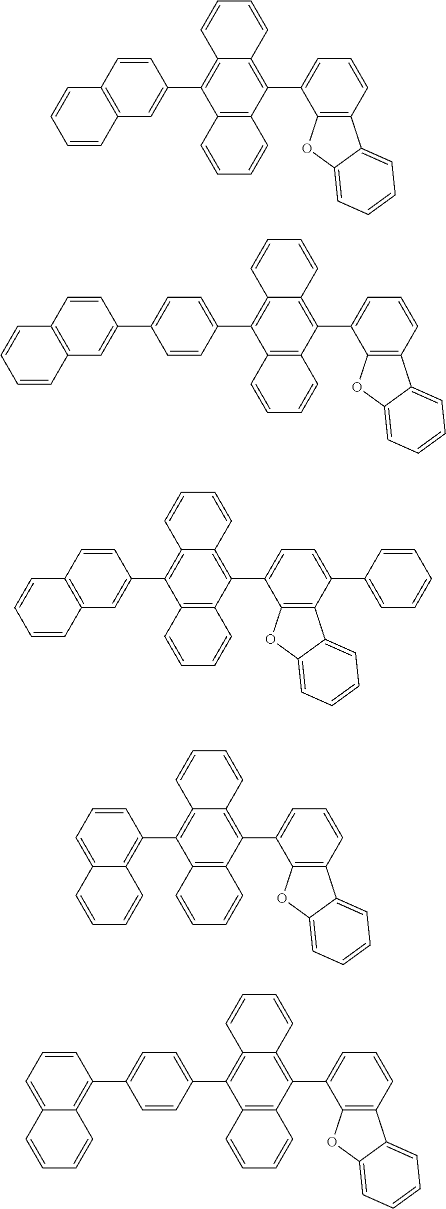 [SMILES: c1ccc2cc(-c3c4ccccc4c(-c4cccc5c4oc4ccccc45)c4ccccc34)ccc2c1 ; c1ccc2cc(-c3ccc(-c4c5ccccc5c(-c5cccc6c5oc5ccccc56)c5ccccc45)cc3)ccc2c1 ; c1ccc(-c2ccc(-c3c4ccccc4c(-c4ccc5ccccc5c4)c4ccccc34)c3oc4ccccc4c23)cc1 ; c1ccc2c(-c3c4ccccc4c(-c4cccc5c4oc4ccccc45)c4ccccc34)cccc2c1 ; c1ccc2c(-c3ccc(-c4c5ccccc5c(-c5cccc6c5oc5ccccc56)c5ccccc45)cc3)cccc2c1]

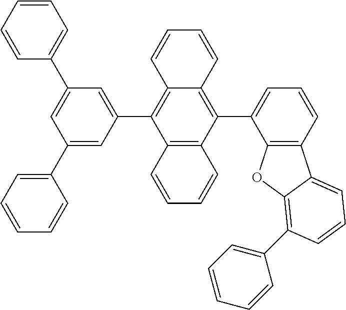 [SMILES: c1ccc(-c2cc(-c3ccccc3)cc(-c3c4ccccc4c(-c4cccc5c4oc4c(-c6ccccc6)cccc45)c4ccccc34)c2)cc1]

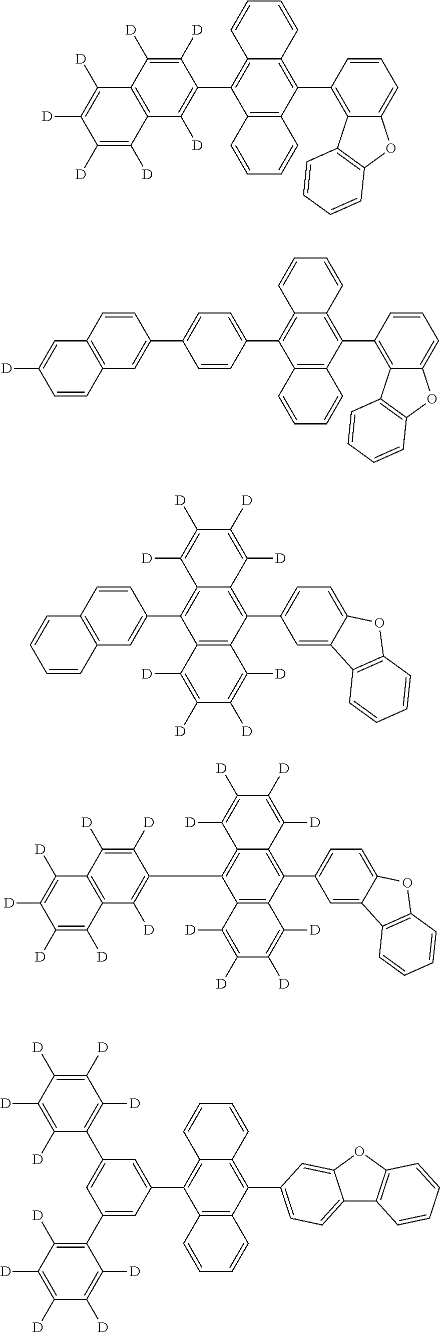

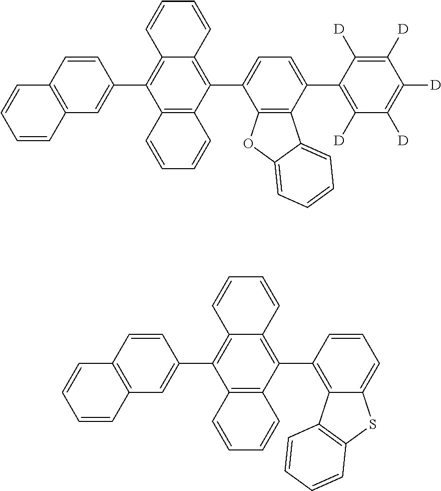 [SMILES: [2H]c1c([2H])c([2H])c(-c2ccc(-c3c4ccccc4c(-c4ccc5ccccc5c4)c4ccccc34)c3oc4ccccc4c23)c([2H])c1[2H] ; c1ccc2cc(-c3c4ccccc4c(-c4cccc5sc6ccccc6c45)c4ccccc34)ccc2c1]

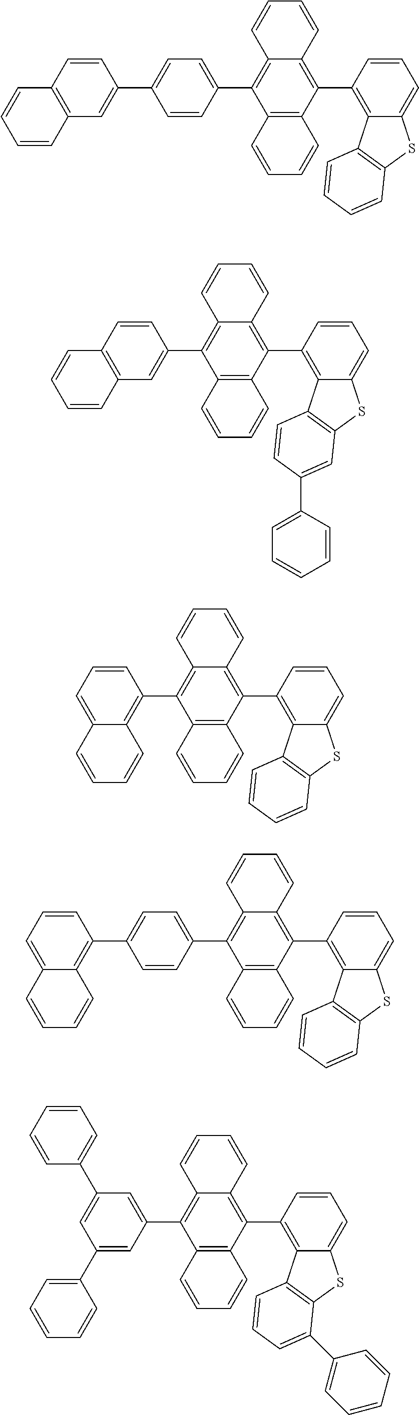

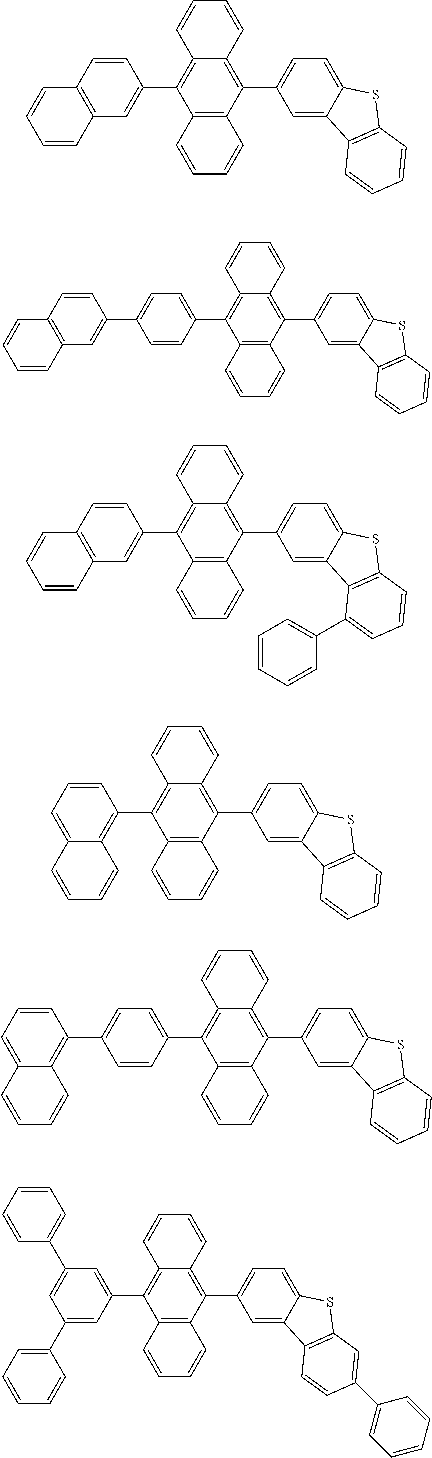 [SMILES: c1ccc2cc(-c3c4ccccc4c(-c4ccc5sc6ccccc6c5c4)c4ccccc34)ccc2c1 ; c1ccc2cc(-c3ccc(-c4c5ccccc5c(-c5ccc6sc7ccccc7c6c5)c5ccccc45)cc3)ccc2c1 ; c1ccc(-c2cccc3sc4ccc(-c5c6ccccc6c(-c6ccc7ccccc7c6)c6ccccc56)cc4c23)cc1 ; c1ccc2c(-c3c4ccccc4c(-c4ccc5sc6ccccc6c5c4)c4ccccc34)cccc2c1 ; c1ccc2c(-c3ccc(-c4c5ccccc5c(-c5ccc6sc7ccccc7c6c5)c5ccccc45)cc3)cccc2c1 ; c1ccc(-c2cc(-c3ccccc3)cc(-c3c4ccccc4c(-c4ccc5sc6cc(-c7ccccc7)ccc6c5c4)c4ccccc34)c2)cc1]

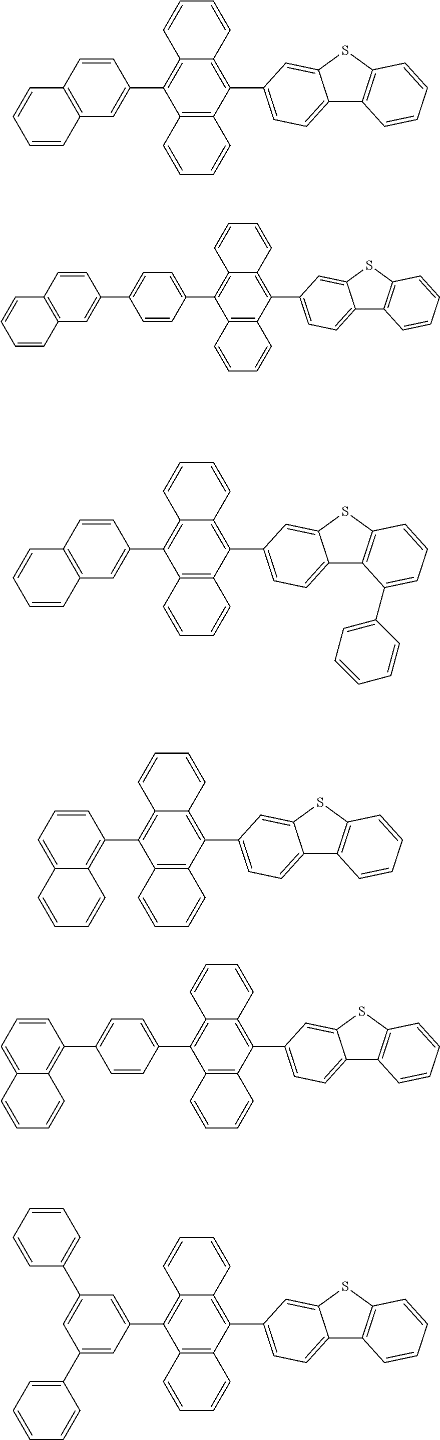

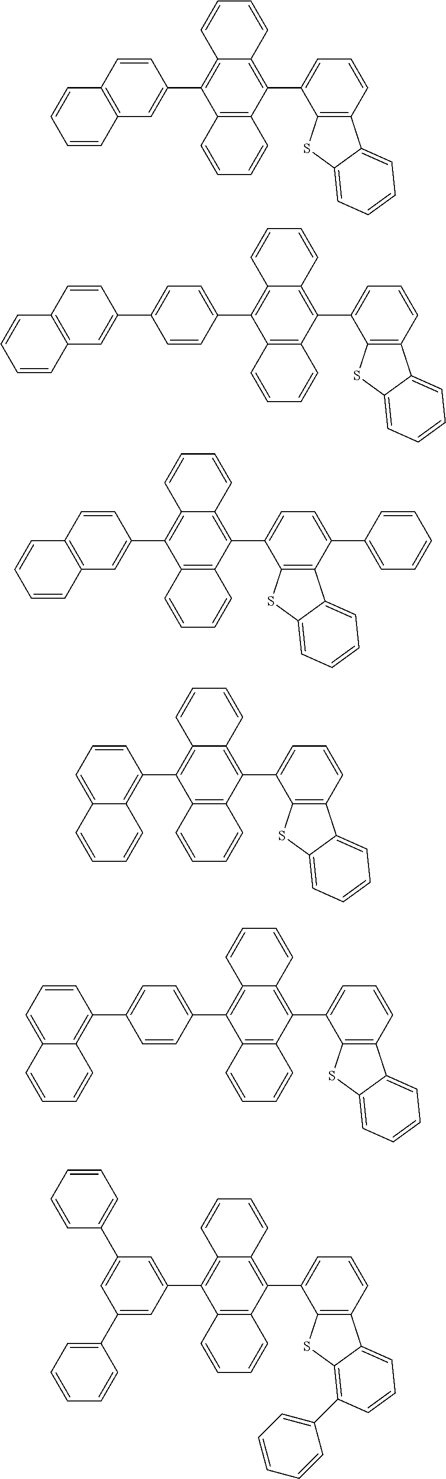

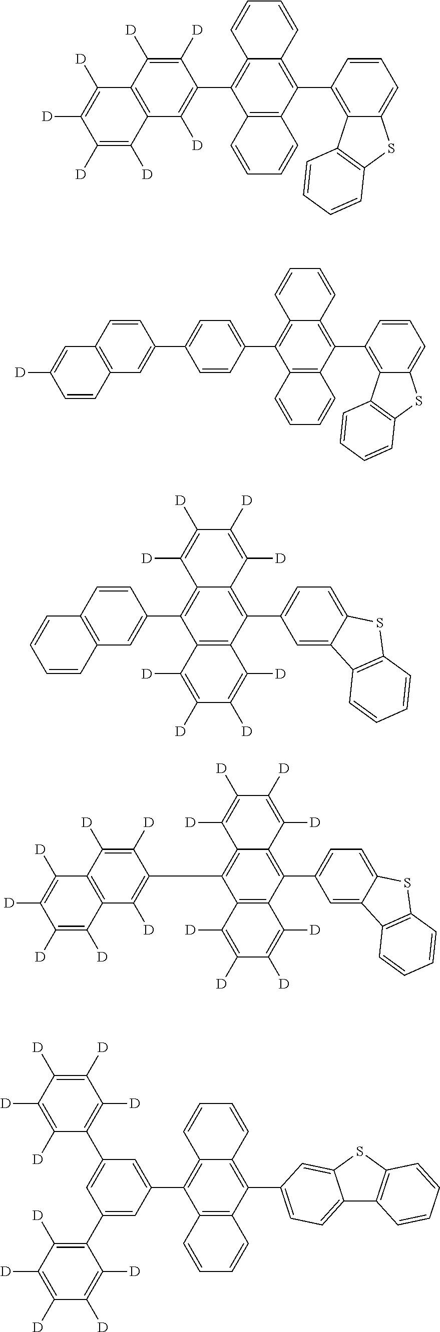

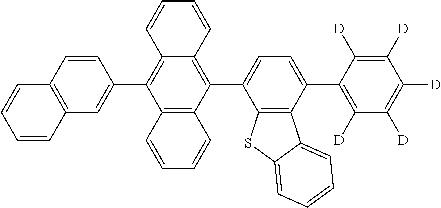 [SMILES: [2H]c1c([2H])c([2H])c(-c2ccc(-c3c4ccccc4c(-c4ccc5ccccc5c4)c4ccccc34)c3sc4ccccc4c23)c([2H])c1[2H]]

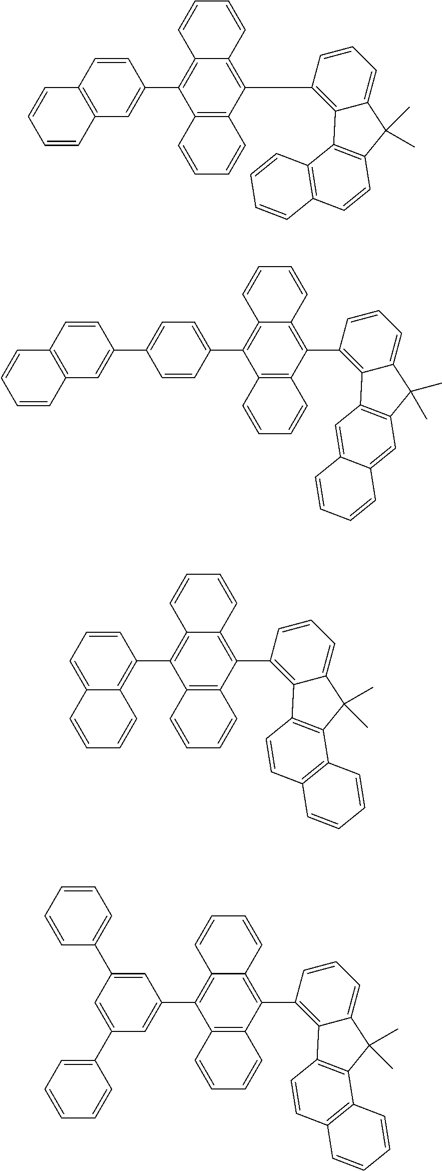

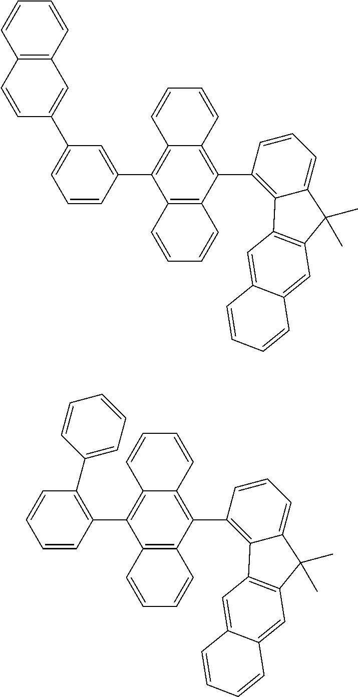

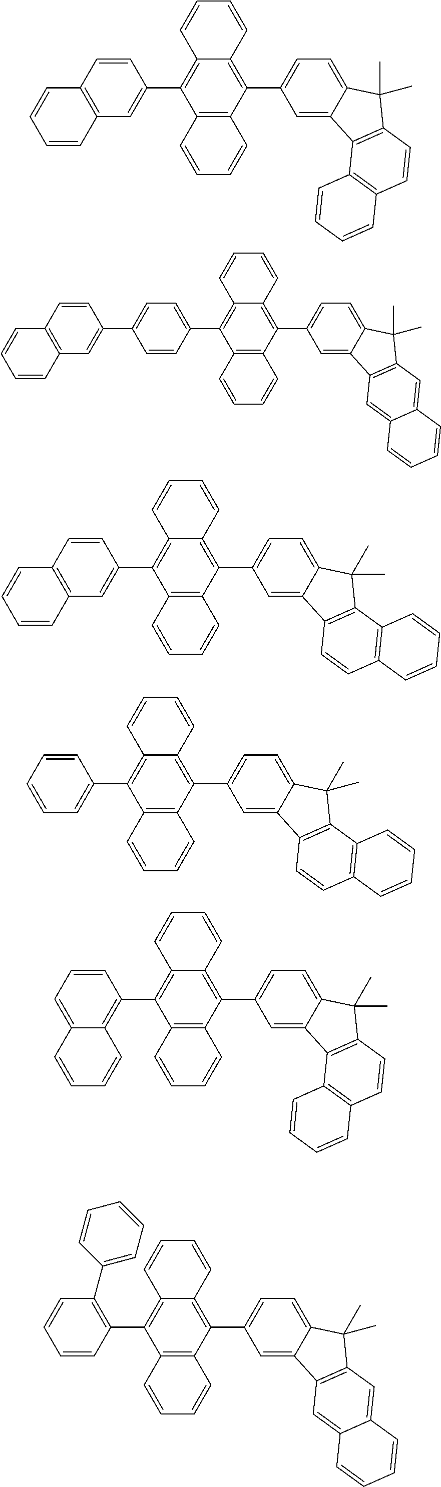

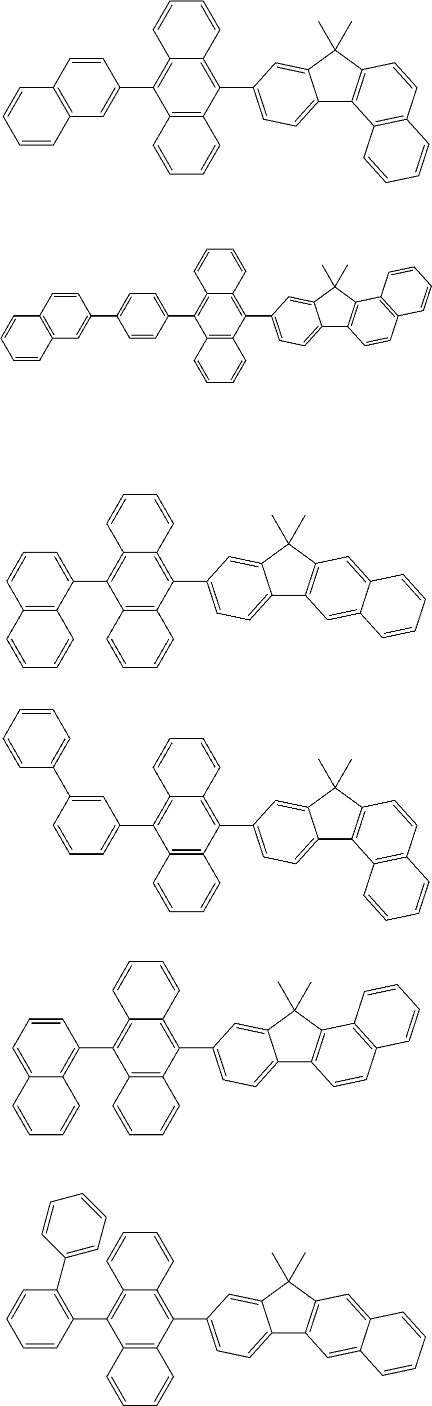

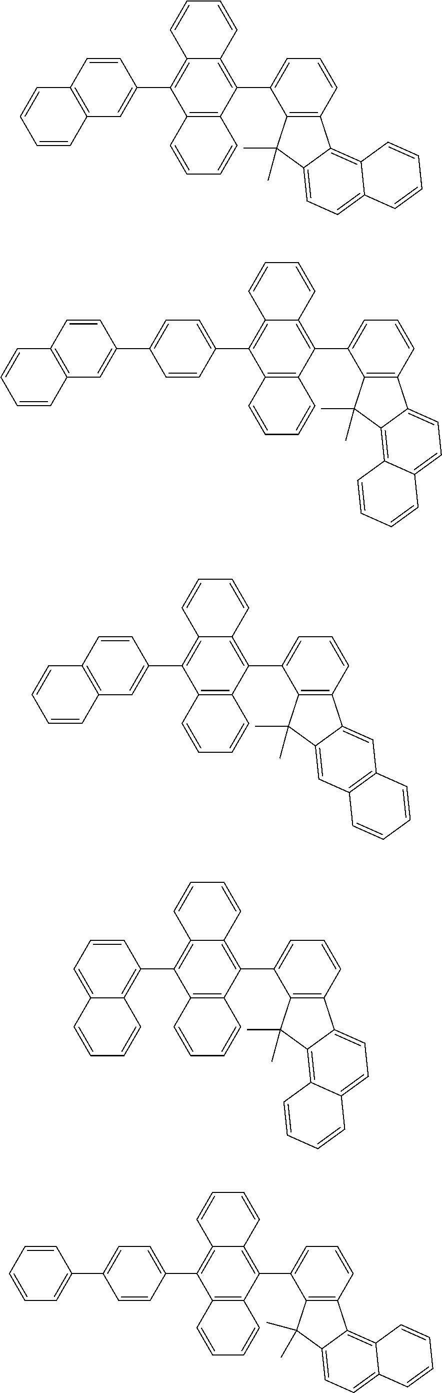

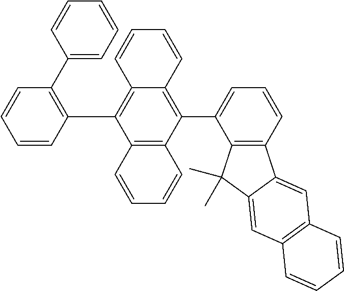 [SMILES: CC1(C)c2cc3ccccc3cc2-c2cccc(-c3c4ccccc4c(-c4ccccc4-c4ccccc4)c4ccccc34)c21]

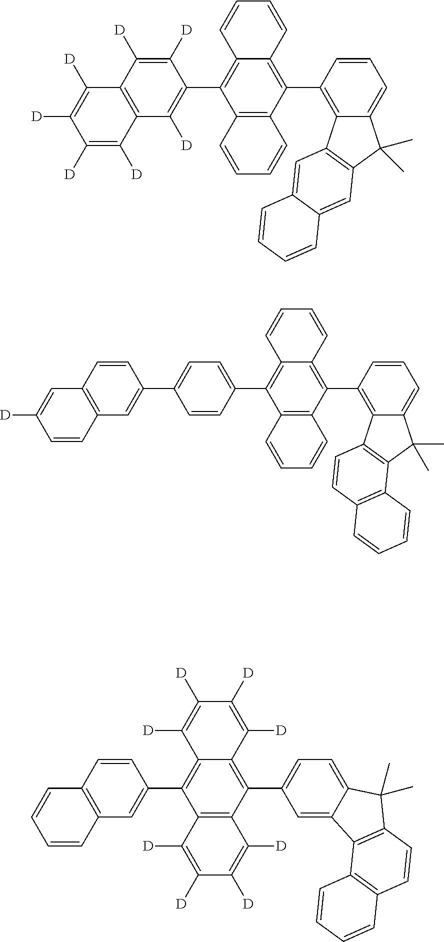 [SMILES: [2H]c1c([2H])c([2H])c2c([2H])c(-c3c4ccccc4c(-c4cccc5c4-c4cc6ccccc6cc4C5(C)C)c4ccccc34)c([2H])c([2H])c2c1[2H] ; [2H]c1ccc2cc(-c3ccc(-c4c5ccccc5c(-c5cccc6c5-c5ccc7ccccc7c5C6(C)C)c5ccccc45)cc3)ccc2c1 ; [2H]c1c([2H])c([2H])c2c(-c3ccc4ccccc4c3)c3c([2H])c([2H])c([2H])c([2H])c3c(-c3ccc4c(c3)-c3c(ccc5ccccc35)C4(C)C)c2c1[2H]]

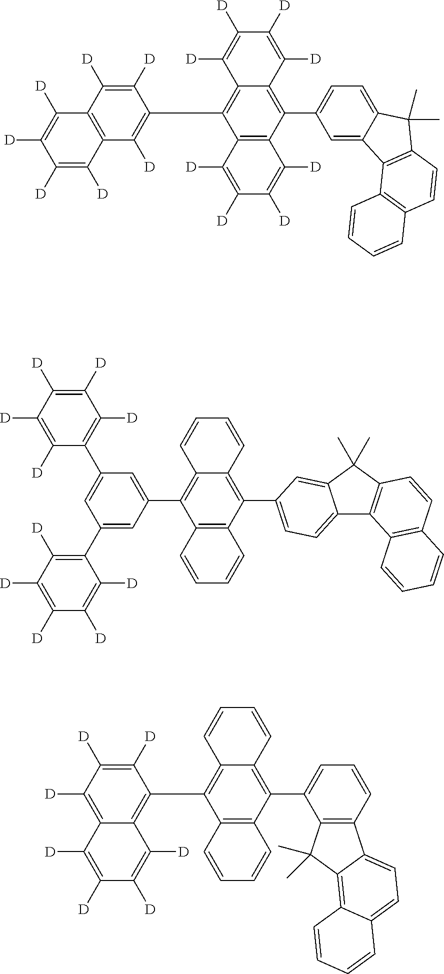 [SMILES: [2H]c1c([2H])c([2H])c2c([2H])c(-c3c4c([2H])c([2H])c([2H])c([2H])c4c(-c4ccc5c(c4)-c4c(ccc6ccccc46)C5(C)C)c4c([2H])c([2H])c([2H])c([2H])c34)c([2H])c([2H])c2c1[2H] ; [2H]c1c([2H])c([2H])c(-c2cc(-c3c([2H])c([2H])c([2H])c([2H])c3[2H])cc(-c3c4ccccc4c(-c4ccc5c(c4)C(C)(C)c4ccc6ccccc6c4-5)c4ccccc34)c2)c([2H])c1[2H] ; [2H]c1c([2H])c([2H])c2c(-c3c4ccccc4c(-c4cccc5c4C(C)(C)c4c-5ccc5ccccc45)c4ccccc34)c([2H])c([2H])c([2H])c2c1[2H]]

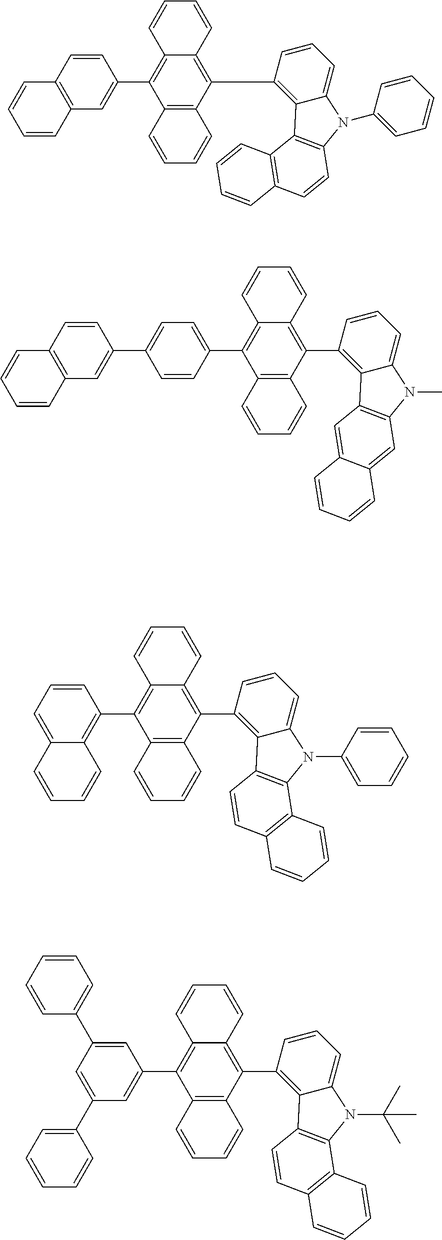 [SMILES: c1ccc(-n2c3cccc(-c4c5ccccc5c(-c5ccc6ccccc6c5)c5ccccc45)c3c3c4ccccc4ccc32)cc1 ; Cn1c2cc3ccccc3cc2c2c(-c3c4ccccc4c(-c4ccc(-c5ccc6ccccc6c5)cc4)c4ccccc34)cccc21 ; c1ccc(-n2c3cccc(-c4c5ccccc5c(-c5cccc6ccccc56)c5ccccc45)c3c3ccc4ccccc4c32)cc1 ; CC(C)(C)n1c2cccc(-c3c4ccccc4c(-c4cc(-c5ccccc5)cc(-c5ccccc5)c4)c4ccccc34)c2c2ccc3ccccc3c21]

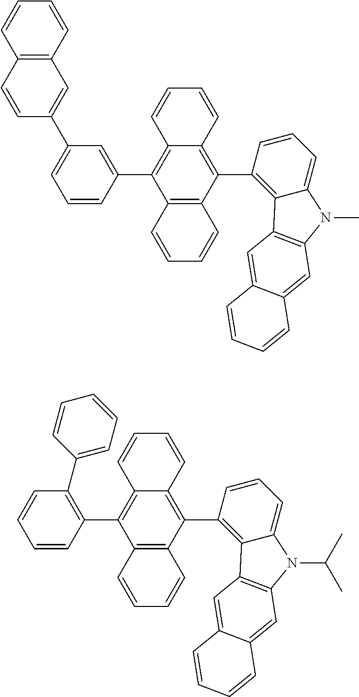 [SMILES: Cn1c2cc3ccccc3cc2c2c(-c3c4ccccc4c(-c4cccc(-c5ccc6ccccc6c5)c4)c4ccccc34)cccc21 ; CC(C)n1c2cc3ccccc3cc2c2c(-c3c4ccccc4c(-c4ccccc4-c4ccccc4)c4ccccc34)cccc21]

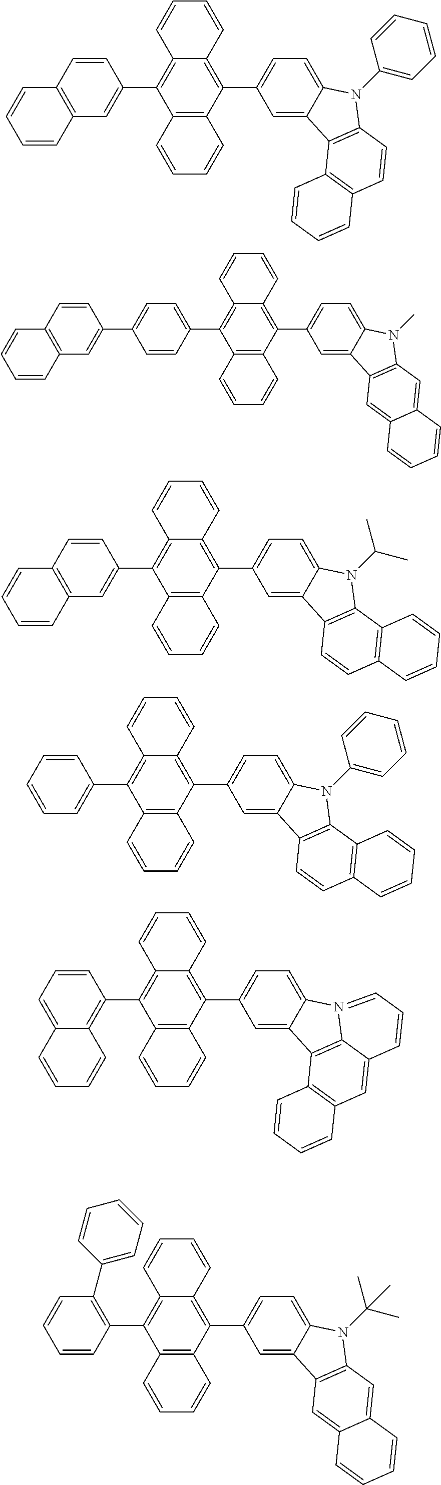

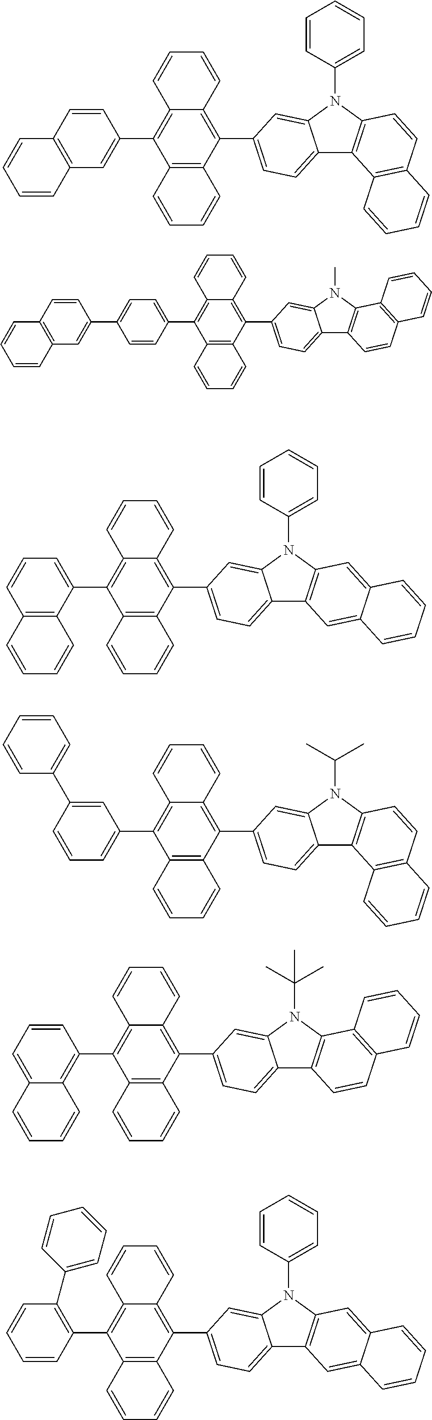

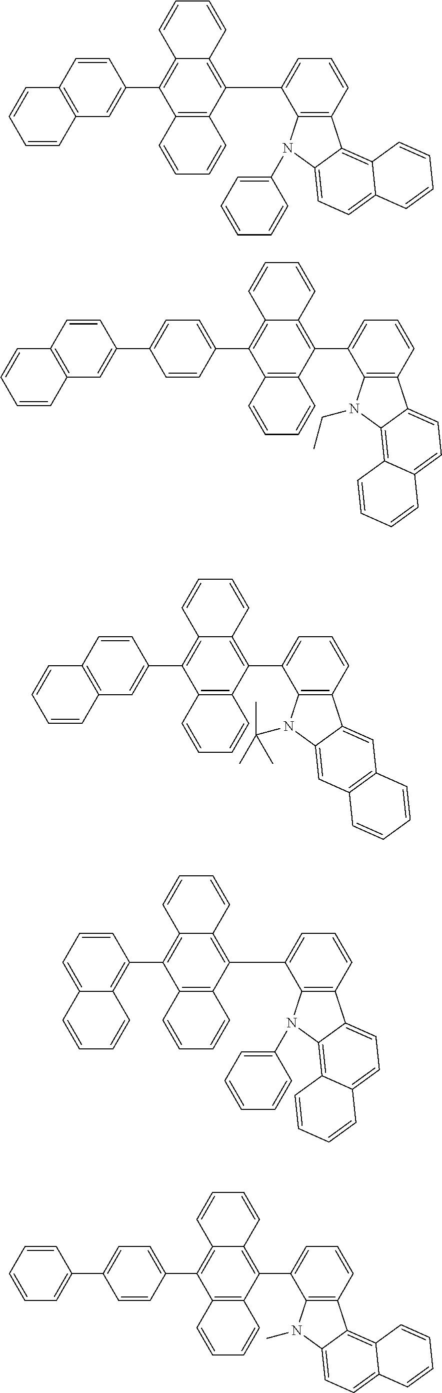

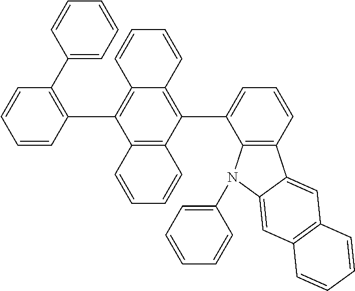 [SMILES: c1ccc(-c2ccccc2-c2c3ccccc3c(-c3cccc4c5cc6ccccc6cc5n(-c5ccccc5)c34)c3ccccc23)cc1]

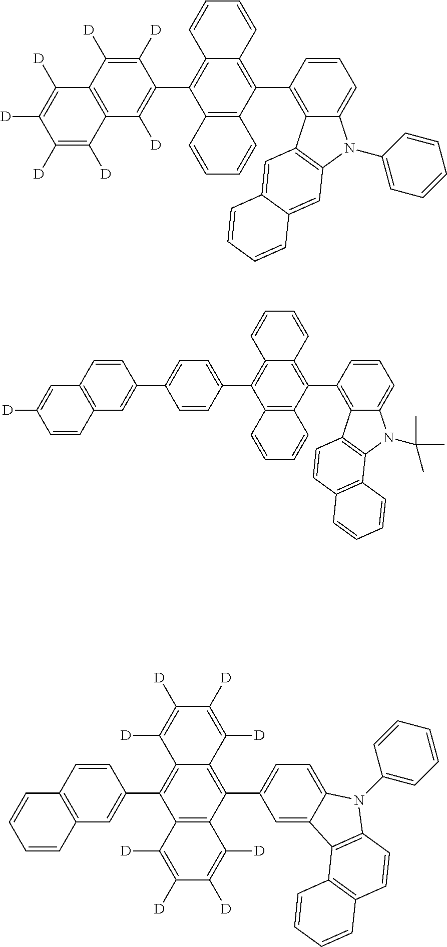 [SMILES: [2H]c1c([2H])c([2H])c2c([2H])c(-c3c4ccccc4c(-c4cccc5c4c4cc6ccccc6cc4n5-c4ccccc4)c4ccccc34)c([2H])c([2H])c2c1[2H] ; [2H]c1ccc2cc(-c3ccc(-c4c5ccccc5c(-c5cccc6c5c5ccc7ccccc7c5n6C(C)(C)C)c5ccccc45)cc3)ccc2c1 ; [2H]c1c([2H])c([2H])c2c(-c3ccc4c(c3)c3c5ccccc5ccc3n4-c3ccccc3)c3c([2H])c([2H])c([2H])c([2H])c3c(-c3ccc4ccccc4c3)c2c1[2H]]

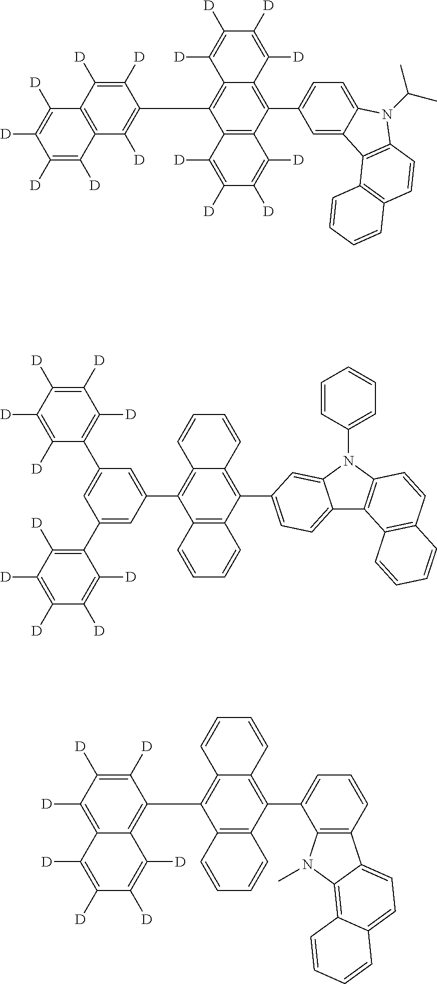 [SMILES: [2H]c1c([2H])c([2H])c2c([2H])c(-c3c4c([2H])c([2H])c([2H])c([2H])c4c(-c4ccc5c(c4)c4c6ccccc6ccc4n5C(C)C)c4c([2H])c([2H])c([2H])c([2H])c34)c([2H])c([2H])c2c1[2H] ; [2H]c1c([2H])c([2H])c(-c2cc(-c3c([2H])c([2H])c([2H])c([2H])c3[2H])cc(-c3c4ccccc4c(-c4ccc5c6c7ccccc7ccc6n(-c6ccccc6)c5c4)c4ccccc34)c2)c([2H])c1[2H] ; [2H]c1c([2H])c([2H])c2c(-c3c4ccccc4c(-c4cccc5c6ccc7ccccc7c6n(C)c45)c4ccccc34)c([2H])c([2H])c([2H])c2c1[2H]]

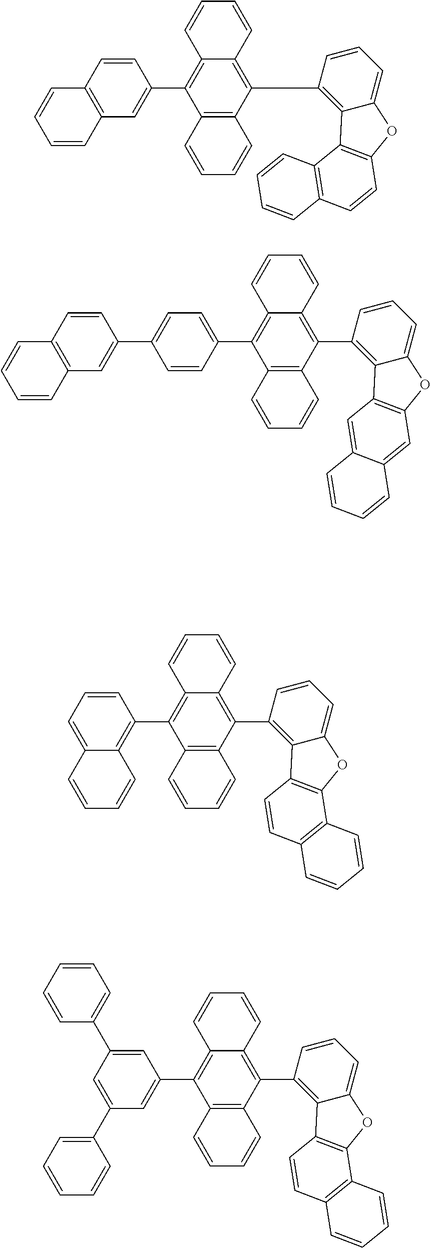

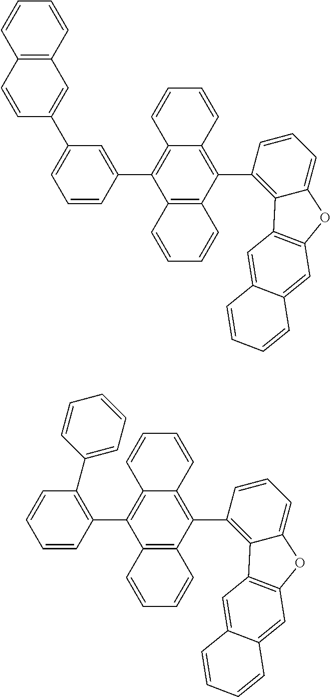 [SMILES: c1cc(-c2ccc3ccccc3c2)cc(-c2c3ccccc3c(-c3cccc4oc5cc6ccccc6cc5c34)c3ccccc23)c1 ; c1ccc(-c2ccccc2-c2c3ccccc3c(-c3cccc4oc5cc6ccccc6cc5c34)c3ccccc23)cc1]

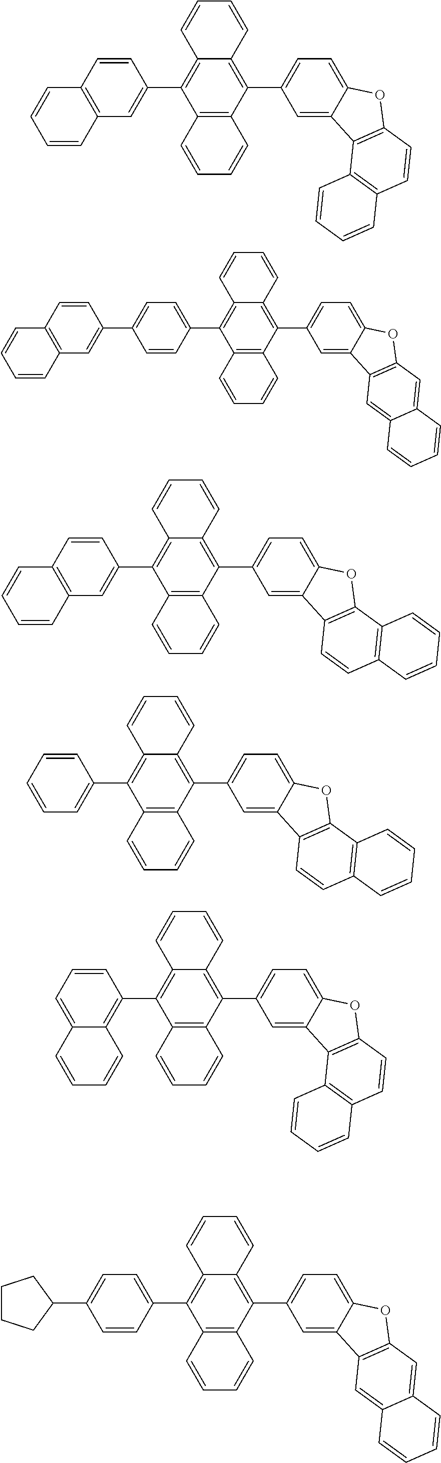

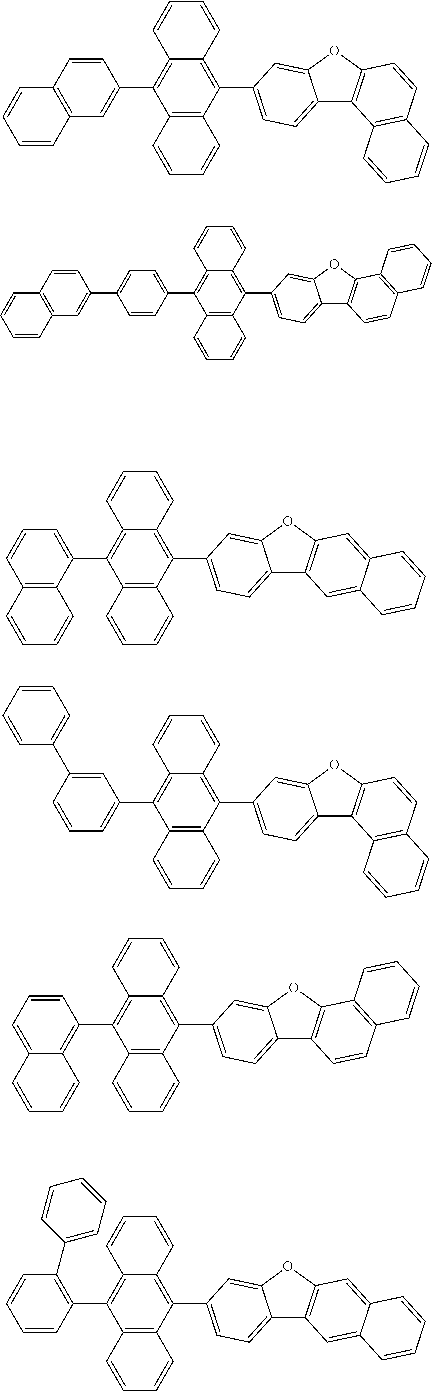

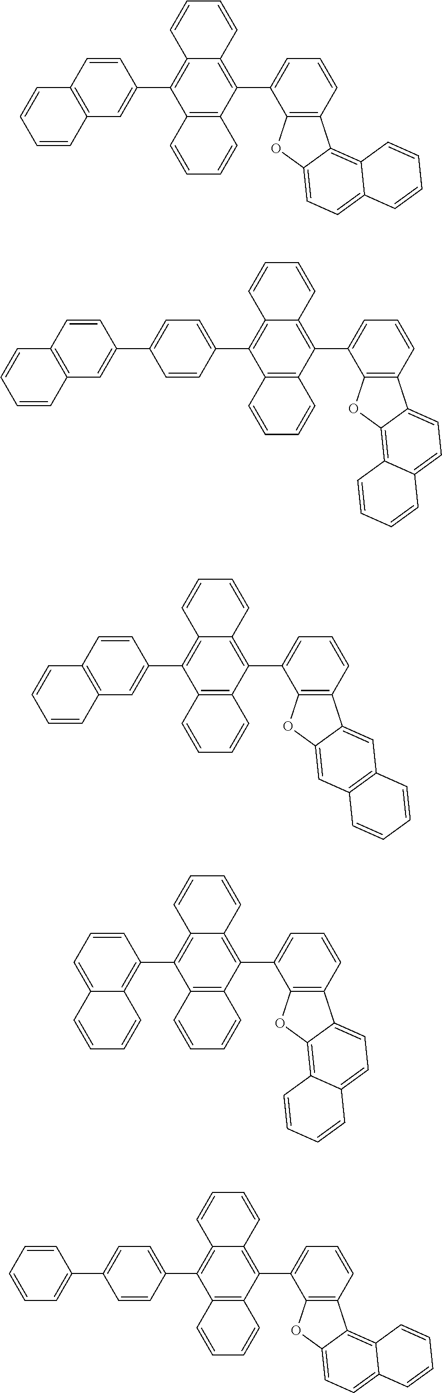 [SMILES: c1ccc2cc(-c3c4ccccc4c(-c4cccc5c4oc4ccc6ccccc6c45)c4ccccc34)ccc2c1 ; c1ccc2cc(-c3ccc(-c4c5ccccc5c(-c5cccc6c5oc5c7ccccc7ccc65)c5ccccc45)cc3)ccc2c1 ; c1ccc2cc(-c3c4ccccc4c(-c4cccc5c4oc4cc6ccccc6cc45)c4ccccc34)ccc2c1 ; c1ccc2c(-c3c4ccccc4c(-c4cccc5c4oc4c6ccccc6ccc54)c4ccccc34)cccc2c1 ; c1ccc(-c2ccc(-c3c4ccccc4c(-c4cccc5c4oc4ccc6ccccc6c45)c4ccccc34)cc2)cc1]

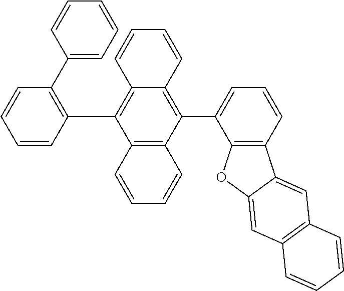 [SMILES: c1ccc(-c2ccccc2-c2c3ccccc3c(-c3cccc4c3oc3cc5ccccc5cc34)c3ccccc23)cc1]

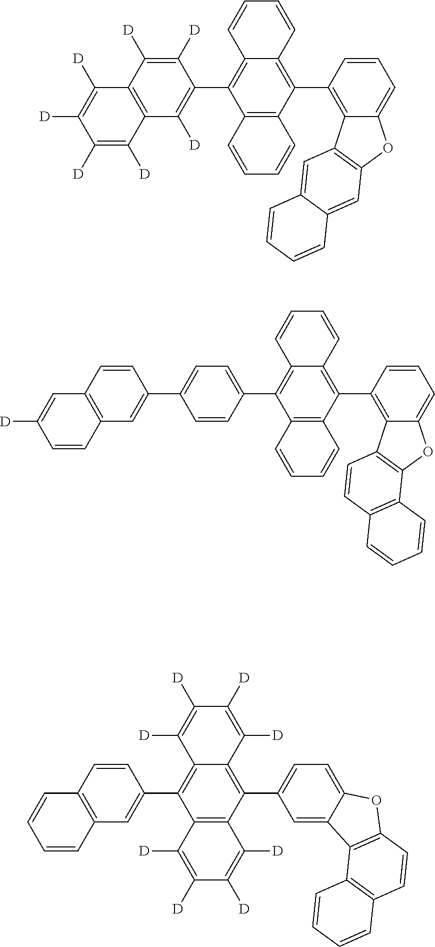 [SMILES: [2H]c1c([2H])c([2H])c2c([2H])c(-c3c4ccccc4c(-c4cccc5oc6cc7ccccc7cc6c45)c4ccccc34)c([2H])c([2H])c2c1[2H] ; [2H]c1ccc2cc(-c3ccc(-c4c5ccccc5c(-c5cccc6oc7c8ccccc8ccc7c56)c5ccccc45)cc3)ccc2c1 ; [2H]c1c([2H])c([2H])c2c(-c3ccc4oc5ccc6ccccc6c5c4c3)c3c([2H])c([2H])c([2H])c([2H])c3c(-c3ccc4ccccc4c3)c2c1[2H]]

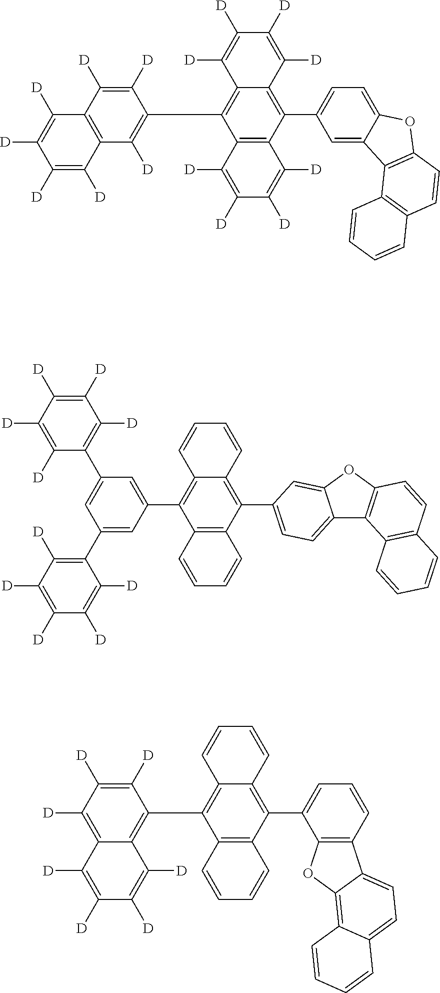 [SMILES: [2H]c1c([2H])c([2H])c2c([2H])c(-c3c4c([2H])c([2H])c([2H])c([2H])c4c(-c4ccc5oc6ccc7ccccc7c6c5c4)c4c([2H])c([2H])c([2H])c([2H])c34)c([2H])c([2H])c2c1[2H] ; [2H]c1c([2H])c([2H])c(-c2cc(-c3c([2H])c([2H])c([2H])c([2H])c3[2H])cc(-c3c4ccccc4c(-c4ccc5c(c4)oc4ccc6ccccc6c45)c4ccccc34)c2)c([2H])c1[2H] ; [2H]c1c([2H])c([2H])c2c(-c3c4ccccc4c(-c4cccc5c4oc4c6ccccc6ccc54)c4ccccc34)c([2H])c([2H])c([2H])c2c1[2H]]

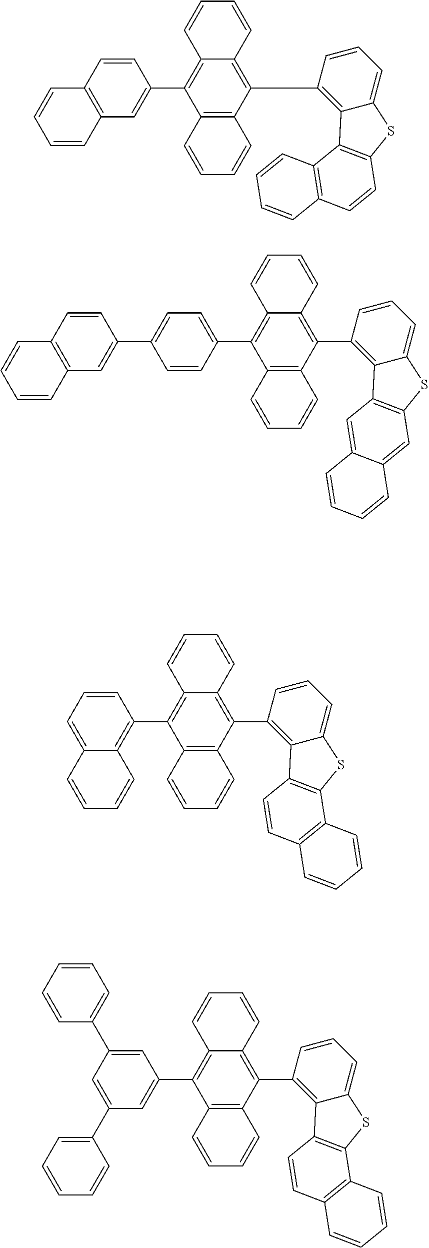

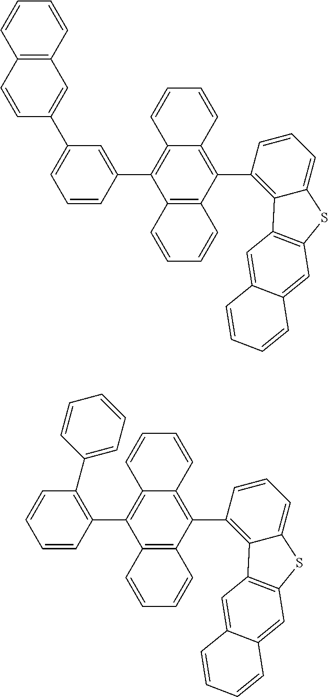 [SMILES: c1cc(-c2ccc3ccccc3c2)cc(-c2c3ccccc3c(-c3cccc4sc5cc6ccccc6cc5c34)c3ccccc23)c1 ; c1ccc(-c2ccccc2-c2c3ccccc3c(-c3cccc4sc5cc6ccccc6cc5c34)c3ccccc23)cc1]

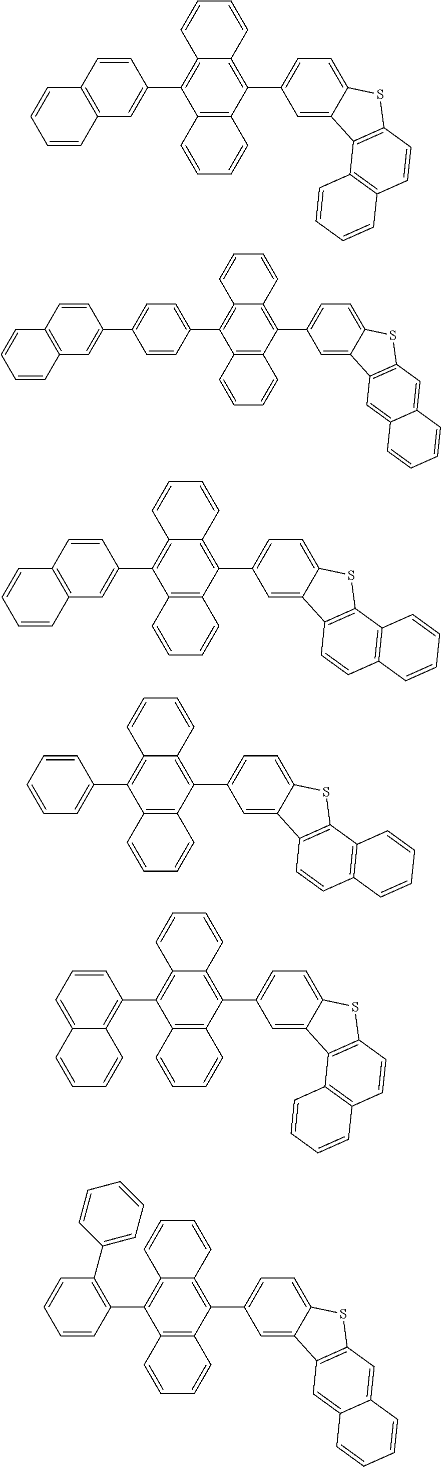

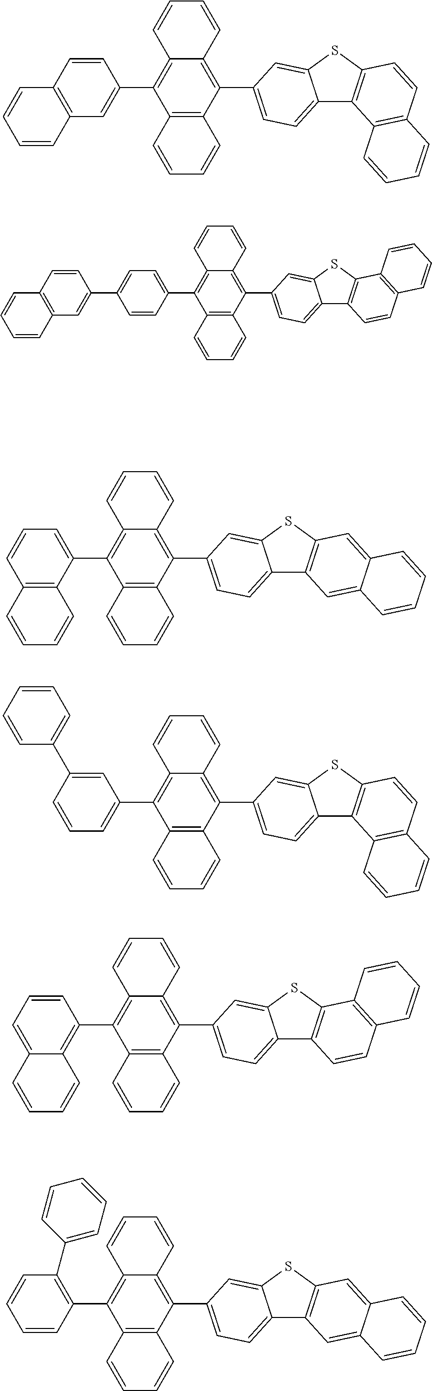

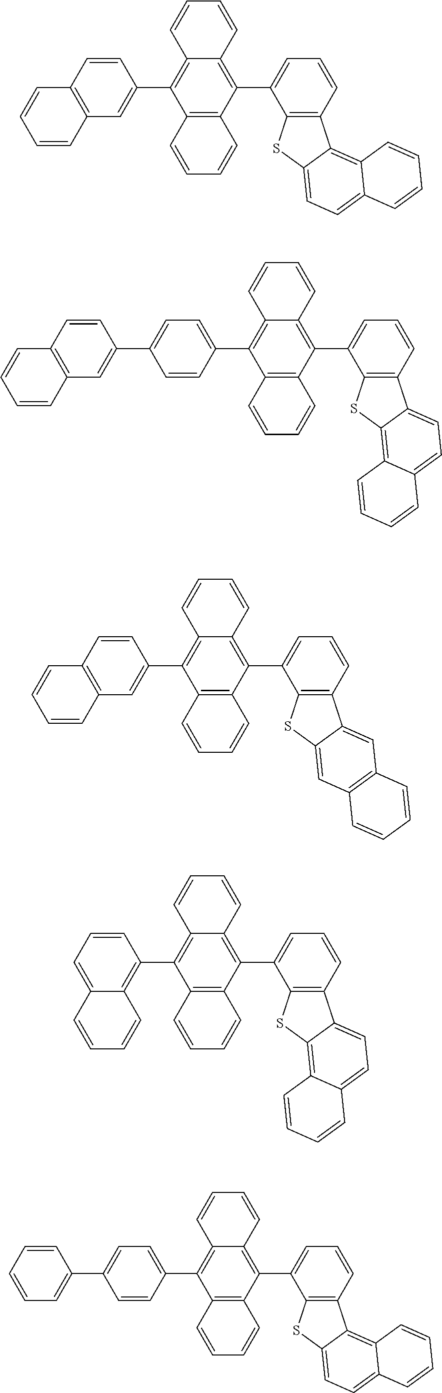 [SMILES: c1ccc2cc(-c3c4ccccc4c(-c4cccc5c4sc4ccc6ccccc6c45)c4ccccc34)ccc2c1 ; c1ccc2cc(-c3ccc(-c4c5ccccc5c(-c5cccc6c5sc5c7ccccc7ccc65)c5ccccc45)cc3)ccc2c1 ; c1ccc2cc(-c3c4ccccc4c(-c4cccc5c4sc4cc6ccccc6cc45)c4ccccc34)ccc2c1 ; c1ccc2c(-c3c4ccccc4c(-c4cccc5c4sc4c6ccccc6ccc54)c4ccccc34)cccc2c1 ; c1ccc(-c2ccc(-c3c4ccccc4c(-c4cccc5c4sc4ccc6ccccc6c45)c4ccccc34)cc2)cc1]

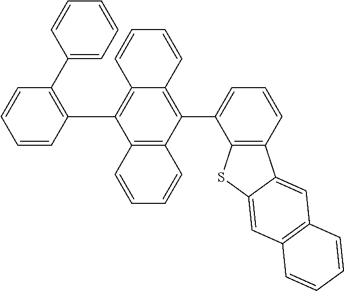 [SMILES: c1ccc(-c2ccccc2-c2c3ccccc3c(-c3cccc4c3sc3cc5ccccc5cc34)c3ccccc23)cc1]

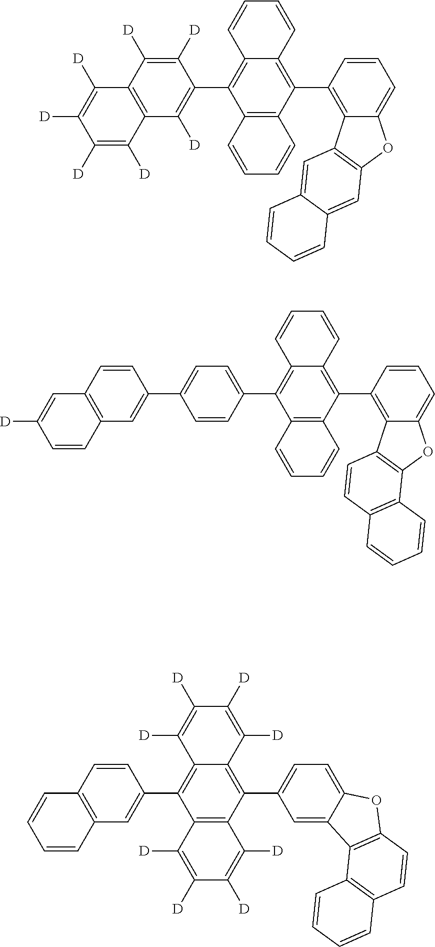 [SMILES: [2H]c1c([2H])c([2H])c2c([2H])c(-c3c4ccccc4c(-c4cccc5oc6cc7ccccc7cc6c45)c4ccccc34)c([2H])c([2H])c2c1[2H] ; [2H]c1ccc2cc(-c3ccc(-c4c5ccccc5c(-c5cccc6oc7c8ccccc8ccc7c56)c5ccccc45)cc3)ccc2c1 ; [2H]c1c([2H])c([2H])c2c(-c3ccc4oc5ccc6ccccc6c5c4c3)c3c([2H])c([2H])c([2H])c([2H])c3c(-c3ccc4ccccc4c3)c2c1[2H]]

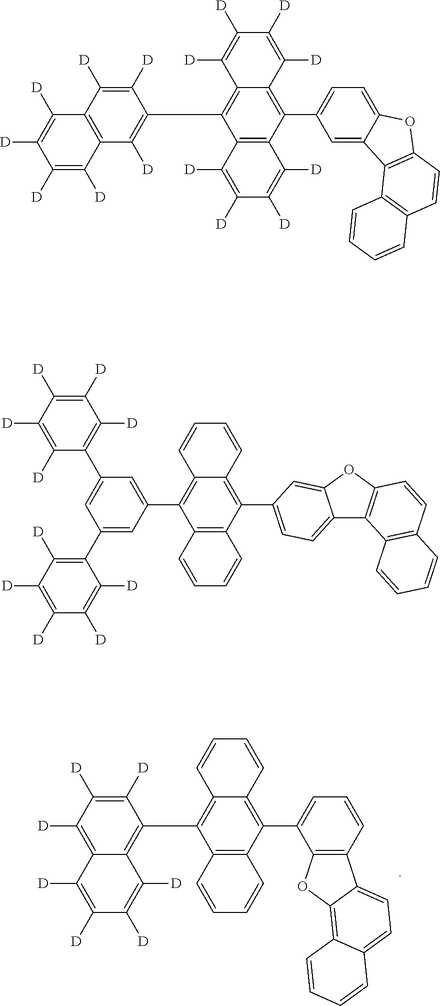 [SMILES: [2H]c1c([2H])c([2H])c2c([2H])c(-c3c4c([2H])c([2H])c([2H])c([2H])c4c(-c4ccc5oc6ccc7ccccc7c6c5c4)c4c([2H])c([2H])c([2H])c([2H])c34)c([2H])c([2H])c2c1[2H] ; [2H]c1c([2H])c([2H])c(-c2cc(-c3c([2H])c([2H])c([2H])c([2H])c3[2H])cc(-c3c4ccccc4c(-c4ccc5c(c4)oc4ccc6ccccc6c45)c4ccccc34)c2)c([2H])c1[2H] ; [2H]c1c([2H])c([2H])c2c(-c3c4ccccc4c(-c4cccc5c4oc4c6ccccc6ccc54)c4ccccc34)c([2H])c([2H])c([2H])c2c1[2H]]

13. The composition of claim 1, wherein the second compound is selected from:

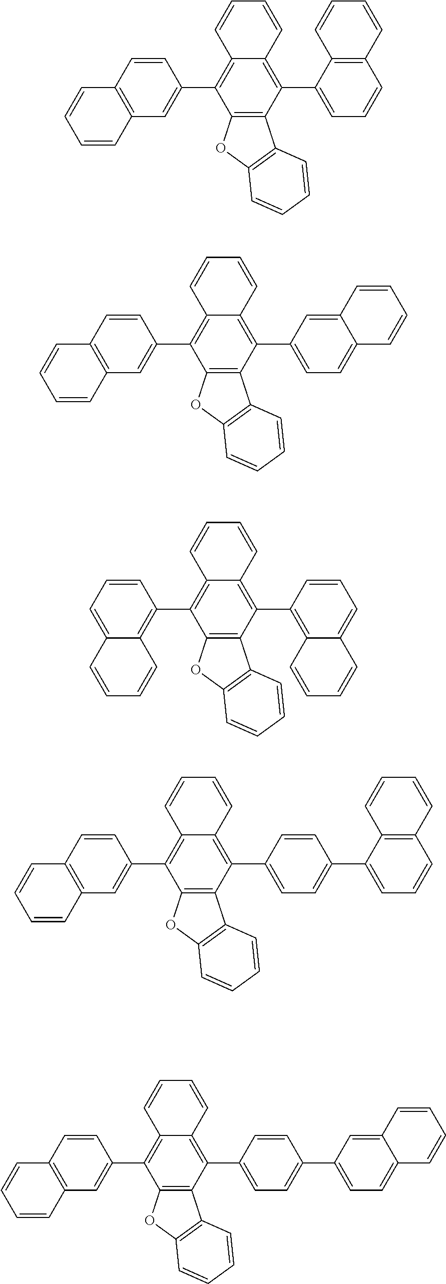 [SMILES: c1ccc2cc(-c3c4ccccc4c(-c4cccc5ccccc45)c4c3oc3ccccc34)ccc2c1 ; c1ccc2cc(-c3c4ccccc4c(-c4ccc5ccccc5c4)c4c3oc3ccccc34)ccc2c1 ; c1ccc2c(-c3c4ccccc4c(-c4cccc5ccccc45)c4c3oc3ccccc34)cccc2c1 ; c1ccc2cc(-c3c4ccccc4c(-c4ccc(-c5cccc6ccccc56)cc4)c4c3oc3ccccc34)ccc2c1 ; c1ccc2cc(-c3ccc(-c4c5ccccc5c(-c5ccc6ccccc6c5)c5oc6ccccc6c45)cc3)ccc2c1]

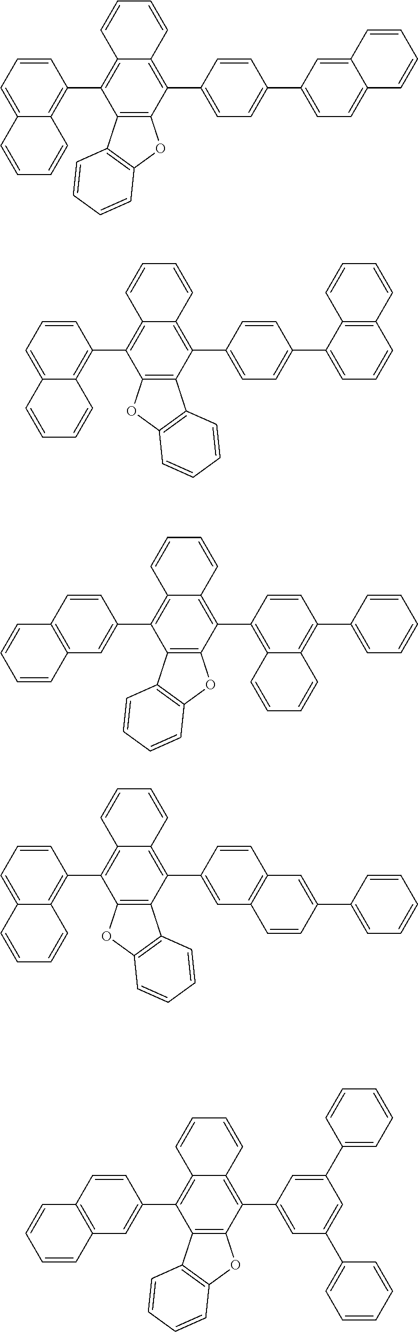

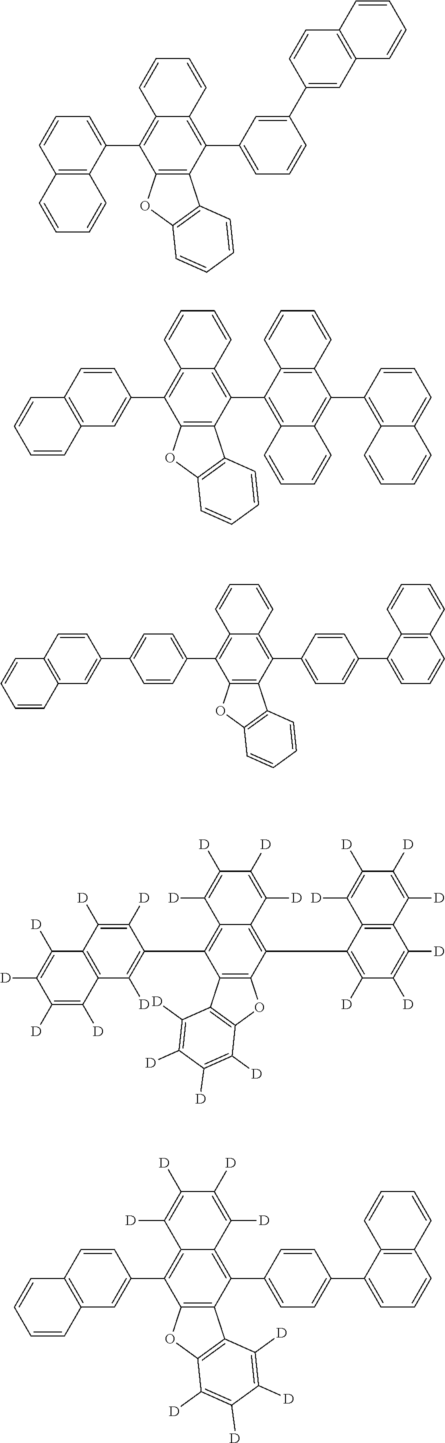

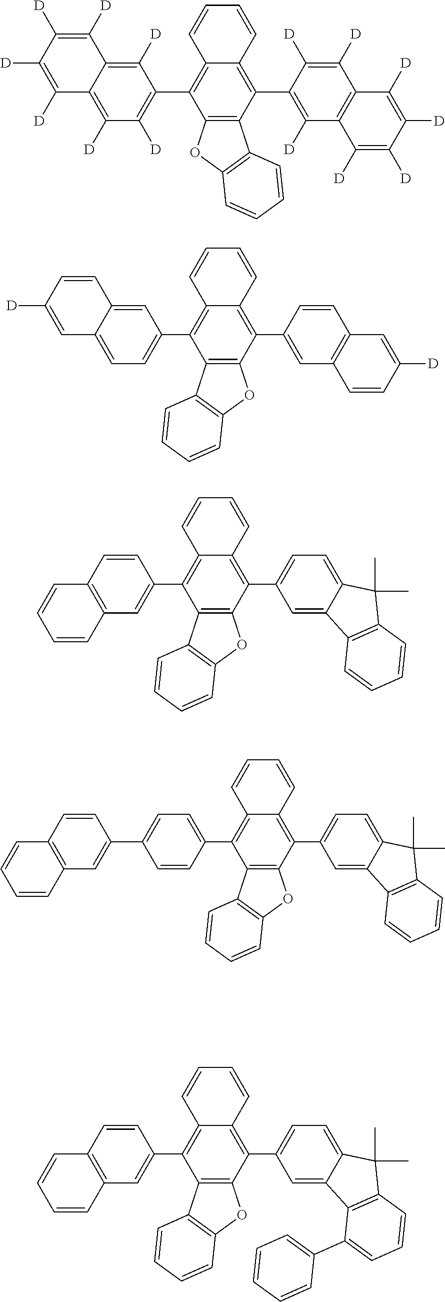

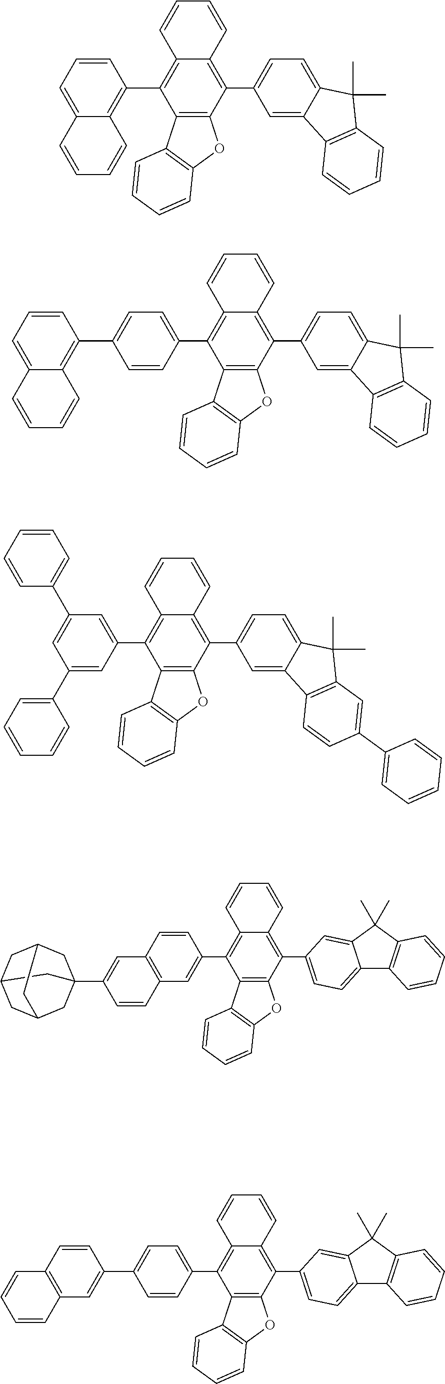 [SMILES: CC1(C)c2ccccc2-c2cc(-c3c4ccccc4c(-c4cccc5ccccc45)c4c3oc3ccccc34)ccc21 ; CC1(C)c2ccccc2-c2cc(-c3c4ccccc4c(-c4ccc(-c5cccc6ccccc56)cc4)c4c3oc3ccccc34)ccc21 ; CC1(C)c2ccc(-c3c4ccccc4c(-c4cc(-c5ccccc5)cc(-c5ccccc5)c4)c4c3oc3ccccc34)cc2-c2ccc(-c3ccccc3)cc21 ; CC1(C)c2ccccc2-c2ccc(-c3c4ccccc4c(-c4ccc5cc(C67CC8CC(CC(C8)C6)C7)ccc5c4)c4c3oc3ccccc34)cc21 ; CC1(C)c2ccccc2-c2ccc(-c3c4ccccc4c(-c4ccc(-c5ccc6ccccc6c5)cc4)c4c3oc3ccccc34)cc21]

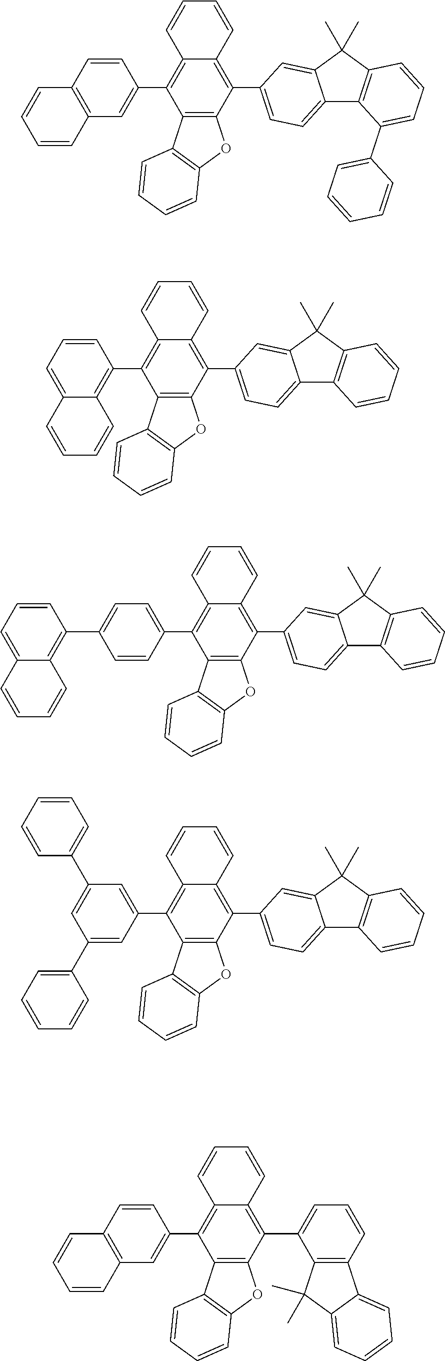 [SMILES: CC1(C)c2cc(-c3c4ccccc4c(-c4ccc5ccccc5c4)c4c3oc3ccccc34)ccc2-c2c(-c3ccccc3)cccc21 ; CC1(C)c2ccccc2-c2ccc(-c3c4ccccc4c(-c4cccc5ccccc45)c4c3oc3ccccc34)cc21 ; CC1(C)c2ccccc2-c2ccc(-c3c4ccccc4c(-c4ccc(-c5cccc6ccccc56)cc4)c4c3oc3ccccc34)cc21 ; CC1(C)c2ccccc2-c2ccc(-c3c4ccccc4c(-c4cc(-c5ccccc5)cc(-c5ccccc5)c4)c4c3oc3ccccc34)cc21 ; CC1(C)c2ccccc2-c2cccc(-c3c4ccccc4c(-c4ccc5ccccc5c4)c4c3oc3ccccc34)c21]

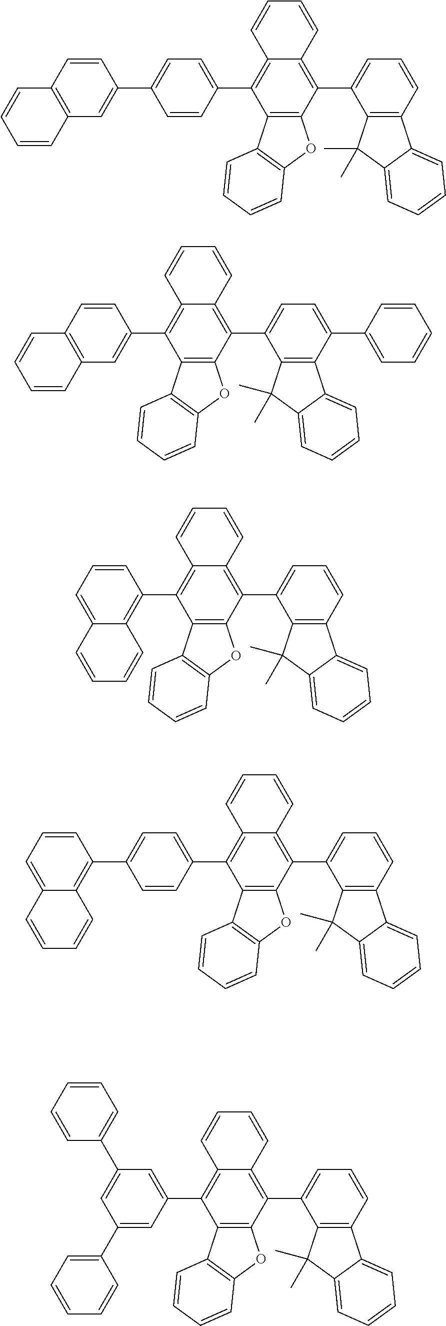 [SMILES: CC1(C)c2ccccc2-c2cccc(-c3c4ccccc4c(-c4ccc(-c5ccc6ccccc6c5)cc4)c4c3oc3ccccc34)c21 ; CC1(C)c2ccccc2-c2c(-c3ccccc3)ccc(-c3c4ccccc4c(-c4ccc5ccccc5c4)c4c3oc3ccccc34)c21 ; CC1(C)c2ccccc2-c2cccc(-c3c4ccccc4c(-c4cccc5ccccc45)c4c3oc3ccccc34)c21 ; CC1(C)c2ccccc2-c2cccc(-c3c4ccccc4c(-c4ccc(-c5cccc6ccccc56)cc4)c4c3oc3ccccc34)c21 ; CC1(C)c2ccccc2-c2cccc(-c3c4ccccc4c(-c4cc(-c5ccccc5)cc(-c5ccccc5)c4)c4c3oc3ccccc34)c21]

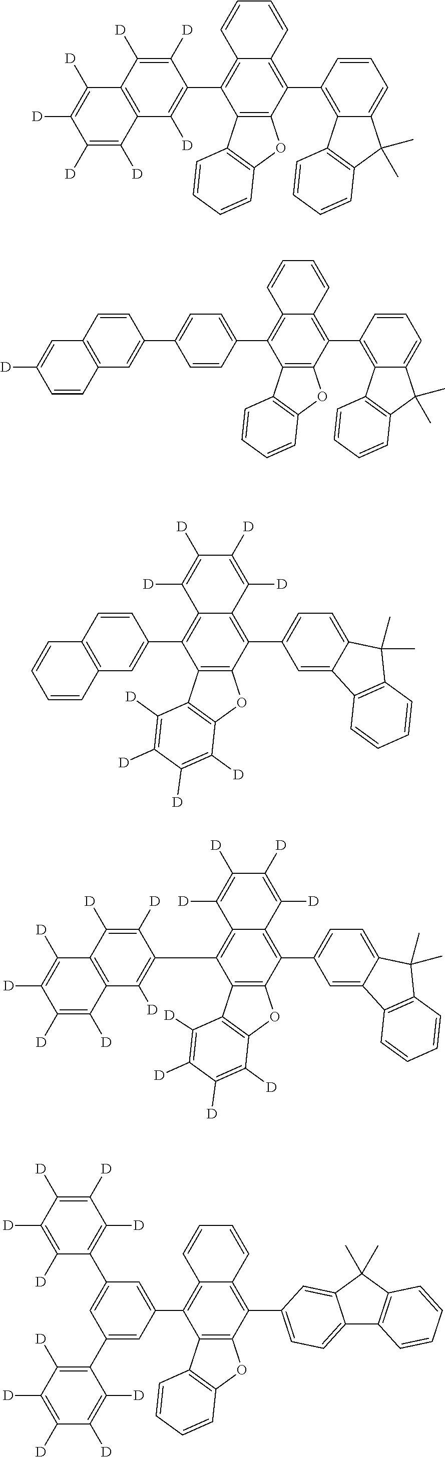

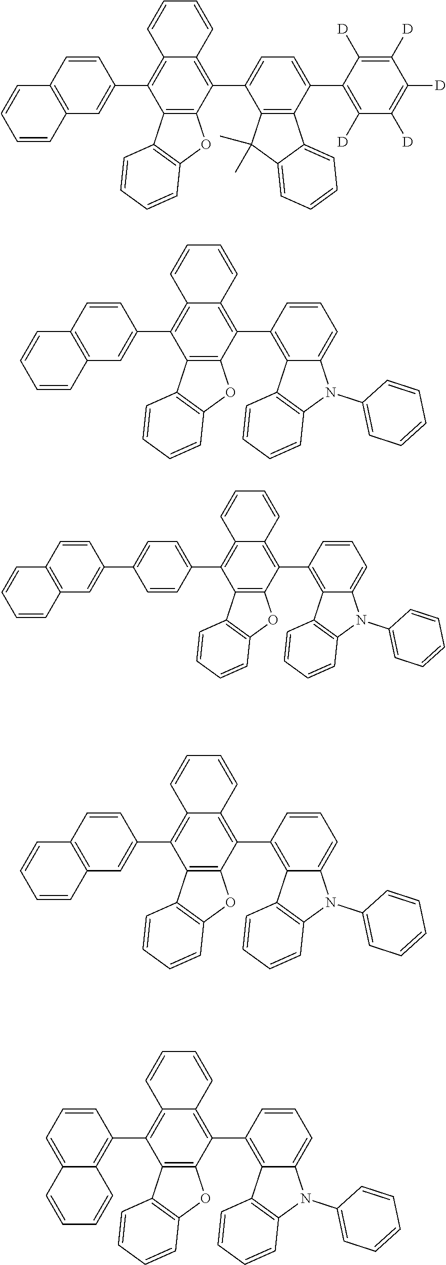

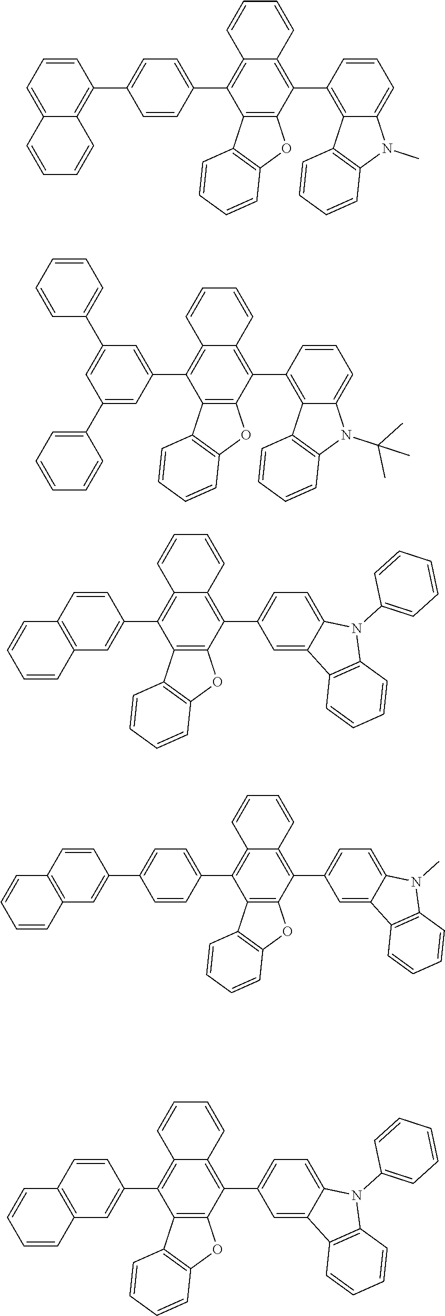

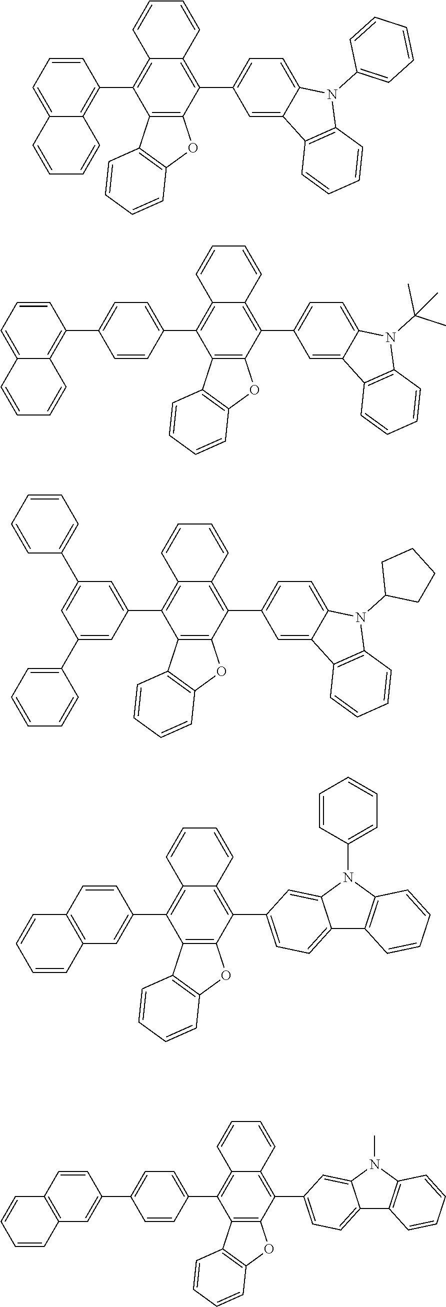 [SMILES: c1ccc(-n2c3ccccc3c3cc(-c4c5ccccc5c(-c5cccc6ccccc56)c5c4oc4ccccc45)ccc32)cc1 ; CC(C)(C)n1c2ccccc2c2cc(-c3c4ccccc4c(-c4ccc(-c5cccc6ccccc56)cc4)c4c3oc3ccccc34)ccc21 ; c1ccc(-c2cc(-c3ccccc3)cc(-c3c4ccccc4c(-c4ccc5c(c4)c4ccccc4n5C4CCCC4)c4oc5ccccc5c34)c2)cc1 ; c1ccc(-n2c3ccccc3c3ccc(-c4c5ccccc5c(-c5ccc6ccccc6c5)c5c4oc4ccccc45)cc32)cc1 ; Cn1c2ccccc2c2ccc(-c3c4ccccc4c(-c4ccc(-c5ccc6ccccc6c5)cc4)c4c3oc3ccccc34)cc21]

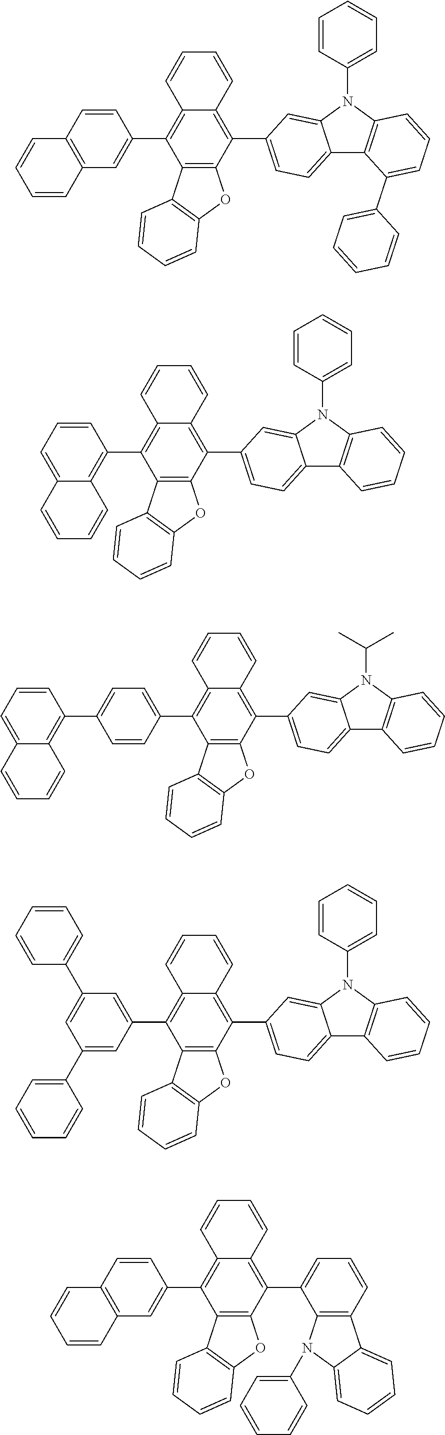 [SMILES: c1ccc(-c2cccc3c2c2ccc(-c4c5ccccc5c(-c5ccc6ccccc6c5)c5c4oc4ccccc45)cc2n3-c2ccccc2)cc1 ; c1ccc(-n2c3ccccc3c3ccc(-c4c5ccccc5c(-c5cccc6ccccc56)c5c4oc4ccccc45)cc32)cc1 ; CC(C)n1c2ccccc2c2ccc(-c3c4ccccc4c(-c4ccc(-c5cccc6ccccc56)cc4)c4c3oc3ccccc34)cc21 ; c1ccc(-c2cc(-c3ccccc3)cc(-c3c4ccccc4c(-c4ccc5c6ccccc6n(-c6ccccc6)c5c4)c4oc5ccccc5c34)c2)cc1 ; c1ccc(-n2c3ccccc3c3cccc(-c4c5ccccc5c(-c5ccc6ccccc6c5)c5c4oc4ccccc45)c32)cc1]

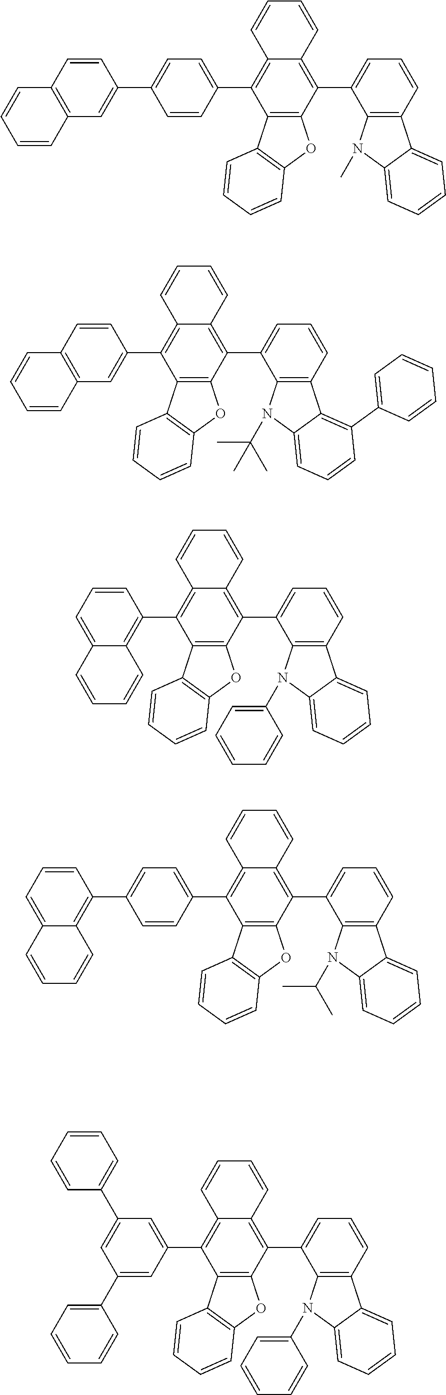 [SMILES: Cn1c2ccccc2c2cccc(-c3c4ccccc4c(-c4ccc(-c5ccc6ccccc6c5)cc4)c4c3oc3ccccc34)c21 ; CC(C)(C)n1c2cccc(-c3ccccc3)c2c2cccc(-c3c4ccccc4c(-c4ccc5ccccc5c4)c4c3oc3ccccc34)c21 ; c1ccc(-n2c3ccccc3c3cccc(-c4c5ccccc5c(-c5cccc6ccccc56)c5c4oc4ccccc45)c32)cc1 ; CC(C)n1c2ccccc2c2cccc(-c3c4ccccc4c(-c4ccc(-c5cccc6ccccc56)cc4)c4c3oc3ccccc34)c21 ; c1ccc(-c2cc(-c3ccccc3)cc(-c3c4ccccc4c(-c4cccc5c6ccccc6n(-c6ccccc6)c45)c4oc5ccccc5c34)c2)cc1]

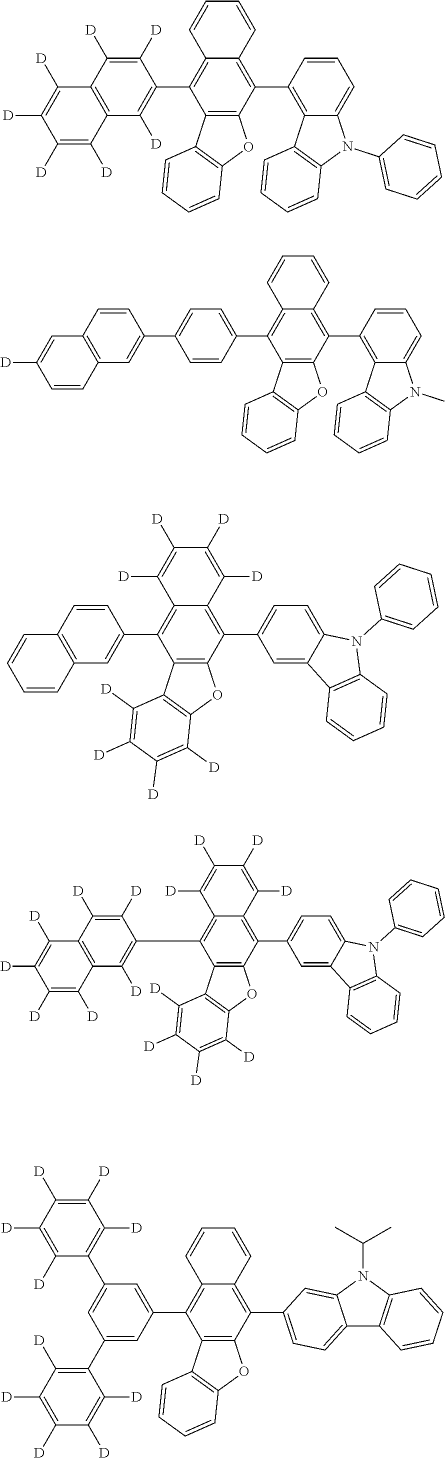

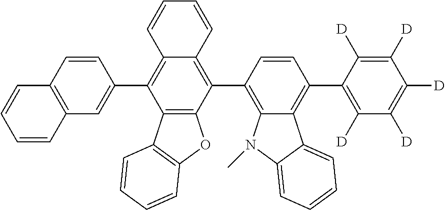 [SMILES: [2H]c1c([2H])c([2H])c(-c2ccc(-c3c4ccccc4c(-c4ccc5ccccc5c4)c4c3oc3ccccc34)c3c2c2ccccc2n3C)c([2H])c1[2H]]

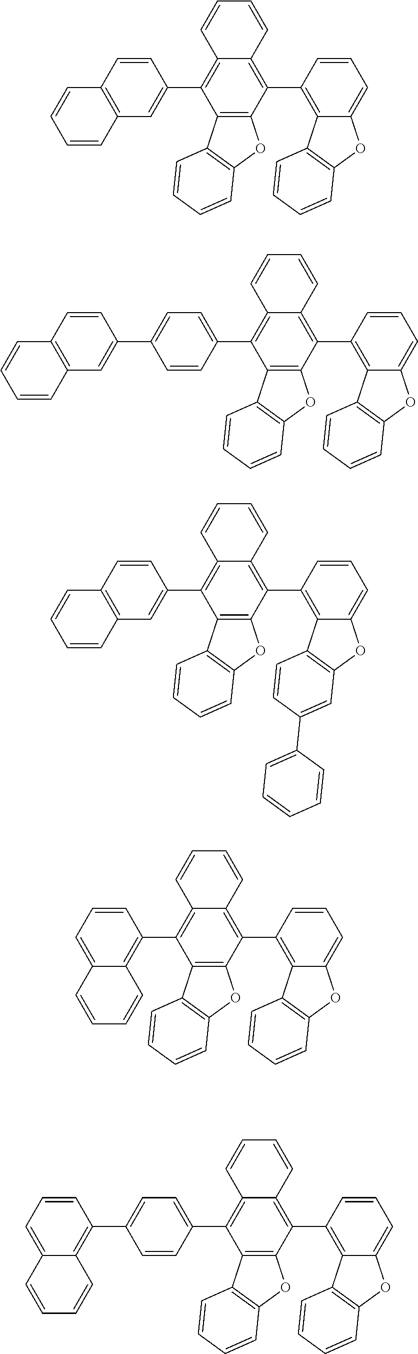

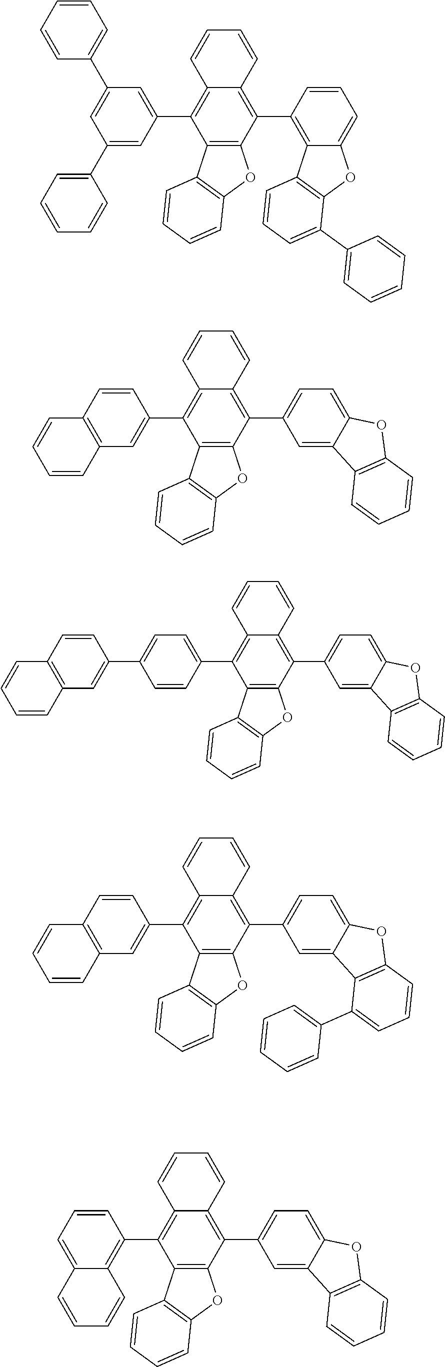 [SMILES: c1ccc(-c2cc(-c3ccccc3)cc(-c3c4ccccc4c(-c4cccc5oc6c(-c7ccccc7)cccc6c45)c4oc5ccccc5c34)c2)cc1 ; c1ccc2cc(-c3c4ccccc4c(-c4ccc5oc6ccccc6c5c4)c4oc5ccccc5c34)ccc2c1 ; c1ccc2cc(-c3ccc(-c4c5ccccc5c(-c5ccc6oc7ccccc7c6c5)c5oc6ccccc6c45)cc3)ccc2c1 ; c1ccc(-c2cccc3oc4ccc(-c5c6ccccc6c(-c6ccc7ccccc7c6)c6c5oc5ccccc56)cc4c23)cc1 ; c1ccc2c(-c3c4ccccc4c(-c4ccc5oc6ccccc6c5c4)c4oc5ccccc5c34)cccc2c1]

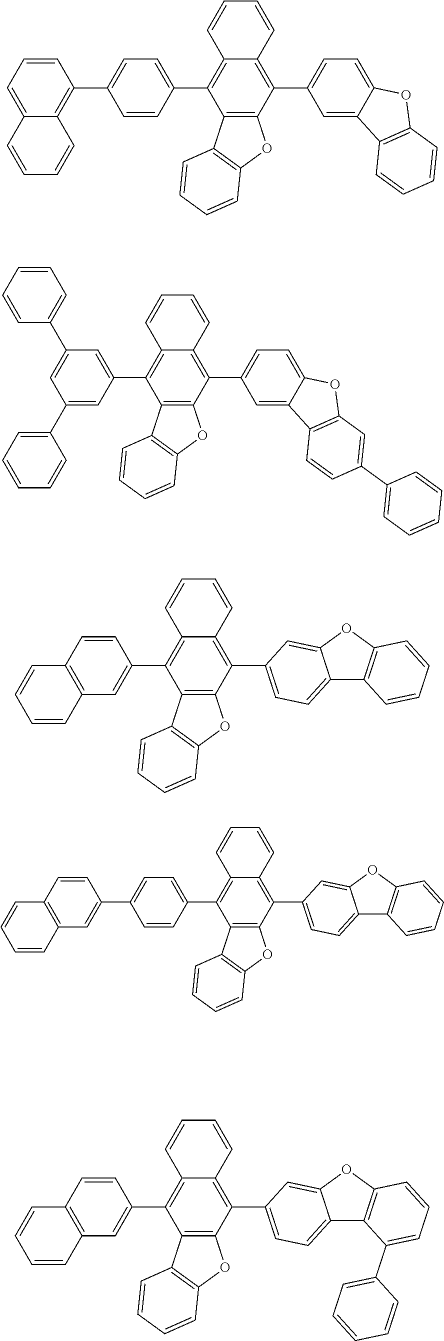 [SMILES: c1ccc2c(-c3ccc(-c4c5ccccc5c(-c5ccc6oc7ccccc7c6c5)c5oc6ccccc6c45)cc3)cccc2c1 ; c1ccc(-c2cc(-c3ccccc3)cc(-c3c4ccccc4c(-c4ccc5oc6cc(-c7ccccc7)ccc6c5c4)c4oc5ccccc5c34)c2)cc1 ; c1ccc2cc(-c3c4ccccc4c(-c4ccc5c(c4)oc4ccccc45)c4oc5ccccc5c34)ccc2c1 ; c1ccc2cc(-c3ccc(-c4c5ccccc5c(-c5ccc6c(c5)oc5ccccc56)c5oc6ccccc6c45)cc3)ccc2c1 ; c1ccc(-c2cccc3oc4cc(-c5c6ccccc6c(-c6ccc7ccccc7c6)c6c5oc5ccccc56)ccc4c23)cc1]

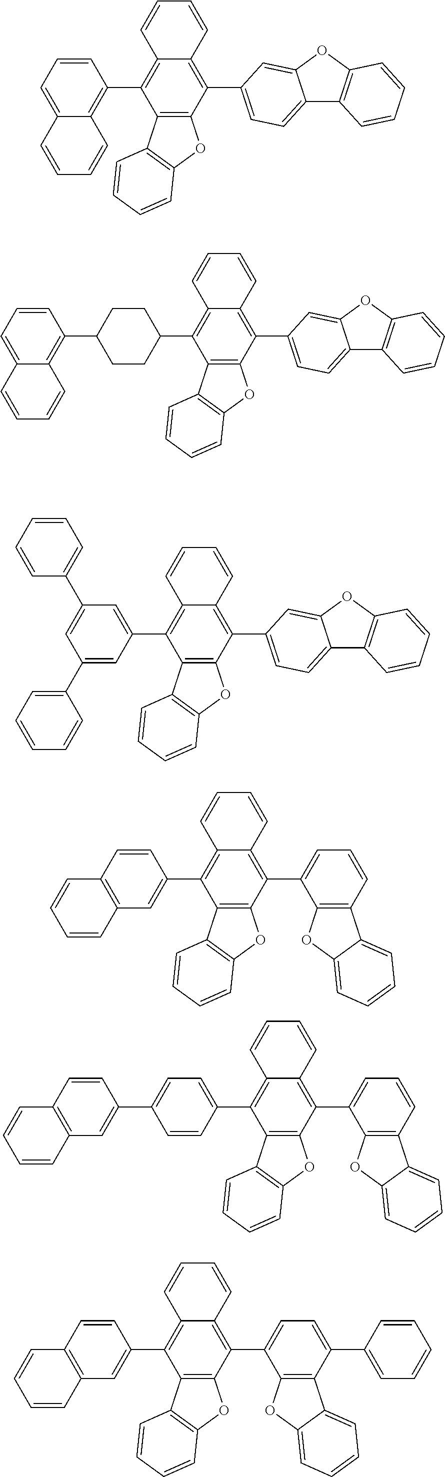

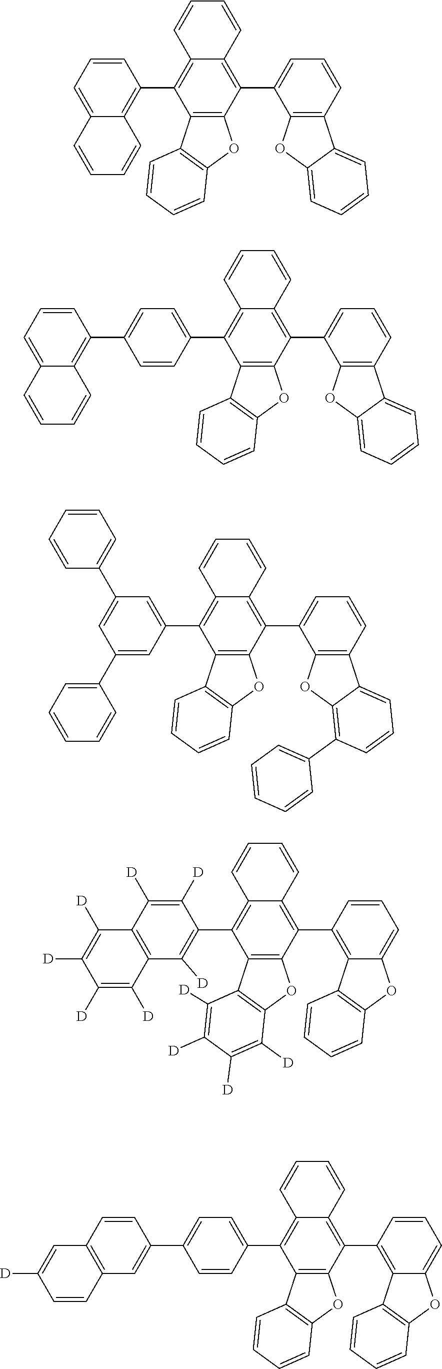

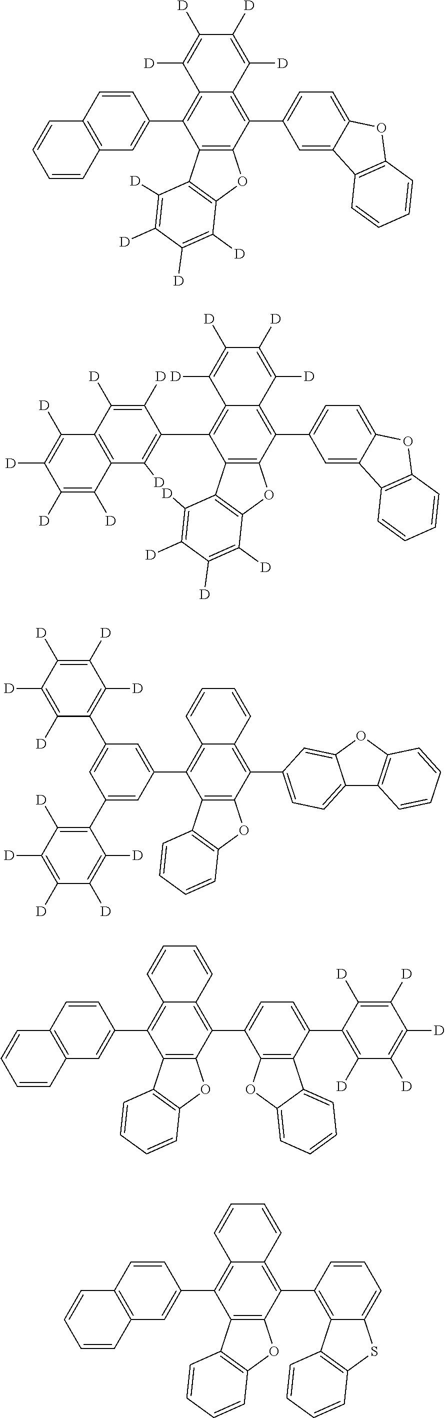

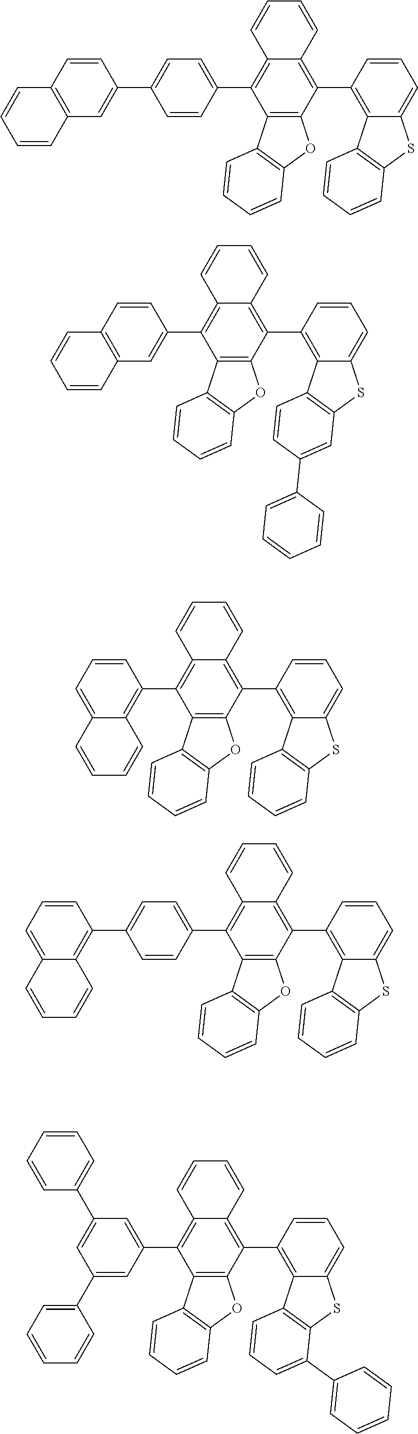

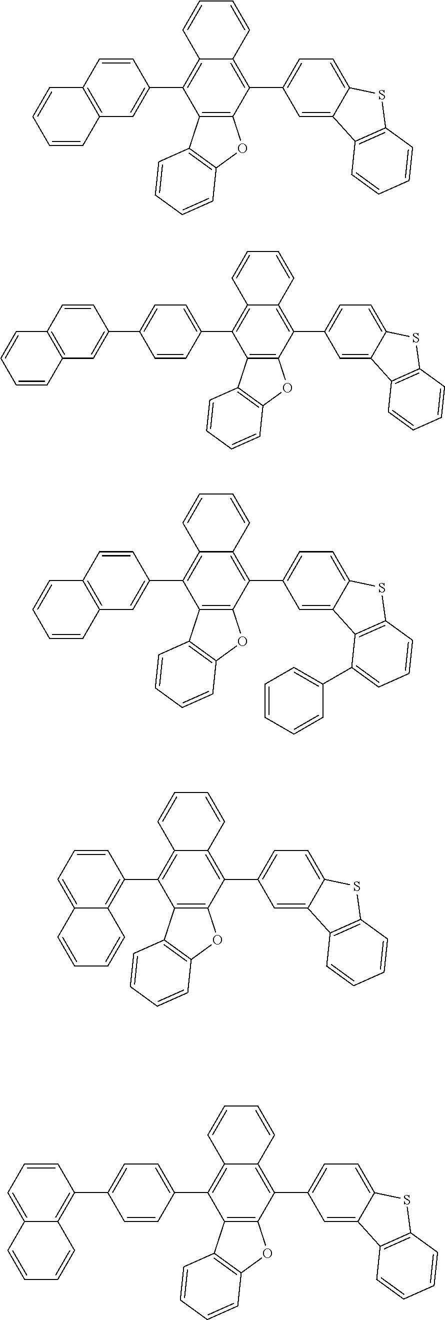

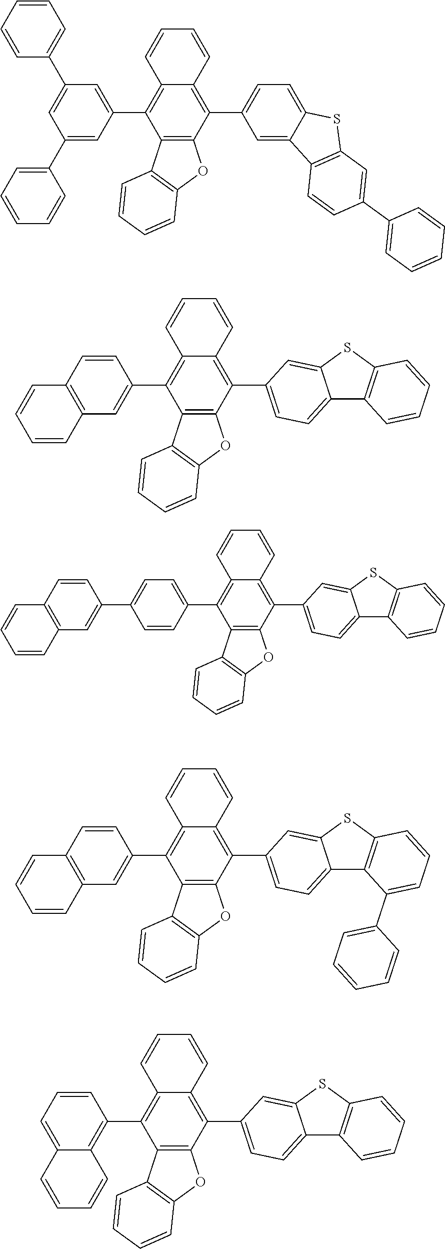 [SMILES: c1ccc(-c2cc(-c3ccccc3)cc(-c3c4ccccc4c(-c4ccc5sc6cc(-c7ccccc7)ccc6c5c4)c4oc5ccccc5c34)c2)cc1 ; c1ccc2cc(-c3c4ccccc4c(-c4ccc5c(c4)sc4ccccc45)c4oc5ccccc5c34)ccc2c1 ; c1ccc2cc(-c3ccc(-c4c5ccccc5c(-c5ccc6c(c5)sc5ccccc56)c5oc6ccccc6c45)cc3)ccc2c1 ; c1ccc(-c2cccc3sc4cc(-c5c6ccccc6c(-c6ccc7ccccc7c6)c6c5oc5ccccc56)ccc4c23)cc1 ; c1ccc2c(-c3c4ccccc4c(-c4ccc5c(c4)sc4ccccc45)c4oc5ccccc5c34)cccc2c1]

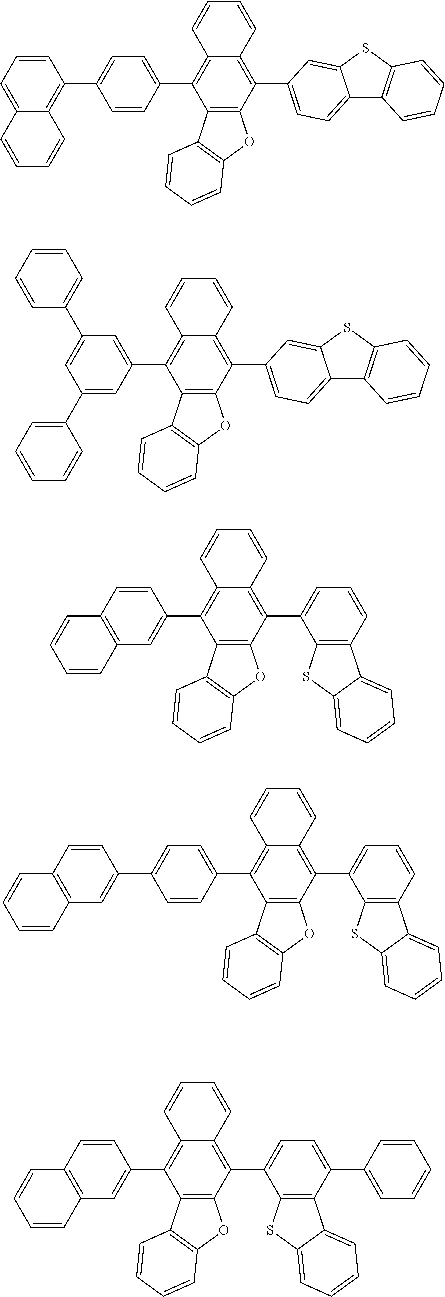 [SMILES: c1ccc2c(-c3ccc(-c4c5ccccc5c(-c5ccc6c(c5)sc5ccccc56)c5oc6ccccc6c45)cc3)cccc2c1 ; c1ccc(-c2cc(-c3ccccc3)cc(-c3c4ccccc4c(-c4ccc5c(c4)sc4ccccc45)c4oc5ccccc5c34)c2)cc1 ; c1ccc2cc(-c3c4ccccc4c(-c4cccc5c4sc4ccccc45)c4oc5ccccc5c34)ccc2c1 ; c1ccc2cc(-c3ccc(-c4c5ccccc5c(-c5cccc6c5sc5ccccc56)c5oc6ccccc6c45)cc3)ccc2c1 ; c1ccc(-c2ccc(-c3c4ccccc4c(-c4ccc5ccccc5c4)c4c3oc3ccccc34)c3sc4ccccc4c23)cc1]

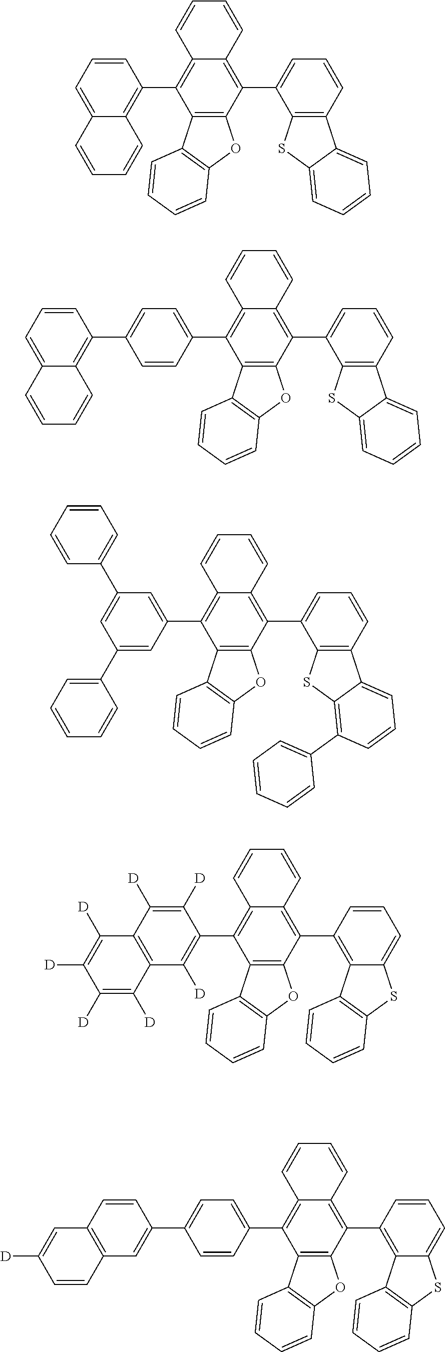

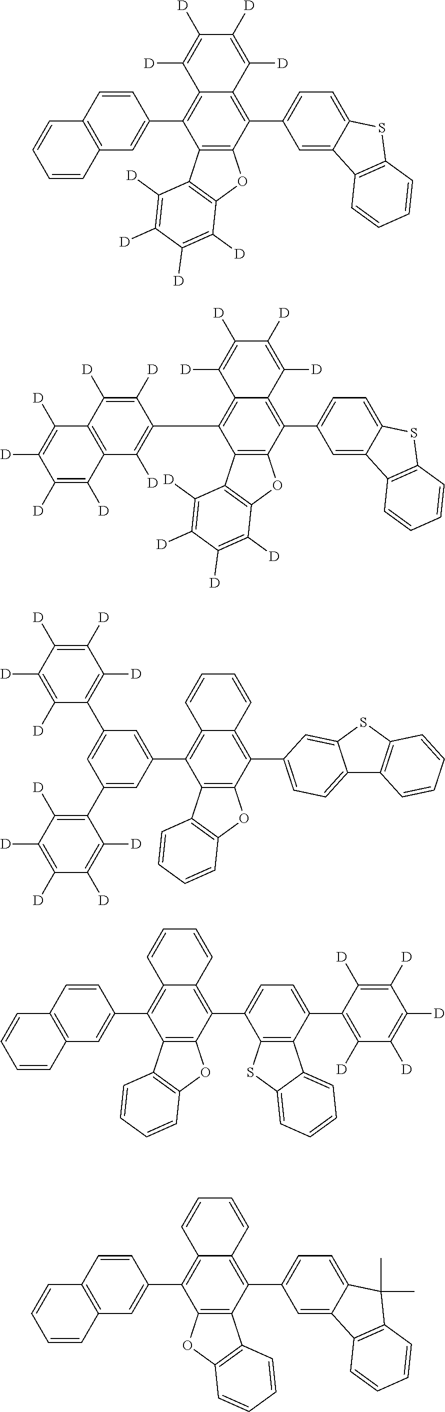

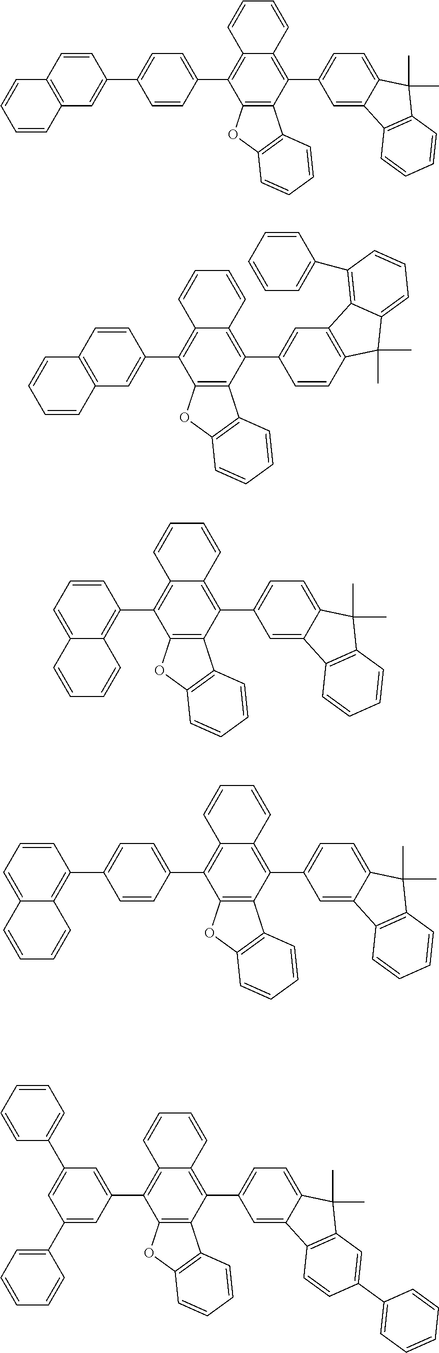

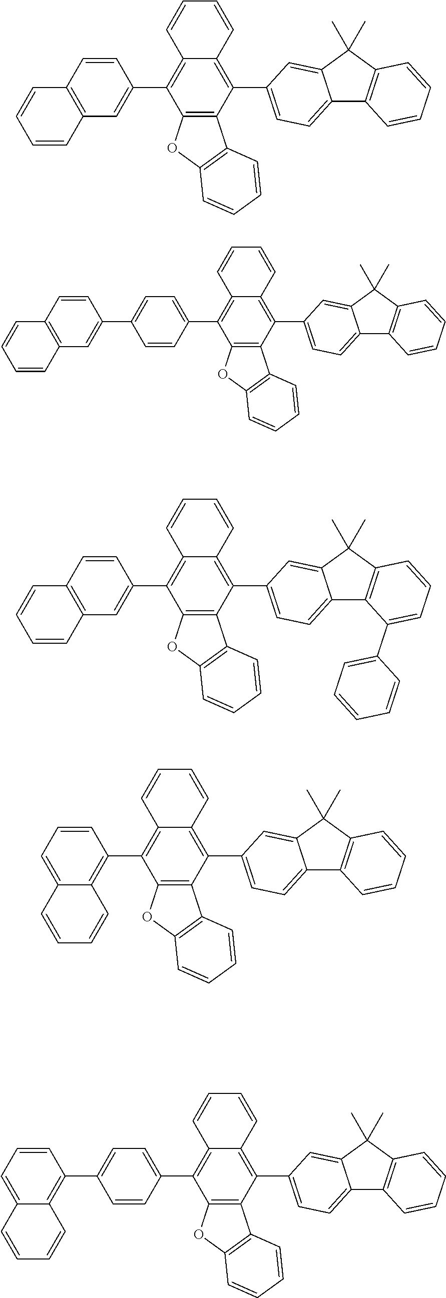

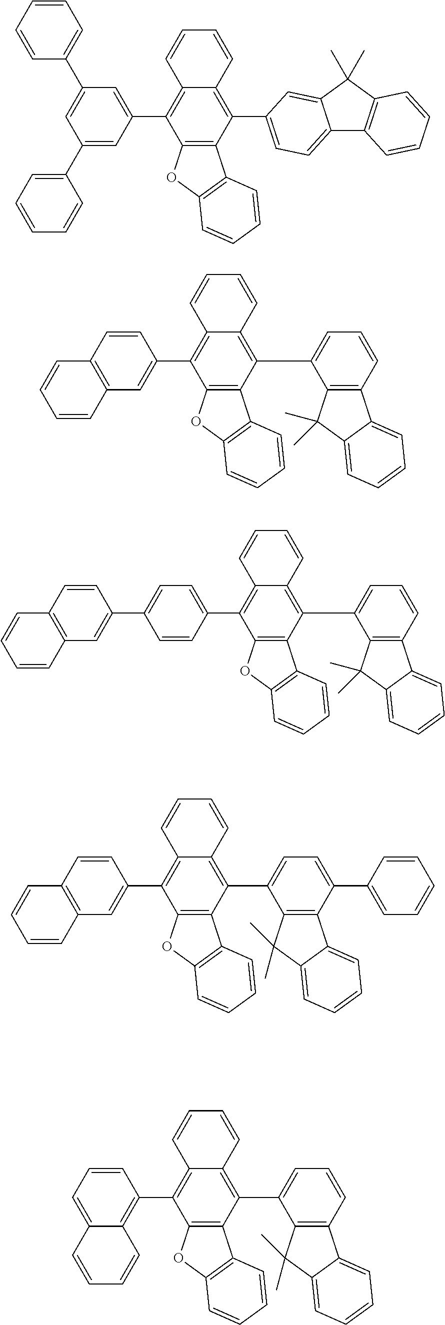

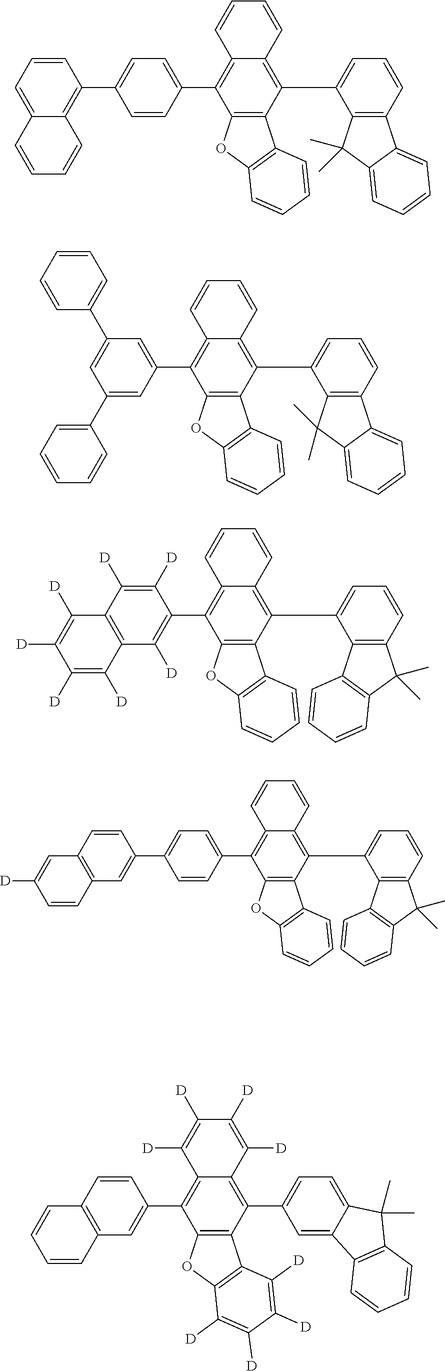

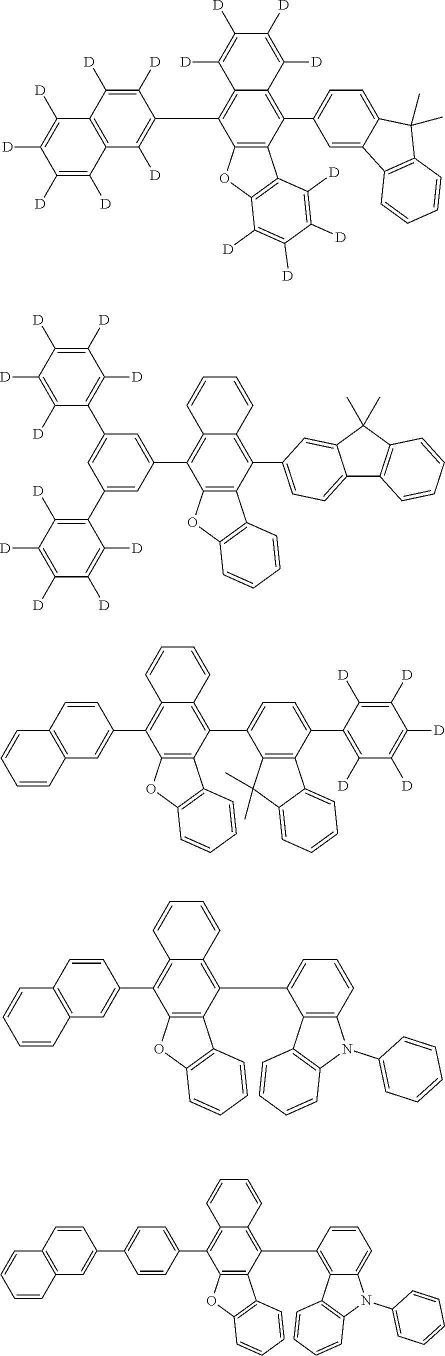

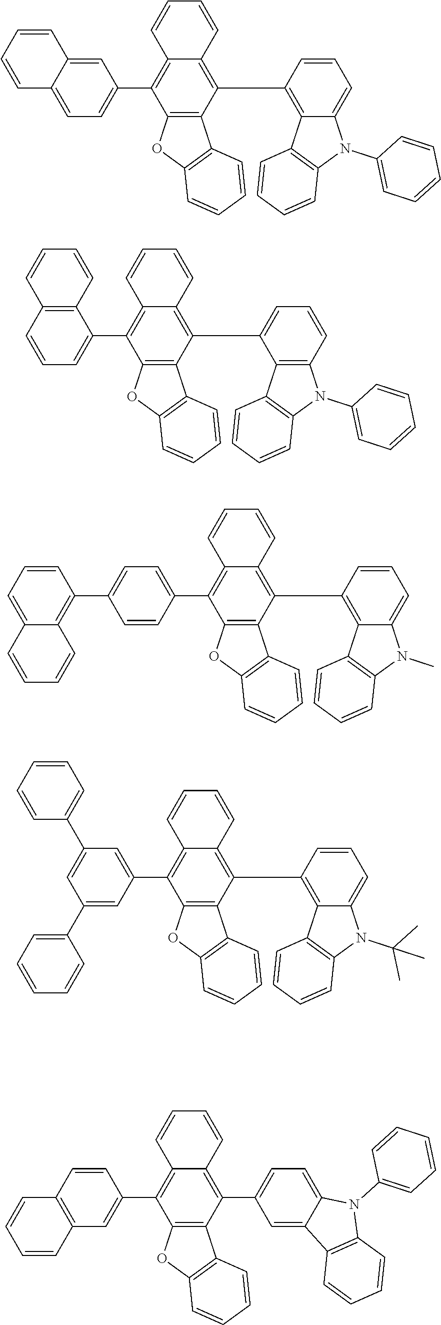

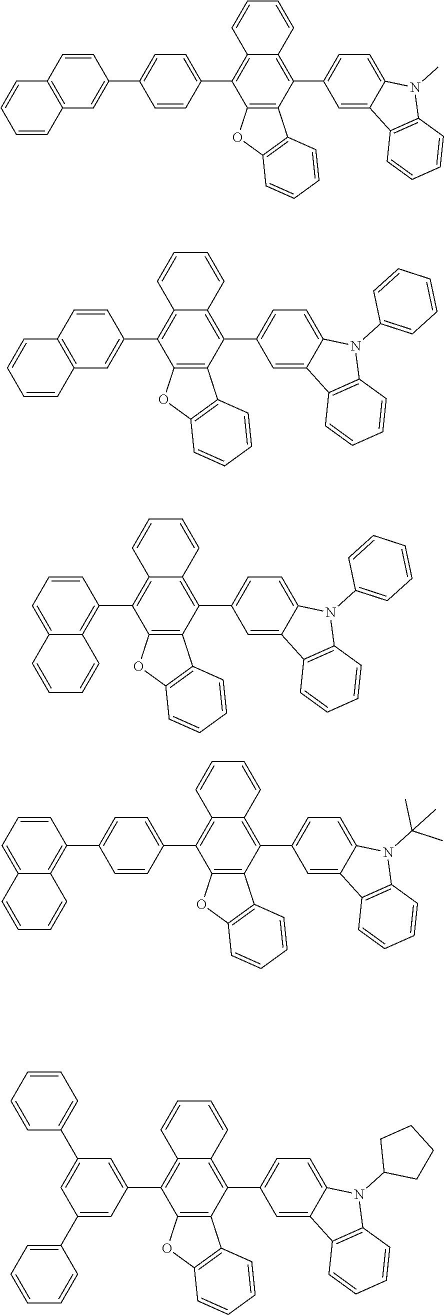

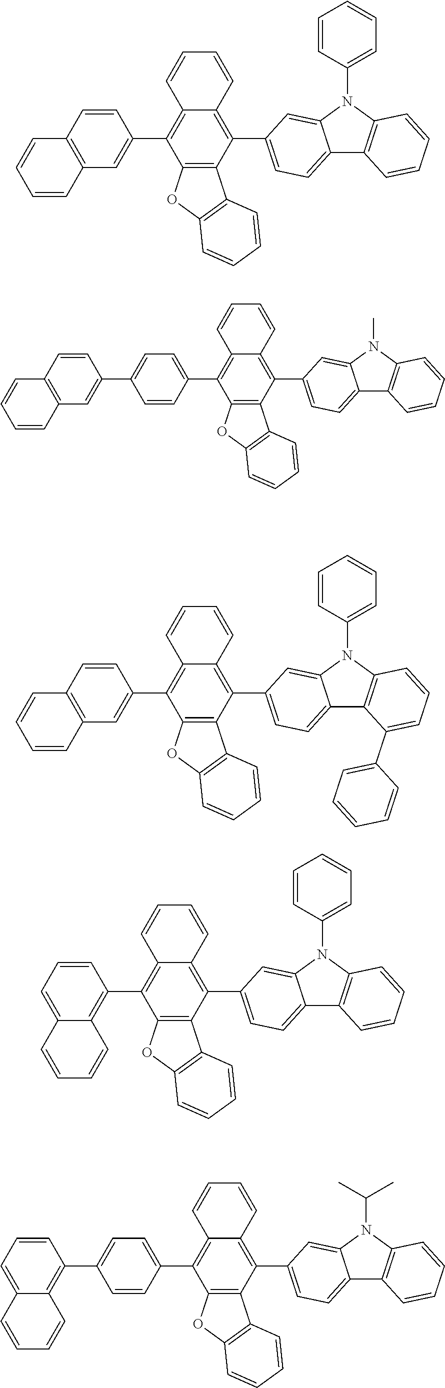

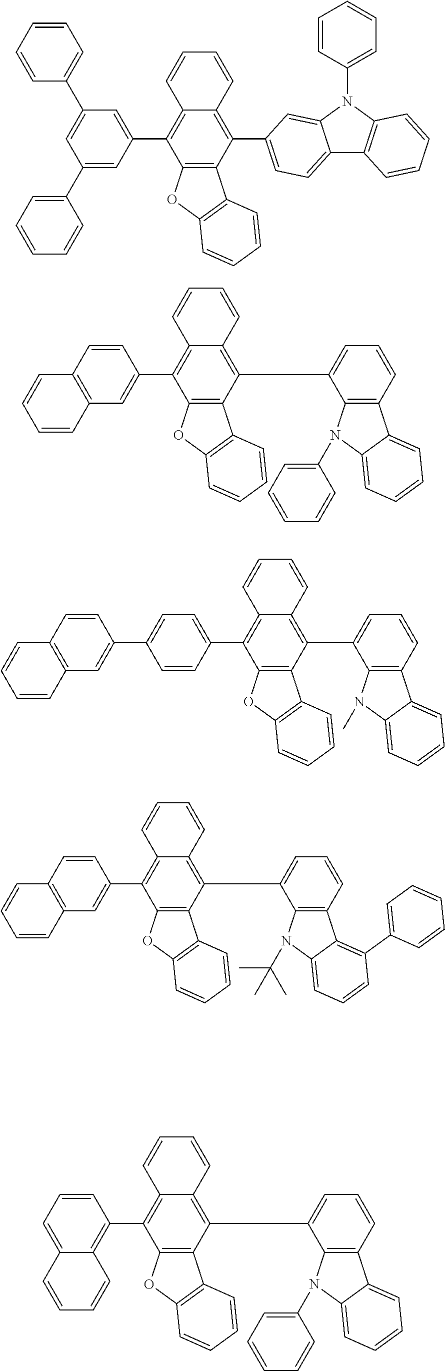

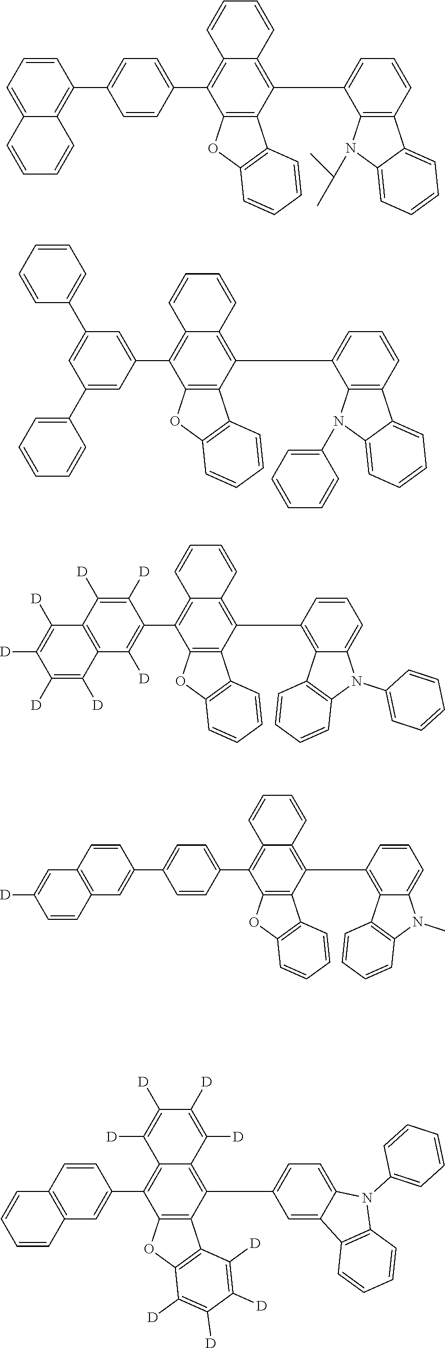 [SMILES: CC(C)n1c2ccccc2c2cccc(-c3c4ccccc4c(-c4ccc(-c5cccc6ccccc56)cc4)c4oc5ccccc5c34)c21 ; c1ccc(-c2cc(-c3ccccc3)cc(-c3c4ccccc4c(-c4cccc5c6ccccc6n(-c6ccccc6)c45)c4c3oc3ccccc34)c2)cc1 ; [2H]c1c([2H])c([2H])c2c([2H])c(-c3c4ccccc4c(-c4cccc5c4c4ccccc4n5-c4ccccc4)c4c3oc3ccccc34)c([2H])c([2H])c2c1[2H] ; [2H]c1ccc2cc(-c3ccc(-c4c5ccccc5c(-c5cccc6c5c5ccccc5n6C)c5c4oc4ccccc45)cc3)ccc2c1 ; [2H]c1c([2H])c([2H])c2c(oc3c(-c4ccc5ccccc5c4)c4c([2H])c([2H])c([2H])c([2H])c4c(-c4ccc5c(c4)c4ccccc4n5-c4ccccc4)c32)c1[2H]]

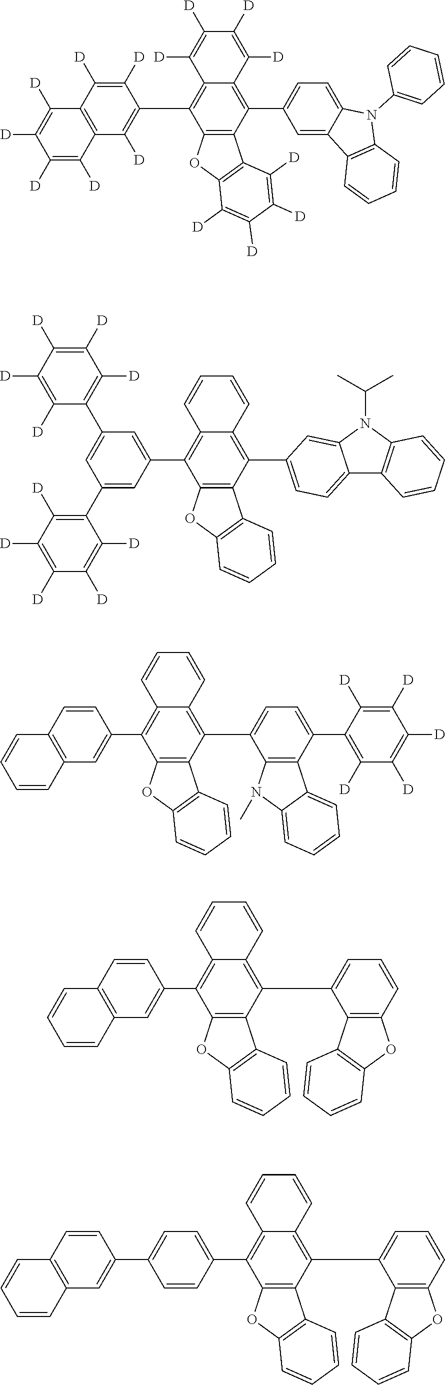

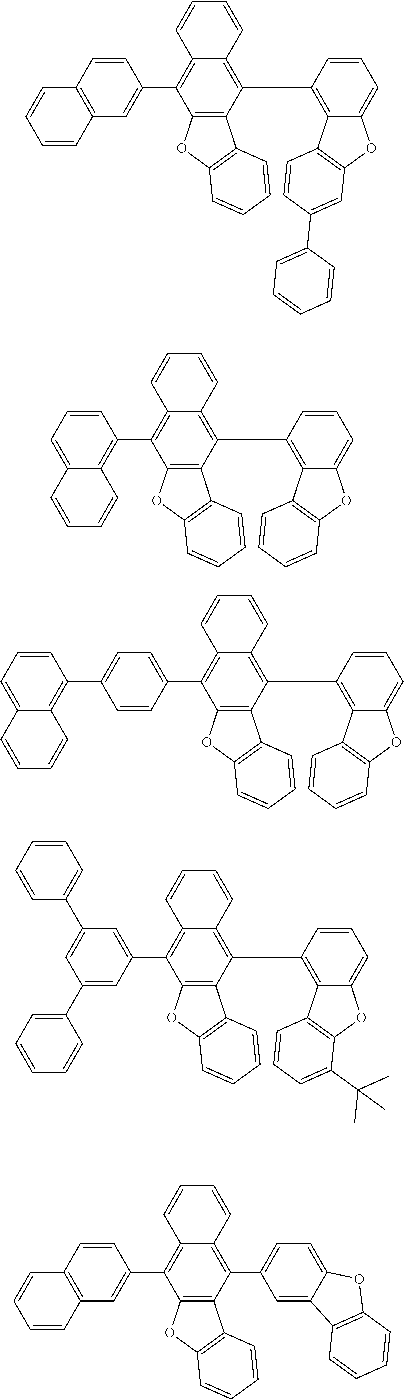

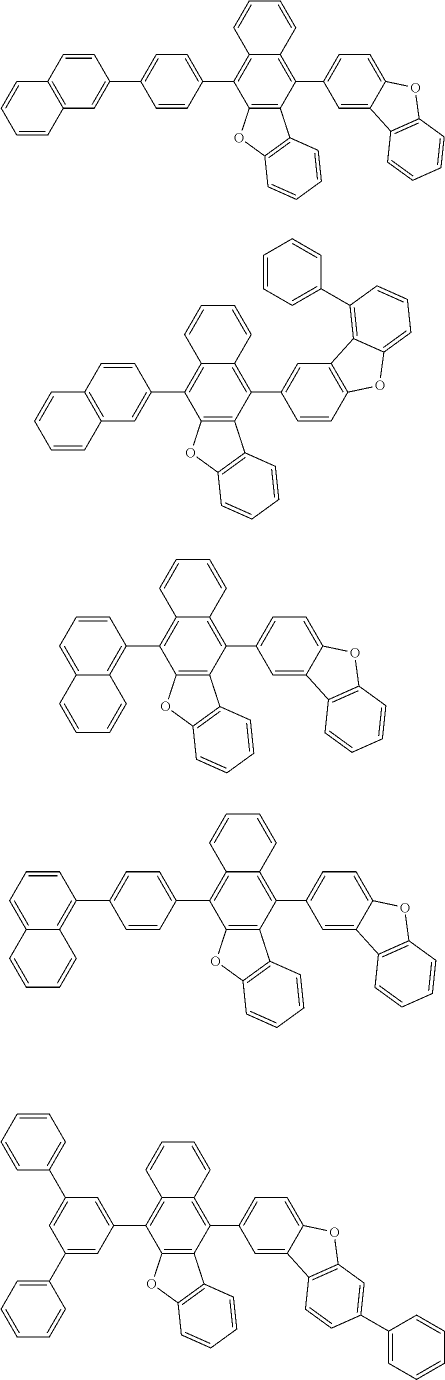

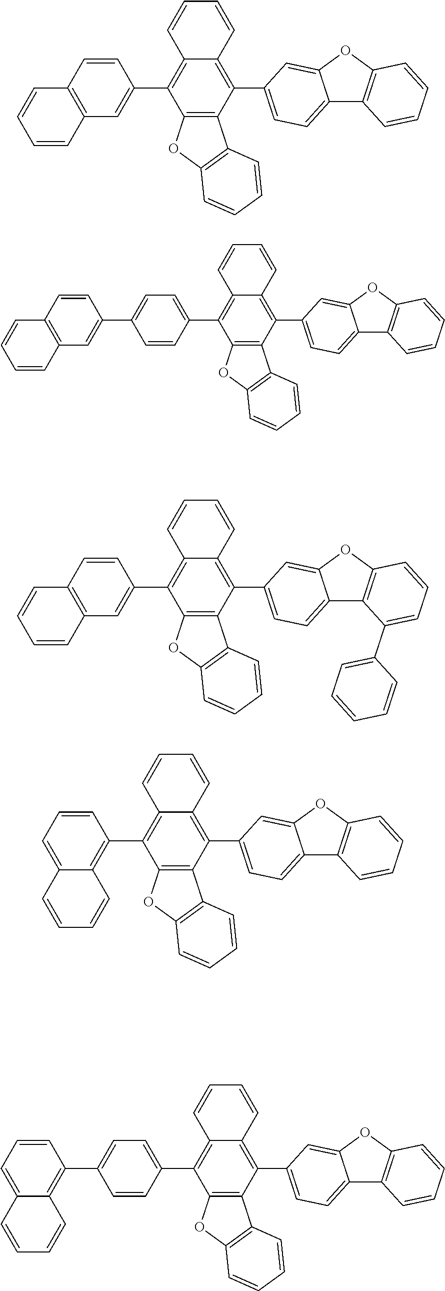

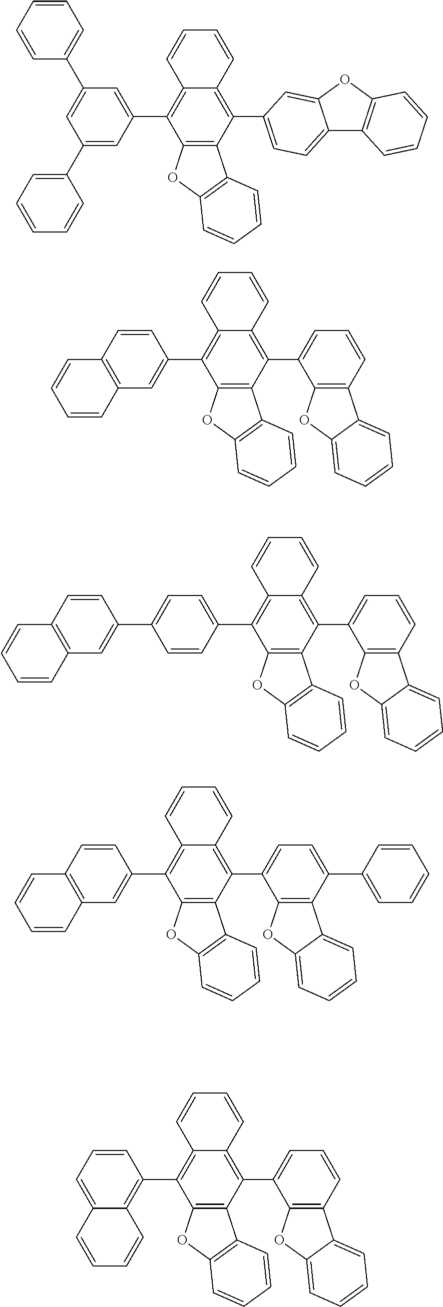

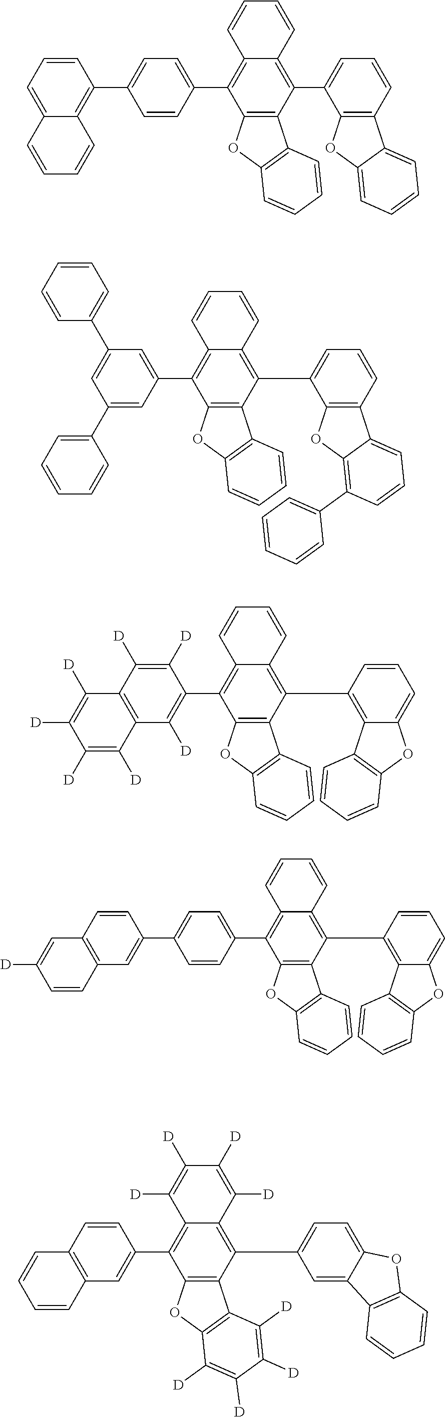

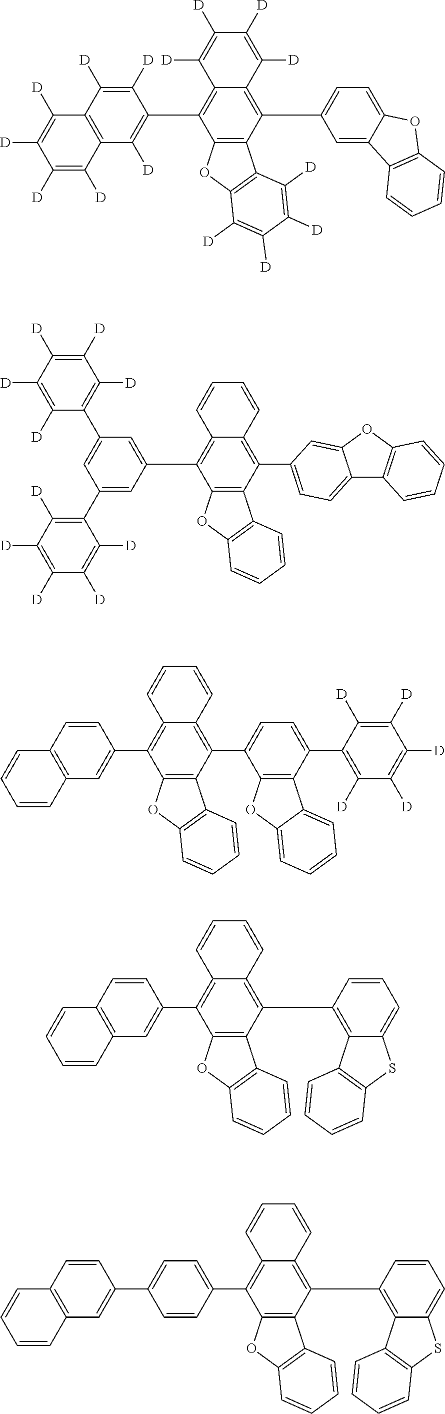

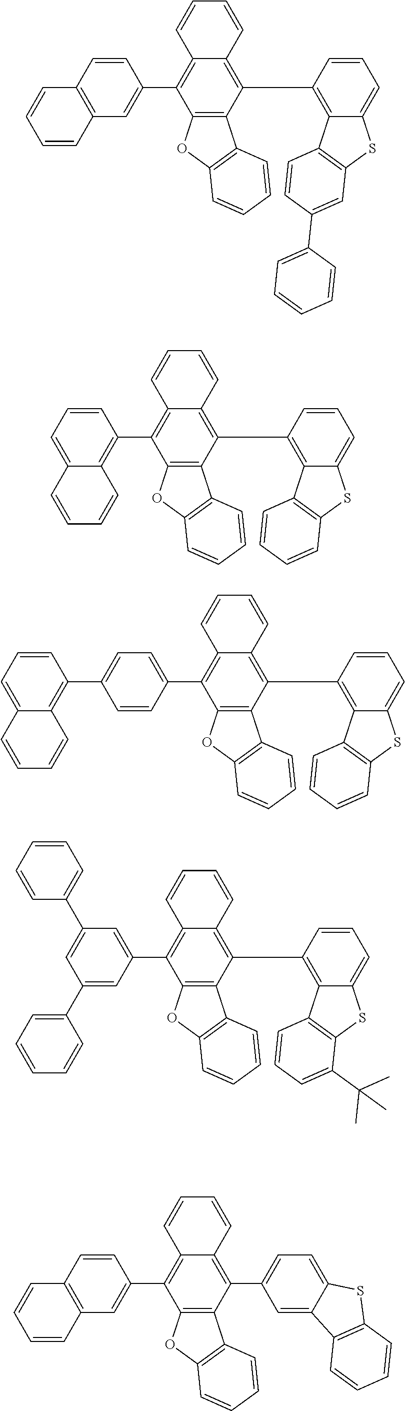

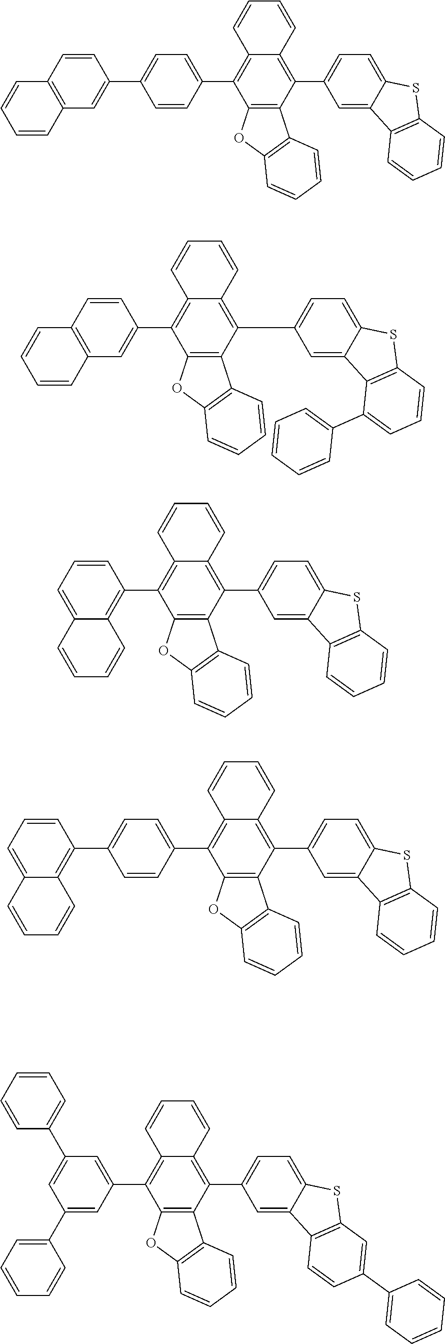

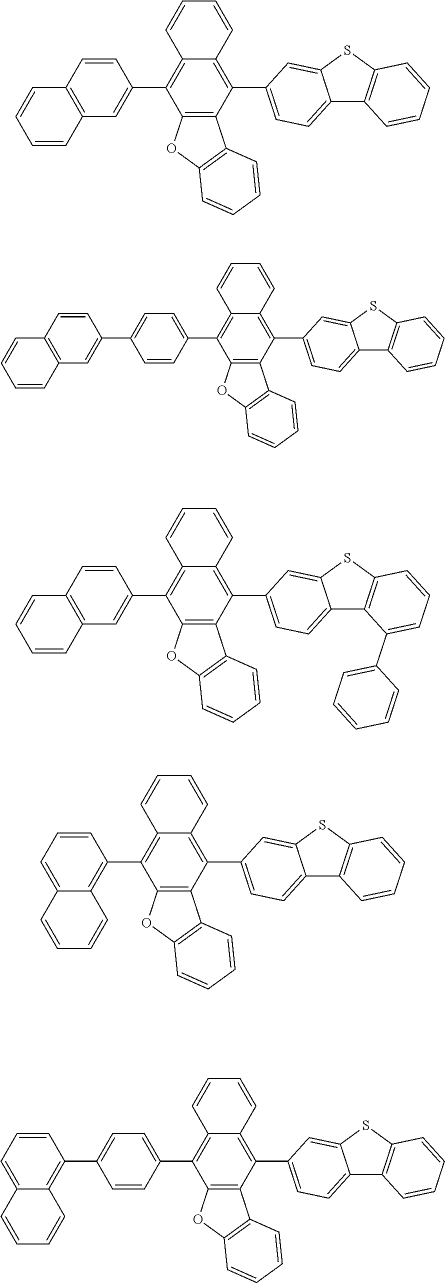 [SMILES: c1ccc2cc(-c3c4ccccc4c(-c4ccc5c(c4)sc4ccccc45)c4c3oc3ccccc34)ccc2c1 ; c1ccc2cc(-c3ccc(-c4c5ccccc5c(-c5ccc6c(c5)sc5ccccc56)c5c4oc4ccccc45)cc3)ccc2c1 ; c1ccc(-c2cccc3sc4cc(-c5c6ccccc6c(-c6ccc7ccccc7c6)c6oc7ccccc7c56)ccc4c23)cc1 ; c1ccc2c(-c3c4ccccc4c(-c4ccc5c(c4)sc4ccccc45)c4c3oc3ccccc34)cccc2c1 ; c1ccc2c(-c3ccc(-c4c5ccccc5c(-c5ccc6c(c5)sc5ccccc56)c5c4oc4ccccc45)cc3)cccc2c1]

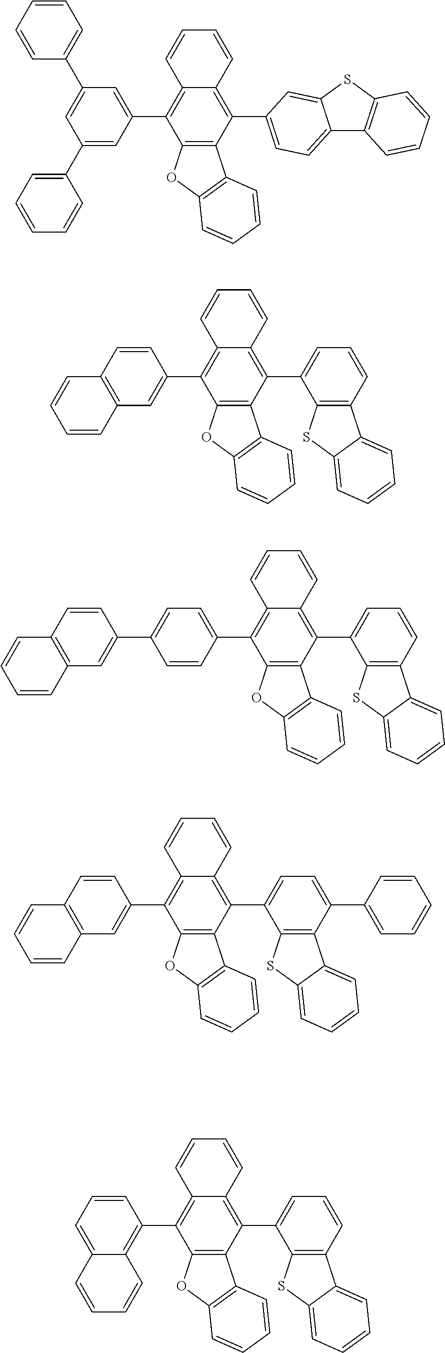 [SMILES: c1ccc(-c2cc(-c3ccccc3)cc(-c3c4ccccc4c(-c4ccc5c(c4)sc4ccccc45)c4c3oc3ccccc34)c2)cc1 ; c1ccc2cc(-c3c4ccccc4c(-c4cccc5c4sc4ccccc45)c4c3oc3ccccc34)ccc2c1 ; c1ccc2cc(-c3ccc(-c4c5ccccc5c(-c5cccc6c5sc5ccccc56)c5c4oc4ccccc45)cc3)ccc2c1 ; c1ccc(-c2ccc(-c3c4ccccc4c(-c4ccc5ccccc5c4)c4oc5ccccc5c34)c3sc4ccccc4c23)cc1 ; c1ccc2c(-c3c4ccccc4c(-c4cccc5c4sc4ccccc45)c4c3oc3ccccc34)cccc2c1]

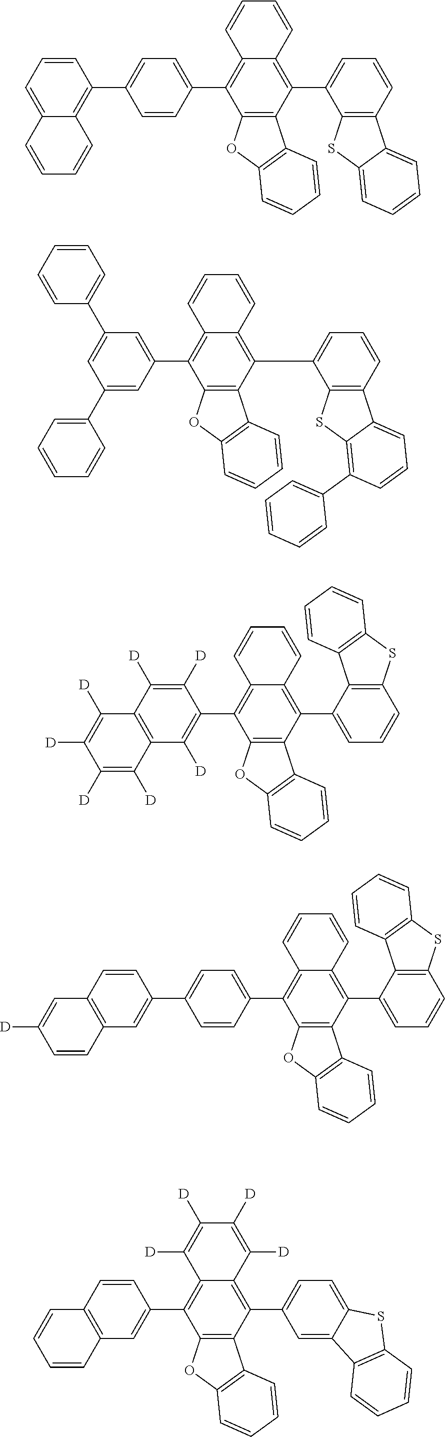 [SMILES: c1ccc2c(-c3ccc(-c4c5ccccc5c(-c5cccc6c5sc5ccccc56)c5c4oc4ccccc45)cc3)cccc2c1 ; c1ccc(-c2cc(-c3ccccc3)cc(-c3c4ccccc4c(-c4cccc5c4sc4c(-c6ccccc6)cccc45)c4c3oc3ccccc34)c2)cc1 ; [2H]c1c([2H])c([2H])c2c([2H])c(-c3c4ccccc4c(-c4cccc5sc6ccccc6c45)c4c3oc3ccccc34)c([2H])c([2H])c2c1[2H] ; [2H]c1ccc2cc(-c3ccc(-c4c5ccccc5c(-c5cccc6sc7ccccc7c56)c5c4oc4ccccc45)cc3)ccc2c1 ; [2H]c1c([2H])c([2H])c2c(-c3ccc4sc5ccccc5c4c3)c3c(oc4ccccc43)c(-c3ccc4ccccc4c3)c2c1[2H]]

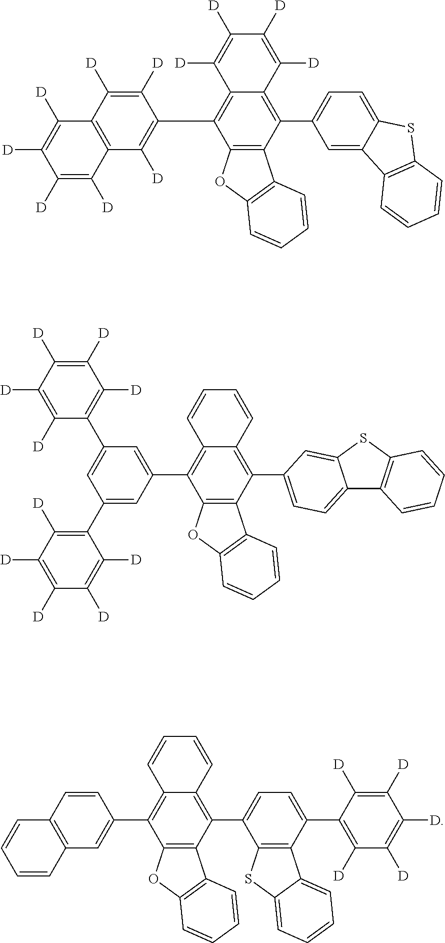

14. A mixture comprising at least one composition according to claim 1 and an organic functional material, the organic functional material being selected from at least one of a hole transport material, a hole injection material, a hole blocking material, an electron injection material, an electron transport material, a host material or a guest material.

15. The mixture according to claim 14, wherein the organic functional material comprises at least one third compound, and the third compound is selected from a structure represented by any one of formulae (3-1) to (3-2): 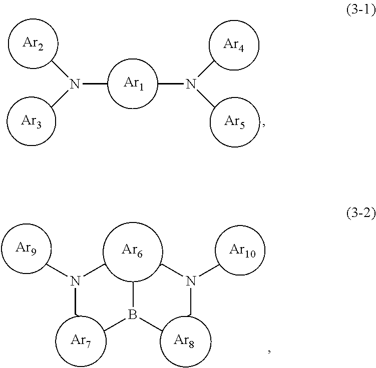
wherein each of Ar₁ to Ar₁₀ is independently selected from a substituted or unsubstituted aromatic group having 6 to 40 ring atoms, or a substituted or unsubstituted heteroaromatic group having 5 to 40 ring atoms, two adjacent ones of Ar₁ to Ar₅ form a ring or not, and two adjacent ones of Ar₆ to Ar₁₀ form a ring or not.

16. The mixture according to claim 15, wherein Ar₁ is independently selected from a structure represented by any one of formulae (H-1) to (H-3): 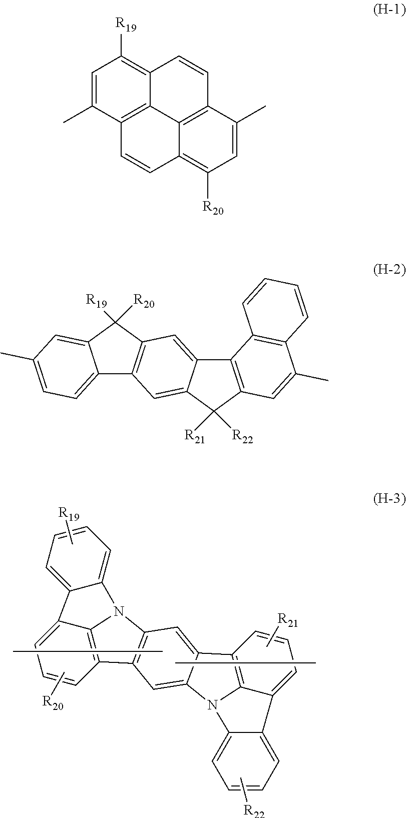
wherein R₁₉, R₂₀, R₂₁ and R₂₂ are each independently selected from —H, -D, a substituted or unsubstituted linear alkyl group having 1 to 20 carbon atoms, a substituted or unsubstituted alkoxy group having 1 to 20 carbon atoms, a substituted or unsubstituted thioalkoxy group having 1 to 20 carbon atoms, a substituted or unsubstituted branched or cyclic alkyl group having 3 to 20 carbon atoms, a substituted or unsubstituted alkoxy group having 3 to 20 carbon atoms, a substituted or unsubstituted thioalkoxy group having 3 to 20 carbon atoms, a silyl group, a substituted or unsubstituted keto group having 1 to 20 carbon atoms, a substituted or unsubstituted alkoxycarbonyl group having 2 to 20 carbon atoms, a substituted or unsubstituted aryloxycarbonyl group having 7 to 20 carbon atoms, a cyano group, a carbamoyl group, a haloformyl group, a formyl group, an isocyano group, an isocyanate group, a thiocyanate group, an isothiocyanate group, a hydroxyl group, a nitro group, an amino group, —CF₃, —Cl, —Br, —F, —I, a substituted or unsubstituted alkenyl having 2 to 20 carbon atoms, a substituted or unsubstituted aromatic group having 6 to 30 ring atoms, a substituted or unsubstituted heteroaromatic groups having 5 to 30 ring atoms, a substituted or unsubstituted aryloxy group having 6 to 30 ring atoms, a substituted or unsubstituted heteroaryloxy group having 5 to 30 ring atoms, or a combinations thereof.

17. The mixture according to claim 15, wherein each of Ar₂ to Ar₁₀ is independently selected from: 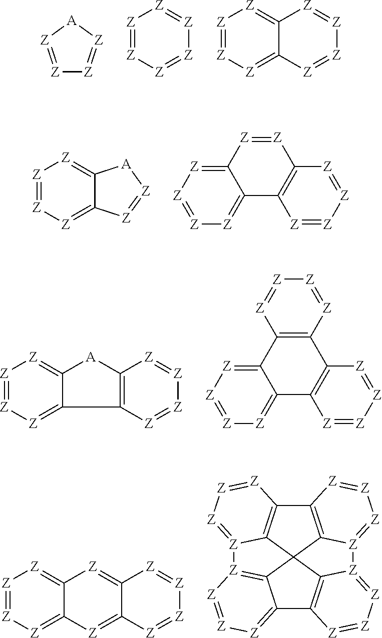
wherein Z is independently selected from CR₂₃ or N;
A is independently selected from NR₂₄, PR₂₄, CR₂₄R₂₅, SiR₂₄R₂₅, O, S, S(═O)₂ or S(═O);
R₂₃, R₂₄ and R₂₅ are each independently selected from —H, -D, a substituted or unsubstituted linear alkyl group having 1 to 20 carbon atoms, a substituted or unsubstituted alkoxy group having 1 to 20 carbon atoms, a substituted or unsubstituted thioalkoxy group having 1 to 20 carbon atoms, a substituted or unsubstituted branched or cyclic alkyl group having 3 to 20 carbon atoms, a substituted or unsubstituted alkoxy group having 3 to 20 carbon atoms, a substituted or unsubstituted thioalkoxy group having 3 to 20 carbon atoms, a silyl group, a substituted or unsubstituted keto group having 1 to 20 carbon atoms, a substituted or unsubstituted alkoxycarbonyl group having 2 to 20 carbon atoms, a substituted or unsubstituted aryloxycarbonyl group having 7 to 20 carbon atoms, a cyano group, a carbamoyl group, a haloformyl group, a formyl group, an isocyano group, an isocyanate group, a thiocyanate group, an isothiocyanate group, a hydroxyl group, a nitro group, an amino group, —CF₃, —Cl, —Br, —F, —I, a substituted or unsubstituted alkenyl having 2 to 20 carbon atoms, a substituted or unsubstituted aromatic group having 6 to 30 ring atoms, a substituted or unsubstituted heteroaromatic groups having 5 to 30 ring atoms, a substituted or unsubstituted aryloxy group having 6 to 30 ring atoms, a substituted or unsubstituted heteroaryloxy group having 5 to 30 ring atoms, or a combinations thereof.

18. The mixture according to claim 15, wherein the third compound is selected from:

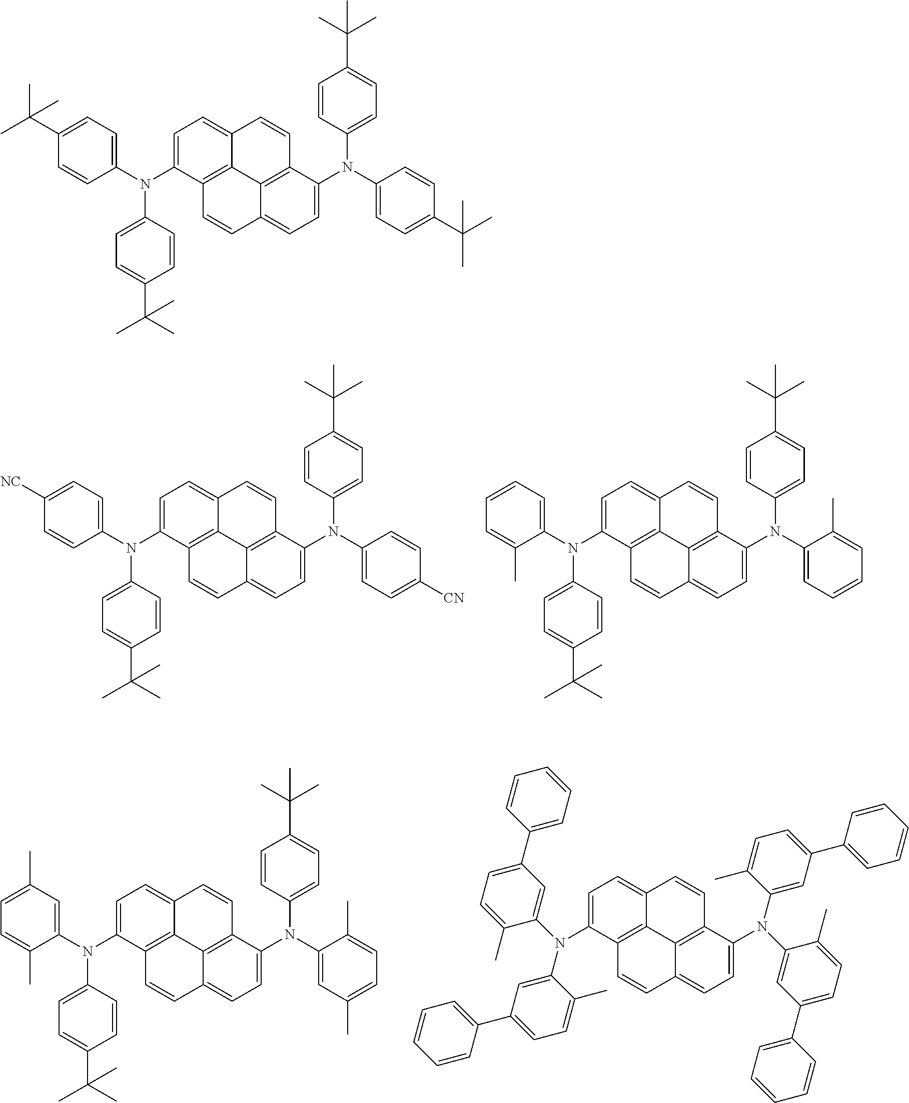

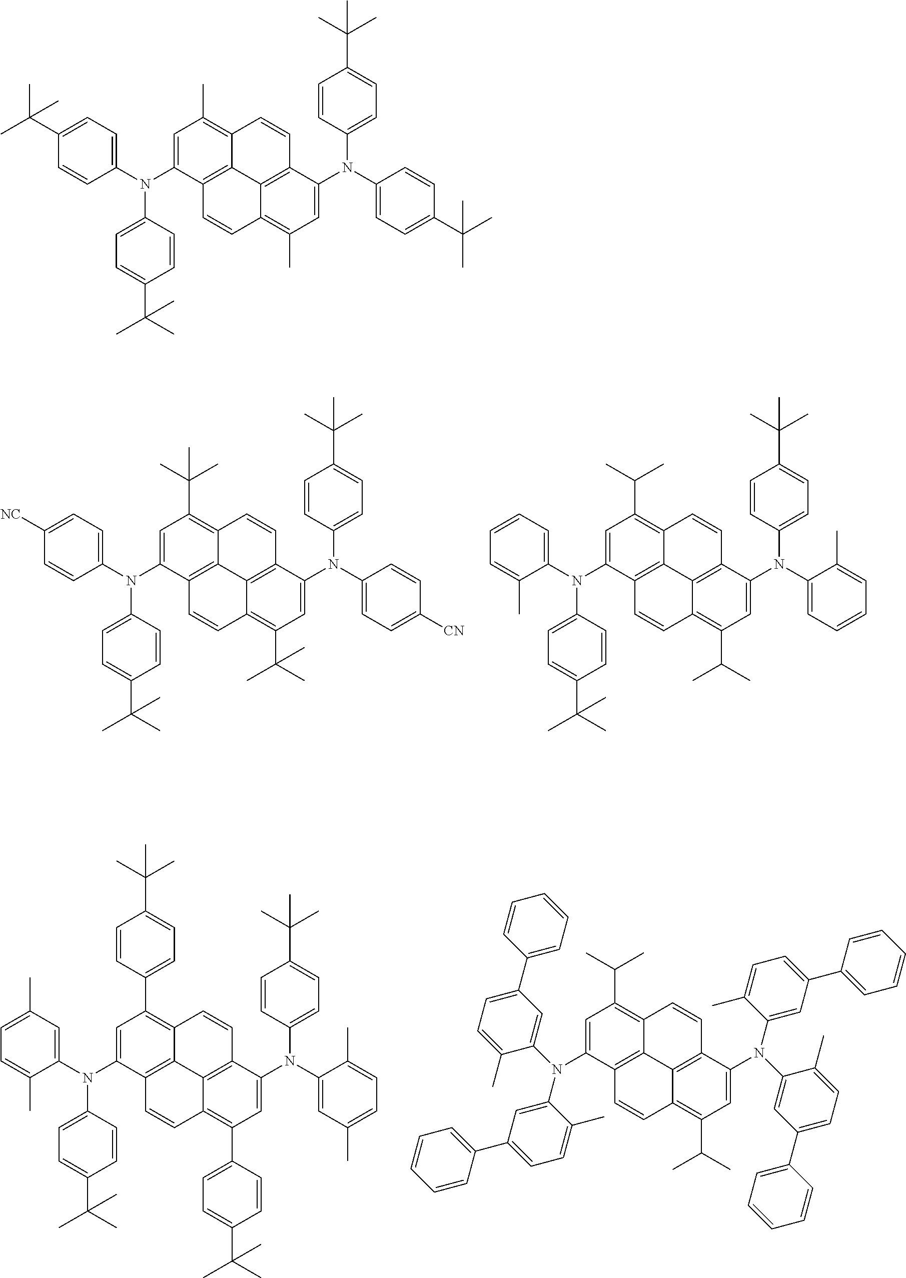

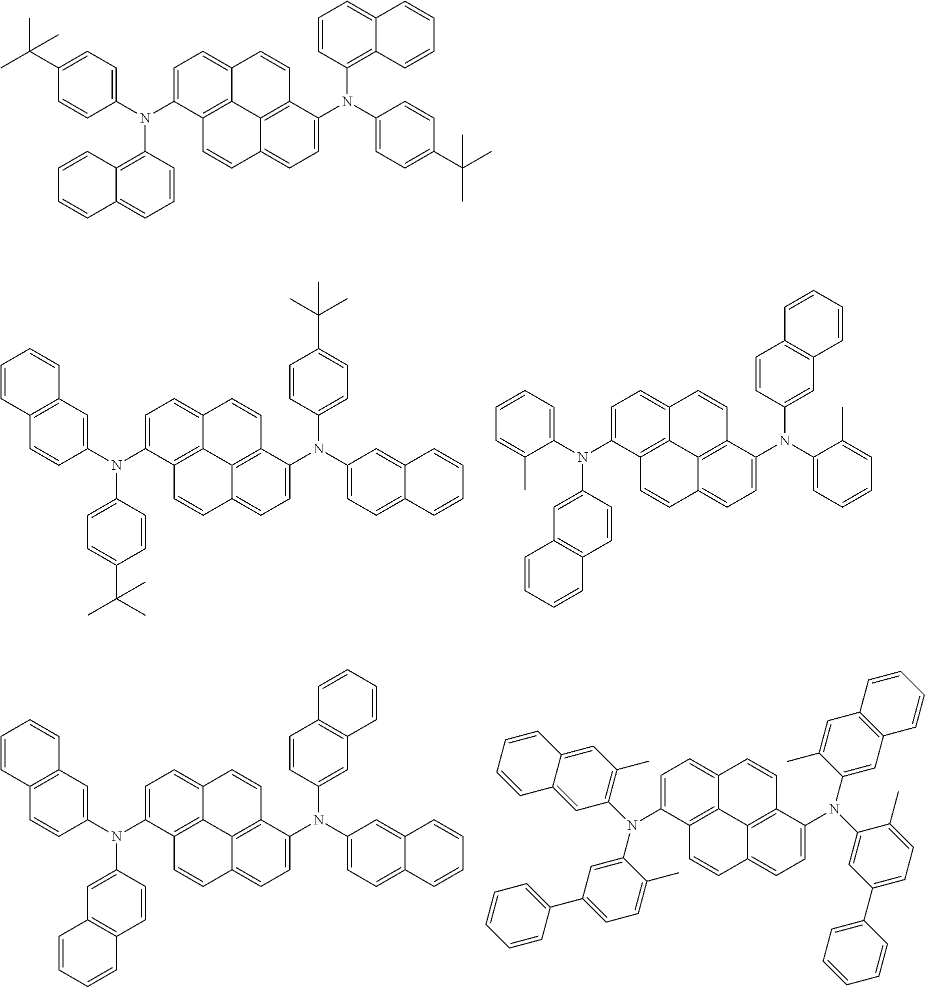

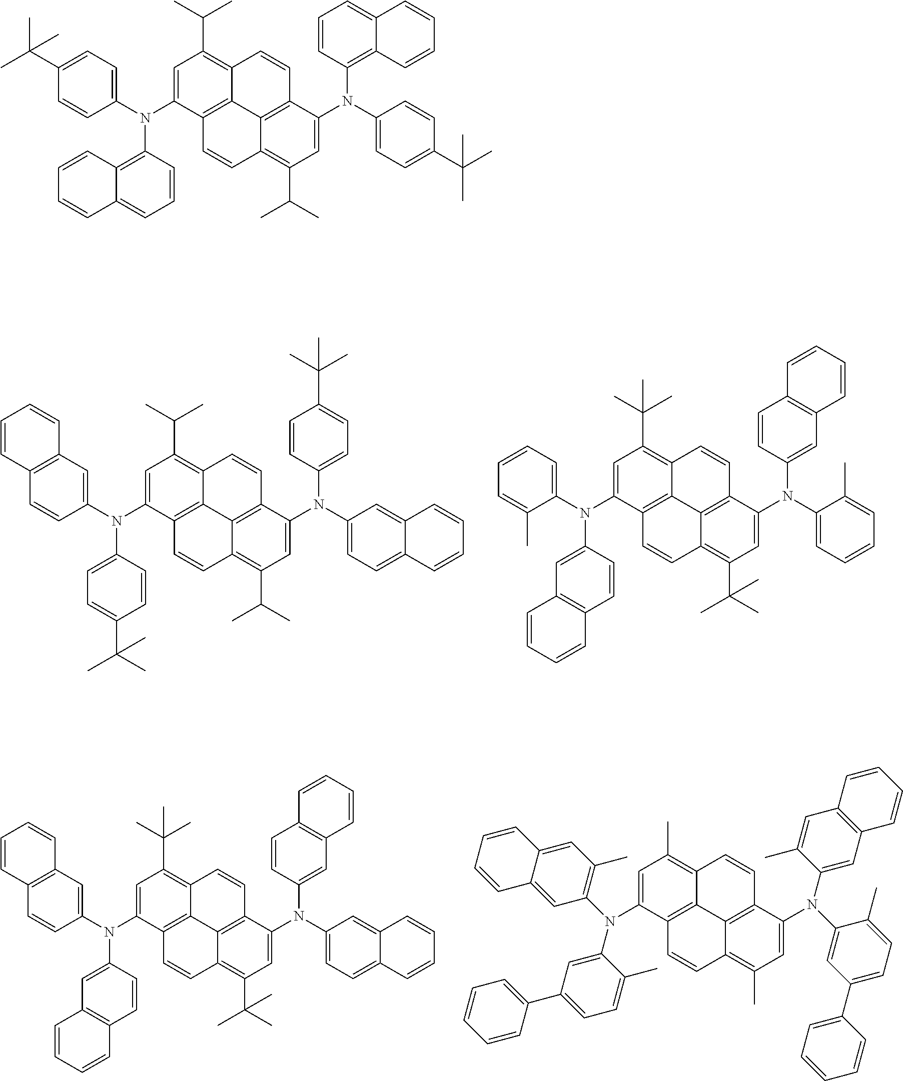

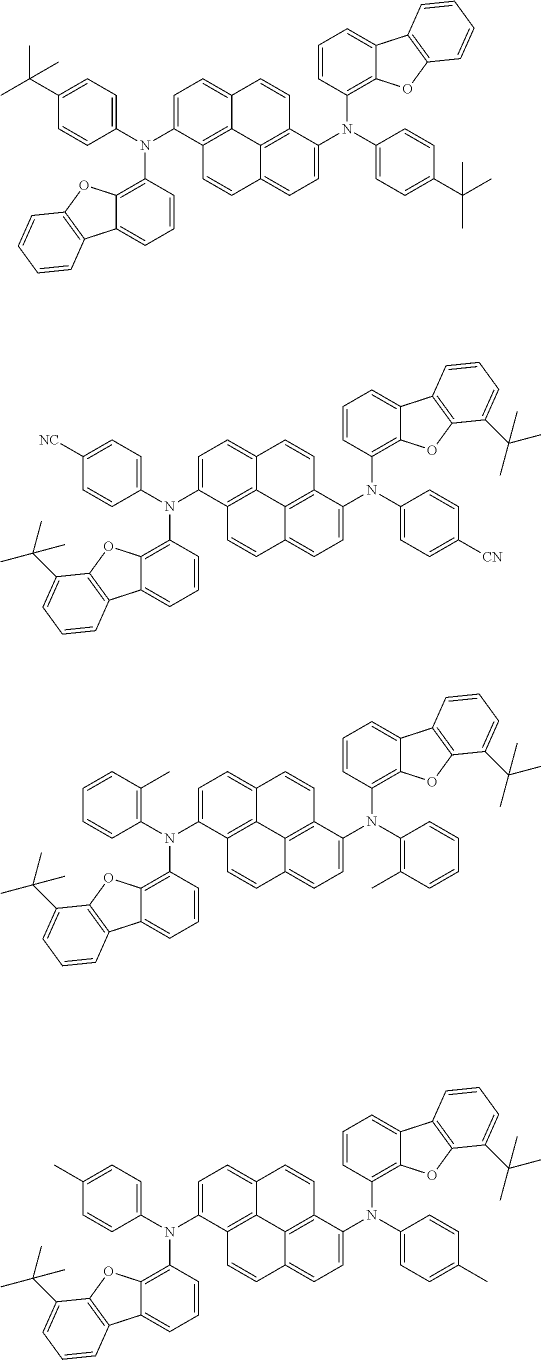

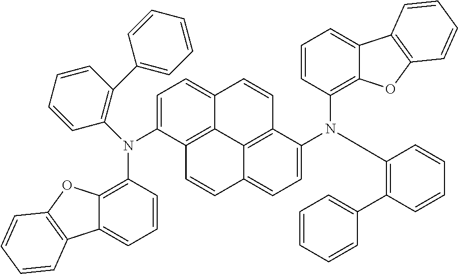 [SMILES: c1ccc(-c2ccccc2N(c2ccc3ccc4c(N(c5ccccc5-c5ccccc5)c5cccc6c5oc5ccccc56)ccc5ccc2c3c54)c2cccc3c2oc2ccccc23)cc1]

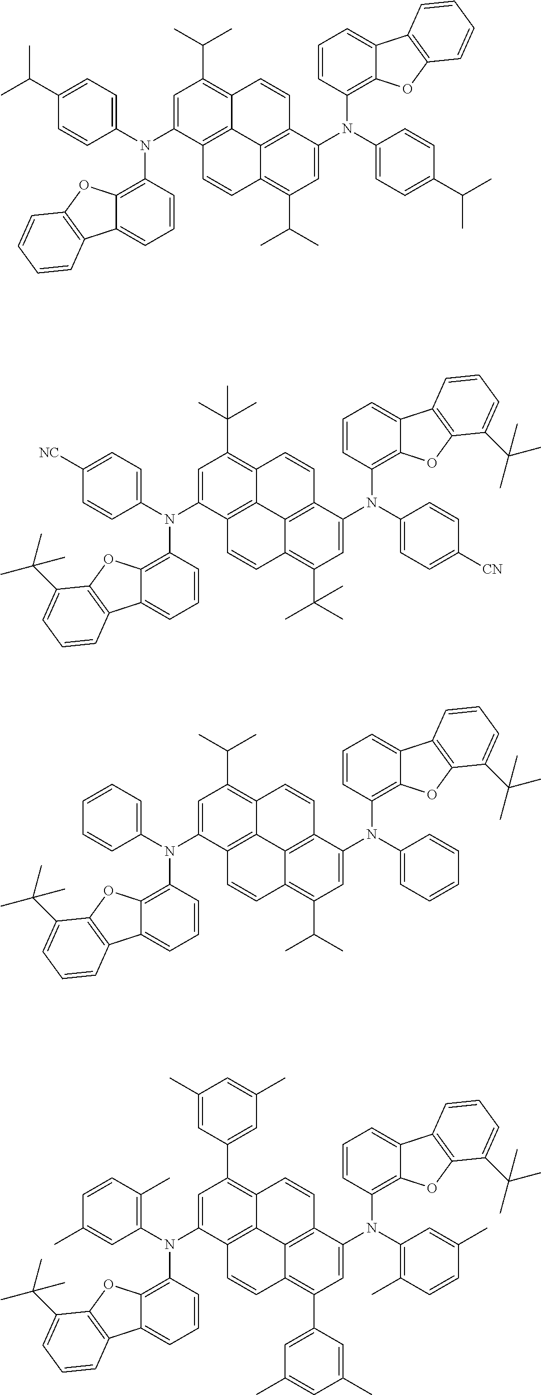

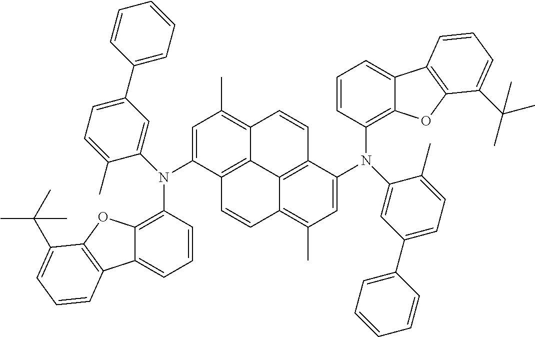 [SMILES: Cc1ccc(-c2ccccc2)cc1N(c1cc(C)c2ccc3c(N(c4cc(-c5ccccc5)ccc4C)c4cccc5c4oc4c(C(C)(C)C)cccc45)cc(C)c4ccc1c2c43)c1cccc2c1oc1c(C(C)(C)C)cccc12]

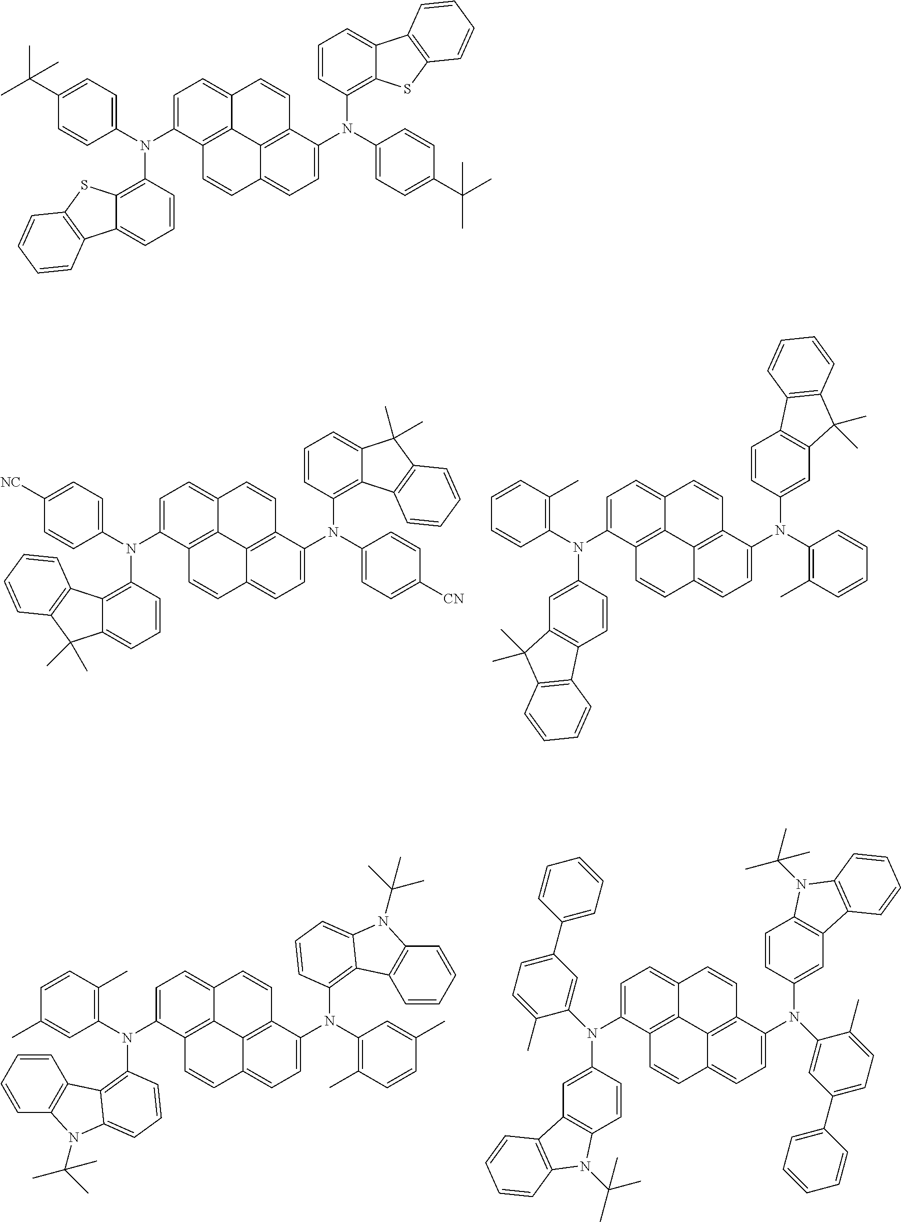

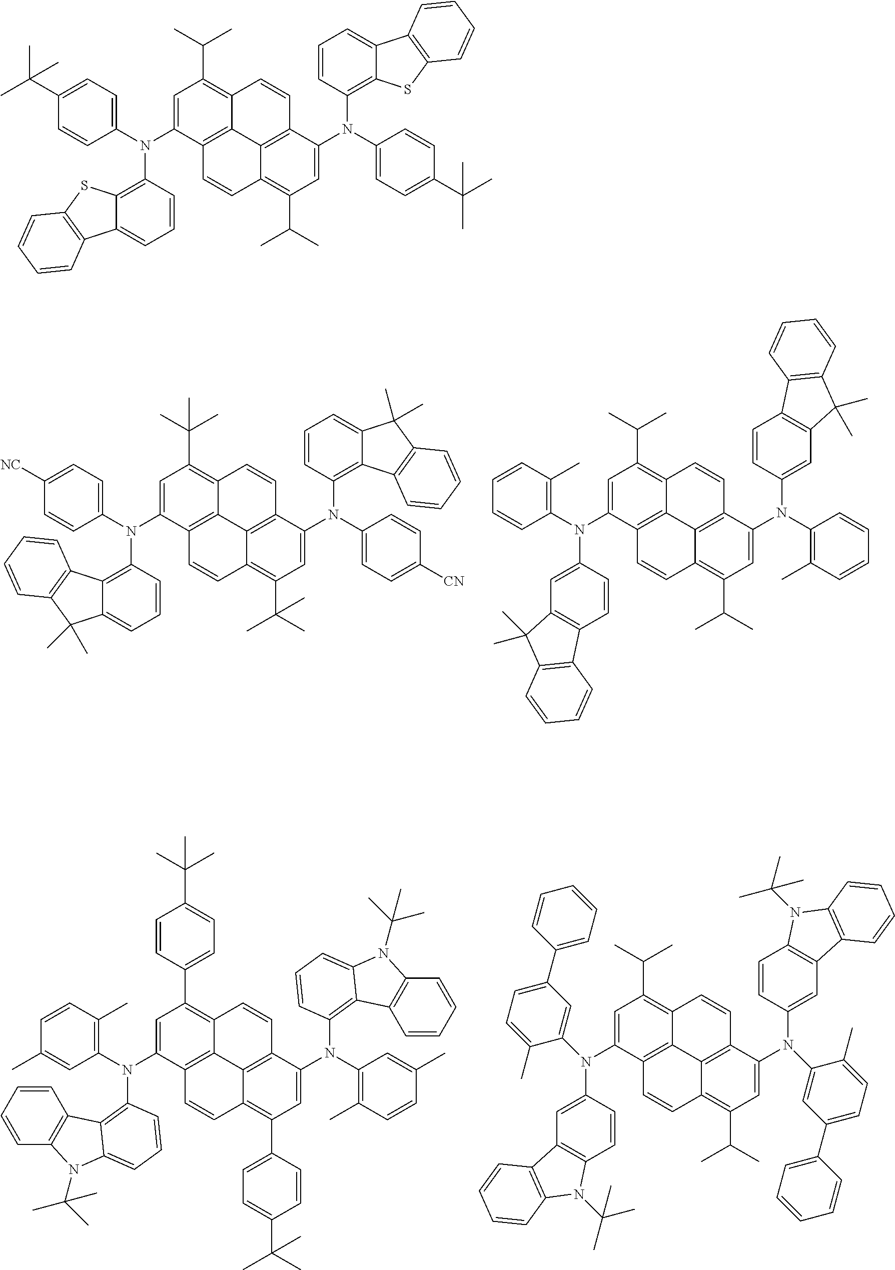

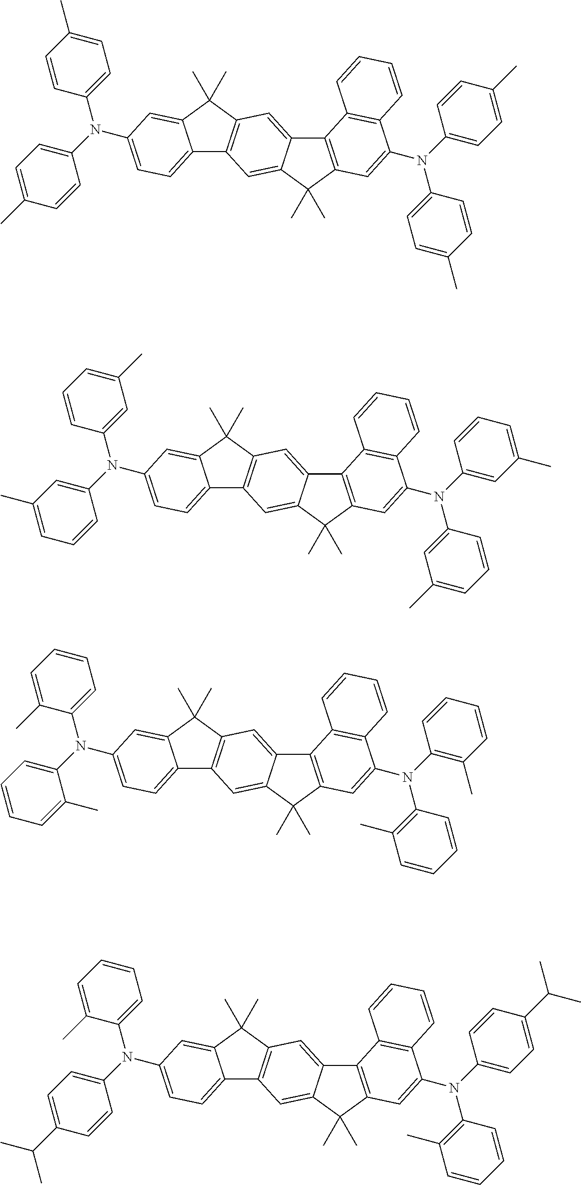

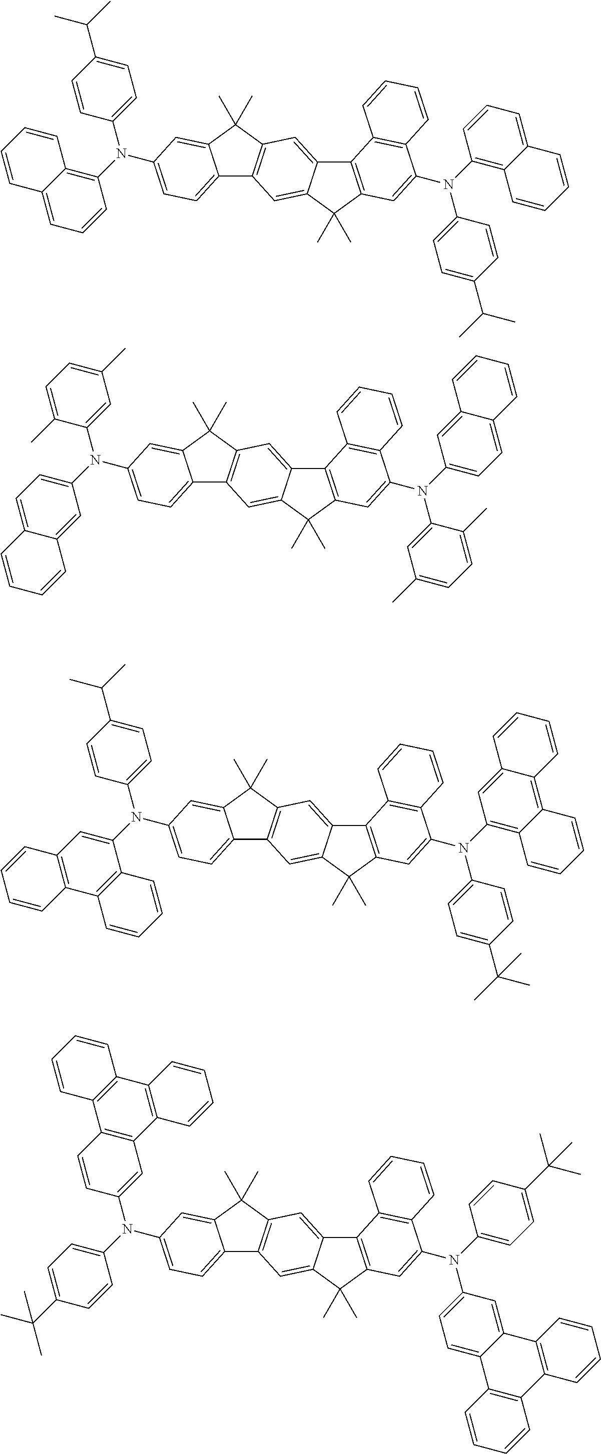

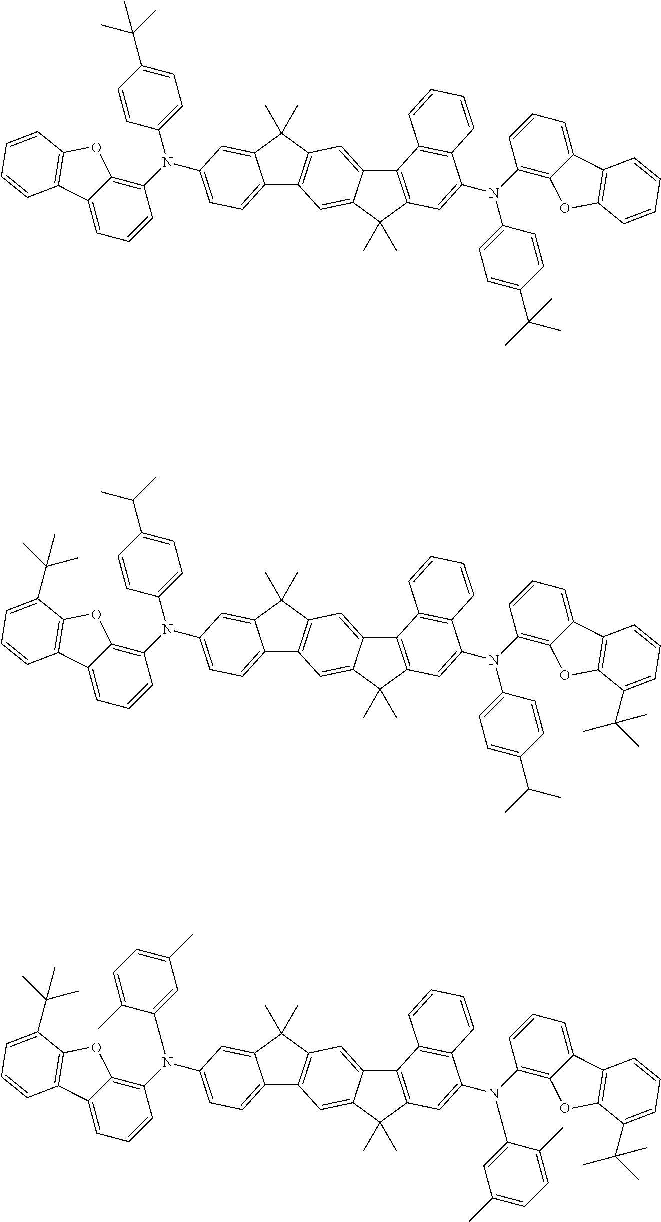 [SMILES: CC(C)(C)c1ccc(N(c2ccc3c(c2)C(C)(C)c2cc4c(cc2-3)C(C)(C)c2cc(N(c3ccc(C(C)(C)C)cc3)c3cccc5c3oc3ccccc35)c3ccccc3c2-4)c2cccc3c2oc2ccccc23)cc1 ; CC(C)c1ccc(N(c2ccc3c(c2)C(C)(C)c2cc4c(cc2-3)C(C)(C)c2cc(N(c3ccc(C(C)C)cc3)c3cccc5c3oc3c(C(C)(C)C)cccc35)c3ccccc3c2-4)c2cccc3c2oc2c(C(C)(C)C)cccc23)cc1 ; Cc1ccc(C)c(N(c2ccc3c(c2)C(C)(C)c2cc4c(cc2-3)C(C)(C)c2cc(N(c3cc(C)ccc3C)c3cccc5c3oc3c(C(C)(C)C)cccc35)c3ccccc3c2-4)c2cccc3c2oc2c(C(C)(C)C)cccc23)c1]

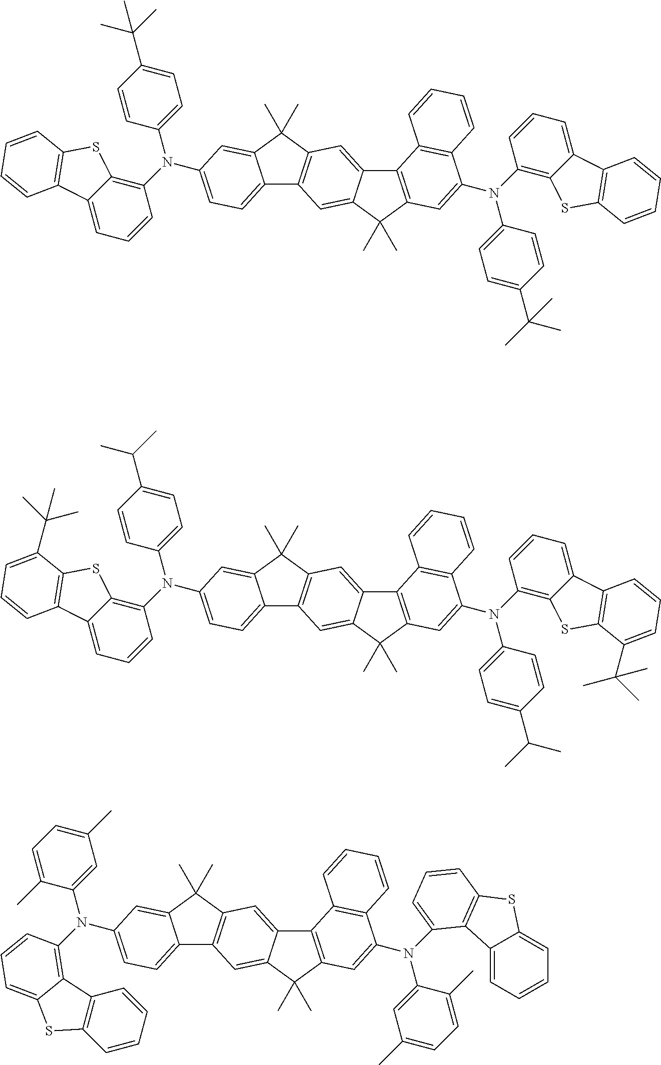 [SMILES: CC(C)(C)c1ccc(N(c2ccc3c(c2)C(C)(C)c2cc4c(cc2-3)C(C)(C)c2cc(N(c3ccc(C(C)(C)C)cc3)c3cccc5c3sc3ccccc35)c3ccccc3c2-4)c2cccc3c2sc2ccccc23)cc1 ; CC(C)c1ccc(N(c2ccc3c(c2)C(C)(C)c2cc4c(cc2-3)C(C)(C)c2cc(N(c3ccc(C(C)C)cc3)c3cccc5c3sc3c(C(C)(C)C)cccc35)c3ccccc3c2-4)c2cccc3c2sc2c(C(C)(C)C)cccc23)cc1 ; Cc1ccc(C)c(N(c2ccc3c(c2)C(C)(C)c2cc4c(cc2-3)C(C)(C)c2cc(N(c3cc(C)ccc3C)c3cccc5sc6ccccc6c35)c3ccccc3c2-4)c2cccc3sc4ccccc4c23)c1]

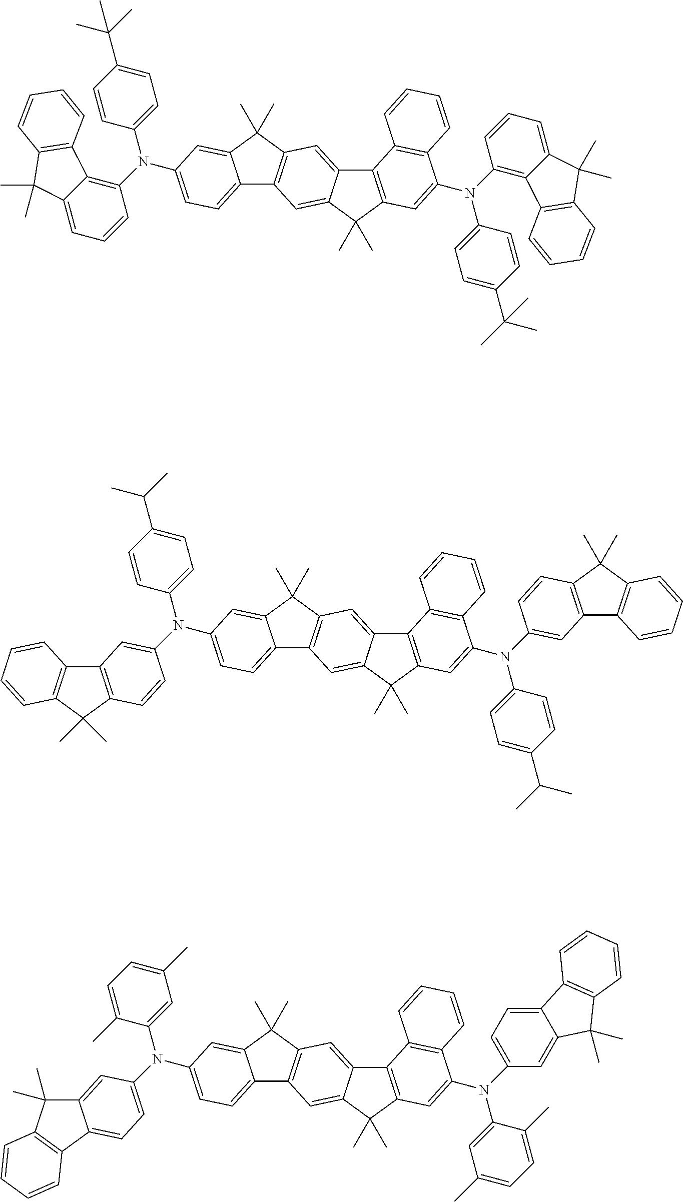

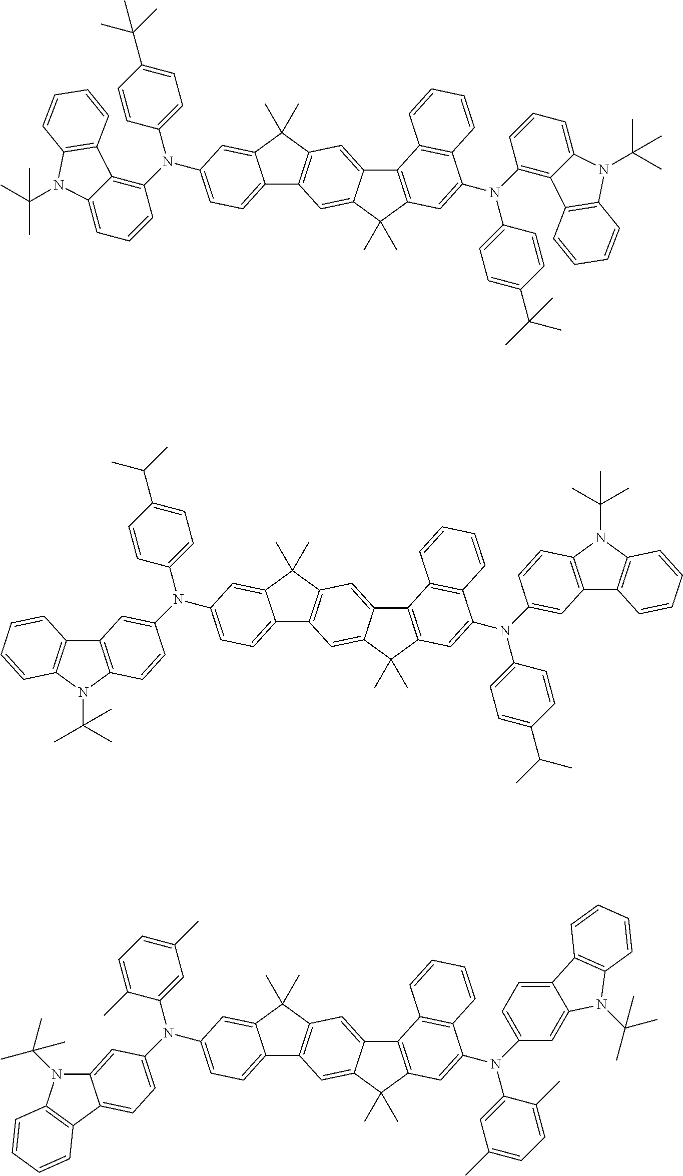

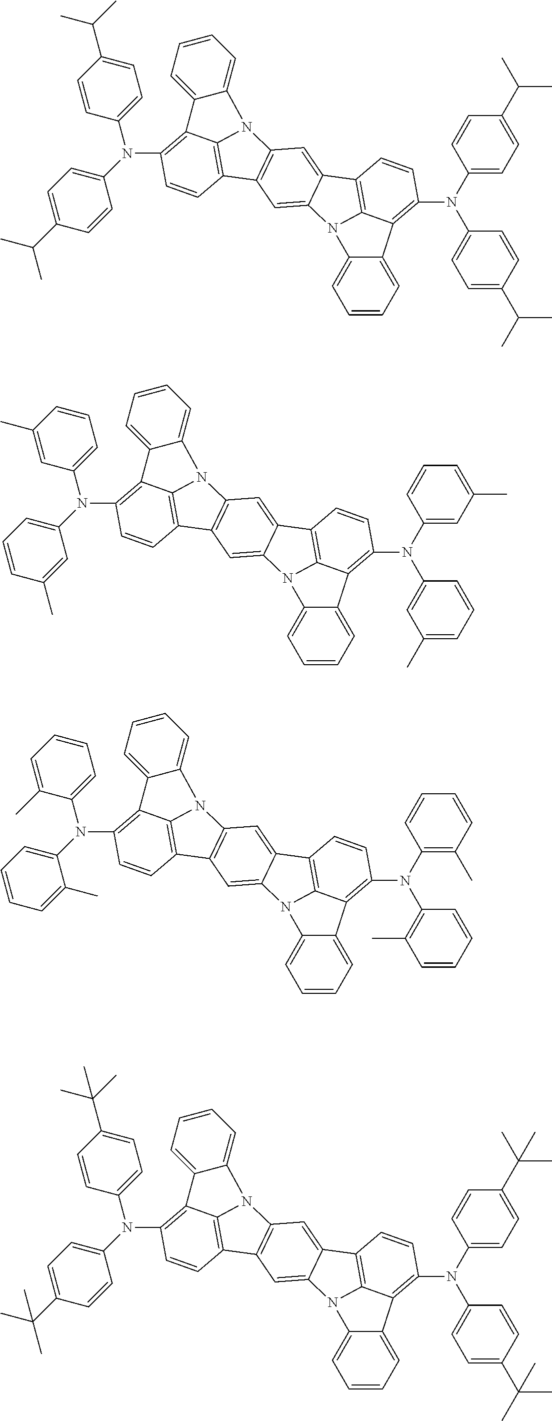

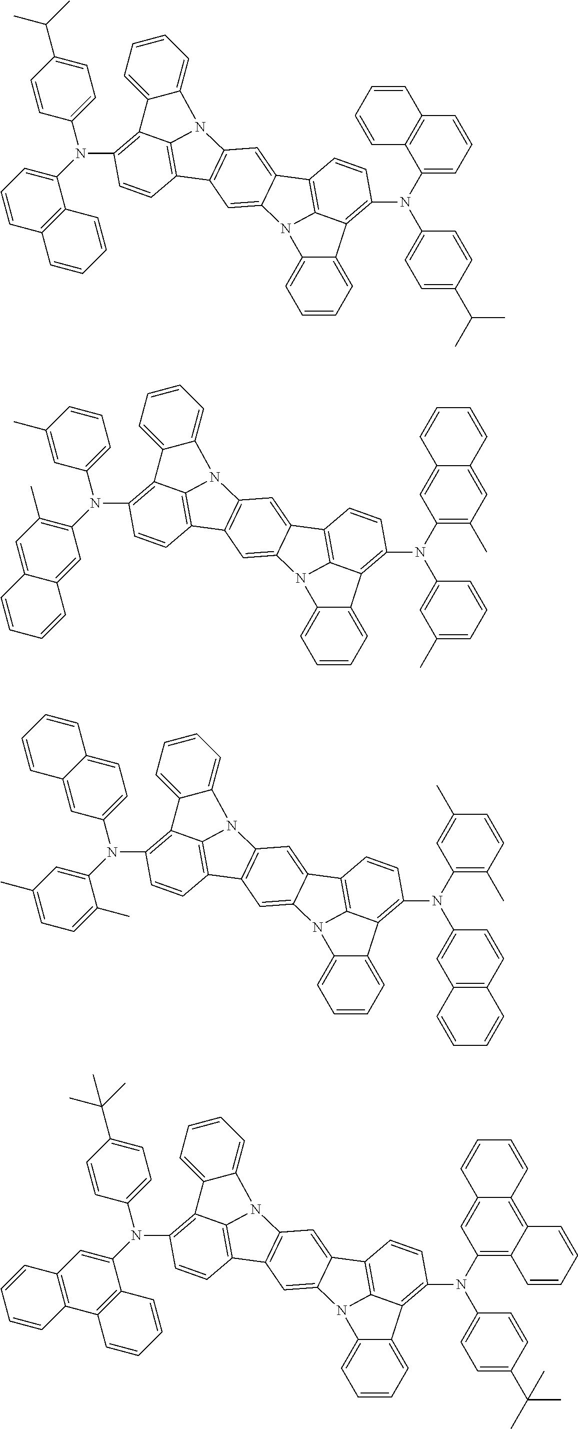

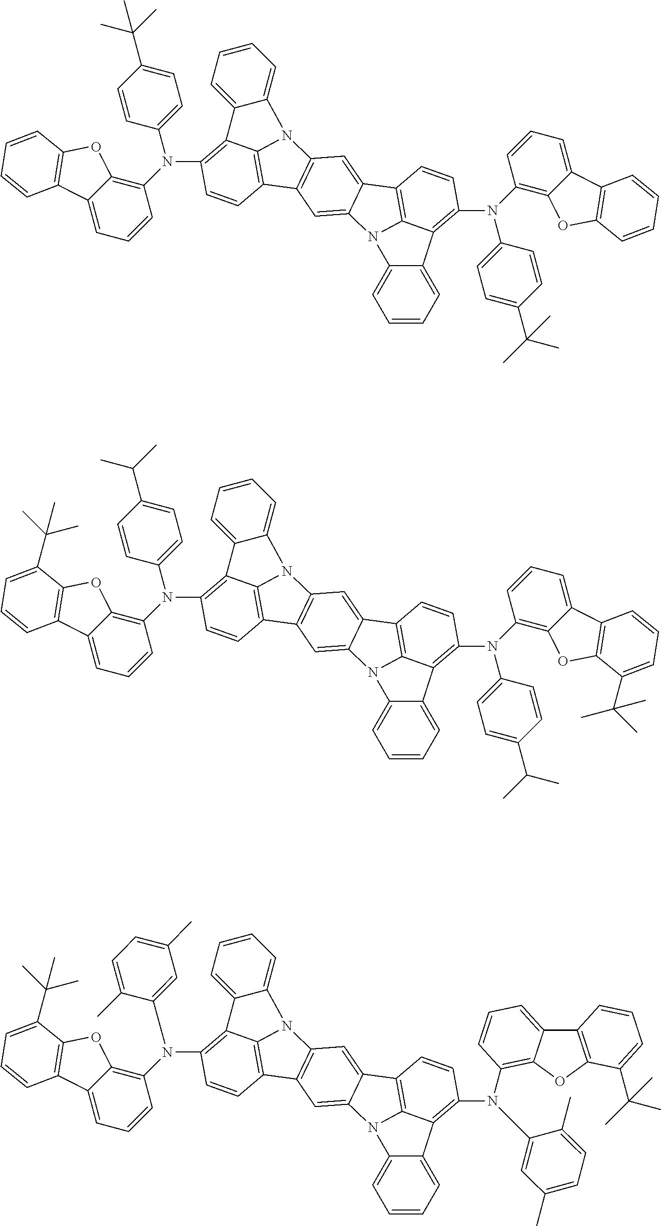 [SMILES: CC(C)(C)c1ccc(N(c2cccc3c2oc2ccccc23)c2ccc3c4cc5c(cc4n4c6ccccc6c2c34)c2ccc(N(c3ccc(C(C)(C)C)cc3)c3cccc4c3oc3ccccc34)c3c4ccccc4n5c23)cc1 ; CC(C)c1ccc(N(c2cccc3c2oc2c(C(C)(C)C)cccc23)c2ccc3c4cc5c(cc4n4c6ccccc6c2c34)c2ccc(N(c3ccc(C(C)C)cc3)c3cccc4c3oc3c(C(C)(C)C)cccc34)c3c4ccccc4n5c23)cc1 ; Cc1ccc(C)c(N(c2cccc3c2oc2c(C(C)(C)C)cccc23)c2ccc3c4cc5c(cc4n4c6ccccc6c2c34)c2ccc(N(c3cc(C)ccc3C)c3cccc4c3oc3c(C(C)(C)C)cccc34)c3c4ccccc4n5c23)c1]

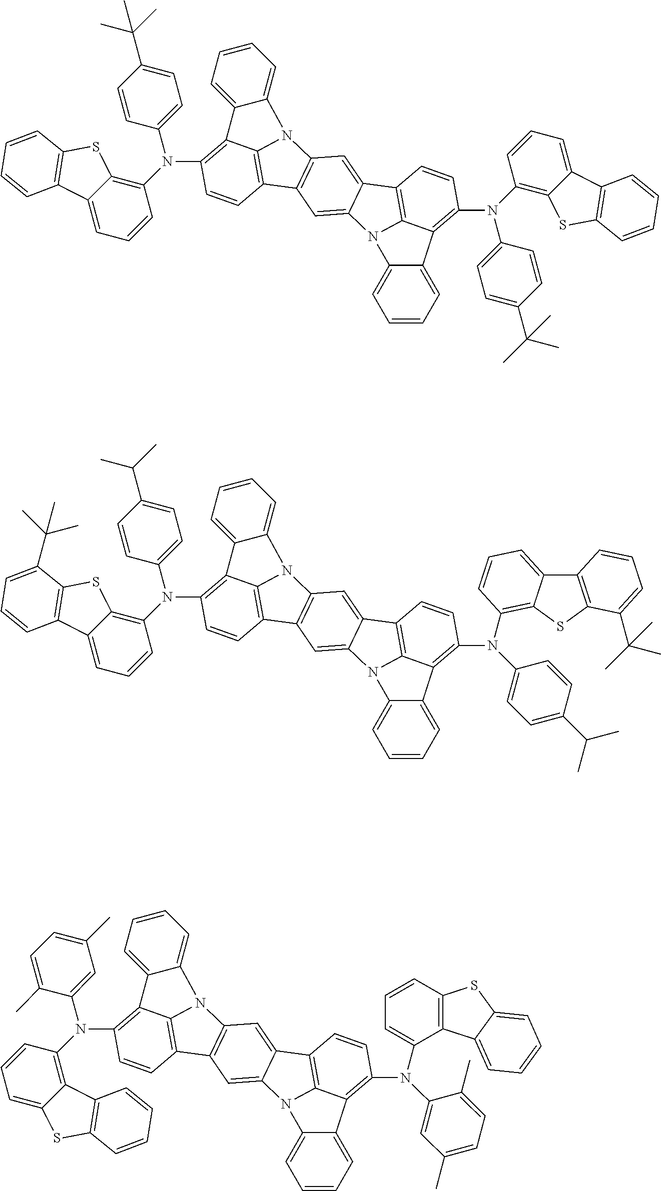 [SMILES: CC(C)(C)c1ccc(N(c2cccc3c2sc2ccccc23)c2ccc3c4cc5c(cc4n4c6ccccc6c2c34)c2ccc(N(c3ccc(C(C)(C)C)cc3)c3cccc4c3sc3ccccc34)c3c4ccccc4n5c23)cc1 ; CC(C)c1ccc(N(c2cccc3c2sc2c(C(C)(C)C)cccc23)c2ccc3c4cc5c(cc4n4c6ccccc6c2c34)c2ccc(N(c3ccc(C(C)C)cc3)c3cccc4c3sc3c(C(C)(C)C)cccc34)c3c4ccccc4n5c23)cc1 ; Cc1ccc(C)c(N(c2cccc3sc4ccccc4c23)c2ccc3c4cc5c(cc4n4c6ccccc6c2c34)c2ccc(N(c3cc(C)ccc3C)c3cccc4sc6ccccc6c34)c3c4ccccc4n5c23)c1]

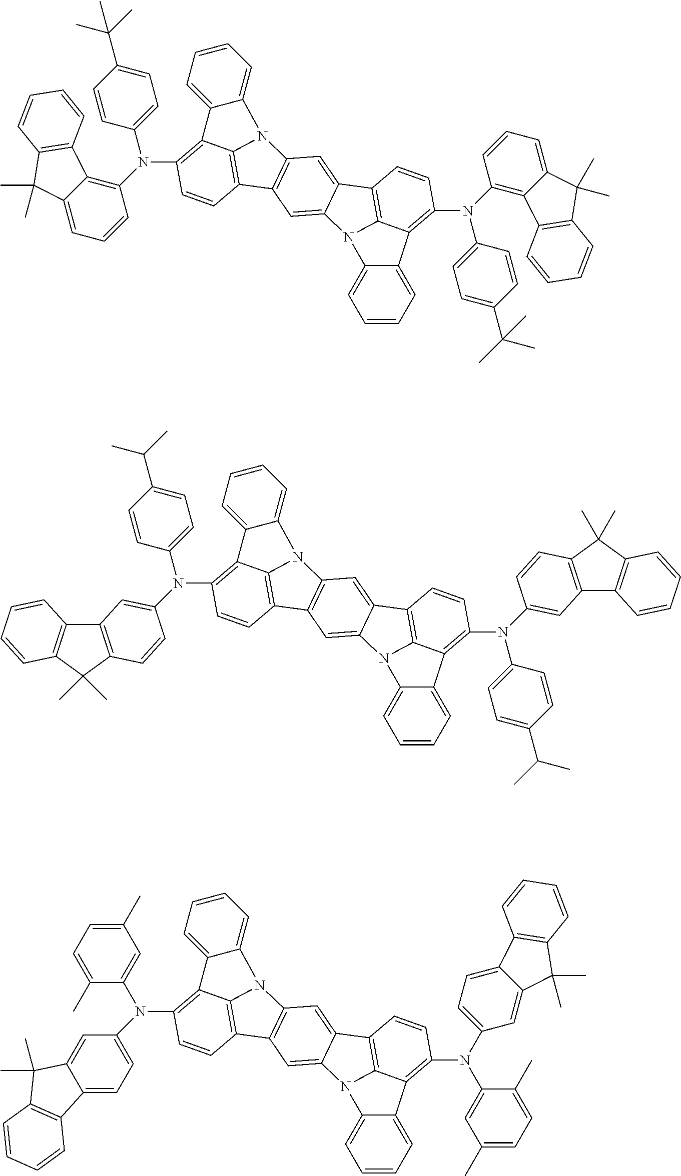

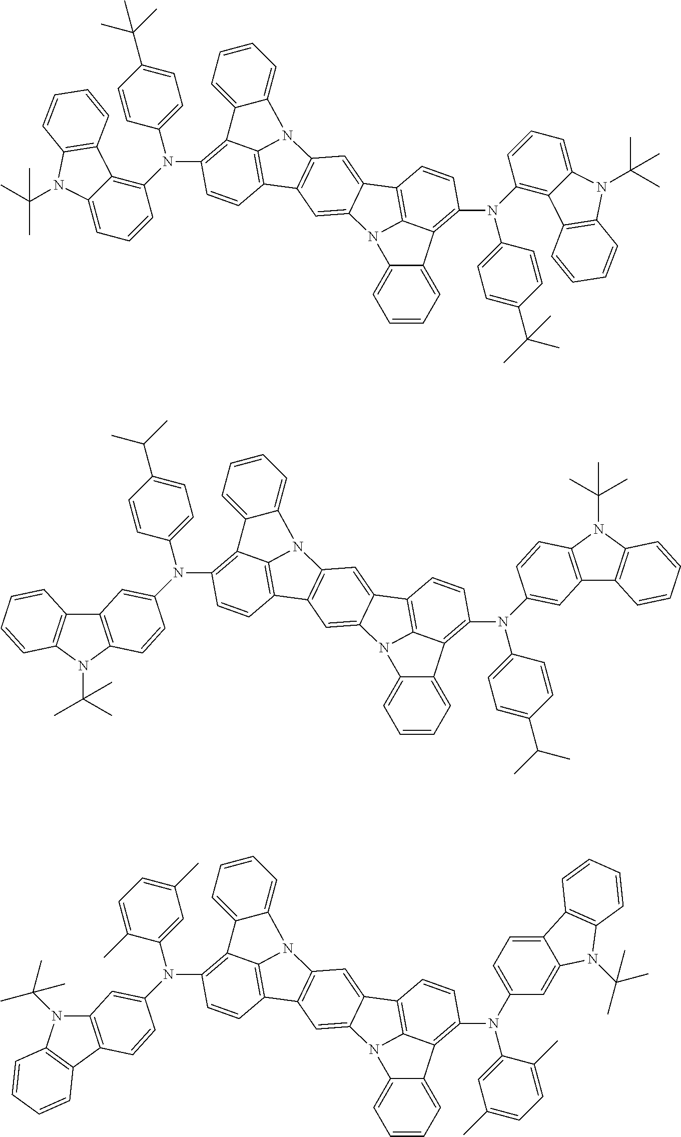

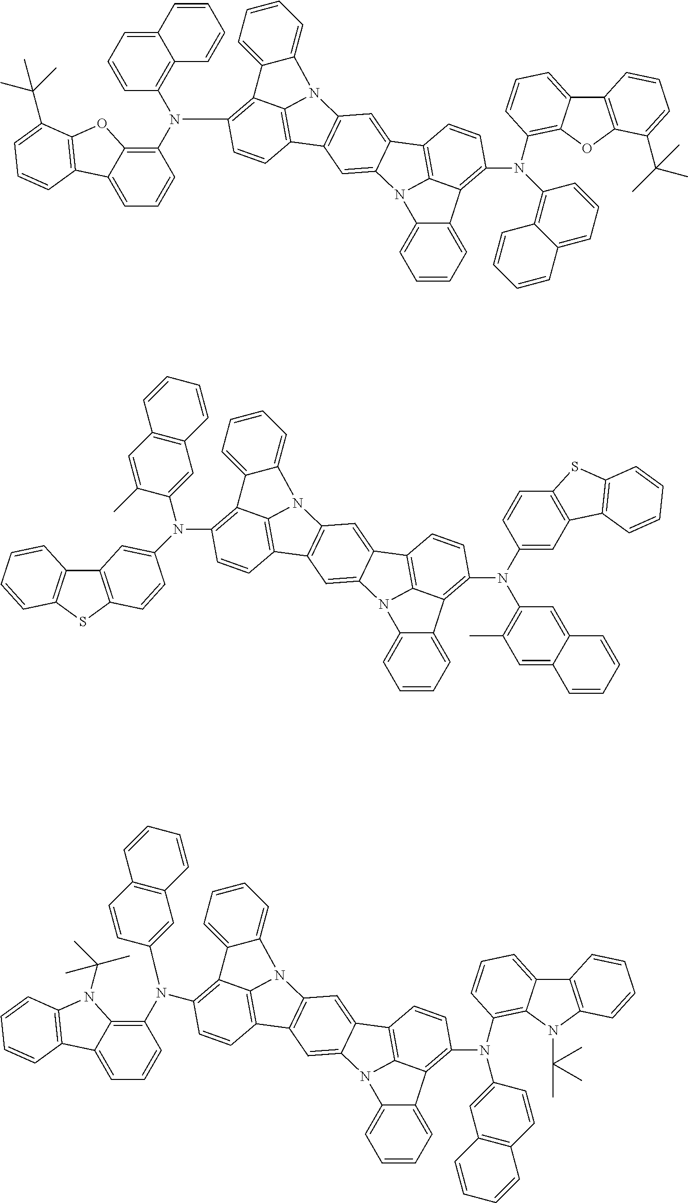 [SMILES: CC(C)(C)c1cccc2c1oc1c(N(c3cccc4ccccc34)c3ccc4c5cc6c(cc5n5c7ccccc7c3c45)c3ccc(N(c4cccc5ccccc45)c4cccc5c4oc4c(C(C)(C)C)cccc45)c4c5ccccc5n6c34)cccc12 ; Cc1cc2ccccc2cc1N(c1ccc2sc3ccccc3c2c1)c1ccc2c3cc4c(cc3n3c5ccccc5c1c23)c1ccc(N(c2ccc3sc5ccccc5c3c2)c2cc3ccccc3cc2C)c2c3ccccc3n4c12 ; CC(C)(C)n1c2ccccc2c2cccc(N(c3ccc4ccccc4c3)c3ccc4c5cc6c(cc5n5c7ccccc7c3c45)c3ccc(N(c4ccc5ccccc5c4)c4cccc5c7ccccc7n(C(C)(C)C)c45)c4c5ccccc5n6c34)c21]

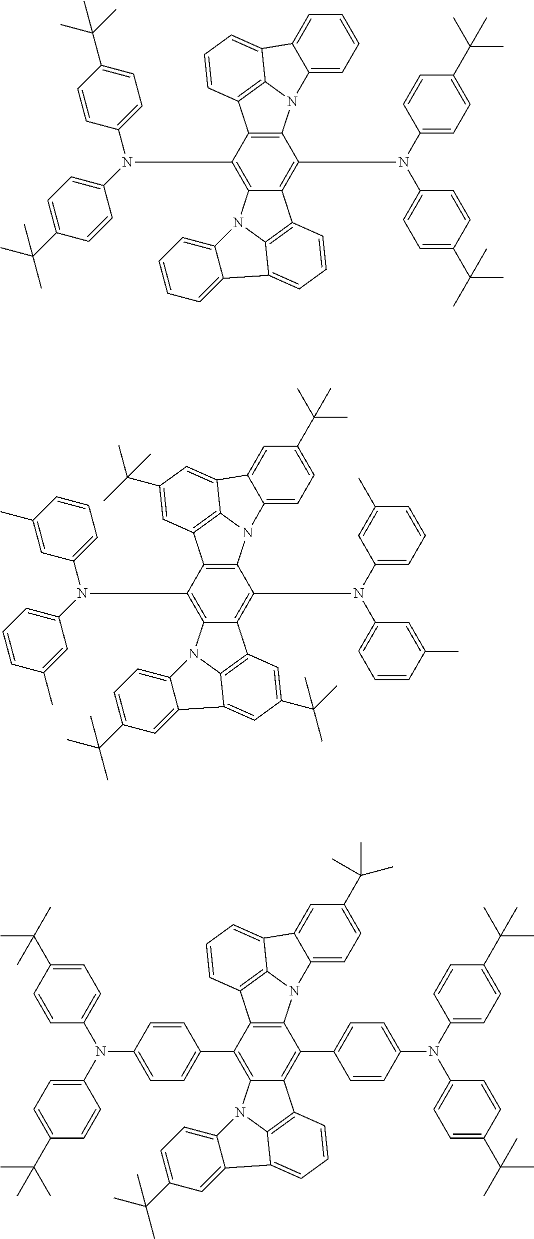

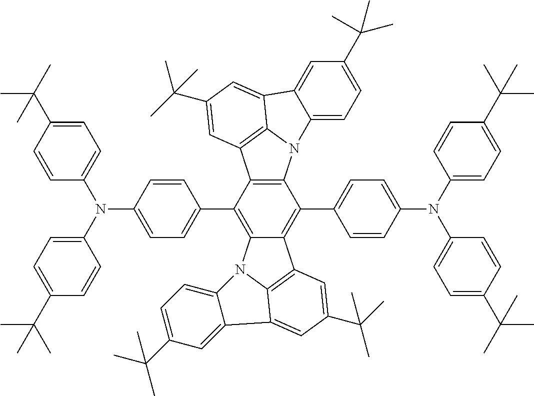 [SMILES: CC(C)(C)c1ccc(N(c2ccc(-c3c4c5cc(C(C)(C)C)cc6c7cc(C(C)(C)C)ccc7n(c4c(-c4ccc(N(c7ccc(C(C)(C)C)cc7)c7ccc(C(C)(C)C)cc7)cc4)c4c7cc(C(C)(C)C)cc8c9cc(C(C)(C)C)ccc9n(c34)c87)c65)cc2)c2ccc(C(C)(C)C)cc2)cc1]

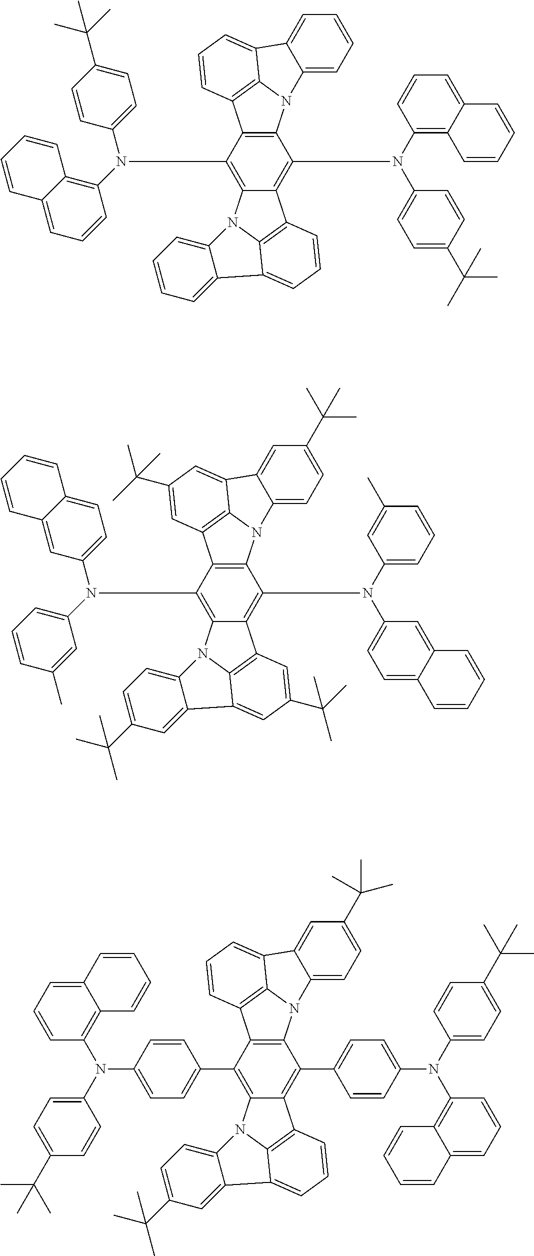 [SMILES: CC(C)(C)c1ccc(N(c2cccc3ccccc23)c2c3c4cccc5c6ccccc6n(c3c(N(c3ccc(C(C)(C)C)cc3)c3cccc6ccccc36)c3c6cccc7c8ccccc8n(c23)c76)c54)cc1 ; Cc1cccc(N(c2ccc3ccccc3c2)c2c3c4cc(C(C)(C)C)cc5c6cc(C(C)(C)C)ccc6n(c3c(N(c3cccc(C)c3)c3ccc6ccccc6c3)c3c6cc(C(C)(C)C)cc7c8cc(C(C)(C)C)ccc8n(c23)c76)c54)c1 ; CC(C)(C)c1ccc(N(c2ccc(-c3c4c5cccc6c7cc(C(C)(C)C)ccc7n(c4c(-c4ccc(N(c7ccc(C(C)(C)C)cc7)c7cccc8ccccc78)cc4)c4c7cccc8c9cc(C(C)(C)C)ccc9n(c34)c87)c65)cc2)c2cccc3ccccc23)cc1]

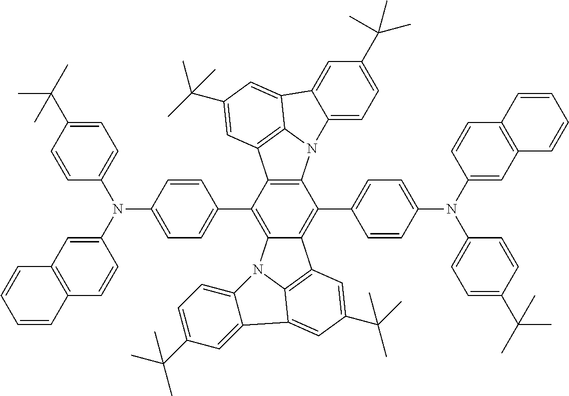 [SMILES: CC(C)(C)c1ccc(N(c2ccc(-c3c4c5cc(C(C)(C)C)cc6c7cc(C(C)(C)C)ccc7n(c4c(-c4ccc(N(c7ccc(C(C)(C)C)cc7)c7ccc8ccccc8c7)cc4)c4c7cc(C(C)(C)C)cc8c9cc(C(C)(C)C)ccc9n(c34)c87)c65)cc2)c2ccc3ccccc3c2)cc1]

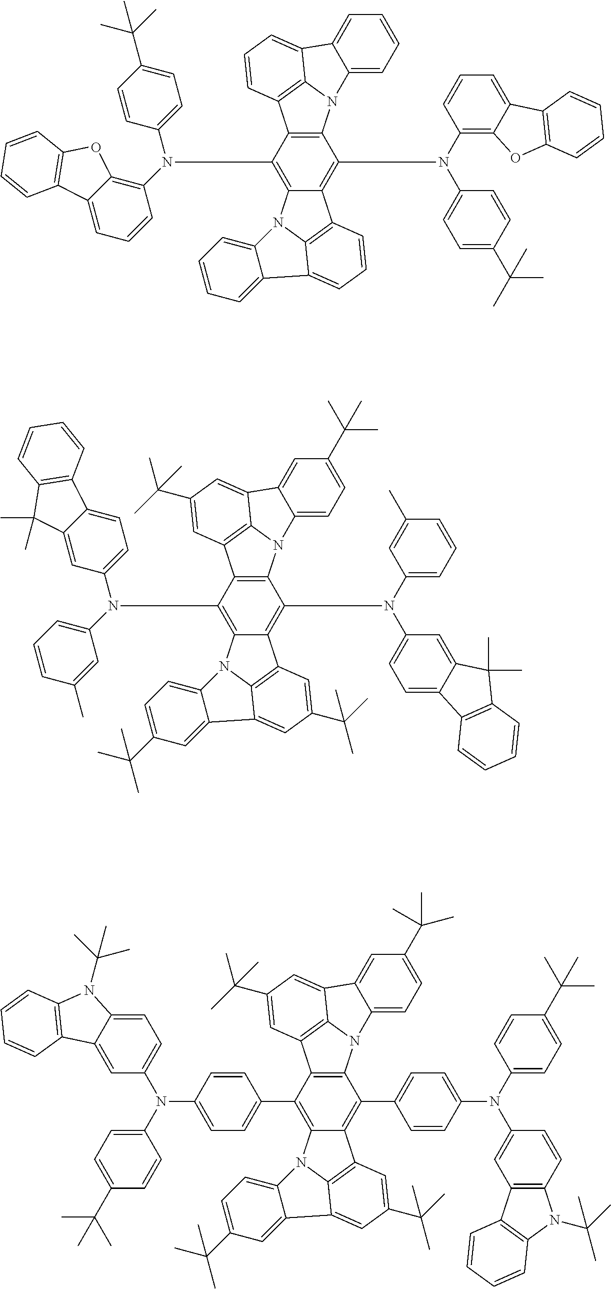

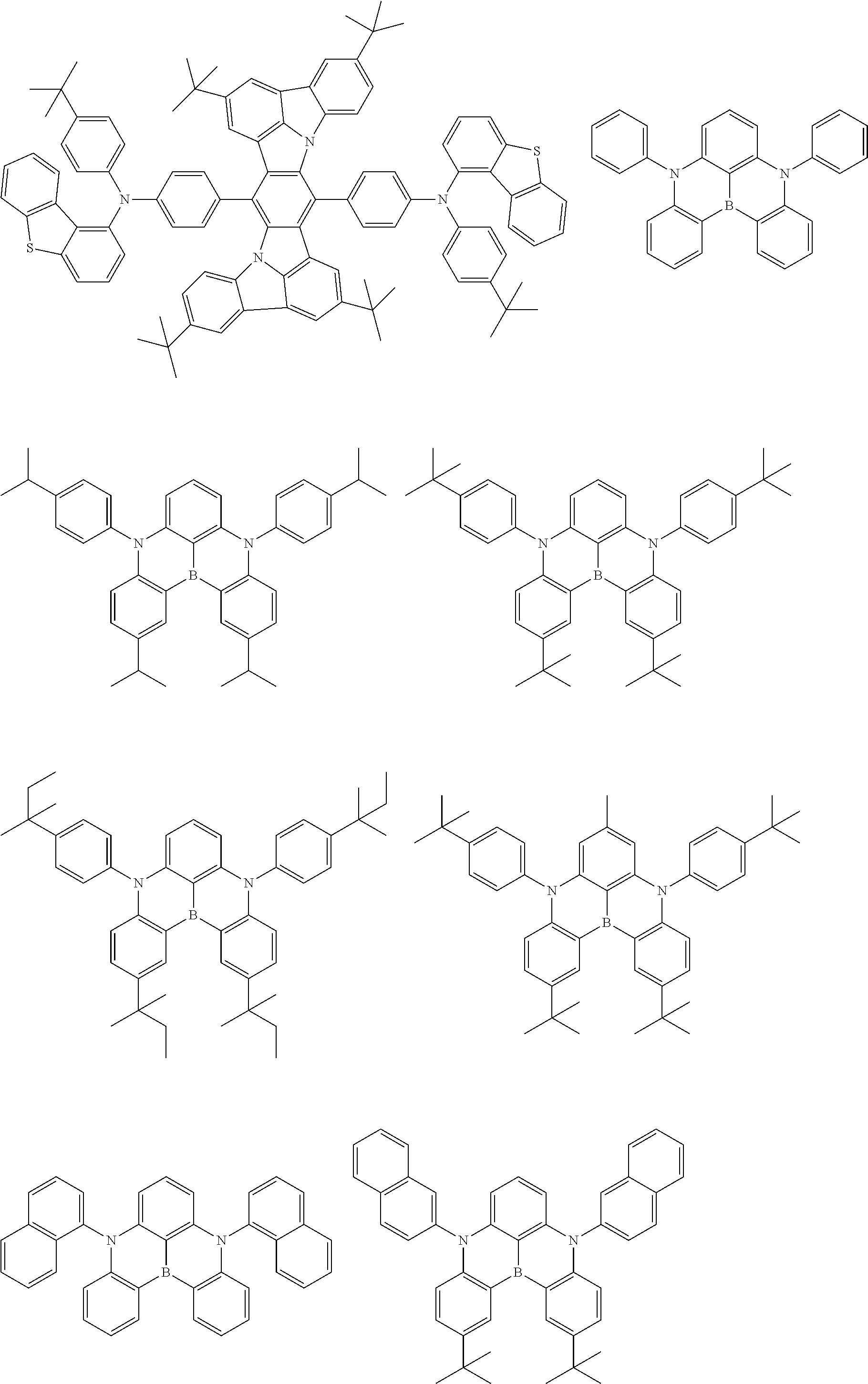

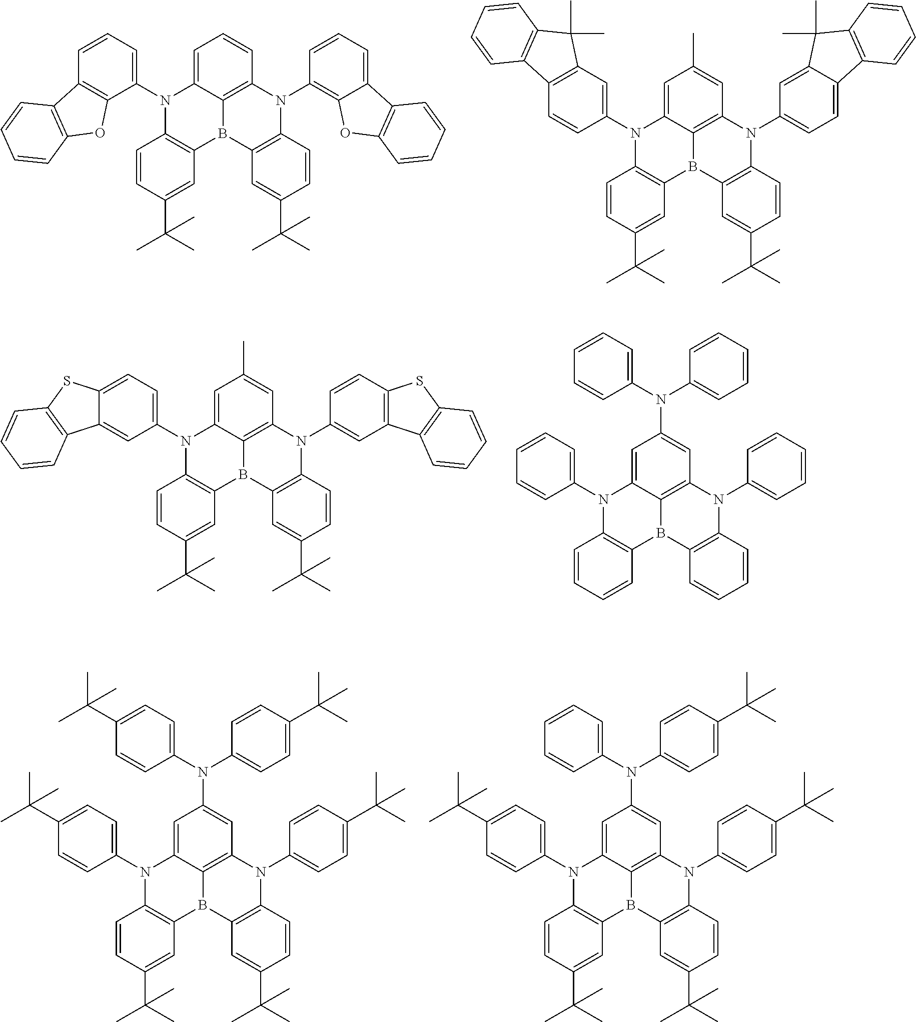

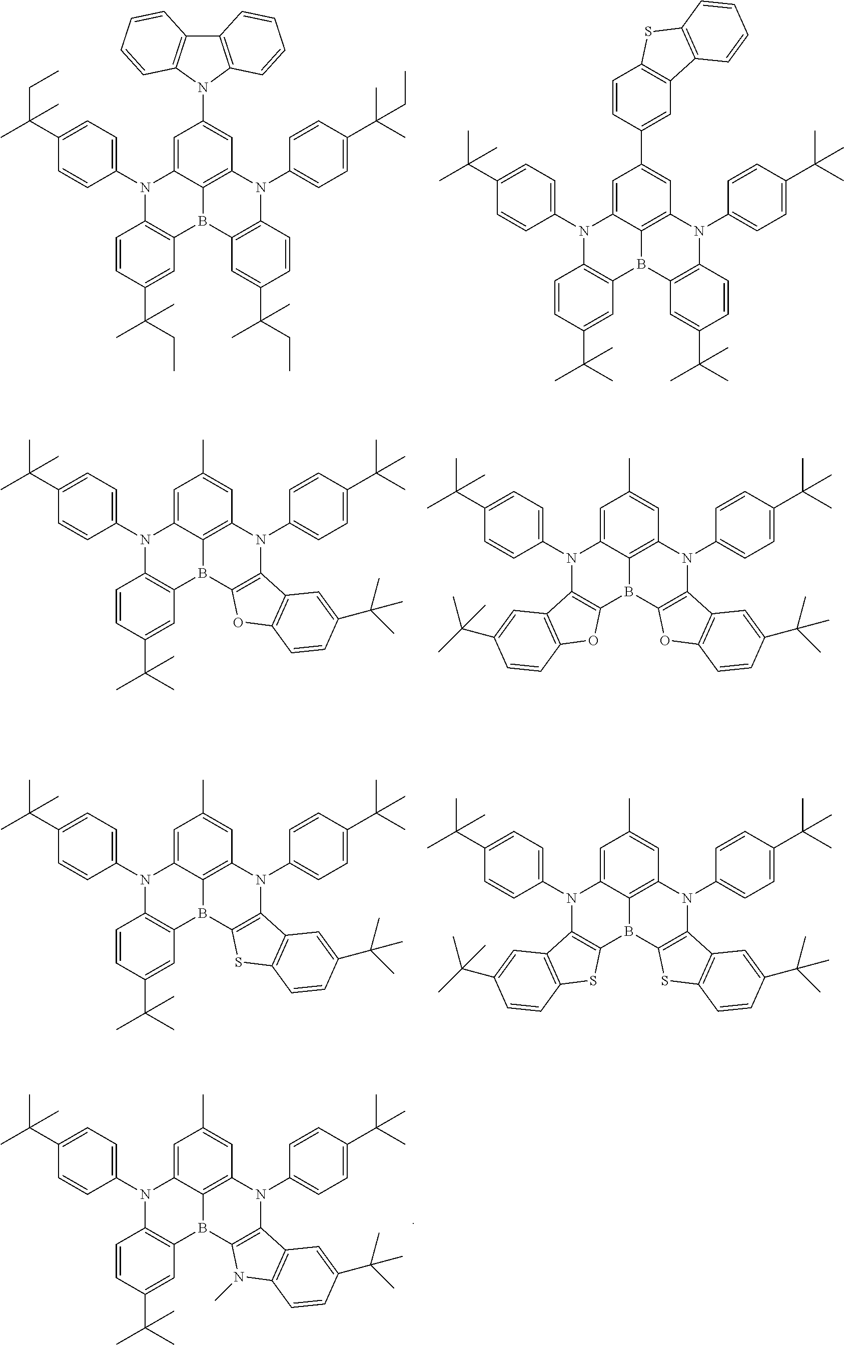

19. The A light-emitting device comprising:
a pair of electrodes comprising a first electrode and a second electrode; and
an organic functional layer disposed between the first electrode and the second electrode;
wherein a material of the organic functional layer comprises at least one composition according to claim 1.

20. A display panel comprising the light-emitting device according to claim 19.
